(19) United States
(12) Patent Application Publication
(10) Pub. No.: US 2024/0179931 A1
(43) Pub. Date: May 30, 2024

(54) LIGHT EMITTING DEVICE AND FUSED POLYCYCLIC COMPOUND FOR THE LIGHT EMITTING DEVICE

(71) Applicant: Samsung Display Co., Ltd., Yongin-si (KR)

(72) Inventors: CHANSEOK OH, Yongin-si (KR); JUNHA PARK, Yongin-si (KR); Kyoung SUNWOO, Yongin-si (KR); MinJae SUNG, Yongin-si (KR); MUN-KI SIM, Yongin-si (KR); CHANGWOONG CHU, Yongin-si (KR)

(21) Appl. No.: 18/355,335

(22) Filed: Jul. 19, 2023

(30) Foreign Application Priority Data
Oct. 26, 2022 (KR) 10-2022-0139109

(51) Int. Cl. H10K 50/11; C09K 11/06; H10K 50/805; H10K 85/30; H10K 85/60

(52) U.S. Cl. CPC H10K 50/11; C09K 11/06; H10K 50/805; H10K 85/346; H10K 85/658; C09K 2211/1048

(57) ABSTRACT

A light emitting device may include a first electrode, a second electrode on the first electrode, and an emission layer between the first electrode and the second electrode, wherein the emission layer includes a first compound represented by Formula 1.

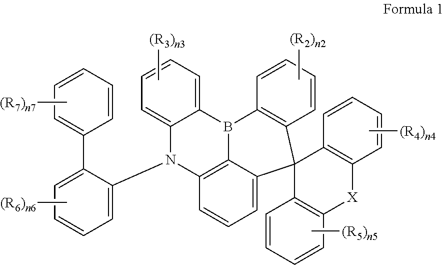

### CROSS-REFERENCE TO RELATED APPLICATIONS

This application claims priority to and the benefit of Korean Patent Application No. 10-2022-0139109, filed on Oct. 26, 2022, in the Korean Intellectual Property Office, the entire content of which is hereby incorporated by reference.

### BACKGROUND

### 1. Field

One or more embodiments of the present disclosure relate to a light emitting device and a fused polycyclic compound utilized in the light emitting device.

### 2. Description of the Related Art

Recently, the development of an organic electroluminescence display as an image display is being actively conducted. The organic electroluminescence display is different from a liquid crystal display because, e.g., it is a self-luminescent display in which holes and electrons separately injected from a first electrode and a second electrode recombine in an emission layer of the organic electroluminescence display so that a light emitting material including an organic compound in the emission layer emits light to achieve display (e.g., of an image).

In the application of an organic electroluminescence device to a display, the decrease of a driving voltage and the increase of the emission efficiency and lifetime of the organic electroluminescence device are required and/or desired. Development on materials for an organic electroluminescence device stably achieving those requirements is being continuously required and pursued.

For example, recently, in order to improve efficiency of an organic electroluminescence device, techniques based on phosphorescence emission which utilizes energy in a triplet state or fluorescence emission which utilizes the phenomenon of generating singlet excitons by the collision of triplet excitons (triplet-triplet annihilation, TTA) are being developed and exploited, and development on a thermally activated delayed fluorescence (TADF) material utilizing delayed fluorescence phenomenon is being conducted and advanced.

### SUMMARY

One or more aspects of embodiments of the present disclosure are directed toward a light emitting device having improved emission efficiency and device lifetime.

One or more aspects of embodiments of the present disclosure are directed toward to a fused polycyclic compound which is capable of improving the emission efficiency and device lifetime of a light emitting device.

Additional aspects will be set forth in part in the description which follows and, in part, will be apparent from the description, or may be learned by practice of the presented embodiments.

One or more embodiments of the present disclosure provide a light emitting device including a first electrode, a second electrode on the first electrode, and an emission layer between the first electrode and the second electrode, wherein the emission layer includes a first compound represented by Formula 1.

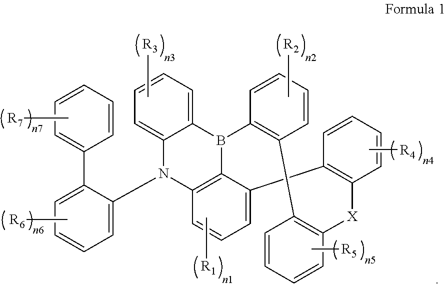

In Formula 1, X may be NR₈, O, or S, R₁ to R₈ may each independently be hydrogen, deuterium, a halogen, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, n1 may be an integer of 0 to 3, n2 to n6 may each independently be an integer of 0 to 4, and n7 may be an integer of 0 to 5.

In one or more embodiments, R₂ and R₃ may each independently be a substituted or unsubstituted amine group, a substituted or unsubstituted aryl group of 6 to 30 ring-forming carbon atoms, or a substituted or unsubstituted heteroaryl group of 2 to 30 ring-forming carbon atoms, and n2 and n3 may each independently be an integer of 1 to 4.

In one or more embodiments, the first compound represented by Formula 1 may be represented by Formula 2.

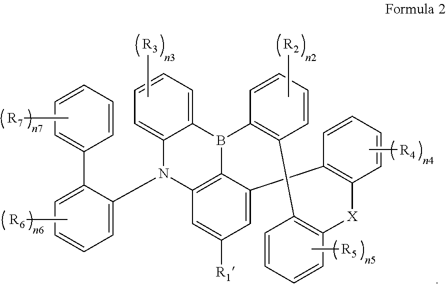

In Formula 2, may be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula 2, the same contents defined in Formula 1 may be applied for X, R₂ to R₇, and n2 to n7.

In one or more embodiments, may be a substituted or unsubstituted alkyl group of 1 to 10 carbon atoms, or represented by Formula A-1 or Formula A-2.

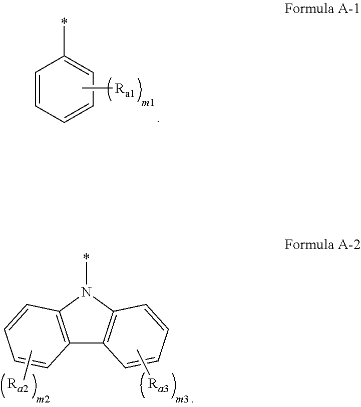

In Formula A-1 and Formula A-2, Rₐ₁ to Rₐ₃ may each independently be hydrogen, deuterium, a halogen, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, m1 may be an integer of 0 to 5, and m2 and m3 may each independently be an integer of 0 to 4.

In one or more embodiments, the first compound represented by Formula 1 may be represented by any one selected from among Formula 3-1 to Formula 3-4.

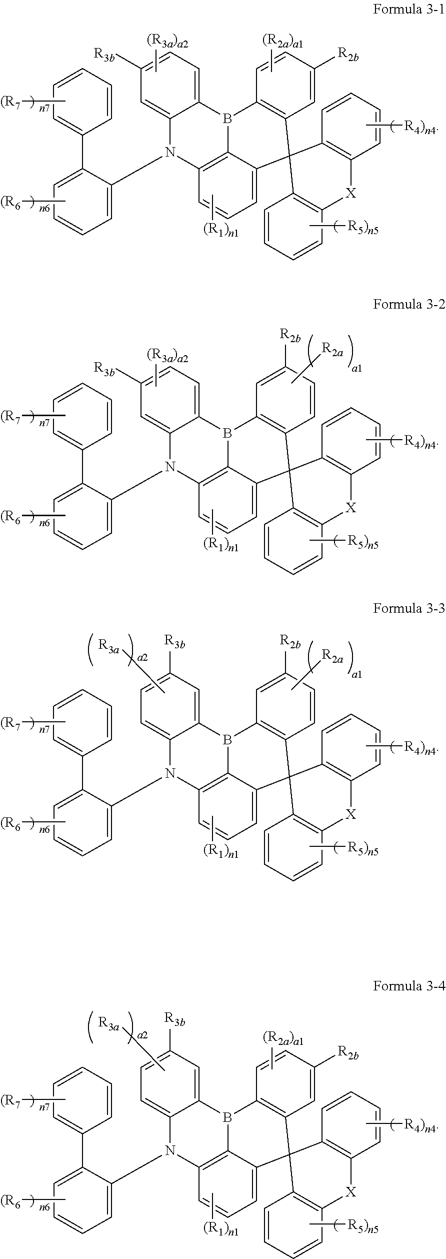

In Formula 3-1 to Formula 3-4, R₂ₐ and R₃ₐ may each independently be hydrogen, deuterium, a halogen, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, R_{2b} and R_{3b} may each independently be a substituted or unsubstituted aryl group of 6 to 30 ring-forming carbon atoms, or a substituted or unsubstituted heteroaryl group of 2 to 30 ring-forming carbon atoms, a1 and a2 may each independently be an integer of 0 to 3.

In Formula 3-1 to Formula 3-4, the same contents defined in Formula 1 may be applied for X, R₁, R₄ to R₇, n1, and n4 to n7.

In one or more embodiments, the first compound represented by Formula 1 may be represented by any one selected from among Formula 4-1 to Formula 4-4.

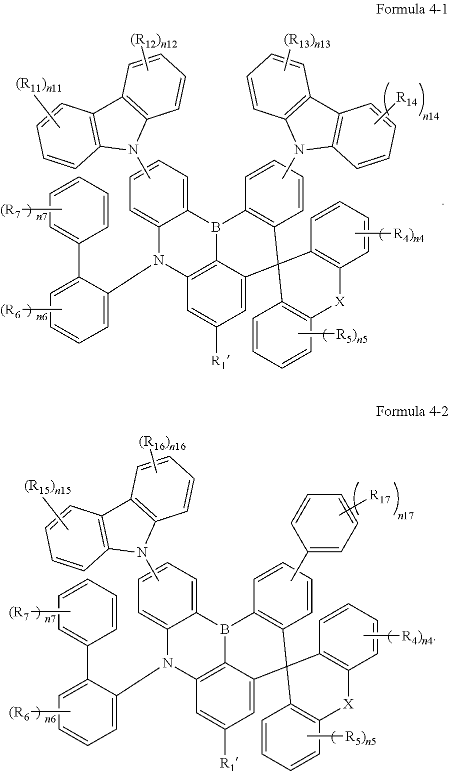

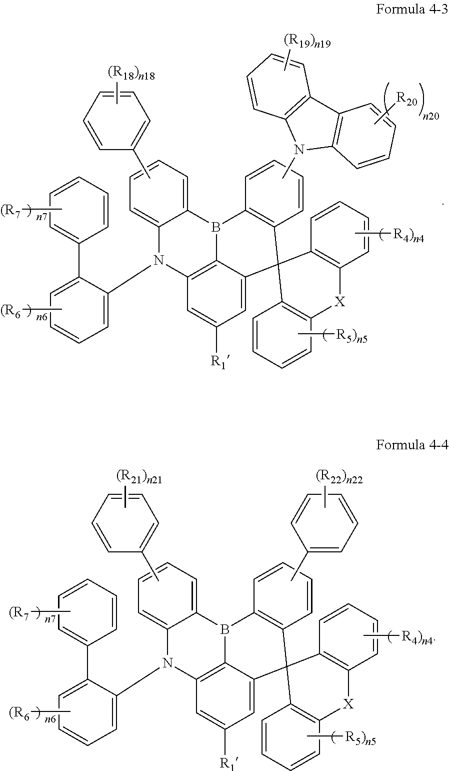

In Formula 4-1 to Formula 4-4, R₁₁ to R₂₂ may each independently be hydrogen, deuterium, a halogen, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, may be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, n11 to n16, n19, and n20 may each independently be an integer of 0 to 4, n17, n18, n21, and n22 may each independently be an integer of 0 to 5.

In Formula 4-1 to Formula 4-4, the same contents defined in Formula 1 may be applied for X, R₄ to R₇, and n4 to n7.

In one or more embodiments, the first compound represented by Formula 1 may be represented by any one selected from among Formula 5-1 to Formula 5-3.

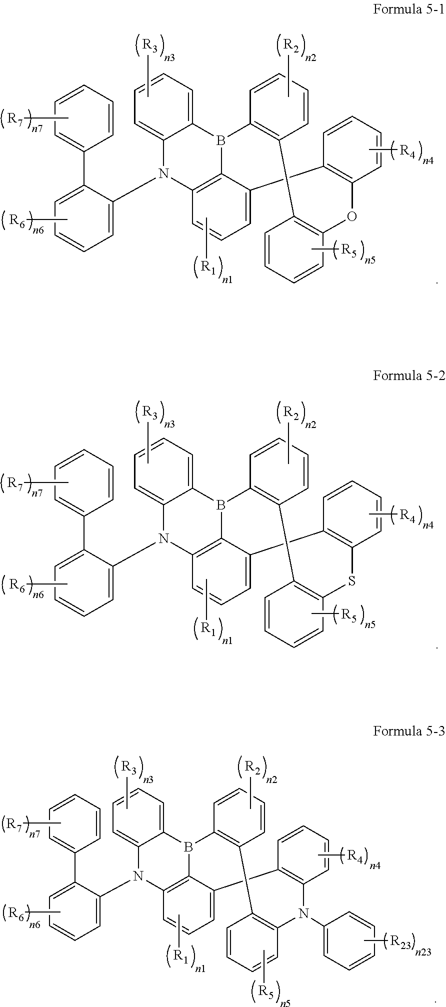

In Formula 5-1 to Formula 5-3, R₂₃ is hydrogen, deuterium, a halogen, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and n23 may be an integer of 0 to 5.

In Formula 5-1 to Formula 5-3, the same contents defined in Formula 1 may be applied for R₁ to R₇, and n1 to n7.

In one or more embodiments, the first compound represented by Formula 1 may be represented by Formula 6.

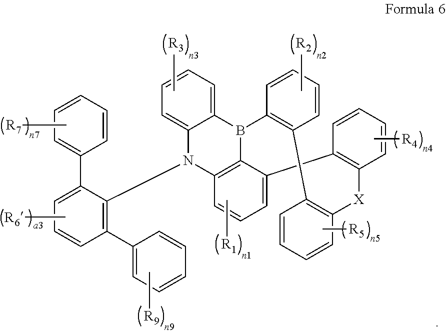

In Formula 6, R₆′ and R₉ may each independently be hydrogen, deuterium, a halogen, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, a3 may be an integer of 0 to 3, and n9 may be an integer of 0 to 5.

In Formula 6, the same contents defined in Formula 1 may be applied for X, R₁ to R₅, R₇, n1 to n5, and n7.

In one or more embodiments, the first compound represented by Formula 1 may be represented by any one selected from among Formula 7-1 to Formula 7-3.

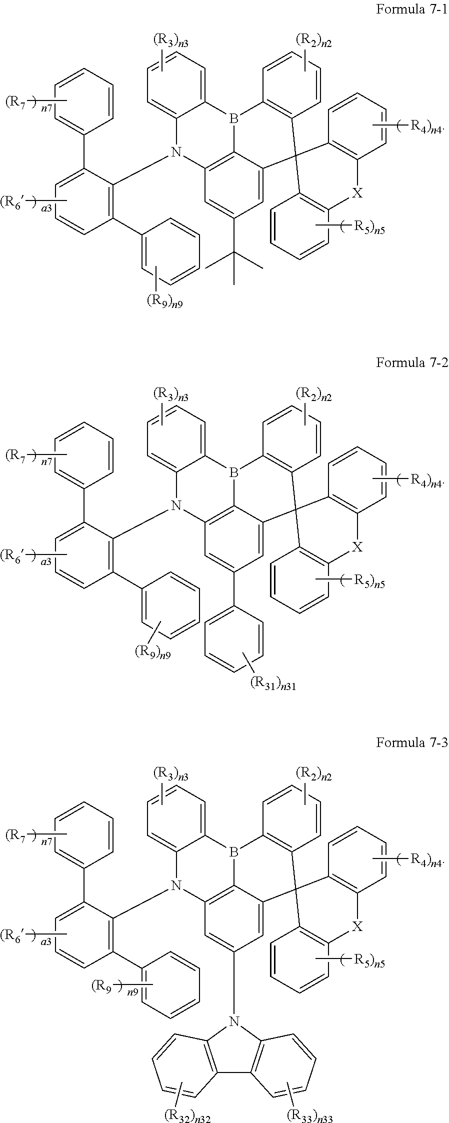

In Formula 7-1 to Formula 7-3, R₆′, R₉, and R₃₁ to R₃₃ may each independently be hydrogen, deuterium, a halogen, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, a3 may be an integer of 0 to 3, n9 and n31 may each independently be an integer of 0 to 5, and n32 and n33 may each independently be an integer of 0 to 4.

In Formula 7-1 to Formula 7-3, the same contents defined in Formula 1 may be applied for X, R₂ to R₅, R₇, n2 to n5, and n7.

In one or more embodiments, the first compound represented by Formula 1 may be represented by any one selected from among Formula 8-1 to Formula 8-3.

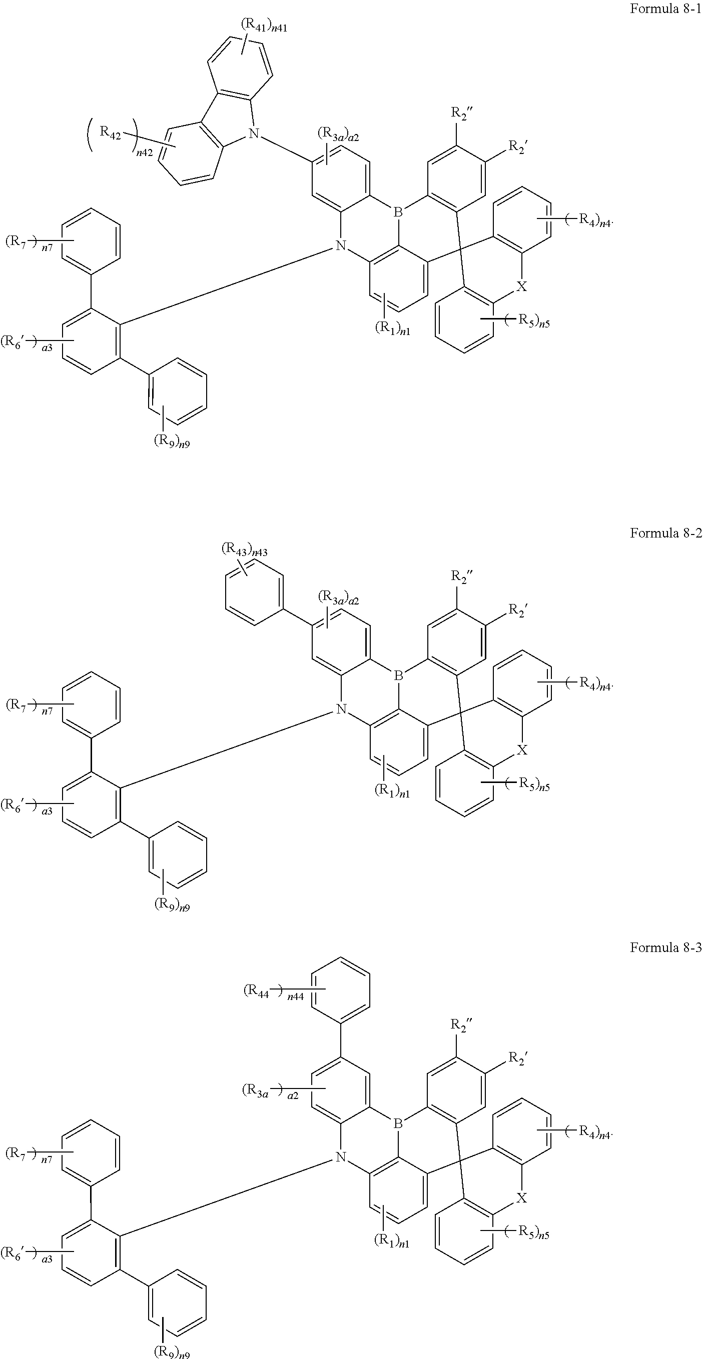

In Formula 8-1 to Formula 8-3, R₃ₐ, R₂′, R₂″, and R₄₁ to R₄₄ may each independently be hydrogen, deuterium, a halogen, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, R₆′, and R₉ may each independently be hydrogen, deuterium, a halogen, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, at least one selected from among R₂′ and R₂″ may be a substituted or unsubstituted aryl group of 6 to 30 ring-forming carbon atoms, or a substituted or unsubstituted heteroaryl group of 2 to 30 ring-forming carbon atoms, a2 and a3 may each independently be an integer of 0 to 3, n9 may be an integer of 0 to 5, n41 and n42 may each independently be an integer of 0 to 4, n43 and n44 may each independently be an integer of 0 to 5.

In Formula 8-1 to Formula 8-3, the same contents defined in Formula 1 may be applied for X, R₁, R₄, R₅, R₇, n1, n4, n5, and n7.

In one or more embodiments, the emission layer may further include at least one selected from among a second compound represented by Formula HT-1, and a third compound represented by Formula ET-1.

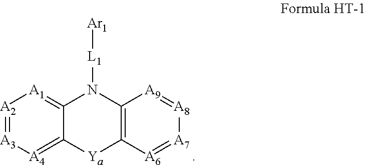

In Formula HT-1, A₁ to A₄ and A₆ to A₉ may each independently be N or CR₅₁, L₁ may be a direct linkage, a substituted or unsubstituted arylene group of 6 to ring-forming carbon atoms, or a substituted or unsubstituted heteroarylene group of 2 to 30 ring-forming carbon atoms, Yₐ may be a direct linkage, CR₅₂R₅₃, or SiR₅₄R₅₅, Ar₁ may be a substituted or unsubstituted aryl group of 6 to 30 ring-forming carbon atoms, or a substituted or unsubstituted heteroaryl group of 2 to 30 ring-forming carbon atoms, and R₅₁ to R₅₅ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring.

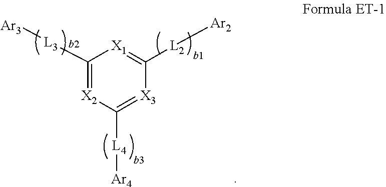

In Formula ET-1, at least one selected from among X₁ to X₃ may be N, and the remainder may be CR₅₆, R₅₆ may be hydrogen, deuterium, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms, L₂ to L₄ may each independently be a direct linkage, a substituted or unsubstituted arylene group of 6 to 30 ring-forming carbon atoms, or a substituted or unsubstituted heteroarylene group of 2 to 30 ring-forming carbon atoms, b1 to b3 may each independently be an integer of 0 to 10, and Are to Ara may each independently be hydrogen, deuterium, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In one or more embodiments, the emission layer may further include a fourth compound represented by Formula D-1.

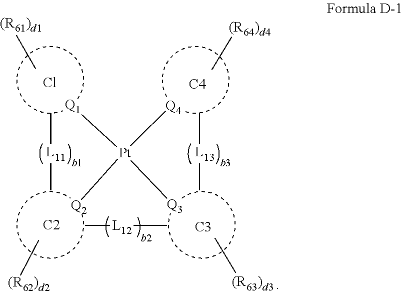

In Formula D-1, Q₁ to Q₄ may each independently be C or N, C1 to C4 may each independently be a substituted or unsubstituted hydrocarbon ring of 5 to 30 ring-forming carbon atoms, or a substituted or unsubstituted heterocycle of 2 to 30 ring-forming carbon atoms, L₁₁ to L₁₃ may each independently be a direct linkage,

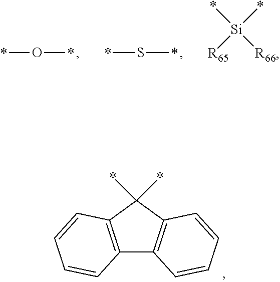

a substituted or unsubstituted alkylene group of 1 to 20 carbon atoms, a substituted or unsubstituted arylene group of 6 to 30 ring-forming carbon atoms, or a substituted or unsubstituted heteroarylene group of 2 to 30 ring-forming carbon atoms, b1 to b3 may each independently be 0 or 1, R₆₁ to R₆₆ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring, and d1 to d4 may each independently be an integer of 0 to 4.

One or more embodiments of the present disclosure provide a fused polycyclic compound represented by Formula 1.

### BRIEF DESCRIPTION OF THE DRAWINGS

The accompanying drawings are included to provide a further understanding of the present disclosure and are incorporated in and constitute a part of this specification. The drawings illustrate embodiments of the present disclosure and, together with the description, serve to explain principles of the present disclosure. Above and/or other aspects of the present disclosure should become apparent and appreciated from the following description of embodiments taken in conjunction with the accompanying drawings. In the drawings:

FIG. 1 is a plan view of a display apparatus according to one or more embodiments of the present disclosure;

FIG. 2 is a cross-sectional view of a display apparatus according to one or more embodiments of the present disclosure;

FIG. 3 is a cross-sectional view schematically showing a light emitting device according to one or more embodiments of the present disclosure;

FIG. 4 is a cross-sectional view schematically showing a light emitting device according to one or more embodiments of the present disclosure;

FIG. 5 is a cross-sectional view schematically showing a light emitting device according to one or more embodiments of the present disclosure;

FIG. 6 is a cross-sectional view schematically showing a light emitting device according to one or more embodiments of the present disclosure;

FIG. 7 and FIG. 8 are cross-sectional views of display apparatuses according to one or more embodiments of the present disclosure;

FIG. 9 is a cross-sectional view showing a display apparatus according to one or more embodiments of the present disclosure;

FIG. 10 is a cross-sectional view showing a display apparatus according to one or more embodiments of the present disclosure; and

FIG. 11 is a diagram showing a vehicle including a display apparatus according to one or more embodiments of the present disclosure.

### DETAILED DESCRIPTION

The present disclosure may have one or more suitable modifications and may be embodied in different forms, and example embodiments will be explained in more detail with reference to the accompany drawings. The present disclosure may, however, be embodied in different forms and should not be construed as limited to the embodiments set forth herein. Rather, all modifications, equivalents, and substituents which are included in the spirit and technical scope of the present disclosure should be included in the present disclosure.

Like reference numerals refer to like elements throughout the present disclosure, and duplicative descriptions thereof may not be provided for conciseness. In the drawings, the dimensions of structures maybe exaggerated for clarity of illustration. It will be understood that, although the terms “first,” “second,” “third,” etc. may be utilized herein to describe one or more suitable elements, these elements should not be limited by these terms. These terms are only utilized to distinguish one element from another element. Thus, a first element could be termed a second element without departing from the teachings of the present disclosure. Similarly, a second element could be termed a first element. As utilized herein, the singular forms are intended to include the plural forms as well, unless the context clearly indicates otherwise.

In the present disclosure, it will be further understood that the terms “comprise(s)/include(s),” “have(has)/having,” and/or “comprising/including,” when utilized in the present disclosure, specify the presence of stated features, numerals, steps, operations, elements, parts, or the combination thereof, but do not preclude the presence or addition of one or more other features, numerals, steps, operations, elements, parts, or the combination thereof.

In the present disclosure, when a layer, a film, a region, a plate, etc. is referred to as being “on” or “above” another part, it can be “directly on” the other part, or intervening layers may also be present. In contrast, when a layer, a film, a region, a plate, etc. is referred to as being “under” or “below” another part, it can be “directly under” the other part, or intervening layers may also be present. Also, when an element is referred to as being disposed “on” another element, it can be disposed under the other element. As used herein, the terms “and,” “or,” and “and/or” may include any and all combinations of one or more of the associated listed items. Expressions such as “at least one of,” “one of,” and “selected from,” when preceding a list of elements, modify the entire list of elements and do not modify the individual elements of the list. For example, “at least one of a, b, or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof. The “/” utilized herein may be interpreted as “and” or as “or” depending on the situation.

In the present disclosure, the term “substituted or unsubstituted” corresponds to substituted or unsubstituted with at least one substituent selected from the group consisting of deuterium, a halogen, a cyano group, a nitro group, an amino group, a silyl group, an oxy group, a thiol group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In some embodiments, each of the exemplified substituents may be substituted or unsubstituted. For example, a biphenyl group may be interpreted as an aryl group or a phenyl group substituted with a phenyl group.

In the present disclosure, the term “forming a ring via the combination with an adjacent group” or the similar may refer to forming a substituted or unsubstituted hydrocarbon ring, or a substituted or unsubstituted heterocycle via the combination with an adjacent group. The hydrocarbon ring may include an aliphatic hydrocarbon ring and/or an aromatic hydrocarbon ring. The heterocycle may include an aliphatic heterocycle and/or an aromatic heterocycle. The hydrocarbon ring and the heterocycle may be monocycles or polycycles. In some embodiments, the ring formed via the combination with an adjacent group may be combined with another ring to form a spiro structure.

In the present disclosure, the term “adjacent group” may refer to a substituent substituted for an atom which is directly combined with an atom substituted with a corresponding substituent, another substituent substituted for an atom which is substituted with a corresponding substituent, or a substituent sterically positioned at the nearest position to a corresponding substituent. For example, in 1,2-dimethylbenzene, two methyl groups thereof may be interpreted as “adjacent groups” to each other, and in 1,1-diethylcyclopentene, two ethyl groups thereof may be interpreted as “adjacent groups” to each other. In some embodiments, in 4,5-dimethylphenanthrene, two methyl groups thereof may be interpreted as “adjacent groups” to each other.

In the present disclosure, a halogen may be fluorine, chlorine, bromine, or iodine.

In the present disclosure, an alkyl group may be a linear or branched type or kind. The carbon number of the alkyl group may be 1 to 50, 1 to 30, 1 to 20, 1 to 10, or 1 to 6. Examples of the alkyl group may include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, 1-methylpentyl, 3-methylpentyl, 2-ethylpentyl, 4-methyl-2-pentyl, n-hexyl, 1-methylhexyl, 2-ethylhexyl, 2-butylhexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-⁻ group, an isobornyl group, a bicycloheptyl group, etc., without limitation.

In the present disclosure, an alkenyl group may refer to a hydrocarbon group including one or more carbon-carbon double bonds in the middle or at the terminal of an alkyl group having a carbon number of 2 or more. The alkenyl group may be a linear chain or a branched chain. The carbon number of the alkenyl is not specifically limited, for example, may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styrylvinyl group, etc., without limitation.

In the present disclosure, an alkynyl group may refer to a hydrocarbon group including one or more carbon-carbon triple bonds in the middle or at the terminal of an alkyl group having a carbon number of 2 or more. The alkynyl group may be a linear chain or a branched chain. The carbon number of the alkynyl group is not specifically limited, for example, may be 2 to 30, 2 to 20, or 2 to 10. Examples of the alkynyl group may include an ethynyl group, a propynyl group, etc., without limitation.

In the present disclosure, a hydrocarbon ring group may refer to an optional functional group or substituent derived from an aliphatic hydrocarbon ring. The hydrocarbon ring group may be a saturated hydrocarbon ring group of 5 to 20 ring-forming carbon atoms.

In the present disclosure, an aryl group may refer to an optional functional group or substituent derived from an aromatic hydrocarbon ring. The aryl group may be a monocyclic aryl group or a polycyclic aryl group. The number of carbon atoms forming rings in the aryl group may be 6 to 30, 6 to 20, or 6 to 15. Examples of the aryl group may include phenyl, naphthyl, fluorenyl, anthracenyl, phenanthryl, biphenyl, terphenyl, quaterphenyl, quinquephenyl, sexiphenyl, triphenylenyl, pyrenyl, benzofluoranthenyl, chrysenyl, etc., without limitation.

In the present disclosure, a fluorenyl group may be substituted, and two substituents may be combined with each other to form a spiro structure. Examples of a substituted fluorenyl group are as follows, but embodiments of the present disclosure are not limited thereto.

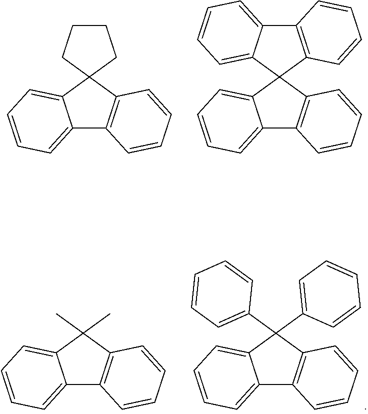

In the present disclosure, a heterocyclic group may refer to an optional functional group or substituent derived from a ring including one or more selected from among B, O, N, P, Si, and S as heteroatoms. The heterocyclic group may include an aliphatic heterocyclic group and/or an aromatic heterocyclic group. The aromatic heterocyclic group may be a heteroaryl group. The aliphatic heterocyclic group and the aromatic heterocyclic group may be a monocycle or a polycycle.

In the present disclosure, a heterocyclic group may include one or more selected from among B, O, N, P, Si and S as heteroatoms. When the heterocyclic group includes two or more heteroatoms, the two or more heteroatoms may be the same or different. The heterocyclic group may be a monocyclic heterocyclic group or a polycyclic heterocyclic group, and has the concept including a heteroaryl group. The number of carbon atoms forming rings of the heterocyclic group may be 2 to 30, 2 to 20, and 2 to 10.

In the present disclosure, an aliphatic heterocyclic group may include one or more selected from among B, O, N, P, Si, and S as heteroatoms. The number of ring-forming carbon atoms of the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., without limitation.

In the present disclosure, a heteroaryl group may include one or more selected from among B, O, N, P, Si, and S as heteroatoms. When the heteroaryl group includes two or more heteroatoms, the two or more heteroatoms may be the same or different. The heteroaryl group may be a monocyclic heterocyclic group or polycyclic heterocyclic group. The number of carbon atoms forming rings of the heteroaryl group may be 2 to 30, 2 to 20, or 2 to 10. Examples of the heteroaryl group may include thiophene, furan, pyrrole, imidazole, pyridine, bipyridine, pyrimidine, triazine, triazole, acridyl, pyridazine, pyrazinyl, quinoline, quinazoline, quinoxaline, phenoxazine, phthalazine, pyrido pyridine, pyrido pyrazine, pyrazino pyrazine, isoquinoline, indole, carbazole, N-arylcarbazole, N-heteroarylcarbazole, N-alkylcarbazole, benzoxazole, benzimidazole, benzothiazole, benzocarbazole, benzothiophene, dibenzothiophene, thienothiophene, benzofuran, phenanthroline, thiazole, isooxazole, oxazole, oxadiazole, thiadiazole, phenothiazine, dibenzosilole, dibenzofuran, etc., without limitation.

In the present disclosure, the same explanation on the above-described aryl group may be applied to an arylene group except that the arylene group is a divalent group. The same explanation on the above-described heteroaryl group may be applied to a heteroarylene group except that the heteroarylene group is a divalent group.

In the present disclosure, a silyl group may include an alkyl silyl group and/or an aryl silyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., without limitation.

In the present disclosure, the carbon number of a carbonyl group is not specifically limited, for example, the carbon number thereof may be 1 to 40, 1 to 30, or 1 to 20. For example, the carbonyl group may have the following structures, but embodiments of the present disclosure are not limited thereto.

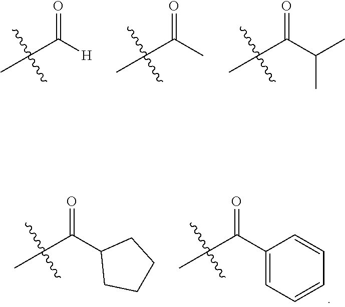

In the present disclosure, the carbon number of a sulfinyl group or a sulfonyl group is not specifically limited, for example, may be 1 to 30. The sulfinyl group may include an alkyl sulfinyl group and/or an aryl sulfinyl group. The sulfonyl group may include an alkyl sulfonyl group and/or an aryl sulfonyl group.

In the present disclosure, a thio group may include an alkyl thio group and/or an aryl thio group. The thio group may refer to the above-defined alkyl group or aryl group combined with a sulfur atom. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., without limitation.

In the present disclosure, an oxy group may refer to the above-defined alkyl group or aryl group which is combined with an oxygen atom. The oxy group may include an alkoxy group and/or an aryl oxy group. The alkoxy group may be a linear, branched, or cyclic chain. The carbon number of the alkoxy group is not specifically limited but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, phenoxy, benzyloxy, etc. However, embodiments of the present disclosure are not limited thereto.

In the present disclosure, a boron group may refer to the above-defined alkyl group or aryl group, combined with a boron atom. The boron group may include an alkyl boron group and/or an aryl boron group. Examples of the boron group may include a dimethylboron group, a diethylboron group, a t-butylmethylboron group, a diphenylboron group, a phenylboron group, etc., without limitation.

In the present disclosure, an alkenyl group may be a linear chain or a branched chain. The carbon number thereof is not specifically limited, for example, may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styrylvinyl group, etc., without limitation.

In the present disclosure, the carbon number of an amine group is not specifically limited, for example, may be 1 to 30. The amine group may include an alkyl amine group and/or an aryl amine group. Examples of the amine group may include a methylamine group, a dimethylamine group, a phenylamine group, a diphenylamine group, a naphthylamine group, a 9-methyl-anthracenylamine group, a triphenylamine group, etc., without limitation.

In the present disclosure, alkyl groups in an alkylthiol group, alkylsulfoxy group, alkylaryl group, alkylamino group, alkyl boron group, alkyl silyl group, and alkyl amine group may be the same as the examples of the above-described alkyl group.

In the present disclosure, aryl groups in an aryloxy group, arylthio group, arylsulfoxy group, arylamino group, aryl boron group, aryl silyl group, and aryl amine group may be the same as the examples of the above-described aryl group.

In the present disclosure, a direct linkage may refer to a single bond.

In the present disclosure,

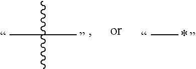

may refer to a position to be connected.

Hereinafter, embodiments of the present disclosure will be explained in more detail referring to the drawings.

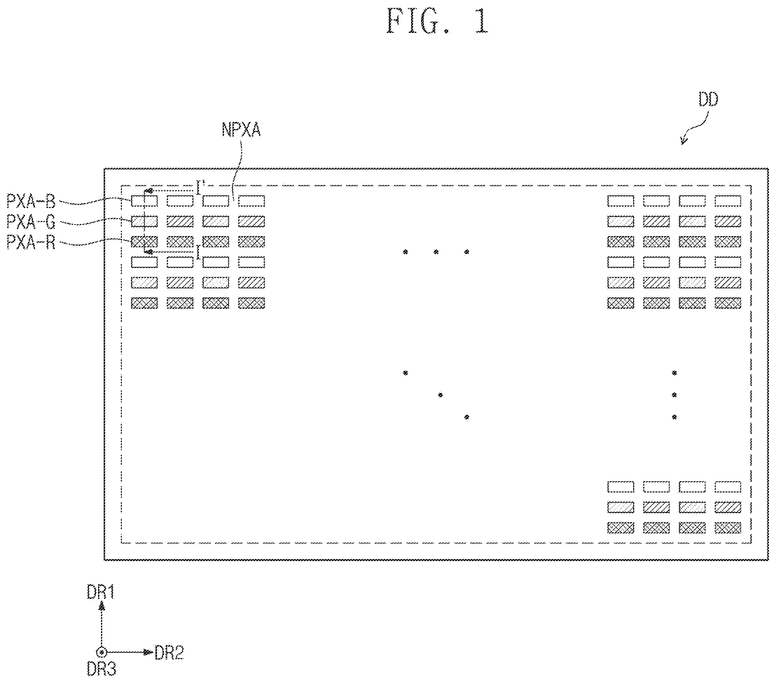

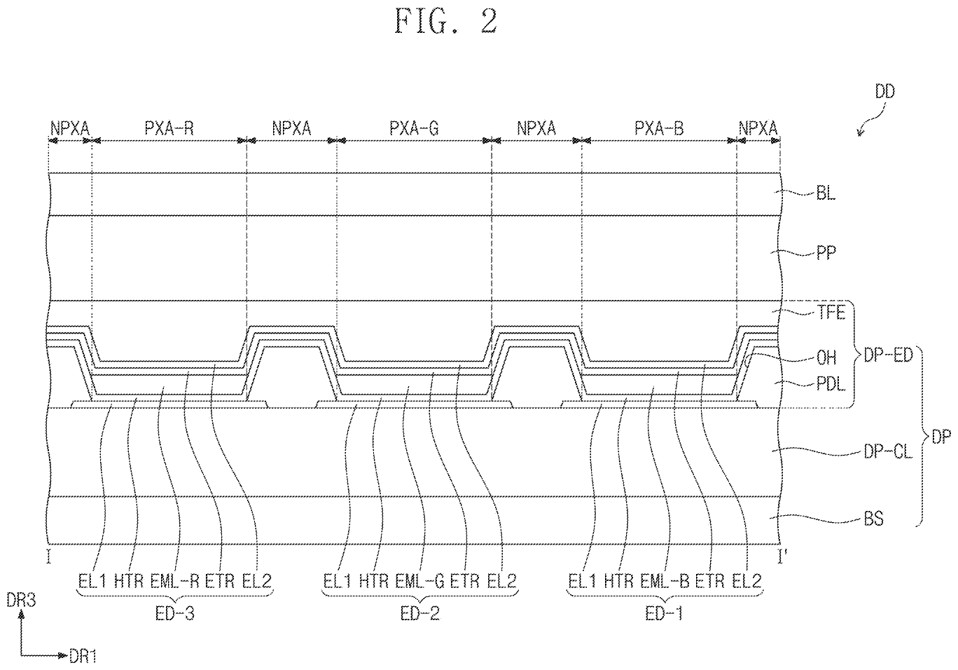

FIG. 1 is a plan view showing a display apparatus DD according to one or more embodiments of the present disclosure. FIG. 2 is a cross-sectional view of a display apparatus DD according to one or more embodiments of the present disclosure. FIG. 2 is a cross-sectional view showing a part corresponding to line I-I′ in FIG. 1.

The display apparatus DD may include a display panel DP and an optical layer PP disposed on the display panel DP. The display panel DP may include light emitting devices ED-1, ED-2, and ED-3. The display apparatus DD may include multiple light emitting devices ED-1, ED-2, and ED-3. The optical layer PP may be disposed on the display panel DP to control reflected light by external light at the display panel DP. The optical layer PP may include, for example, a polarization layer and/or a color filter layer. In some embodiments, different from the drawings, the optical layer PP may not be provided in the display apparatus DD.

On the optical layer PP, a base substrate BL may be disposed or provided. The base substrate BL may be a member providing a base surface where the optical layer PP is disposed. The base substrate BL may be a glass substrate, a metal substrate, a plastic substrate, etc. However, embodiments of the present disclosure are not limited thereto, and the base substrate BL may be an inorganic layer, an organic layer, or a composite material layer. In some embodiments, different from the drawings, the base substrate BL may not be provided.

The display apparatus DD according to one or more embodiments may further include a plugging layer. The plugging layer may be disposed between a display device layer DP-ED and a base substrate BL. The plugging layer may be an organic layer. The plugging layer may include at least one selected from among an acrylic resin, a silicon-based resin, and an epoxy-based resin.

The display panel DP may include a base layer BS, a circuit layer DP-CL provided on the base layer BS, and a display device layer DP-ED. The display device layer DP-ED may include a pixel definition layer PDL, light emitting devices ED-1, ED-2, and ED-3 each disposed in the pixel definition layer PDL, and an encapsulating layer TFE disposed on the light emitting devices ED-1, ED-2, and ED-3.

The base layer BS may be a member providing a base surface on which the display device layer DP-ED is disposed. The base layer BS may be a glass substrate, a metal substrate, a plastic substrate, etc. However, embodiments of the present disclosure are not limited thereto, and the base layer BS may be an inorganic layer, an organic layer, or a composite material layer.

In one or more embodiments, the circuit layer DP-CL may be disposed on the base layer BS, and the circuit layer DP-CL may include multiple transistors. Each of the transistors may include a control electrode, an input electrode, and an output electrode. For example, in some embodiments, the circuit layer DP-CL may include switching transistors and driving transistors for driving the light emitting devices ED-1, ED-2, and ED-3 of the display device layer DP-ED.

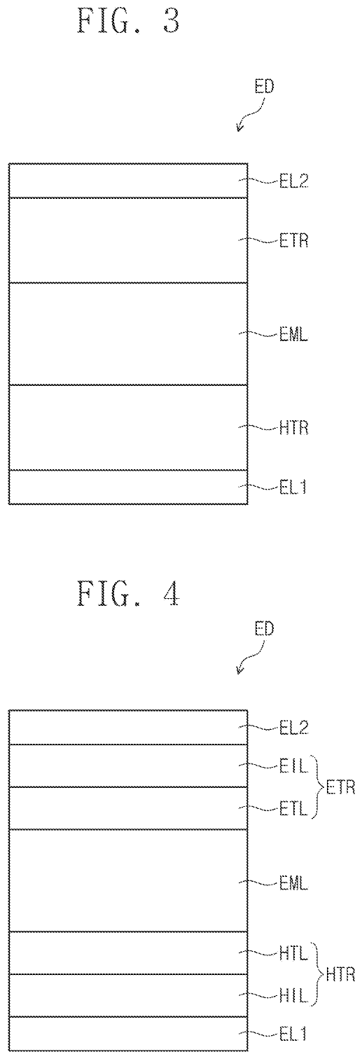

Each of the light emitting devices ED-1, ED-2, and ED-3 may have the structures of light emitting devices ED of embodiments according to FIG. 3 to FIG. 6, which will be explained later in more detail. Each of the light emitting devices ED-1, ED-2, and ED-3 may include a first electrode EL1, a hole transport region HTR, a respective one of the emission layers EML-R, EML-G, and EML-B, an electron transport region ETR, and a second electrode EL2.

In FIG. 2, shown is an embodiment where the respective emission layers EML-R, EML-G, and EML-B of light emitting devices ED-1, ED-2, and ED-3, which are in opening portions OH defined in a pixel definition layer PDL, are disposed, and a hole transport region HTR, an electron transport region ETR, and a second electrode EL2 are provided as common layers in all light emitting devices ED-1, ED-2, and ED-3. However, embodiments of the present disclosure are not limited thereto. In one or more embodiments, the hole transport region HTR and the electron transport region ETR may be patterned and provided in the opening portions OH defined in the pixel definition layer PDL. For example, in some embodiments, the hole transport region HTR, the respective emission layers EML-R, EML-G, and EML-B, and the electron transport region ETR of the light emitting devices ED-1, ED-2, and ED-3 may be provided and patterned by an ink jet printing method.

The encapsulating layer TFE may cover the light emitting devices ED-1, ED-2, and ED-3. The encapsulating layer TFE may encapsulate a display device layer DP-ED. The encapsulating layer TFE may be a thin film encapsulating layer. The encapsulating layer TFE may be one layer or a stacked layer of multiple layers. The encapsulating layer TFE may include at least one insulating layer. In some embodiments, the encapsulating layer TFE may include at least one inorganic layer (hereinafter, encapsulating inorganic layer). In some embodiments, the encapsulating layer TFE may include at least one organic layer (hereinafter, encapsulating organic layer) and at least one encapsulating inorganic layer.

The encapsulating inorganic layer protects the display device layer DP-ED from moisture/oxygen, and the encapsulating organic layer protects the display device layer DP-ED from foreign materials such as dust particles. The encapsulating inorganic layer may include silicon nitride, silicon oxy nitride, silicon oxide, titanium oxide, and/or aluminum oxide, without specific limitation. The encapsulating organic layer may include an acrylic compound, an epoxy-based compound, etc. In one or more embodiments, the encapsulating organic layer may include a photopolymerizable organic material, without specific limitation.

The encapsulating layer TFE may be disposed on the second electrode EL2 and may be disposed while filling the opening portion OH.

Referring to FIG. 1 and FIG. 2, the display apparatus DD may include a non-luminous area NPXA and luminous areas PXA-R, PXA-G, and PXA-B. The luminous areas PXA-R, PXA-G, and PXA-B may be areas emitting light produced from the light emitting devices ED-1, ED-2, and ED-3, respectively. The luminous areas PXA-R, PXA-G, and PXA-B may be separated or apart from each other on a plane.

The luminous areas PXA-R, PXA-G, and PXA-B may be areas separated by the pixel definition layer PDL. The non-luminous areas NPXA may be areas between neighboring luminous areas PXA-R, PXA-G, and PXA-B and may be areas corresponding to the pixel definition layer PDL. In some embodiments of the present disclosure, each of the luminous areas PXA-R, PXA-G, and PXA-B may correspond to each pixel. The pixel definition layer PDL may divide the light emitting devices ED-1, ED-2, and ED-3. The respective emission layers EML-R, EML-G, and EML-B of the light emitting devices ED-1, ED-2, and ED-3 may be disposed and divided in the opening portions OH defined in the pixel definition layer PDL.

The luminous areas PXA-R, PXA-G, and PXA-B may be divided into multiple groups according to the color of light produced from the light emitting devices ED-1, ED-2, and ED-3. In the display apparatus DD of one or more embodiments, shown in FIG. 1 and FIG. 2, three luminous areas PXA-R, PXA-G, and PXA-B emitting red light, green light, and blue light, respectively, are illustrated as an example. For example, in one or more embodiments, the display apparatus DD may include a red luminous area PXA-R, a green luminous area PXA-G, and a blue luminous area PXA-B, which are separated or apart from each other.

In the display apparatus DD according to one or more embodiments, multiple light emitting devices ED-1, ED-2, and ED-3 may be to emit light having different wavelength regions. For example, in some embodiments, the display apparatus DD may include a first light emitting device ED-1 to emit red light, a second light emitting device ED-2 to emit green light, and a third light emitting device ED-3 to emit blue light. For example, in one or more embodiments, each of the red luminous area PXA-R, the green luminous area PXA-G, and the blue luminous area PXA-B of the display apparatus DD may respectively correspond to the first light emitting device ED-1, the second light emitting device ED-2, and the third light emitting device ED-3.

However, embodiments of the present disclosure are not limited thereto, and the first to third light emitting devices ED-1, ED-2, and ED-3 may be to emit light in substantially the same wavelength region, or at least one thereof may be to emit light in a different wavelength region. For example, in some embodiments, all the first to third light emitting devices ED-1, ED-2, and ED-3 may be to emit blue light.

The luminous areas PXA-R, PXA-G, and PXA-B in the display apparatus DD according to one or more embodiments may be arranged in a stripe shape. Referring to FIG. 1, multiple red luminous areas PXA-R may be arranged with each other along a second direction axis DR2, multiple green luminous areas PXA-G may be arranged with each other along the second direction axis DR2, and multiple blue luminous areas PXA-B may be arranged with each other along the second direction axis DR2. In some embodiments, the red luminous area PXA-R, the green luminous area PXA-G, and the blue luminous area PXA-B may be arranged by turns along a first direction axis DR1.

In FIG. 1 and FIG. 2, the areas of the luminous areas PXA-R, PXA-G, and PXA-B are shown similar, but embodiments of the present disclosure are not limited thereto. The areas of the luminous areas PXA-R, PXA-G, and PXA-B may be different from each other according to the wavelength region of light emitted. The areas of the luminous areas PXA-R, PXA-G, and PXA-B may refer to areas on a plane defined by the first direction axis DR1 and the second direction axis DR2 (e.g., the areas in a plan view).

In some embodiments, the arrangement type or kind of the luminous areas PXA-R, PXA-G, and PXA-B is not limited to the configuration shown in FIG. 1, and the arrangement order of the red luminous areas PXA-R, the green luminous areas PXA-G, and the blue luminous areas PXA-B may be provided in one or more suitable combinations according to the properties of display quality required for the display apparatus DD. For example, in one or more embodiments, the arrangement type or kind of the luminous areas PXA-R, PXA-G and PXA-B may be a pentile (PENTILE®) arrangement type or kind (for example, an RGBG matrix, an RGBG structure, or an RGBG matrix structure), or a diamond (Diamond Pixel™) arrangement type or kind (e.g., a display (e.g., an OLED display) containing red, blue, and green (RGB) light-emitting regions arranged in the shape of diamonds). PENTILE® is a duly registered trademark of Samsung Display Co., Ltd. Diamond Pixel TM is a trademark of Samsung Display Co., Ltd.

In some embodiments, the areas of the luminous areas PXA-R, PXA-G, and PXA-B may be different from each other. For example, in some embodiments, the area of the green luminous area PXA-G may be smaller than the area of the blue luminous area PXA-B, but embodiments of the present disclosure are not limited thereto.

Hereinafter, FIG. 3 to FIG. 6 are cross-sectional views schematically showing light emitting devices according to one or more embodiments of the present disclosure. The light emitting device ED of one or more embodiments shown in FIG. 3 may include a first electrode EL1, a hole transport region HTR, an emission layer EML, an electron transport region ETR, and a second electrode EL2 stacked in order (e.g., in the stated order).

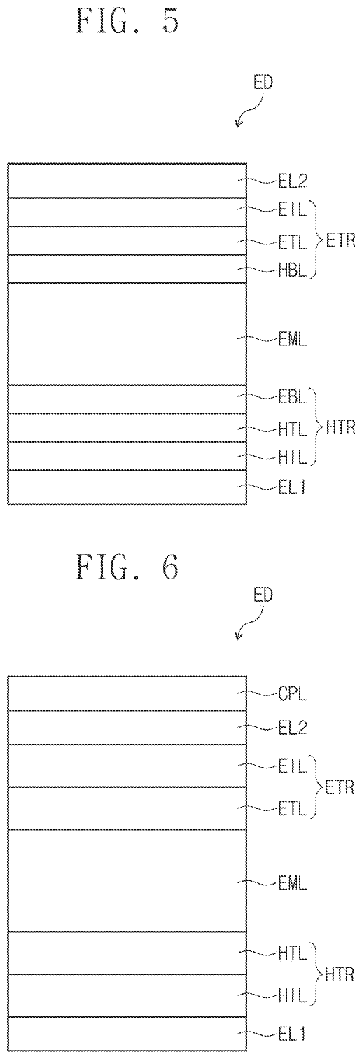

Compared with FIG. 3, FIG. 4 shows the cross-sectional view of a light emitting device ED according to one or more embodiments, wherein a hole transport region HTR may include a hole injection layer HIL and a hole transport layer HTL, and an electron transport region ETR may include an electron injection layer EIL and an electron transport layer ETL. Compared with FIG. 3, FIG. 5 shows the cross-sectional view of a light emitting device ED according to one or more embodiments, wherein a hole transport region HTR may include a hole injection layer HIL, a hole transport layer HTL, and an electron blocking layer EBL, and an electron transport region ETR may include an electron injection layer EIL, an electron transport layer ETL, and a hole blocking layer HBL. Compared with FIG. 4, FIG. 6 shows the cross-sectional view of a light emitting device ED according to one or more embodiments, including a capping layer CPL disposed on the second electrode EL2.

The first electrode EL1 has conductivity (e.g., is a conductor). The first electrode EL1 may be formed utilizing a metal material, a metal alloy, and/or a conductive compound. The first electrode EU may be an anode or a cathode. However, embodiments of the present disclosure are not limited thereto. In some embodiments, the first electrode EL1 may be a pixel electrode. The first electrode EL1 may be a transmissive electrode, a transflective electrode, or a reflective electrode. The first electrode EL1 may include at least one selected from silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium (In), tin (Sn), zinc (Zn), compounds of two or more selected therefrom, mixtures of two or more selected therefrom, and/or oxides thereof.

When the first electrode EL1 is a transmissive electrode, the first electrode EL1 may include a transparent metal oxide such as indium tin oxide (ITO), indium zinc oxide (IZO), zinc oxide (ZnO), and/or indium tin zinc oxide (ITZO). When the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (stacked structure of LiF and Ca), LiF/AI (stacked structure of LiF and Al), Mo, Ti, W, compound(s) thereof, or mixture(s) thereof (for example, a mixture of Ag and Mg). Also, in one or more embodiments, the first electrode EL1 may have a structure including multiple layers including a reflective layer or a transflective layer formed utilizing the above materials, and a transmissive conductive layer formed utilizing ITO, IZO, ZnO, or ITZO. For example, in some embodiments, the first electrode EL1 may include a three-layer structure of ITO/Ag/ITO. However, embodiments of the present disclosure are not limited thereto. The first electrode EU may include the above-described metal materials, combinations of two or more metal materials selected from the above-described metal materials, and/or oxides of the above-described metal materials. The thickness of the first electrode EL1 may be from about 700 Å to about 10,000 Å. For example, in one or more embodiments, the thickness of the first electrode EL1 may be from about 1,000 Å to about 3,000 Å.

The hole transport region HTR may be provided on the first electrode EL1. The hole transport region HTR may include at least one selected from among a hole injection layer HIL, a hole transport layer HTL, a buffer layer or an emission auxiliary layer, and an electron blocking layer EBL. The thickness of the hole transport region HTR may be, for example, from about 50 Å to about 15,000 Å.

The hole transport region HTR may have a single layer formed utilizing a single material, a single layer formed utilizing multiple different materials, or a multilayer structure including multiple layers formed utilizing multiple different materials.

For example, in one or more embodiments, the hole transport region HTR may have a structure of a single layer of a hole injection layer HIL or a hole transport layer HTL, and may have a structure of a single layer formed utilizing a hole injection material and a hole transport material. In some embodiments, the hole transport region HTR may have a structure of a single layer formed utilizing multiple different materials, or a structure stacked from the first electrode EL1 of hole injection layer HIL/hole transport layer HTL, hole injection layer HIL/hole transport layer HTL/buffer layer, hole injection layer HIL/buffer layer, hole transport layer HTL/buffer layer, or hole injection layer HIL/hole transport layer HTL/electron blocking layer EBL, without limitation.

The hole transport region HTR may be formed utilizing one or more suitable methods such as a vacuum deposition method, a spin coating method, a casting method, a Langmuir-Blodgett (LB) method, an inkjet printing method, a laser printing method, and/or a laser induced thermal imaging (LITI) method.

The hole transport region HTR may include a compound represented by Formula H-2.

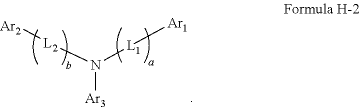

In Formula H-2, L₁ and L₂ may each independently be a direct linkage, a substituted or unsubstituted arylene group of 6 to 30 ring-forming carbon atoms, or a substituted or unsubstituted heteroarylene group of 2 to 30 ring-forming carbon atoms. “a” and “b” may each independently be an integer of 0 to 10. In some embodiments, when “a” or “b” is an integer of 2 or more, multiple L₁(s) and L₂(s) may each independently be a substituted or unsubstituted arylene group of 6 to 30 ring-forming carbon atoms, or a substituted or unsubstituted heteroarylene group of 2 to 30 ring-forming carbon atoms.

In Formula H-2, Ar₁ and Ar₂ may each independently be a substituted or unsubstituted aryl group of 6 to 30 ring-forming carbon atoms, or a substituted or unsubstituted heteroaryl group of 2 to 30 ring-forming carbon atoms. In some embodiments, in Formula H-2, Ar₃ may be a substituted or unsubstituted aryl group of 6 to 30 ring-forming carbon atoms, or a substituted or unsubstituted heteroaryl group of 2 to 30 ring-forming carbon atoms.

The compound represented by Formula H-2 may be a monoamine compound. In some embodiments, the compound represented by Formula H-2 may be a diamine compound in which at least one selected from among Ar₁ to Ar₃ may include an amine group as a substituent. In some embodiments, the compound represented by Formula H-2 may be a carbazole-based compound in which at least one selected from among Ar₁ and Ar₂ may include a substituted or unsubstituted carbazole group, or a fluorene-based compound in which at least one selected from among Ar₁ and Ar₂ may include a substituted or unsubstituted fluorene group.

The compound represented by Formula H-2 may be represented by any one selected from among compounds in Compound Group H. However, the compounds shown in Compound Group H are only mere examples, and the compound represented by Formula H-2 is not limited to the compounds represented in Compound Group H.

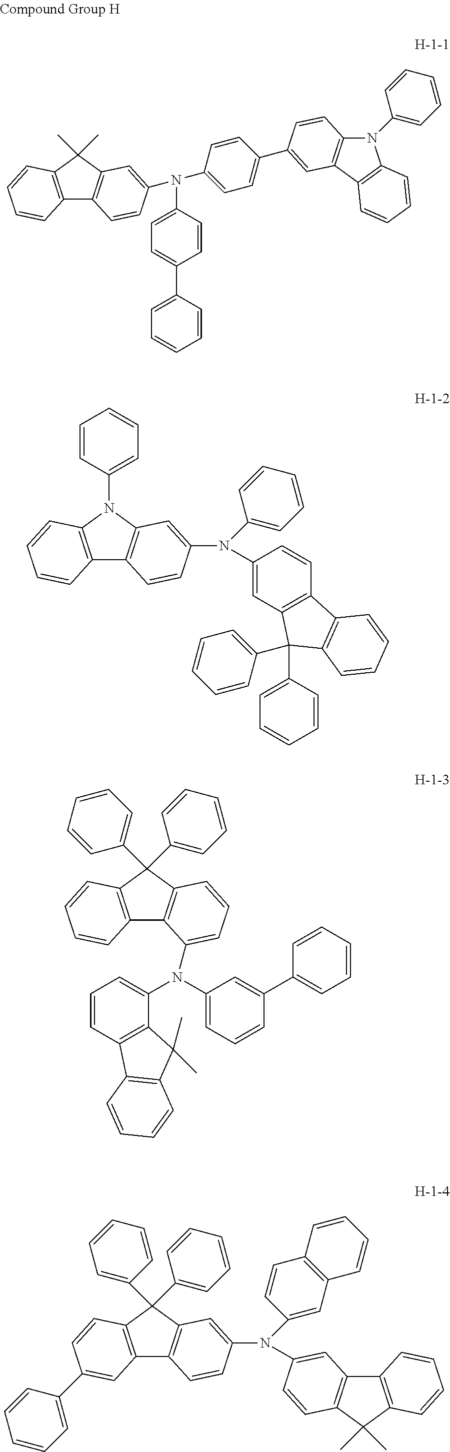 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

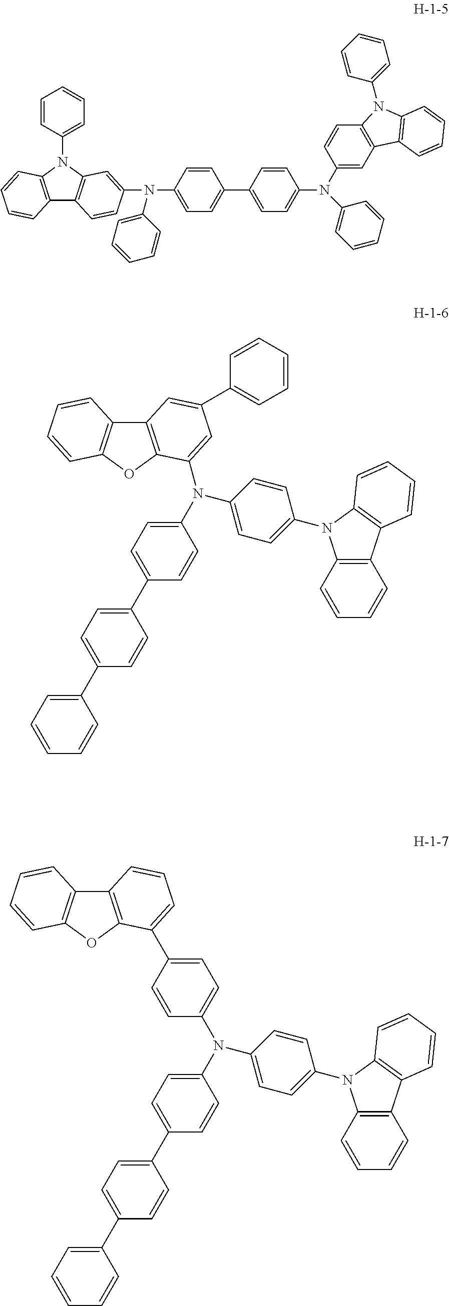 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

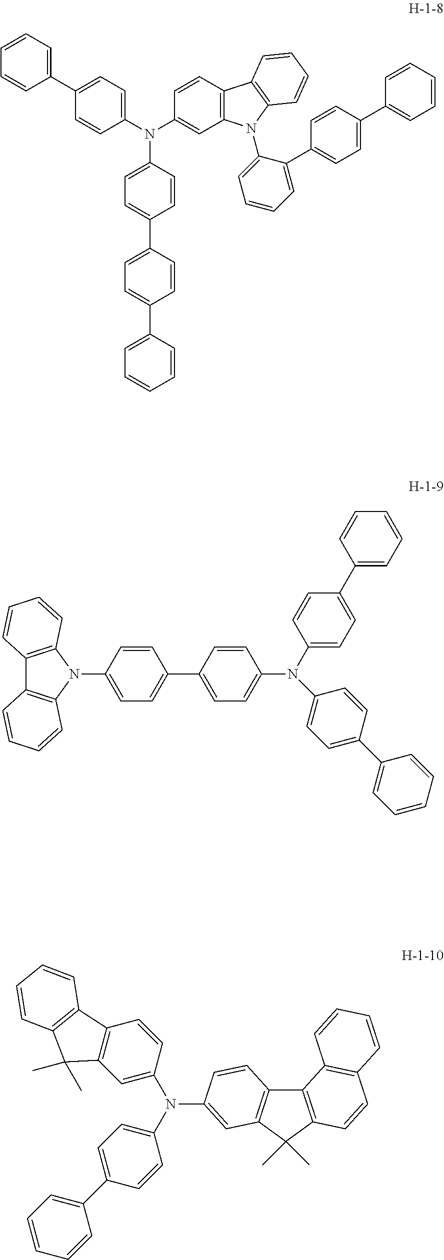 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

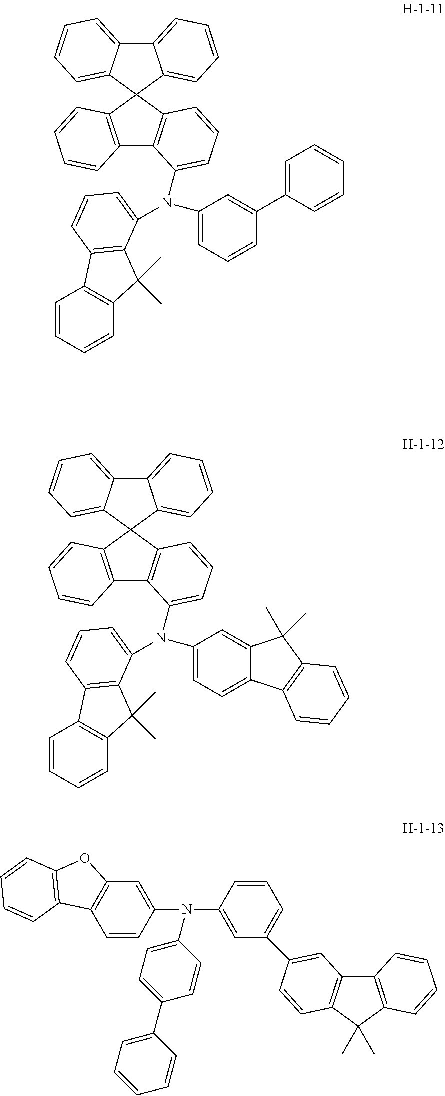 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

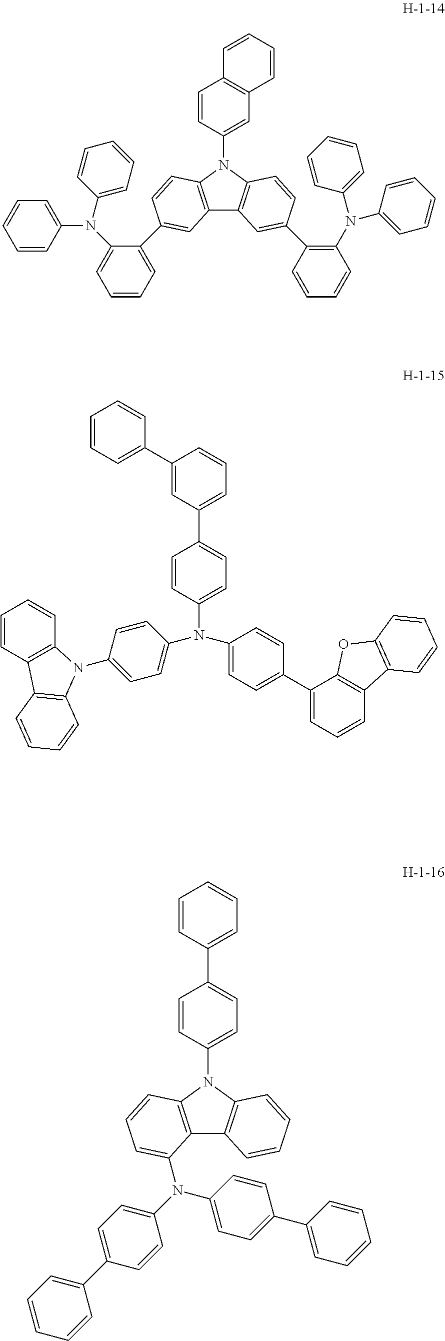 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

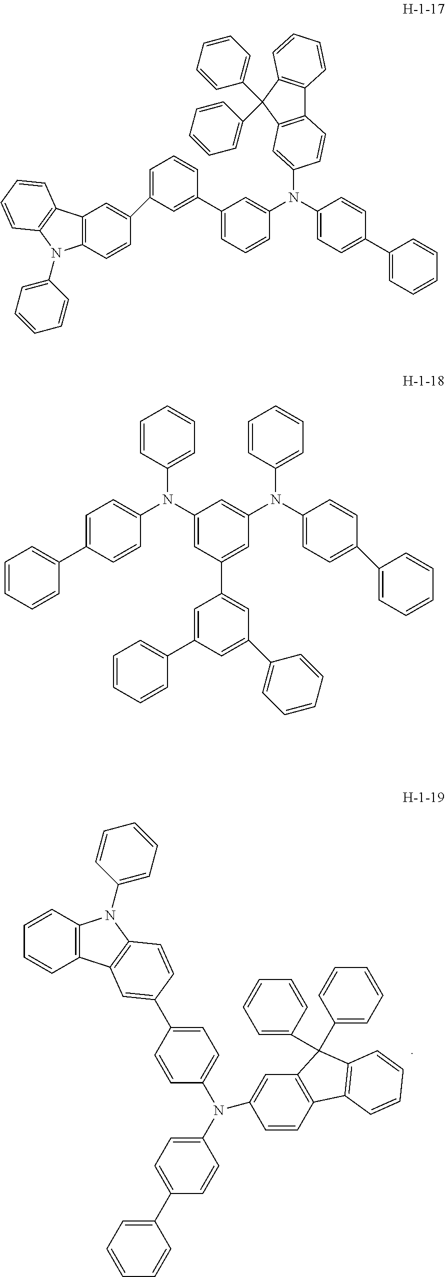 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

In one or more embodiments, the hole transport region HTR may include at least one selected from a phthalocyanine compound (such as copper phthalocyanine), N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(1-naphthalen-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], and dipyrazino[2,3-f:2′,3′-h]quinoxaline-2,3,6,7,10,11-hexacarbonitrile (HAT-CN).

In one or more embodiments, the hole transport region HTR may include one or more carbazole derivatives (such as N-phenyl carbazole and/or polyvinyl carbazole), one or more fluorene-based derivatives, N,N′-bis(3-methylphenyl)-N,N′-diphenyl-[1,1′-biphenyl]-4,4′-diamine (TPD), one or more triphenylamine-based derivatives (such as 4,4′,4″-tris(N-carbazolyl)triphenylamine (TCTA)), N,N′-di(1-naphthalen-1-yl)-N,N′-diphenyl-benzidine (NPB), 4,4′-cyclohexylidene bis[N,N-bis(4-methylphenyl)benzenamine](TAPC), 4,4′-bis[N,N′-(3-tolyl)amino]-3,3′-dimethylbiphenyl (HMTPD), 1,3-bis(N-carbazolyl)benzene (mCP), etc.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-Abenzene (mDCP), etc.

The hole transport region HTR may include at least one of the above-described compounds of the hole transport region in at least one selected from among the hole injection layer HIL, hole transport layer HTL, and electron blocking layer EBL.

The thickness of the hole transport region HTR may be from about 100 Å to about 10,000 Å, for example, from about 100 Å to about 5,000 Å. When the hole transport region HTR includes a hole injection layer HIL, the thickness of the hole injection region HIL may be, for example, from about 30 Å to about 1,000 Å. When the hole transport region HTR includes a hole transport layer HTL, the thickness of the hole transport layer HTL may be from about 30 Å to about 1,000 Å. For example, when the hole transport region HTR includes an electron blocking layer, the thickness of the electron blocking layer EBL may be from about 10 Å to about 1,000 Å. When the thicknesses of the hole transport region HTR, the hole injection layer HIL, the hole transport layer HTL, and the electron blocking layer EBL satisfy the above-described ranges, satisfactory hole transport properties may be achieved without a substantial increase in a driving voltage.

In one or more embodiments, the hole transport region HTR may further include a charge generating material to increase conductivity in addition to the above-described materials. The charge generating material may be dispersed uniformly or non-uniformly in the hole transport region HTR. The charge generating material may be, for example, a p-dopant. The p-dopant may include at least one of metal halide compounds, quinone derivatives, metal oxides, or cyano group-containing compounds, without limitation. For example, the p-dopant may include one or more metal halide compounds (such as Cul and RbI), one or more quinone derivatives (such as tetracyanoquinodimethane (TCNQ) and 2,3,5,6-tetrafluoro-7,7′,8,8-tetracyanoquinodimethane (F4-TCNQ)), one or more metal oxides (such as tungsten oxide and molybdenum oxide), one or more cyano group-containing compounds (such as dipyrazino[2,3-f: 2′, 3′-h]quinoxaline-2,3,6,7,10,11-hexacarbonitrile (HATCN) and 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9)), etc., without limitation.

As described above, the hole transport region HTR may further include at least one selected from among a buffer layer and an electron blocking layer EBL in addition to the hole injection layer HIL and the hole transport layer HTL. The buffer layer may compensate resonance distance according to the wavelength of light emitted from an emission layer EML and may increase emission efficiency. As materials included in the buffer layer, materials which may be included in the hole transport region HTR may be utilized. The electron blocking layer EBL may be a layer playing the role of blocking the injection of electrons from an electron transport region ETR to a hole transport region HTR.

The emission layer EML may be provided on the hole transport region HTR. The emission layer EML may have a thickness of, for example, about 100 Å to about 1,000 Å, or about 100 Å to about 300 Å. The emission layer EML may have a single layer formed utilizing a single material, a single layer formed utilizing multiple different materials, or a multilayer structure having multiple layers formed utilizing multiple different materials.

In the light emitting device ED of one or more embodiments, the emission layer EML may include the fused polycyclic compound of one or more embodiments of the present disclosure. In one or more embodiments, the emission layer EML may include the fused polycyclic compound of one or more embodiments as a dopant. The fused polycyclic compound of one or more embodiments may be a dopant material of the emission layer EML. In one or more embodiments of the present disclosure, the fused polycyclic compound of one or more embodiments, which will be explained later, may be referred to as a first compound.

The fused polycyclic compound of one or more embodiments may include a fused structure of multiple aromatic rings via a boron atom, a nitrogen atom, and a carbon atom. For example, the fused polycyclic compound of one or more embodiments may include a fused structure of first to third aromatic rings via a boron atom, a first nitrogen atom, and a first carbon atom. Each of the first to third aromatic rings may be connected to the boron atom, the first aromatic ring and the third aromatic ring may be connected via the first nitrogen atom, and the first aromatic ring and the second aromatic ring may be connected via the first carbon atom. In one or more embodiments of the present disclosure, a boron atom, a first nitrogen atom, and a first carbon atom, and a fused structure formed through first to third aromatic rings fused via the boron atom, the first nitrogen atom, and the first carbon atom may be referred to as a “fused ring core.”

The fused polycyclic compound of one or more embodiments may include a first substituent connected with the fused ring core. The first substituent may include a fourth aromatic ring, a fifth aromatic ring, and a first sub-substituent connecting the fourth aromatic ring and the fifth aromatic ring. In one or more embodiments, the fourth aromatic ring and the fifth aromatic ring may each be hexagonal aromatic rings (e.g., 6-membered aromatic rings). The fourth aromatic ring and the fifth aromatic ring may be connected with each other via the first sub-substituent. The first sub-substituent may be *—O—*, *—S—*, or *—N(R)—*. Here, R may be hydrogen, deuterium, a halogen, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In the fused polycyclic compound of one or more embodiments, the first substituent may be combined with (e.g., bonded to) the first carbon atom of the fused ring core. In one or more embodiments, the fourth aromatic ring and the fifth aromatic ring of the first substituent may be combined with (e.g., bonded to) the first carbon atom of the fused ring core, respectively. In one or more embodiments, the fourth aromatic ring and the fifth aromatic ring may be directly bonded to the first carbon atom, respectively. In one or more embodiments, the fourth aromatic ring may be combined with (e.g., bonded to) the first carbon atom at carbon at an ortho position with respect to the carbon atom connected with the first sub-substituent among the carbon atoms constituting the fourth aromatic ring. In one or more embodiments, the fifth aromatic ring may be combined with (e.g., bonded to) the first carbon atom at carbon at an ortho position with respect to the carbon atom connected with the first sub-substituent among the carbon atoms constituting the fifth aromatic ring. For example, in one or more embodiments, the first substituent may be connected with the first carbon atom via a spiro bond. In one or more embodiments, the first substituent may be represented by Formula S1.

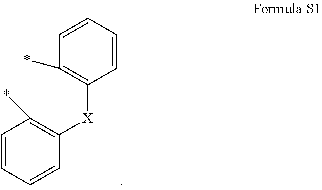

In Formula S1, X may correspond to the above-described first sub-substituent. X may be *—O—*, *—S—*, or *—N(R)—*. Here, the same contents explained in the first substituent may be applied for R. In Formula S1, [symbol] is a position connected with (e.g., bonded to) the first carbon atom of the fused ring core. In some embodiments, for the convenience of explanation, the substituent connected with the fourth aromatic ring and the fifth aromatic ring in Formula S1 is omitted and/or not described. In one or more embodiments, different from Formula S1, the first substituent may have at least one substituent other than a hydrogen.

In one or more embodiments, the fused polycyclic compound of present disclosure may include a second substituent that is a substituent having steric hindrance in a molecular structure. The second substituent may be connected with (e.g., bonded to) the first nitrogen atom constituting the fused ring core in the fused polycyclic compound of one or more embodiments. The second substituent may include a benzene moiety and may be a substituent introducing a substituted or unsubstituted phenyl group to carbon at a specific position in the benzene moiety. For example, in one or more embodiments, the second substituent may include a structure including a benzene moiety and connected with the first nitrogen atom constituting the fused ring core and introducing a substituted or unsubstituted phenyl group to at least one selected from among two ortho positions of the benzene moiety with respect to the first nitrogen atom.

In one or more embodiments, the fused ring compound of the present disclosure may be represented by Formula 1.

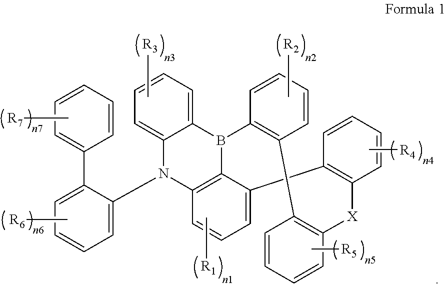

The fused polycyclic compound of one or more embodiments, represented by Formula 1, may include a fused structure of three aromatic rings through one boron atom, one nitrogen atom, and one carbon atom. In one or more embodiments of the present disclosure, in Formula 1, a benzene ring substituted with a substituent represented by R₁ may correspond to (e.g., refer to) the first aromatic ring, a benzene ring substituted with a substituent represented by R₂ may correspond to (e.g., refer to) the second aromatic ring, and a benzene ring substituted with a substituent represented by R₃ may correspond to (e.g., refer to) the third aromatic ring. In Formula 1, a benzene ring substituted with a substituent represented by R₄ may correspond to (e.g., refer to) a fourth aromatic ring, a benzene ring substituted with a substituent represented by R₅ may correspond to (e.g., refer to) a fifth aromatic ring, and X may correspond to (e.g., refer to) the first sub-substituent. In Formula 1, a carbon atom connected with a benzene ring substituted with the substituent represented by R₄ and a benzene ring substituted with the substituent represented by R₅, may correspond to (e.g., refer to) the first carbon atom.

In Formula 1, X may be NR₈, O, or S. For example, in one or more embodiments, X may be NR₈ or O.

In Formula 1, R₁ to R₈ may each independently be hydrogen, deuterium, a halogen, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, in one or more embodiments, R₁ to R₃ may each independently be hydrogen, deuterium, a substituted or unsubstituted t-butyl group, a substituted or unsubstituted phenyl group, or a substituted or unsubstituted carbazole group. R₄ and R₅ may be hydrogen. R₆ and R₇ may each independently be hydrogen, a substituted or unsubstituted t-butyl group, or a substituted or unsubstituted phenyl group. R₈ may be a substituted or unsubstituted phenyl group, or a substituted or unsubstituted biphenyl group.

In Formula 1, n1 may be an integer of 0 to 3. In Formula 1, when n1 is 0, the fused polycyclic compound of one or more embodiments may be unsubstituted with R₁. An embodiment of Formula 1 in which n1 is 3, and all of R₁ are hydrogen, may be the same as an embodiment of Formula 1 in which n1 is 0. When n1 is an integer of 2 or more, multiple R₁(s) may be all the same, or at least one selected from among multiple R₁(s) may be different.

In Formula 1, n2 to n6 may each independently be an integer of 0 to 4. In Formula 1, when n2 to n6 each independently are 0, the fused polycyclic compound of one or more embodiments may be unsubstituted with corresponding R₂ to R₆. An embodiment of Formula 1 in which n2 to n6 are 4, and all R₂ to R₆ are hydrogen, may be the same as an embodiment of Formula 1 in which n2 to n6 each are 0. When n2 to n6 are integers of 2 or more, multiple R₂(s) to R₆(s) may be all the same, or at least one selected from among multiple R₂(s) to R₆(s) may be different.

In Formula 1, n7 may be an integer of 0 to 5. In Formula 1, when n7 is 0, the fused polycyclic compound of one or more embodiments may be unsubstituted with R₇.

An embodiment of Formula 1 in which n7 is 5, and all R₇ are hydrogen, may be the same as an embodiment of Formula 1 in which n7 is 0. When n7 is an integer of 2 or more, multiple R₇(s) may be all the same, or at least one selected from among multiple R₇(s) may be different.

In the fused polycyclic compound of one or more embodiments, at least one selected from among the second aromatic ring and the third aromatic ring may be substituted with a substituted or unsubstituted amine group, a substituted or unsubstituted aryl group of 6 to 30 ring-forming carbon atoms, or a substituted or unsubstituted heteroaryl group of 2 to 30 ring-forming carbon atoms. For example, in one or more embodiments, in Formula 1, at least one selected from among R₂ and R₃ may be a substituted or unsubstituted amine group, a substituted or unsubstituted aryl group of 6 to 30 ring-forming carbon atoms, or a substituted or unsubstituted heteroaryl group of 2 to 30 ring-forming carbon atoms. For example, in one or more embodiments, at least one selected from among R₂ and R₃ may be a substituted or unsubstituted phenyl group, or a substituted or unsubstituted carbazole group. For example, the fused polycyclic compound of one or more embodiments, represented by Formula 1, may include a structure in which a substituent other than hydrogen is substituted in at least one selected from among the second aromatic ring and the third aromatic ring. In some embodiments, when R₂ is a substituent other than hydrogen, n2 may be an integer of 1 to 4. When R₃ is a substituent other than hydrogen, n3 may be an integer of 1 to 4.

In one or more embodiments, R₂ and R₃ may each independently be a substituted or unsubstituted amine group, a substituted or unsubstituted aryl group of 6 to 30 ring-forming carbon atoms, or a substituted or unsubstituted heteroaryl group of 2 to 30 ring-forming carbon atoms, and n2 and n3 may each independently be an integer of 1 to 4. For example, in some embodiments, R₂ and R₃ may each independently be a substituted or unsubstituted phenyl group, or a substituted or unsubstituted carbazole group, and n2 and n3 may each independently be an integer of 1 to 4. For example, in one or more embodiments, the fused polycyclic compound represented by Formula 1 may include a structure in which each of the second aromatic ring and the third aromatic ring is substituted with a substituent other than hydrogen.

In one or more embodiments, the first compound represented by Formula 1 may be represented by any one selected from among Formula 1-1 to Formula 1-3.

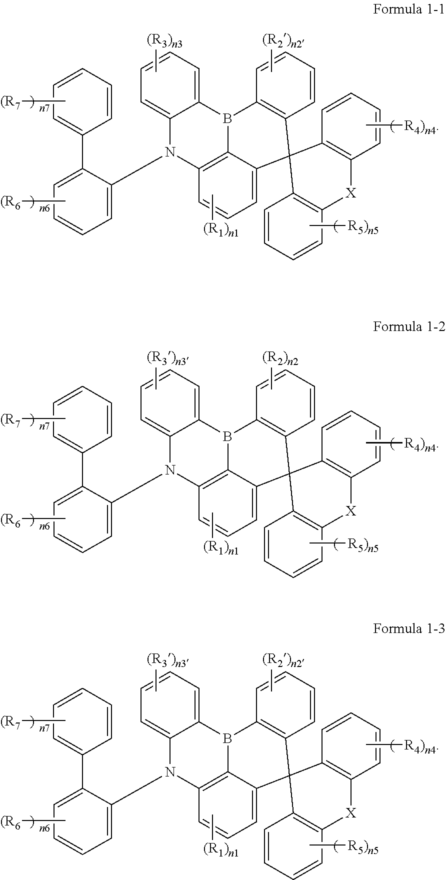

In Formula 1-1 to Formula 1-3, R₂ ‘ and R₃’ may each independently be a substituted or unsubstituted amine group, a substituted or unsubstituted aryl group of 6 to 30 ring-forming carbon atoms, or a substituted or unsubstituted heteroaryl group of 2 to 30 ring-forming carbon atoms.

In Formula 1-1 to Formula 1-3, n2′ and n3′ may each independently be an integer of 1 to 4. For example, when n2′ and n3′ are 1, in the fused polycyclic compound represented by Formula 1, the second aromatic ring and the third aromatic ring may be substituted with one R₂ ‘ and one R₃’, respectively, and the remainder may be hydrogen.

In Formula 1-1 to Formula 1-3, the same contents explained in Formula 1 may be applied for X, R₁ to R₇, and n1 to n7.

In one or more embodiments, the first compound represented by Formula 1 may be represented by Formula 2.

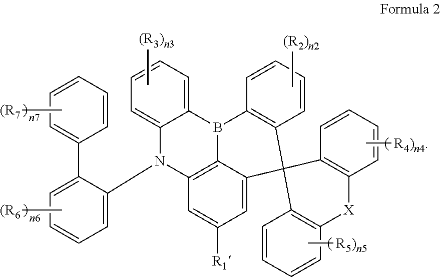

Formula 2 represents an embodiment of Formula 1 in which the number, type or kind, and substitution position of the substituent represented by R₁ are specified.

In Formula 2, R₁′ may be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In some embodiments, in Formula 2, may be a substituted or unsubstituted t-butyl group, a substituted or unsubstituted phenyl group, or a substituted or unsubstituted carbazole group.

In Formula 2, the same contents explained in Formula 1 may be applied for X, R₂ to R₇, and n2 to n7.

In one or more embodiments, may be a substituted or unsubstituted alkyl group of 1 to 10 carbon atoms, or represented by Formula A-1 or Formula A-2. For example, in some embodiments, may be a substituted or unsubstituted t-butyl group, or represented by Formula A-1 or Formula A-2.

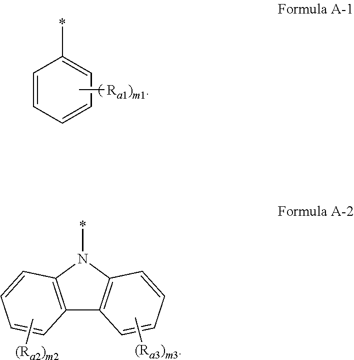

In Formula A-1 and Formula A-2, Rₐ₁ to Rₐ₃ may each independently be hydrogen, deuterium, a halogen, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, in one or more embodiments, Rₐ₁ to Rₐ₃ may each independently be hydrogen, deuterium, a cyano group, a substituted or unsubstituted t-butyl group, or a substituted or unsubstituted phenyl group.

In Formula A-1, m1 may be an integer of 0 to 5. In Formula A-1, when m1 is 0, the fused polycyclic compound of one or more embodiments may be unsubstituted with Rₐ₁. An embodiment of Formula A-1 in which m1 is 5, and all Rₐ₁ are hydrogen, may be the same as an embodiment of Formula A-1 in which m1 is 0. When m1 is an integer of 2 or more, multiple Rₐ₁(s) may be all the same, or at least one among multiple Rₐ₁(s) may be different.

In Formula A-2, m2 and m3 may each independently be an integer of 0 to 4. In Formula A-2, when m2 and m3 each independently are 0, the fused polycyclic compound of one or more embodiments may be unsubstituted with corresponding Rₐ₂ and Rₐ₃. An embodiment of Formula A-2 in which m2 and m3 are 4, and Rₐ₂ and Rₐ₃ are hydrogen, may be the same as an embodiment of Formula A-2 in which m2 and m3 each are 0. When m2 and m3 are integers of 2 or more, multiple Rₐ₂(s) and Rₐ₃(s) may be all the same, or at least one among multiple Rₐ₂(s) and Rₐ₃(s) may be different.

In one or more embodiments, the first compound represented by Formula 1 may be represented by any one selected from among Formula 3-1 to Formula 3-4.

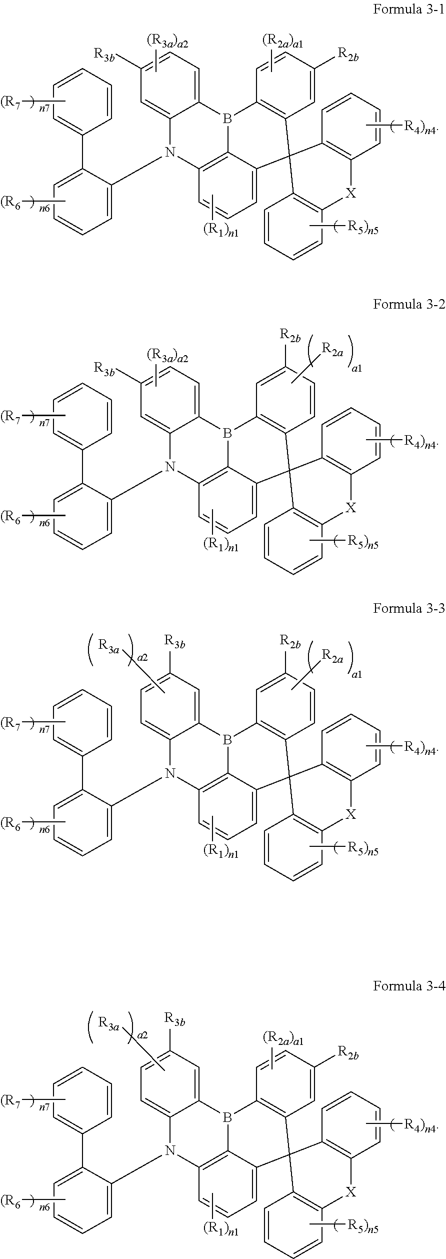

Formula 3-1 to Formula 3-4 represent embodiments of Formula 1 in which the numbers, types (kinds), and substitution positions of R₂ and R₃ are specified.

In Formula 3-1 to Formula 3-4, R₂a and R₃a may each independently be hydrogen, deuterium, a halogen, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, in some embodiments, R₂a and R₃a may all be hydrogen.

In Formula 3-1 to Formula 3-4, R_{2b} and R_{3b} may each independently be a substituted or unsubstituted aryl group of 6 to 30 ring-forming carbon atoms, or a substituted or unsubstituted heteroaryl group of 2 to 30 ring-forming carbon atoms. For example, in some embodiments, R_{2b} and R_{3b} may each independently be a substituted or unsubstituted phenyl group, or a substituted or unsubstituted carbazole group.

In Formula 3-1 to Formula 3-4, a1 and a2 may each independently be an integer of 0 to 3. In Formula 3-1 to Formula 3-4, when a1 and a2 each independently are 0, the fused polycyclic compound of one or more embodiments may be unsubstituted with corresponding R₂a and R₃a. Embodiments of Formula 3-1 to Formula 3-4 in which a1 and a2 are 3, and R₂a and R₃a are all hydrogen, may be the same as embodiments of Formula 3-1 to Formula 3-4 in which a1 and a2 each are 0. When a1 and a2 are integers of 2 or more, multiple R₂a(s) and R₃a(s) may be all the same, or at least one among multiple R₂a and R₃a may be different.

In Formula 3-1 to Formula 3-4, the same contents explained in Formula 1 may be applied for X, R₁, R₄ to R₇, n1, and n4 to n7.

In one or more embodiments, the first compound represented by Formula 1 may be represented by any one selected from among Formula 4-1 to Formula 4-4.

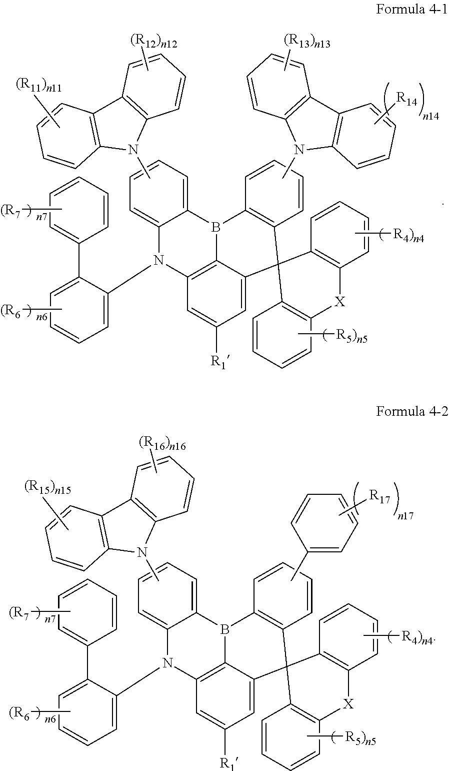

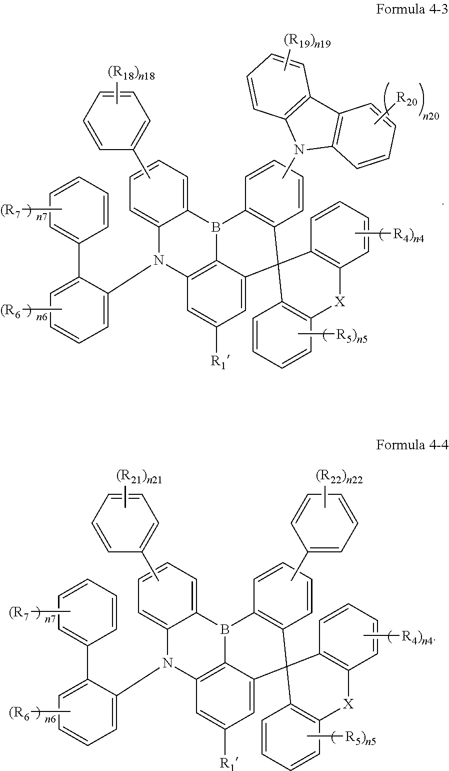

Formula 4-1 to Formula 4-4 represent embodiments of Formula 1 where the numbers and types (kinds) of R₂ and R₃ are specified.

In Formula 4-1 to Formula 4-4, R₁₁ to R₂₂ may each independently be hydrogen, deuterium, a halogen, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, in some embodiments, R₁₁ to R₂₂ may each independently be hydrogen, deuterium, a cyano group, a substituted or unsubstituted t-butyl group, or a substituted or unsubstituted phenyl group.

In Formula 4-1 to Formula 4-4, the same contents explained on in Formula 2 may be applied for

In Formula 4-1 to Formula 4-3, n11 to n16, n19, and n20 may each independently be an integer of 0 to 4. In Formula 4-1 to Formula 4-3, when n11 to n16, n19, and n20 each independently are 0, the fused polycyclic compound of one or more embodiments may be unsubstituted with corresponding R₁₁ to R₁₆, R₁₉, and R₂₀. Embodiments of Formula 4-1 to Formula 4-3 in which n11 to n16, n19, and n20 are 4, and R₁₁ to R₁₆, R₁₉, and R₂₀ are all hydrogen, may be the same as embodiments of Formula 4-1 to Formula 4-3 in which n11 to n16, n19, and n20 each are 0. When where n11 to n16, n19, and n20 are integers of 2 or more, each of multiple R₁₁(s) to R₁₆(s), R₁₉(s), and R₂₀(s) may all the same, or at least one selected from among R₁₁(s) to R₁₆(s), R₁₉(s), and R₂₀(s) may be different.

In Formula 4-1 to Formula 4-4, n17, n18, n21, and n22 may each independently be an integer of 0 to 5. In Formula 4-2 to Formula 4-4, when n17, n18, n21, and n22 each independently are 0, the fused polycyclic compound of one or more embodiments may be unsubstituted with corresponding R₁₇, R₁₈, R₂₁, and R₂₂. Embodiments of Formula 4-2 to Formula 4-4 in which n17, n18, n21, and n22 are 5, and R₁₇, R₁₈, R₂₁, and R₂₂ are all hydrogen, may be the same as embodiments of Formula 4-2 to Formula 4-4 in which n17, n18, n21, and n22 each are 0. When n17, n18, n21, and n22 are integers of 2 or more, each of multiple R₁₇, R₁₈, R₂₁, and R₂₂ may all the same, or at least one among R₁₇, R₁₈, R₂₁, and R₂₂ may be different.

In Formula 4-1 to Formula 4-4, the same contents explained in Formula 1 may be applied for X, R₄ to R₇, and n4 to n7.

In one or more embodiments, R₂ and R₃ may each independently be represented by any one selected from among Formula B-1 to Formula B-11.

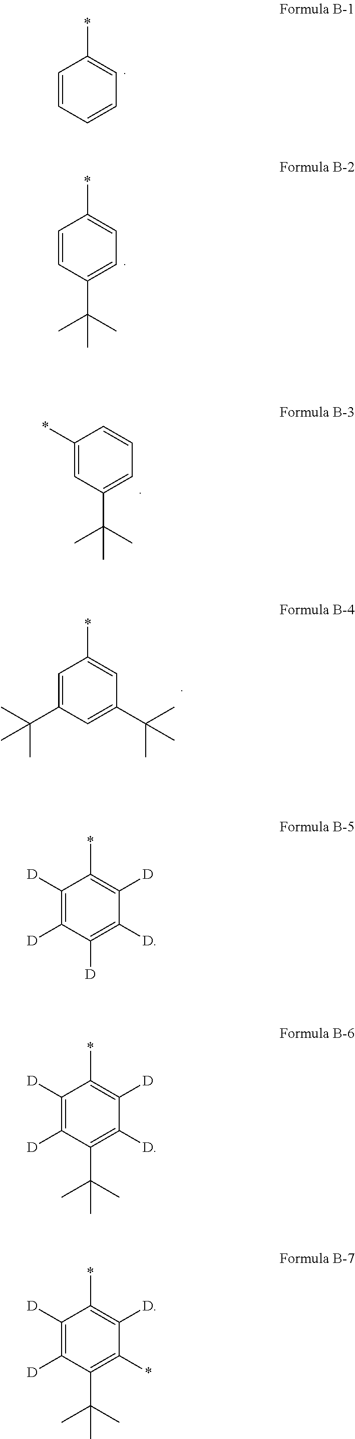

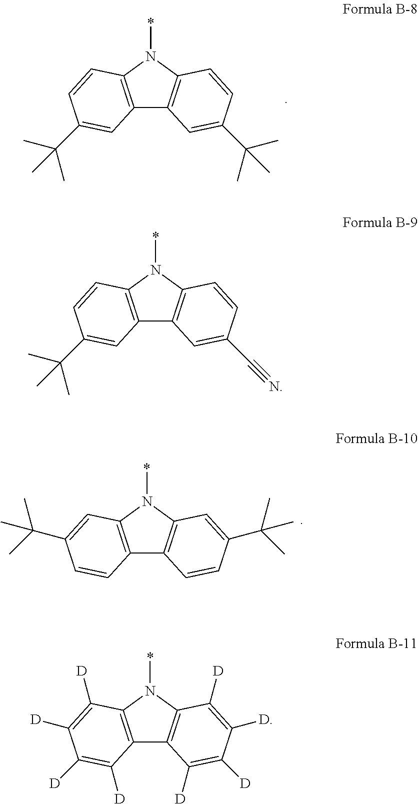

In Formula B-1 to Formula B-11, [symbol] is a position connected with Formula 1. In Formula B-5, Formula B-6, Formula B-7, and Formula B-11, “D” refers to deuterium.

In one or more embodiments, the first compound represented by Formula 1 may be represented by any one selected from among Formula 5-1 to Formula 5-3.

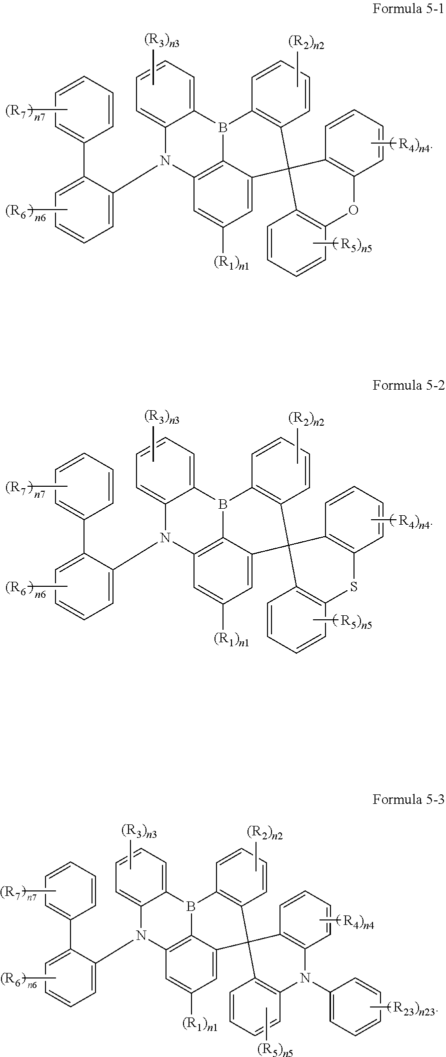

Formula 5-1 to Formula 5-3 represent embodiments of Formula 1 in which the type or kind of X is specified.

In Formula 5-3, R₂₃ may be hydrogen, deuterium, a halogen, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, in some embodiments, R₂₃ may be hydrogen, or a substituted or unsubstituted phenyl group.

In Formula 5-3, n23 may be an integer of 0 to 5. In Formula 5-3, when n23 is 0, the fused polycyclic compound of one or more embodiments may be unsubstituted with R₂₃. An embodiment of Formula 5-3 in which n23 is 5, and all R₂₃ are hydrogen, may be the same as an embodiment of Formula 5-3 in which n23 is 0. When n23 is an integer of 2 or more, multiple R₂₃(s) may be all the same, or at least one selected from among multiple R₂₃(s) may be different.

In Formula 5-1 to Formula 5-3, the same contents explained in Formula 1 may be applied for R₁ to R₇, and n1 to n7.

In the fused polycyclic compound of one or more embodiments, the second substituent connected with (e.g., bonded to) the first nitrogen atom may include a structure introducing a substituted or unsubstituted phenyl group in at least one selected from among two ortho positions with respect to the first nitrogen atom in a benzene moiety. In the fused polycyclic compound of one or more embodiments, the second substituent may include a structure introducing substituted or unsubstituted phenyl groups in two ortho positions with respect to the first nitrogen atom in a benzene moiety.

In one or more embodiments, the first compound represented by Formula 1 may be represented by Formula 6.

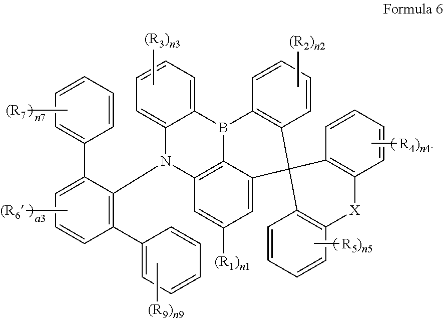

In Formula 6, R₆′ and R₉ may each independently be hydrogen, deuterium, a halogen, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, in some embodiments, R₆′ and R₉ may each independently be hydrogen, deuterium, or a substituted or unsubstituted t-butyl group.

In Formula 6, a3 may be an integer of 0 to 3. In Formula 6, when a3 is 0, the fused polycyclic compound of one or more embodiments may be unsubstituted with R₆′. An embodiment of Formula 6 in which a3 is 3, and all R₆′ are hydrogen, may be the same as an embodiment of Formula 6 in which a3 is 0. When a3 is an integer of 2 or more, multiple R₆′(s) may be all the same, or at least one selected from among multiple R₆′(s) may be different.

In Formula 6, n9 may be an integer of 0 to 5. In Formula 6, when n9 is 0, the fused polycyclic compound of one or more embodiments may be unsubstituted with R₉. An embodiment of Formula 6 in which n9 is 5, and all R₉ are hydrogen, may be the same as an embodiment of Formula 6 in which n9 is 0. When n9 is an integer of 2 or more, multiple R₉(s) may be all the same, or at least one among multiple R₉(s) may be different.

In Formula 6, the same contents explained in Formula 1 may be applied for X, R₁ to R₅, R₇, n1 to n5, and n7.

In one or more embodiments, the first compound represented by Formula 1 may be represented by Formula 6-1.

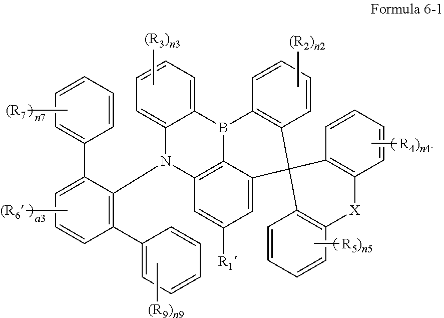

In Formula 6-1, the same contents on explained in Formula 2 may be applied for

In Formula 6-1, the same contents on R₆′, R₉, a3, and n9 explained in Formula 6 may be applied for R₆′, R₉, a3, and n9.

In Formula 6-1, the same contents explained in Formula 1 may be applied for X, R₂ to R₅, R₇, n2 to n5, and n7.

In one or more embodiments, the first compound represented by Formula 1 may be represented by any one selected from among Formula 7-1 to Formula 7-3.

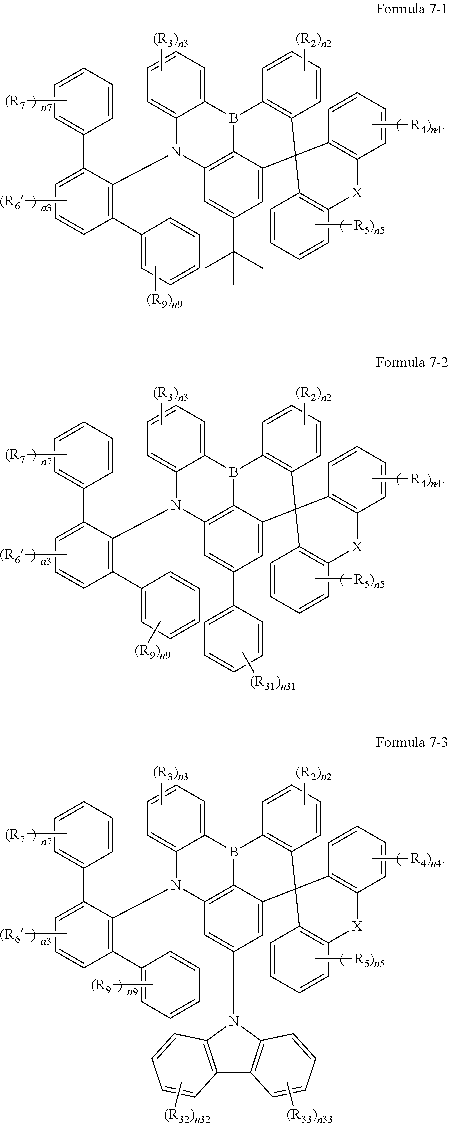

In Formula 7-1 to Formula 7-3, R₆′, R₉, and R₃₁ to R₃₃ may each independently be hydrogen, deuterium, a halogen, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, in some embodiments, R₆′ and R₉ may each independently be hydrogen, deuterium, or a substituted or unsubstituted t-butyl group. R₃₁ to R₃₃ may each independently be hydrogen, deuterium, a cyano group, a substituted or unsubstituted t-butyl group, or a substituted or unsubstituted phenyl group.

In Formula 7-1 to Formula 7-3, the same contents on a3 and n9 explained in Formula 6 may be applied for a3 and n9.

In Formula 7-2, n31 may be an integer of 0 to 5. In Formula 7-2, when n31 is 0, the fused polycyclic compound of one or more embodiments may be unsubstituted with R₃₁. An embodiment of Formula 7-2 in which n31 is 5, and all R₃₁ are hydrogen, may be the same as an embodiment of Formula 7-2 in which n31 is 0. When n31 is an integer of 2 or more, multiple R₃₁(s) may be all the same, or at least one among multiple R₃₁(s) may be different.

In Formula 7-3, n32 and n33 may each independently be an integer of 0 to 4. In Formula 7-3, when n32 and n32 each independently are 0, the fused polycyclic compound of one or more embodiments may be unsubstituted with corresponding R₃₂ and R₃₃. An embodiment of Formula 7-3 in which n32 and n32 are 4, and R₃₂ and R₃₃ are all hydrogen, may be the same as an embodiment of Formula 7-3 in which n32 and n33 each are 0. When n32 and n32 are integers of 2 or more, multiple R₃₂(s) and R₃₃(s) may be all the same, or at least one selected from among multiple R₃₂(s) and R₃₃(s) may be different.

In Formula 7-1 to Formula 7-3, the same contents explained in Formula 1 may be applied for X, R₂ to R₅, R₇, n2 to n5, and n7.

In one or more embodiments, the first compound represented by Formula 1 may be represented by any one selected from among Formula 8-1 to Formula 8-3.

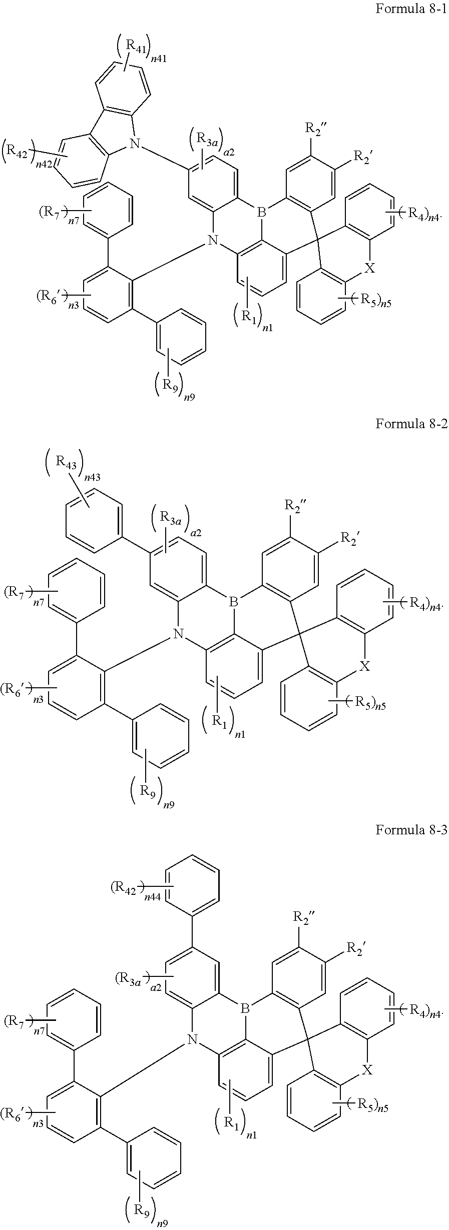

In Formula 8-1 to Formula 8-3, R₃a, R₂′, R₂″, and R₄₁ to R₄₄ may each independently be hydrogen, deuterium, a halogen, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, in some embodiments, R₃a may be hydrogen. R₂′ and R₂″ may each independently be hydrogen, a substituted or unsubstituted phenyl group, or a substituted or unsubstituted carbazole group. R₄₁ to R₄₄ may each independently be hydrogen, deuterium, a cyano group, a substituted or unsubstituted t-butyl group, or a substituted or unsubstituted phenyl group.

In Formula 8-1 to Formula 8-3, the same contents on R₆′, R₉, a3 and n9 explained in Formula 6 may be applied for R₆′, R₉, a3 and n9.

In Formula 8-1 to Formula 8-3, at least one selected from among R₂′ and R₂″ may be a substituted or unsubstituted aryl group of 6 to 30 ring-forming carbon atoms, or a substituted or unsubstituted heteroaryl group of 2 to 30 ring-forming carbon atoms. For example, in some embodiments, any one selected from among R₂′ and R₂″ may be a substituted or unsubstituted aryl group of 6 to 30 ring-forming carbon atoms, or a substituted or unsubstituted heteroaryl group of 2 to 30 ring-forming carbon atoms, and the remainder may be hydrogen. In some embodiments, R₂′ and R₂″ may be substituted or unsubstituted aryl groups of 6 to 30 ring-forming carbon atoms, or substituted or unsubstituted heteroaryl groups of 2 to 30 ring-forming carbon atoms. In some embodiments, at least one selected from among R₂′ and R₂″ may be a substituted or unsubstituted phenyl group, or a substituted or unsubstituted carbazole group.

In some embodiments, any one selected from among R₂′ and R₂″ may be a substituted or unsubstituted aryl group of 6 to 30 ring-forming carbon atoms, or a substituted or unsubstituted heteroaryl group of 2 to 30 ring-forming carbon atoms. For example, in some embodiments, any one selected from among R₂′ and R₂″ may be a substituted or unsubstituted phenyl group, or a substituted or unsubstituted carbazole group.

In Formula 8-1, n41 and n42 may each independently be an integer of 0 to 4. In Formula 8-1, when n41 and n42 each independently are 0, the fused polycyclic compound of one or more embodiments may be unsubstituted with corresponding R₄₁ and R₄₂. An embodiment of Formula 8-1 in which n41 and n42 are 4, and R₄₁ and R₄₂ are all hydrogen, may be the same as an embodiment of Formula 8-1 in which n41 and n42 each are 0. When n41 and n42 are integers of 2 or more, multiple R₄₁(s) and R₄₂(s) may be all the same, or at least one selected from among multiple R₄₁(s) and R₄₂(s) may be different.

In Formula 8-2 and Formula 8-3, n43 and n44 may each independently be an integer of 0 to 5. In Formula 8-2 and Formula 8-3, when n43 and n44 are 0, the fused polycyclic compound of one or more embodiments may be unsubstituted with corresponding R₄₃ and R₄₄. Embodiments of Formula 8-2 and Formula 8-3 in which n43 and n44 are 5, and R₄₃ and R₄₄ are all hydrogen, may be the same as embodiments of Formula 8-2 and Formula 8-3 in which n43 and n44 are 0, respectively. When n43 and n44 are integers of 2 or more, multiple R₄₃(s) and R₄₄(s) may be all the same, or at least one among multiple R₄₃(s) and R₄₄(s) may be different.

In Formula 8-1 to Formula 8-3, the same contents explained in Formula 1 may be applied for X, R₁, R₄, R₅, R₇, n1, n4, n5, and n7.

The fused polycyclic compound of one or more embodiments may be any one selected from among compounds represented in Compound Group 1. The light emitting device ED of one or more embodiments of the present disclosure may include at least one fused polycyclic compound selected from among the compounds represented in Compound Group 1 in an emission layer EML of the light emitting device.

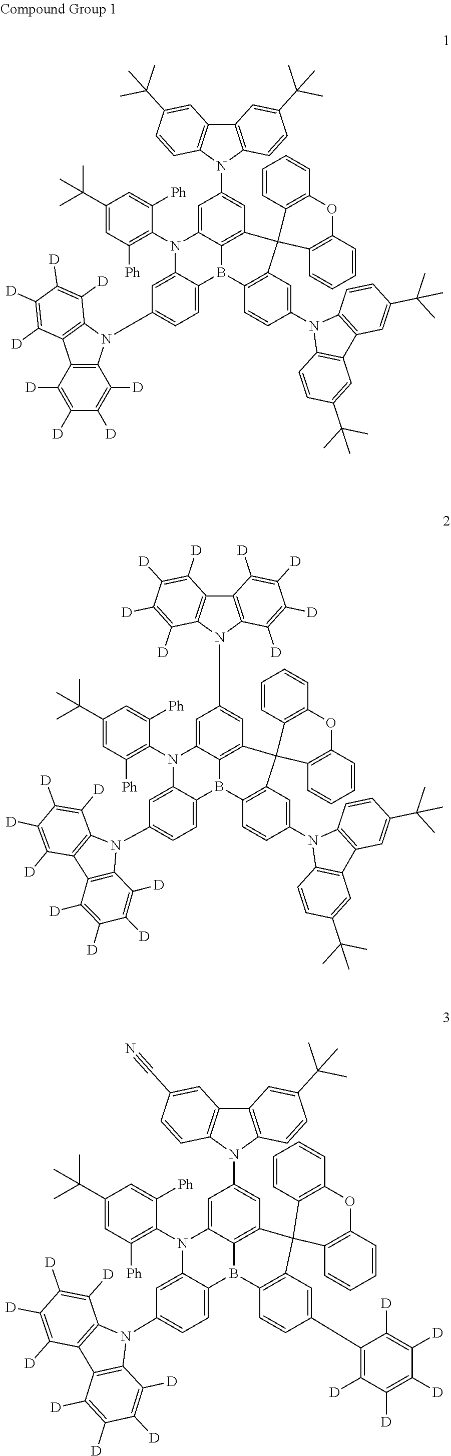

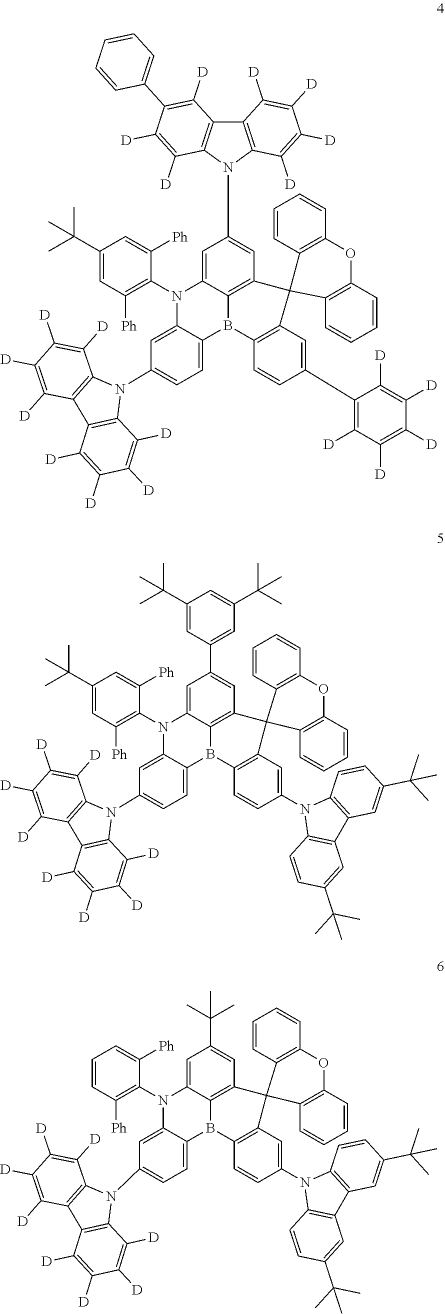

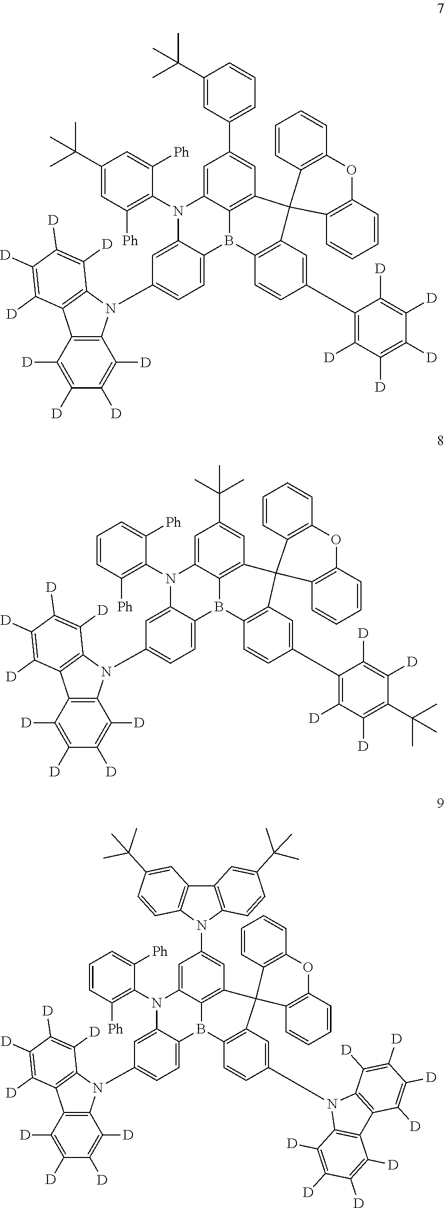

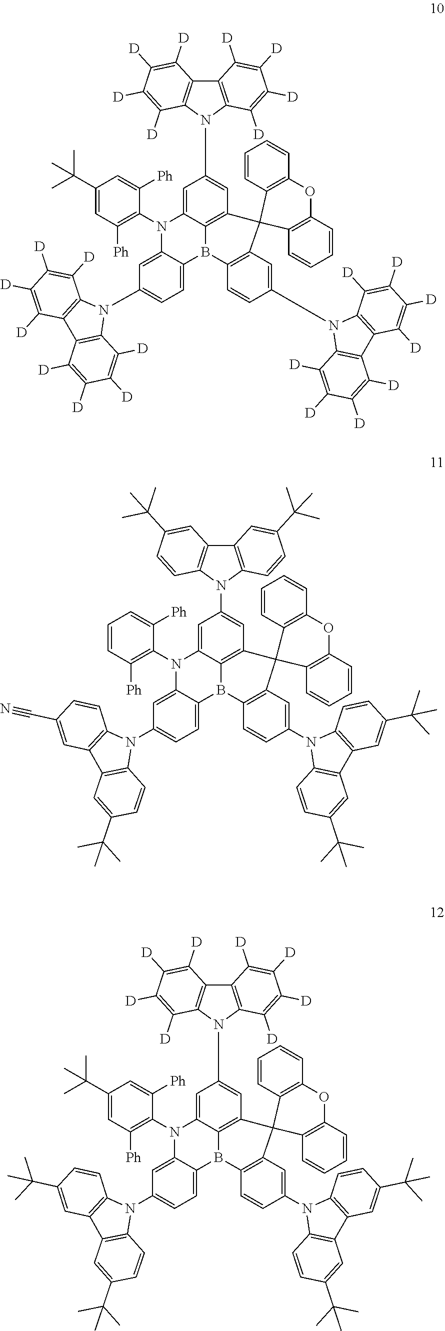

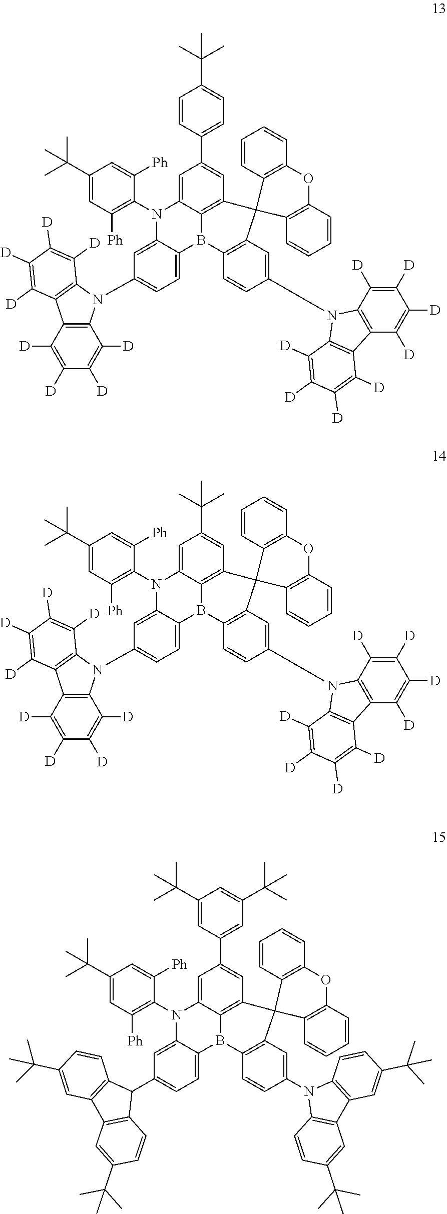

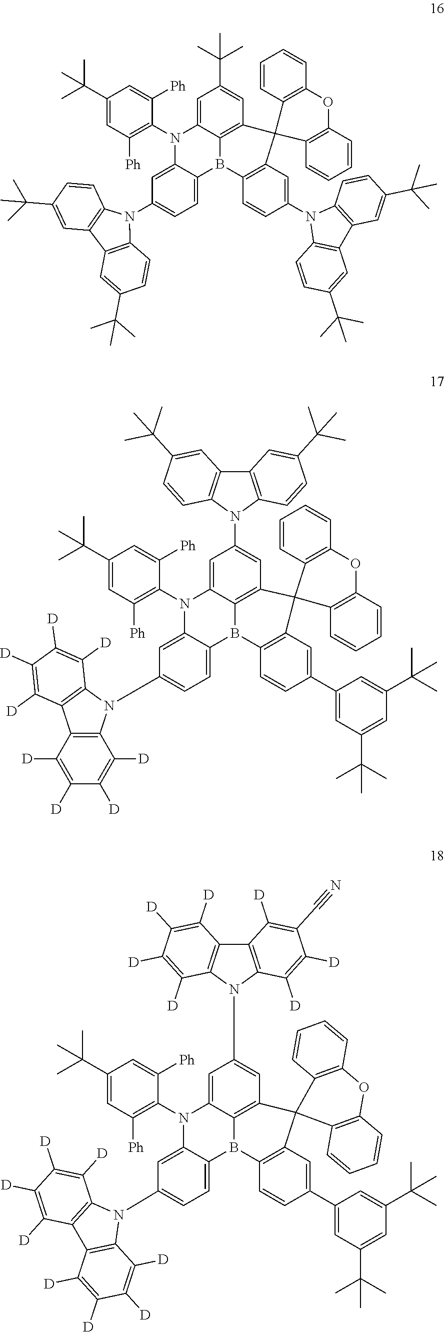

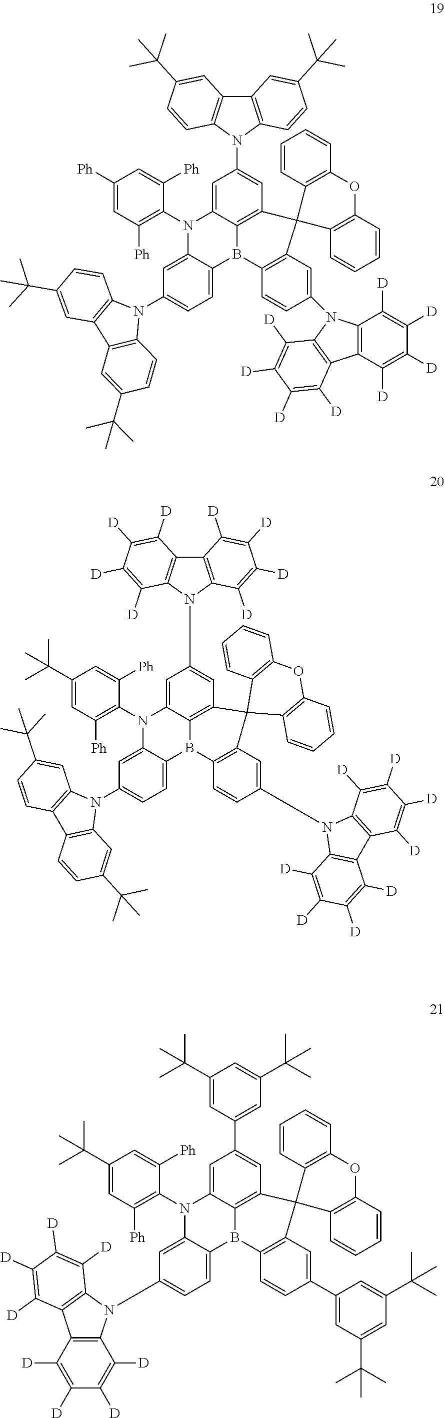

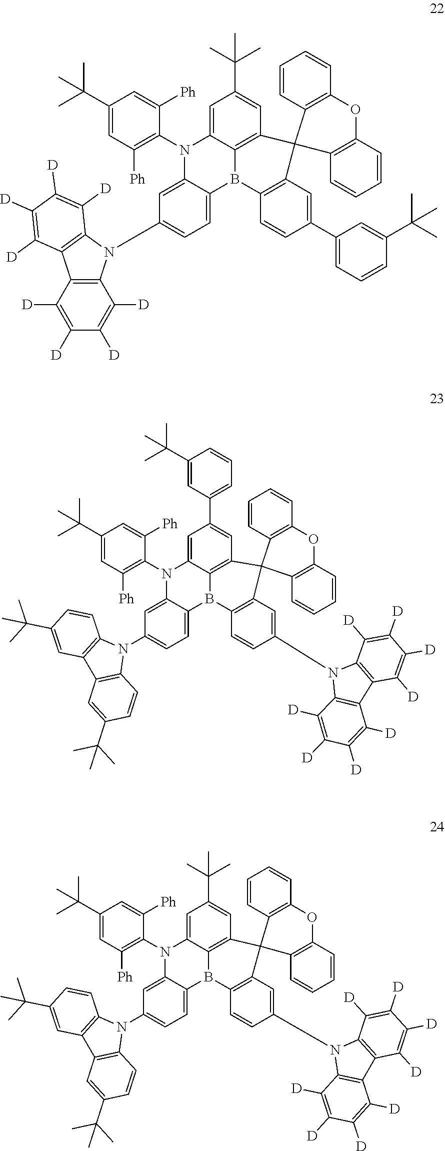

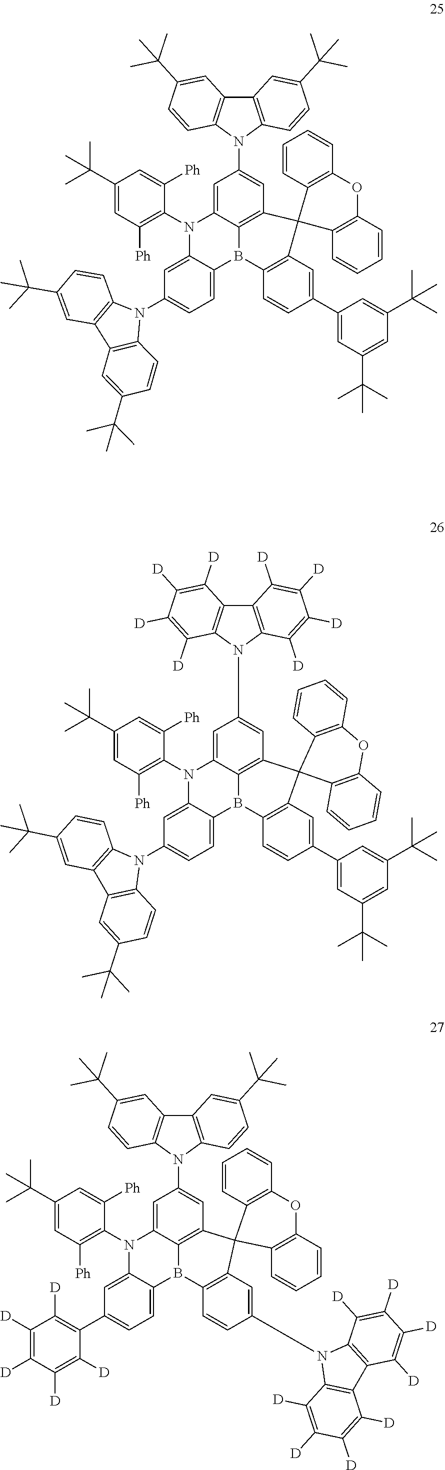

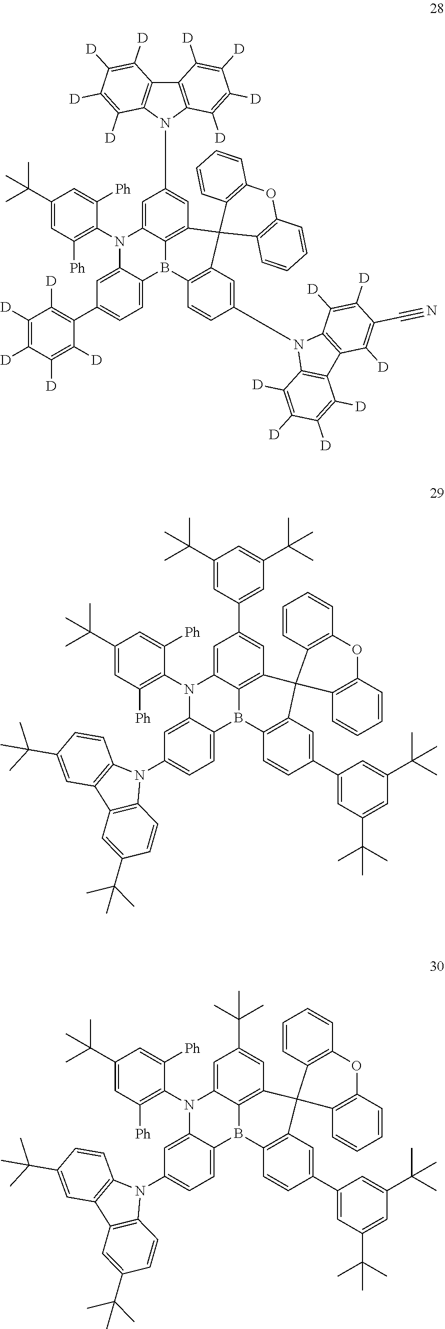

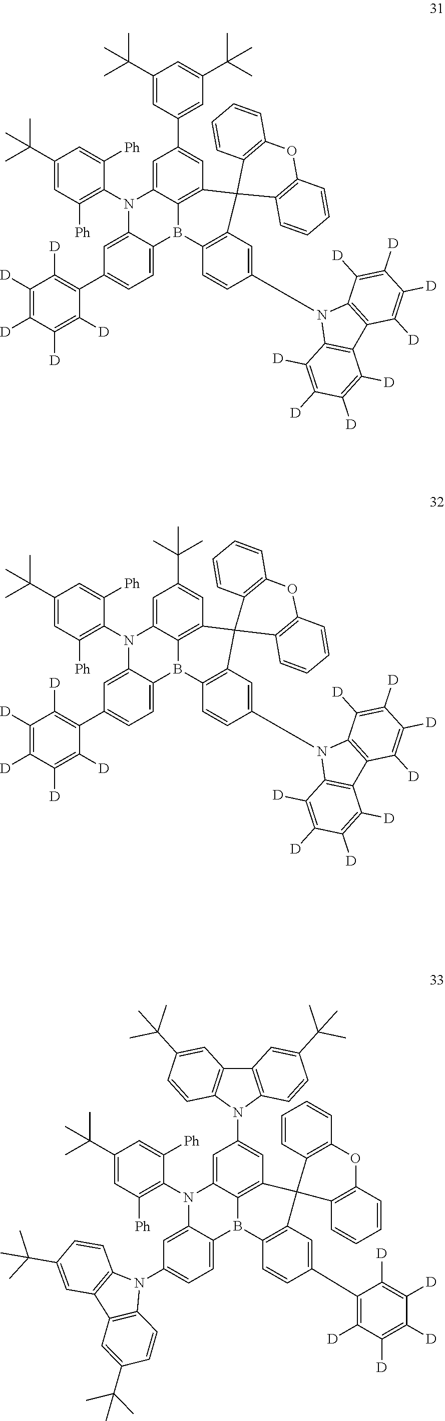

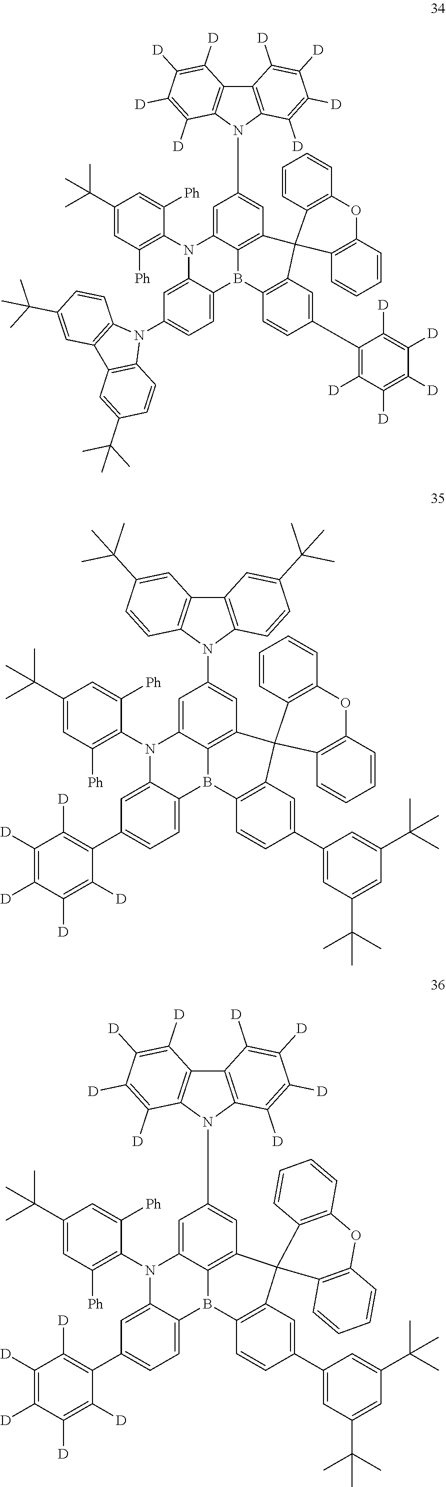

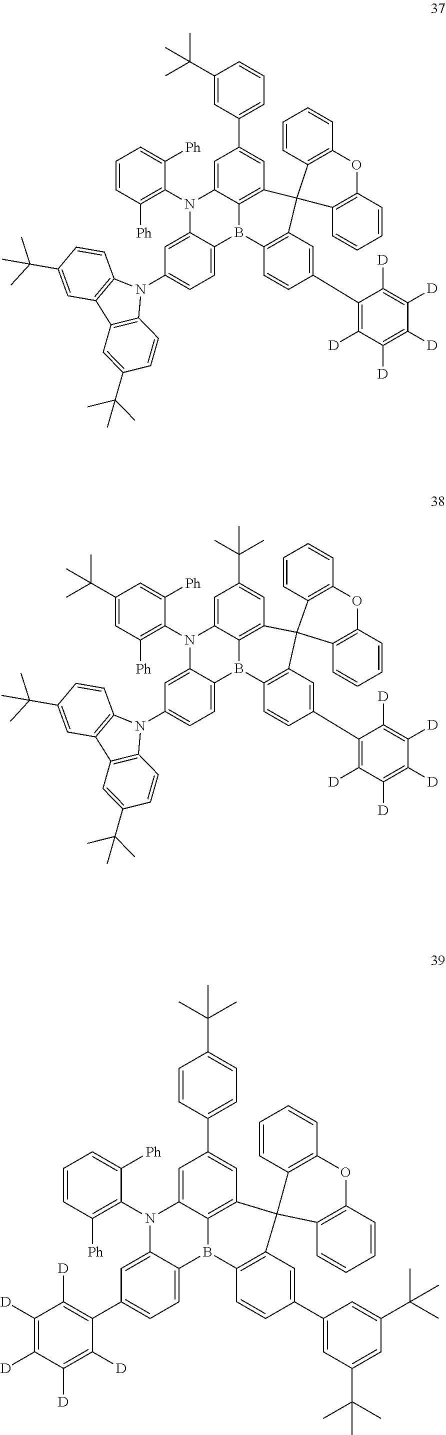

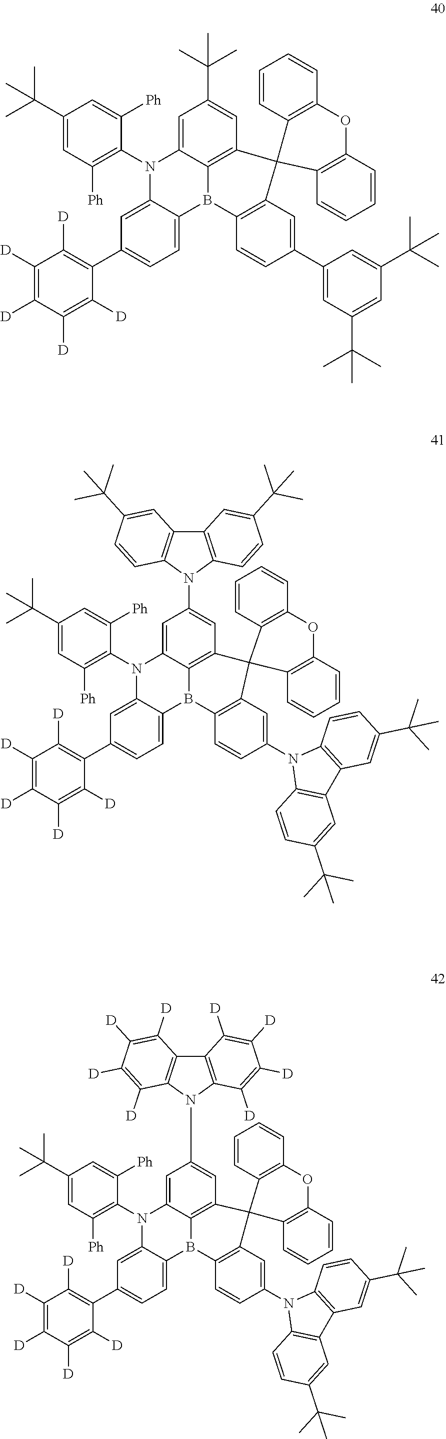

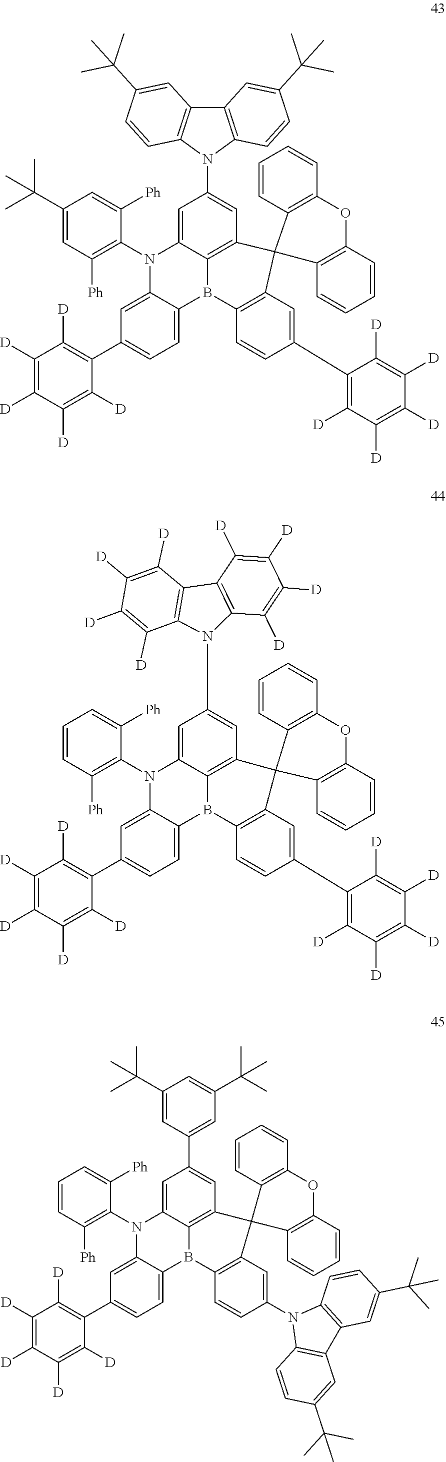

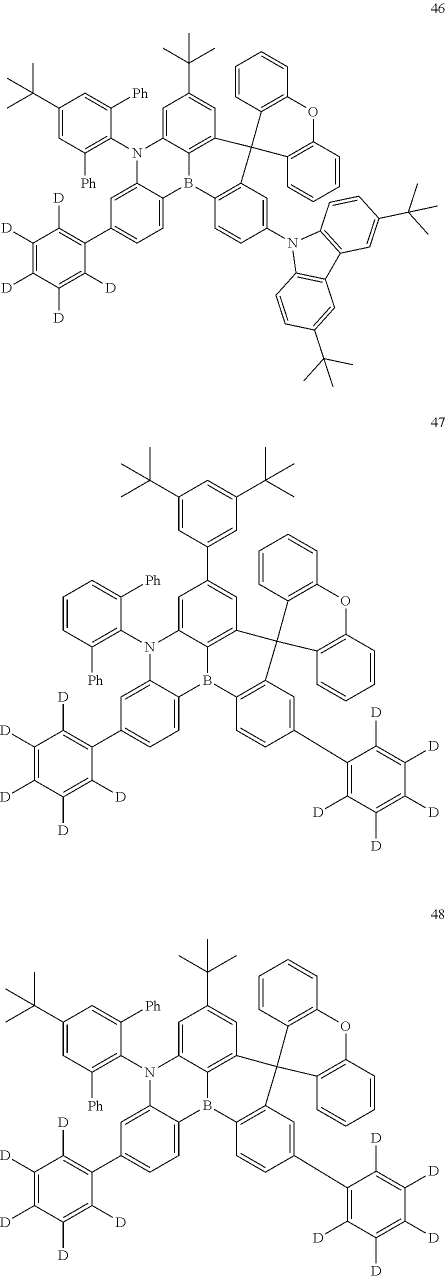

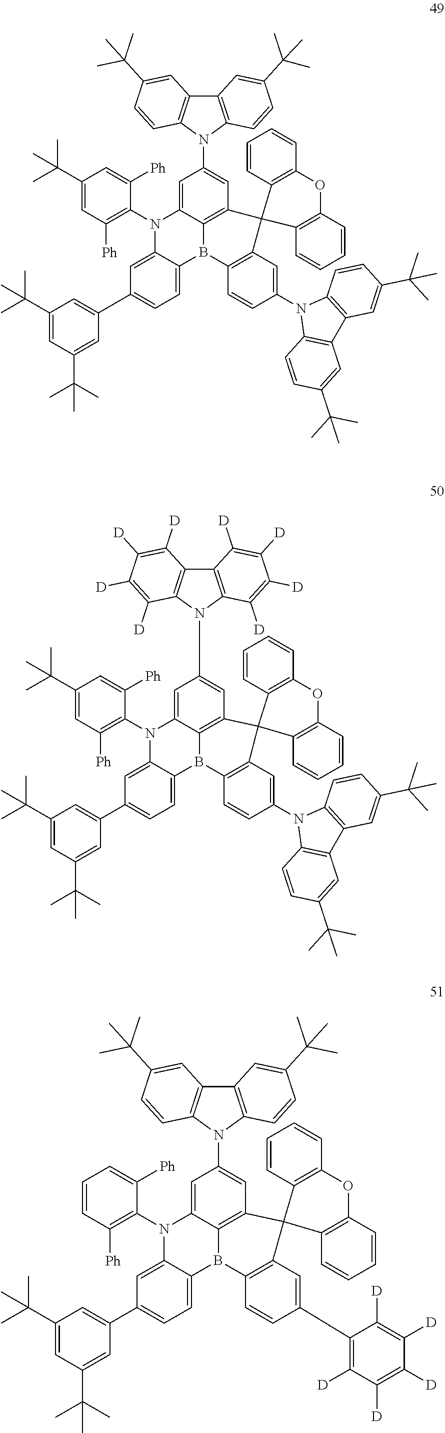

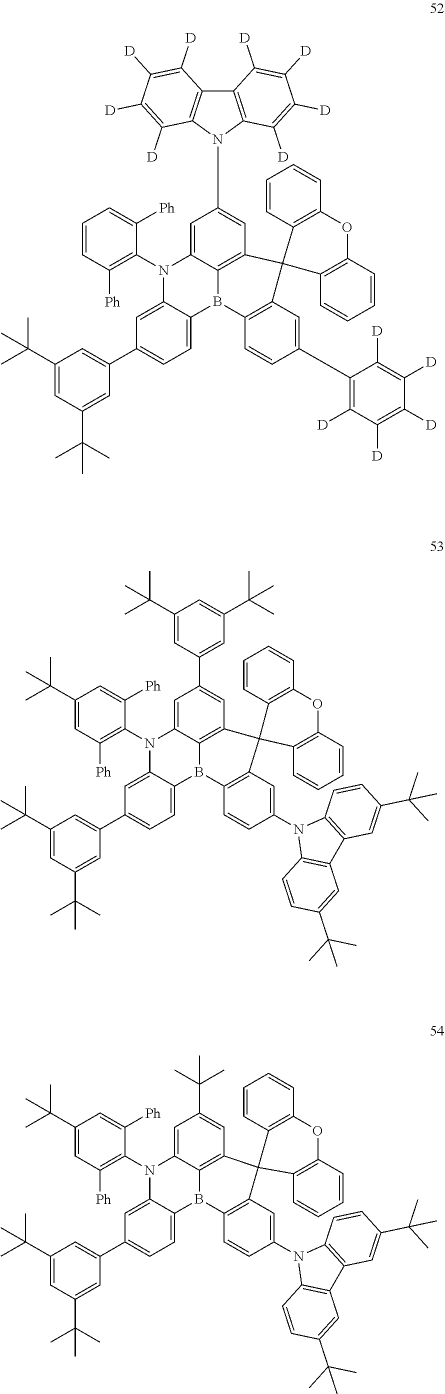

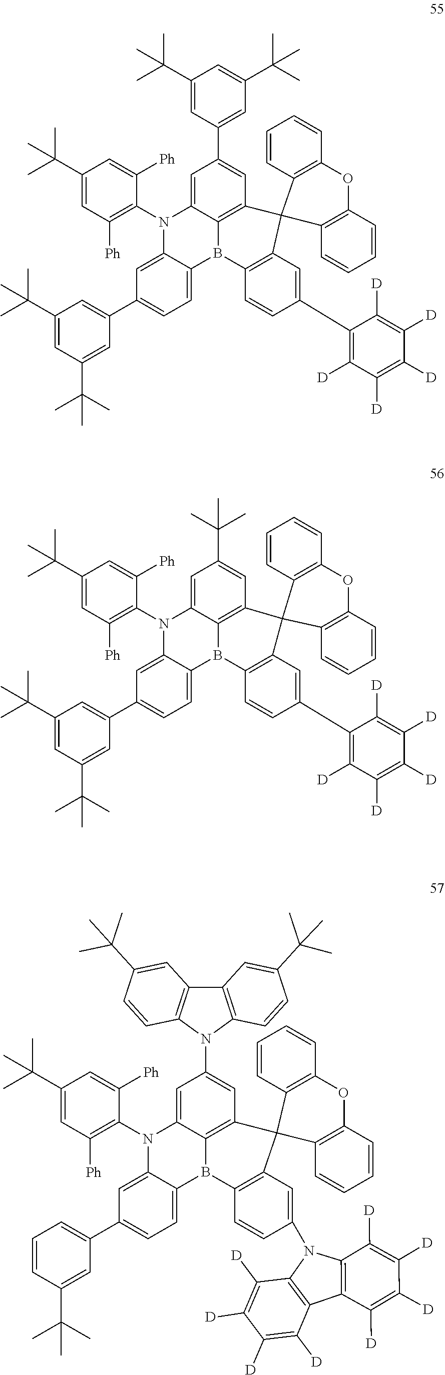

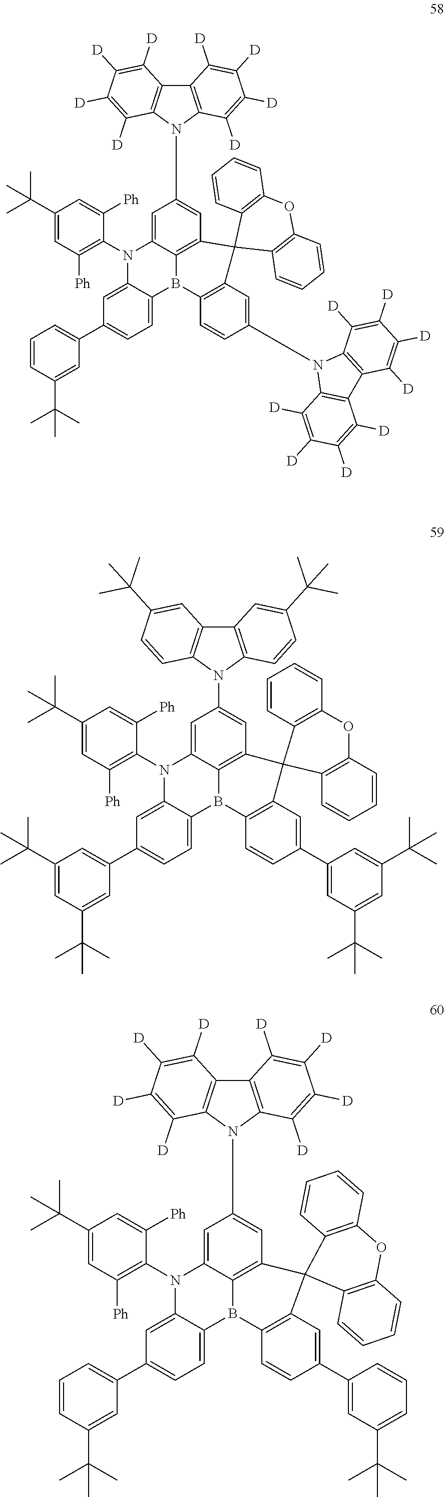

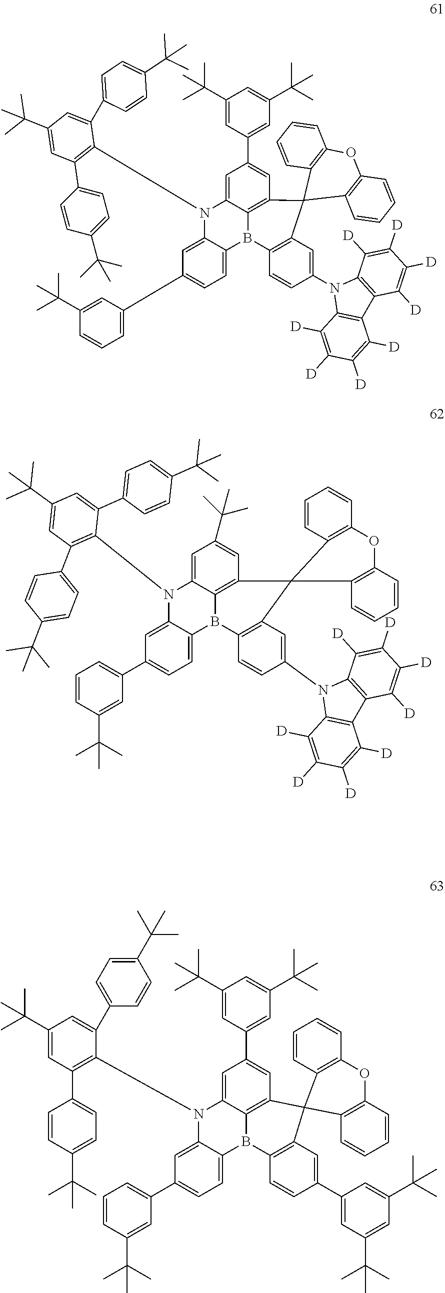

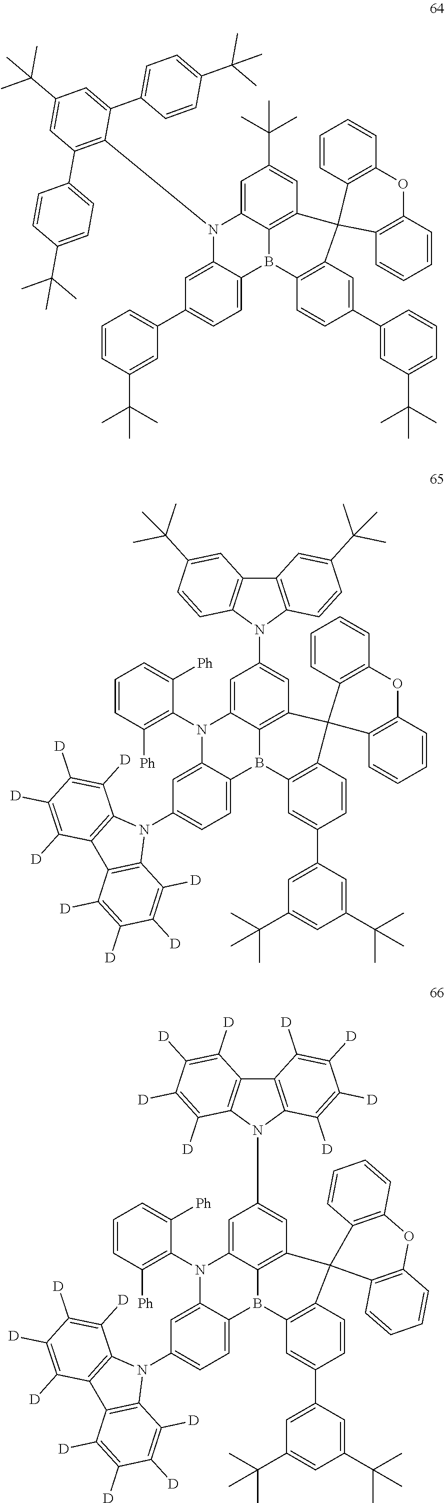

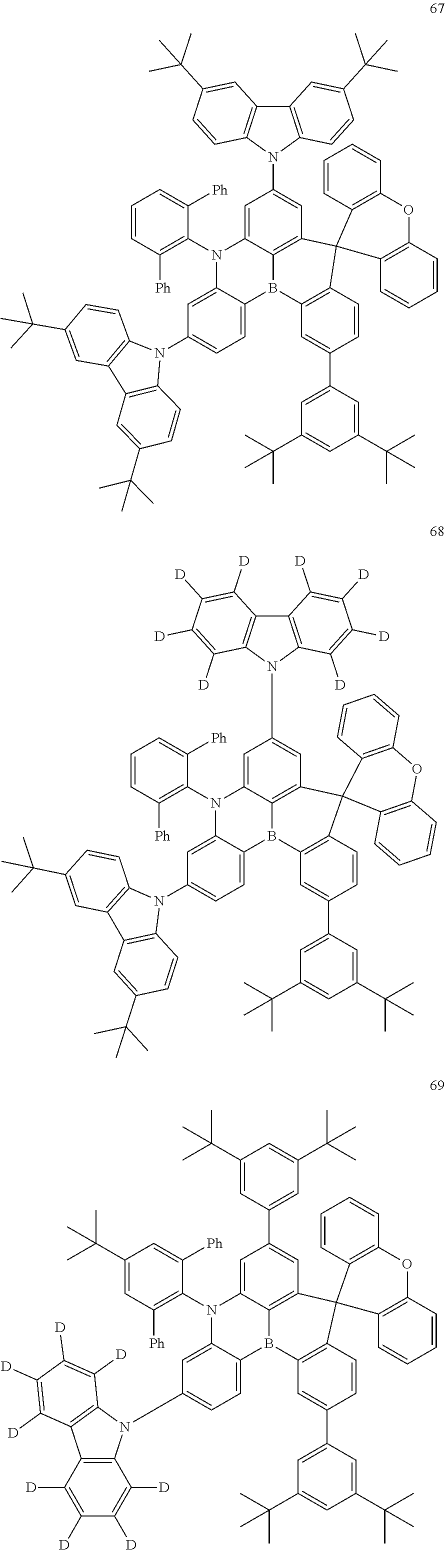

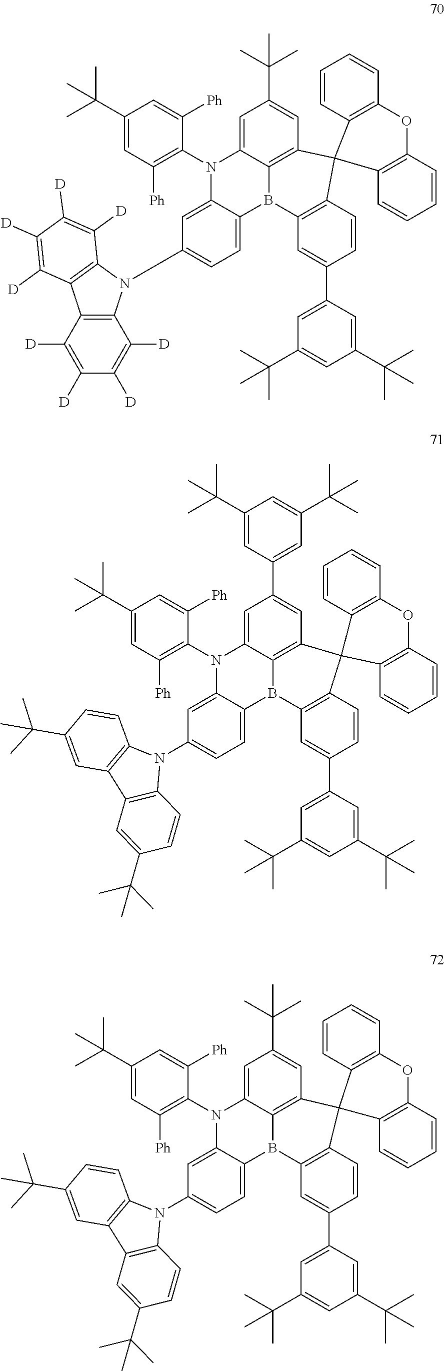

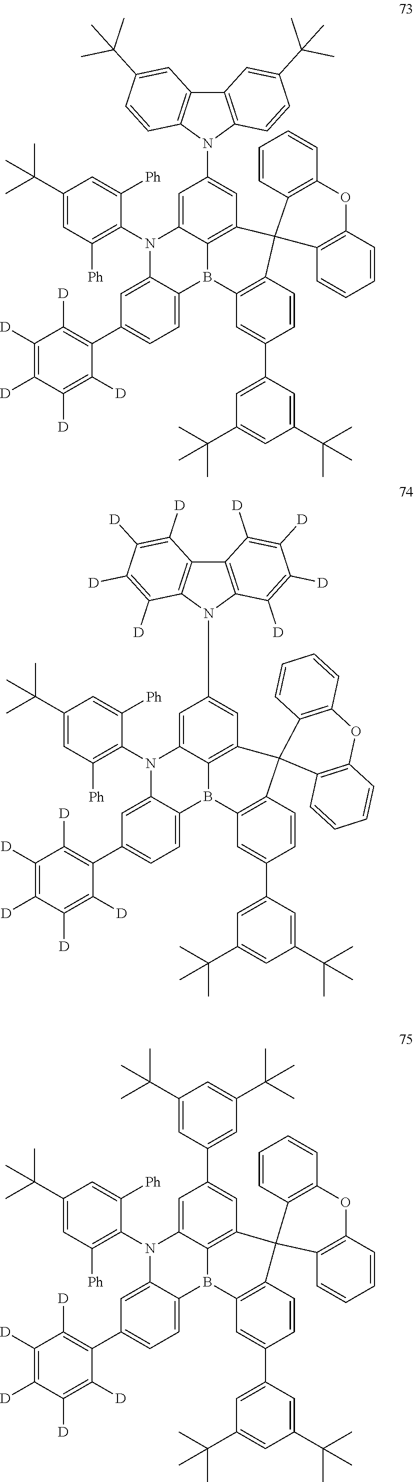

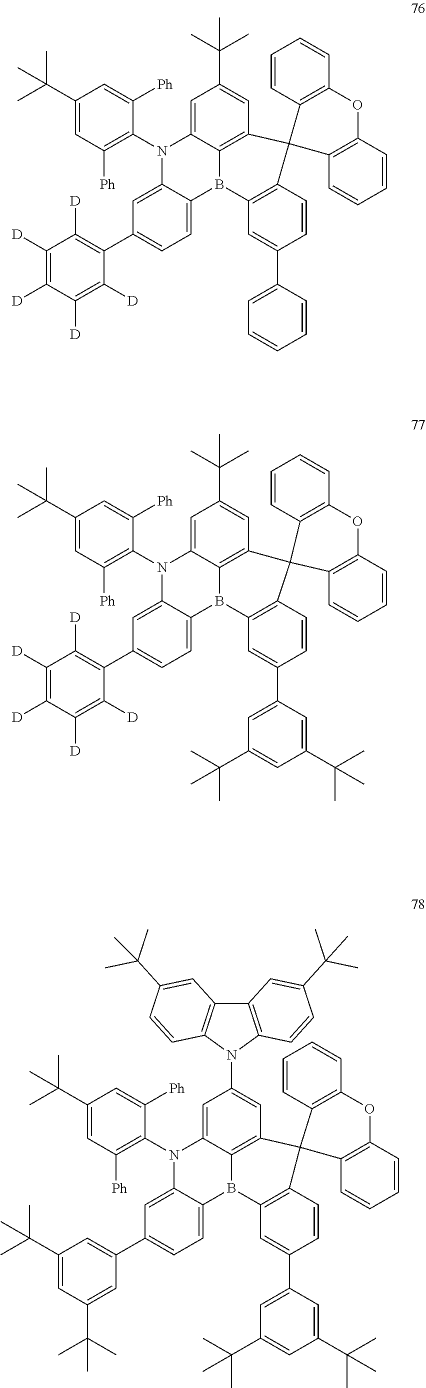

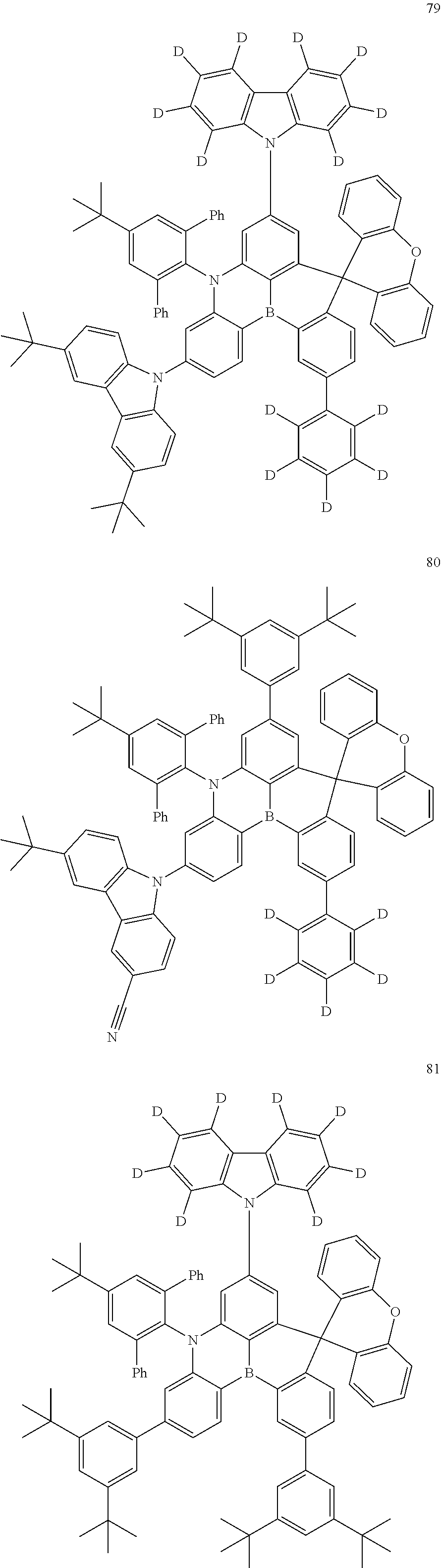

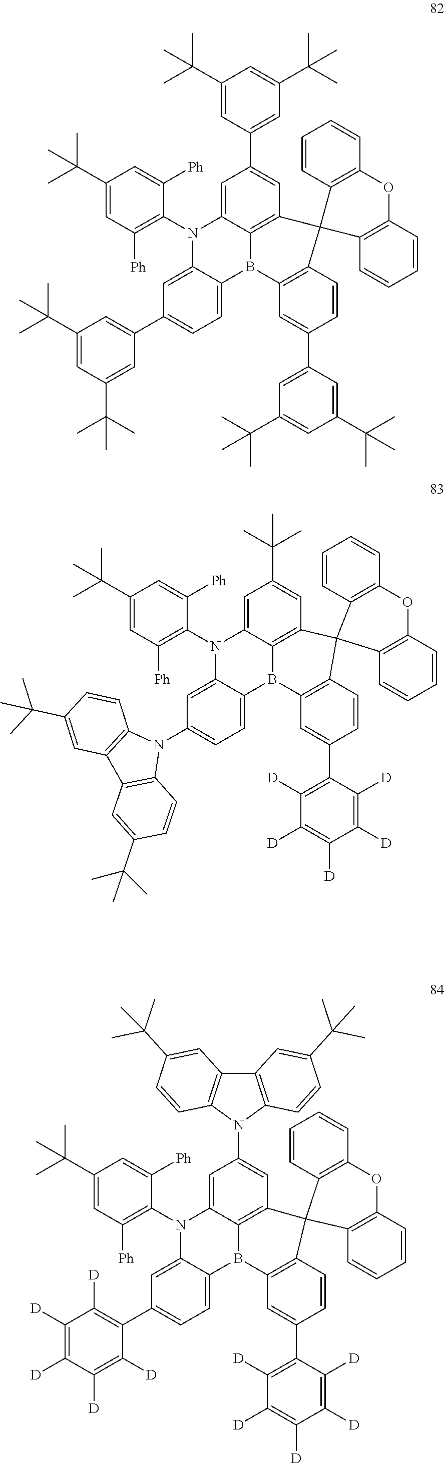

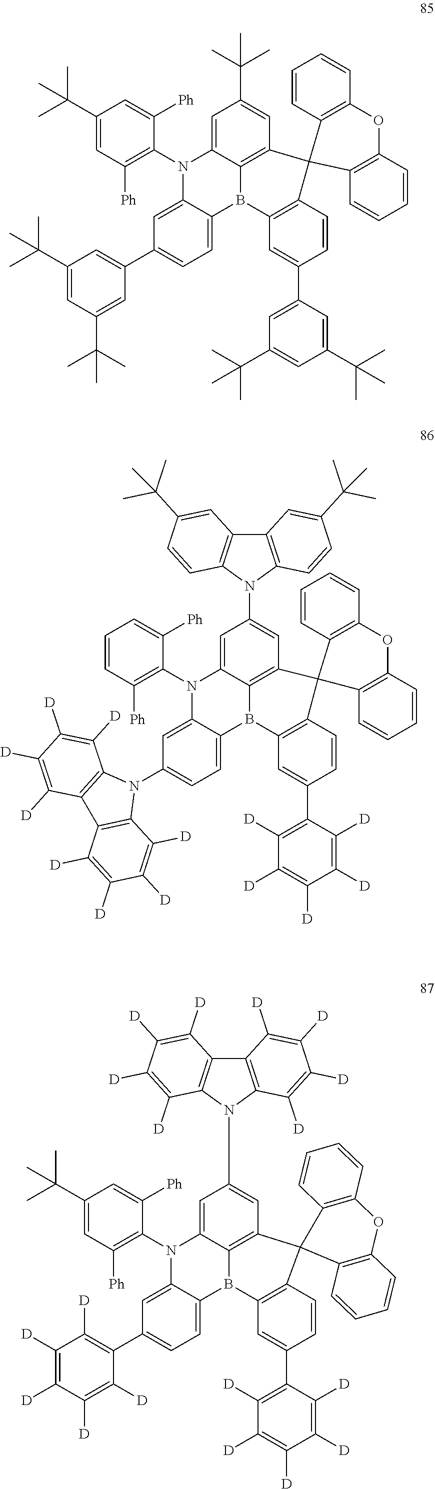

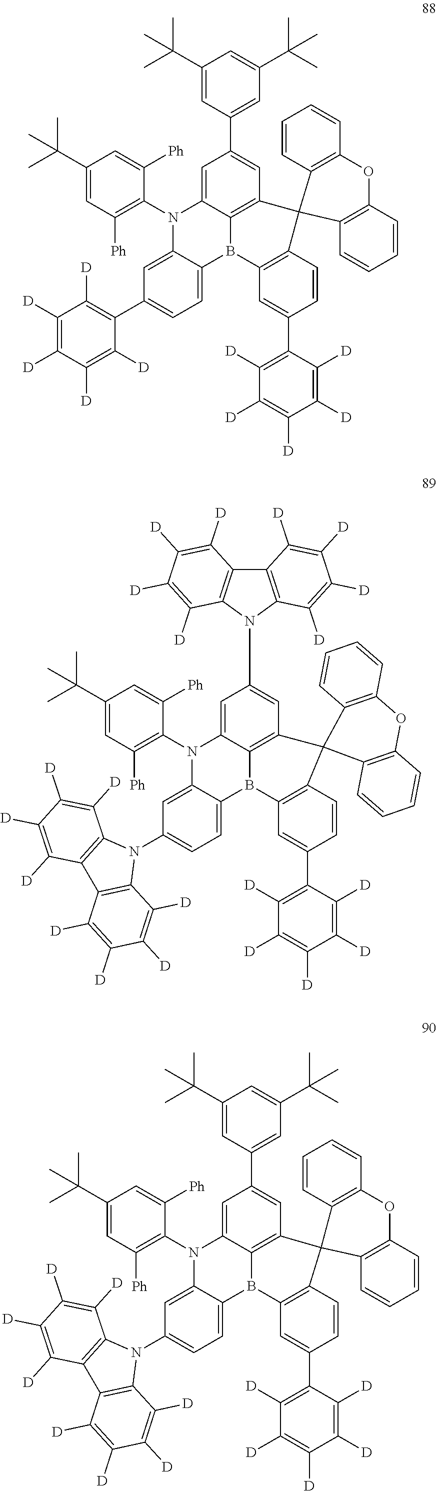

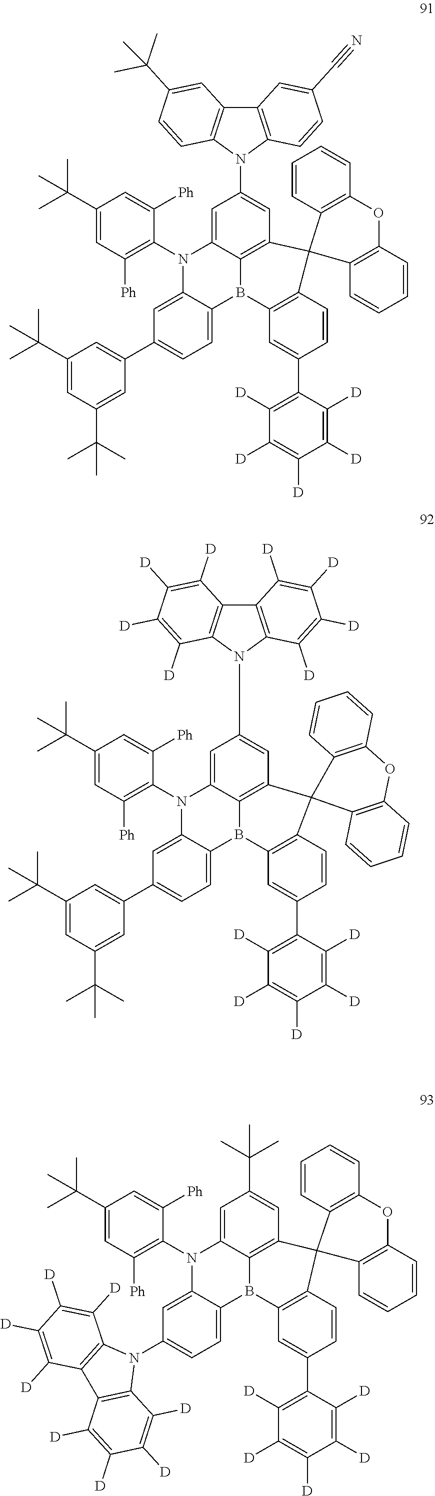

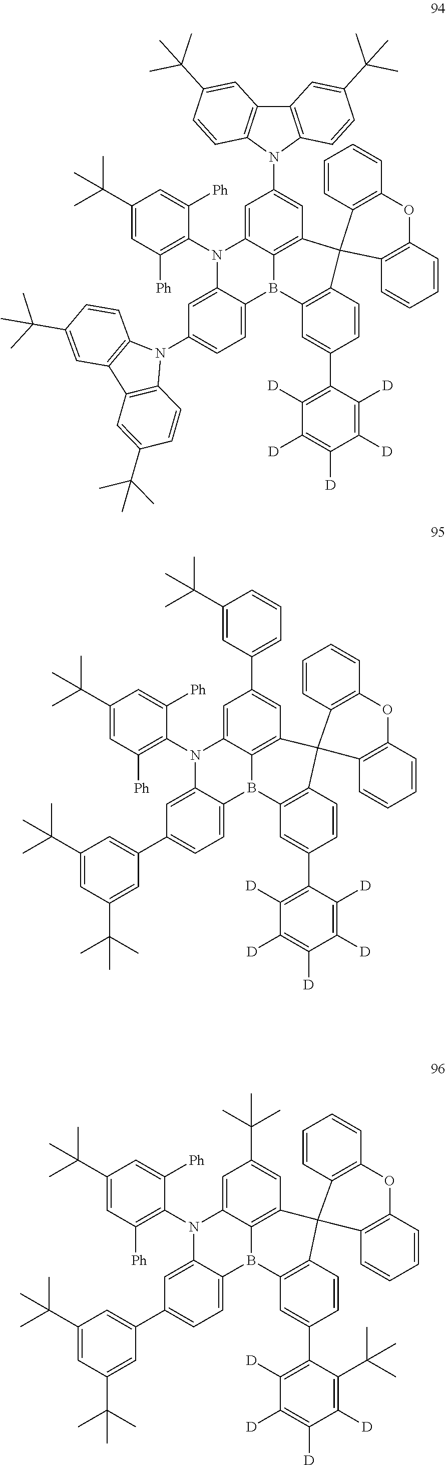

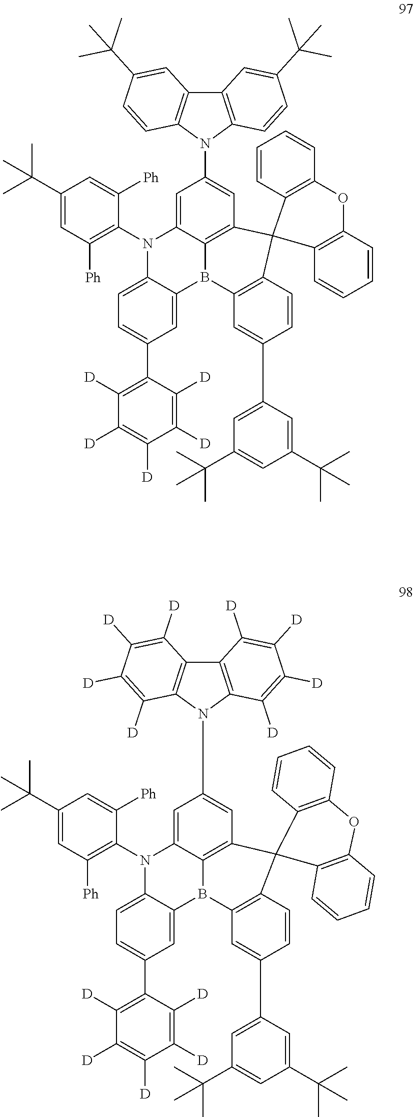 [SMILES: [2H]c1c([2H])c([2H])c(-c2ccc3c(c2)B2c4cc(-c5cc(C(C)(C)C)cc(C(C)(C)C)c5)ccc4C4(c5ccccc5Oc5ccccc54)c4cc(-n5c6ccc(C(C)(C)C)cc6c6cc(C(C)(C)C)ccc65)cc(c42)N3c2c(-c3ccccc3)cc(C(C)(C)C)cc2-c2ccccc2)c([2H])c1[2H] ; [2H]c1c([2H])c([2H])c(-c2ccc3c(c2)B2c4cc(-c5cc(C(C)(C)C)cc(C(C)(C)C)c5)ccc4C4(c5ccccc5Oc5ccccc54)c4cc(-n5c6c([2H])c([2H])c([2H])c([2H])c6c6c([2H])c([2H])c([2H])c([2H])c65)cc(c42)N3c2c(-c3ccccc3)cc(C(C)(C)C)cc2-c2ccccc2)c([2H])c1[2H]]

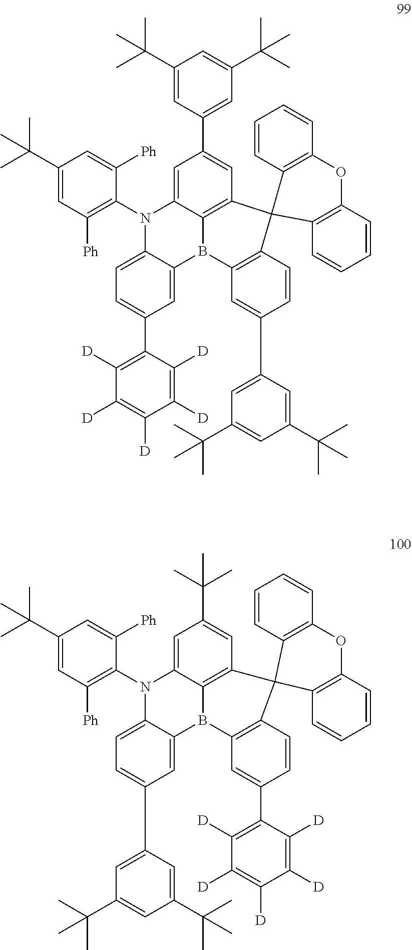 [SMILES: [2H]c1c([2H])c([2H])c(-c2ccc3c(c2)B2c4cc(-c5cc(C(C)(C)C)cc(C(C)(C)C)c5)ccc4C4(c5ccccc5Oc5ccccc54)c4cc(-c5cc(C(C)(C)C)cc(C(C)(C)C)c5)cc(c42)N3c2c(-c3ccccc3)cc(C(C)(C)C)cc2-c2ccccc2)c([2H])c1[2H] ; [2H]c1c([2H])c([2H])c(-c2ccc3c(c2)B2c4cc(-c5cc(C(C)(C)C)cc(C(C)(C)C)c5)ccc4N(c4c(-c5ccccc5)cc(C(C)(C)C)cc4-c4ccccc4)c4cc(C(C)(C)C)cc(c42)C32c3ccccc3Oc3ccccc32)c([2H])c1[2H]]

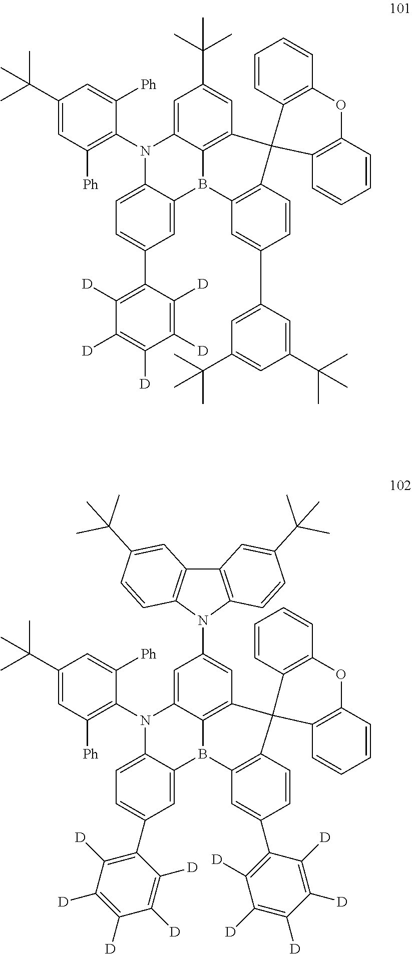 [SMILES: [2H]c1c([2H])c([2H])c(-c2ccc3c(c2)B2c4cc(-c5cc(C(C)(C)C)cc(C(C)(C)C)c5)ccc4C4(c5ccccc5Oc5ccccc54)c4cc(C(C)(C)C)cc(c42)N3c2c(-c3ccccc3)cc(C(C)(C)C)cc2-c2ccccc2)c([2H])c1[2H] ; [2H]c1c([2H])c([2H])c(-c2ccc3c(c2)B2c4cc(-c5c([2H])c([2H])c([2H])c([2H])c5[2H])ccc4C4(c5ccccc5Oc5ccccc54)c4cc(-n5c6ccc(C(C)(C)C)cc6c6cc(C(C)(C)C)ccc65)cc(c42)N3c2c(-c3ccccc3)cc(C(C)(C)C)cc2-c2ccccc2)c([2H])c1[2H]]

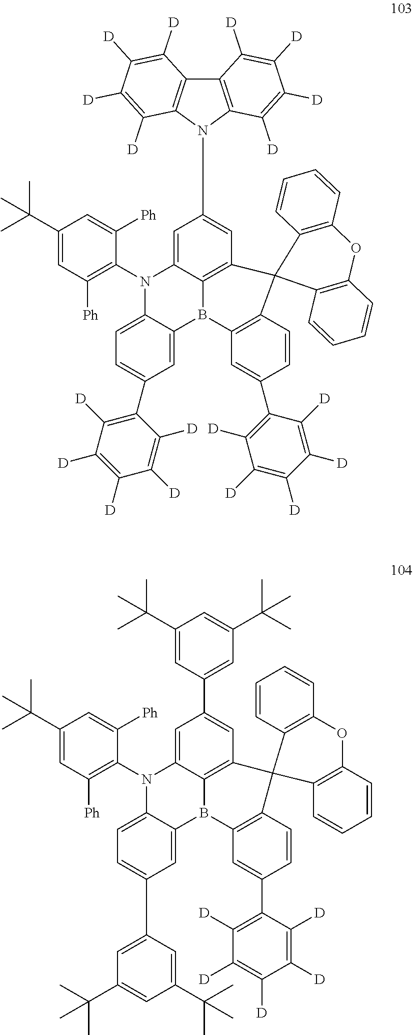 [SMILES: [2H]c1c([2H])c([2H])c(-c2ccc3c(c2)B2c4cc(-c5c([2H])c([2H])c([2H])c([2H])c5[2H])ccc4C4(c5ccccc5Oc5ccccc54)c4cc(-n5c6c([2H])c([2H])c([2H])c([2H])c6c6c([2H])c([2H])c([2H])c([2H])c65)cc(c42)N3c2c(-c3ccccc3)cc(C(C)(C)C)cc2-c2ccccc2)c([2H])c1[2H] ; [2H]c1c([2H])c([2H])c(-c2ccc3c(c2)B2c4cc(-c5cc(C(C)(C)C)cc(C(C)(C)C)c5)ccc4N(c4c(-c5ccccc5)cc(C(C)(C)C)cc4-c4ccccc4)c4cc(-c5cc(C(C)(C)C)cc(C(C)(C)C)c5)cc(c42)C32c3ccccc3Oc3ccccc32)c([2H])c1[2H]]

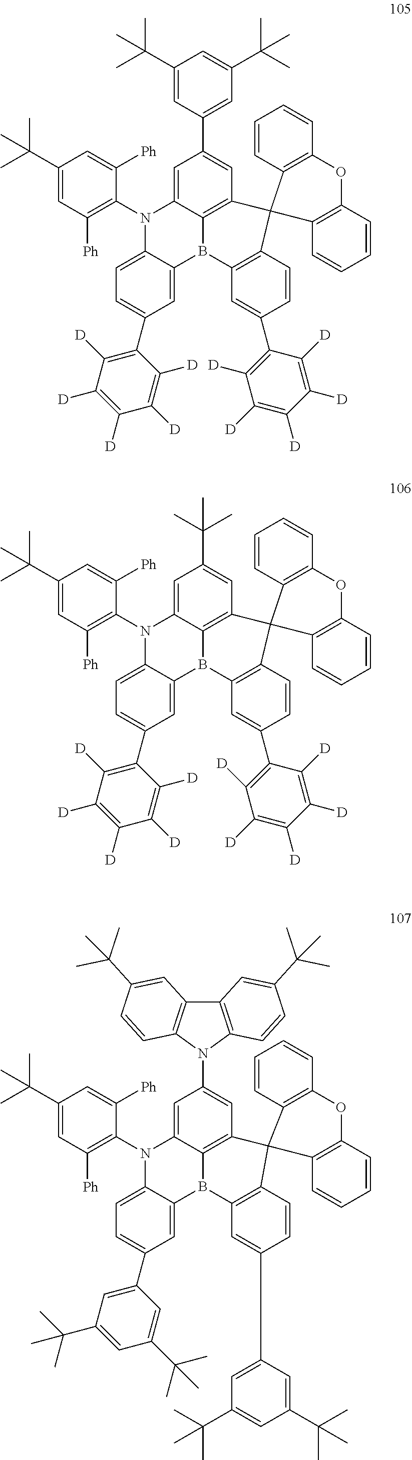

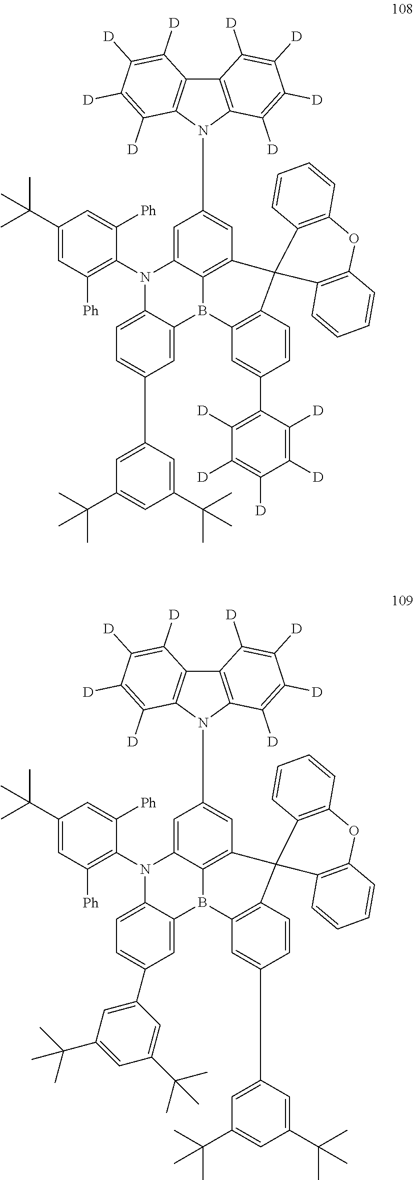 [SMILES: [2H]c1c([2H])c([2H])c(-c2ccc3c(c2)B2c4cc(-c5cc(C(C)(C)C)cc(C(C)(C)C)c5)ccc4N(c4c(-c5ccccc5)cc(C(C)(C)C)cc4-c4ccccc4)c4cc(-n5c6c([2H])c([2H])c([2H])c([2H])c6c6c([2H])c([2H])c([2H])c([2H])c65)cc(c42)C32c3ccccc3Oc3ccccc32)c([2H])c1[2H] ; [2H]c1c([2H])c([2H])c2c(c1[2H])c1c([2H])c([2H])c([2H])c([2H])c1n2-c1cc2c3c(c1)C1(c4ccccc4Oc4ccccc41)c1ccc(-c4cc(C(C)(C)C)cc(C(C)(C)C)c4)cc1B3c1cc(-c3cc(C(C)(C)C)cc(C(C)(C)C)c3)ccc1N2c1c(-c2ccccc2)cc(C(C)(C)C)cc1-c1ccccc1]

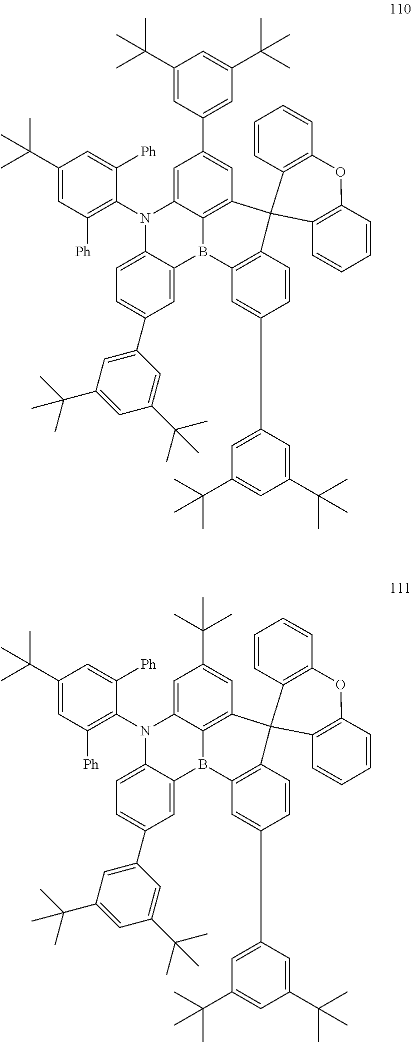 [SMILES: CC(C)(C)c1cc(-c2ccc3c(c2)B2c4cc(-c5cc(C(C)(C)C)cc(C(C)(C)C)c5)ccc4C4(c5ccccc5Oc5ccccc54)c4cc(-c5cc(C(C)(C)C)cc(C(C)(C)C)c5)cc(c42)N3c2c(-c3ccccc3)cc(C(C)(C)C)cc2-c2ccccc2)cc(C(C)(C)C)c1 ; CC(C)(C)c1cc(-c2ccc3c(c2)B2c4cc(-c5cc(C(C)(C)C)cc(C(C)(C)C)c5)ccc4C4(c5ccccc5Oc5ccccc54)c4cc(C(C)(C)C)cc(c42)N3c2c(-c3ccccc3)cc(C(C)(C)C)cc2-c2ccccc2)cc(C(C)(C)C)c1]

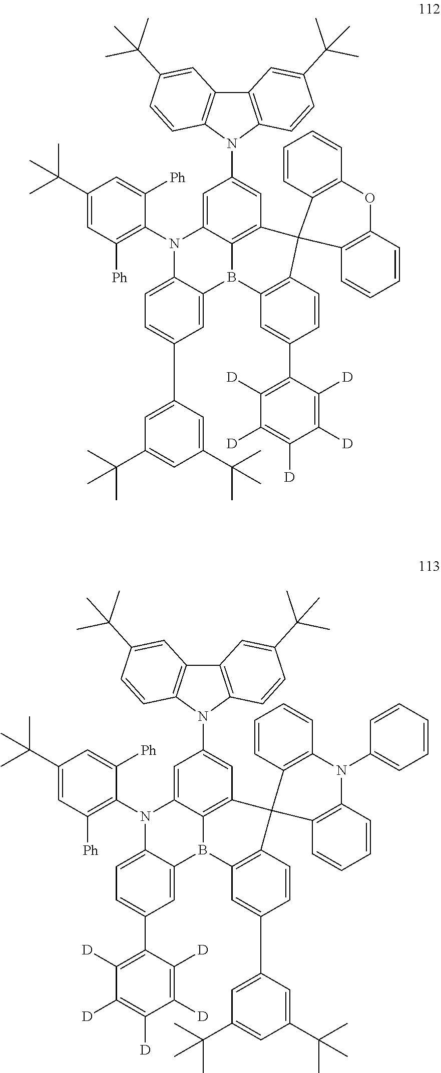 [SMILES: [2H]c1c([2H])c([2H])c(-c2ccc3c(c2)B2c4cc(-c5cc(C(C)(C)C)cc(C(C)(C)C)c5)ccc4N(c4c(-c5ccccc5)cc(C(C)(C)C)cc4-c4ccccc4)c4cc(-n5c6ccc(C(C)(C)C)cc6c6cc(C(C)(C)C)ccc65)cc(c42)C32c3ccccc3Oc3ccccc32)c([2H])c1[2H] ; [2H]c1c([2H])c([2H])c(-c2ccc3c(c2)B2c4cc(-c5cc(C(C)(C)C)cc(C(C)(C)C)c5)ccc4C4(c5ccccc5N(c5ccccc5)c5ccccc54)c4cc(-n5c6ccc(C(C)(C)C)cc6c6cc(C(C)(C)C)ccc65)cc(c42)N3c2c(-c3ccccc3)cc(C(C)(C)C)cc2-c2ccccc2)c([2H])c1[2H]]

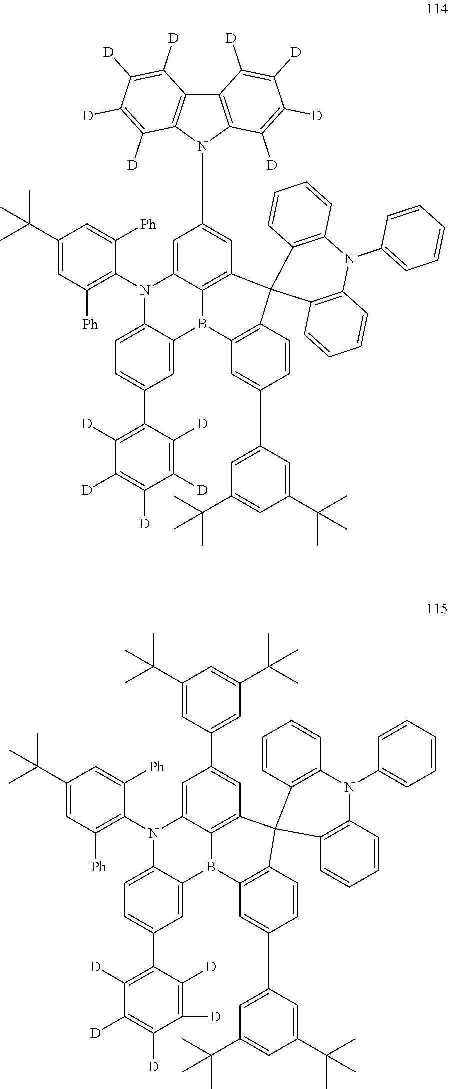 [SMILES: [2H]c1c([2H])c([2H])c(-c2ccc3c(c2)B2c4cc(-c5cc(C(C)(C)C)cc(C(C)(C)C)c5)ccc4C4(c5ccccc5N(c5ccccc5)c5ccccc54)c4cc(-n5c6c([2H])c([2H])c([2H])c([2H])c6c6c([2H])c([2H])c([2H])c([2H])c65)cc(c42)N3c2c(-c3ccccc3)cc(C(C)(C)C)cc2-c2ccccc2)c([2H])c1[2H] ; [2H]c1c([2H])c([2H])c(-c2ccc3c(c2)B2c4cc(-c5cc(C(C)(C)C)cc(C(C)(C)C)c5)ccc4C4(c5ccccc5N(c5ccccc5)c5ccccc54)c4cc(-c5cc(C(C)(C)C)cc(C(C)(C)C)c5)cc(c42)N3c2c(-c3ccccc3)cc(C(C)(C)C)cc2-c2ccccc2)c([2H])c1[2H]]

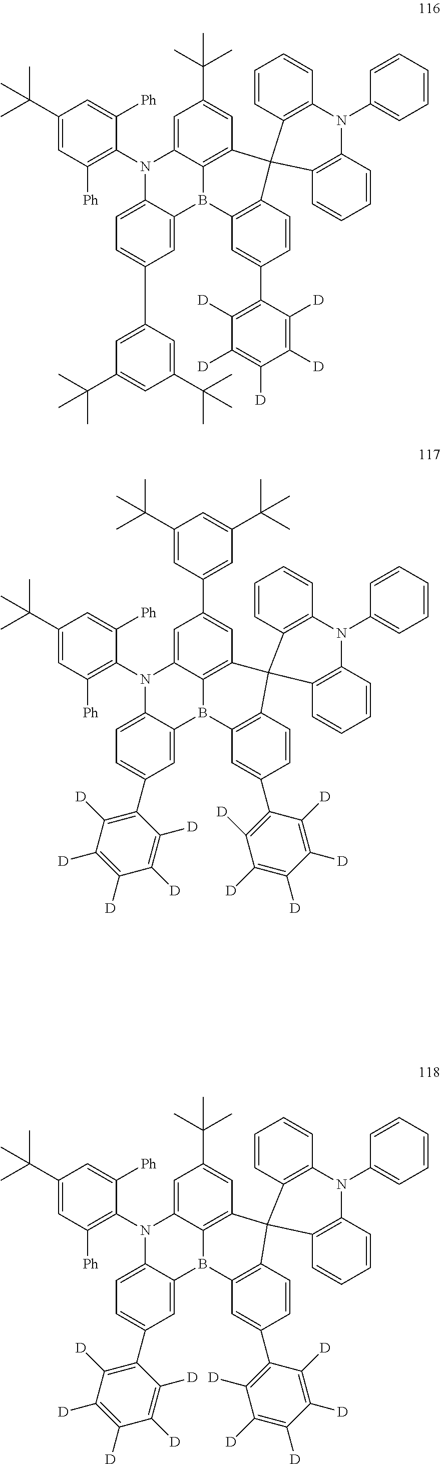

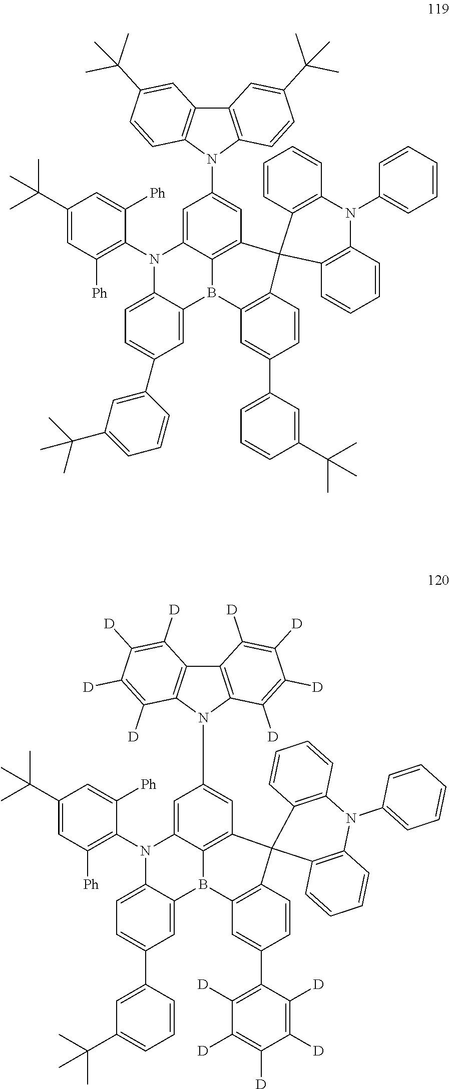 [SMILES: CC(C)(C)c1cccc(-c2ccc3c(c2)B2c4cc(-c5cccc(C(C)(C)C)c5)ccc4C4(c5ccccc5N(c5ccccc5)c5ccccc54)c4cc(-n5c6ccc(C(C)(C)C)cc6c6cc(C(C)(C)C)ccc65)cc(c42)N3c2c(-c3ccccc3)cc(C(C)(C)C)cc2-c2ccccc2)c1 ; [2H]c1c([2H])c([2H])c(-c2ccc3c(c2)B2c4cc(-c5cccc(C(C)(C)C)c5)ccc4N(c4c(-c5ccccc5)cc(C(C)(C)C)cc4-c4ccccc4)c4cc(-n5c6c([2H])c([2H])c([2H])c([2H])c6c6c([2H])c([2H])c([2H])c([2H])c65)cc(c42)C32c3ccccc3N(c3ccccc3)c3ccccc32)c([2H])c1[2H]]

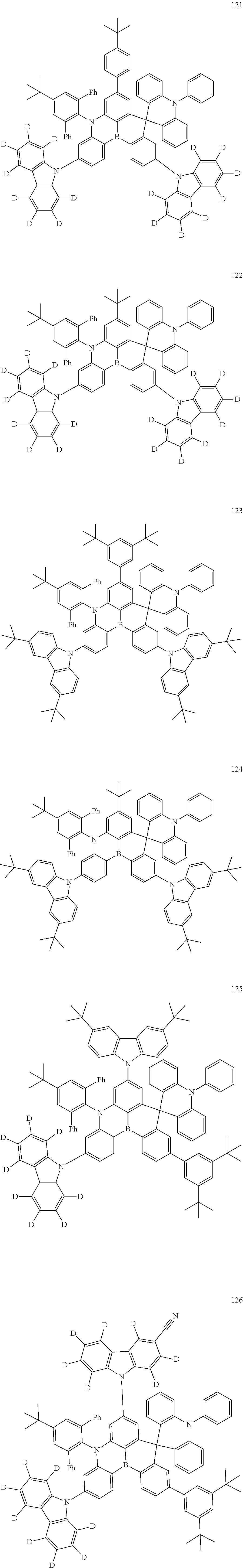

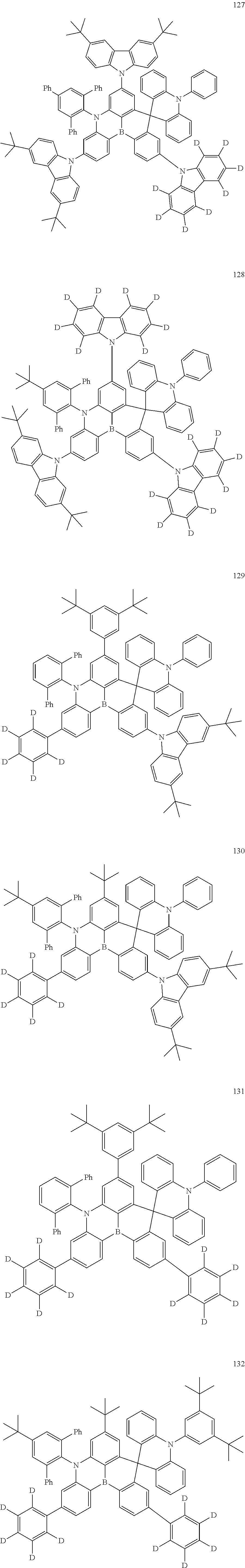

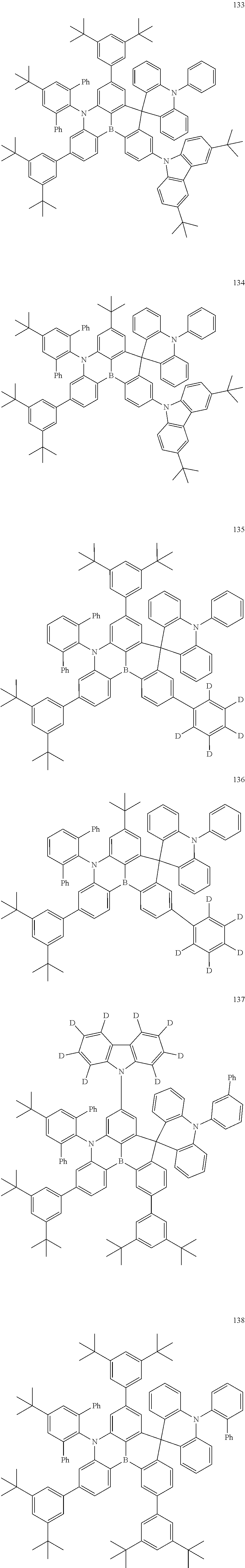

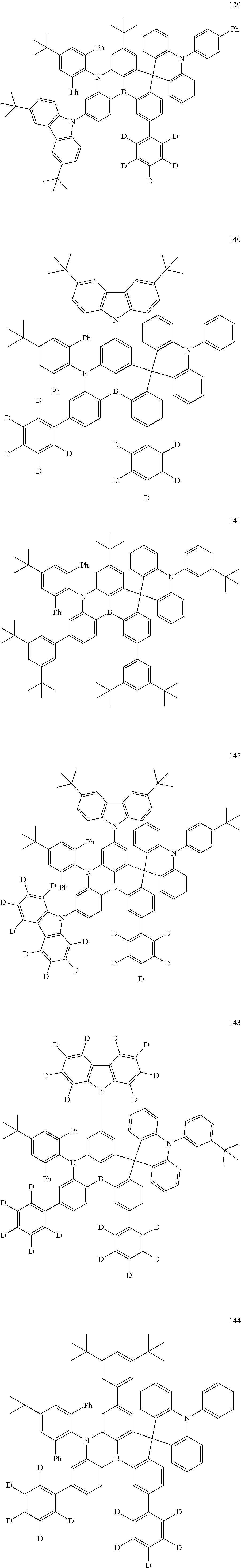

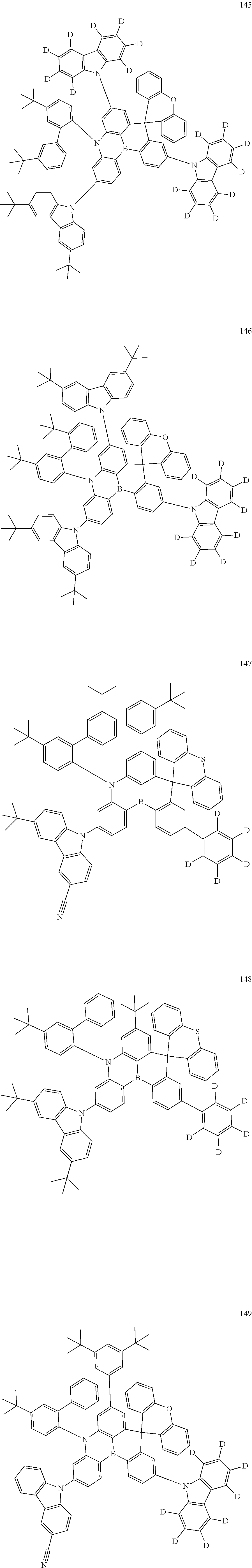

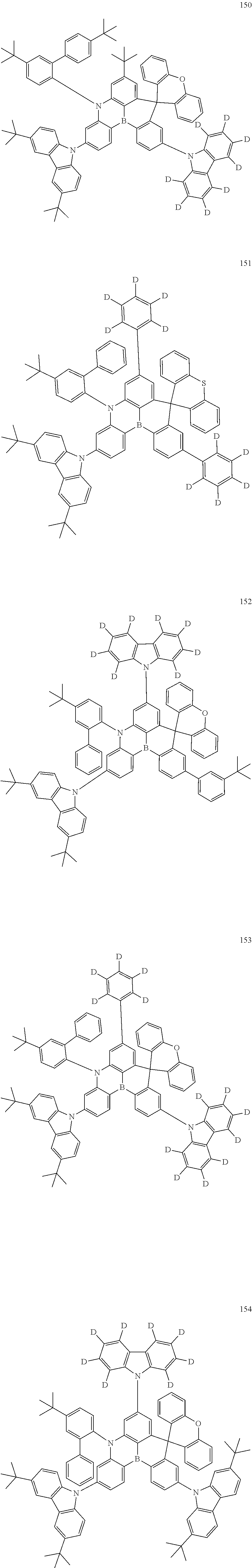

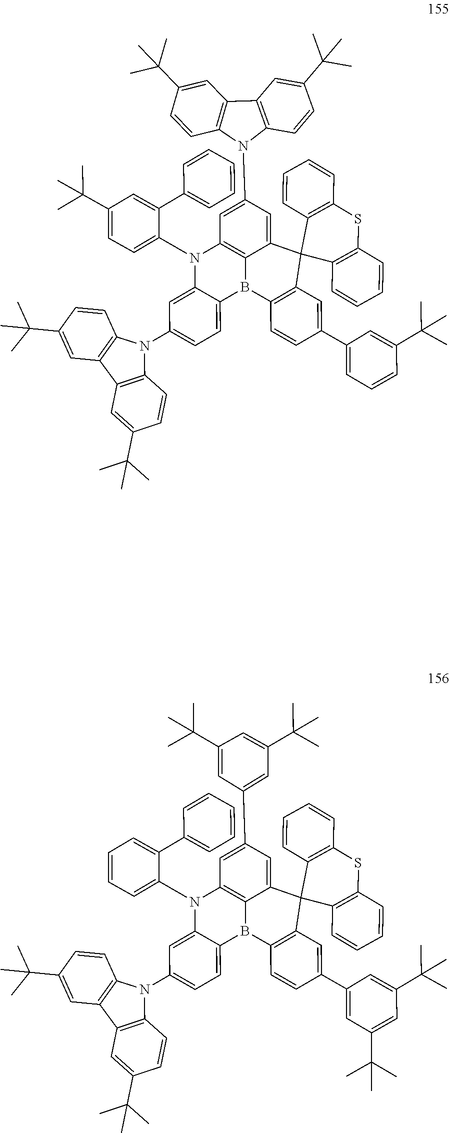

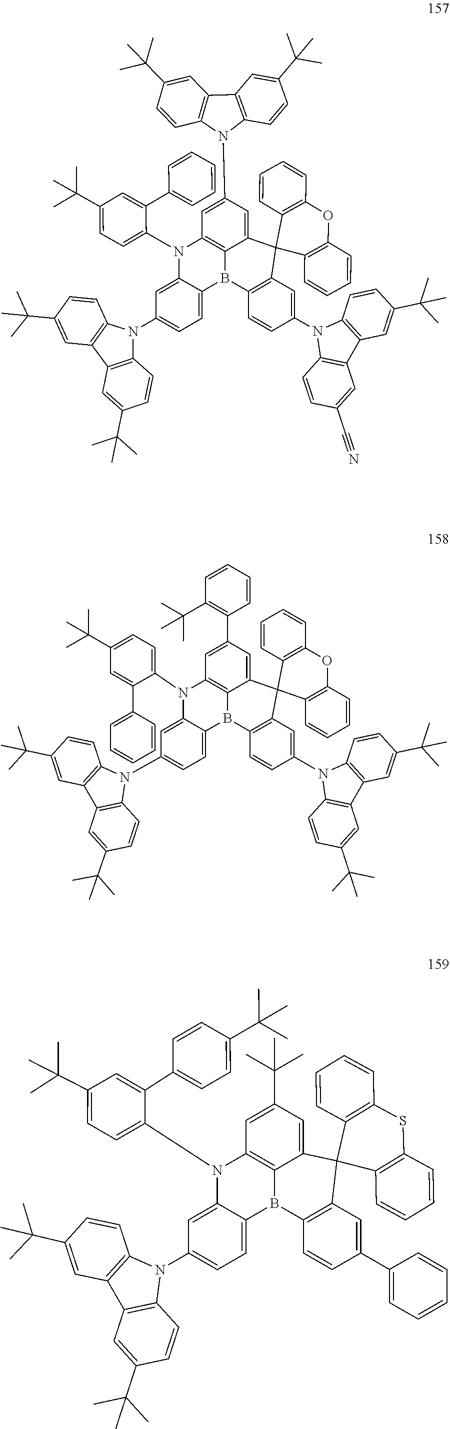

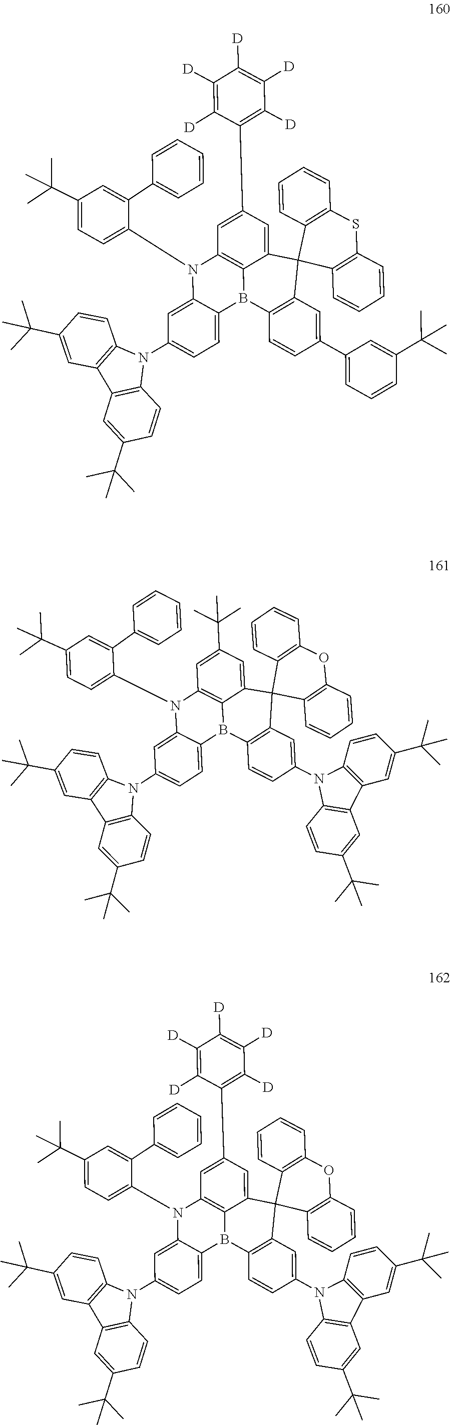

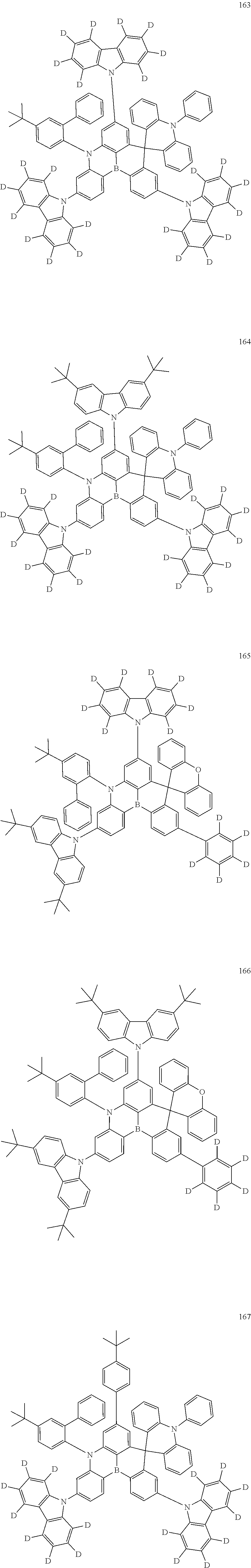

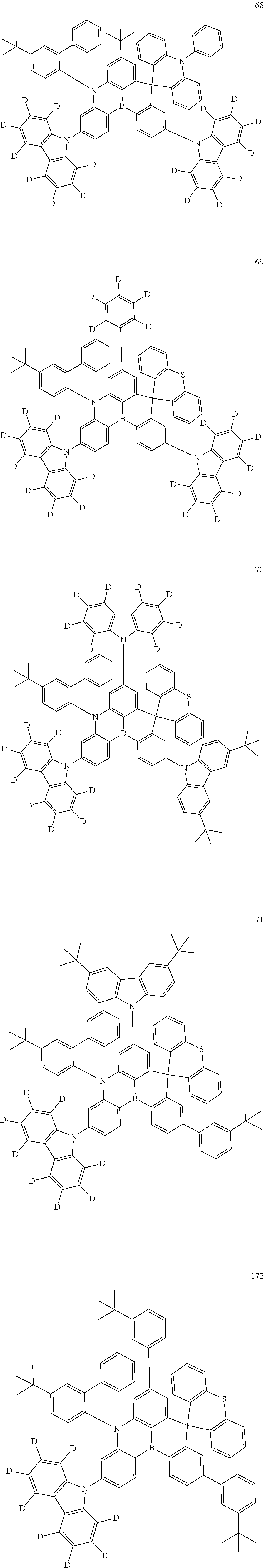

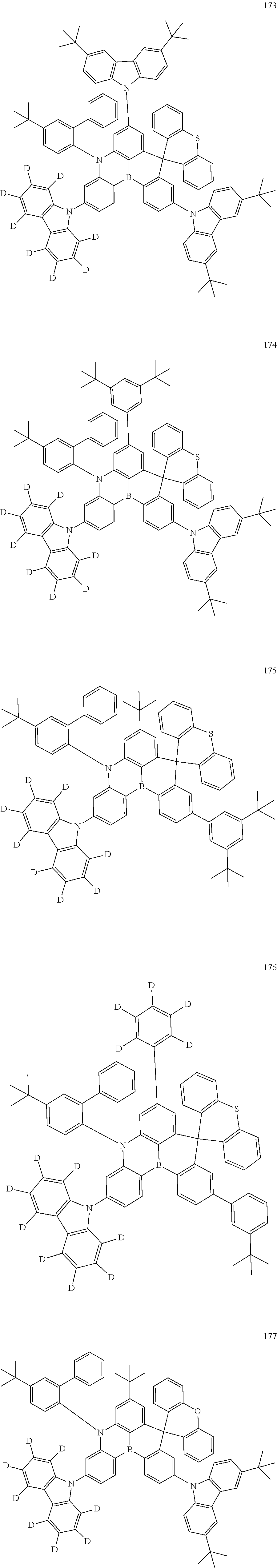

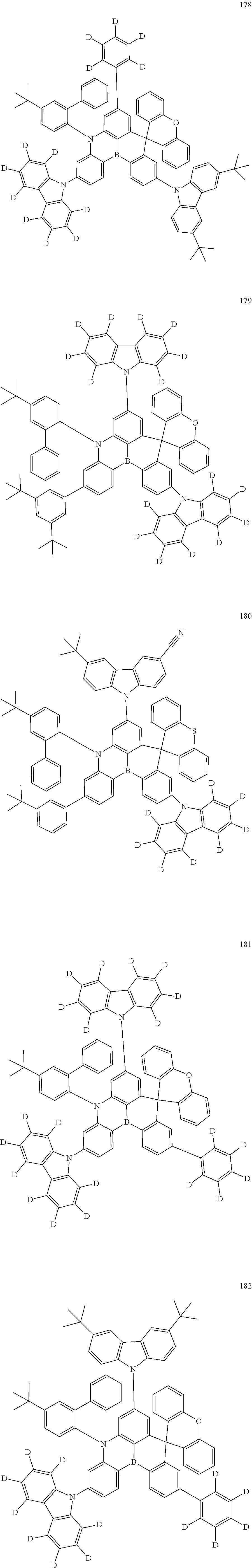

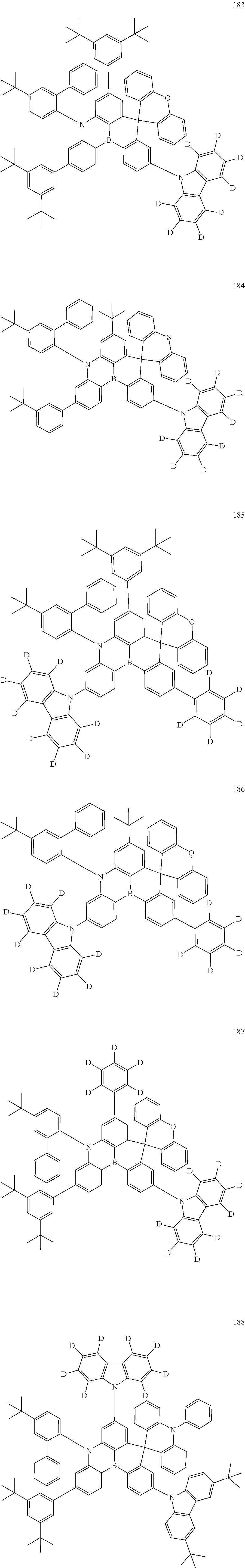

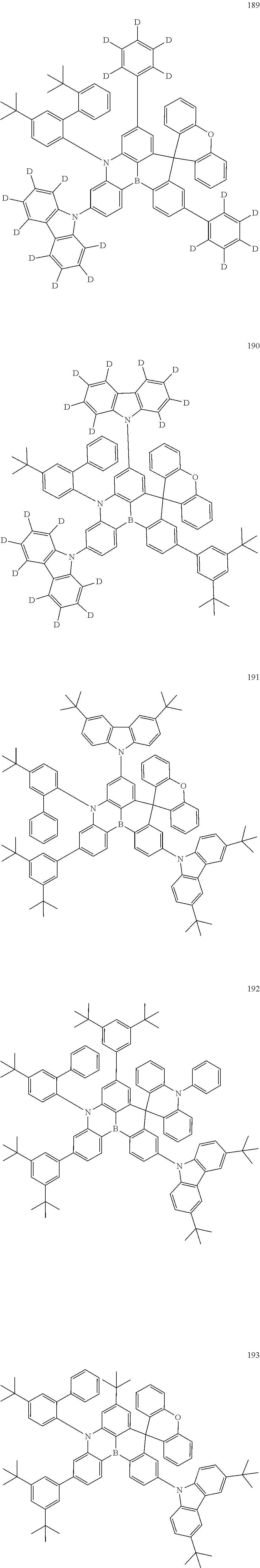

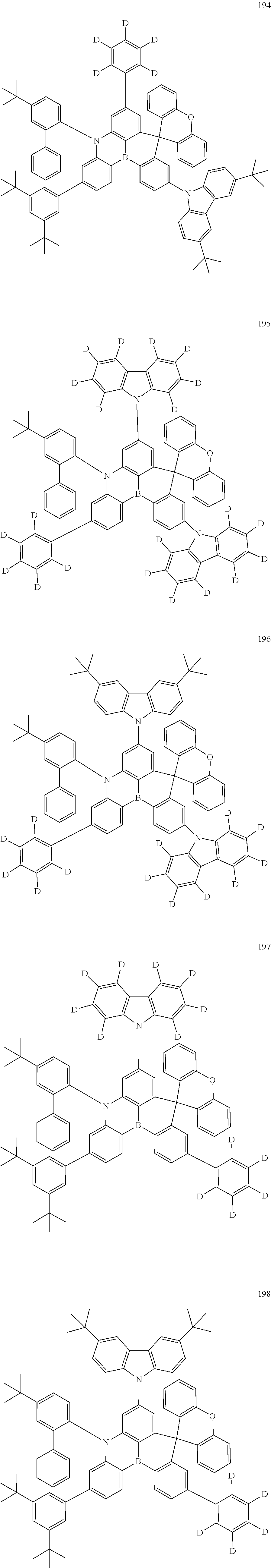

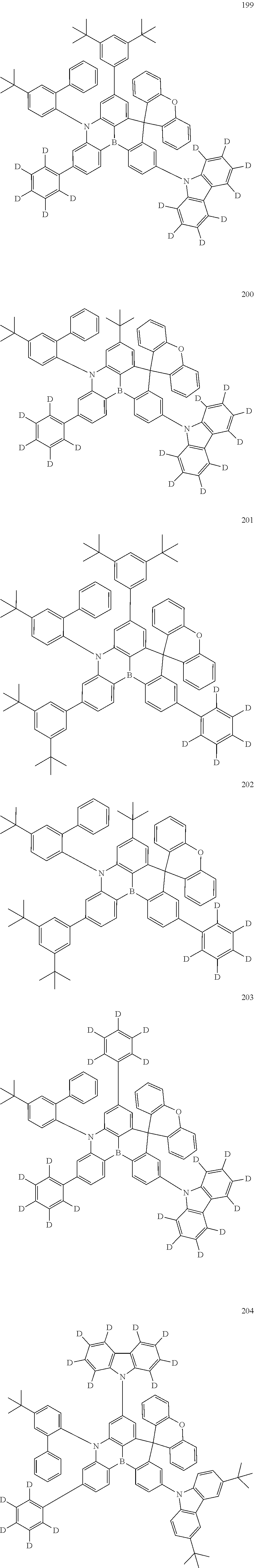

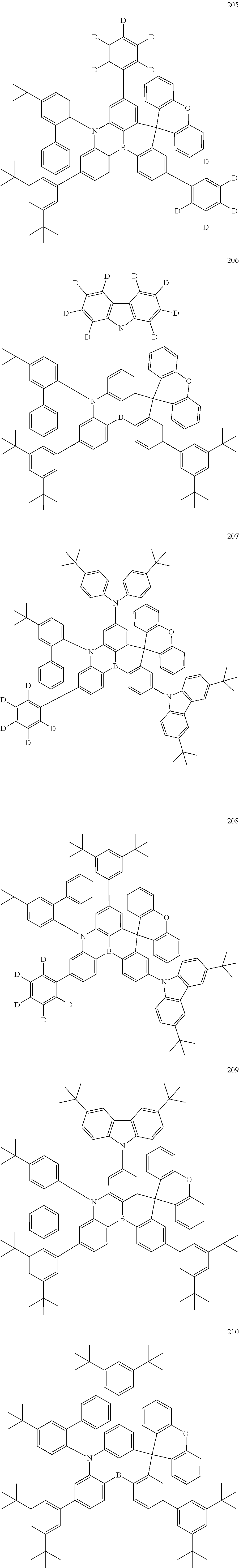

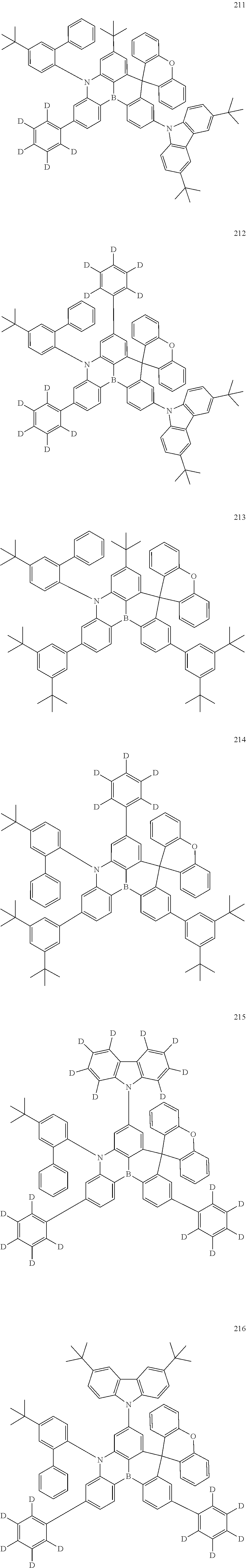

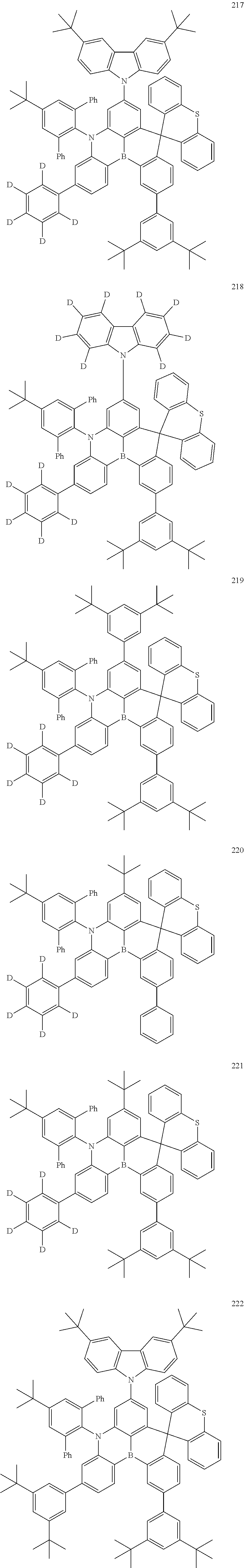

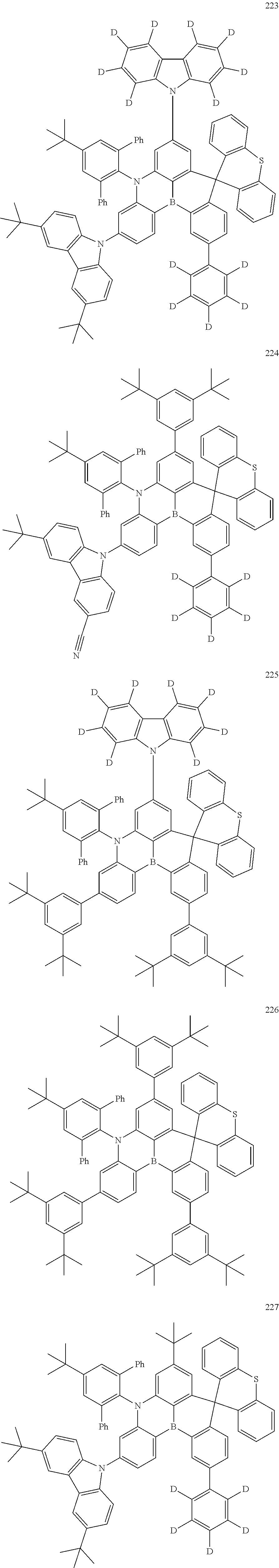

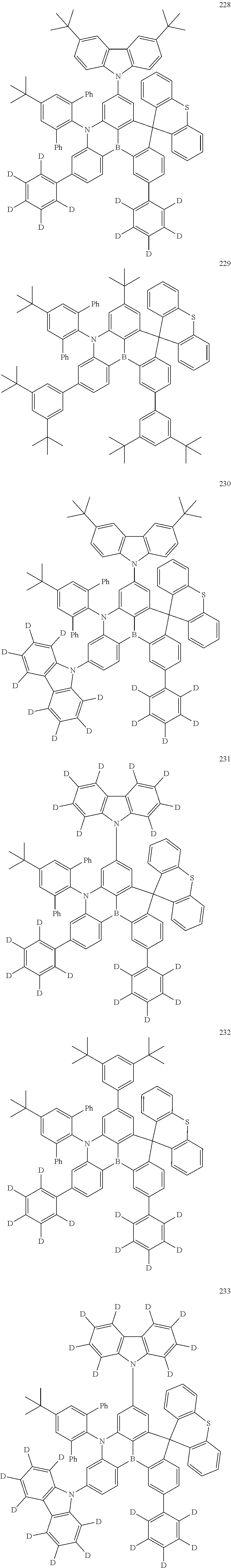

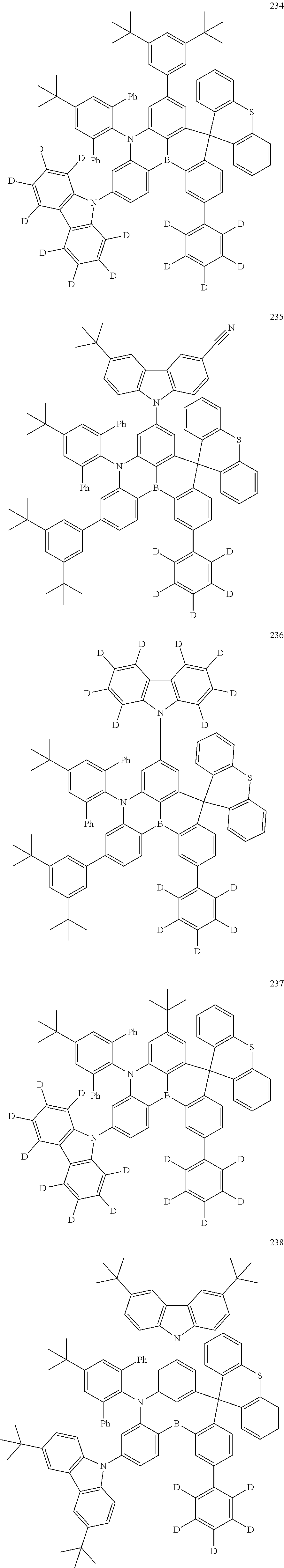

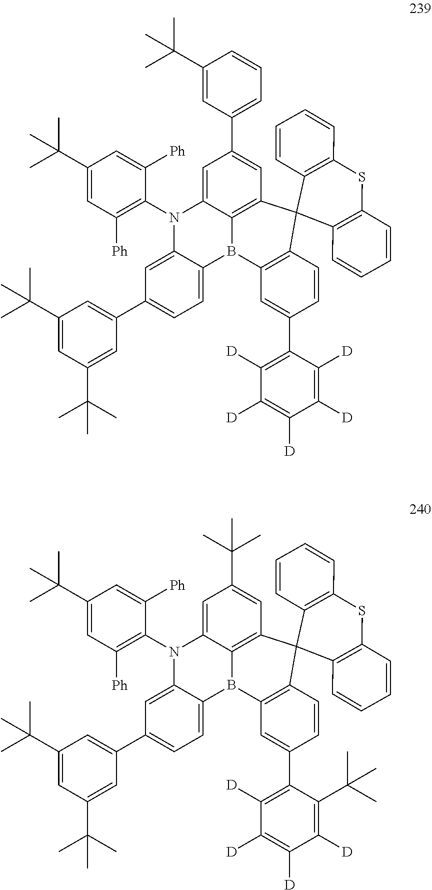 [SMILES: [2H]c1c([2H])c([2H])c(-c2ccc3c(c2)B2c4ccc(-c5cc(C(C)(C)C)cc(C(C)(C)C)c5)cc4N(c4c(-c5ccccc5)cc(C(C)(C)C)cc4-c4ccccc4)c4cc(-c5cccc(C(C)(C)C)c5)cc(c42)C32c3ccccc3Sc3ccccc32)c([2H])c1[2H] ; [2H]c1c([2H])c([2H])c(C(C)(C)C)c(-c2ccc3c(c2)B2c4ccc(-c5cc(C(C)(C)C)cc(C(C)(C)C)c5)cc4N(c4c(-c5ccccc5)cc(C(C)(C)C)cc4-c4ccccc4)c4cc(C(C)(C)C)cc(c42)C32c3ccccc3Sc3ccccc32)c1[2H]]

In the example compounds in Compound Group 1, “D” refers to deuterium, and “Ph” refers to an unsubstituted phenyl group.

The fused polycyclic compound represented by Formula 1 according to one or more embodiments has a structure in which a first substituent and a second substituent are introduced into a fused ring core, and may accomplish and achieve high emission efficiency and long lifetime.

The fused polycyclic compound of one or more embodiments represented by Formula 1 may include a fused ring core in which first to third aromatic rings are fused by a boron atom, a first nitrogen atom, and a first carbon atom, and may have a structure in which a first substituent is connected with (e.g., bonded to) the first carbon atom. The first substituent may include a fourth aromatic ring, a fifth aromatic ring, and a first sub-substituent connecting the fourth aromatic ring and the fifth aromatic ring. The first substituent may be combined with (e.g., bonded to) the first carbon atom of the fused ring core. Each of the fourth aromatic ring and the fifth aromatic ring of the first substituent may be combined with (e.g., bonded to) the first carbon atom of the fused ring core. For example, the first substituent may be connected with (e.g., bonded to) the first carbon atom via a spiro bond. Because the fourth aromatic ring and the fifth aromatic ring are connected by sharing the first carbon atom which is an spa carbon, a twisted non-coplanar structure may be made/formed at the position of the first carbon atom. Accordingly, the fused polycyclic compound of one or more embodiments has improved rigidity properties at a center part (e.g., the fused ring core) and may be accompanied with a phenomenon of reducing a full width at half maximum of emission spectrum. Also, intermolecular distance may be increased, quenching phenomenon due to intermolecular stacking may be suppressed or reduced, and emission efficiency properties may be improved. In some embodiments, due to the increase in the rigidity of molecule, the fused polycyclic compound of one or more embodiments represented by Formula 1 may show small structural change in an excited state and a ground state that markedly reduces Stokes shift, and accordingly, blue emission of high color purity may be achieved.

In addition, the fused polycyclic compound of one or more embodiments may effectively maintain the trigonal planar structure of a boron atom through steric hindrance effects due to the first substituent and the second substituent. In the case of a boron atom, electron-deficient properties of the boron atom may be shown by a vacant p-orbital, and a bond may be formed with a nucleophile to change into a tetrahedral structure, and this may be a factor of deteriorating a device. According to the present disclosure, the fused polycyclic compound of one or more embodiments introduces the first substituent and the second substituent in the fused ring core, and the vacant p-orbital of the boron atom may be effectively protected; thus, deterioration phenomenon by the structural deformation may be prevented or reduced.

In some embodiments, in the fused polycyclic compound of one or more embodiments, intermolecular interaction may be suppressed or reduced through steric hindrance effects by the first substituent and the second substituent, the aggregation of the fused polycyclic compound and the formation of excimer or exciplex may be controlled or selected, and thus, emission efficiency may be increased. The fused polycyclic compound of one or more embodiments represented by Formula 1 has a bulky structure, and distance between molecules may be increased, and Dexter energy transfer may be reduced. Consequently, the increase of the concentration of triplet excitons in the fused polycyclic compound may be suppressed or reduced. When the triple excitons of high concentration stay in an excited state for a long time, the decomposition of a compound may be induced, and the production of hot excitons having high energy produced through triplet-triplet annihilation (TTA) may be induced and prompted, thereby inducing the destruction of the structure of an adjacent compound. In addition, because the triplet-triplet annihilation is bimolecular reaction, triplet excitons utilized for emitting light are rapidly exhausted, and the deterioration of emission efficiency may be induced by non-radiative transition. In the present disclosure, according to the fused polycyclic compound of one or more embodiments, intermolecular distance may increase by the first substituent and the second substituent, Dexter energy transfer may be suppressed or reduced, and the deterioration of lifetime by the increase in the concentration of triplet excitons may be suppressed or reduced. Accordingly, when the fused polycyclic compound of one or more embodiments is applied to the emission layer EML of a light emitting device ED, emission efficiency may be increased, and device lifetime may be improved.

The emission spectrum of the fused polycyclic compound of one or more embodiments, represented by Formula 1, has a full width at half maximum of about 10-50 nm, or about 20-40 nm. Because the emission spectrum of the fused polycyclic compound (e.g., acting as a first dopant) of one or more embodiments, represented by Formula 1, has the above-described range of the full width at half maximum, when applied to a device, emission efficiency and/or color purity may be improved. In some embodiments, when utilized as a material for a blue light emitting device, device lifetime and/or color purity may be improved.

The fused polycyclic compound of one or more embodiments, represented by Formula 1, may be a material for emitting thermally activated delayed fluorescence. In one or more embodiments, the fused polycyclic compound represented by Formula 1 may be a thermally activated delayed fluorescence dopant having a difference (ΔE_{ST}) between the lowest triplet excitation energy level (T1 level) and the lowest singlet excitation energy level (S1 level) of about 0.6 eV or less. In one or more embodiments, the fused polycyclic compound represented by Formula 1 may be a thermally activated delayed fluorescence dopant having a difference (ΔE_{ST}) between the lowest triplet excitation energy level (T1 level) and the lowest singlet excitation energy level (S1 level) of about 0.2 eV or less.

The fused polycyclic compound of one or more embodiments, represented by Formula 1, may be a light-emitting material having a central wavelength of emission spectrum in a wavelength region of about 430 nm to about 490 nm. For example, in one or more embodiments, the fused polycyclic compound represented by Formula 1 may be a blue thermally activated delayed fluorescence (TADF) dopant. However, embodiments of the present disclosure are not limited thereto, and when the fused polycyclic compound of one or more embodiments is utilized as a light-emitting material, the fused polycyclic compound may be utilized as a dopant material to emit light in one or more suitable wavelength regions such as a red emitting dopant, and green emitting dopant.

In the light emitting device ED of one or more embodiments, the emission layer EML may be to emit delayed fluorescence. For example, in some embodiments, the emission layer EML may be to emit thermally activated delayed fluorescence (TADF).

In one or more embodiments, the emission layer EML of the light emitting device ED may be to emit blue light. For example, in one or more embodiments, the emission layer EML of an organic electroluminescence light emitting device ED may be to emit blue light in a region of about 490 nm to about 430 nm. However, embodiments of the present disclosure are not limited thereto, and the emission layer EML may be to emit green light or red light.

In one or more embodiments, the fused polycyclic compound of present disclosure may be included in an emission layer EML. The fused polycyclic compound of one or more embodiments may be included in an emission layer EML as a dopant material. The fused polycyclic compound of one or more embodiments may be a thermally activated delayed fluorescence emitting material. The fused polycyclic compound of one or more embodiments may be utilized as a thermally activated delayed fluorescence dopant. For example, in one or more embodiments, in the light emitting device ED, the emission layer EML may include at least one selected from among the fused polycyclic compounds represented in Compound Group 1 as a thermally delayed fluorescence dopant. However, the utilization of the fused polycyclic compound of one or more embodiments is not limited thereto.

In one or more embodiments, the emission layer EML may include a plurality of compounds. The emission layer EML of one or more embodiments may include the fused polycyclic compound represented by Formula 1, i.e., the first compound, and at least one selected from among a second compound represented by Formula HT-1, a third compound represented by Formula ET-1, and a fourth compound represented by Formula D-1.

In one or more embodiments, the emission layer EML may further include a second compound represented by Formula HT-1. In one or more embodiments, the second compound may be utilized as a hole transport host material in the emission layer EML.

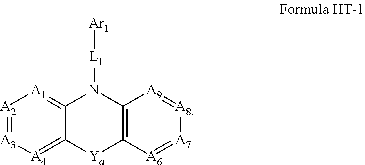

In Formula HT-1, A₁ to A₄ and A₆ to A₉ may each independently be N or CR₅₁. For example, all A₁ to A₄ and A₆ to A₉ may be CR₅₁. In some embodiments, any one selected from among A₁ to A₄ and A₆ to A₉ may be N, and the remainder may be CR₅₁.

In Formula HT-1, Li may be a direct linkage, a substituted or unsubstituted arylene group of 6 to 30 ring-forming carbon atoms, or a substituted or unsubstituted heteroarylene group of 2 to 30 ring-forming carbon atoms. For example, in one or more embodiments, Li may be a direct linkage, a substituted or unsubstituted phenylene group, a substituted or unsubstituted divalent biphenyl group, a substituted or unsubstituted divalent carbazole group, and/or the like, but embodiments of the present disclosure are not limited thereto.

In Formula HT-1, Yₐ may be a direct linkage, CR₅₂R₅₃, or SiR₅₄R₅₅. For example, it may refer to that two benzene rings connected with the nitrogen atom of Formula HT-1 may be connected via a direct linkage,

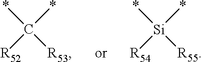

In Formula HT-1, when Yₐ is a direct linkage, the substituent represented by Formula HT-1 may include a carbazole moiety.

In Formula HT-1, An may be a substituted or unsubstituted aryl group of 6 to ring-forming carbon atoms, or a substituted or unsubstituted heteroaryl group of 2 to ring-forming carbon atoms. For example, in one or more embodiments, An may be a substituted or unsubstituted carbazole group, a substituted or unsubstituted dibenzofuran group, a substituted or unsubstituted dibenzothiophene group, a substituted or unsubstituted biphenyl group, and/or the like, but embodiments of the present disclosure are not limited thereto.

In Formula HT-1, R₅₁ to R₅₅ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 60 ring-forming carbon atoms. In some embodiments, each of R₅₁ to R₅₅ may be combined with an adjacent group to form a ring. In some embodiments, R₅₁ to R₅₅ may each independently be hydrogen or deuterium. In some embodiments, R₅₁ to R₅₅ may each independently be an unsubstituted methyl group or an unsubstituted phenyl group.

In one or more embodiments, the second compound represented by Formula HT-1 may be represented by any one selected from among compounds represented in Compound Group 2. The emission layer EML may include at least one selected from among the compounds represented in Compound Group 2 as a hole transport host material.

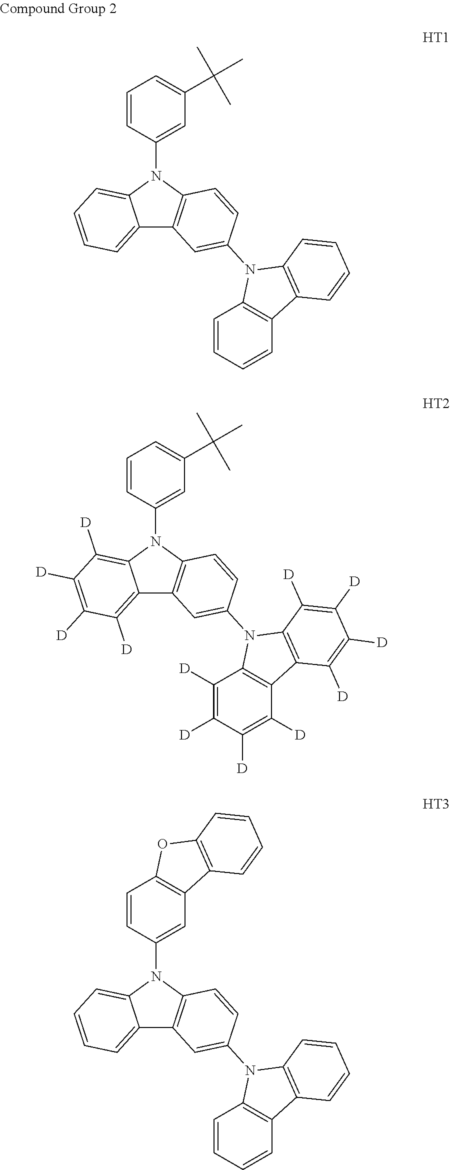 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

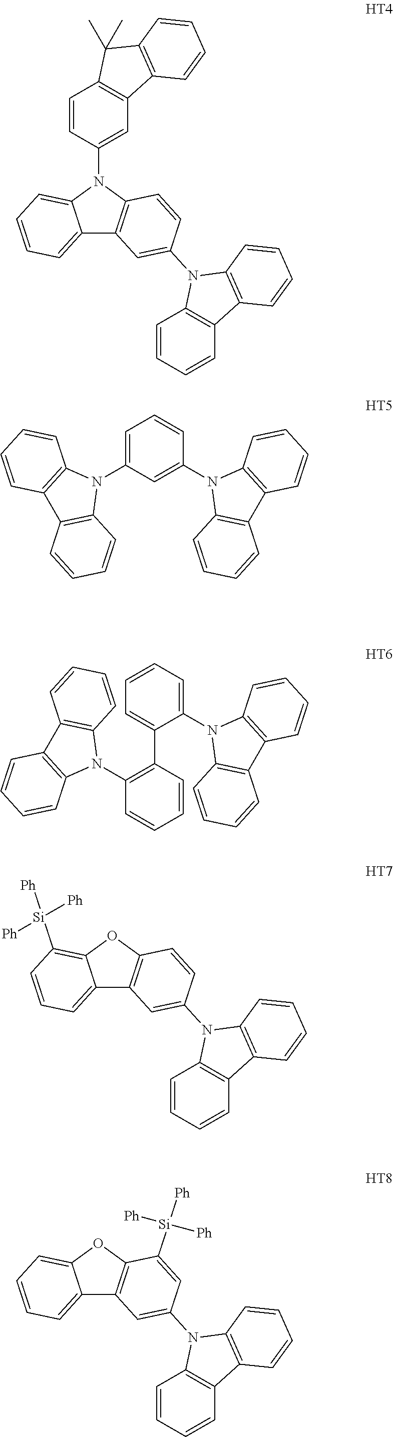 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

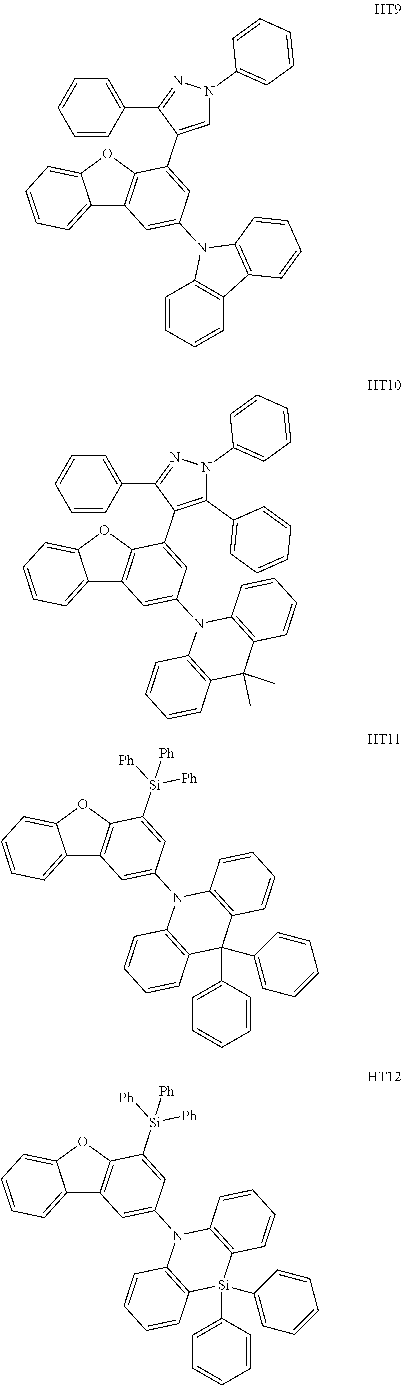

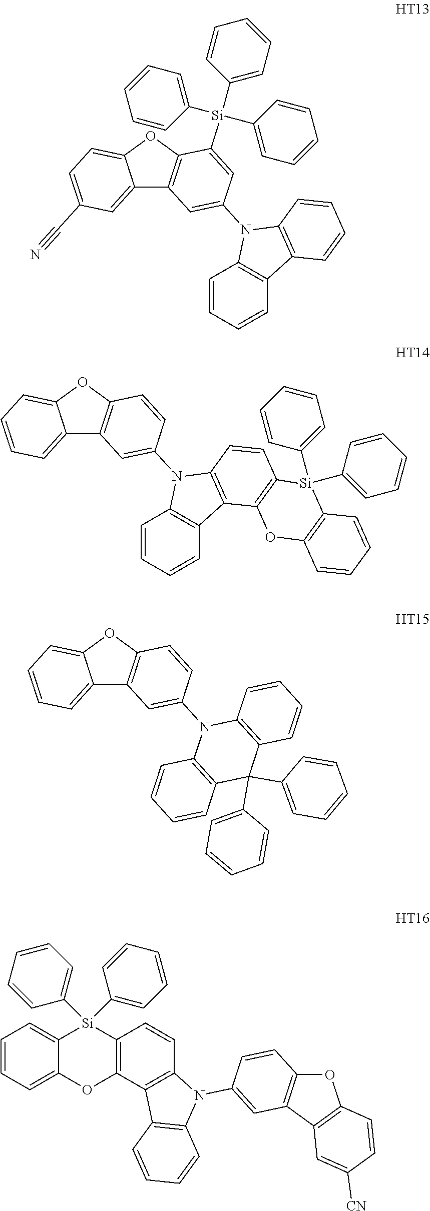 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc(C2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

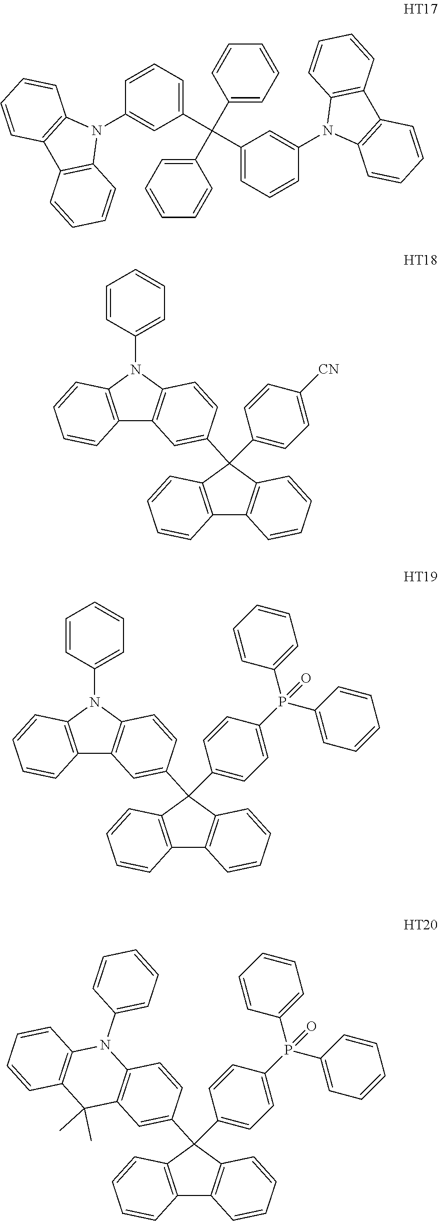 [SMILES: c1ccc(C(c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

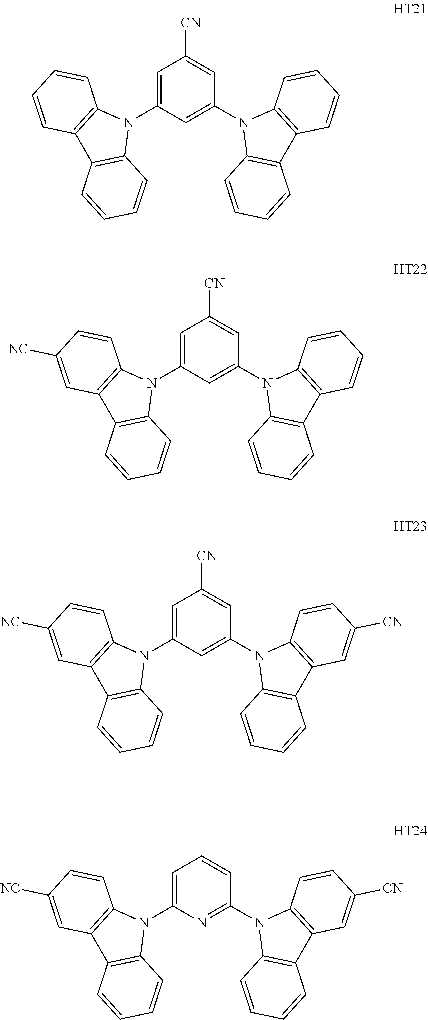 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

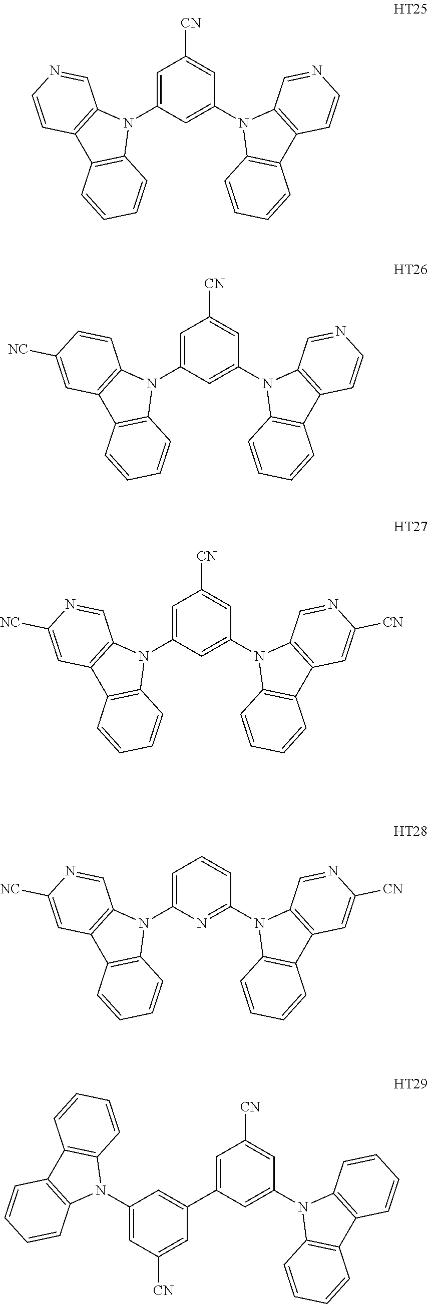 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1]

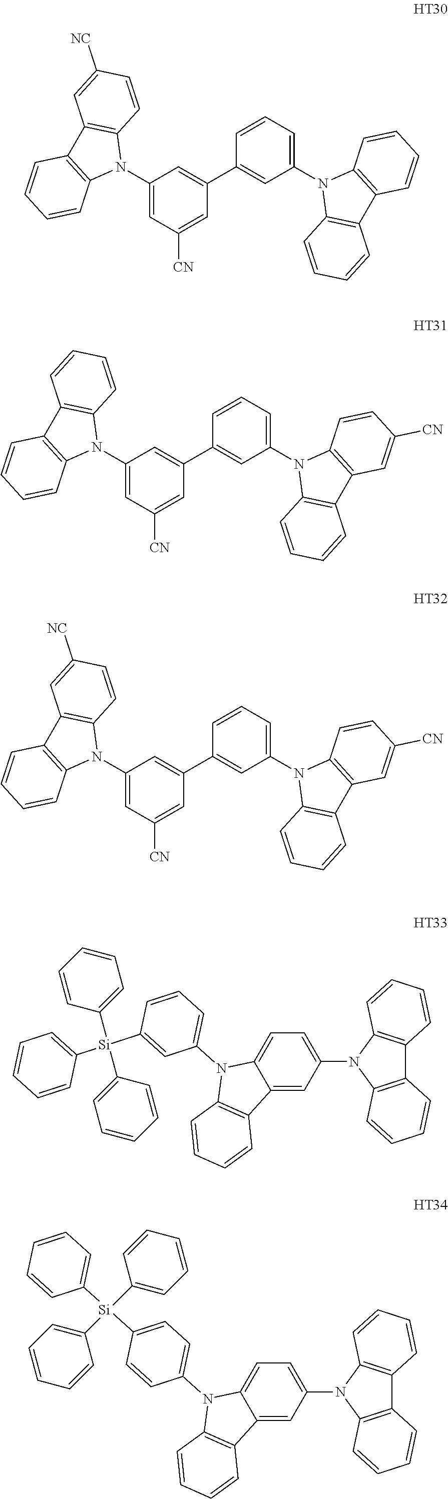 [SMILES: N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2ccc(-n3c4ccccc4c4cc(-n5c6ccccc6c6ccccc65)ccc43)cc2)cc1]

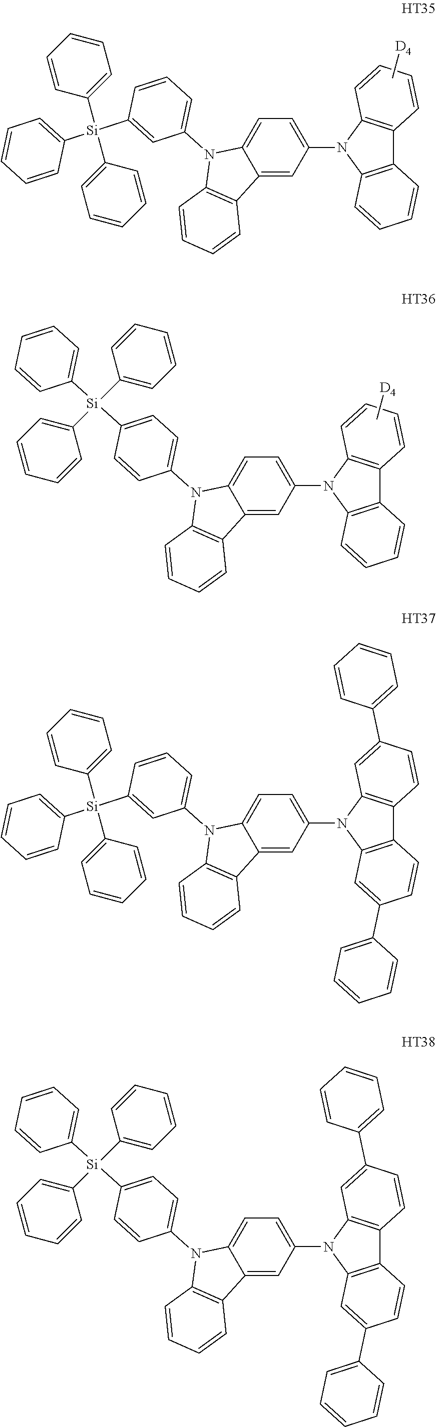

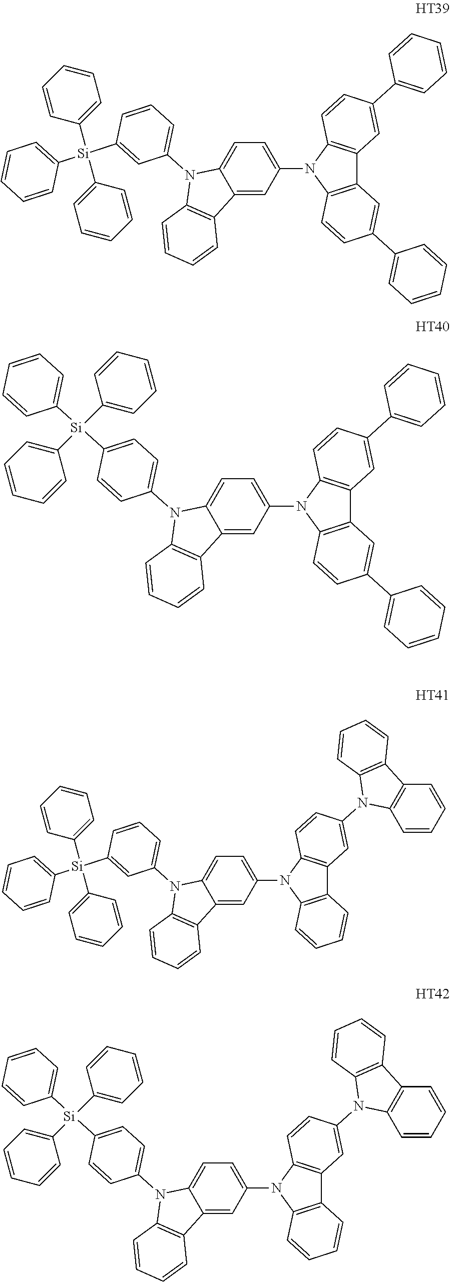 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

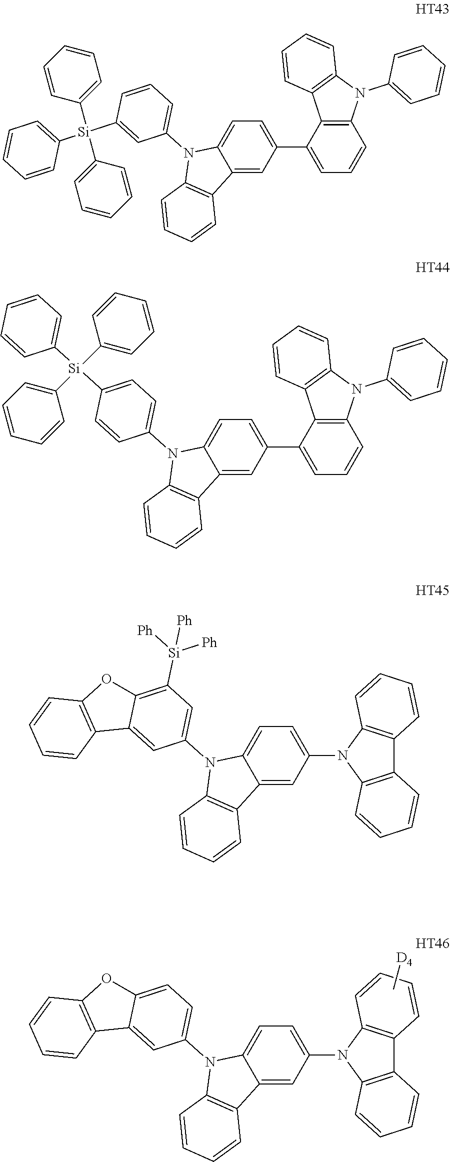

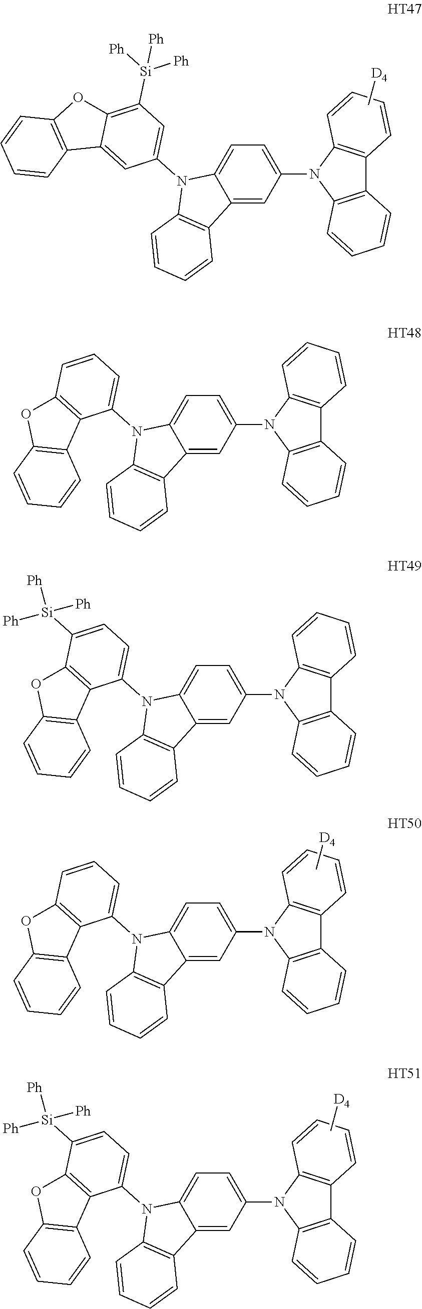

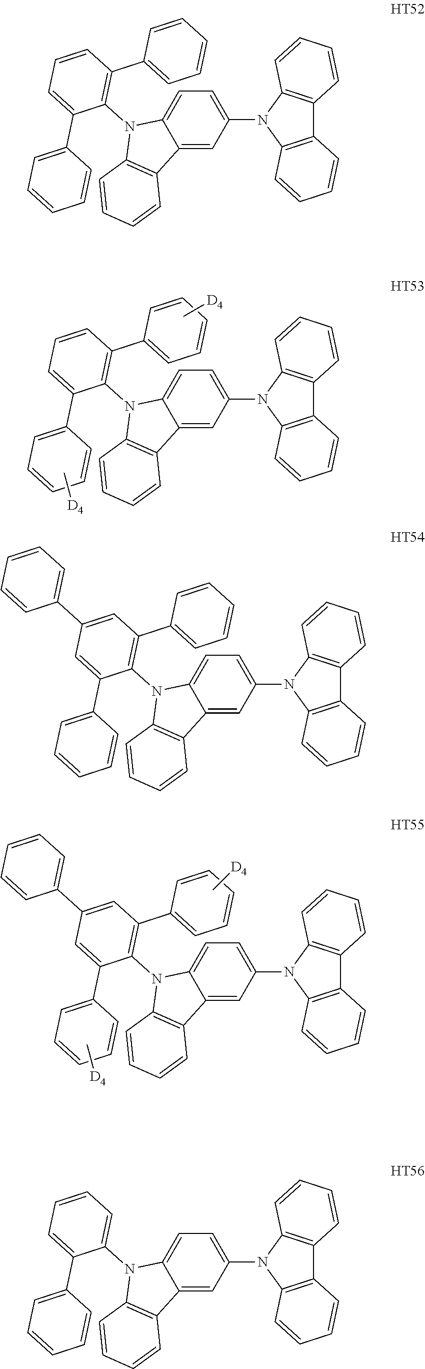

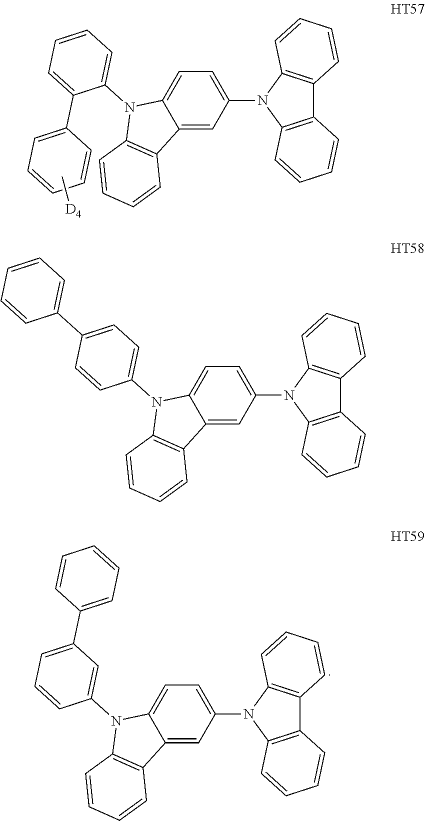

In the example compounds in Compound Group 2, “D” refers to deuterium, and “Ph” refers to an unsubstituted phenyl group.

In one or more embodiments, the emission layer EML may include a third compound represented by Formula ET-1. For example, in one or more embodiments, the third compound may be utilized as an electron transport host material in the emission layer EML.

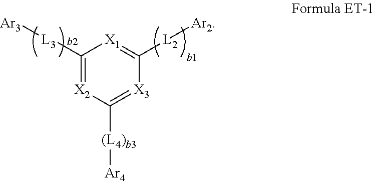

In Formula ET-1, at least one selected from among X₁ to X₃ may be N, and the remainder may be CR₅₆. For example, in some embodiments, one selected from among X₁ to X₃ may be N, and the remainder two may each independently be CR₅₆. In these embodiments, the third compound represented by Formula ET-1 may include a pyridine moiety. In some embodiments, two selected from among X₁ to X₃ may be N, and the remainder may be CR₅₆. In these embodiments, the third compound represented by Formula ET-1 may include a pyrimidine moiety. In some embodiments, X₁ to X₃ may be all N. In these embodiments, the third compound represented by Formula ET-1 may include a triazine moiety.

In Formula ET-1, R₅₆ may be hydrogen, deuterium, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

In Formula ET-1, b1 to b3 may each independently be an integer of 0 to 10. In Formula ET-1, Ar₂ to Ar₄ may each independently be hydrogen,

deuterium, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, in some embodiments, Ar₂ to Ar₄ may be substituted or unsubstituted phenyl groups or substituted or unsubstituted carbazole groups.

In Formula ET-1, L₂ to L₄ may each independently be a direct linkage, a substituted or unsubstituted arylene group of 6 to 30 ring-forming carbon atoms, or a substituted or unsubstituted heteroarylene group of 2 to 30 ring-forming carbon atoms. In some embodiments, when each of b1 to b3 is an integer of 2 or more, L₂ to L₄ may each independently be a substituted or unsubstituted arylene group of 6 to 30 ring-forming carbon atoms, or a substituted or unsubstituted heteroarylene group of 2 to 30 ring-forming carbon atoms.

In one or more embodiments, the third compound may be represented by any one selected from among compounds in Compound Group 3. The light emitting device ED of one or more embodiments may include any one selected from among the compounds in Compound Group 3.

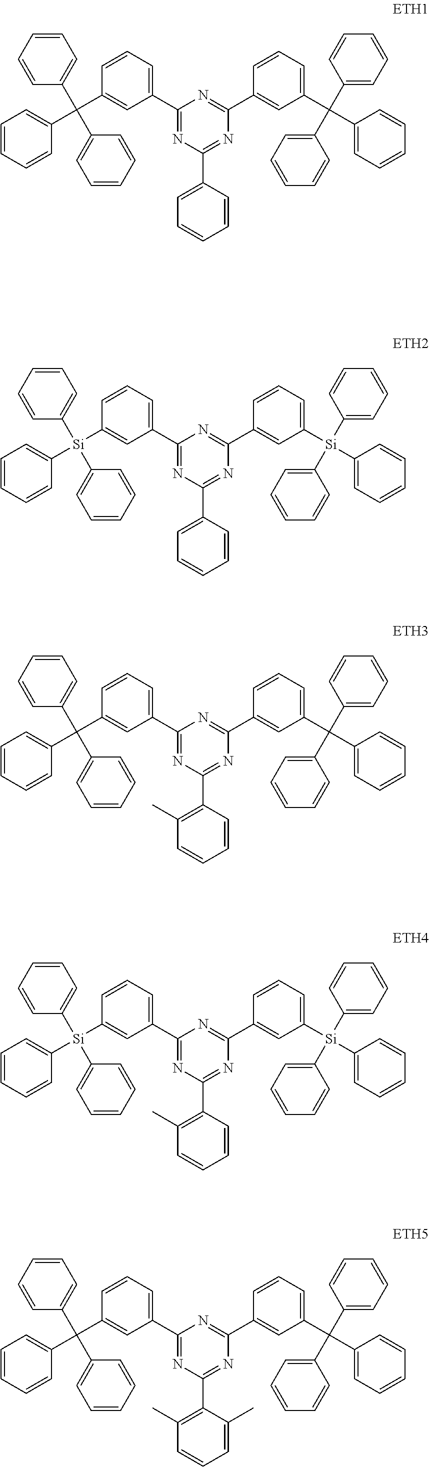

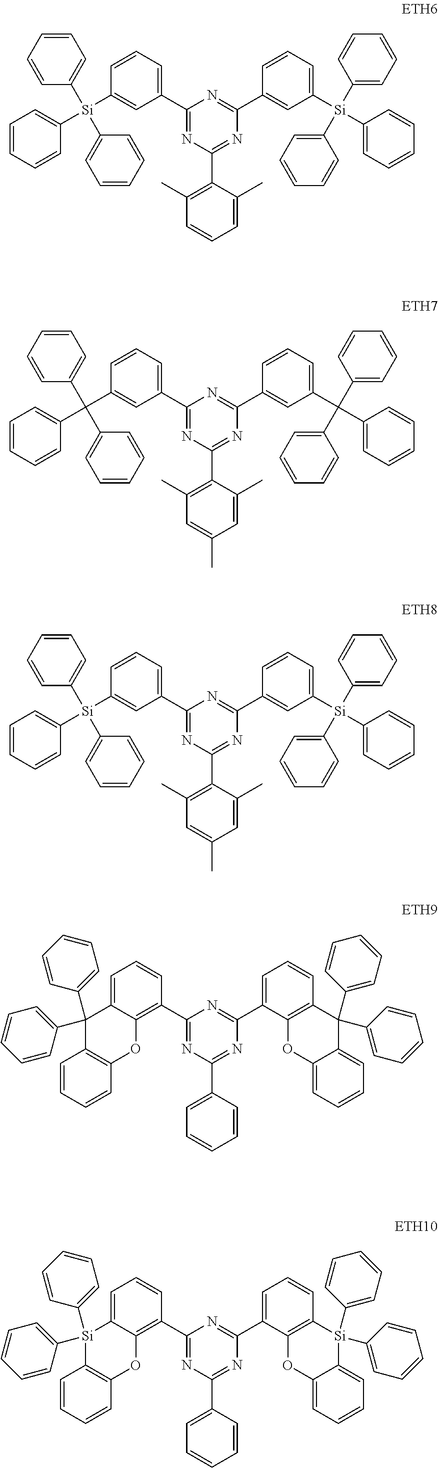

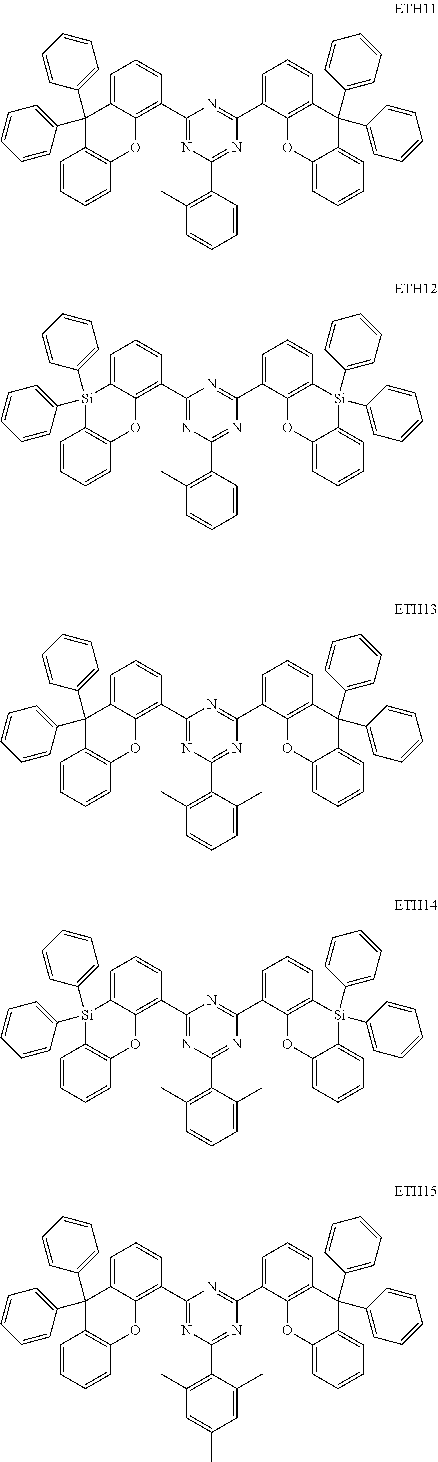

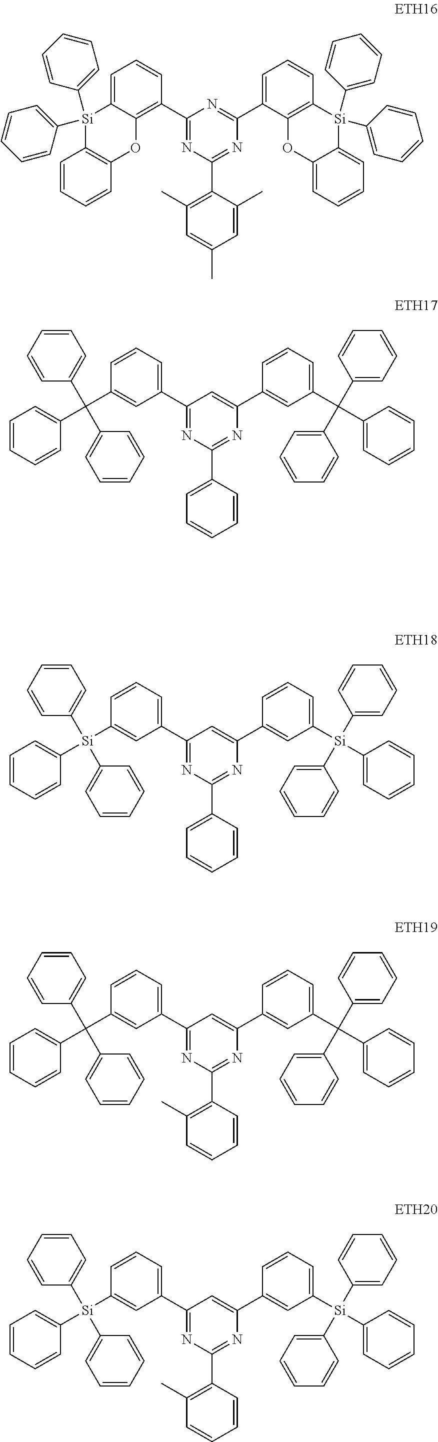

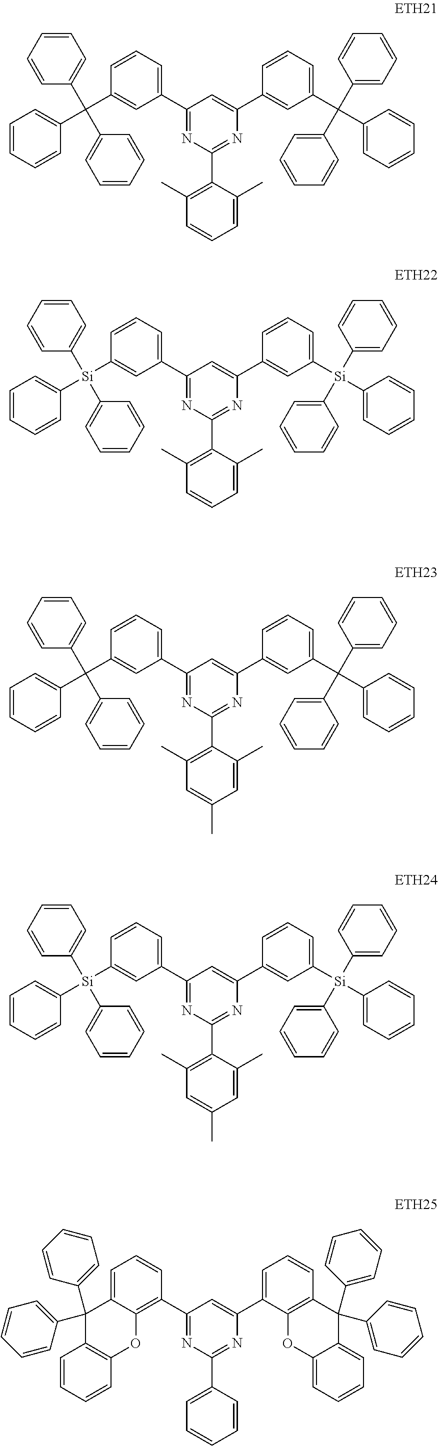

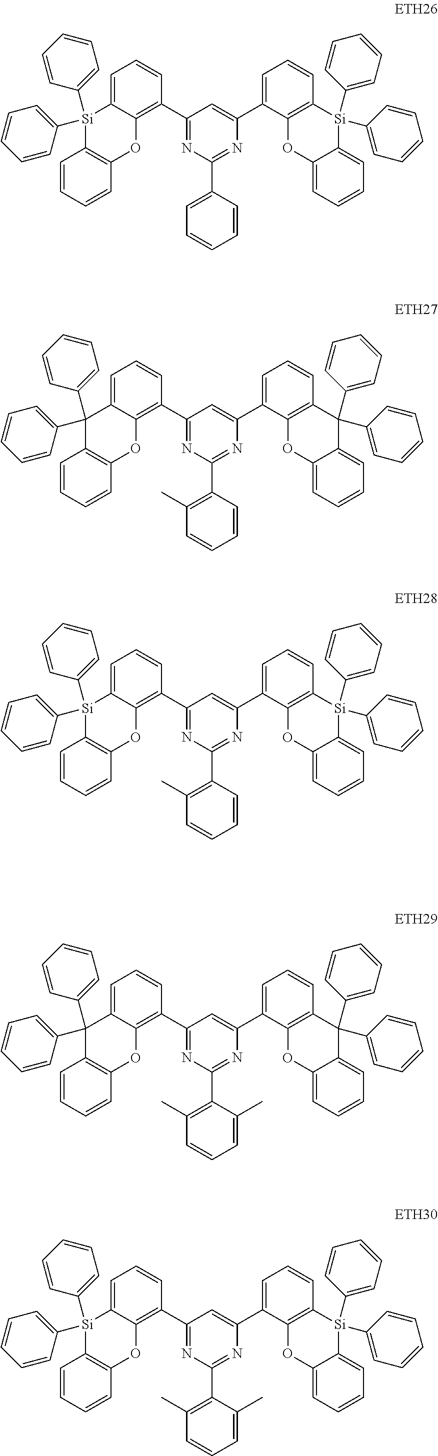

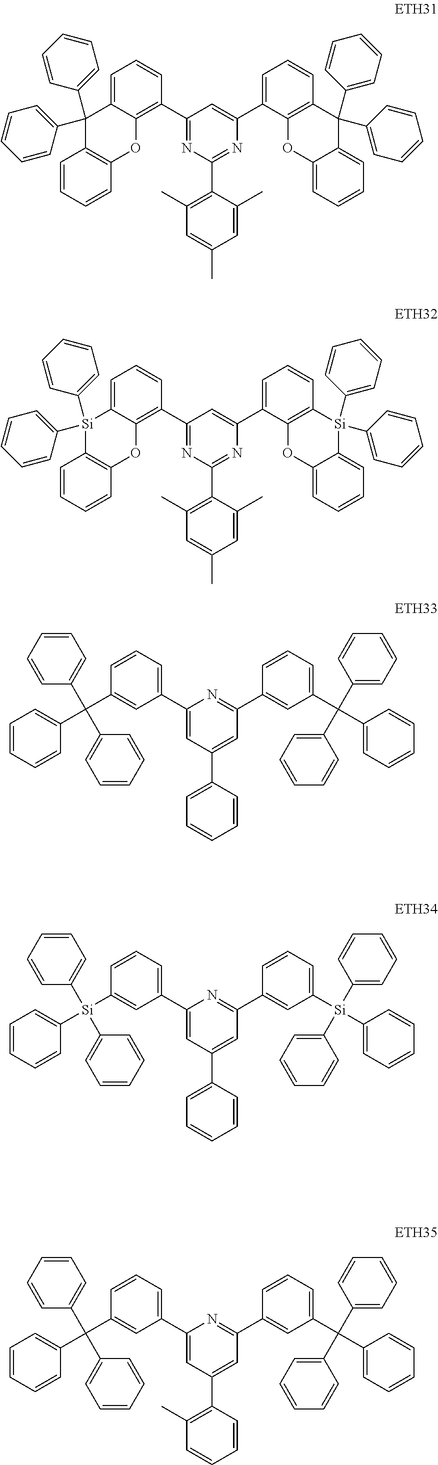

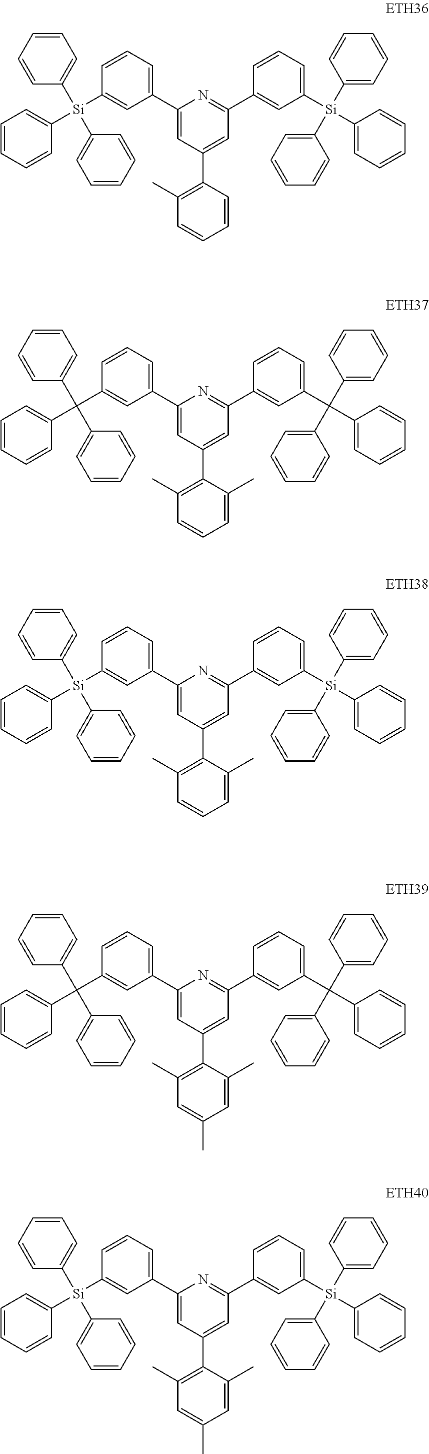

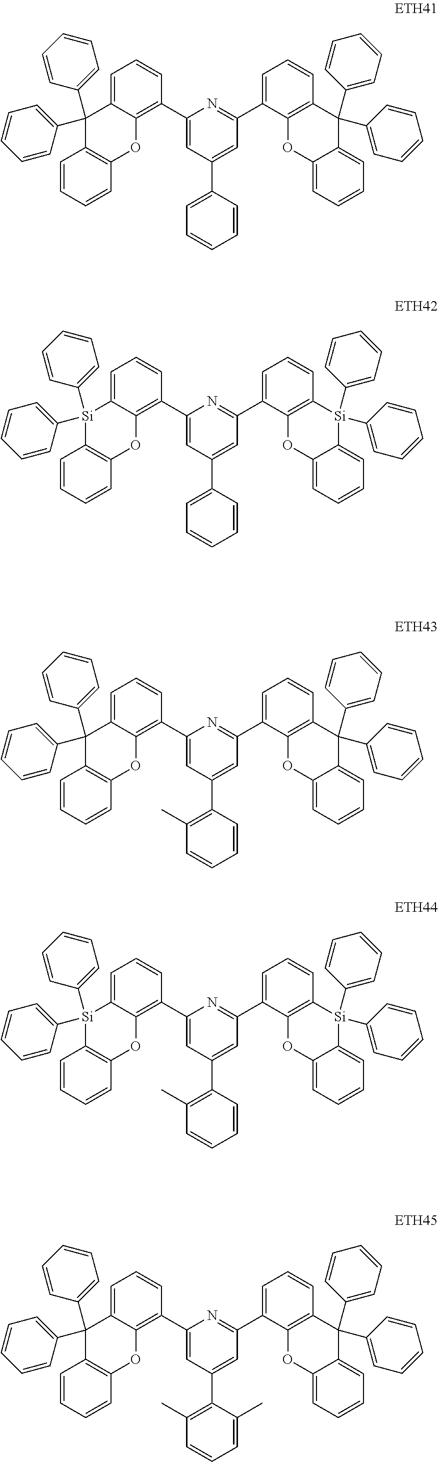

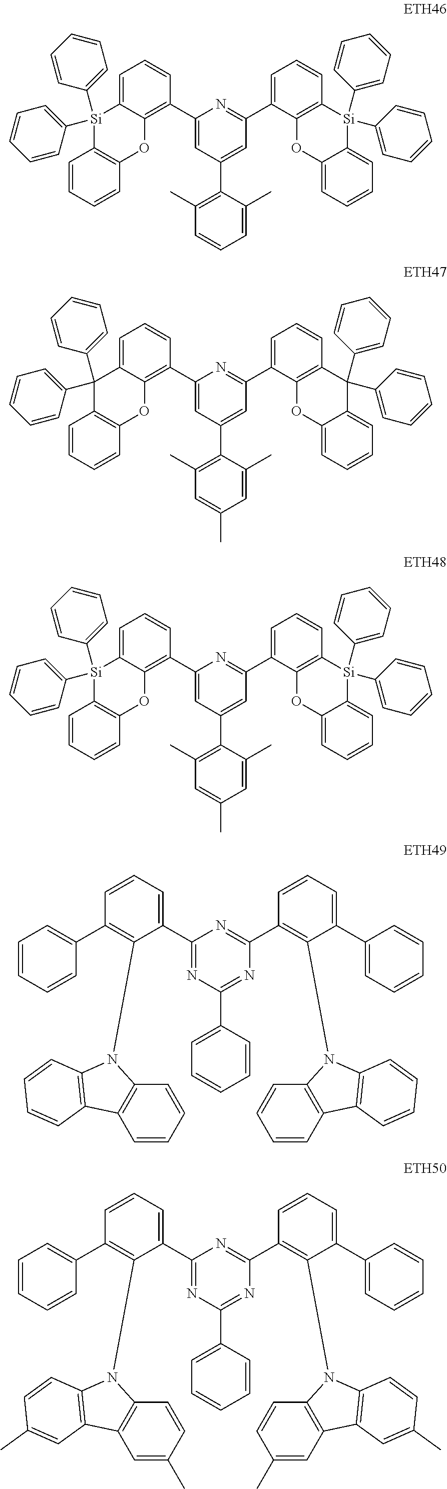

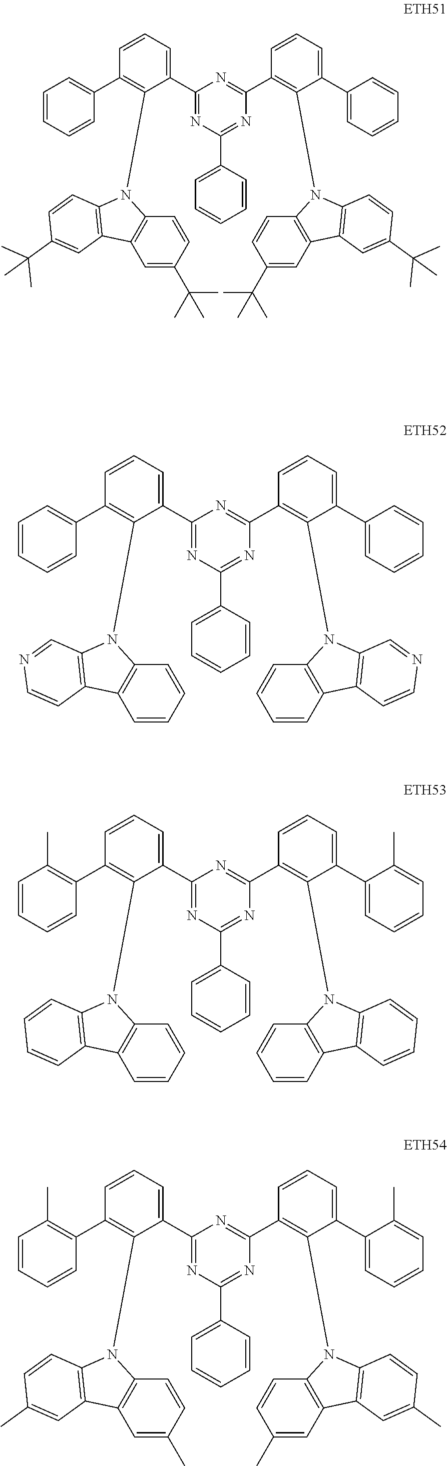

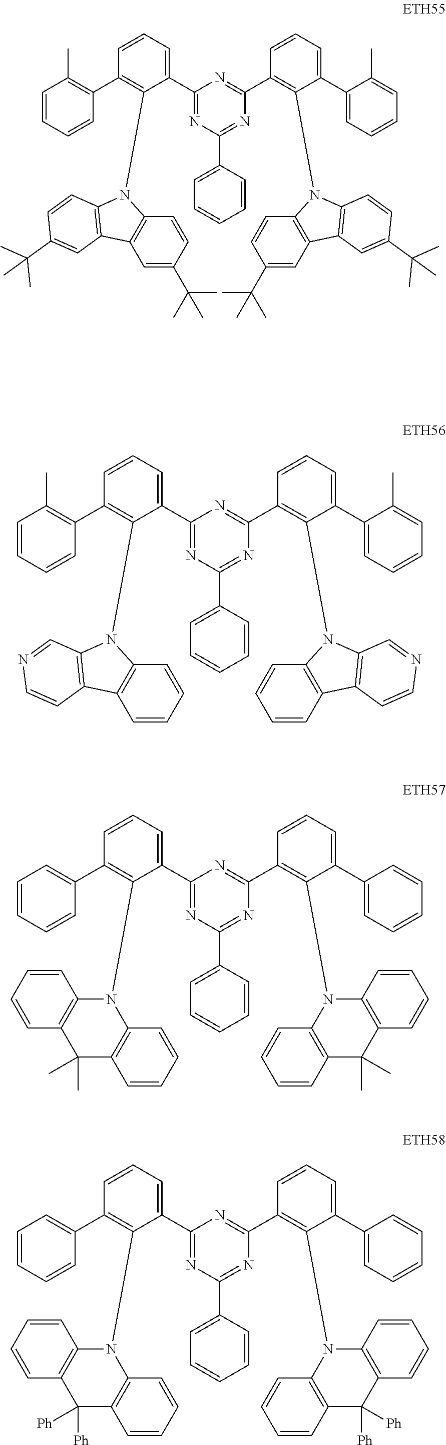

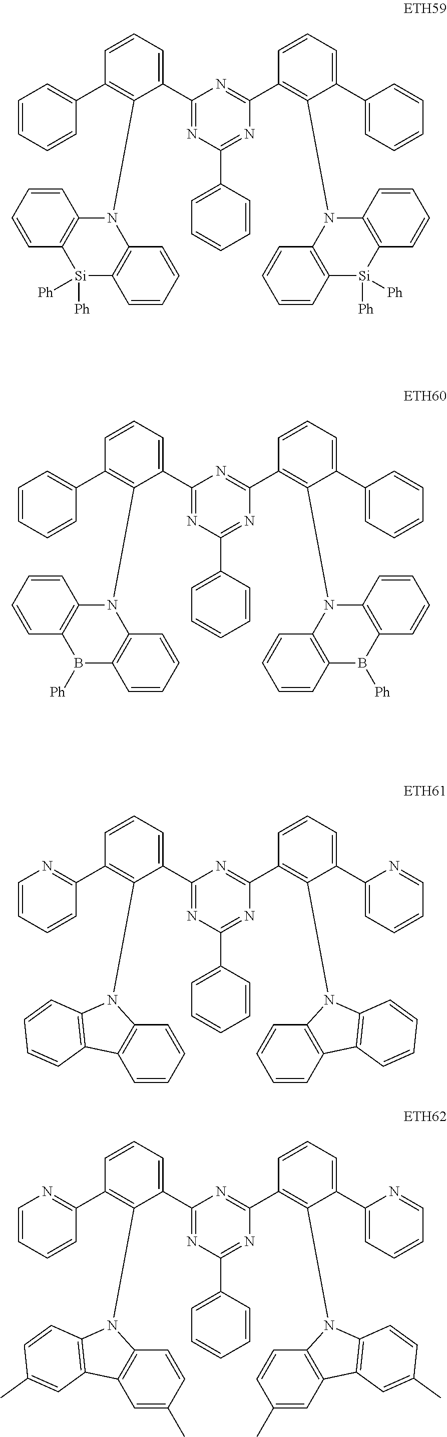

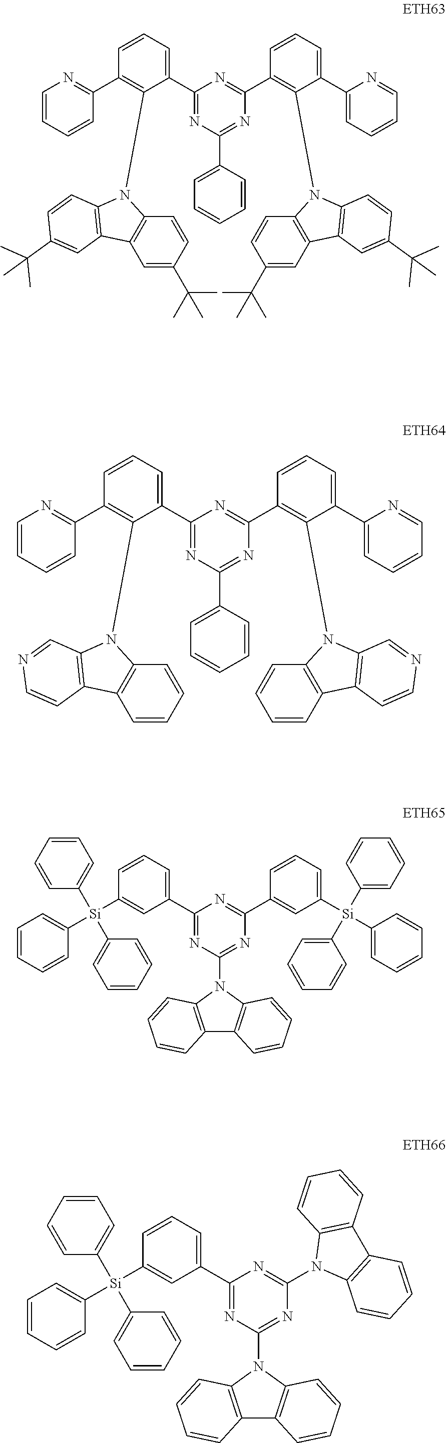 [SMILES: CC(C)(C)c1ccc2c(c1)c1cc(C(C)(C)C)ccc1n2-c1c(-c2ccccn2)cccc1-c1nc(-c2ccccc2)nc(-c2cccc(-c3ccccn3)c2-n2c3ccc(C(C)(C)C)cc3c3cc(C(C)(C)C)ccc32)n1 ; c1ccc(-c2nc(-c3cccc(-c4ccccn4)c3-n3c4ccccc4c4ccncc43)nc(-c3cccc(-c4ccccn4)c3-n3c4ccccc4c4ccncc43)n2)cc1 ; c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1]

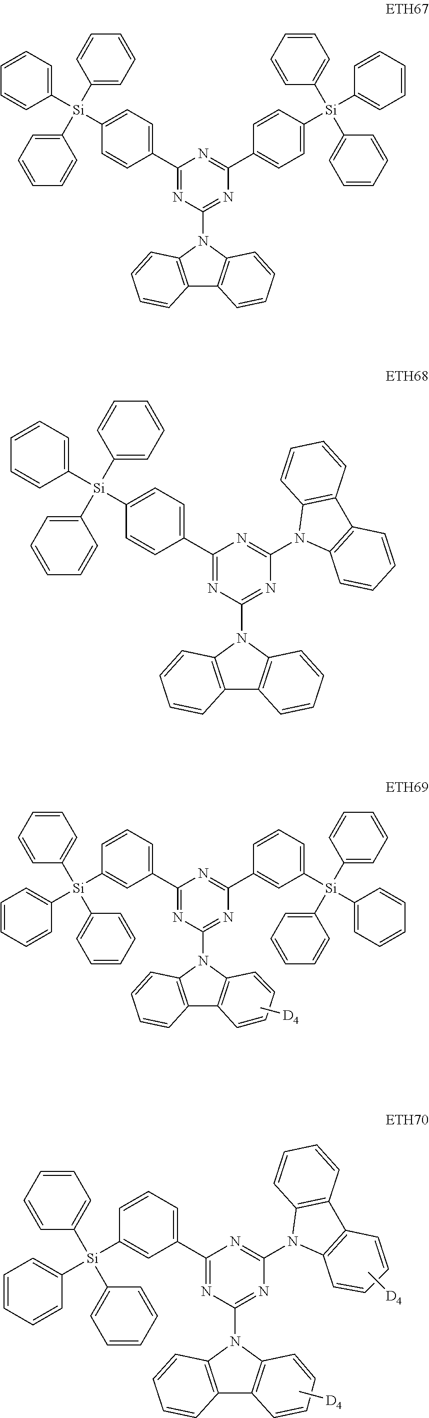

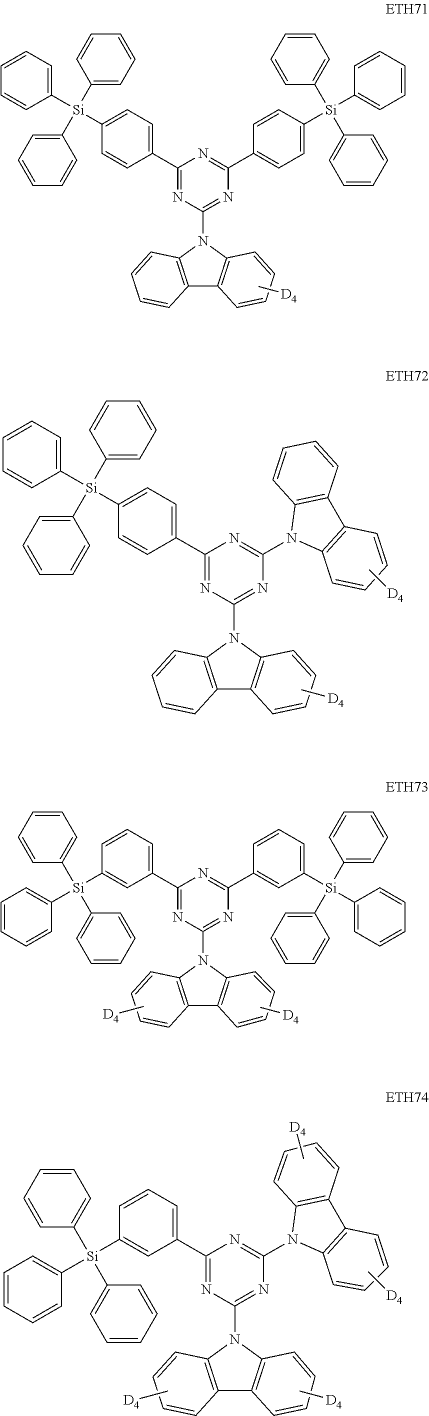

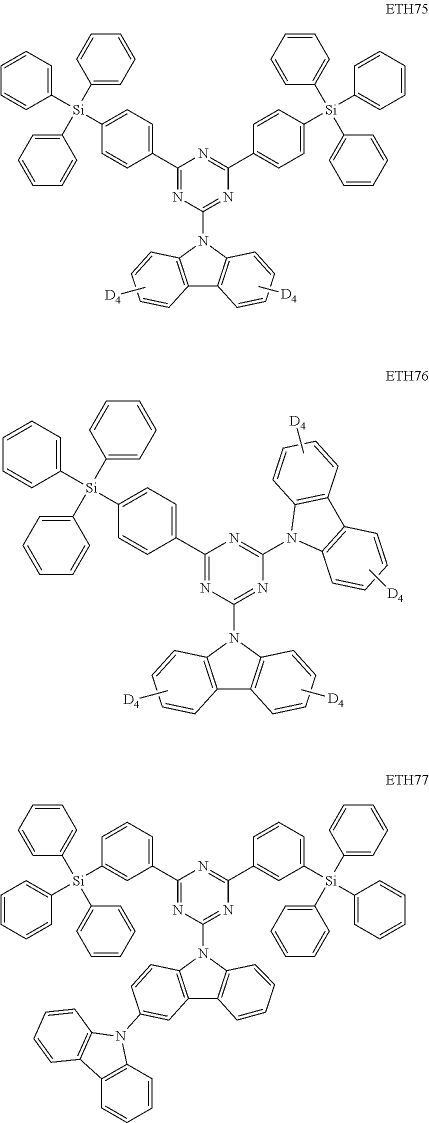

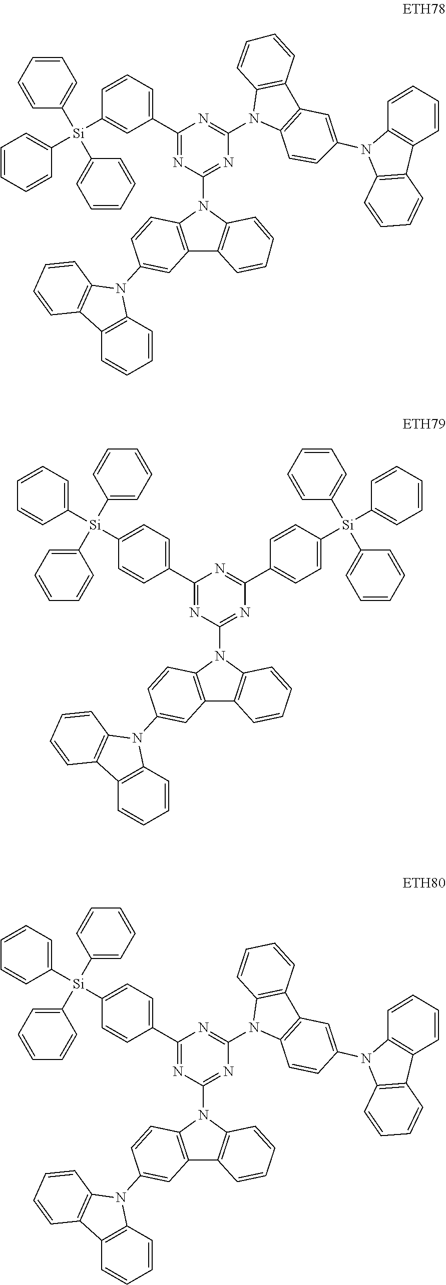 [SMILES: c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1 ; c1ccc([Si](c2ccccc2)(c2ccccc2)c2ccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)cc2)cc1]

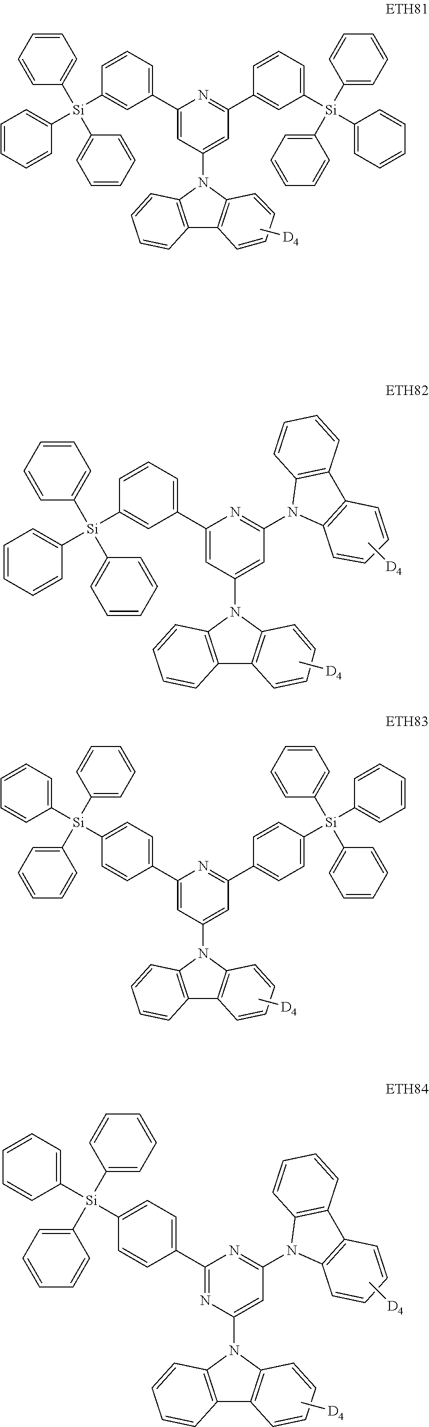

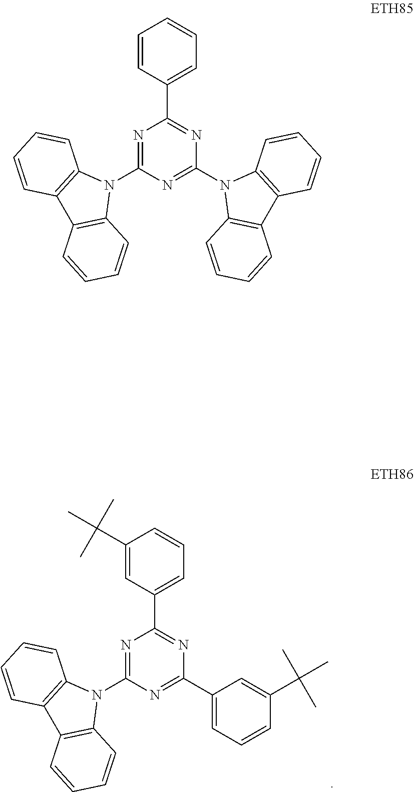 [SMILES: c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1]

In the example compounds in Compound Group 3, “D” may refer to deuterium, and “Ph” may refer to an unsubstituted phenyl group.

In one or more embodiments, the emission layer EML may include the second compound and the third compound, and the second compound and the third compound may form exciplex. In the emission layer EML, exciplex may be formed by a hole transport host and an electron transport host. In this case, the triplet energy of the exciplex formed by the hole transport host and the electron transport host may correspond to a difference between the lowest unoccupied molecular orbital (LUMO) energy level of the electron transport host and the highest occupied molecular orbital (HOMO) energy level of the hole transport host.

For example, in one or more embodiments, the absolute value of the triplet energy level (T1) of the exciplex formed by a hole transport host and an electron transport host may be about 2.4 eV to about 3.0 eV. In some embodiments, the triplet energy of the exciplex may be a smaller value than the energy gap of each host material. The exciplex may have a triplet energy of about 3.0 eV or less, that is the energy gap between the hole transport host and the electron transport host.

In one or more embodiments, the emission layer EML may include a fourth compound in addition to the first compound to the third compound. The fourth compound may be utilized as a phosphorescence sensitizer of the emission layer EML. Because energy may transfer from the fourth compound to the first compound, light emission may arise.

For example, in one or more embodiments, the emission layer EML may include an organometallic complex including platinum (Pt) as a central metal atom and ligands bonded to the central metal atom, as the fourth compound. In the light emitting device ED of one or more embodiments, the emission layer EML may include a compound represented by Formula D-1 as the fourth compound.

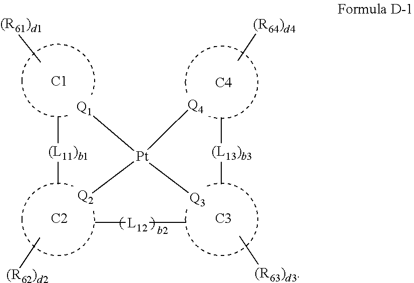

In Formula D-1, Q₁ to Q₄ may each independently be C or N.

In Formula D-1, C1 to C4 may each independently be a substituted or unsubstituted hydrocarbon ring of 5 to 30 ring-forming carbon atoms, or a substituted or unsubstituted heterocycle of 2 to 30 ring-forming carbon atoms.

In Formula D-1, L₁₁ to L₁₃ may each independently be a direct linkage,

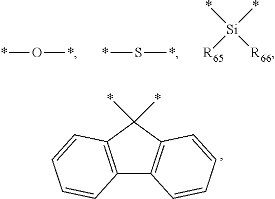

a substituted or unsubstituted alkylene group of 1 to 20 carbon atoms, a substituted or unsubstituted arylene group of 6 to 30 ring-forming carbon atoms, or a substituted or unsubstituted heteroarylene group of 2 to 30 ring-forming carbon atoms. In L₁₁ to L₁₃, [symbol] may refer to a part connected with C1 to C4.

In Formula D-1, b1 to b3 may each independently be 0 or 1. When b1 is 0, C1 and C2 may be unconnected. When b2 is 0, C2 and C3 may be unconnected. When b3 is 0, C3 and C4 may be unconnected.

In Formula D-1, R₆₁ to R₆₆ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms. In some embodiments, each of R₆₁ to R₆₆ may be combined with an adjacent group to form a ring. In some embodiments, R₆₁ to R₆₆ may each independently be a substituted or unsubstituted methyl group, or a substituted or unsubstituted t-butyl group.

In Formula D-1, d1 to d4 may each independently be an integer of 0 to 4. In Formula D-1, when d1 to d4 (e.g., each independently) are 0, the fourth compound may be unsubstituted with corresponding R₆₁ to R₆₄. An embodiment in which d1 to d4 are (e.g., each independently) 4, and R₆₁ to R₆₄ are hydrogen, may be the same as an embodiment in which d1 to d4 are all 0. When dl to d4 are integers of 2 or more (e.g., are each 2 or more), each of multiple R₆₁(s) to R₆₄(s) may be all the same, or at least one selected from among multiple R₆₁(s) to R₆₄(s) may be different.

In Formula D-1, C1 to C4 may each independently be a substituted or unsubstituted hydrocarbon ring or a substituted or unsubstituted heterocycle, represented by any one selected from among C-1 to C-4.

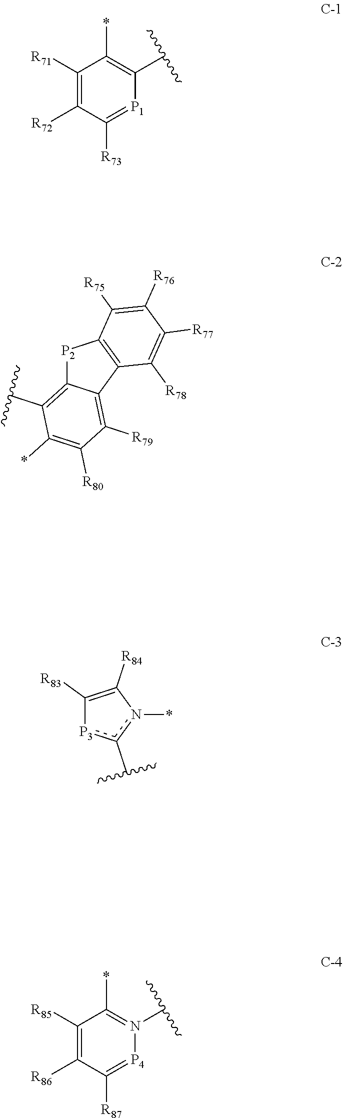

In C-1 to C-4, P₁ may be [symbol] or CR₇₄, P₂ may be [symbol] or NR₈₁, P₃ may be [symbol] or NR₈₂, and P₄ may be [symbol] or CR₈₈. R₇₁ to R₈₈ may each independently be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring.

In C-1 to C-4, “ [symbol] ”is a part connected with a central metal atom of Pt, and “ [symbol] ”corresponds to a part connected with an adjacent ring group (C1 to C4) or linker (L₁₁ to L₁₃).

The emission layer EML of one or more embodiments may include the first compound that is a fused polycyclic compound, and at least one selected from among the second to fourth compounds. For example, in some embodiments, the emission layer EML may include the first compound, the second compound, and the third compound. In the emission layer EML, the second compound and the third compound may form exciplex, and via the exciplex, energy transfer to the first compound may arise, and light emission may arise.

In one or more embodiments, the emission layer EML may include the first compound, the second compound, the third compound, and the fourth compound. In the emission layer EML, the second compound and the third compound may form exciplex, and via the exciplex, energy transfer to the fourth compound and the first compound may arise, and light emission may arise. In some embodiments, the fourth compound may be a sensitizer. In the light emitting device ED of one or more embodiments, the fourth compound included in the emission layer EML may act as a sensitizer and may play the role of transferring energy from a host to the first compound that is a light-emitting dopant. For example, in some embodiments, the fourth compound that plays the role of an auxiliary dopant may accelerate energy transfer to the first compound that is a light emitting dopant and increase the light emitting ratio of the first compound. Accordingly, the emission efficiency of the emission layer EML of one or more embodiments may be improved. In some embodiments, when the energy transfer to the first compound increases, excitons formed in the emission layer EML may not be accumulated but rapidly emit light, and the deterioration of a device may be reduced. As a result, the lifetime of the light emitting device ED of one or more embodiments may increase.

The light emitting device ED of one or more embodiments may include all of the first compound, the second compound, the third compound, and the fourth compound, and the emission layer EML may include the combination of two host materials and two dopant materials. In the light emitting device ED of one or more embodiments, the emission layer EML may include the second compound and the third compound, which are two different hosts, the first compound which emits delayed fluorescence, and the fourth compound including an organometallic complex, concurrently (e.g., simultaneously), and may show excellent or suitable emission efficiency properties.

In one or more embodiments, the fourth compound represented by Formula D-1 may be represented by at least one selected from among compounds represented in Compound Group 4. The emission layer EML may include at least one selected from among the compounds represented in Compound Group 4 as a sensitizer material.

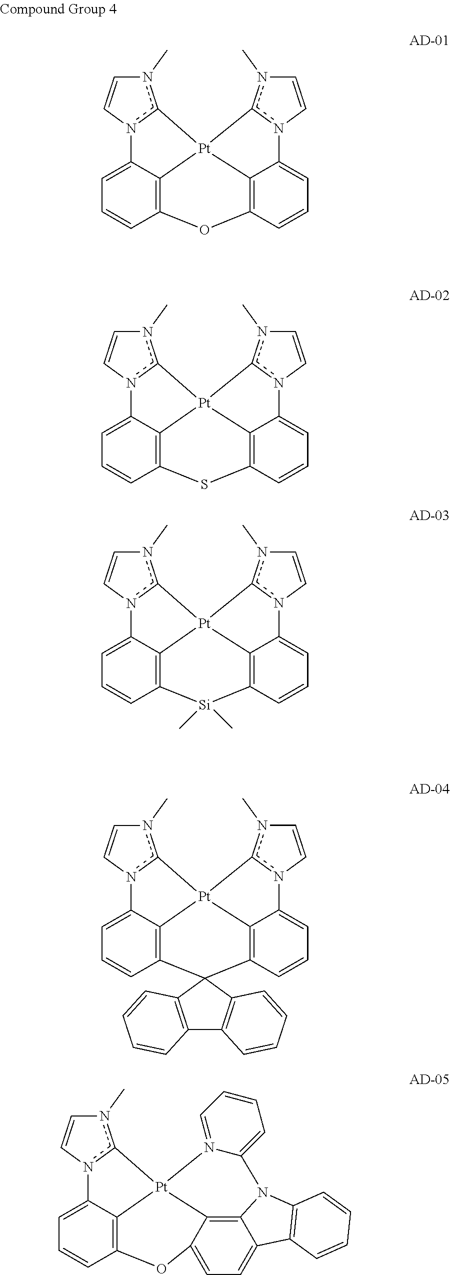

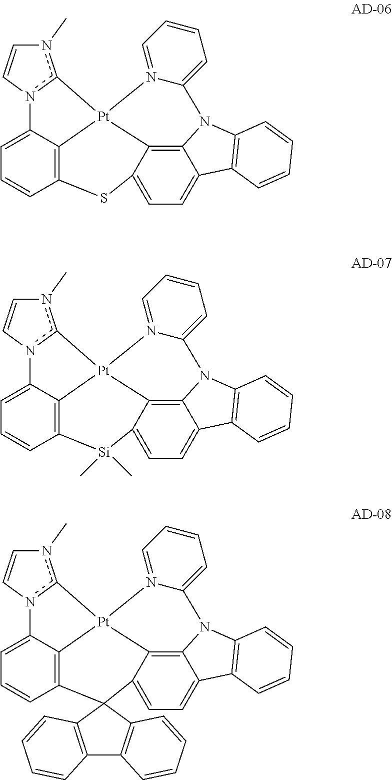

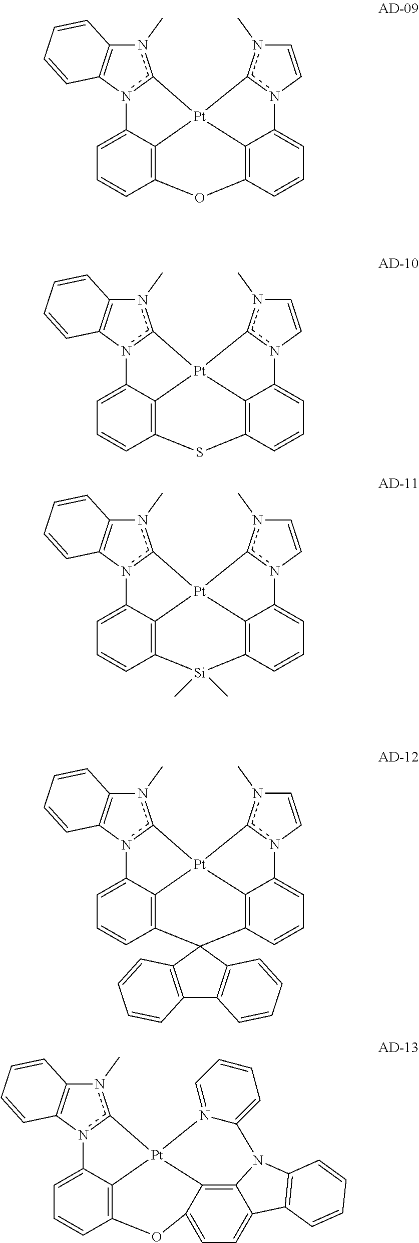

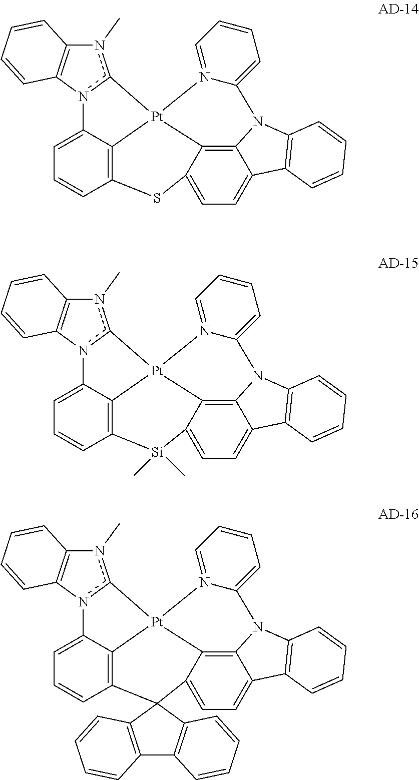

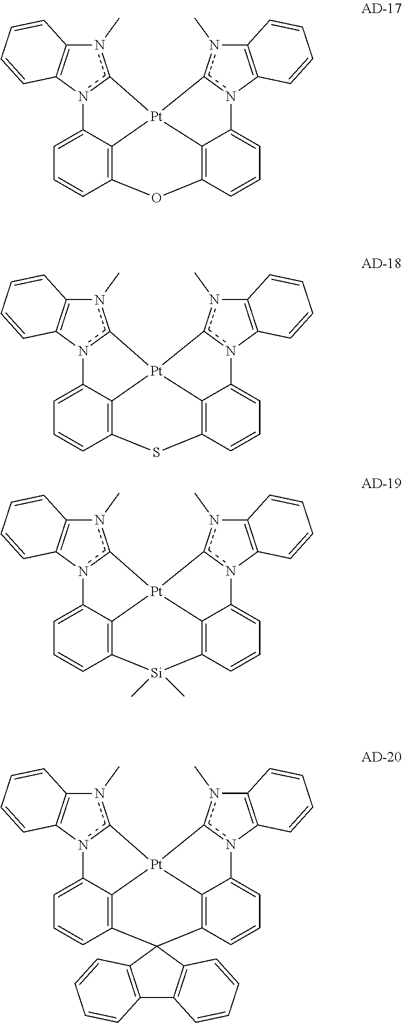

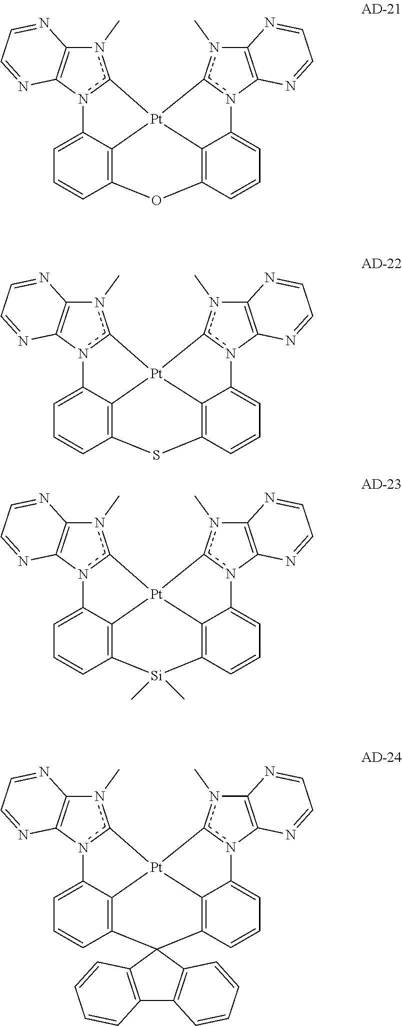

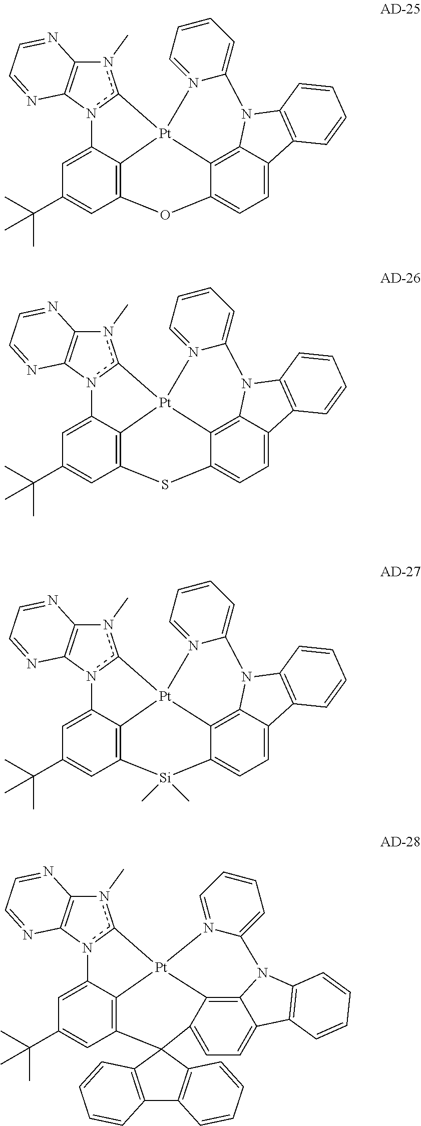

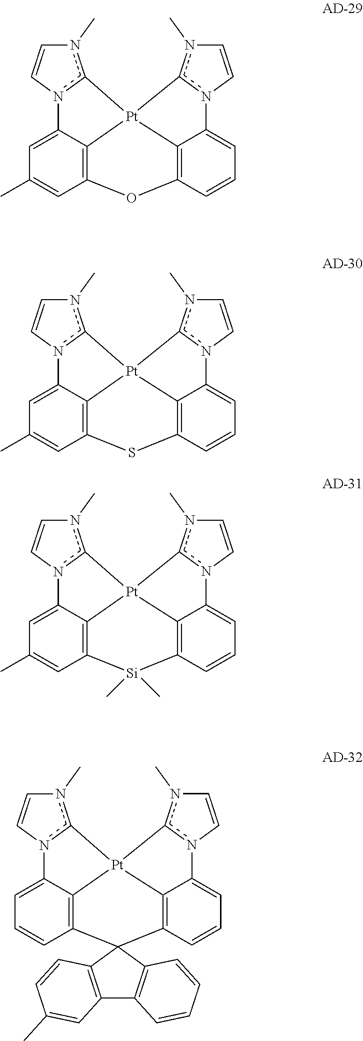

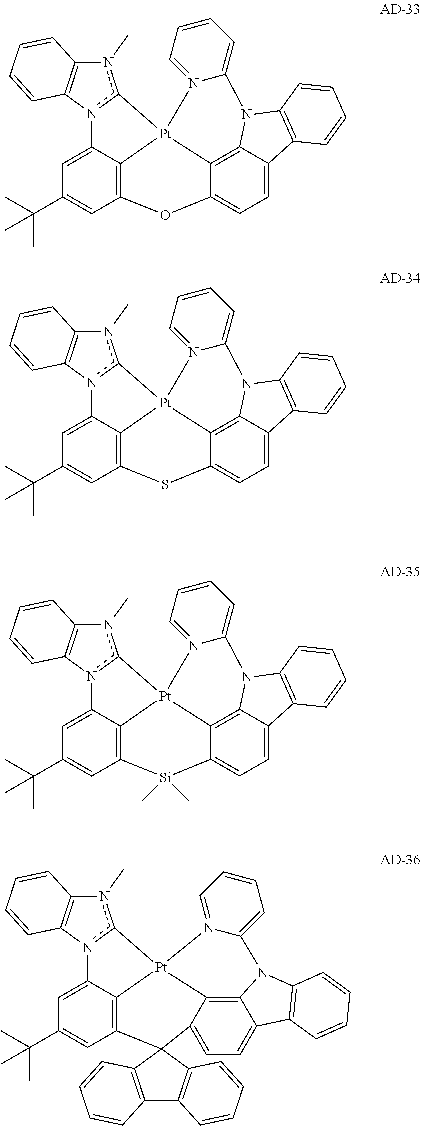

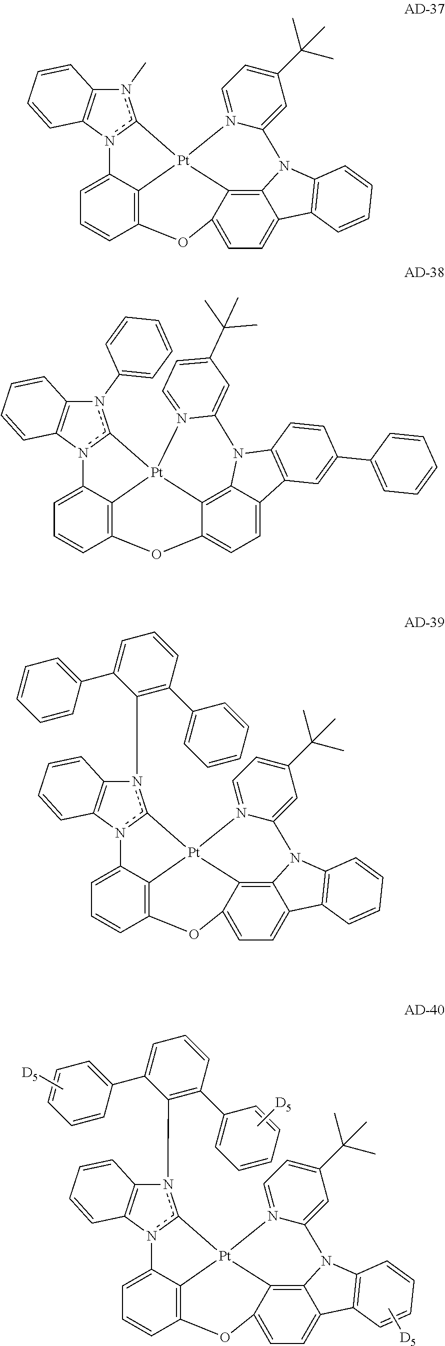

In the example compounds in Compound Group 4, “D” may refer to deuterium.

In one or more embodiments, the light emitting device ED may include multiple emission layers. Multiple emission layers may be stacked in order and provided, and for example, a light emitting device ED including multiple emission layers may be to emit white light (e.g., combined white light). The light emitting device including multiple emission layers may be a light emitting device of a tandem structure. When the light emitting device ED includes multiple emission layers, at least one emission layer EML may include the first compound represented by Formula 1 of one or more embodiments. In one or more embodiments, when the light emitting device ED includes multiple emission layers, at least one emission layer EML may include all of the first compound, the second compound, the third compound, and the fourth compound as described above.

In the light emitting device ED of one or more embodiments, when the emission layer EML includes all of the first compound, the second compound, and the third compound, the amount of the first compound may be about 0.1 wt % to about 5 wt % based on the total weight of the first compound, the second compound, and the third compound. However, embodiments of the present disclosure are not limited thereto. When the amount of the first compound satisfies the above-described ratio, energy transfer from the second compound and the third compound to the first compound may increase, and accordingly, the emission efficiency and device lifetime of the light emitting device may increase.

In the emission layer EML, the total amount of the second compound and the third compound may be the remaining amount excluding the amount of the first compound. For example, in one or more embodiments, the total amount of the second compound and the third compound may be about 65 wt % to about 95 wt % based on the total weight of the first compound, the second compound and the third compound.

In the total amount of the second compound and the third compound, the weight ratio of the second compound and the third compound may be about 3: 7 to about 7: 3.

When the total amount of the second compound and the third compound satisfies the above-described ratio, charge balance properties in the emission layer EML may be improved, and emission efficiency and device lifetime may be improved and/or increased. When the total amount of the second compound and the third compound deviates from the above-described ratio range, charge balance in the emission layer EML may be broken, emission efficiency may be degraded and/or decreased, and the device may be easily deteriorated.

In one or more embodiments, when the emission layer EML further includes the fourth compound, the amount of the fourth compound may be about 10 wt % to 30 wt % based on the total weight of the first compound, the second compound, the third compound, and the fourth compound in the emission layer EML. However, embodiments of the present disclosure are not limited thereto. When the amount of the fourth compound satisfies the above-described amount, energy transfer from a host to the first compound that is a light emitting dopant may increase, and emission ratio may be improved. Accordingly, the emission efficiency of the emission layer EML may be improved and/or increased. When the amount ratio of the first compound, the second compound, the third compound, and the fourth compound, included in the emission layer EML, satisfies the above-described amount ratio, excellent or suitable emission efficiency and long lifetime of the light emitting device may be achieved.

In the light emitting device ED of one or more embodiments, the emission layer EML may further include at least one of anthracene derivatives, pyrene derivatives, fluoranthene derivatives, chrysene derivatives, dihydrobenzanthracene derivatives, or triphenylene derivatives. For example, in one or more embodiments, the emission layer EML may include anthracene derivatives or pyrene derivatives.

In the light emitting devices ED of one or more embodiments, shown in FIG. 3 to FIG. 6, the emission layer EML may further include suitable hosts and dopants in addition to the above-described host and dopant. For example, in some embodiments, the emission layer EML may include a compound represented by Formula E-1. The compound represented by Formula E-1 may be utilized as a fluorescence host material.

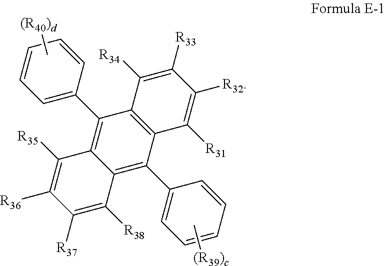

In Formula E-1, R₃₁ to R₄₀ may each independently be hydrogen, deuterium, a halogen, a substituted or unsubstituted silyl group, a substituted or unsubstituted thiol group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring. In some embodiments, R₃₁ to R₄₀ may be combined with an adjacent group to form a saturated hydrocarbon ring, an unsaturated hydrocarbon ring, a saturated heterocycle, or an unsaturated heterocycle.

In Formula E-1, “c” and “d” may each independently be an integer of 0 to 5.

The compound represented by Formula E-1 may be any one selected from among Compound E1 to Compound E19.

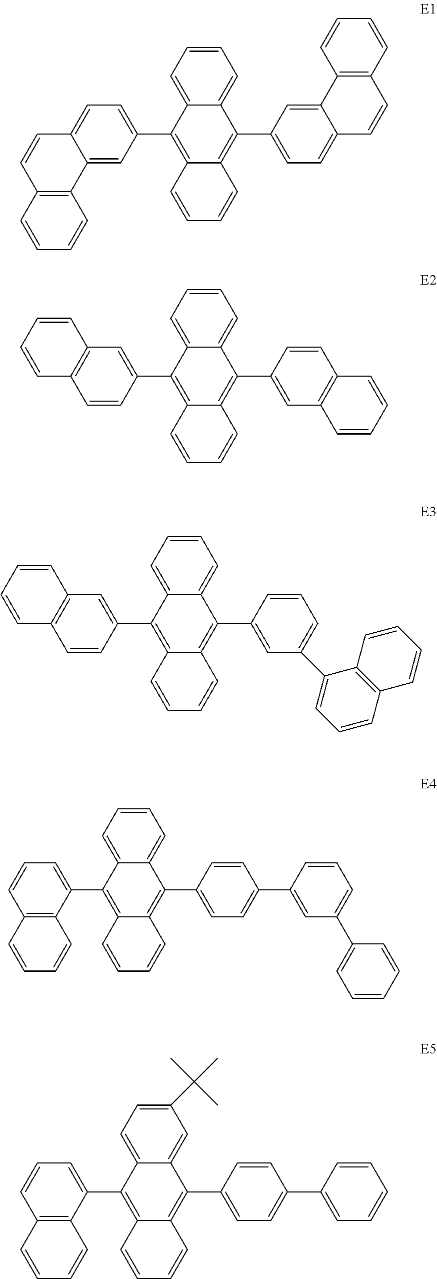

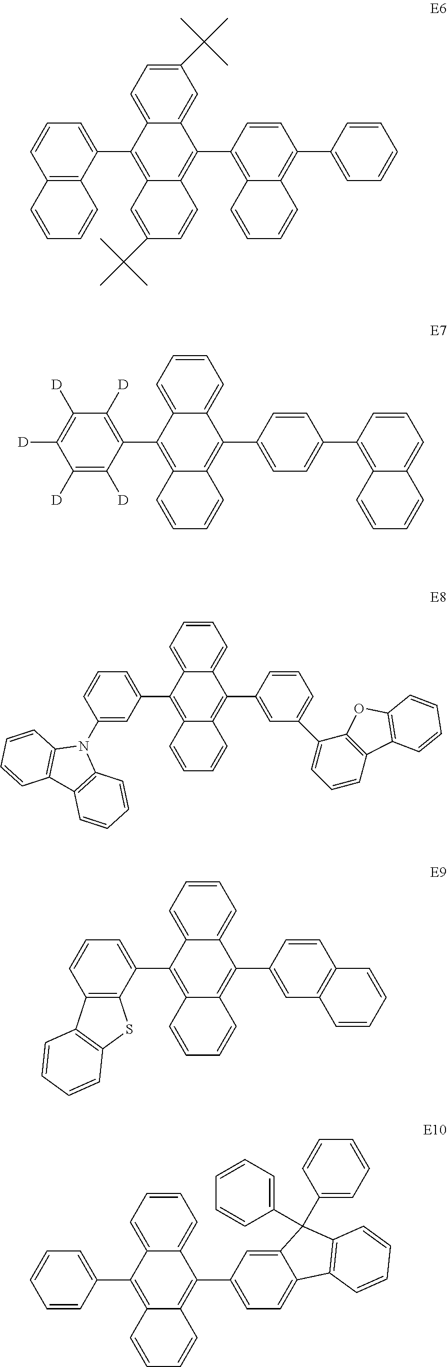

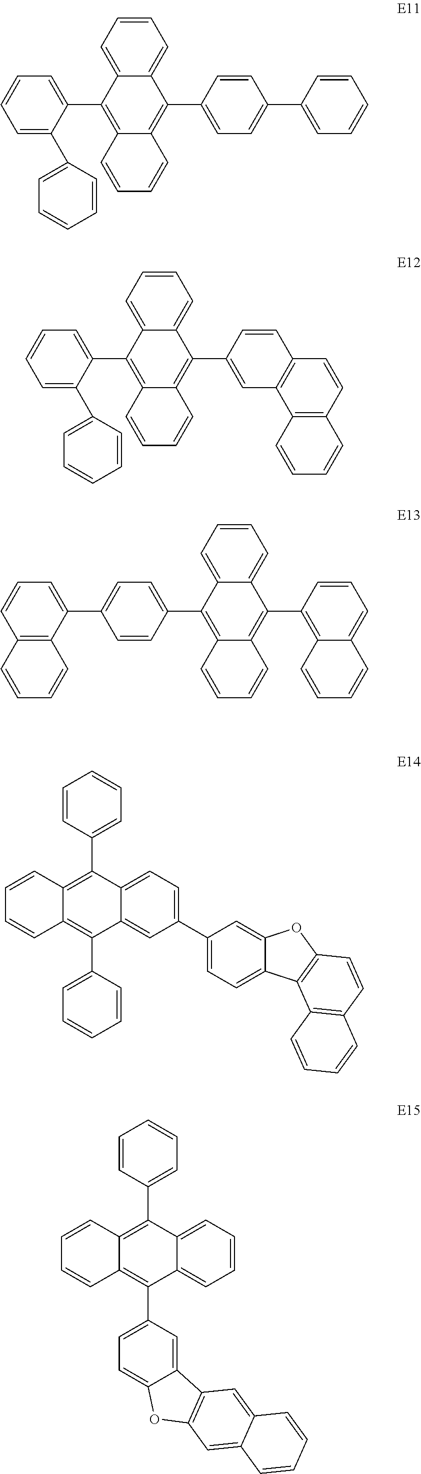

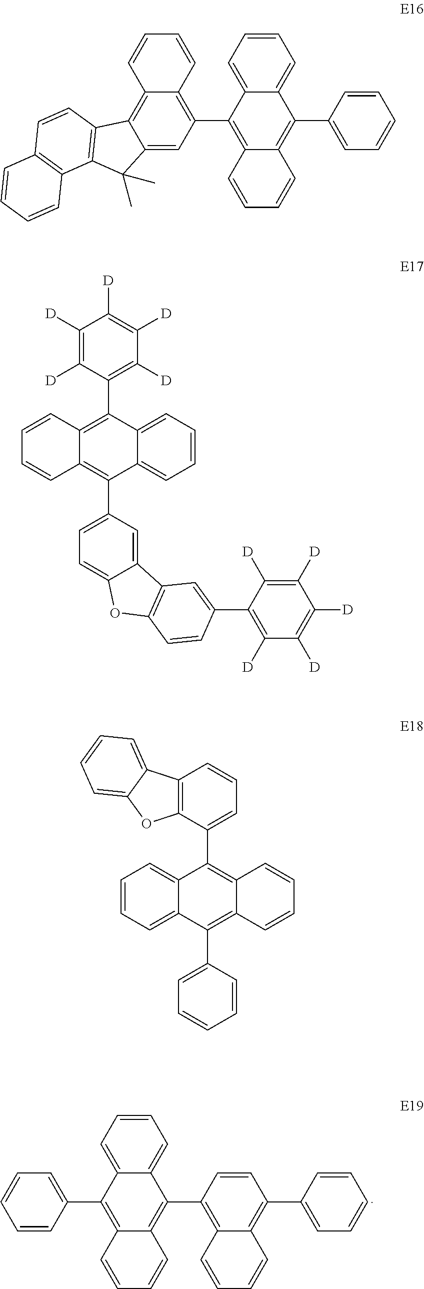

In one or more embodiments, the emission layer EML may include a compound represented by Formula E-2a or Formula E-2b. The compound represented by Formula E-2a or Formula E-2b may be utilized as a phosphorescence host material.

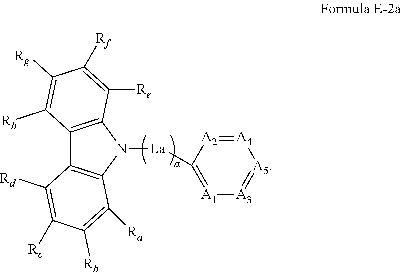

In Formula E-2a, “a” may be an integer of 0 to 10, La may be a direct linkage, a substituted or unsubstituted arylene group of 6 to 30 ring-forming carbon atoms, or a substituted or unsubstituted heteroarylene group of 2 to 30 ring-forming carbon atoms. In some embodiments, when “a” is an integer of 2 or more, multiple La(s) may each independently be a substituted or unsubstituted arylene group of 6 to ring-forming carbon atoms, or a substituted or unsubstituted heteroarylene group of 2 to 30 ring-forming carbon atoms.

In some embodiments, in Formula E-2a, A₁ to A₅ may each independently be N or CRᵢ. Rₐ to R₁ may each independently be hydrogen, deuterium, a substituted or unsubstituted amine group, a substituted or unsubstituted thiol group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. In some embodiments, Rₐ to Rᵢ may be combined with an adjacent group to form a hydrocarbon ring or a heterocycle including N, O, S, etc. as a ring-forming atom.

In some embodiments, in Formula E-2a, two or three selected from A₁ to A₅ may be N, and the remainder may be CRᵢ.

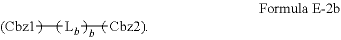

In Formula E-2b, Cbz1 and Cbz2 may each independently be an unsubstituted carbazole group, or a carbazole group substituted with an aryl group of 6 to 30 ring-forming carbon atoms. L_{b} may be a direct linkage, a substituted or unsubstituted arylene group of 6 to 30 ring-forming carbon atoms, or a substituted or unsubstituted heteroarylene group of 2 to 30 ring-forming carbon atoms. “b” may be an integer of 0 to 10, and when “b” is an integer of 2 or more, multiple L_{b}(s) may each independently be a substituted or unsubstituted arylene group of 6 to 30 ring-forming carbon atoms, or a substituted or unsubstituted heteroarylene group of 2 to 30 ring-forming carbon atoms.

The compound represented by Formula E-2a or Formula E-2b may be any one selected from among compounds in Compound Group E-2. However, the compounds shown in Compound Group E-2 are mere examples, and the compound represented by Formula E-2a or Formula E-2b is not limited to the compounds represented in Compound Group E-2.

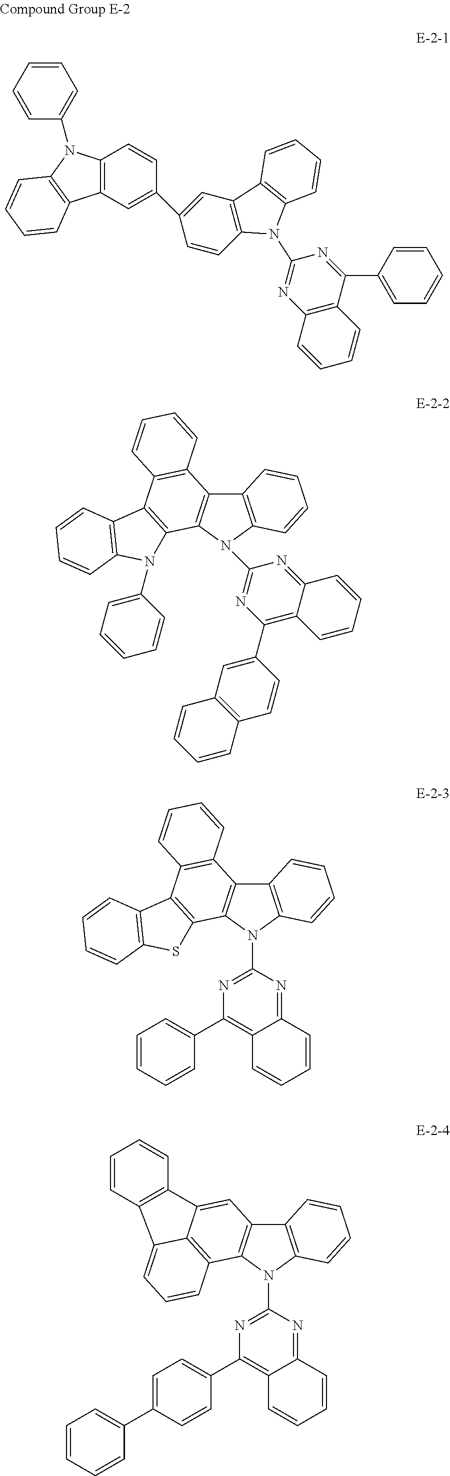

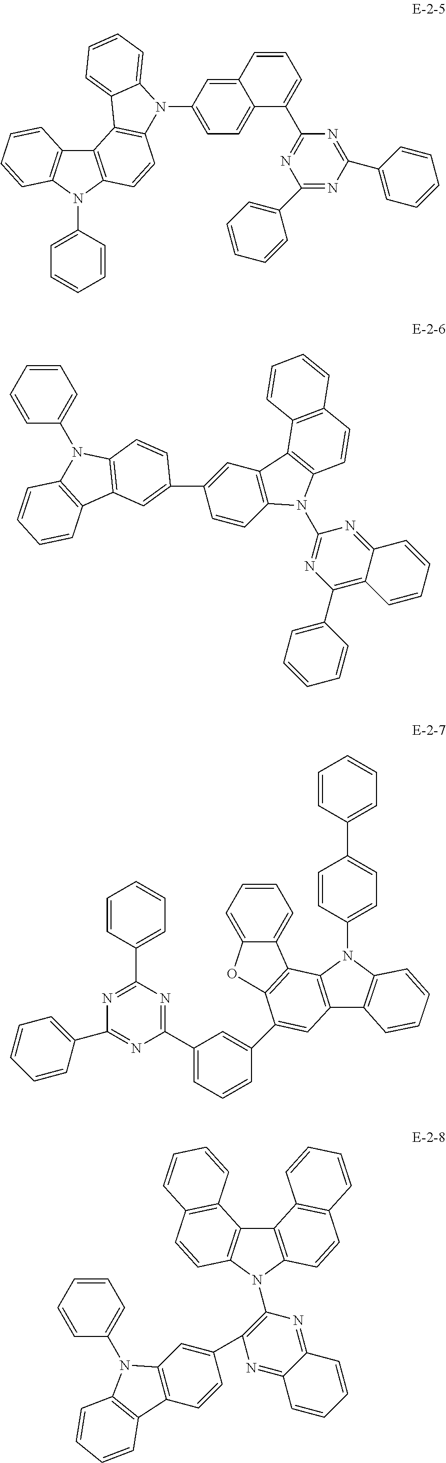 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

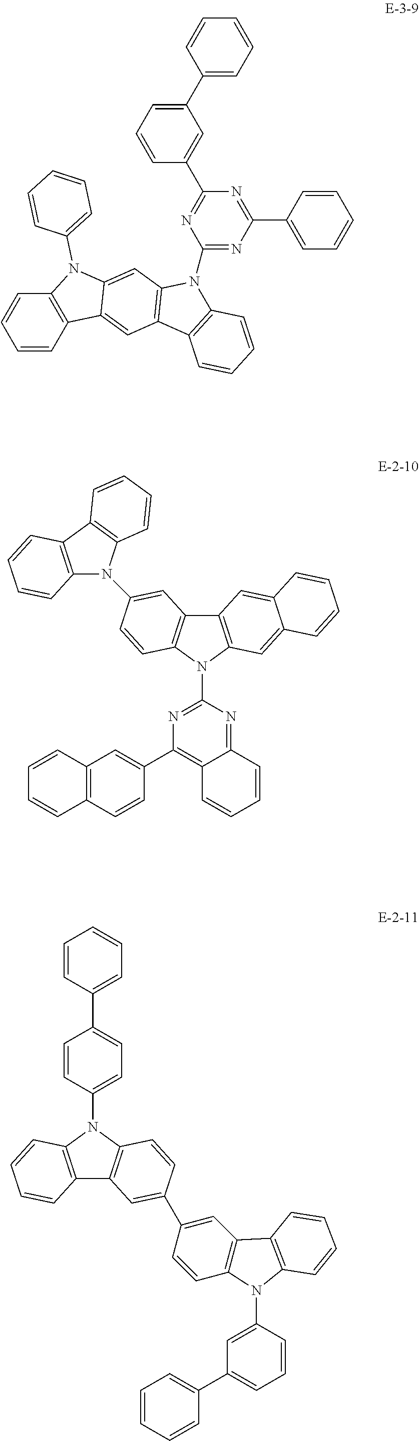 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

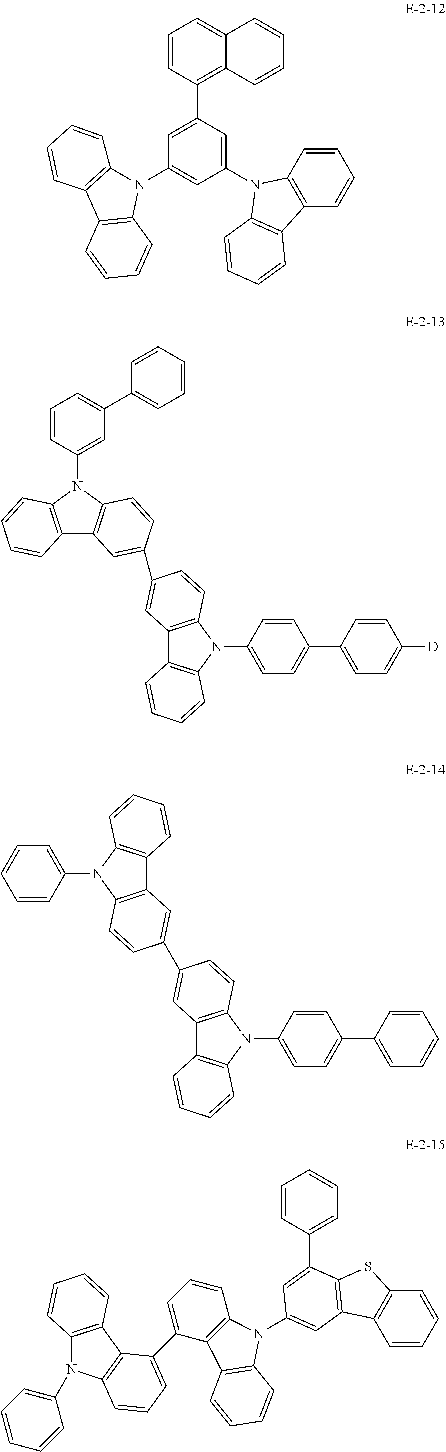 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

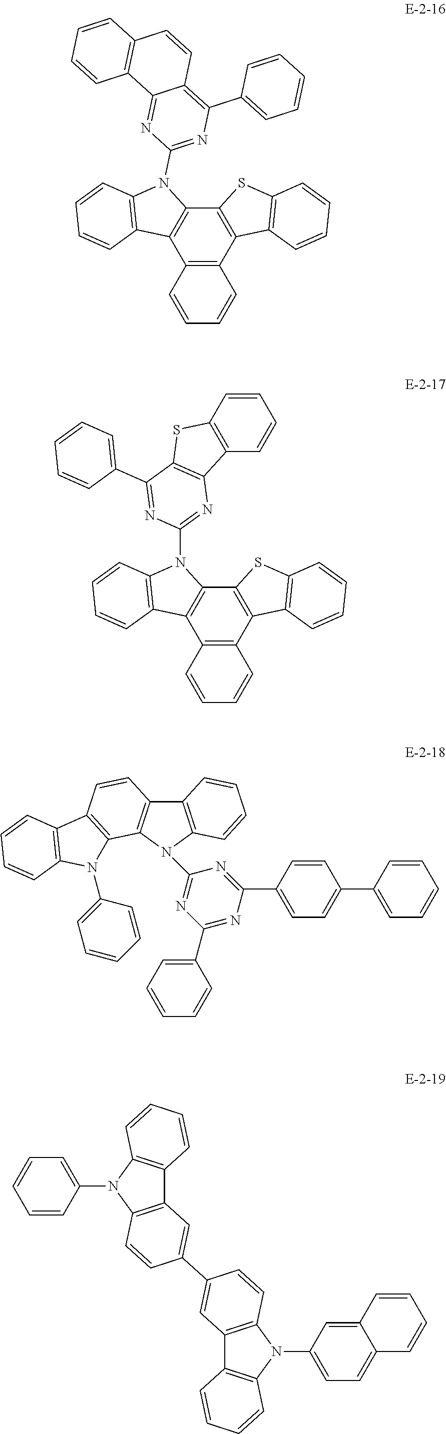 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1]

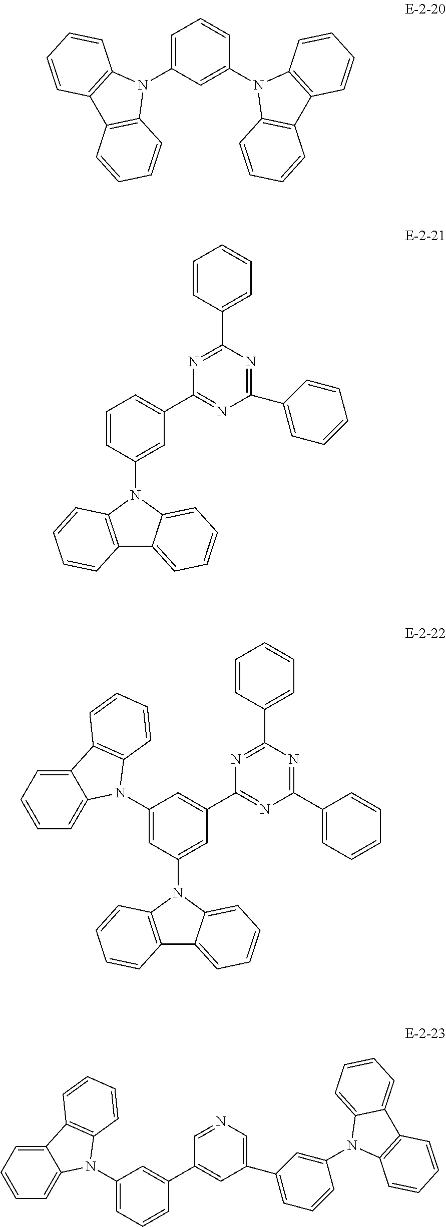 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

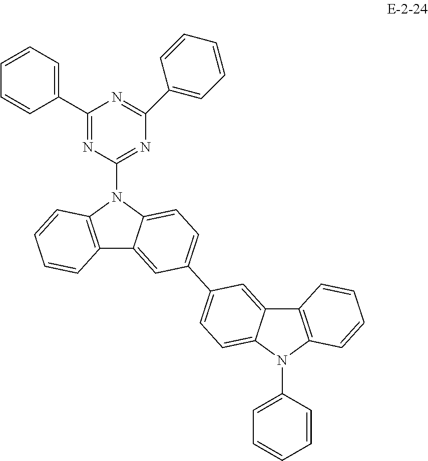 [SMILES: c1ccc(-c2nc(-c3ccccc3)nc(-n3c4ccccc4c4cc(-c5ccc6c(c5)c5ccccc5n6-c5ccccc5)ccc43)n2)cc1]

In one or more embodiments, the emission layer EML may further include a material well-suitable in the art as a host material. For example, the emission layer EML may include as a host material, at least one of bis (4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, embodiments of the present disclosure are not limited thereto. For example, tris(8-hydroxyquinolinato)aluminum (Alq₃), 9,10-di(naphthalen-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be utilized as the host material.

In one or more embodiments, the emission layer EML may include a compound represented by Formula M-a. The compound represented by Formula M-a may be utilized as a phosphorescence dopant material.

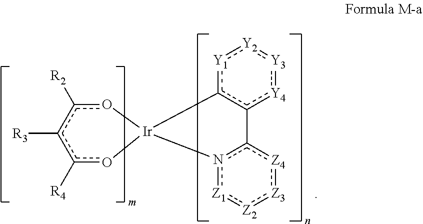

In Formula M-a, Y₁ to Y₄, and Z₁ to Z₄ may each independently be CR₁ or N, and R₁ to R₄ may each independently be hydrogen, deuterium, a substituted or unsubstituted amine group, a substituted or unsubstituted thiol group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. In Formula M-a, “m” is 0 or 1, and “n” is 2 or 3. In Formula M-a, when “m” is 0, “n” is 3, and when “m” is 1, “n” is 2.

The compound represented by Formula M-a may be utilized as a phosphorescence dopant.

The compound represented by Formula M-a may be any one selected from among Compounds M-a1 to M-a25. However, Compounds M-a1 to M-a25 are mere examples, and the compound represented by Formula M-a is not limited to the compounds represented by Compounds M-a1 to M-a25.

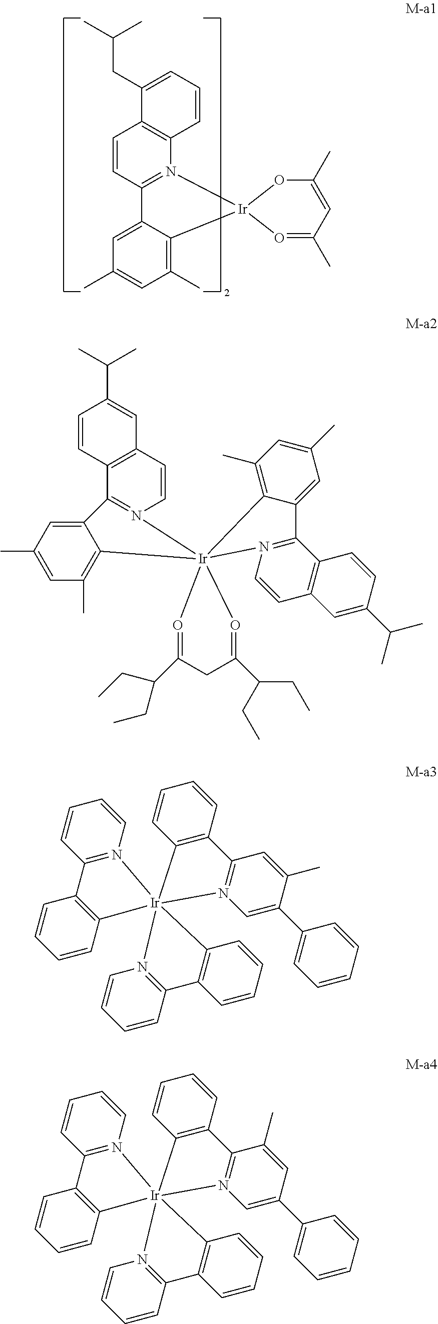

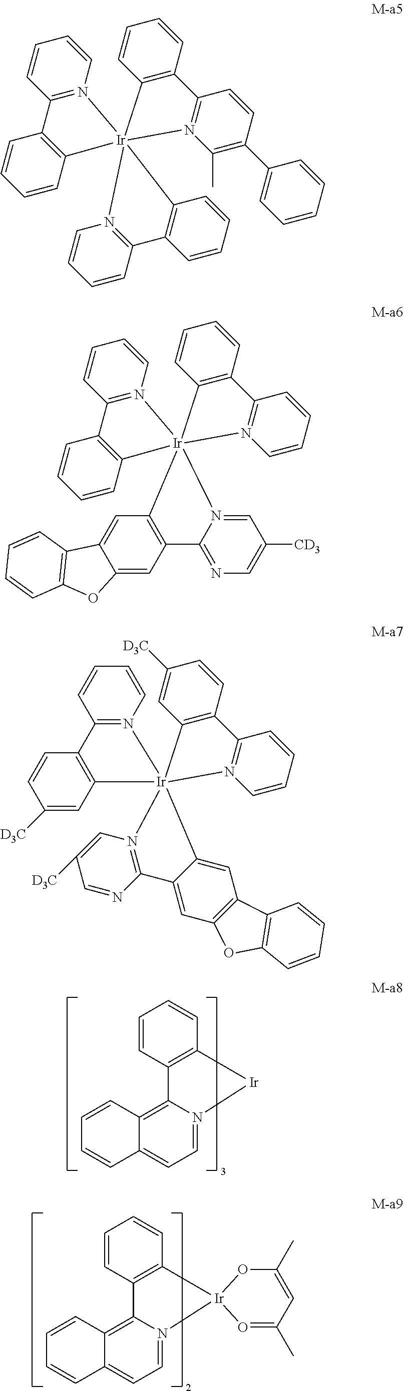

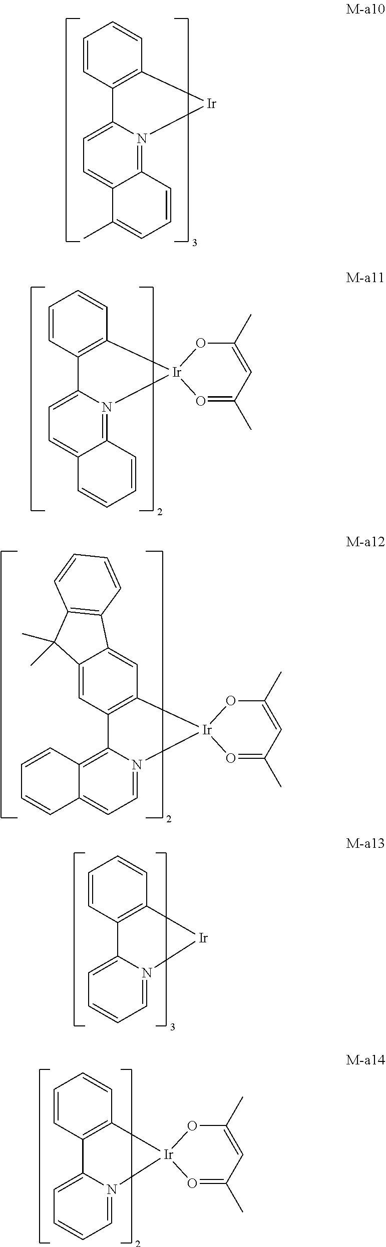

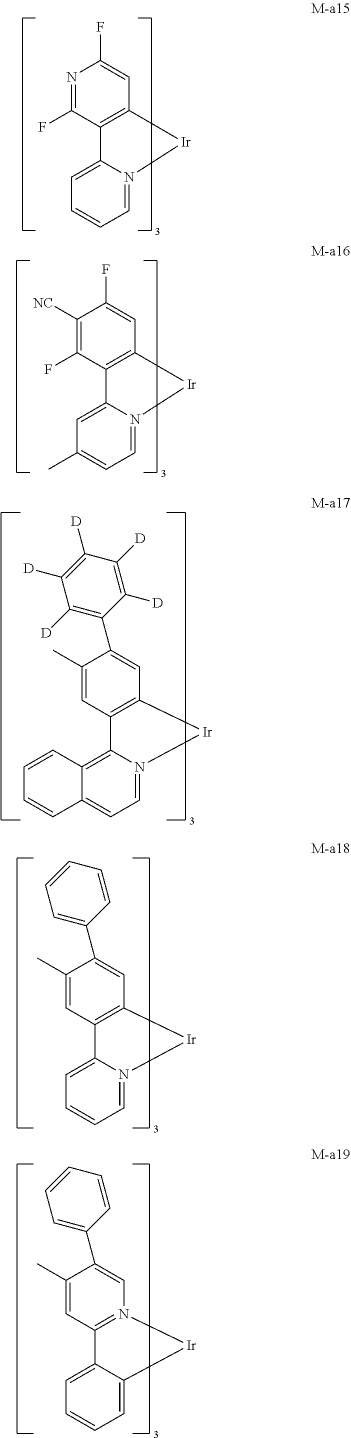

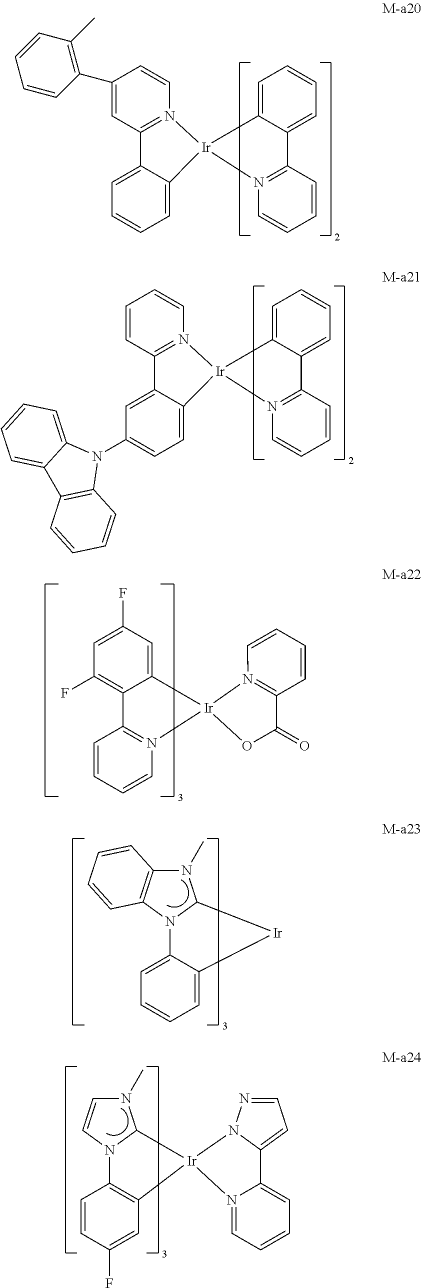

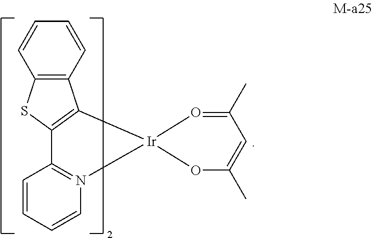

In one or more embodiments, the emission layer EML may further include a compound represented by any one selected from among Formula F-a to Formula F-c. The compounds represented by Formula F-a to Formula F-c may be utilized as fluorescence dopant materials.

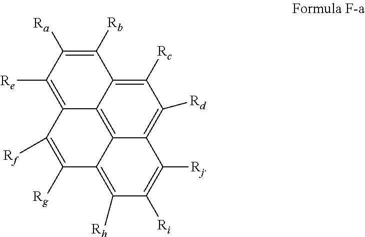

In Formula F-a, two selected from Rₐ to Rⱼ may each independently be substituted with [symbol] . The remainder not substituted with [symbol] among Rₐ to Rⱼ may each independently be hydrogen, deuterium, a halogen, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In [symbol] , Ar₁ and Ar₂ may each independently be a substituted or unsubstituted aryl group of 6 to 30 ring-forming carbon atoms, or a substituted or unsubstituted heteroaryl group of 2 to 30 ring-forming carbon atoms. For example, in some embodiments, at least one selected from among Ar₁ and Ar₂ may be a heteroaryl group including O or S as a ring-forming atom.

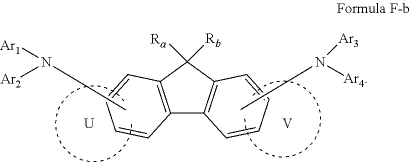

In Formula F-b, Rₐ and R_{b} may each independently be hydrogen, deuterium, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. Ar₁ to Ar₄ may each independently be a substituted or unsubstituted aryl group of 6 to 30 ring-forming carbon atoms, or a substituted or unsubstituted heteroaryl group of 2 to 30 ring-forming carbon atoms.

In Formula F-b, U and V may each independently be a substituted or unsubstituted hydrocarbon ring of 5 to 30 ring-forming carbon atoms, or a substituted or unsubstituted heterocycle of 2 to 30 ring-forming carbon atoms. In some embodiments, at least one selected from among Ar₁ to Ar₄ may be a heteroaryl group including O or S as a ring-forming atom.

In Formula F-b, the number of rings represented by U and V may each independently be 0 or 1. For example, in Formula F-b, when the number of U or V is 1, one ring forms a fused ring at the designated part by U or V, and when the number of U or V is 0, a ring is not present at the designated part by U or V. For example, when the number of U is 0, and the number of V is 1, or when the number of U is 1, and the number of V is 0, a fused ring having the fluorene core of Formula F-b may be a ring compound with four rings. In some embodiments, when the number of both (e.g., simultaneously) U and V is 0, the fused ring of Formula F-b may be a ring compound with three rings. In some embodiments, when the number of both (e.g., simultaneously) U and V is 1, a fused ring having the fluorene core of Formula F-b may be a ring compound with five rings.

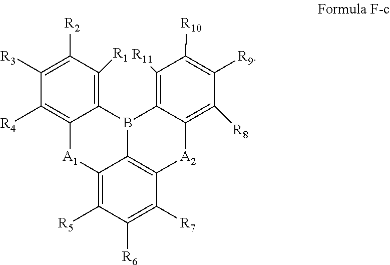

In Formula F-c, A₁ and A₂ may each independently be O, S, Se, or NRₘ, and Rₘ may be hydrogen, deuterium, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. R₁ to R₁₁ may each independently be hydrogen, deuterium, a halogen, a cyano group, a substituted or unsubstituted amine group, a substituted or unsubstituted boryl group, a substituted or unsubstituted oxy group, a substituted or unsubstituted thiol group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring.

In Formula F-c, A₁ and A₂ may each independently be combined with the substituents of an adjacent ring to form a fused ring. For example, when A₁ and A₂ may each independently be NRₘ, A₁ may be combined with R₄ or R₅ to form a ring. In some embodiments, A₂ may be combined with R₇ or R₈ to form a ring.

In one or more embodiments, the emission layer EML may include as a suitable dopant material, one or more selected from styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinylphenyl)-N-phenylbenzenamine (N-BDAVBi), and 4,4′-bis[2-(4-(N,N-diphenylamino)phenyl)vinyl]biphenyl (DPAVBi)), perylene and the derivatives thereof (for example, 2,5,8,11-tetra-t-butylperylene (TBP)), pyrene and the derivatives thereof (for example, 1,1-dipyrene, 1,4-dipyrenylbenzene, and 1,4-bis(N,N-diphenylamino)pyrene), etc.

In one or more embodiments, the emission layer EML may include a suitable phosphorescence dopant material. For example, the phosphorescence dopant may utilize a metal complex including iridium (Ir), platinum (Pt), osmium (Os), gold (Au), titanium (Ti), zirconium (Zr), hafnium (Hf), europium (Eu), terbium (Tb), or thulium (Tm). For example, iridium(III) bis(4,6-difluorophenylpyridinato-N,C2′)picolinate (Flrpic), bis(2,4-difluorophenylpyridinato)-tetrakis(1-pyrazolyl)borate iridium(III) (Fir6), or platinum octaethyl porphyrin (PtOEP) may be utilized as the phosphorescence dopant material. However, embodiments of the present disclosure are not limited thereto.

In one or more embodiments, the emission layer EML may include a quantum dot material. The core of the quantum dot material may be selected from a II-VI group compound, a III—VI group compound, a group compound, a III—V group compound, a III—II—V group compound, a IV—VI group compound, a IV group element, a IV group compound, and combinations thereof.

The II-VI group compound may be selected from the group consisting of: a binary compound selected from the group consisting of CdSe, CdTe, CdS, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and mixtures thereof.

The III-VI group compound may include a binary compound such as In₂S₃ and/or In₂Se₃, a ternary compound such as InGaS₃ and/or InGaSe₃, or one or more suitable combinations thereof.

The I-III-VI group compound may be selected from a ternary compound selected from the group consisting of AgInS, AgInS₂, CuInS, CuInS₂, AgGaS₂, CuGaS₂, CuGaO₂, AgGaO₂, AgAlO₂, and mixtures thereof, and/or a quaternary compound such as AgInGaS₂ and/or CuInGaS₂.

The III-V group compound may be selected from the group consisting of a binary compound selected from the group consisting of GaN, GaP, GaAs, GaSb, AlN, AIP, AlAs, AlSb, InN, InP, InAs, InSb, and mixtures thereof, a ternary compound selected from the group consisting of GaNP, GaNAs, GaNSb, GaPAs, GaPSb, AINP, AINAs, AINSb, AIPAs, AIPSb, InGaP, InAIP, InNP, InNAs, InNSb, InPAs, InPSb, and mixtures thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAINAs, InAlNSb, InAIPAs, InAlPSb, and mixtures thereof. In some embodiments, the III-V group compound may further include a II group metal. For example, InZnP, etc. may be selected as a III-II-V group compound.

The IV-VI group compound may be selected from the group consisting of a binary compound selected from the group consisting of SnS, SnSe, SnTe, PbS, PbSe, PbTe, and mixtures thereof, a ternary compound selected from the group consisting of SnSeS, SnSeTe, SnSTe, PbSeS, PbSeTe, PbSTe, SnPbS, SnPbSe, SnPbTe, and mixtures thereof, and a quaternary compound selected from the group consisting of SnPbSSe, SnPbSeTe, SnPbSTe, and mixtures thereof. The IV group element may be selected from the group consisting of Si, Ge, and a mixture thereof. The IV group compound may be a binary compound selected from the group consisting of SiC, SiGe, and a mixture thereof.

In one or more embodiments, the binary compound, the ternary compound, or the quaternary compound may be present at substantially uniform concentration distribution in a particle or may be present at a partially different concentration distribution within substantially the same particle. In some embodiments, a core/shell structure in which one quantum dot wraps another quantum dot may be desirable. The interface of the core and the shell may have a concentration gradient in which the concentration of an element present in the shell is decreased toward the center.

In some embodiments, the quantum dot may have the above-described core-shell structure including a core including a nanocrystal and a shell wrapping the core. The shell of the quantum dot may play the role of a protection layer for preventing or reducing the chemical deformation of the core to maintain semiconductor properties and/or a charging layer for imparting the quantum dot with electrophoretic properties. The shell may have a single layer or a multilayer. Examples of the shell of the quantum dot may include a metal or non-metal oxide, a semiconductor compound, or combinations thereof.

For example, the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and/or NiO, and/or a ternary compound such as MgAl₂O₄, CoFe₂O₄, NiFe₂O₄ and/or CoMn₂O₄, but embodiments of the present disclosure are not limited thereto.

Also, the semiconductor compound suitable as a shell may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AIP, AlSb, etc., but embodiments of the present disclosure are not limited thereto.

The quantum dot may have a full width of half maximum (FWHM) of emission spectrum of about 45 nm or less, about 40 nm or less, or about 30 nm or less. Within this range, the color purity or color reproducibility of the light emitting device may be improved. In some embodiments, light emitted via such quantum dots is emitted in all directions, and light view angle properties may be improved.

In some embodiments, the shape of the quantum dot may be generally utilized shapes in the art, without specific limitation. in one or more embodiments, the shape of substantially spherical, pyramidal, multi-arm, or cubic nanoparticle, nanotube, nanowire, nanofiber, nanoplate particle, etc. may be utilized.

The quantum dot may control the color of light emitted according to the particle size, and accordingly, the quantum dot may have one or more suitable emission colors such as blue, red, and/or green.

In the light emitting devices ED of one or more embodiments, as shown in FIG. 3 to FIG. 6, the electron transport region ETR may be provided on the emission layer EML. The electron transport region ETR may include at least one of an electron blocking layer HBL, an electron transport layer ETL, or an electron injection layer EIL. However, embodiments of the present disclosure are not limited thereto.

The electron transport region ETR may have a single layer formed utilizing a single material, a single layer formed utilizing multiple different materials, or a multilayer structure having multiple layers formed utilizing multiple different materials.

For example, in some embodiments, the electron transport region ETR may have a single layer structure of an electron injection layer EIL or an electron transport layer ETL, or a single layer structure formed utilizing an electron injection material and an electron transport material. Further, in some embodiments, the electron transport region ETR may have a single layer structure formed utilizing multiple different materials, or a structure stacked from the emission layer EML of electron transport layer ETL/electron injection layer EIL, or hole blocking layer HBL/electron transport layer ETL/electron injection layer EIL, without limitation. The thickness of the electron transport region ETR may be, for example, from about 1,000 Å to about 1,500 Å.

The electron transport region ETR may be formed utilizing one or more suitable methods such as a vacuum deposition method, a spin coating method, a casting method, a Langmuir-Blodgett (LB) method, an inkjet printing method, a laser printing method, and/or a laser induced thermal imaging (LITI) method.

In one or more embodiments, the electron transport region ETR may include a compound represented by Formula ET-2.

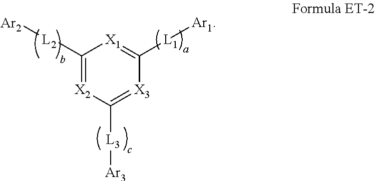

In Formula ET-2, at least one selected from among X₁ to X₃ is N, and the remainder is CRₐ. Rₐ may be hydrogen, deuterium, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. Ar₁ to Ar₃ may each independently be hydrogen, deuterium, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-2, “a” to “c” may each independently be an integer of 0 to 10. In Formula ET-2, L₁ to L₃ may each independently be a direct linkage, a substituted or unsubstituted arylene group of 6 to 30 ring-forming carbon atoms, or a substituted or unsubstituted heteroarylene group of 2 to 30 ring-forming carbon atoms. In some embodiments, when “a” to “c” are integers of 2 or more, L₁ to L₃ may each independently be a substituted or unsubstituted arylene group of 6 to 30 ring-forming carbon atoms, or a substituted or unsubstituted heteroarylene group of 2 to 30 ring-forming carbon atoms.

In one or more embodiments, the electron transport region ETR may include an anthracene-based compound. However, embodiments of the present disclosure are not limited thereto, and, in some embodiments, the electron transport region ETR may include, for example, at least one selected from among tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzimidazolyl-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(biphenyl-4-yl)-4-phenyl-5-tert-butylphenyl-1,2,4-triazole (TAZ), 4-(naphthalen-1-yl)-3,5-diphenyl-4H-1,2,4-triazole (NTAZ), 2-(biphenyl-4-yl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), berylliumbis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), and mixtures thereof, without limitation.

In one or more embodiments, the electron transport region ETR may include at least one selected from among Compounds ET1 to ET36.

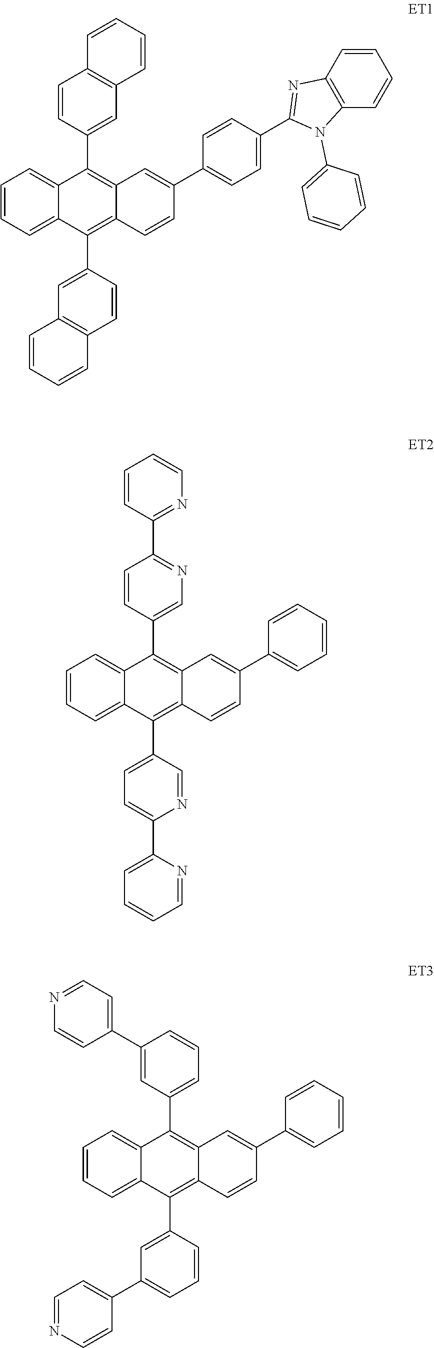 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

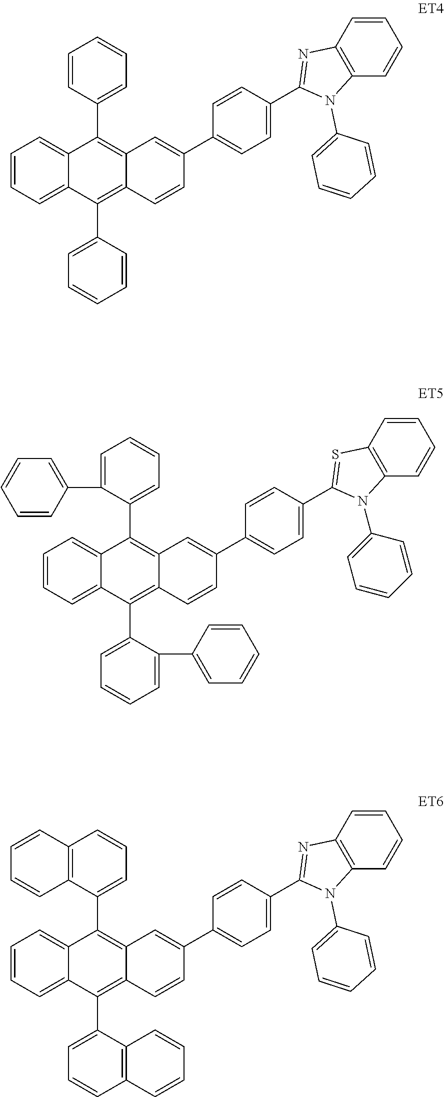

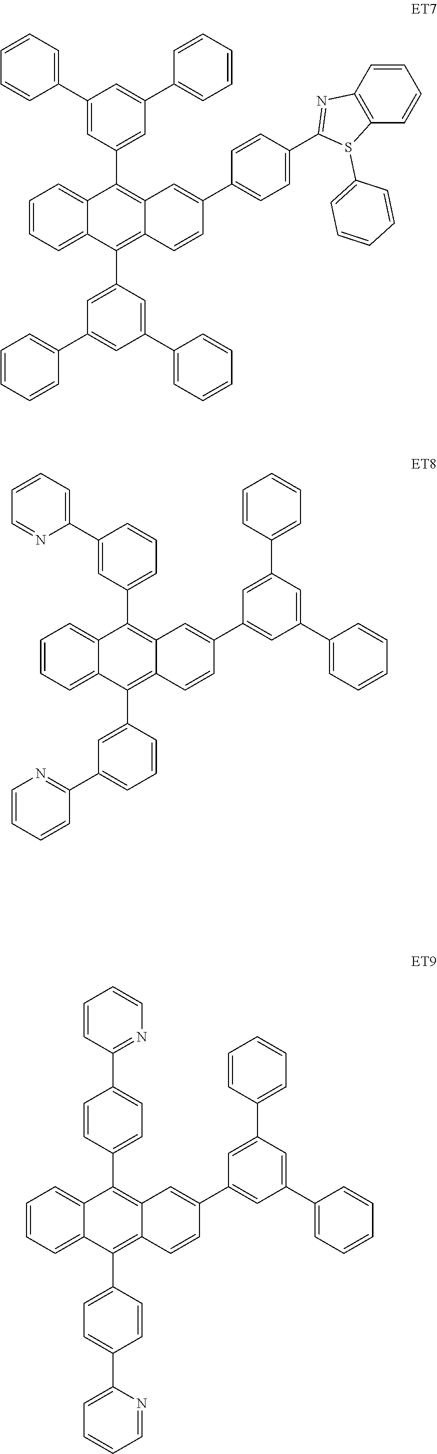

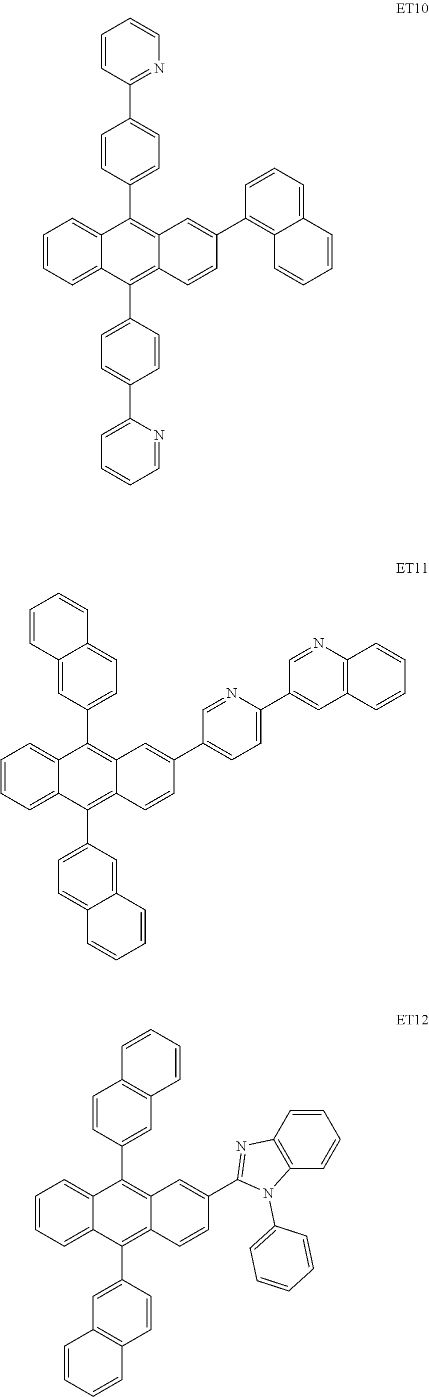 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

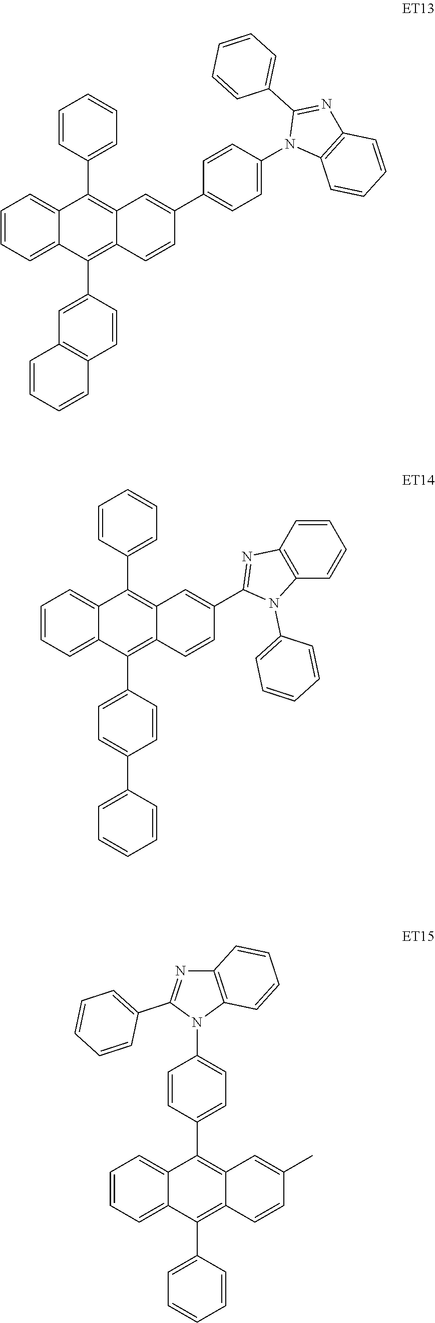 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

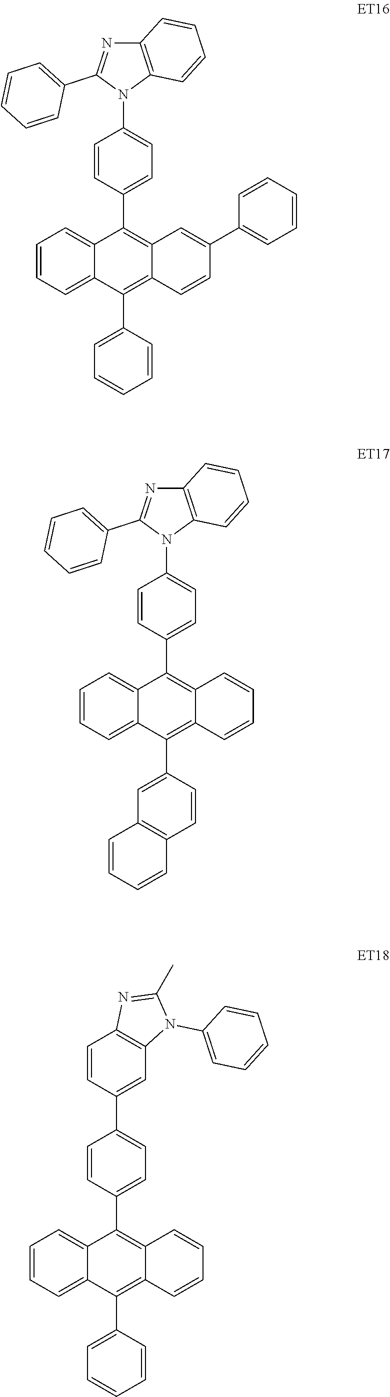 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

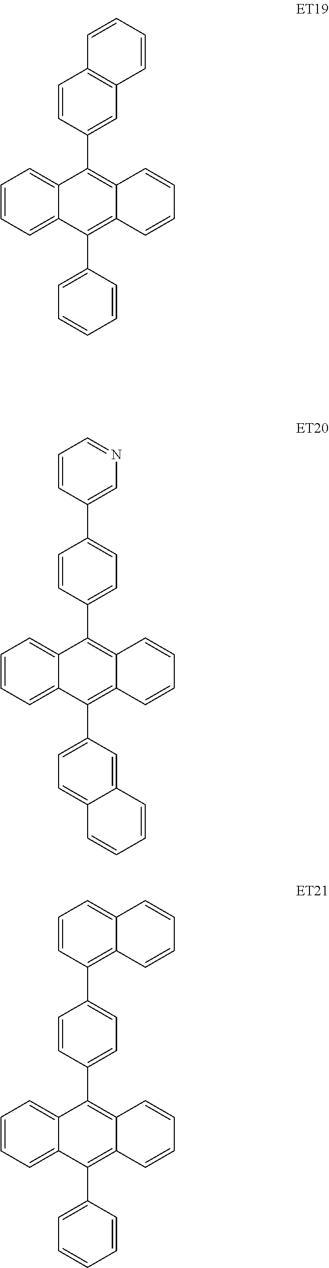

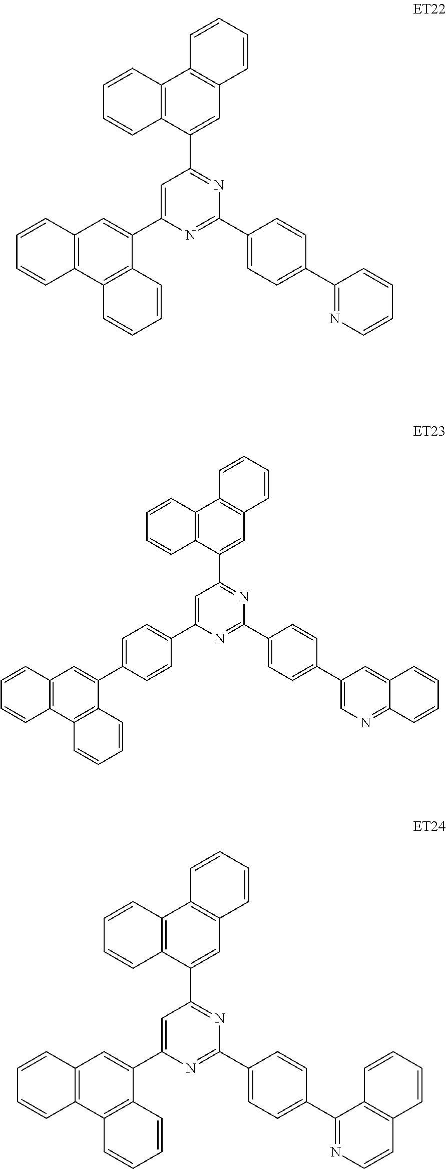 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

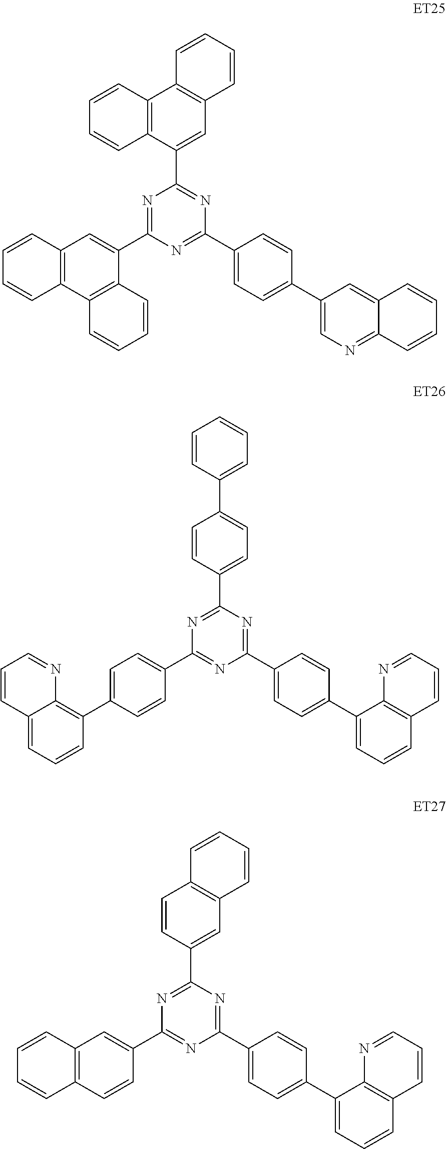 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

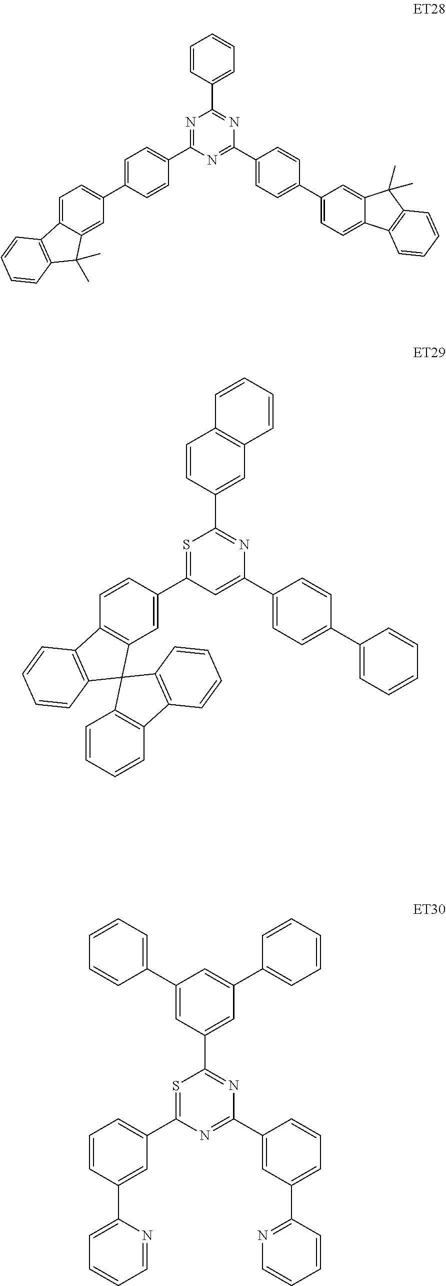

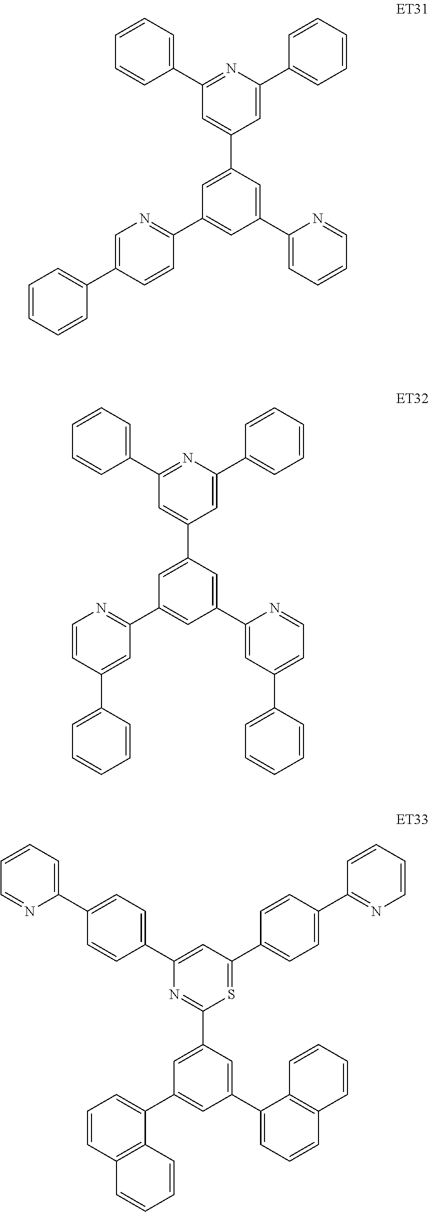

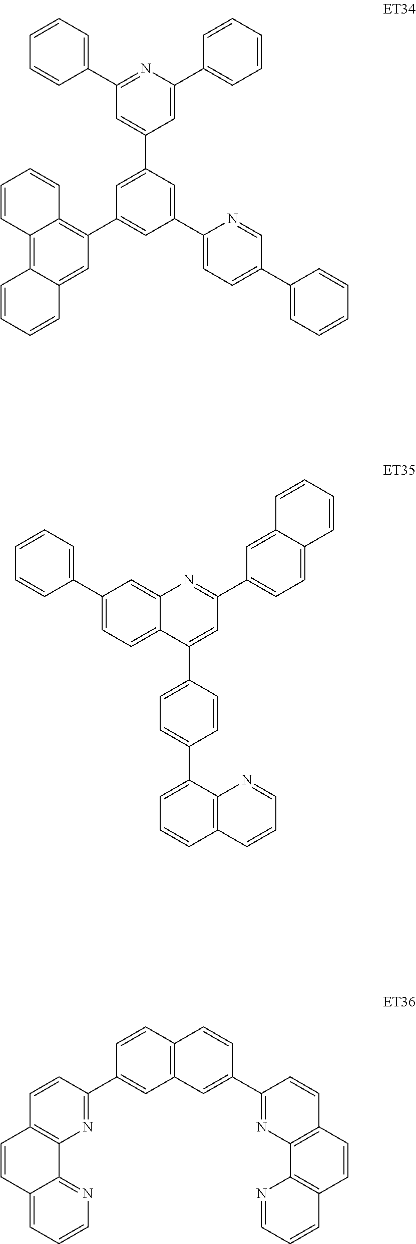 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In some embodiments, the electron transport region ETR may include a metal halide such as LiF, NaCl, CsF, RbCl, RbI, Cul and KI, a lanthanide metal such as Yb, or a co-depositing material of the metal halide and the lanthanide metal. For example, the electron transport region ETR may include KI:Yb, RbI:Yb, LiF:Yb, etc., as the co-depositing material. In some embodiments, the electron transport region ETR may utilize a metal oxide such as Li₂O and/or BaO, or 8-hydroxy-lithium quinolate (Liq). However, embodiments of the present disclosure are not limited thereto. In some embodiments, the electron transport region ETR may also be formed utilizing a mixture material of an electron transport material and an insulating organo metal salt. The organo metal salt may be a material having an energy band gap of about 4 eV or more. For example, the organo metal salt may include, for example, metal acetates, metal benzoates, metal acetoacetates, metal acetylacetonates, and/or metal stearates.

In one or more embodiments, the electron transport region ETR may include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the aforementioned materials. However, embodiments of the present disclosure are not limited thereto.

The electron transport region ETR may include the above-described compounds of the electron transport region in at least one selected from among an electron injection layer EIL, an electron transport layer ETL, and a hole blocking layer HBL.

When the electron transport region ETR includes an electron transport layer ETL, the thickness of the electron transport layer ETL may be from about 100 Å to about 1,000 Å, for example, from about 150 Å to about 500 Å. When the thickness of the electron transport layer ETL satisfies the above-described range, satisfactory electron transport properties may be obtained without a substantial increase in a driving voltage. When the electron transport region ETR includes an electron injection layer EIL, the thickness of the electron injection layer EIL may be from about 1 Å to about 100 Å, or from about 3 Å to about 90 Å. When the thickness of the electron injection layer EIL satisfies the above described range, satisfactory electron injection properties may be obtained without inducing a substantial increase in a driving voltage.

The second electrode EL2 may be provided on the electron transport region ETR. The second electrode EL2 may be a common electrode. The second electrode EL2 may be a cathode or an anode, but embodiments of the present disclosure are not limited thereto. For example, when the first electrode EL1 is an anode, the second cathode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may include a transparent metal oxide, for example, ITO, IZO, ZnO, ITZO, etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/AI, Mo, Ti, Yb, W, compound(s) thereof, or mixture(s) thereof (for example, AgMg, AgYb, or MgYb). In some embodiments, the second electrode EL2 may have a multilayered structure including a reflective layer or a transflective layer formed utilizing one or more selected from the above-described materials and a transparent conductive layer formed utilizing ITO, IZO, ZnO, ITZO, etc. For example, the second electrode EL2 may include one or more selected from the aforementioned metal materials, combinations of two or more metal materials selected from the aforementioned metal materials, and/or oxides of the aforementioned metal materials.

In some embodiments, the second electrode EL2 may be connected with an auxiliary electrode. When the second electrode EL2 is connected with the auxiliary electrode, the resistance of the second electrode EL2 may decrease.

In one or more embodiments, on the second electrode EL2 in the light emitting device ED, a capping layer CPL may be further disposed. The capping layer CPL may include a multilayer or a single layer.

In one or more embodiments, the capping layer CPL may be an organic layer or an inorganic layer. For example, in some embodiments, when the capping layer CPL includes an inorganic material, the inorganic material may include an alkali metal compound such as LiF, an alkaline earth metal compound such as MgF₂, SiON, SiNx, SiOy, etc.

For example, in some embodiments, when the capping layer CPL includes an organic material, the organic material may include 2,2′-dimethyl-N,N′-di-[(1-naphthyl)-N,N′-diphenyl]-1,1′-biphenyl-4,4′-diamine(α-NPD), NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol-9-yl) triphenylamine (TCTA), etc., or includes an epoxy resin, and/or acrylate such as methacrylate. In some embodiments, the capping layer CPL may include at least one selected from among Compounds P1 to P5, but embodiments of the present disclosure are not limited thereto.

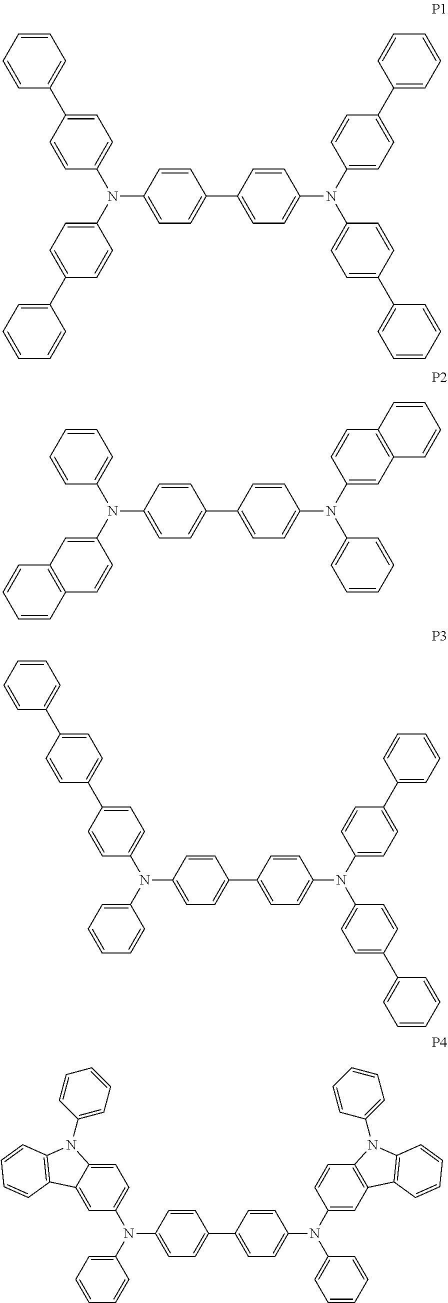 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

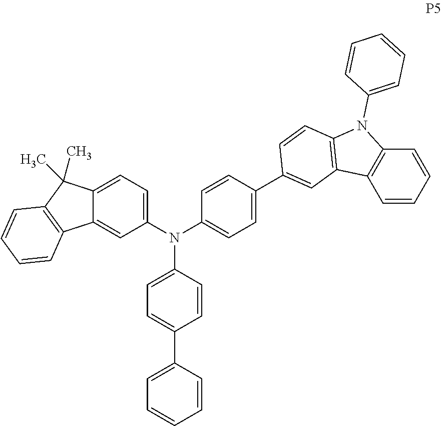 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the capping layer CPL may be about 1.6 or more. For example, in some embodiments, the refractive index of the capping layer CPL with respect to light in a wavelength range of about 550 nm to about 660 nm may be about 1.6 or more.

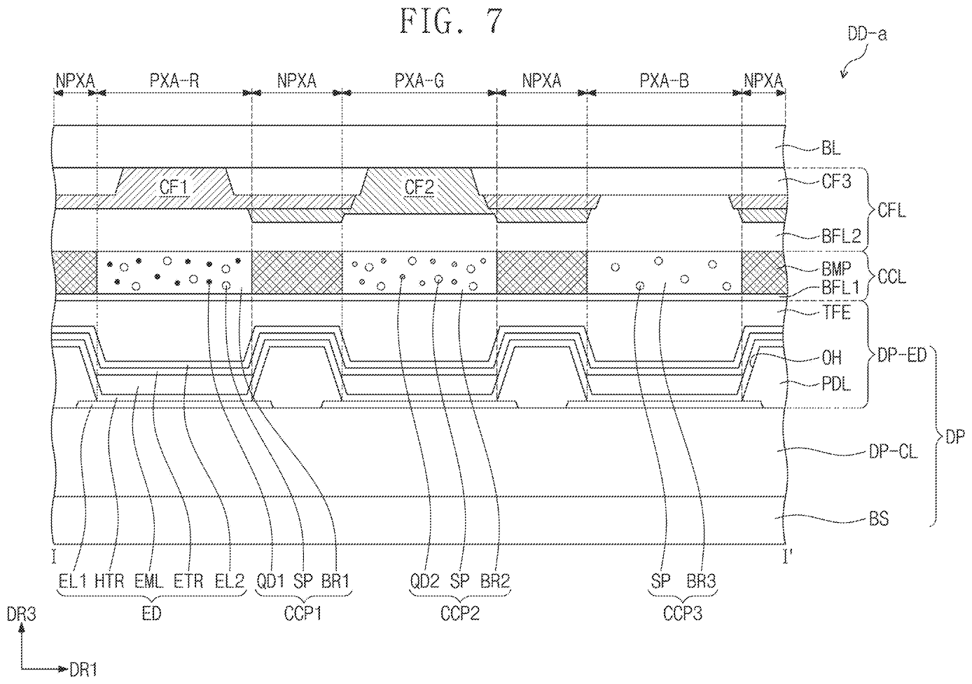

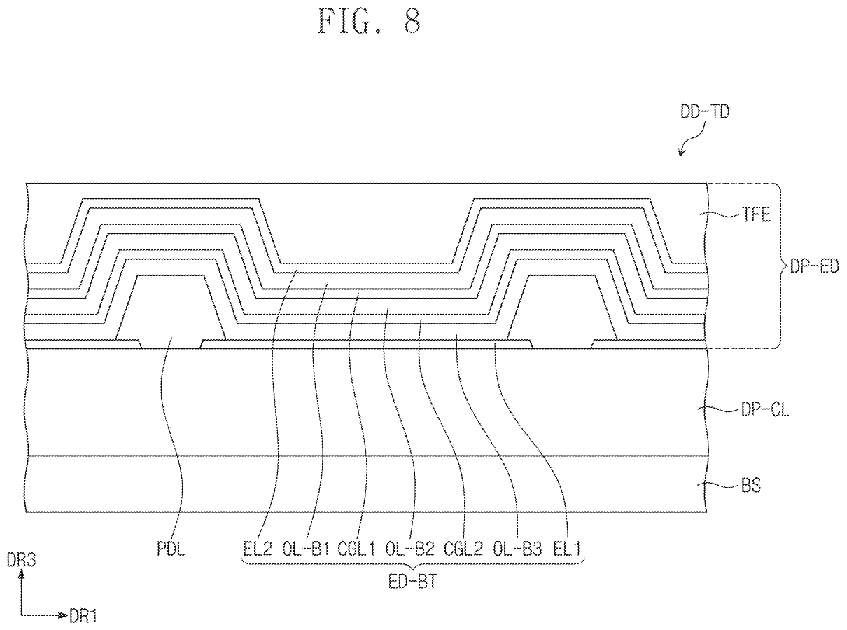

FIG. 7 to FIG. 10 are cross-sectional views on display apparatuses according to one or more embodiments of the present disclosure. In the explanation on the display apparatuses of embodiments by referring to FIG. 7 to FIG. 10, the overlapping parts with the explanation on FIG. 1 to FIG. 6 will not be explained/described again for conciseness, and only different features will be explained chiefly and mainly.

Referring to FIG. 7, the display apparatus DD-a according to one or more embodiments of the present disclosure may include a display panel DP including a display device layer DP-ED, a light controlling layer CCL disposed on the display panel

DP, and a color filter layer CFL. In one or more embodiments shown in FIG. 7, the display panel DP may include a base layer BS, a circuit layer DP-CL provided on the base layer BS, and a display device layer DP-ED, and the display device layer DP-ED may include a light emitting device ED.

The light emitting device ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In one or more embodiments, the same structures as the light emitting devices of FIG. 3 to FIG. 6 may be applied to the structure of the light emitting device ED shown in FIG. 7.

In the display apparatus DD-a according to one or more embodiments, the emission layer EML of the light emitting device ED may include the fused polycyclic compound of one or more embodiments of the present disclosure.

Referring to FIG. 7, the emission layer EML may be disposed in an opening part OH defined in a pixel definition layer PDL. For example, the emission layer EML divided by the pixel definition layer PDL and correspondingly provided to each of luminous areas PXA-R, PXA-G, and PXA-B may be to emit light in substantially the same wavelength region. In the display apparatus DD-a of one or more embodiments, the emission layer EML may be to emit blue light. In some embodiments, the emission layer EML may be provided as a common layer for all luminous areas PXA-R, PXA-G, and PXA-B.

The light controlling layer CCL may be disposed on the display panel DP. The light controlling layer CCL may include a light converter. The light converter may be a quantum dot or a phosphor. The light converter may transform the wavelength of light provided and then emit. For example, the light controlling layer CCL may be a layer including a quantum dot or a layer including a phosphor.

The light controlling layer CCL may include multiple light controlling parts CCP1, CCP2, and CCP3. The light controlling parts CCP1, CCP2, and CCP3 may be separated and apart from one another.

Referring to FIG. 7, a partition pattern BMP may be disposed between the separated light controlling parts CCP1, CCP2, and CCP3, but embodiments of the present disclosure are not limited thereto. In FIG. 7, the partition pattern BMP is shown not to be overlapped with the light controlling parts CCP1, CCP2, and CCP3, but, in some embodiments, at least a portion of the edges of the light controlling parts CCP1, CCP2, and CCP3 may be overlapped with the partition pattern BMP.

The light controlling layer CCL may include a first light controlling part CCP1 including a first quantum dot QD1 converting first color light provided from the light emitting device ED into second color light, a second light controlling part CCP2 including a second quantum dot QD2 converting the first color light into third color light, and a third light controlling part CCP3 transmitting the first color light.

In one or more embodiments, the first light controlling part CCP1 may provide red light which is the second color light, and the second light controlling part CCP2 may provide green light which is the third color light. The third color controlling part CCP3 may be to transmit and provide blue light which is the first color light provided from the light emitting device ED. For example, the first quantum dot QD1 may be a red quantum dot to emit red light, and the second quantum dot QD2 may be a green quantum dot to emit green light. On the quantum dots QD1 and QD2, the same content as those described above may be applied.

In some embodiments, the light controlling layer CCL may further include a scatterer SP. The first light controlling part CCP1 may include the first quantum dot QD1 and the scatterer SP, the second light controlling part CCP2 may include the second quantum dot QD2 and the scatterer SP, and the third light controlling part CCP3 may not include (e.g., may exclude) a quantum dot but include the scatterer SP.

The scatterer SP may be an inorganic particle. For example, the scatterer SP may include at least one selected from among TiO₂, ZnO, Al₂O₃, SiO₂, and hollow silica. In one or more embodiments, the scatterer SP may include at least one selected from among TiO₂, ZnO, Al₂O₃, SiO₂, and hollow silica, or may be a mixture of two or more materials selected from among TiO₂, ZnO, Al₂O₃, SiO₂, and hollow silica.

The first light controlling part CCP1, the second light controlling part CCP2, and the third light controlling part CCP3 may respectively include base resins BR1, BR2, and BR3 dispersing the quantum dots QD1 and QD2 and the scatterer SP. In one or more embodiments, the first light controlling part CCP1 may include the first quantum dot QD1 and the scatterer SP dispersed in a first base resin BR1, the second light controlling part CCP2 may include the second quantum dot QD2 and the scatterer SP dispersed in a second base resin BR2, and the third light controlling part CCP3 may include the scatterer particle SP dispersed in a third base resin BR3.

The base resins BR1, BR2, and BR3 are mediums in which the quantum dots QD1 and QD2 and the scatterer SP are dispersed, and may be composed of one or more suitable resin compositions which may be generally referred to as a binder. For example, the base resins BR1, BR2 and BR3 may independently be acrylic resins, urethane-based resins, silicone-based resins, epoxy-based resins, etc. The base resins BR1, BR2 and BR3 may be transparent resins. In one or more embodiments, the first base resin BR1, the second base resin BR2, and the third base resin BR3 may be the same or different from each other.

In one or more embodiments, the light controlling layer CCL may include a barrier layer BFL1. The barrier layer BFL1 may play a role of blocking the penetration of moisture and/or oxygen (hereinafter, will be referred to as “humidity/oxygen”). The barrier layer BFL1 may block or reduce the exposure of the light controlling parts CCP1, CCP2, and CCP3 to humidity/oxygen. In some embodiments, the barrier layer BFL1 may cover the light controlling parts CCP1, CCP2, and CCP3. In some embodiments, a color filter layer CFL, which will be explained later, may include a barrier layer BFL2 disposed on the light controlling parts CCP1, CCP2, and CCP3.

The barrier layers BFL1 and BFL2 may include at least one inorganic layer. For example, in some embodiments, the barrier layers BFL1 and BFL2 may be formed by including an inorganic material. For example, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, and/or a thin metal film to secure light transmittance. In some embodiments, the barrier layers BFL1 and BFL2 may further include an organic layer. The barrier layers BFL1 and BFL2 may be composed of a single layer or multiple layers.

In one or more embodiments, in the display apparatus DD-a, the color filter layer CFL may be disposed on the light controlling layer CCL. For example, in some embodiments, the color filter layer CFL may be disposed directly on the light controlling layer CCL. In these embodiments, the barrier layer BFL2 may not be provided.

The color filter layer CFL may include filters CF1, CF2, and CF3. Each of the first to third filters CF1, CF2 and CF3 may be disposed corresponding to a red luminous area PXA-R, a green luminous area PXA-G, and a blue luminous area PXA-B, respectively.

The color filter layer CFL may include a first filter CF1 transmitting the second color light, a second filter CF2 transmitting the third color light, and a third filter CF3 transmitting the first color light. For example, in some embodiments, the first filter CF1 may be a red filter, the second filter CF2 may be a green filter, and the third filter CF3 may be a blue filter. Each of the filters CF1, CF2 and CF3 may include a polymer photosensitive resin and a pigment and/or dye. The first filter CF1 may include a red pigment and/or dye, the second filter CF2 may include a green pigment and/or dye, and the third filter CF3 may include a blue pigment and/or dye.

However, embodiments of the present disclosure are not limited thereto, for example, in some embodiments, the third filter CF3 may not include (e.g., may exclude) the pigment and/or dye (e.g., not include any pigment or dye). The third filter CF3 may include a polymer photosensitive resin and not include a pigment and/or dye (e.g., not include any pigment or dye). The third filter CF3 may be transparent. The third filter CF3 may be formed utilizing a transparent photosensitive resin.

In one or more embodiments, the first filter CF1 and the second filter CF2 may be yellow filters. The first filter CF1 and the second filter CF2 may be provided in one body without distinction.

In one or more embodiments, the color filter layer CFL may further include a light blocking part. The light blocking part may be a black matrix. The light blocking part may be formed by including an organic light blocking material and/or an inorganic light blocking material including a black pigment and/or black dye. The light blocking part may prevent or reduce light leakage phenomenon and divide the boundaries among adjacent filters CF1, CF2, and CF3.

On the color filter layer CFL, a base substrate BL may be disposed/provided. The base substrate BL may be a member providing a base surface on which the color filter layer CFL, the light controlling layer CCL, etc. are disposed. The base substrate BL may be a glass substrate, a metal substrate, a plastic substrate, etc. However, embodiments of the present disclosure are not limited thereto, and the base substrate BL may be an inorganic layer, an organic layer, or a composite material layer. In some embodiments, the base substrate BL may not be provided.

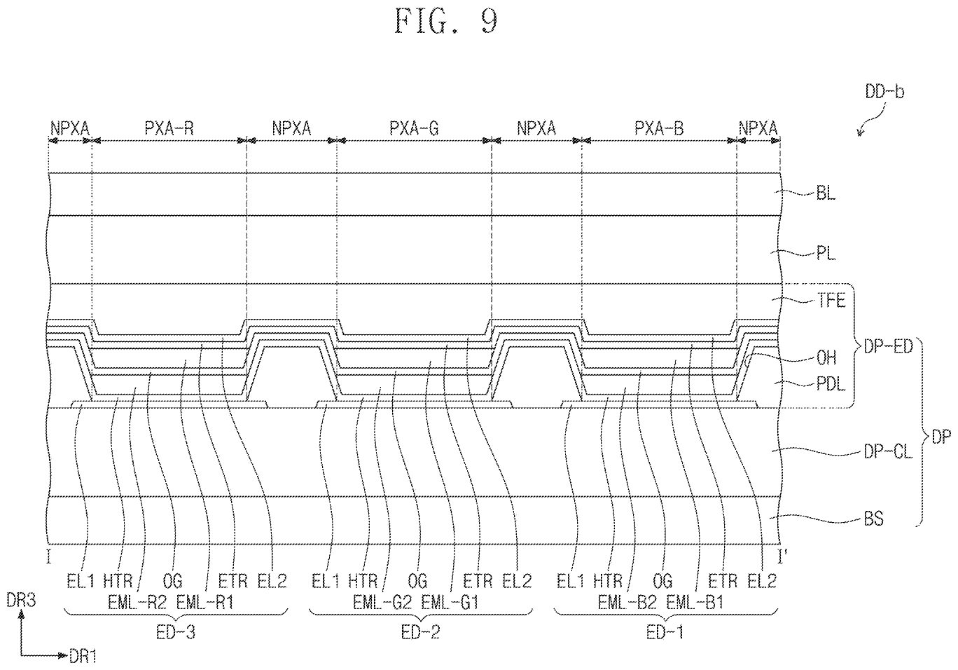

FIG. 8 is a cross-sectional view showing a portion of a display apparatus according to one or more embodiments of the present disclosure. In a display apparatus DD-TD of one or more embodiments, the light emitting device ED-BT may include multiple light emitting structures OL-B1, OL-B2, and OL-B3. The light emitting device ED-BT may include oppositely disposed first electrode EL1 and second electrode EL2, and the multiple light emitting structures OL-B1, OL-B2, and OL-B3 stacked in order in a thickness direction and provided between the first electrode EL1 and the second electrode EL2. Each of the light emitting structures OL-B1, OL-B2, and OL-B3 may include an emission layer EML (FIG. 7), and a hole transport region HTR and an electron transport region ETR disposed with the emission layer EML (FIG. 7) therebetween.

For example, in some embodiments, the light emitting device ED-BT included in the display apparatus DD-TD may be a light emitting device of a tandem structure including multiple emission layers.

In one or more embodiments shown in FIG. 8, light emitted from the light emitting structures OL-B1, OL-B2, and OL-B3 may be all blue light. However, embodiments of the present disclosure are not limited thereto, and the wavelength regions of light emitted from the light emitting structures OL-B1, OL-B2, and OL-B3 may be different from each other. For example, in one or more embodiments, the light emitting device ED-BT including the multiple light emitting structures OL-B1, OL-B2, and OL-B3 emitting light in different wavelength regions may be to emit white light (e.g., combined white light).

Between neighboring light emitting structures OL-B1, OL-B2, and OL-B3, charge generating layers CGL1 and CGL2 may be disposed. The charge generating layers CGL1 and CGL2 may include a p-type or kind charge (e.g., P-charge) generating layer and/or an n-type or kind charge (e.g., N-charge) generating layer.

In at least one selected from among the light emitting structures OL-B1, OL-B2, and OL-B3, included in the display apparatus DD-TD of one or more embodiments, the fused polycyclic compound of one or more embodiments may be included. For example, in one or more embodiments, at least one selected from among multiple emission layers included in the light emitting device ED-BT may include the fused polycyclic compound of one or more embodiments.

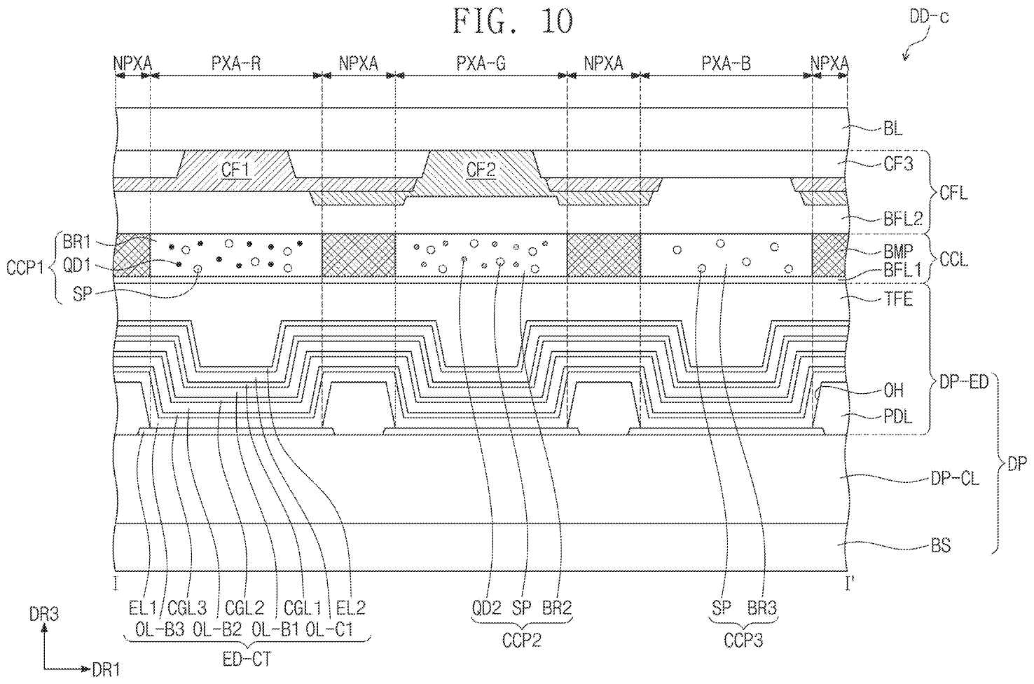

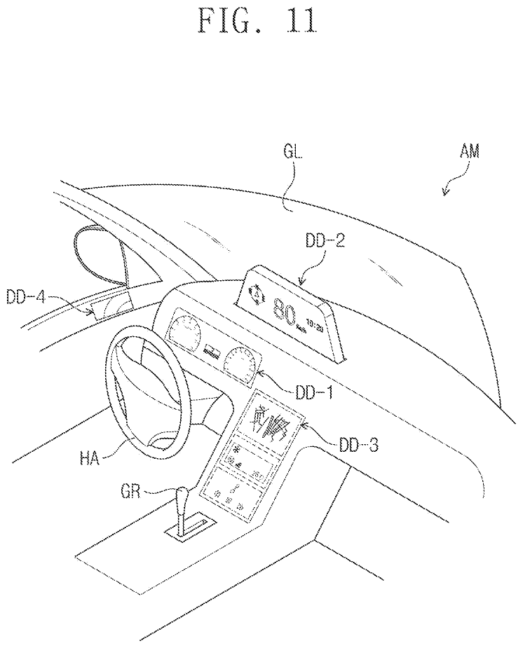

FIG. 9 is a cross-sectional view showing a display apparatus according to one or more embodiments of the present disclosure. FIG. 10 is a cross-sectional view showing a display apparatus according to one or more embodiments of the present disclosure.

Referring to FIG. 9, a display apparatus DD-b according to one or more embodiments may include light emitting devices ED-1, ED-2, and ED-3, each formed by stacking two emission layers. Compared to the display apparatus DD shown in FIG. 2, the display apparatus DD-b shown in FIG. 9 is different in that first to third light emitting devices ED-1, ED-2, and ED-3 each include two emission layers stacked in a thickness direction. In each of the first to third light emitting devices ED-1, ED-2, and ED-3, the two emission layers may be to emit light in substantially the same wavelength region.

In one or more embodiments, the first light emitting device ED-1 may include a first red emission layer EML-R₁ and a second red emission layer EML-R₂. The second light emitting device ED-2 may include a first green emission layer EML-G1 and a second green emission layer EML-G2. In addition, the third light emitting device ED-3 may include a first blue emission layer EML-B1 and a second blue emission layer EML-B2. Between the first red emission layer EML-R₁ and the second red emission layer EML-R₂, between the first green emission layer EML-G1 and the second green emission layer EML-G2, and between the first blue emission layer EML-B1 and the second blue emission layer EML-B2, an emission auxiliary part OG may be disposed.

The emission auxiliary part OG may include a single layer or a multilayer. The emission auxiliary part OG may include a charge generating layer. In one or more embodiments, the emission auxiliary part OG may include an electron transport region, a charge generating layer, and a hole transport region stacked in order (e.g., in the stated order). The emission auxiliary part OG may be provided as a common layer in all of the first to third light emitting devices ED-1, ED-2, and ED-3. However, embodiment of the present disclosure are not limited thereto, and, in some embodiments, the emission auxiliary part OG may be patterned and provided in an opening part OH defined in a pixel definition layer PDL.

The first red emission layer EML-R₁, the first green emission layer EML-G1, and the first blue emission layer EML-B1 may be disposed between the electron transport region ETR and the emission auxiliary part OG. The second red emission layer EML-R₂, the second green emission layer EML-G2, and the second blue emission layer EML-B2 may be disposed between the emission auxiliary part OG and the hole transport region HTR.

For example, in one or more embodiments, the first light emitting device ED-1 may include a first electrode EL1, a hole transport region HTR, a second red emission layer EML-R₂, an emission auxiliary part OG, a first red emission layer EML-R₁, an electron transport region ETR, and a second electrode EL2, stacked in order (e.g., in the stated order). The second light emitting device ED-2 may include a first electrode EL1, a hole transport region HTR, a second green emission layer EML-G2, an emission auxiliary part OG, a first green emission layer EML-G1, an electron transport region ETR, and a second electrode EL2, stacked in order (e.g., in the stated order). The third light emitting device ED-3 may include a first electrode EL1, a hole transport region HTR, a second blue emission layer EML-B2, an emission auxiliary part OG, a first blue emission layer EML-B1, an electron transport region ETR, and a second electrode EL2, stacked in order (e.g., in the stated order).

In some embodiments, an optical auxiliary layer PL may be disposed on a display device layer DP-ED. The optical auxiliary layer PL may include a polarization layer. The optical auxiliary layer PL may be disposed on a display panel DP and may control reflected light at the display panel DP by external light. In some embodiments, the optical auxiliary layer PL may not be provided in the display apparatus.

In one or more embodiments, at least one emission layer included in the display apparatus DD-b shown in FIG. 9 may include the fused polycyclic compound of one or more embodiments of the present disclosure. For example, in one or more embodiments, at least one selected from among a first blue emission layer EML-B1 and a second blue emission layer EML-B2 may include the fused polycyclic compound of one or more embodiments of the present disclosure.

Different from FIG. 8 and FIG. 9, a display apparatus DD-c in FIG. 10 is shown to include four light emitting structures OL-B1, OL-B2, OL-B3, and OL-C1. A light emitting device ED-CT may include oppositely disposed first electrode EU and second electrode EL2, and first to fourth light emitting structures OL-B1, OL-B2, OL-B3, and OL-C1 stacked in a thickness direction between the first electrode EL1 and the second electrode EL2. Between the first to fourth light emitting structures OL-B1, OL-B2, OL-B3, and OL-C1, charge generating layers CGL1, CGL2, and CGL3 may be disposed. Among the four light emitting structures, the first to third light emitting structures OL-B1, OL-B2, and OL-B3 may be to emit blue light, and the fourth light emitting structure OL-C1 may be to emit green light. However, embodiments of the present disclosure are not limited thereto, and the first to fourth light emitting structures OL-B1, OL-B2, OL-B3, and OL-C1 may be to emit different wavelengths of light.

Charge generating layers CGL1, CGL2, and CGL3 disposed among neighboring light emitting structures OL-B1, OL-B2, OL-B3, and OL-C1 may include a p-type or kind charge (e.g., P-charge) generating layer and/or an n-type or kind charge (e.g., N-charge) generating layer.

In at least one selected from among the light emitting structures OL-B1, OL-B2, OL-B3, and OL-C1, included in the display apparatus DD-c of one or more embodiments, the fused polycyclic compound of one or more embodiments of the present disclosure may be included. For example, in one or more embodiments, at least one selected from among the first to third light emitting structures OL-B1, OL-B2, and OL-B3 may include the fused polycyclic compound of one or more embodiments of the present disclosure.

The light emitting device ED according to one or more embodiments of the present disclosure may include the fused polycyclic compound of one or more embodiments, represented by Formula 1, in at least one functional layer disposed between a first electrode and a second electrode EL2 and may show excellent or suitable emission efficiency and improved lifetime characteristics. For example, in one or more embodiments, the fused polycyclic compound according to one or more embodiments may be included in the emission layer EML of the light emitting device ED, and the light emitting device may show long lifetime characteristics.

In one or more embodiments, an electronic apparatus may include a display apparatus including multiple light emitting devices and a control part controlling the display apparatus. The electronic apparatus of one or more embodiments may be an apparatus activated according to electrical signals. The electronic apparatus may include display apparatuses of one or more embodiments. For example, the electronic apparatus may include at least one selected from televisions, monitors, large-size display apparatuses such as outside billboards, personal computers, laptop computers, personal digital terminals, display apparatuses for automobiles, game consoles, portable electronic devices, and medium- and small-size display apparatuses such as cameras.

FIG. 11 is a diagram showing an automobile AM in which first to fourth display apparatuses DD-1, DD-2, DD-3, and DD-4 are disposed. At least one selected from among the first to fourth display apparatuses DD-1, DD-2, DD-3, and DD-4 may include substantially the same configurations of the display apparatuses DD, DD-TD, DD-a, DD-b, and/or DD-c explained referring to FIGS. 1, 2, and 7 to 10.

In FIG. 11, a vehicle is shown as an automobile AM, but this is a mere example. The first to fourth display apparatuses DD-1, DD-2, DD-3, and DD-4 may be disposed on other transport apparatuses such as bicycles, motorcycles, trains, ships, and airplanes. In one or more embodiments, at least one selected from among the first to fourth display apparatuses DD-1, DD-2, DD-3, and DD-4 including substantially the same configurations of the display apparatuses DD, DD-TD, DD-a, DD-b, and/or DD-c may be introduced in personal computers, laptop computers, personal digital terminals, game consoles, portable electronic devices, televisions, monitors, external billboards, and/or the like. These are mere examples, and the display apparatus may be introduced in other electronic devices as long as not deviated from the present disclosure.

In one or more embodiments, at least one selected from among the first to fourth display apparatuses DD-1, DD-2, DD-3, and DD-4 may include the light emitting device ED of one or more embodiments, explained referring to FIG. 3 to FIG. 6. The light emitting device ED of one or more embodiments may include the fused polycyclic compound of one or more embodiments of the present disclosure. In one or more embodiments, at least one selected from among the first to fourth display apparatuses DD-1, DD-2, DD-3, and DD-4 may include the light emitting device ED including the fused polycyclic compound of one or more embodiments and may show improved display lifetime.

Referring to FIG. 11, an automobile AM may include a steering wheel HA for the operation of the automobile AM and a gear GR. In addition, the automobile AM may include a front window GL disposed to face a driver.

A first display apparatus DD-1 may be disposed in a first region overlapping with the steering wheel HA. For example, the first display apparatus DD-1 may be a digital cluster displaying first information of the automobile AM. The first information may include a first graduation showing the travel speed of the automobile AM, a second graduation showing the number of revolution of an engine (i.e., revolutions per minute (RPM)), and images showing a fuel state. The first graduation and the second graduation may be represented by digital images.

A second display apparatus DD-2 may be disposed in a second region facing a driver's seat and overlapping with the front window GL. The driver's seat may be a seat where the steering wheel HA faces. For example, the second display apparatus DD-2 may be a head up display (HUD) showing second information of the automobile AM. The second display apparatus DD-2 may be optically clear. The second information may include digital numbers showing the travel speed of the automobile AM and may further include information including the current time. In some embodiments, the second information of the second display apparatus DD-2 may be projected and displayed on the front window GL.

A third display apparatus DD-3 may be disposed in a third region adjacent to the gear GR. For example, the third display apparatus DD-3 may be a center information display (CID) for the automobile, disposed between a driver's seat and a passenger seat and showing third information. The passenger seat may be a seat separated from the driver's seat with the gear GR therebetween. The third information may include information on road conditions (for example, navigation information), on playing music or radio, on playing a dynamic image (or image), on the temperature in the automobile AM, and/or the like.

A fourth display apparatus DD-4 may be disposed in a fourth region separated from the steering wheel HA and the gear GR and adjacent to the side of the automobile AM. For example, the fourth display apparatus DD-4 may be a digital wing/side mirror displaying fourth information. The fourth display apparatus DD-4 may display external images of the automobile AM, taken by a camera module CM disposed at the outside of the automobile AM. The fourth information may include external images of the automobile AM.

The above-described first to fourth information is mere examples, and the first to fourth display apparatuses DD-1, DD-2, DD-3, and DD-4 may further display information on the inside and outside of the automobile. The first to fourth information may include different information from each other. However, embodiments of the present disclosure are not limited thereto, for example, in some embodiments, a portion of the first to fourth information may include the same information.

Hereinafter, the fused polycyclic compound according to one or more embodiments and the light emitting device according to one or more embodiments of the present disclosure will be explained in more detail by referring to embodiments/examples and comparative embodiments/examples. In addition, the embodiments/examples described are mere illustrations to assist the understanding of the present disclosure, and the scope of the present disclosure is not limited thereto.

### EXAMPLES

### 1. Synthesis of Fused Polycyclic Compound

First, the synthetic method of the fused polycyclic compound according to one or more embodiments will be explained in detail by illustrating the synthetic methods of Compounds 1, 44, 70, 116, and 135. In addition, the synthetic methods of the fused polycyclic compounds explained hereinafter are embodiments and examples, and the synthetic method of the fused polycyclic compound according to one or more embodiments of the present disclosure is not limited to the embodiments and examples described.

### (1) Synthesis of Intermediate A

### Synthesis of Intermediate A-1

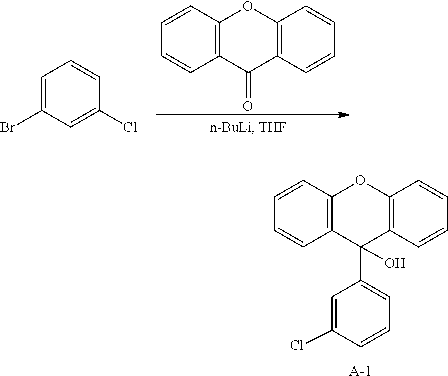

1-Bromo-3-chlorobenzene (1 eq) was dissolved in tetrahydrofuran and then, cooled to about −78° C. for about 30 minutes. Then, n-BuLi/n-hexane (2.5 M, 1.1 eq) was slowly injected thereto. After stirring for about 1 hour, 9H-xanthen-9-one (1 eq) dissolved in tetrahydrofuran was slowly injected. After stirring for about 2 hours, the resultant was quenched with an ammonium chloride solution. The resultant was washed with ethyl acetate and water three times, and an organic layer obtained was dried over MgSO₄ and dried under a reduced pressure. The resultant was purified by column chromatography utilizing dichloromethane and n-hexane as an eluent and recrystallized to obtain Intermediate A-1 (yield: 64%).

### Synthesis of Intermediate A

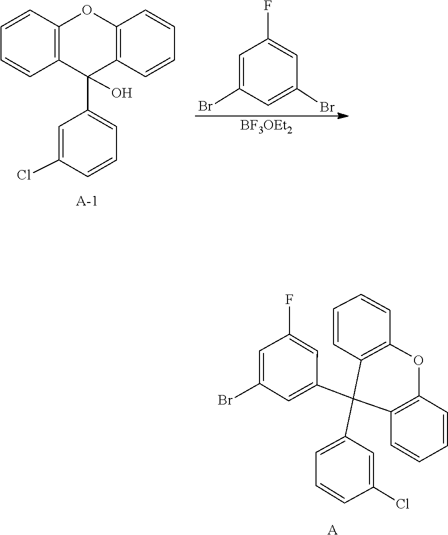

Intermediate A-1 (1 eq), 1,3-dibromo-5-fluorobenzene (20 eq), and boron trifluoride diethyl etherate (0.2 eq) were put in a high-pressure reactor and stirred. The resultant was washed with ethyl acetate and water three times, and an organic layer obtained was dried over MgSO₄ and dried under a reduced pressure. The reaction product thus obtained was purified by column chromatography utilizing dichloromethane and n-hexane as an eluent and recrystallized to obtain Intermediate A (yield: 42%).

### (2) Synthesis of Intermediate B

### Synthesis of Intermediate B-1

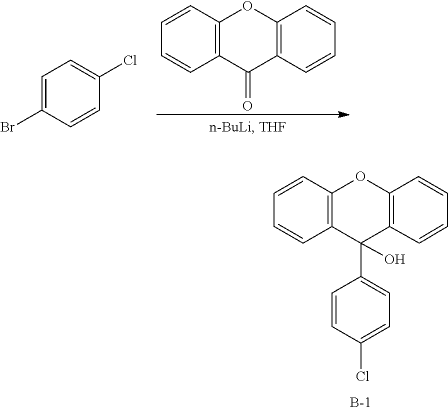

1-Bromo-4-chlorobenzene (1 eq) was dissolved in tetrahydrofuran and then, cooled to about −78° C. for about 30 minutes. Then, n-BuLi/n-hexane (2.5 M, 1.1 eq) was slowly injected thereto. After stirring for about 1 hour, 9H-xanthen-9-one (1 eq) dissolved in tetrahydrofuran was slowly injected. After stirring for about 2 hours, the resultant was quenched with an ammonium chloride solution. The resultant was washed with ethyl acetate and water three times, and an organic layer obtained was dried over MgSO₄ and dried under a reduced pressure. The resultant was purified by column chromatography utilizing dichloromethane and n-hexane as an eluent and recrystallized to obtain Intermediate B-1 (yield: 56%).

### Synthesis of Intermediate B

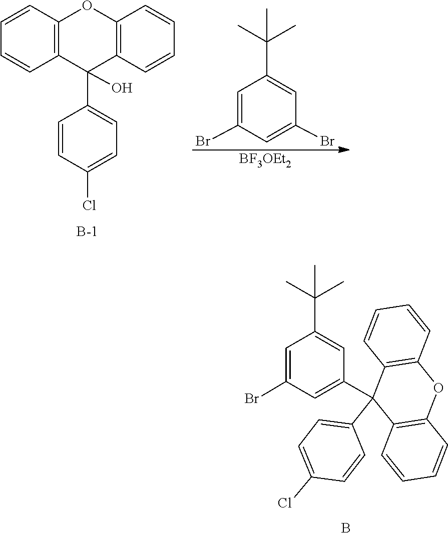

Intermediate B-1 (1 eq), 1,3-dibromo-5-(tert-butyl)benzene (20 eq), and boron trifluoride diethyl etherate (0.2 eq) were put in a high-pressure reactor and stirred. The resultant was washed with ethyl acetate and water three times, and an organic layer obtained was dried over MgSO₄ and dried under a reduced pressure.

The reaction product thus obtained was purified by column chromatography utilizing dichloromethane and n-hexane as an eluent and recrystallized to obtain Intermediate B (yield: 47%).

### (3) Synthesis of Intermediate C

### Synthesis of Intermediate C-1

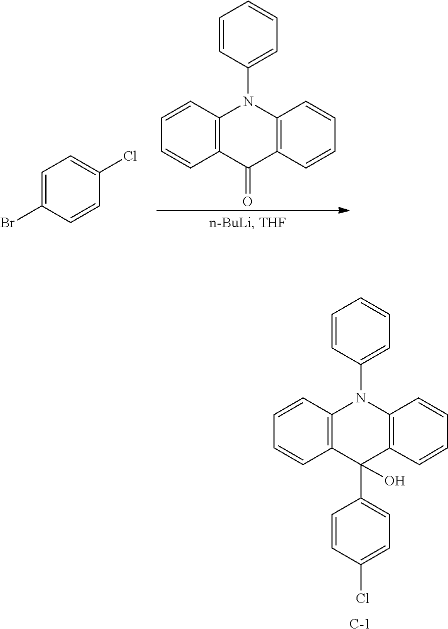

1-Bromo-4-chlorobenzene (1 eq) was dissolved in tetrahydrofuran and then, cooled to about −78° C. for about 30 minutes. Then, n-BuLi/n-hexane (2.5 M, 1.1 eq) was slowly injected thereto. After stirring for about 1 hour, 10-phenylacridin-9(1 OH)-one (1 eq) dissolved in tetrahydrofuran was slowly injected. After stirring for about 2 hours, the resultant was quenched with an ammonium chloride solution. The resultant was washed with ethyl acetate and water three times, and an organic layer obtained was dried over MgSO₄ and dried under a reduced pressure. The reaction product was purified by column chromatography utilizing dichloromethane and n-hexane as an eluent and recrystallized to obtain Intermediate C-1 (yield: 62%).

### Synthesis of Intermediate C

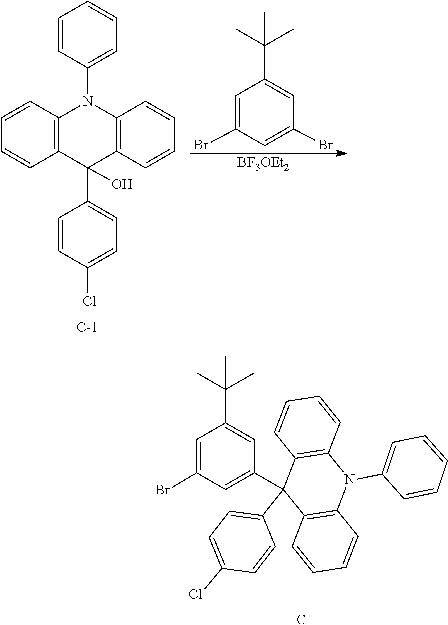

Intermediate C-1 (1 eq), 1,3-dibromo-5-(tert-butyl)benzene (20 eq), and boron trifluoride diethyl etherate (0.2 eq) were put in a high-pressure reactor and stirred. The resultant was washed with ethyl acetate and water three times, and an organic layer obtained was dried over MgSO₄ and dried under a reduced pressure. The reaction product thus obtained was purified by column chromatography utilizing dichloromethane and n-hexane as an eluent and recrystallized to obtain Intermediate C (yield: 64%).

### (4) Synthesis of Intermediate D

### Synthesis of Intermediate D-1

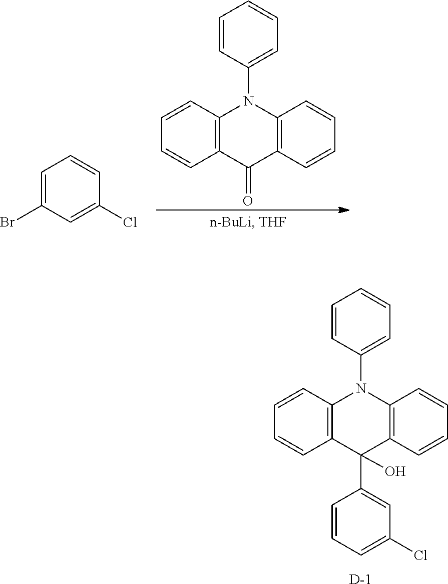

1-Bromo-3-chlorobenzene (1 eq) was dissolved in tetrahydrofuran and then, cooled to about −78° C. for about 30 minutes. Then, n-BuLi/n-hexane (2.5 M, 1.1 eq) was slowly injected thereto. After stirring for about 1 hour, 10-phenylacridin-9(1 OH)-one (1 eq) dissolved in tetrahydrofuran was slowly injected. After stirring for about 2 hours, the resultant was quenched with an ammonium chloride solution. The resultant was washed with ethyl acetate and water three times, and an organic layer obtained was dried over MgSO₄ and dried under a reduced pressure. The reaction product was purified by column chromatography utilizing dichloromethane and n-hexane as an eluent and recrystallized to obtain Intermediate D-1 (yield: 59%).

### Synthesis of Intermediate D

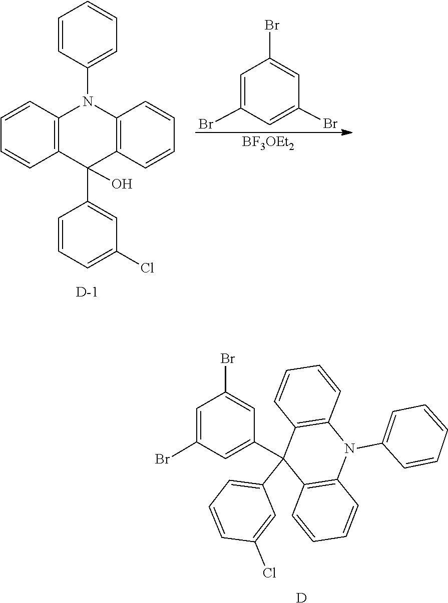

Intermediate D-1 (1 eq), 1,3, 5-tribromobenzene (20 eq), and boron trifluoride diethyl etherate (0.2 eq) were put in a high-pressure reactor and stirred. The resultant was washed with ethyl acetate and water three times, and an organic layer obtained was dried over MgSO₄ and dried under a reduced pressure. The reaction product thus obtained was purified by column chromatography utilizing dichloromethane and n-hexane as an eluent and recrystallized to obtain Intermediate D (yield: 53%).

### (5) Synthesis of Compound 1

Fused Polycyclic Compound 1 according to one or more embodiments may be synthesized by, for example, the reactions below.

### Synthesis of Intermediate 1-1

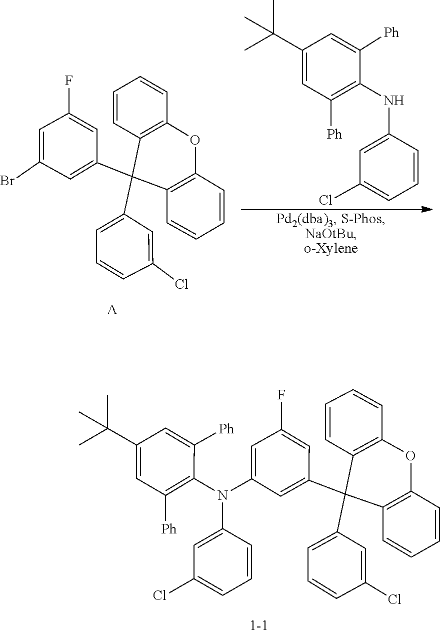

Intermediate A (1 eq), 5′-(tert-butyl)-N-(3-chlorophenyl)-[1,1′:3′,1″-terphenyl]-2′-amine (1 eq), tris(dibenzylideneacetone)dipalladium(0) (0.05 eq), 2-dicyclohexylphosphino-2′,6′-dimethoxybiphenyl (S-Phos), (0.10 eq), and sodium tert-butoxide (1.5 eq) were dissolved in o-xylene and stirred under a nitrogen atmosphere at about 150 degrees centigrade for about 20 hours in a high-pressure reactor. After cooling, the resultant was dried under a reduced pressure to remove o-xylene. Then, the resultant was washed with ethyl acetate and water three times, an organic layer obtained was dried over MgSO₄ and dried under a reduced pressure. The reaction product thus obtained was purified by column chromatography utilizing dichloromethane and n-hexane as an eluent and recrystallized to obtain Intermediate 1-1 (yield: 54%).

### Synthesis of Intermediate 1-2

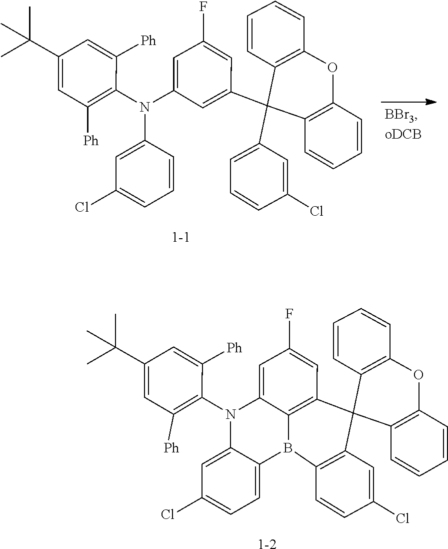

Intermediate 1-1 (1 eq) was dissolved in o-dichlorobenzene in a flask, and then, the flask was cooled to about 0 degrees centigrade under a nitrogen atmosphere, and BBr₃ (2.5 eq) dissolved in o-dichlorobenzene was slowly injected thereto. After finishing dropwise addition, the temperature was raised to about 160 degrees centigrade and stirring was performed for about 24 hours. After cooling to about 0 degrees centigrade, triethylamine was slowly added dropwise to the flask until the exothermic reaction stopped to finish the reaction. n-Hexane and methanol were added to precipitate, and a solid component was filtered. The solid content thus obtained was purified by silica filtration, and then purified by recrystallization utilizing dichloromethane and n-hexane as a solvent to obtain Intermediate 1-2. Final purification was performed by column chromatography utilizing dichloromethane and n-hexane as an eluent (yield: 8%).

### Synthesis of Intermediate 1-3

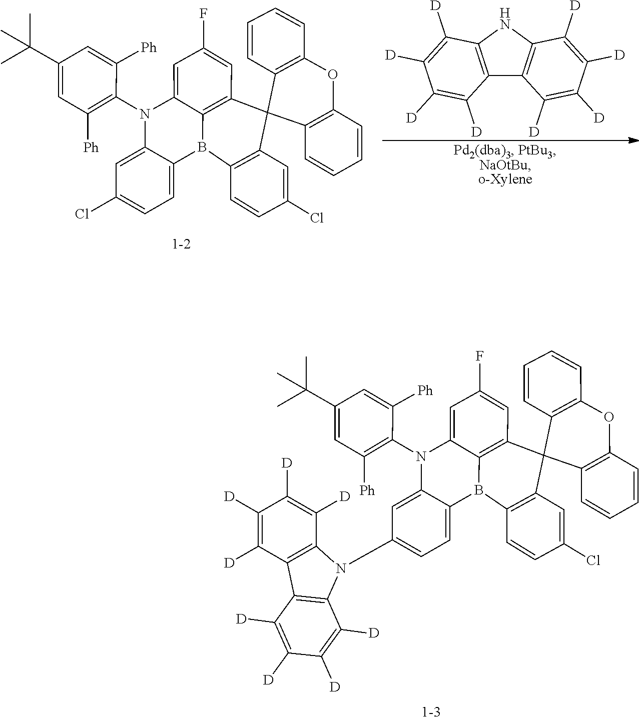

Intermediate 1-2 (1 eq), 9H-carbazole-1,2,3,4,5,6,7,8-d₈ (1 eq), tris(dibenzylideneacetone)dipalladium(0) (0.05 eq), tri-tert-butylphosphine (0.10 eq), and sodium tert-butoxide (1.5 eq) were dissolved in o-xylene and stirred under a nitrogen atmosphere at about 150 degrees centigrade for about 20 hours. After cooling, the resultant was dried under a reduced pressure to remove o-xylene. Then, the resultant was washed with ethyl acetate and water three times, and an organic layer obtained was dried over MgSO₄ and dried under a reduced pressure. The reaction product thus obtained was purified by column chromatography utilizing dichloromethane and n-hexane as an eluent and recrystallized to obtain Intermediate 1-3 (yield: 29%).

### Synthesis of Intermediate 1-4

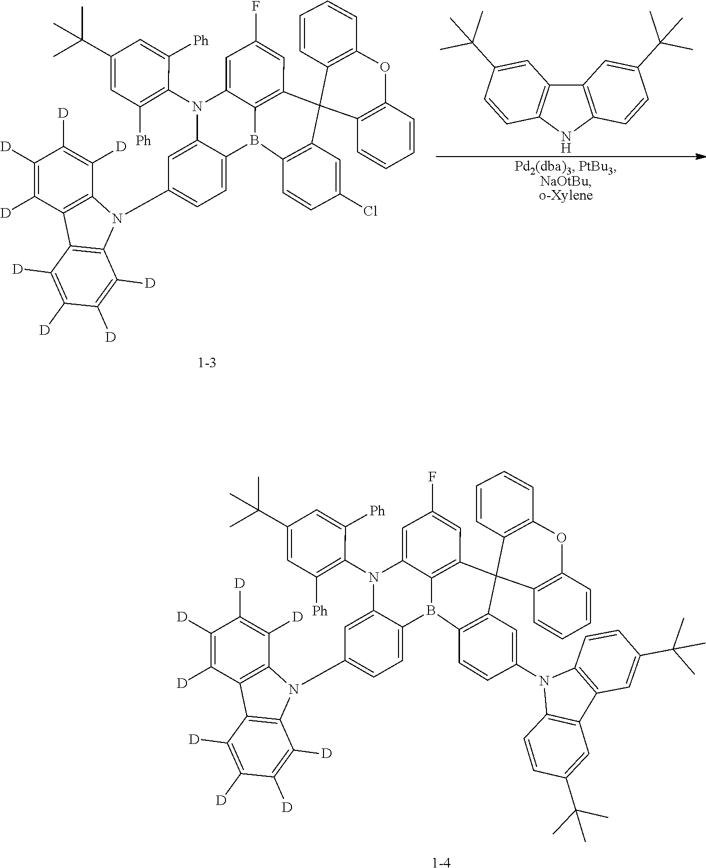

Intermediate 1-3 (1 eq), 3,6-di-tert-butyl-9H-carbazole (1 eq), tris(dibenzylideneacetone)dipalladium(0) (0.05 eq), tri-tert-butylphosphine (0.10 eq), and sodium tert-butoxide (1.5 eq) were dissolved in o-xylene and stirred under a nitrogen atmosphere at about 150 degrees centigrade for about 10 hours. After cooling, the resultant was dried under a reduced pressure to remove o-xylene. Then, the resultant was washed with ethyl acetate and water three times, and an organic layer obtained was dried over MgSO₄ and dried under a reduced pressure. The reaction product thus obtained was purified by column chromatography utilizing dichloromethane and n-hexane as an eluent and recrystallized to obtain Intermediate 1-4 (yield: 67%).

### Synthesis of Compound 1

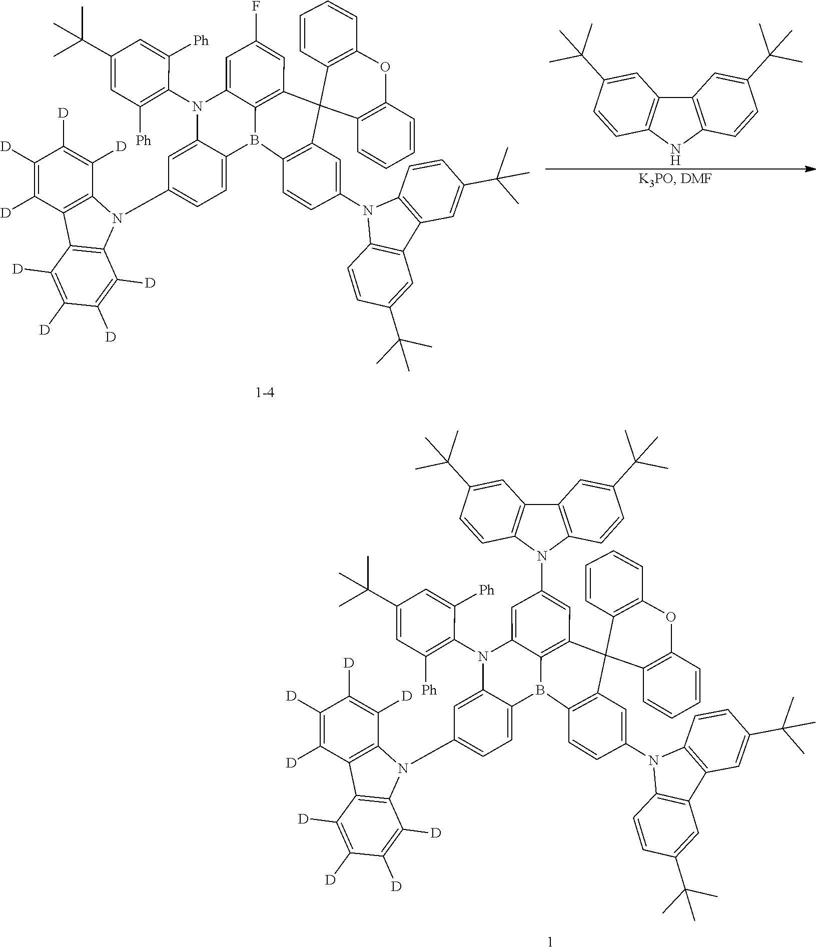

Intermediate 1-4 (1 eq), 3,6-di-tert-butyl-9H-carbazole (1.2 eq), and potassium phosphate (3 eq) were dissolved in dimethylformamide and stirred at about 150 degrees centigrade for about 24 hours. After cooling, the resultant was dried under a reduced pressure to remove dimethylformamide. Then, the resultant was washed with ethyl acetate and water three times, and an organic layer obtained was dried over MgSO₄ and dried under a reduced pressure. The reaction product thus obtained was purified by column chromatography utilizing dichloromethane and n-hexane as an eluent and recrystallized to obtain Compound 1 (yield: 53%).

After that, a final purification was performed by sublimation purification. The compound obtained was identified as Compound 1 through ESI-LCMS (ESI-LCMS: [M]+: C₁₀₅D₈H₈₅BN₄O. 1446.1).

### (6) Synthesis of Compound 44

Fused Polycyclic Compound 44 according to one or more embodiments may be synthesized by, for example, the reactions below.

### Synthesis of Intermediate 44-1

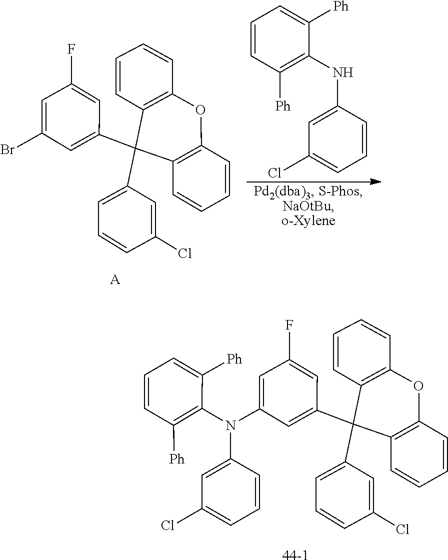

Intermediate A (1 eq), N-(3-chlorophenyl)-[1,1′:3′,1″-terphenyl]-2′-amine (1 eq), tris(dibenzylideneacetone)dipalladium(0) (0.05 eq), 2-dicyclohexylphosphino-2′,6′-dimethoxybiphenyl (S-Phos), (0.10 eq), sodium tert-butoxide (1.5 eq) were dissolved in o-xylene and stirred under a nitrogen atmosphere at about 150 degrees for about 20 hours in a high-pressure reactor. After cooling, the resultant was dried under a reduced pressure to remove o-xylene. Then, the resultant was washed with ethyl acetate and water three times, and an organic layer obtained was dried over MgSO₄ and dried under a reduced pressure. The reaction product thus obtained was purified by column chromatography utilizing dichloromethane and n-hexane as an eluent and recrystallized to obtain Intermediate 44-1 (yield: 51%).

### Synthesis of Intermediate 44-2

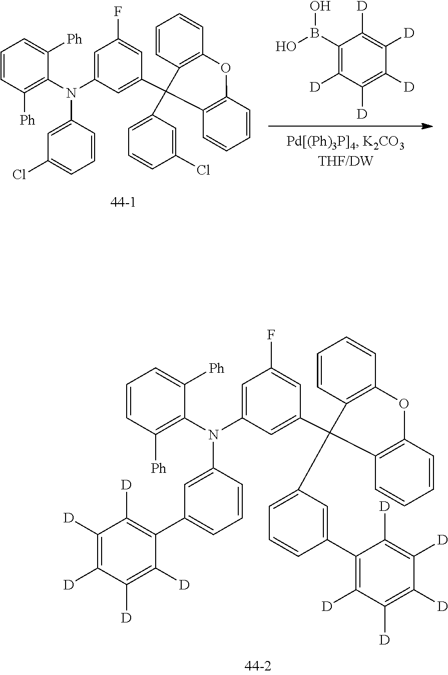 [SMILES: Fc1cc(N(c2cccc(Cl)c2)c2c(-c3ccccc3)cccc2-c2ccccc2)cc(C2(c3cccc(Cl)c3)c3ccccc3Oc3ccccc32)c1 ; [2H]c1c([2H])c([2H])c(B(O)O)c([2H])c1[2H] ; [2H]c1c([2H])c([2H])c(-c2cccc(N(c3cc(F)cc(C4(c5cccc(-c6c([2H])c([2H])c([2H])c([2H])c6[2H])c5)c5ccccc5Oc5ccccc54)c3)c3c(-c4ccccc4)cccc3-c3ccccc3)c2)c([2H])c1[2H]]

Intermediate 44-1 (1 eq), (phenyl-d5)boronic acid (3 eq), tetrakis(triphenylphosphine)palladium(0) (0.1 eq), and potassium carbonate (K₂CO₃, 4 eq) were dissolved in tetrahydrofuran: distilled water (a volume ratio of 3: 1), and refluxed for about 20 hours. After cooling, the resultant was washed with ethyl acetate and water three times, and an organic layer obtained was dried over MgSO₄ and dried under a reduced pressure. The reaction product thus obtained was purified by column chromatography utilizing dichloromethane and n-hexane as an eluent and recrystallized to obtain Intermediate 44-2 (yield: 57%).

### Synthesis of Intermediate 44-3

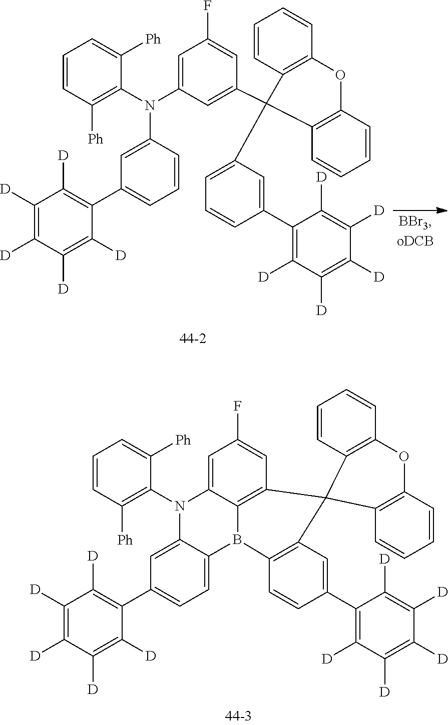 [SMILES: [2H]c1c([2H])c([2H])c(-c2cccc(N(c3cc(F)cc(C4(c5cccc(-c6c([2H])c([2H])c([2H])c([2H])c6[2H])c5)c5ccccc5Oc5ccccc54)c3)c3c(-c4ccccc4)cccc3-c3ccccc3)c2)c([2H])c1[2H] ; [2H]c1c([2H])c([2H])c(-c2ccc3c(c2)N(c2c(-c4ccccc4)cccc2-c2ccccc2)c2cc(F)cc4c2B3c2ccc(-c3c([2H])c([2H])c([2H])c([2H])c3[2H])cc2C42c3ccccc3Oc3ccccc32)c([2H])c1[2H]]

Intermediate 44-2 (1 eq) was dissolved in o-dichlorobenzene in a flask, and then, the flask was cooled to about 0 degrees centigrade under a nitrogen atmosphere, and BBr₃ (2.5 eq) dissolved in o-dichlorobenzene was slowly injected thereto. After finishing dropwise addition, the temperature was raised to about 160 degrees centigrade and stirring was performed for about 24 hours. After cooling to about 0 degrees centigrade, triethylamine was slowly added dropwise to the flask until the exothermic reaction stopped to finish the reaction. n-Hexane and methanol were added to precipitate, and a solid component was filtered. The solid content thus obtained was purified by silica filtration, and then purified by recrystallization utilizing dichloromethane and n-hexane as a solvent to obtain Intermediate 44-3. Final purification was performed by column chromatography utilizing dichloromethane and n-hexane as an eluent(yield: 7%).

### Synthesis of Compound 44

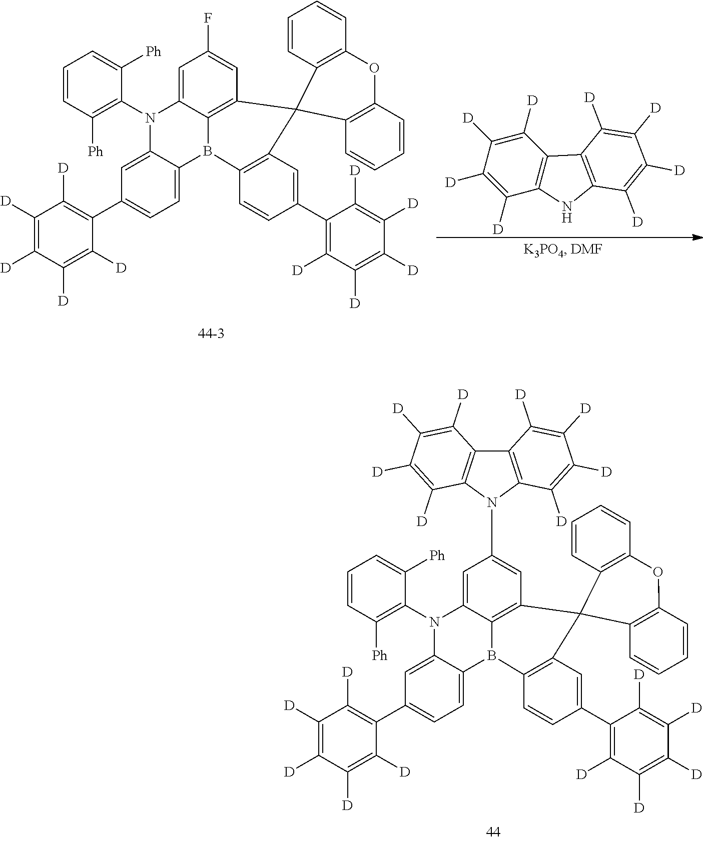

Intermediate 44-3 (1 eq), 9H-carbazole-1,2,3,4,5,6,7,8-d₈ (1.3 eq), and potassium phosphate (3 eq) were dissolved in dimethylformamide and stirred at about 150 degrees centigrade for about 24 hours. After cooling, the resultant was dried under a reduced pressure to remove dimethylformamide. Then, the resultant was washed with ethyl acetate and water three times, and an organic layer obtained was dried over MgSO₄ and dried under a reduced pressure. The reaction product thus obtained was purified by column chromatography utilizing dichloromethane and n-hexane as an eluent and recrystallized to obtain Compound 44 (yield: 53%).

After that, a final purification was performed by sublimation purification. The compound obtained was identified as Compound 44 through ESI-LCMS (ESI-LCMS: [M]+: C₇₃D₁₈H₂₉BN₂O. 997.5).

### (7) Synthesis of Compound 70

Fused Polycyclic Compound 70 according to one or more embodiments may be synthesized by, for example, the reactions below.

### Synthesis of Intermediate 70-1

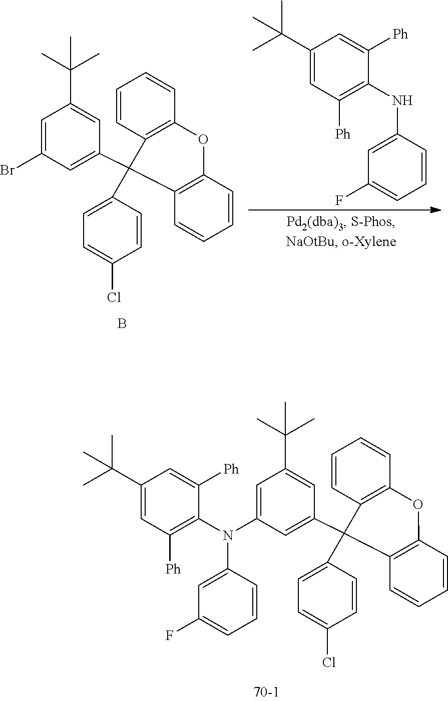

Intermediate B (1 eq), 5′-(tert-butyl)-N-(3-chlorophenyl)-[1,1′:3′,1″-terphenyl]-2′-amine (1 eq), tris(dibenzylideneacetone)dipalladium(0) (0.05 eq), 2-dicyclohexylphosphino-2′,6′-dimethoxybiphenyl (S-Phos), (0.10 eq), and sodium tert-butoxide (1.5 eq) were dissolved in o-xylene and stirred under a nitrogen atmosphere at about 150 degrees centigrade for about 20 hours in a high-pressure reactor. After cooling, the resultant was dried under a reduced pressure to remove o-xylene. Then, the resultant was washed with ethyl acetate and water three times, and an organic layer obtained was dried over MgSO₄ and dried under a reduced pressure. The reaction product thus obtained was purified by column chromatography utilizing dichloromethane and n-hexane as an eluent and recrystallized to obtain Intermediate 70-1 (yield: 53%).

### Synthesis of Intermediate 70-2

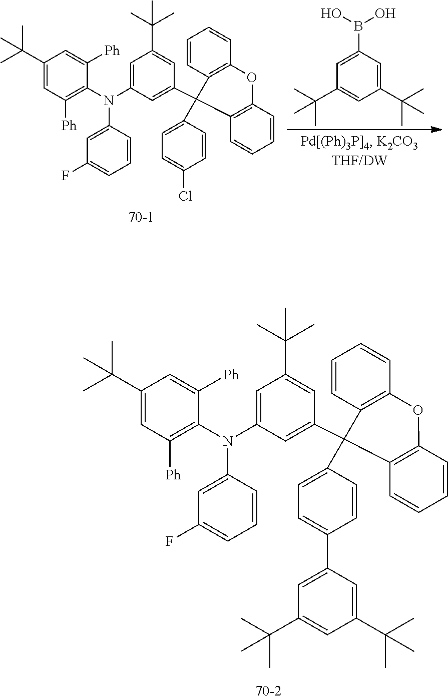

Intermediate 70-1 (1 eq), (3,5-di-tert-butylphenyl)boronic acid (1.3 eq), tetrakis(triphenylphosphine)palladium(0) (0.1 eq), and potassium carbonate (K₂CO₃, 3 eq) were dissolved in tetrahydrofuran: distilled water (a volume ratio of 3: 1), and refluxed for about 20 hours. Then, the resultant was washed with ethyl acetate and water three times, and an organic layer obtained was dried over MgSO₄ and dried under a reduced pressure. The reaction product thus obtained was purified by column chromatography utilizing dichloromethane and n-hexane as an eluent and recrystallized to obtain Intermediate 70-2 (yield: 61%).

### Synthesis of Intermediate 70-3

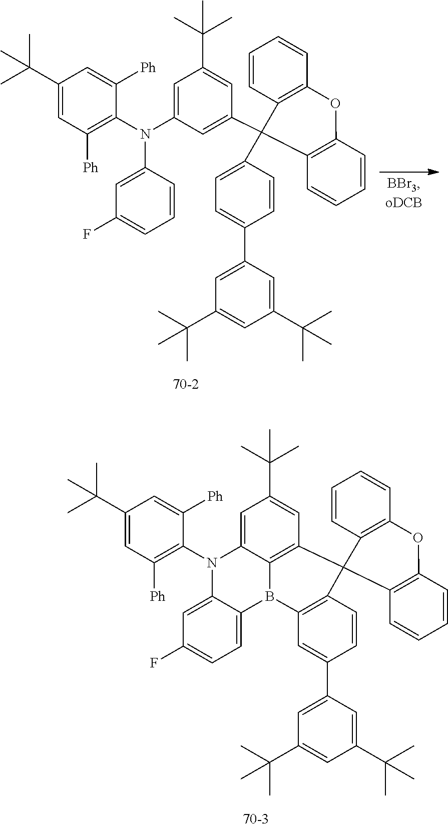 [SMILES: CC(C)(C)c1cc(-c2ccc(C3(c4cc(N(c5cccc(F)c5)c5c(-c6ccccc6)cc(C(C)(C)C)cc5-c5ccccc5)cc(C(C)(C)C)c4)c4ccccc4Oc4ccccc43)cc2)cc(C(C)(C)C)c1 ; CC(C)(C)c1cc(-c2ccc3c(c2)B2c4ccc(F)cc4N(c4c(-c5ccccc5)cc(C(C)(C)C)cc4-c4ccccc4)c4cc(C(C)(C)C)cc(c42)C32c3ccccc3Oc3ccccc32)cc(C(C)(C)C)c1]

Intermediate 70-2 (1 eq) was dissolved in o-dichlorobenzene in a flask, and then, the flask was cooled to about 0 degrees centigrade under a nitrogen atmosphere, and BBr₃ (2.5 eq) dissolved in o-dichlorobenzene was slowly injected thereto. After finishing dropwise addition, the temperature was raised to about 160 degrees centigrade and stirring was performed for about 24 hours. After cooling to about 0 degrees centigrade, triethylamine was slowly added dropwise to the flask until the exothermic reaction stopped to finish the reaction. n-Hexane and methanol were added to precipitate, and a solid component was filtered. The solid content thus obtained was purified by silica filtration, and then purified by recrystallization utilizing dichloromethane and n-hexane as a solvent to obtain Intermediate 70-3. Final purification was performed by column chromatography utilizing dichloromethane and n-hexane as an eluent (yield: 10%).

### Synthesis of Compound 70

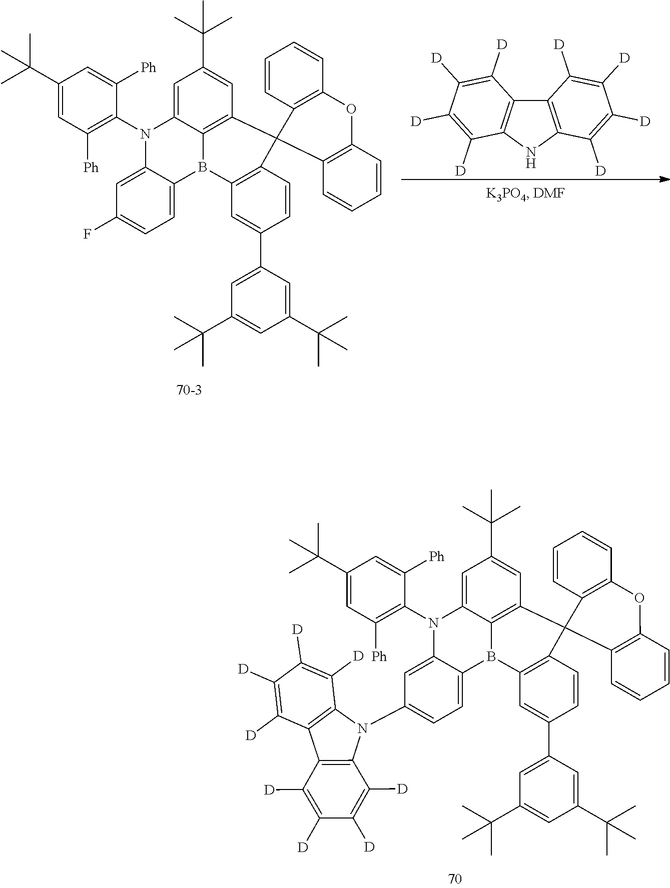 [SMILES: CC(C)(C)c1cc(-c2ccc3c(c2)B2c4ccc(F)cc4N(c4c(-c5ccccc5)cc(C(C)(C)C)cc4-c4ccccc4)c4cc(C(C)(C)C)cc(c42)C32c3ccccc3Oc3ccccc32)cc(C(C)(C)C)c1 ; [2H]c1c([2H])c([2H])c2c([nH]c3c([2H])c([2H])c([2H])c([2H])c32)c1[2H] ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1cc(-c2cc(C(C)(C)C)cc(C(C)(C)C)c2)ccc1C31c2ccccc2Oc2ccccc21]

Intermediate 70-3 (1 eq), 9H-carbazole-1,2,3,4,5,6,7,8-d₈ (1.3 eq), and potassium phosphate (3 eq) were dissolved in dimethylformamide and stirred at about 150 degrees centigrade for about 24 hours. After cooling, the resultant was dried under a reduced pressure to remove dimethylformamide. Then, the resultant was washed with ethyl acetate and water three times, and an organic layer obtained was dried over MgSO₄ and dried under a reduced pressure. The reaction product thus obtained was purified by column chromatography utilizing dichloromethane and n-hexane as an eluent and recrystallized to obtain Compound 70 (yield: 53%).

After that, a final purification was performed by sublimation purification. The compound obtained was identified as Compound 70 through ESI-LCMS (ESI-LCMS: [M]+: C₈₃D₈H₆₇BN₂O. 1135.9).

### (8) Synthesis of Compound 116

Fused Polycyclic Compound 116 according to one or more embodiments may be synthesized by, for example, the reactions below.

### Synthesis of Intermediate 116-1

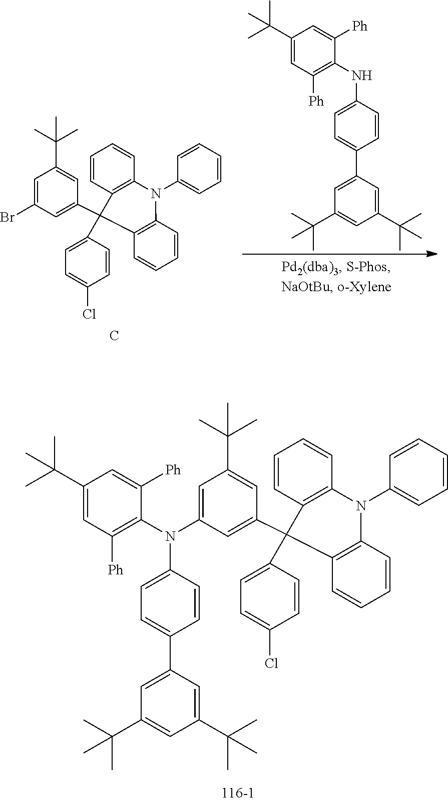

Intermediate C (1 eq), 5′-(tert-butyl)-N-(3′,5′-di-tert-butyl-[1,1′-biphenyl]-4-yl)-[1,1′:3′,1″-terphenyl]-2′-amine (1 eq), tris(dibenzylideneacetone)dipalladium(0) (0.05 eq), 2-dicyclohexylphosphino-2′,6′-dimethoxybiphenyl (S-Phos), (0.10 eq), and sodium tert-butoxide (1.5 eq) were dissolved in o-xylene and stirred under a nitrogen atmosphere at about 150 degrees for about 20 hours in a high-pressure reactor. After cooling, the resultant was dried under a reduced pressure to remove o-xylene. Then, the resultant was washed with ethyl acetate and water three times, and an organic layer obtained was dried over MgSO₄ and dried under a reduced pressure. The reaction product thus obtained was purified by column chromatography utilizing dichloromethane and n-hexane as an eluent and recrystallized to obtain Intermediate 116-1 (yield: 57%).

### Synthesis of Intermediate 116-2

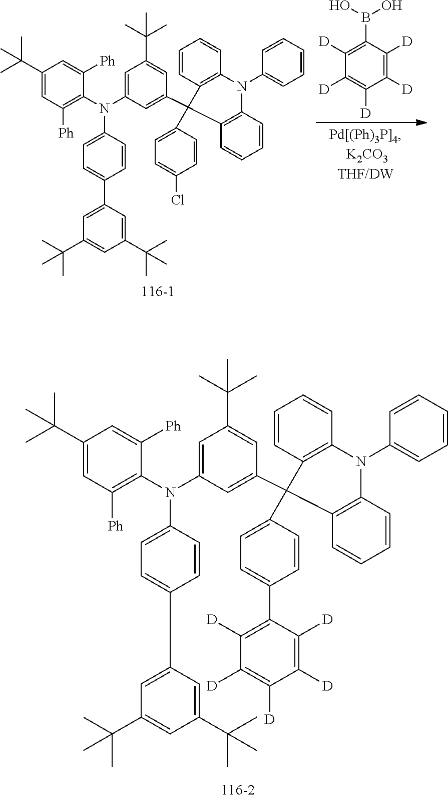

Intermediate 116-1 (1 eq), (phenyl-d5)boronic acid (1.3 eq), tetrakis(triphenylphosphine)palladium(0) (0.1 eq), and potassium carbonate (K₂CO₃, 3 eq) were dissolved in tetrahydrofuran: distilled water (a volume ratio of 3: 1), and refluxed for about 20 hours. After cooling, the resultant was washed with ethyl acetate and water three times, and an organic layer obtained was dried over MgSO₄ and dried under a reduced pressure. The reaction product thus obtained was purified by column chromatography utilizing dichloromethane and n-hexane as an eluent and recrystallized to obtain Intermediate 116-2 (yield: 66%).

### Synthesis of Compound 116

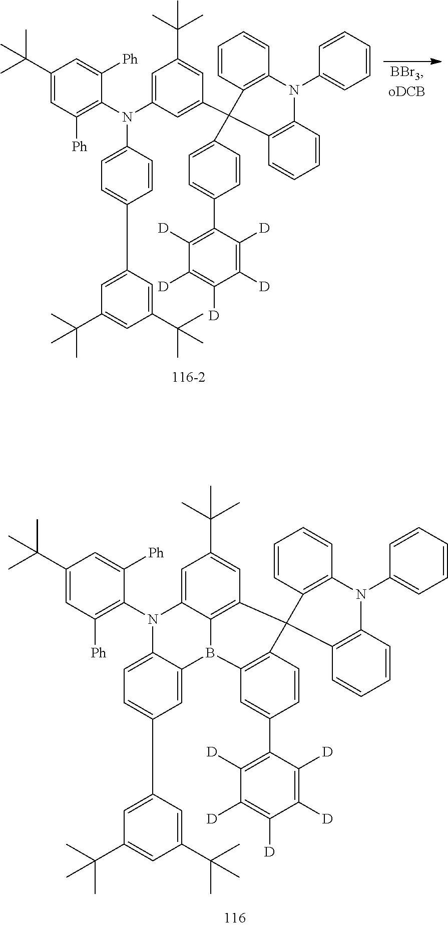 [SMILES: [2H]c1c([2H])c([2H])c(-c2ccc(C3(c4cc(N(c5ccc(-c6cc(C(C)(C)C)cc(C(C)(C)C)c6)cc5)c5c(-c6ccccc6)cc(C(C)(C)C)cc5-c5ccccc5)cc(C(C)(C)C)c4)c4ccccc4N(c4ccccc4)c4ccccc43)cc2)c([2H])c1[2H] ; [2H]c1c([2H])c([2H])c(-c2ccc3c(c2)B2c4cc(-c5cc(C(C)(C)C)cc(C(C)(C)C)c5)ccc4N(c4c(-c5ccccc5)cc(C(C)(C)C)cc4-c4ccccc4)c4cc(C(C)(C)C)cc(c42)C32c3ccccc3N(c3ccccc3)c3ccccc32)c([2H])c1[2H]]

Intermediate 116-2 (1 eq) was dissolved in o-dichlorobenzene in a flask, and then, the flask was cooled to about 0 degrees centigrade under a nitrogen atmosphere, and BBr₃ (2.5 eq) dissolved in o-dichlorobenzene was slowly injected thereto. After finishing dropwise addition, the temperature was raised to about 160 degrees centigrade and stirring was performed for about 24 hours. After cooling to about 0 degrees centigrade, triethylamine was slowly added dropwise to the flask until the exothermic reaction stopped to finish the reaction. n-Hexane and methanol were added to precipitate, and a solid component was filtered. The solid content thus obtained was purified by silica filtration, and then purified by recrystallization utilizing dichloromethane and n-hexane as a solvent to obtain Compound 116. Final purification was performed by column chromatography utilizing dichloromethane and n-hexane as an eluent (yield: 9%).

After that, a final purification was performed by sublimation purification. The compound obtained was identified as Compound 116 through ESI-LCMS (ESI-LCMS: [M]+: C₈₃D₅H₇₂BN₂. 1118.9).

### (9) Synthesis of Compound 135

Fused Polycyclic Compound 135 according to one or more embodiments may be synthesized by, for example, the reactions below.

### Synthesis of Intermediate 135-1

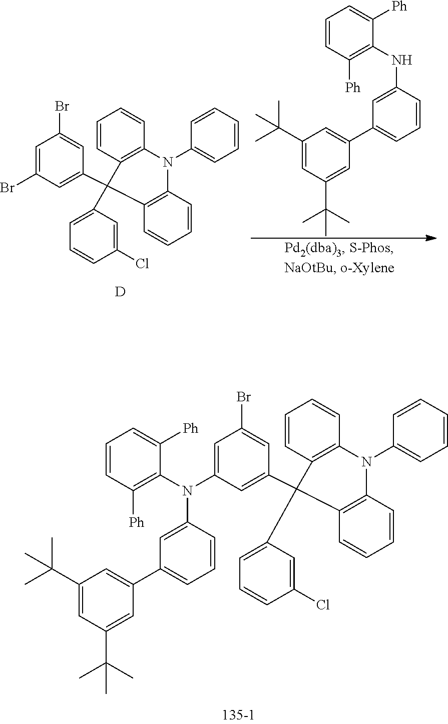

Intermediate D (1 eq), N-(3′,5′-di-tert-butyl-[1,1′-biphenyl]-3-yl)-[1,1′:3′,1″-terphenyl]-2′-amine (1 eq), tris(dibenzylideneacetone)dipalladium(0) (0.05 eq), 2-dicyclohexylphosphino-2′,6′-dimethoxybiphenyl (S-Phos), (0.10 eq), and sodium tert-butoxide (1.5 eq) were dissolved in o-xylene and stirred under a nitrogen atmosphere at about 150 degrees centigrade for about 20 hours in a high-pressure reactor. After cooling, the resultant was dried under a reduced pressure to remove o-xylene. Then, the resultant was washed with ethyl acetate and water three times, an organic layer obtained was dried over MgSO₄ and dried under a reduced pressure. The reaction product thus obtained was purified by column chromatography utilizing dichloromethane and n-hexane as an eluent and recrystallized to obtain Intermediate 135-1 (yield: 61%).

### Synthesis of Intermediate 135-2

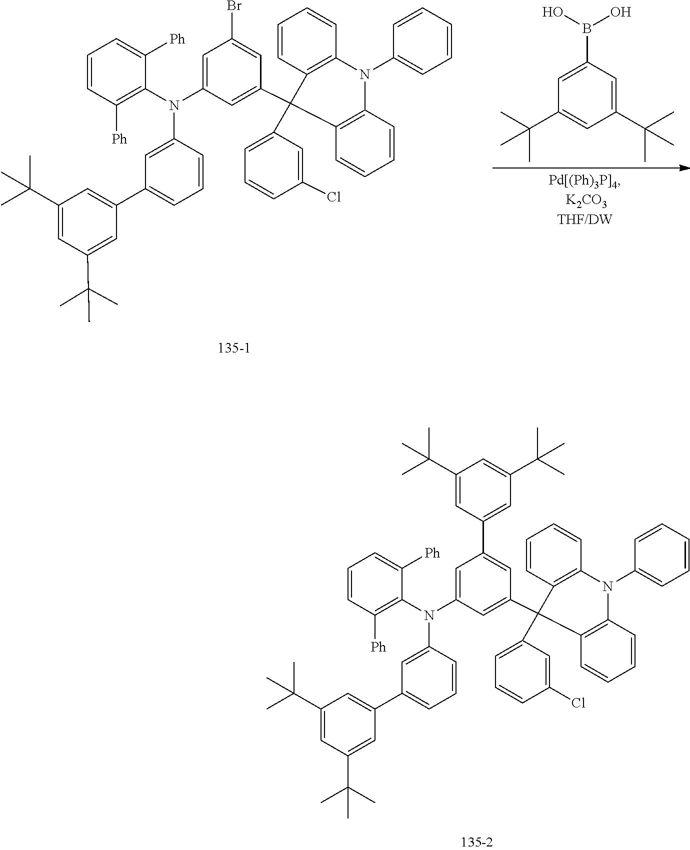 [SMILES: CC(C)(C)c1cc(-c2cccc(N(c3cc(Br)cc(C4(c5cccc(Cl)c5)c5ccccc5N(c5ccccc5)c5ccccc54)c3)c3c(-c4ccccc4)cccc3-c3ccccc3)c2)cc(C(C)(C)C)c1 ; CC(C)(C)c1cc(B(O)O)cc(C(C)(C)C)c1 ; CC(C)(C)c1cc(-c2cccc(N(c3cc(-c4cc(C(C)(C)C)cc(C(C)(C)C)c4)cc(C4(c5cccc(Cl)c5)c5ccccc5N(c5ccccc5)c5ccccc54)c3)c3c(-c4ccccc4)cccc3-c3ccccc3)c2)cc(C(C)(C)C)c1]

Intermediate 135-1 (1 eq), (3,5-di-tert-butylphenyl)boronic acid (1 eq), tetrakis(triphenylphosphine)palladium(0) (0.1 eq), and potassium carbonate (K₂CO₃, 3 eq) were dissolved in tetrahydrofuran: distilled water (a volume ratio of 3: 1), and refluxed for about 20 hours. After cooling, the resultant was washed with ethyl acetate and water three times, and an organic layer obtained was dried over MgSO₄ and dried under a reduced pressure. The reaction product thus obtained was purified by column chromatography utilizing dichloromethane and n-hexane as an eluent and recrystallized to obtain Intermediate 135-2 (yield: 59%).

### Synthesis of Intermediate 135-3

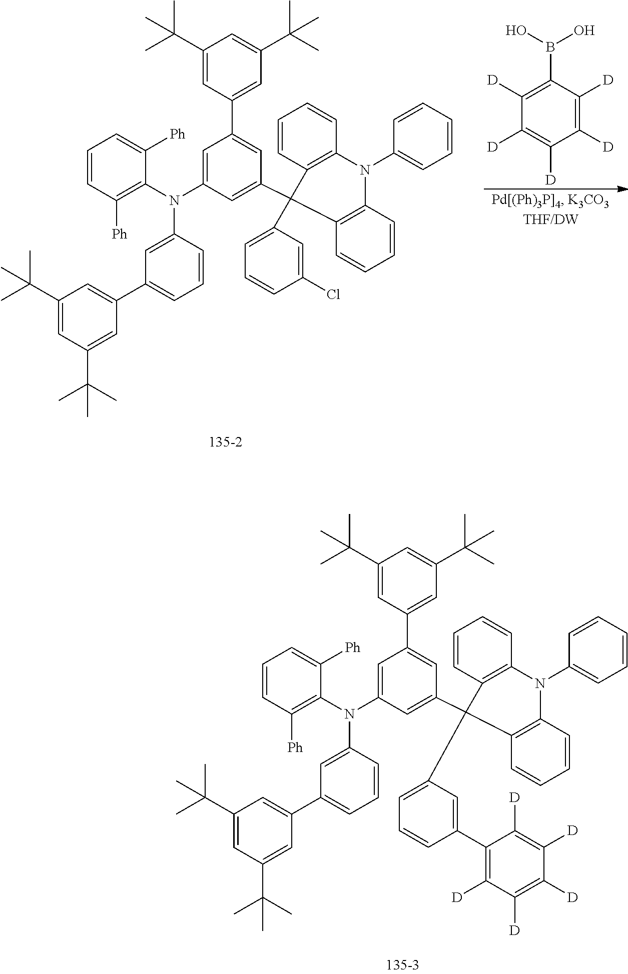

Intermediate 135-2 (1 eq), (phenyl-d5)boronic acid (1 eq), tetrakis(triphenylphosphine)palladium(0) (0.1 eq), and potassium carbonate (K₂CO₃, 3 eq) were dissolved in tetrahydrofuran: distilled water (a volume ratio of 3: 1), and refluxed for about 20 hours. After cooling, the resultant was washed with ethyl acetate and water three times, and an organic layer obtained was dried over MgSO₄ and dried under a reduced pressure. The reaction product thus obtained was purified by column chromatography utilizing dichloromethane and n-hexane as an eluent and recrystallized to obtain Intermediate 135-3 (yield: 60%).

### Synthesis of Compound 135

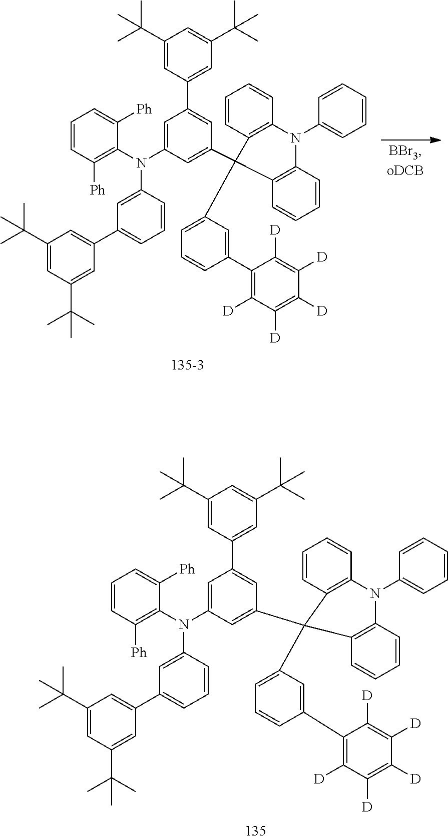 [SMILES: [2H]c1c([2H])c([2H])c(-c2cccc(C3(c4cc(-c5cc(C(C)(C)C)cc(C(C)(C)C)c5)cc(N(c5cccc(-c6cc(C(C)(C)C)cc(C(C)(C)C)c6)c5)c5c(-c6ccccc6)cccc5-c5ccccc5)c4)c4ccccc4N(c4ccccc4)c4ccccc43)c2)c([2H])c1[2H] ; [2H]c1c([2H])c([2H])c(-c2cccc(C3(c4cc(-c5cc(C(C)(C)C)cc(C(C)(C)C)c5)cc(N(c5cccc(-c6cc(C(C)(C)C)cc(C(C)(C)C)c6)c5)c5c(-c6ccccc6)cccc5-c5ccccc5)c4)c4ccccc4N(c4ccccc4)c4ccccc43)c2)c([2H])c1[2H]]

Intermediate 135-3 (1 eq) was dissolved in o-dichlorobenzene in a flask, and then, the flask was cooled to about 0 degrees centigrade under a nitrogen atmosphere, and BBr₃ (2.5 eq) dissolved in o-dichlorobenzene was slowly injected thereto. After finishing dropwise addition, the temperature was raised to about 160 degrees centigrade and stirring was performed for about 24 hours. After cooling to about 0 degrees centigrade, triethylamine was slowly added dropwise to the flask until the exothermic reaction stopped to finish the reaction. n-Hexane and methanol were added to precipitate, and a solid component was filtered. The solid content thus obtained was purified by silica filtration, and then purified by recrystallization utilizing dichloromethane and n-hexane as a solvent to obtain Compound 135. Final purification was performed by column chromatography utilizing dichloromethane and n-hexane as an eluent (yield: 8%).

After that, a final purification was performed by sublimation purification. The compound obtained was identified as Compound 135 through ESI-LCMS (ESI-LCMS: [M]+: C₈₉D₅H₇₆BN₂. 1194.8).

2. Manufacture and Evaluation of Light Emitting Device

(1) Manufacture of Light Emitting Device

A light emitting device of one or more embodiments, including the fused polycyclic compound of one or more embodiments in an emission layer of the light emitting device was manufactured by a method described herein. Light emitting devices of Example 1 to Example 10 were manufactured utilizing Example Compounds 1, 44, 70, 116, and 135 as dopant materials of an emission layer of corresponding light emitting devices. Comparative Example 1 to Comparative Example 10 correspond to light emitting devices manufactured utilizing Comparative Compound C1 to Comparative Compound C5 as dopant materials of an emission layer of corresponding light emitting devices.

Example Compounds

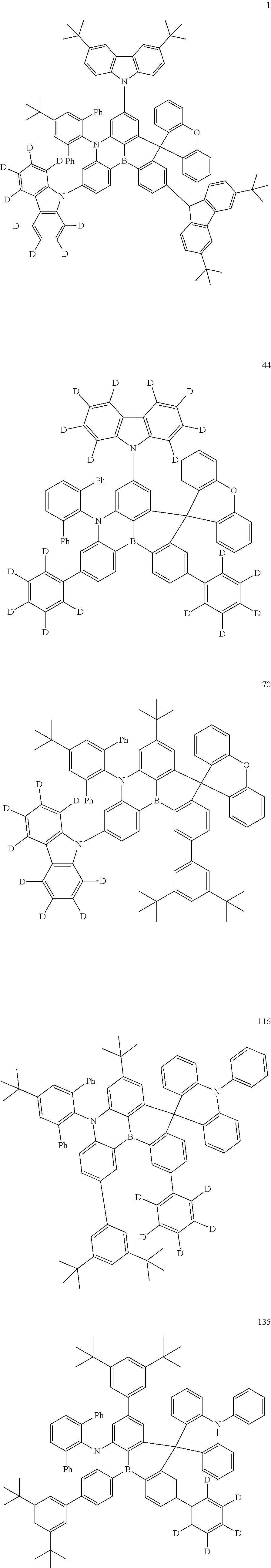

Comparative Compounds

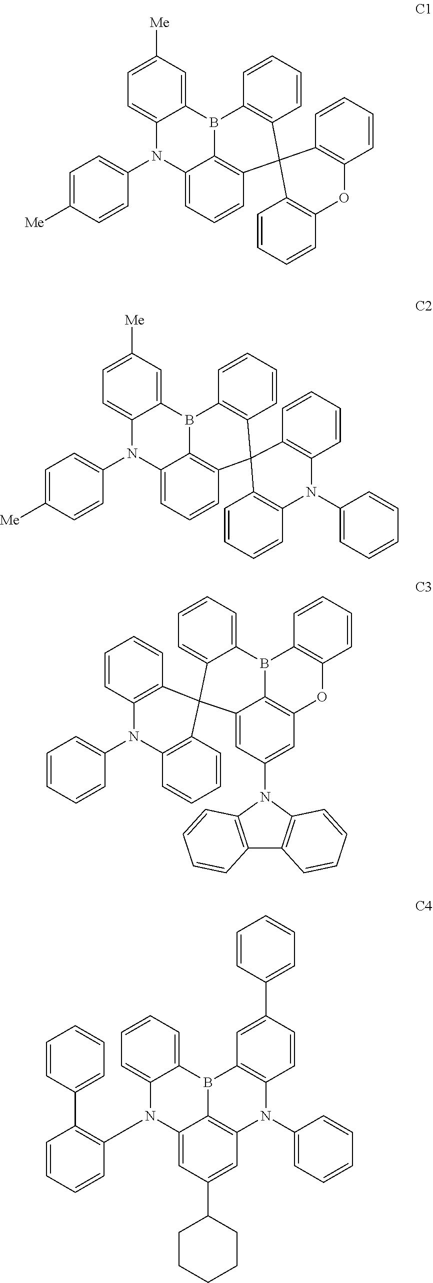 [SMILES: Cc1ccc(N2c3ccc(C)cc3B3c4ccccc4C4(c5ccccc5Oc5ccccc54)c4cccc2c43)cc1 ; Cc1ccc(N2c3ccc(C)cc3B3c4ccccc4C4(c5ccccc5N(c5ccccc5)c5ccccc54)c4cccc2c43)cc1 ; c1ccc(N2c3ccccc3C3(c4ccccc4B4c5ccccc5Oc5cc(-n6c7ccccc7c7ccccc76)cc3c54)c3ccccc32)cc1 ; c1ccc(-c2ccc3c(c2)B2c4ccccc4N(c4ccccc4-c4ccccc4)c4cc(C5CCCCC5)cc(c42)N3c2ccccc2)cc1]

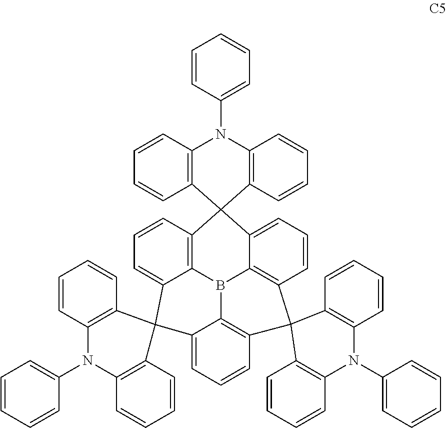 [SMILES: c1ccc(N2c3ccccc3C3(c4ccccc42)c2cccc4c2B2c5c3cccc5C3(c5ccccc5N(c5ccccc5)c5ccccc53)c3cccc(c32)C42c3ccccc3N(c3ccccc3)c3ccccc32)cc1]

Manufacture of Light Emitting Device

A glass substrate (product of Corning Co.) on which an ITO electrode with 15 Ω/cm² (1200 Å) was formed as an anode, was cut into a size of about 50 mm×50 mm×0.7 mm, washed by ultrasonic waves utilizing isopropyl alcohol and pure water for about 5 minutes each, and cleansed by irradiating ultraviolet rays for about 30 minutes and then, ozone. After that, the ITO glass substrate was installed in a vacuum deposition apparatus.

On the anode, a hole injection layer with a thickness of about 300 Å was formed by depositing NPD, and on the hole injection layer, a hole transport layer with a thickness of about 200 Å was formed by depositing H-1-1. On the hole transport layer, an emission auxiliary layer with a thickness of about 100 Å was formed by depositing CzSi.

Then, a host mixture of a second compound and a third compound in a ratio (e.g., weight ratio) of 1:1, a fourth compound, and the Example Compound or Comparative Compound were co-deposited in a weight ratio of about 85: 14: 1 to form an emission layer EML with a thickness of about 200 Å. On the emission layer, a hole blocking layer with a thickness of about 200 Å was formed by depositing TSPO1. Then, on the hole blocking layer, an electron transport layer with a thickness of about 300 Å was formed by depositing TPBI, and on the electron transport layer, an electron injection layer with a thickness of about 10 Å was formed by depositing LiF. Then, on the electron injection layer, Al was deposited to form a cathode with a thickness of about 3000 Å, and P4 was deposited to form a capping layer with a thickness of about 700 Å on the cathode to manufacture a light emitting device.

All layers were formed by a vacuum deposition method. Meanwhile, the second compound utilized HT2 and HT3 selected from among the compounds in Compound Group 2, the third compound utilized ETH66 and ETH86 selected from among the compounds in Compound Group 3, and the fourth compound utilized AD-37 and AD-38 selected from among the compounds in Compound Group 4.

The compounds utilized for the manufacture of the light emitting devices of the Examples and Comparative Examples are shown below. The materials were utilized after purchasing commercial products and performing sublimation purification.

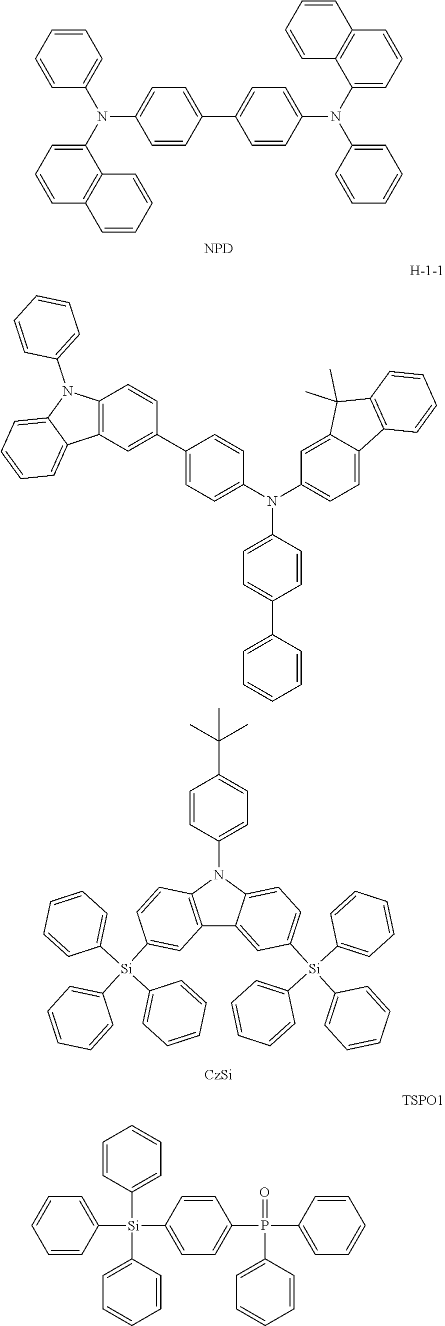

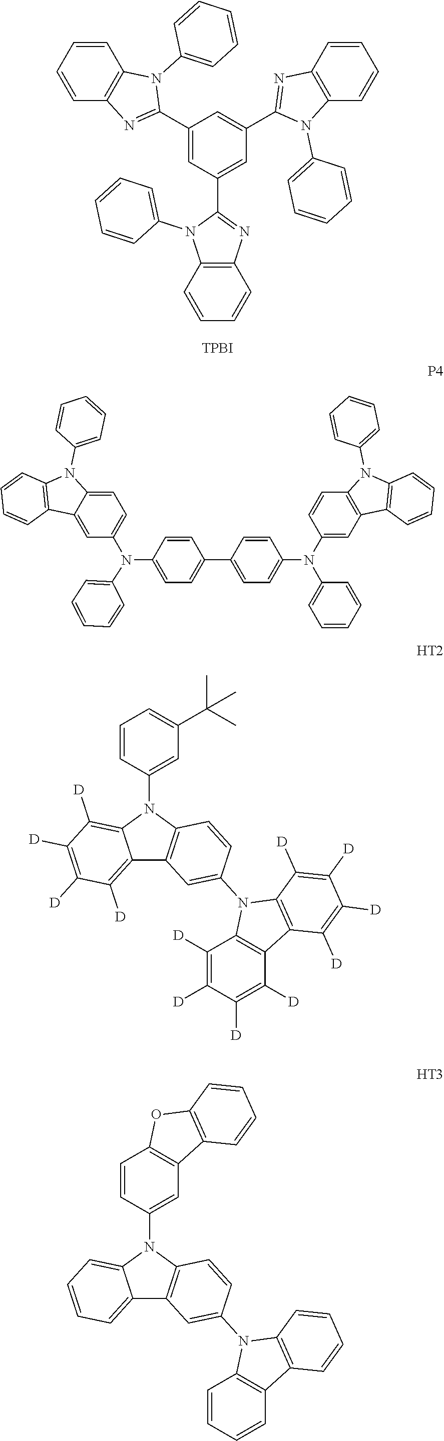

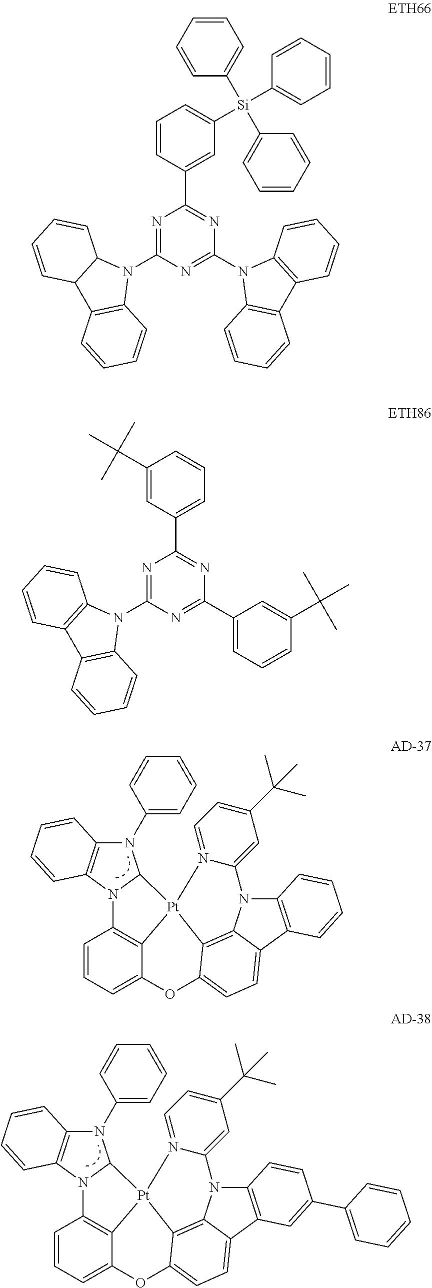

3. Evaluation of Properties of Light Emitting Devices

The device efficiency and device lifetime of each of the light emitting devices manufactured utilizing Example Compounds 1, 44, 70, 116, and 135, and Comparative Compounds C1 to C5 were evaluated. In Table 1, the evaluation results on the light emitting devices of Examples 1 to 10 and Comparative Examples 1 to 10 are shown. In order to evaluate the properties of the light emitting devices manufactured in Examples 1 to 10 and Comparative Examples 1 to 10, a driving voltage (V) at a current density of about 1000 cd/m², emission efficiency (cd/A), and emission wavelength were measured utilizing Keithley SMU 236 and a luminance meter PR650. The time consumed to reach about 95% luminance relative to an initial luminance was measured as the lifetime (T95), a relative lifetime (e.g., lifetime ratio) was calculated based on the device of Comparative Example 1, and the results are shown in Table 1.

TABLE 1

| | Host (second | | | Driving | | | Lifetime |
|---|---|---|---|---|---|---|---|
| | compound:third | Fourth | First | voltage | Efficiency | Emission | ratio |
| | compound = 5:5) | compound | compound | (V) | (cd/A) | color | (T95) |
| Example | HT2/ETH66 | AD-37 | Compound | 4.3 | 26.8 | Blue | 340 |
| 1 | | | 1 | | | | |
| Example | HT2/ETH66 | AD-37 | Compound | 4.6 | 26.3 | Blue | 360 |
| 2 | | | 44 | | | | |
| Example | HT2/ETH66 | AD-37 | Compound | 4.4 | 25.6 | Blue | 380 |
| 3 | | | 70 | | | | |
| Example | HT2/ETH66 | AD-37 | Compound | 4.6 | 24.4 | Blue | 320 |
| 4 | | | 116 | | | | |
| Example | HT2/ETH66 | AD-37 | Compound | 4.5 | 25.9 | Blue | 370 |
| 5 | | | 135 | | | | |
| Example | HT3/ETH86 | AD-38 | Compound | 4.4 | 26.5 | Blue | 310 |
| 6 | | | 1 | | | | |
| Example | HT3/ETH86 | AD-38 | Compound | 4.5 | 25.6 | Blue | 335 |
| 7 | | | 44 | | | | |
| Example | HT3/ETH86 | AD-38 | Compound | 4.6 | 24.7 | Blue | 365 |
| 8 | | | 70 | | | | |
| Example | HT3/ETH86 | AD-38 | Compound | 4.5 | 23.8 | Blue | 305 |
| 9 | | | 116 | | | | |
| Example | HT3/ETH86 | AD-38 | Compound | 4.6 | 25.4 | Blue | 355 |
| 10 | | | 135 | | | | |
| Comparative | HT2/ETH66 | AD-37 | Comparative | 5.0 | 20.3 | Blue | 100 |
| Example 1 | | | Compound | | | | |
| | | | C1 | | | | |
| Comparative | HT2/ETH66 | AD-37 | Comparative | 4.9 | 21.6 | Blue | 110 |
| Example 2 | | | Compound | | | | |
| | | | C2 | | | | |
| Comparative | HT2/ETH66 | AD-37 | Comparative | 5.1 | 19.5 | Blue | 80 |
| Example 3 | | | Compound | | | | |
| | | | C3 | | | | |
| Comparative | HT2/ETH66 | AD-37 | Comparative | 4.8 | 22.4 | Blue | 140 |
| Example 4 | | | Compound | | | | |
| | | | C4 | | | | |
| Comparative | HT2/ETH66 | AD-37 | Comparative | 4.8 | 22.9 | Blue | 160 |
| Example 5 | | | Compound | | | | |
| | | | C5 | | | | |
| Comparative | HT3/ETH86 | AD-38 | Comparative | 4.9 | 19.7 | Blue | 100 |
| Example 6 | | | Compound | | | | |
| | | | C1 | | | | |
| Comparative | HT3/ETH86 | AD-38 | Comparative | 5.0 | 20.3 | Blue | 105 |
| Example 7 | | | Compound | | | | |
| | | | C2 | | | | |
| Comparative | HT3/ETH86 | AD-38 | Comparative | 5.0 | 18.6 | Blue | 85 |
| Example 8 | | | Compound | | | | |
| | | | C3 | | | | |
| Comparative | HT3/ETH86 | AD-38 | Comparative | 4.9 | 21.4 | Blue | 145 |
| Example 9 | | | Compound | | | | |
| | | | C4 | | | | |
| Comparative | HT3/ETH86 | AD-38 | Comparative | 4.8 | 21.8 | Blue | 155 |
| Example 10 | | | Compound | | | | |
| | | | C5 | | | | |

Referring to the results of Table 1, it could be confirmed that the Examples of the light emitting devices utilizing the fused polycyclic compounds of one or more embodiments of the present disclosure as light emitting materials, showed improved emission efficiency and life characteristics when compared to the Comparative Examples. The Example Compounds have a structure introducing a first substituent and a second substituents to a fused ring core, and when applied to a light emitting device, it could be confirmed that high emission efficiency and improved lifetime characteristics are shown when compared to the Comparative Examples. The Example Compounds may include a fused ring core in which first to third aromatic rings are fused by a boron atom, a first nitrogen atom, and a first carbon atom, and may have a structure in which a first substituent is spiro bonded to the first carbon atom. Accordingly, the Example Compounds may achieve narrow full width at half maximum of emission spectrum, improved emission efficiency, and blue emission with high color purity due to improved rigidity properties at a center part (e.g., the fused ring core). In addition, because the Example Compounds include a first substituent and a second substituent, a boron atom may be effectively protected, chemical stability of the fused polycyclic compound may be improved, intermolecular interaction may be suppressed or reduced, and excimer or exciplex formation may be controlled or selected, and thus, emission efficiency may be improved and increased. Furthermore, the Example Compounds have a structure having large steric hindrance, distance between adjacent molecules may increase, and Dexter energy transfer may be suppressed or reduced. Accordingly, triplet concentration may decrease, and thus triplet induced lifetime deterioration may be suppressed or reduced. In the fused polycyclic compound of one or more embodiments, the above-described rigidity in the molecule and steric hindrance effects act synergistically, and when introduced and employed as a material of the emission layer of a light emitting device, high efficiency and long lifetime may be achieved.

The light emitting device of one or more embodiments may include the first compound of one or more embodiments as an emission dopant of a thermally activated delayed fluorescence (TADF) emitting device, and high device efficiency in a blue light wavelength region may be achieved.

Referring to Comparative Example 1 and Comparative Example 2, Comparative Compound C1 and Comparative Compound C2 include a fused ring core with one boron atom, one nitrogen atom, and one carbon atom in the center, and have a structure in which a first substituent and a first carbon atom form a spiro bond, but do not include a second substituent that is a substituent having steric hindrance, and as a result, when applied to a device, it could be confirmed that emission efficiency and device lifetime are degraded when compared to the Examples. In the embodiments of Comparative Compound C1 and Comparative Compound C2, a structure in which a methyl group is substituted at a phenyl group that is connected with a nitrogen atom connecting aromatic rings, nonetheless steric hindrance effects are insufficient only with the methyl group, without being bound to any theory, it is considered the reasons why emission efficiency and lifetime of Comparative Example 1 and Comparative Example 2 are degraded when compared to the Example Compounds. In the case of including both (e.g., simultaneously) a first substituent and a second substituent connected with the fused ring core as in the fused polycyclic compound of one or more embodiments of the present disclosure, high emission efficiency in a blue wavelength region and long lifetime could be achieved.

When comparing the Examples and Comparative Example 3, it could be confirmed that Comparative Example 3 showed a high driving voltage, and markedly degraded emission efficiency and lifetime characteristics when compared to the Examples. Comparative Compound C3 included in Comparative Example 3 includes a fused ring structure with a boron atom, a carbon atom, and an oxygen atom in the center and has a structure in which a first substituent and a first carbon atom form a spiro bond, but does not include a second substituent that is a substituent having steric hindrance, and as a result, when applied to a device, it could be confirmed that emission efficiency and device lifetime are degraded when compared to the Examples. Thus, in the case of a polycyclic compound not including a nitrogen atom as a fused ring-forming atom like Comparative Compound C3, multiple resonance effects are reduced when compared to the Examples, and emission efficiency may be deteriorated. As in the fused polycyclic compound of one or more embodiments of the present disclosure, when a nitrogen atom is included as a constituting atom of a fused ring core, and a second substituent that is a substituent having steric hindrance is introduced in the nitrogen atom, high emission efficiency in a blue emission wavelength region and long lifetime could be achieved.

When comparing the Examples and Comparative Example 4, it could be confirmed that Comparative Example 4 showed a high driving voltage, and degraded emission efficiency and device lifetime when compared to the Examples. Comparative Compound C4 included in Comparative Example 4 includes a structure in which a substituent having steric hindrance is substituted at a fused ring in which three aromatic rings are fused with a boron atom as a center, but does not include a carbon atom as the constituting atom of the fused ring. As such, the first substituent suggested and disclosed in the present disclosure is not included. Accordingly, rigidity properties in the molecule were relatively deteriorated when compared to the Example Compounds, and when applied to a light emitting device, emission efficiency and lifetime were degraded when compared to the Examples.

When comparing the Examples and Comparative Example 5, it could be confirmed that Comparative Example 5 showed a high driving voltage, and degraded emission efficiency and lifetime characteristics. Comparative Compound C5 included in Comparative Example 5 does not include a second substituent suggested and disclosed in the present disclosure, and when applied to a device, it could be confirmed that emission efficiency and device lifetime were degraded when compared to the Examples. Comparative Compound C5 has a structure in which a first substituent forms a spiro bond to the fused ring in which three aromatic rings are fused with a boron atom and three carbon atoms as center, and may show improved rigidity in the molecule, but does not include an sp 2 nitrogen atom that plays the role of the highest occupied molecular orbital (HOMO) as a constituting atom of a fused ring. Accordingly, multiple resonance effects were reduced, and emission efficiency was degraded when compared to the Examples.

The light emitting device of one or more embodiments of the present disclosure may show improved device properties of high efficiency and long lifetime.

The fused polycyclic compound of one or more embodiments of the present disclosure may be included in an emission layer of a light emitting device and may contribute to the increase of the efficiency and lifetime of the light emitting device.

Throughout the present disclosure, when a component such as a layer, a film, a region, or a plate is mentioned to be placed “on” another component, it will be understood that it may be directly on another component or that another component may be interposed therebetween. In some embodiments, “directly on” may refer to that there are no additional layers, films, regions, plates, etc., between a layer, a film, a region, a plate, etc. and the other part. For example, “directly on” may refer to two layers or two members are disposed without utilizing an additional member such as an adhesive member therebetween.

As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure”.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The light-emitting device, the display apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present disclosure have been described, it is understood that the present disclosure should not be limited to these embodiments, but one or more suitable changes and modifications can be made by one ordinary skilled in the art within the spirit and scope of the present disclosure as hereinafter claimed and equivalent thereof.

What is claimed is:

1. A light emitting device, comprising:
a first electrode;
a second electrode on the first electrode; and
an emission layer between the first electrode and the second electrode,
wherein the emission layer comprises a first compound represented by Formula 1: 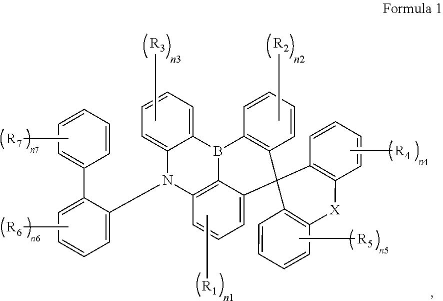
wherein, in Formula 1,
X is NR₈, O, or S,
R₁ to R₈ are each independently hydrogen, deuterium, a halogen, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
n1 is an integer of 0 to 3,
n2 to n6 are each independently an integer of 0 to 4, and
n7 is an integer of 0 to 5.

2. The light emitting device of claim 1, wherein R₂ and R₃ are each independently a substituted or unsubstituted amine group, a substituted or unsubstituted aryl group of 6 to 30 ring-forming carbon atoms, or a substituted or unsubstituted heteroaryl group of 2 to 30 ring-forming carbon atoms, and
n2 and n3 are each independently an integer of 1 to 4.

3. The light emitting device of claim 1, wherein the first compound represented by Formula 1 is represented by Formula 2: 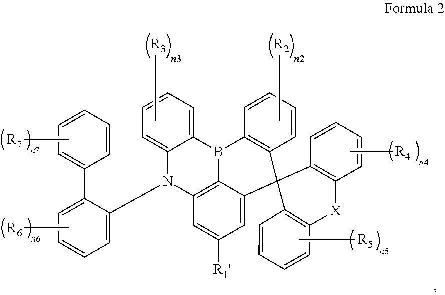
and
wherein, in Formula 2,
R₁′ is a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and
X, R₂ to R₇, and n2 to n7 are the same as defined in Formula 1.

4. The light emitting device of claim 3, wherein is a substituted or unsubstituted alkyl group of 1 to 10 carbon atoms, or represented by Formula A-1 or Formula A-2: 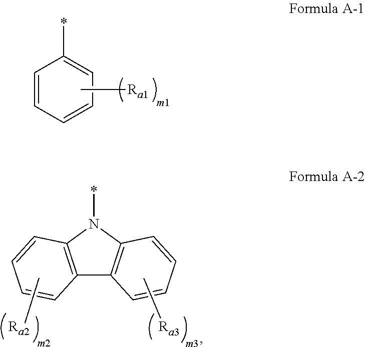
and
wherein, in Formula A-1 and Formula A-2,
Rₐ₁ to Rₐ₃ are each independently hydrogen, deuterium, a halogen, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
m1 is an integer of 0 to 5, and
m2 and m3 are each independently an integer of 0 to 4.

5. The light emitting device of claim 1, wherein the first compound represented by Formula 1 is represented by any one selected from among Formula 3-1 to Formula 3-4: 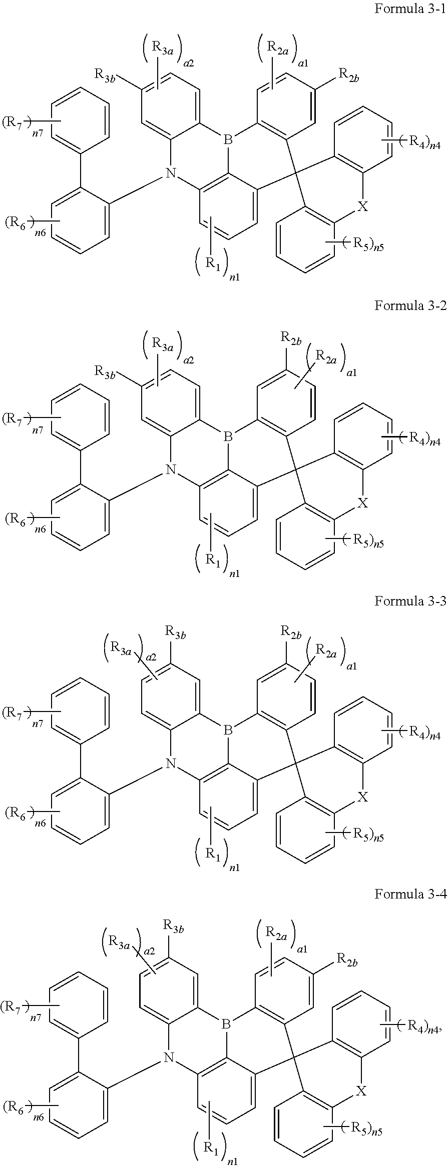
and
wherein, in Formula 3-1 to Formula 3-4,
R₂ₐ and R₃ₐ are each independently hydrogen, deuterium, a halogen, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
R_{2b} and R_{3b} are each independently a substituted or unsubstituted aryl group of 6 to 30 ring-forming carbon atoms, or a substituted or unsubstituted heteroaryl group of 2 to 30 ring-forming carbon atoms,
a1 and a2 are each independently an integer of 0 to 3, and
X, R₁, R₄ to R₇, n1, and n4 to n7 are the same as defined in Formula 1.

6. The light emitting device of claim 1, wherein the first compound represented by Formula 1 is represented by any one selected from among Formula 4-1 to Formula 4-4: 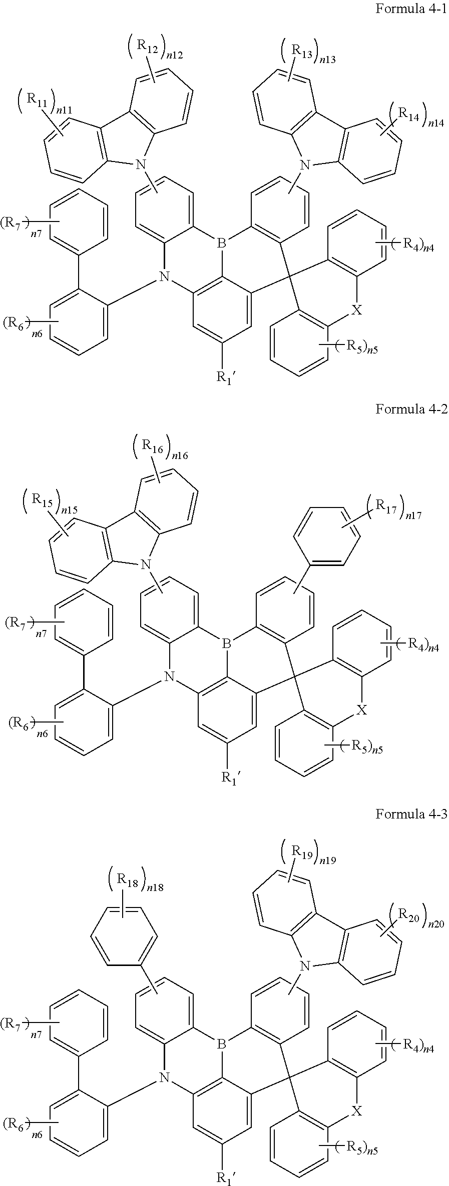 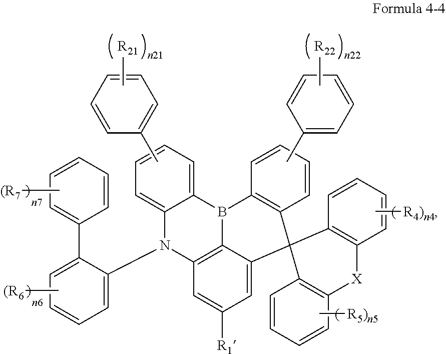
and
wherein, in Formula 4-1 to Formula 4-4,
R₁₁ to R₂₂ are each independently hydrogen, deuterium, a halogen, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
R₁′ is a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
n11 to n16, n19, and n20 are each independently an integer of 0 to 4,
n17, n18, n21, and n22 are each independently an integer of 0 to 5, and
X, R₄ to R₇, and n4 to n7 are the same as defined in Formula 1.

7. The light emitting device of claim 1, wherein the first compound represented by Formula 1 is represented by any one selected from among Formula 5-1 to Formula 5-3: 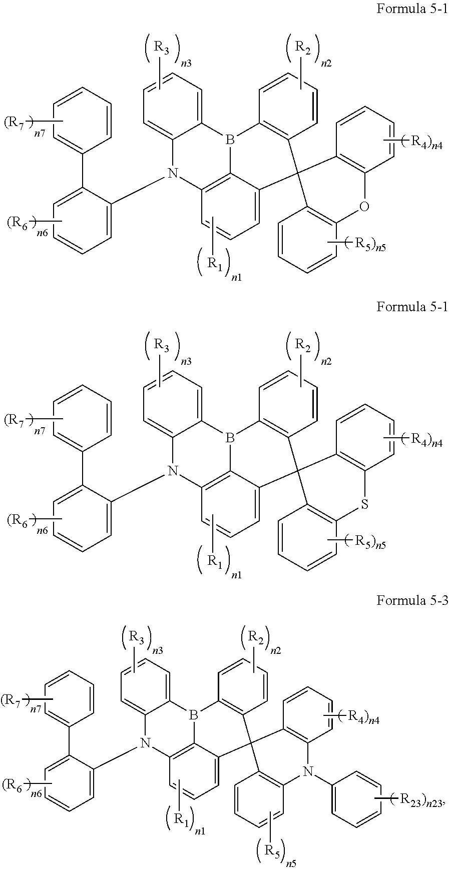
and
wherein, in Formula 5-1 to Formula 5-3,
R₂₃ is hydrogen, deuterium, a halogen, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
n23 is an integer of 0 to 5, and
R₁ to R₇, and n1 to n7 are the same as defined in Formula 1.

8. The light emitting device of claim 1, wherein the first compound represented by Formula 1 is represented by Formula 6: 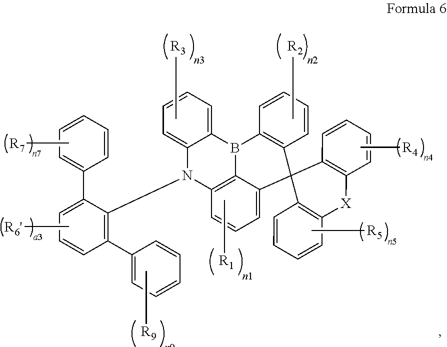
and
wherein, in Formula 6,
R₆′ and R₉ are each independently hydrogen, deuterium, a halogen, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
a3 is an integer of 0 to 3,
n9 is an integer of 0 to 5, and
X, R₁ to R₅, R₇, n1 to n5, and n7 are the same as defined in Formula 1.

9. The light emitting device of claim 1, wherein the first compound represented by Formula 1 is represented by any one selected from among Formula 7-1 to Formula 7-3: 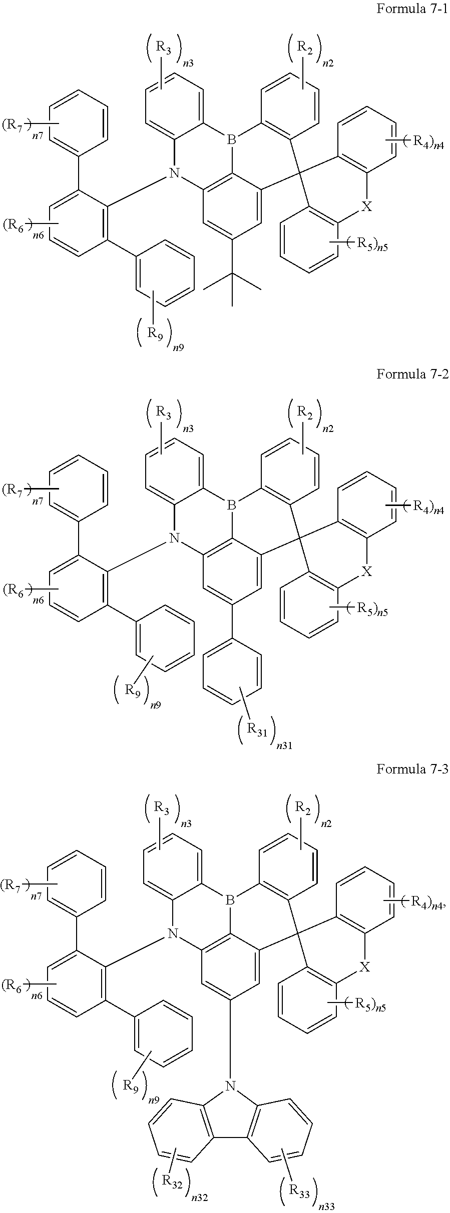
and
wherein, in Formula 7-1 to Formula 7-3,
R₆′, R₉, and R₃₁ to R₃₃ are each independently hydrogen, deuterium, a halogen, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
a3 is an integer of 0 to 3,
n9 and n31 are each independently an integer of 0 to 5,
n32 and n33 are each independently an integer of 0 to 4, and
X, R₂ to R₅, R₇, n2 to n5, and n7 are the same as defined in Formula 1.

10. The light emitting device of claim 1, wherein the first compound represented by Formula 1 is represented by any one selected from among Formula 8-1 to Formula 8-3: 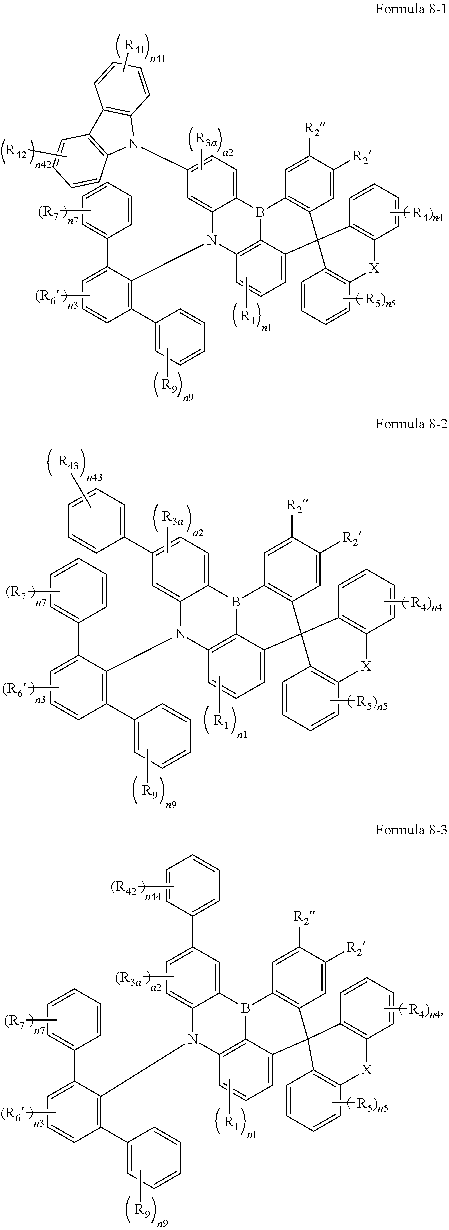
and
wherein, in Formula 8-1 to Formula 8-3,
R₃ₐ, R₂′, R₂″, and R₄₁ to R₄₄ are each independently hydrogen, deuterium, a halogen, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
R₆′, and R₉ are each independently hydrogen, deuterium, a halogen, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
at least one selected from among R₂′ and R₂″ is a substituted or unsubstituted aryl group of 6 to 30 ring-forming carbon atoms, or a substituted or unsubstituted heteroaryl group of 2 to 30 ring-forming carbon atoms,
a2 and a3 are each independently an integer of 0 to 3,
n9 is an integer of 0 to 5,
n41 and n42 are each independently an integer of 0 to 4,
n43 and n44 are each independently an integer of 0 to 5, and
X, R₁, R₄, R₅, R₇, n1, n4, n5, and n7 are the same as defined in Formula 1.

11. The light emitting device of claim 1, wherein the first compound represented by Formula 1 comprises at least one selected from among compounds in Compound Group 1:

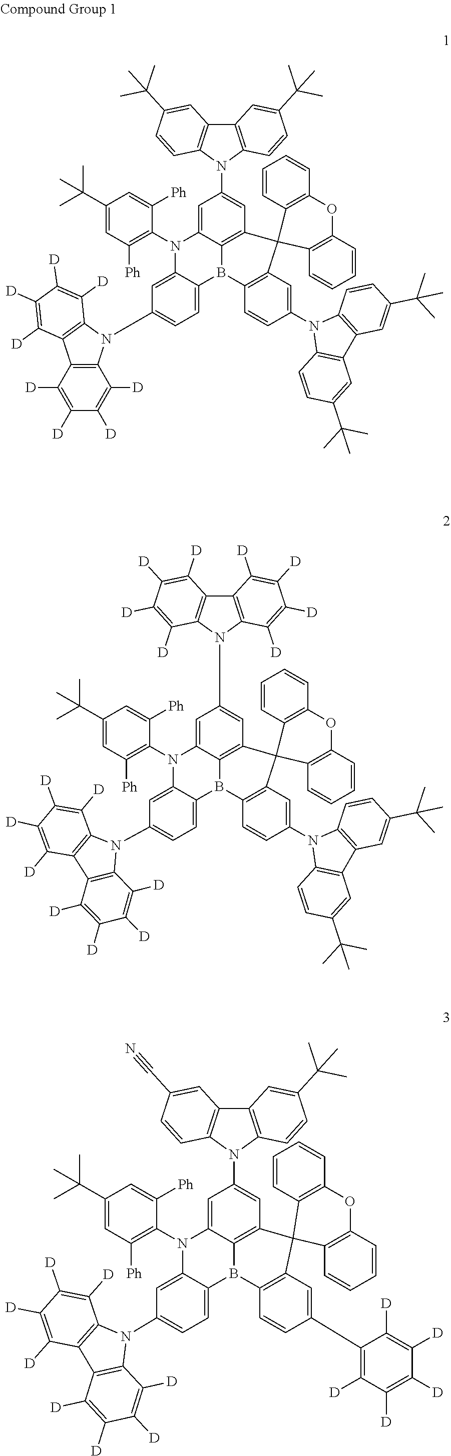

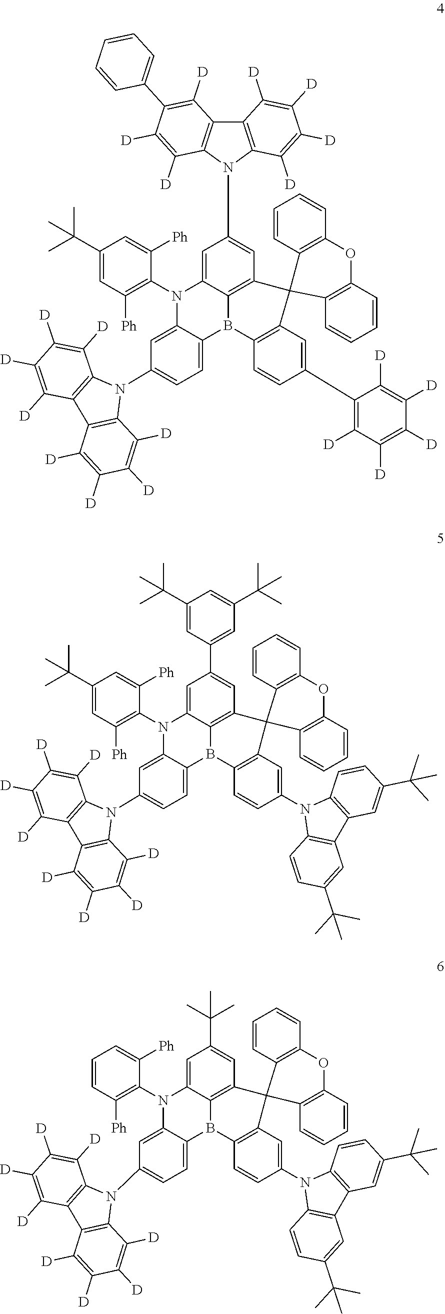

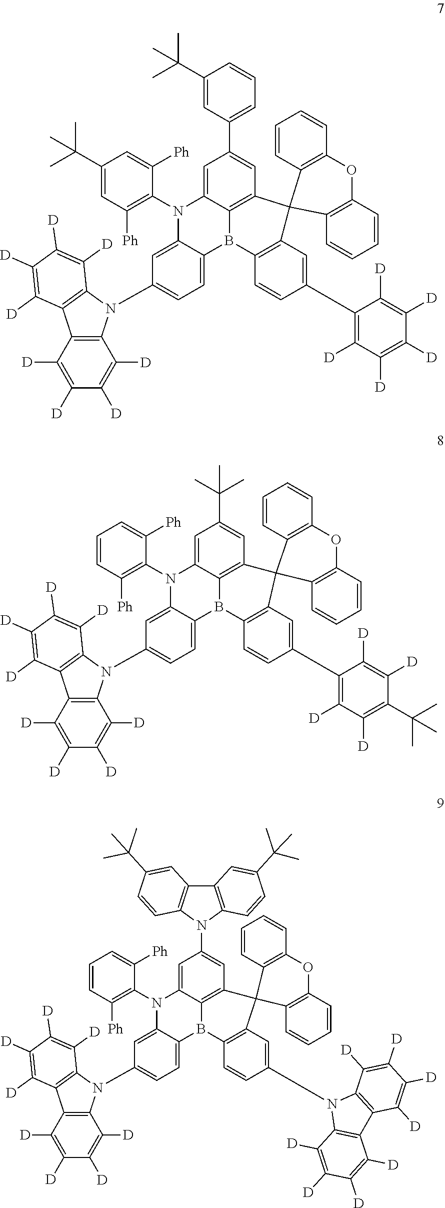

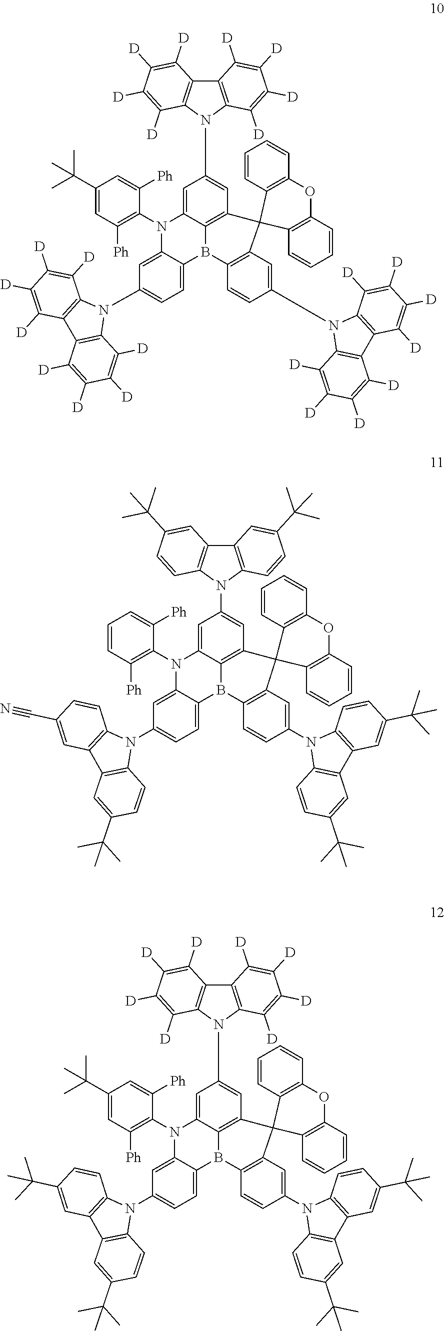

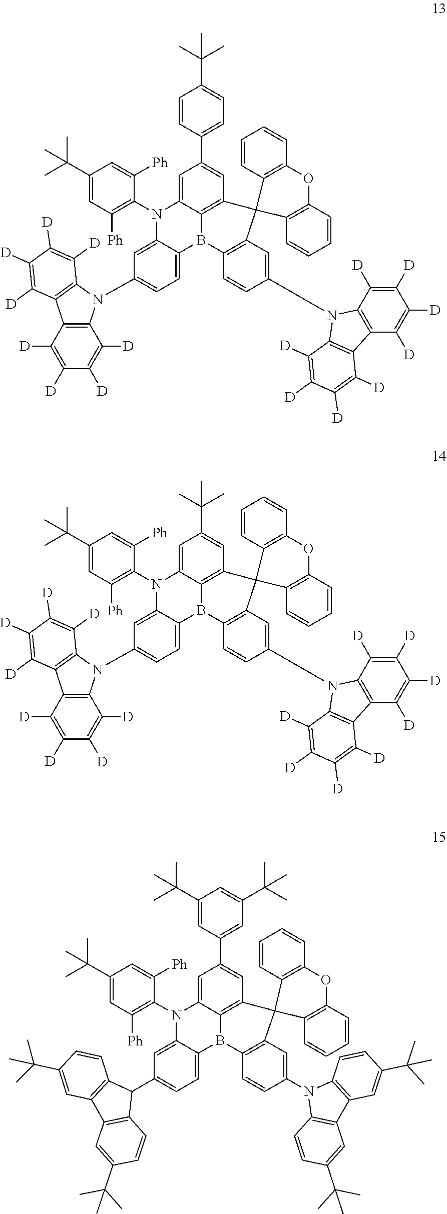

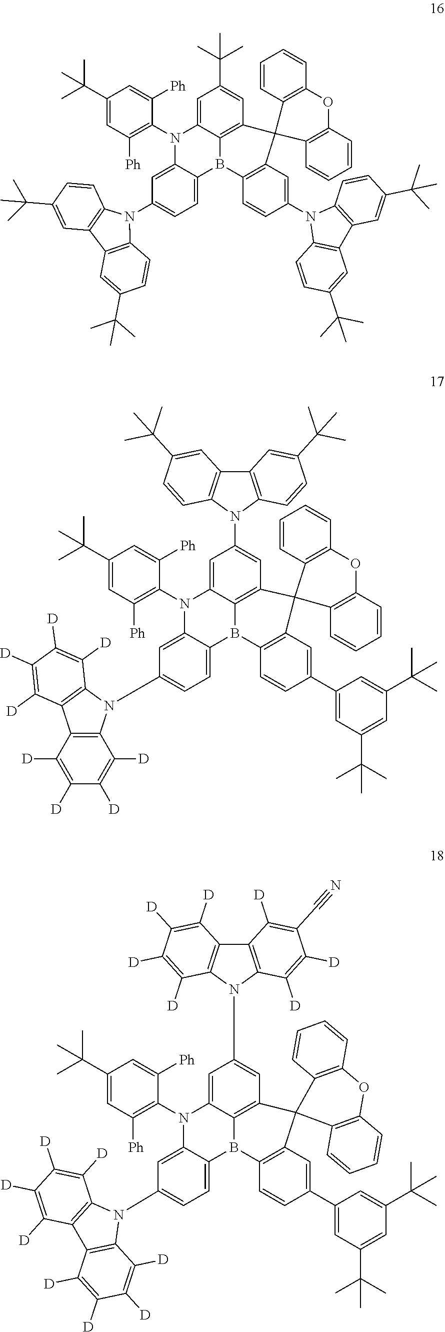

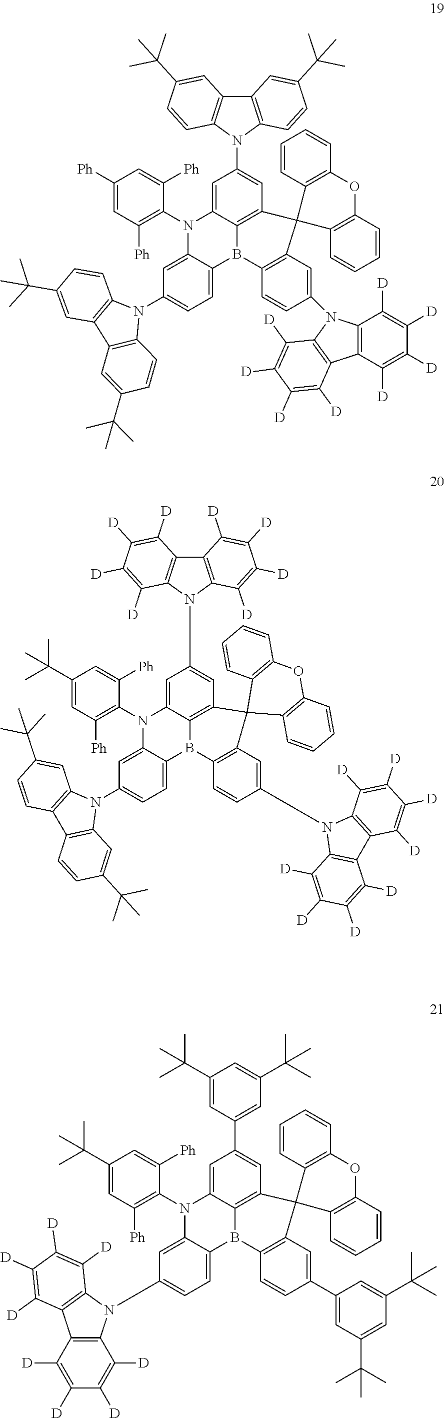

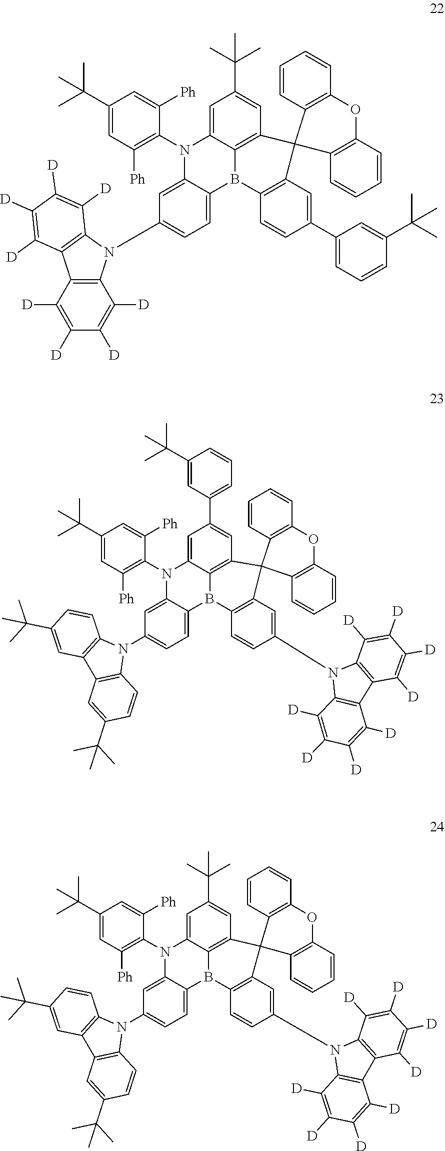

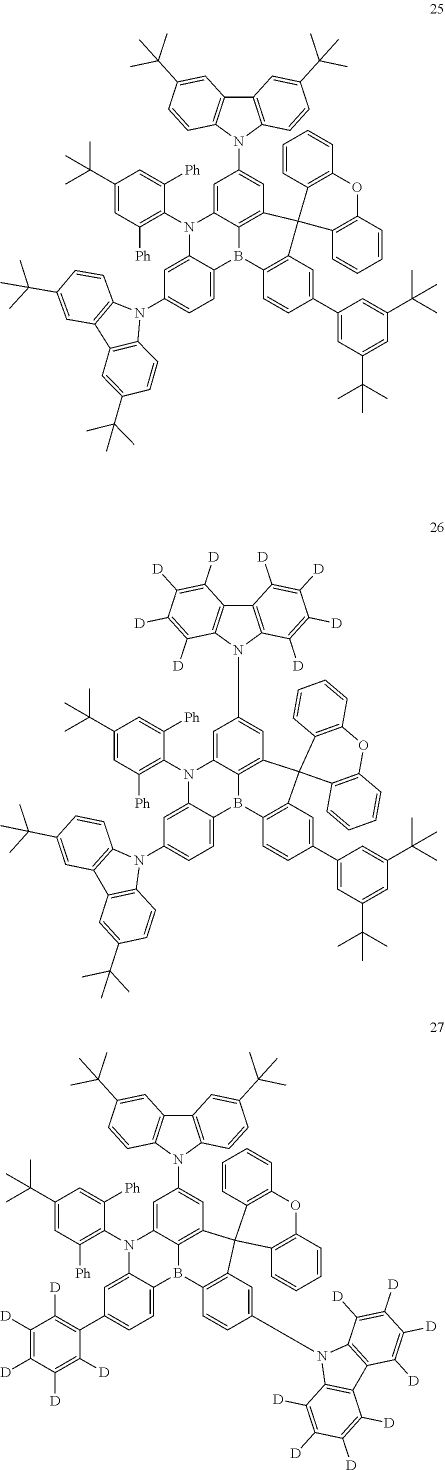

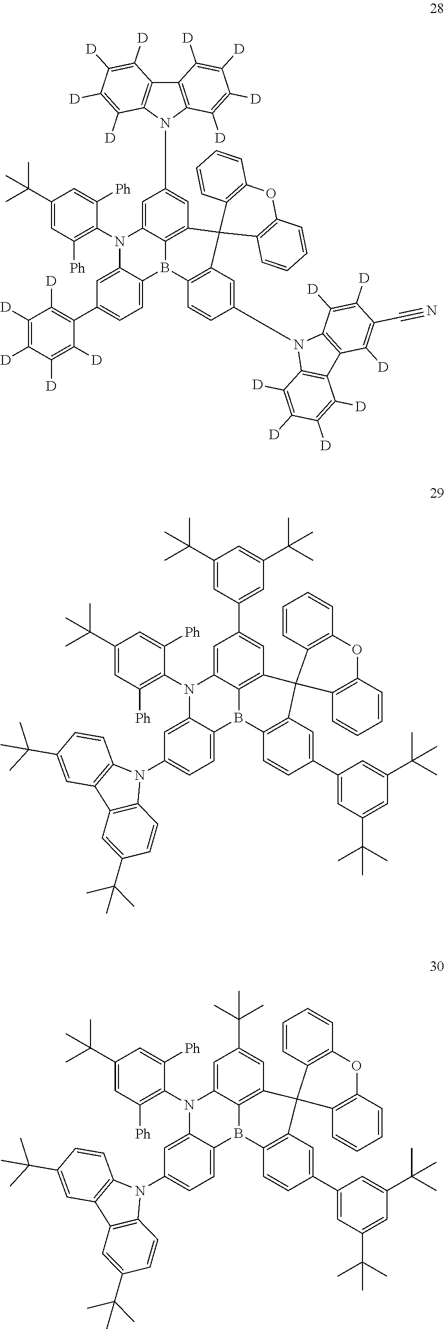

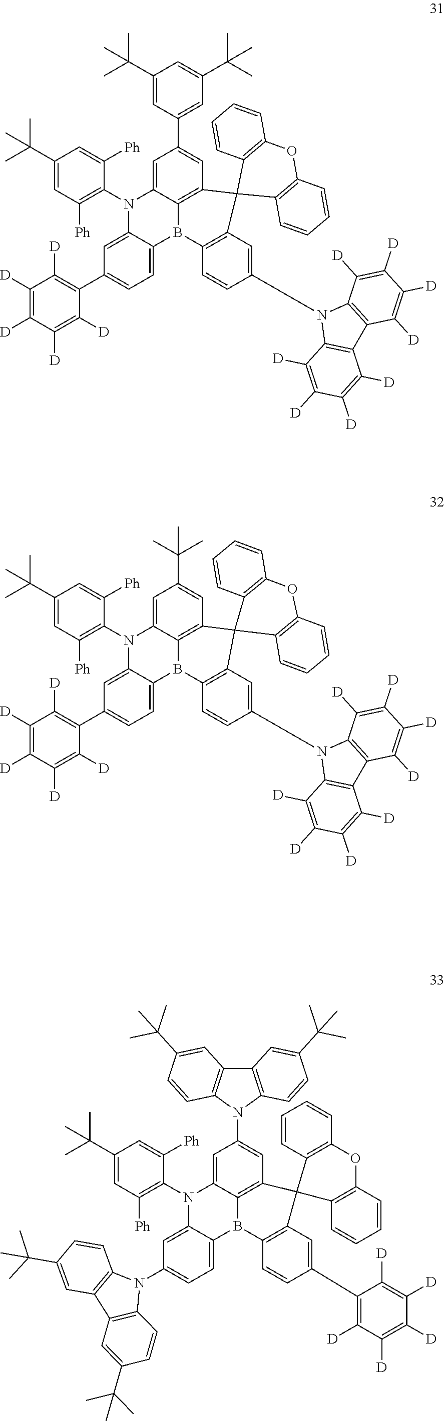

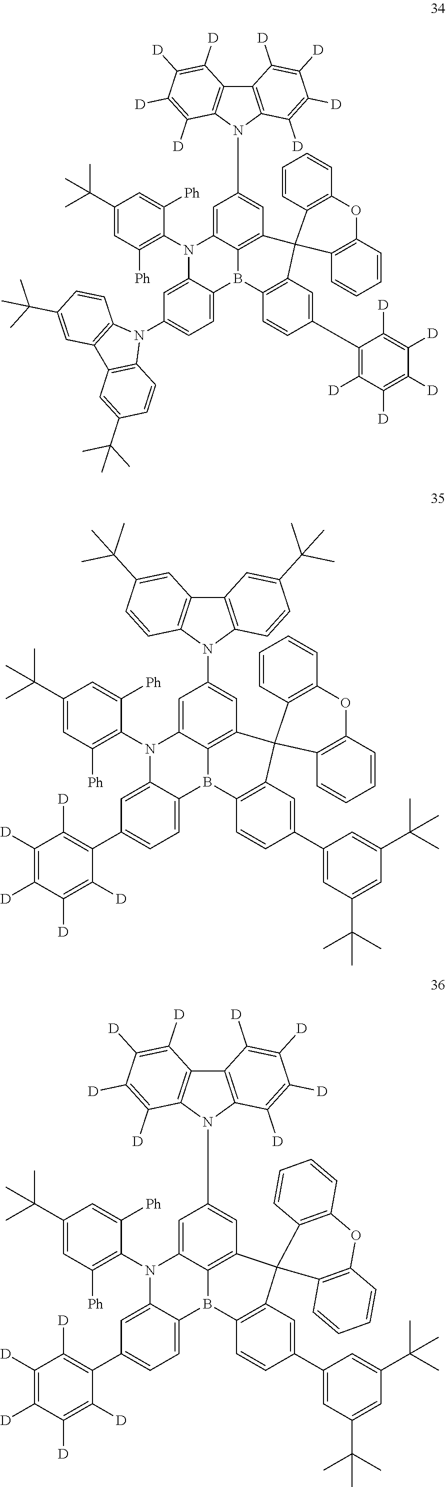

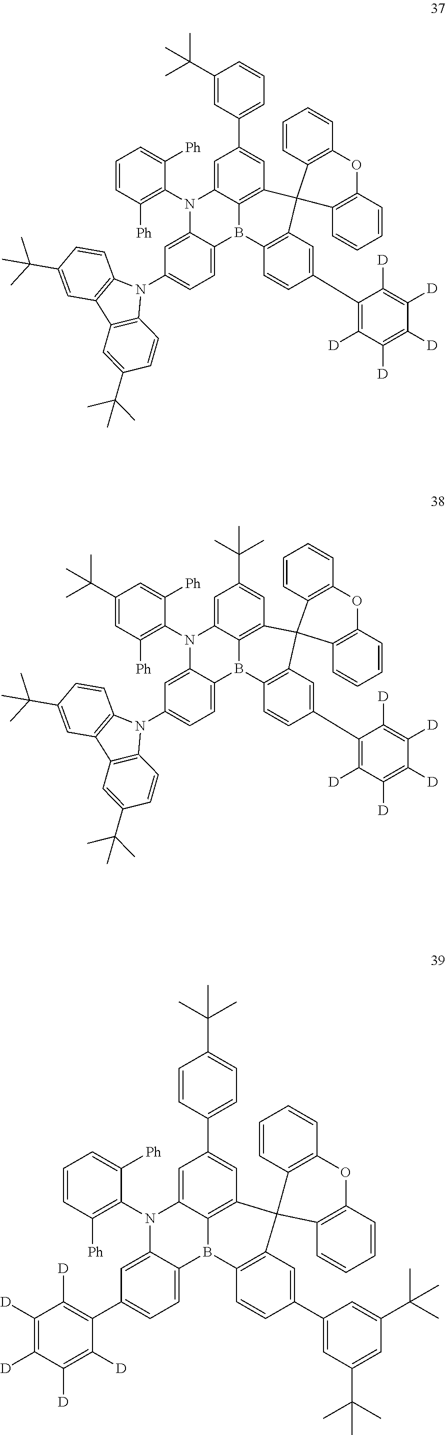

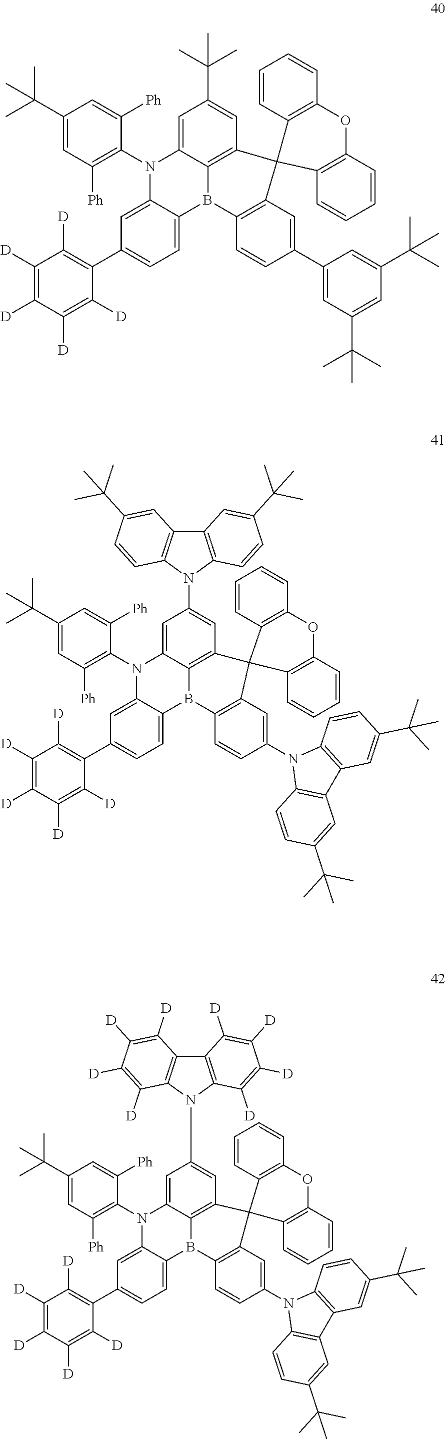

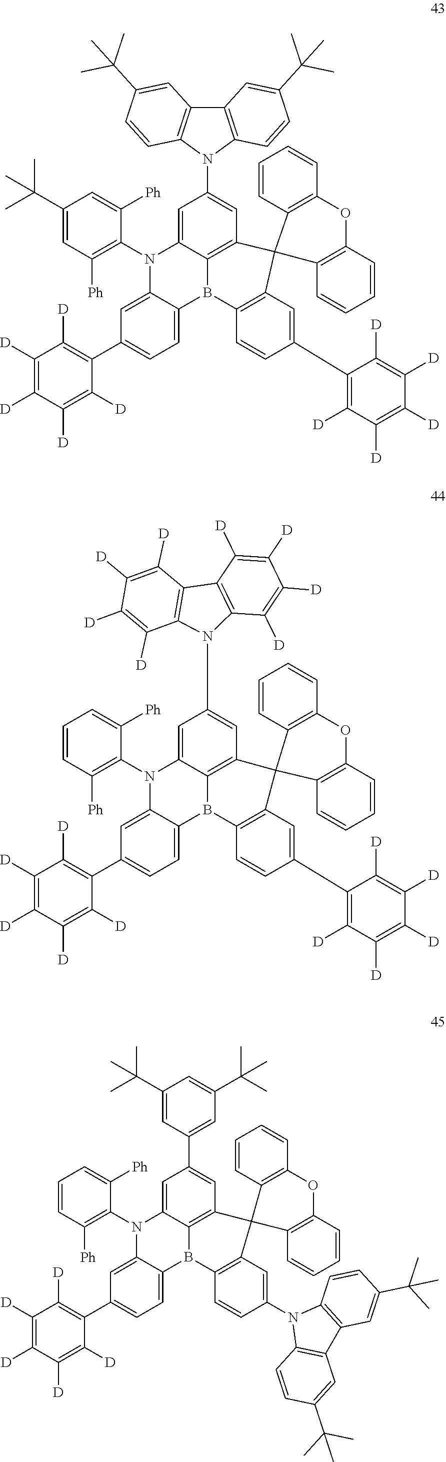

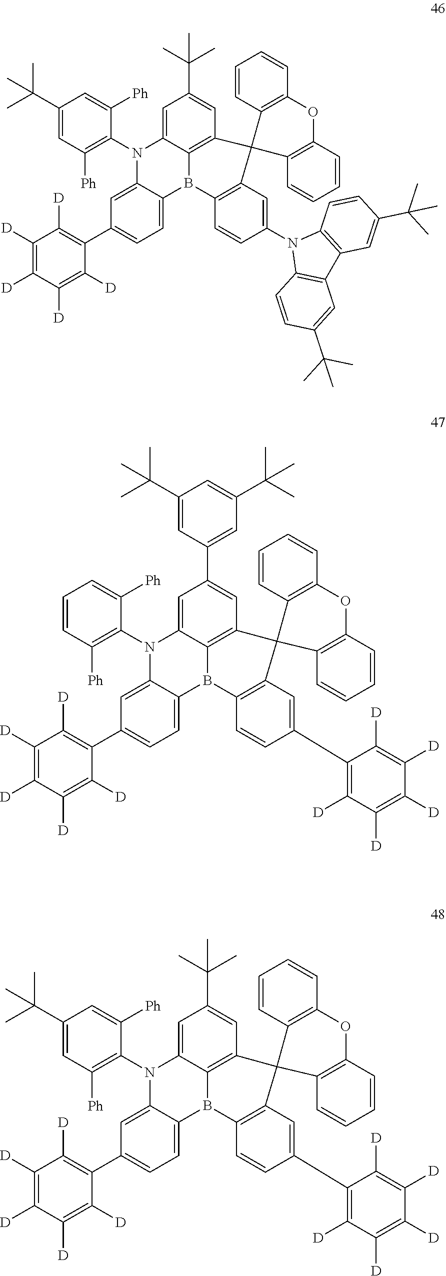

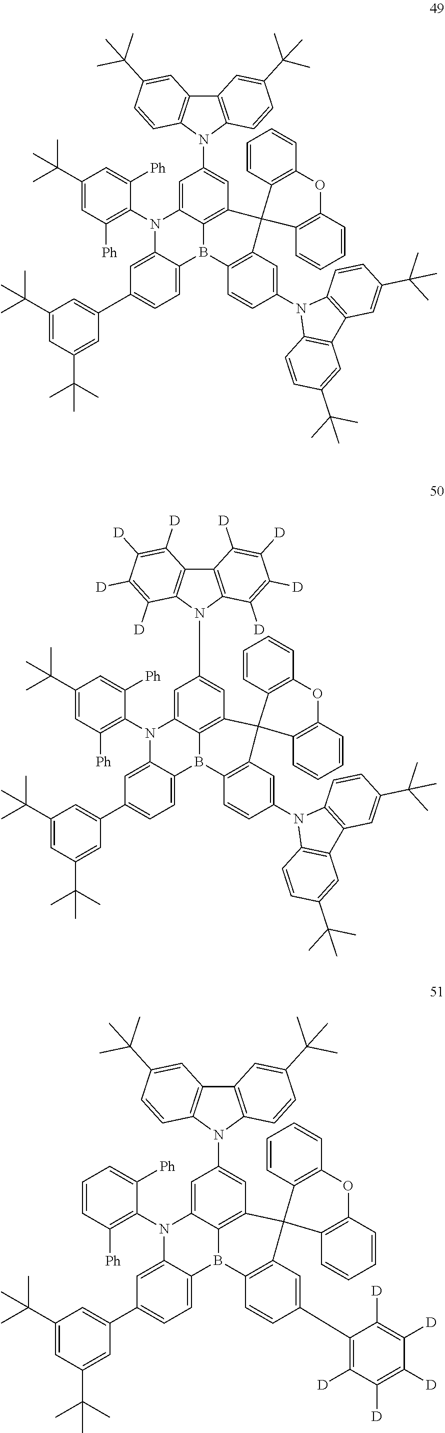

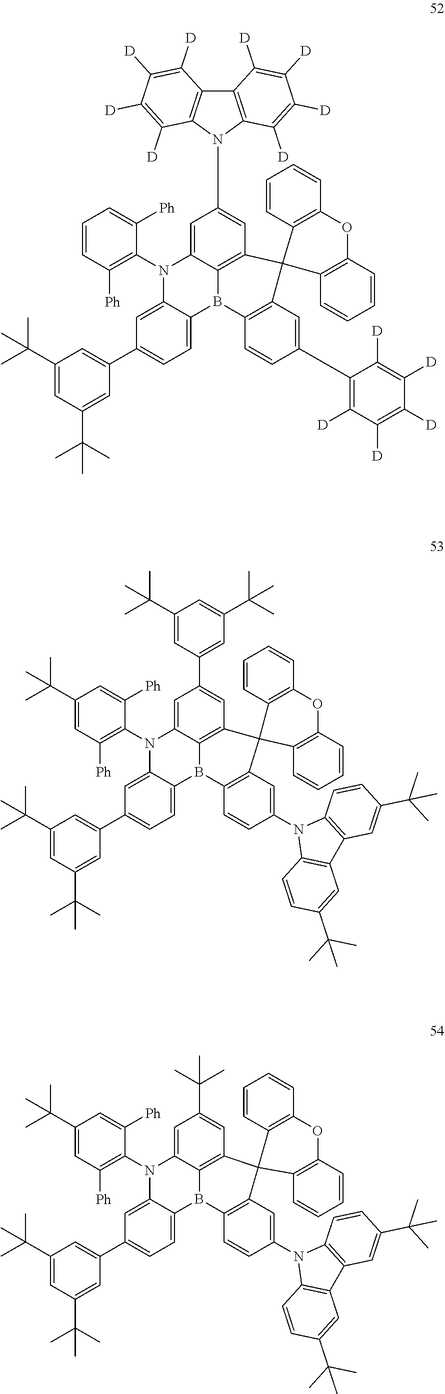

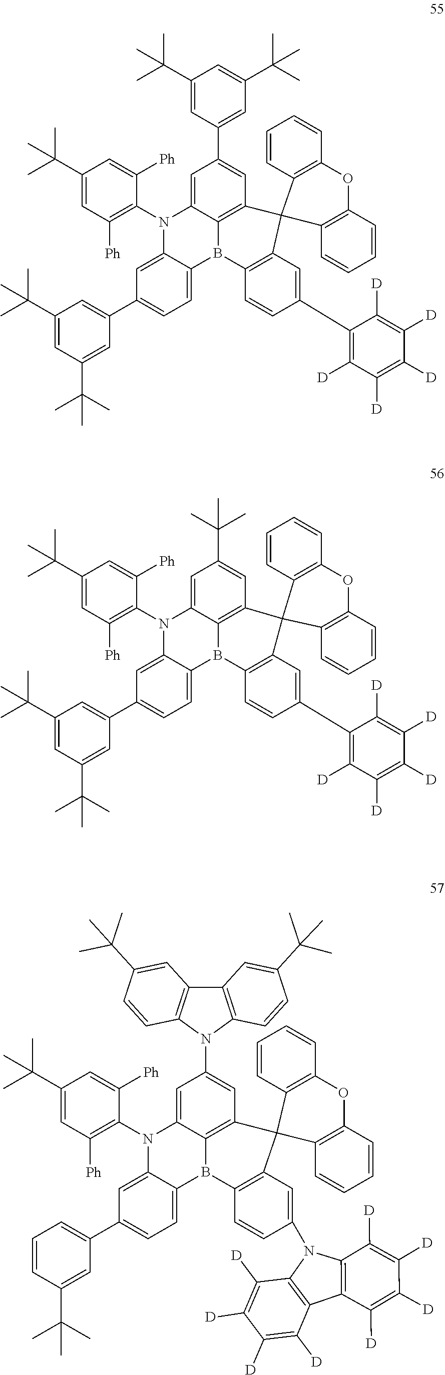

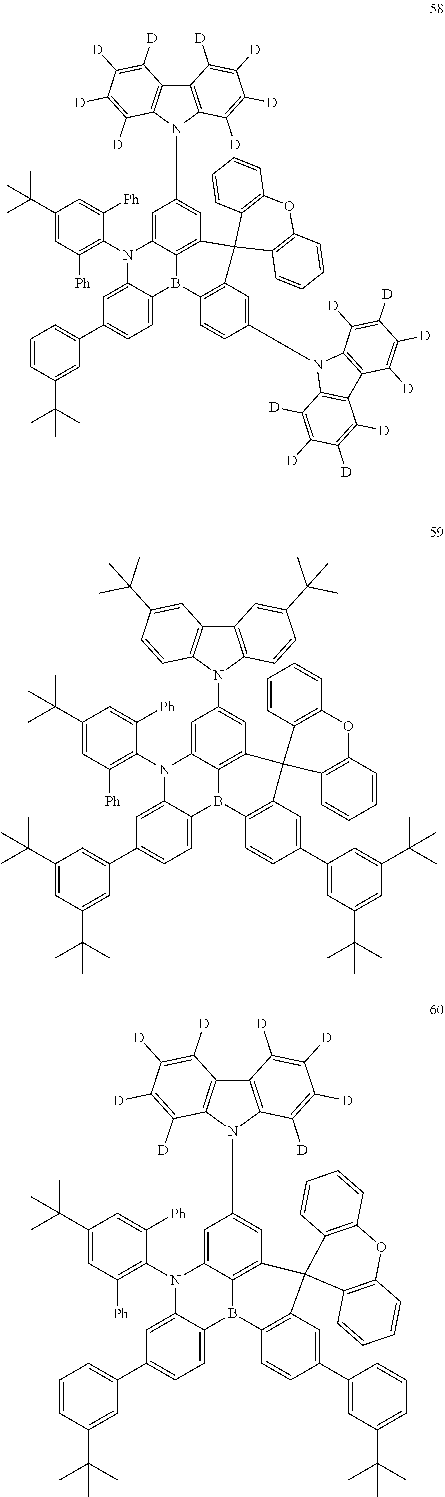

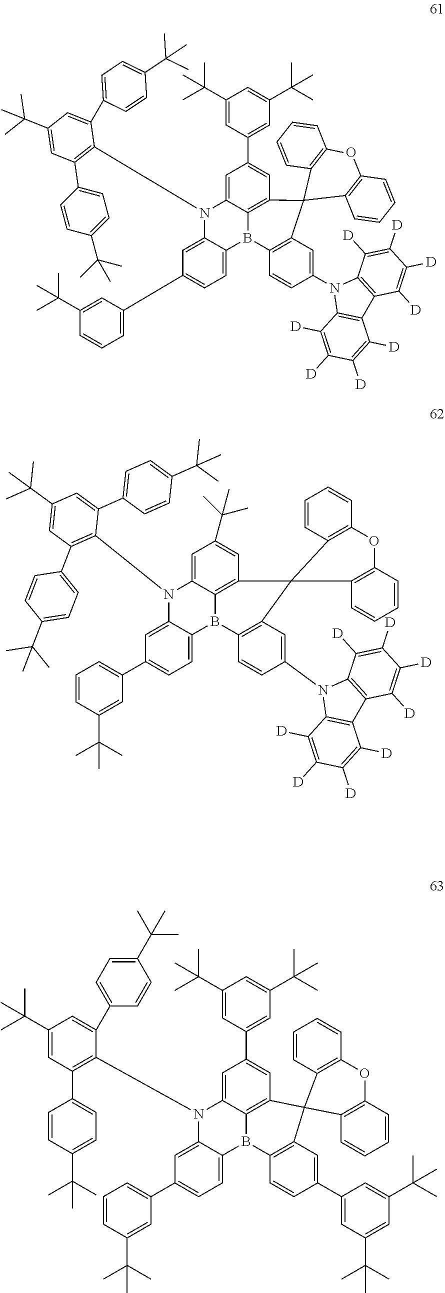

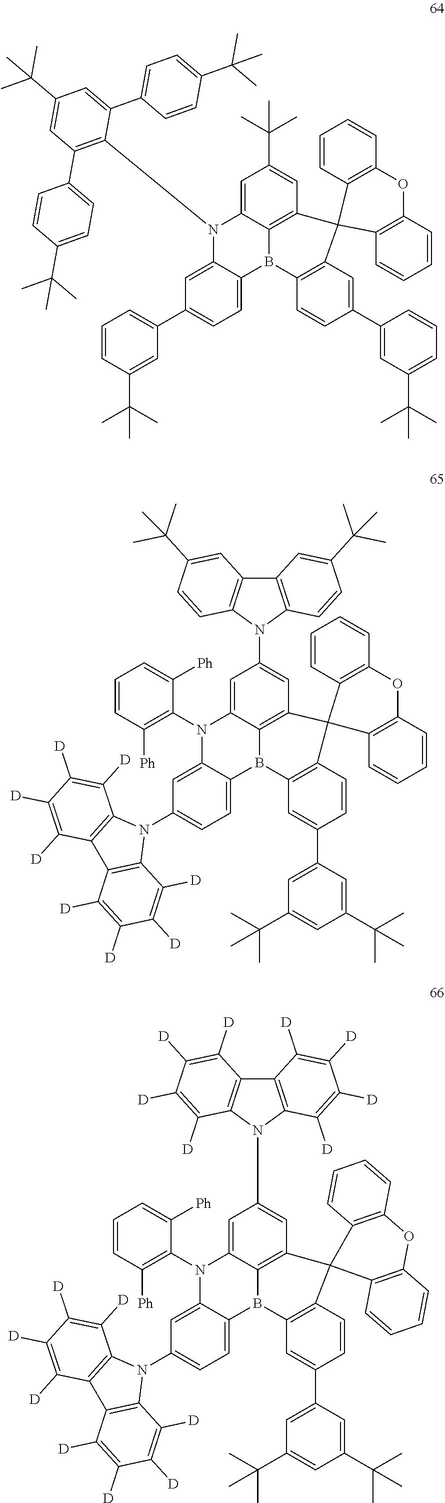

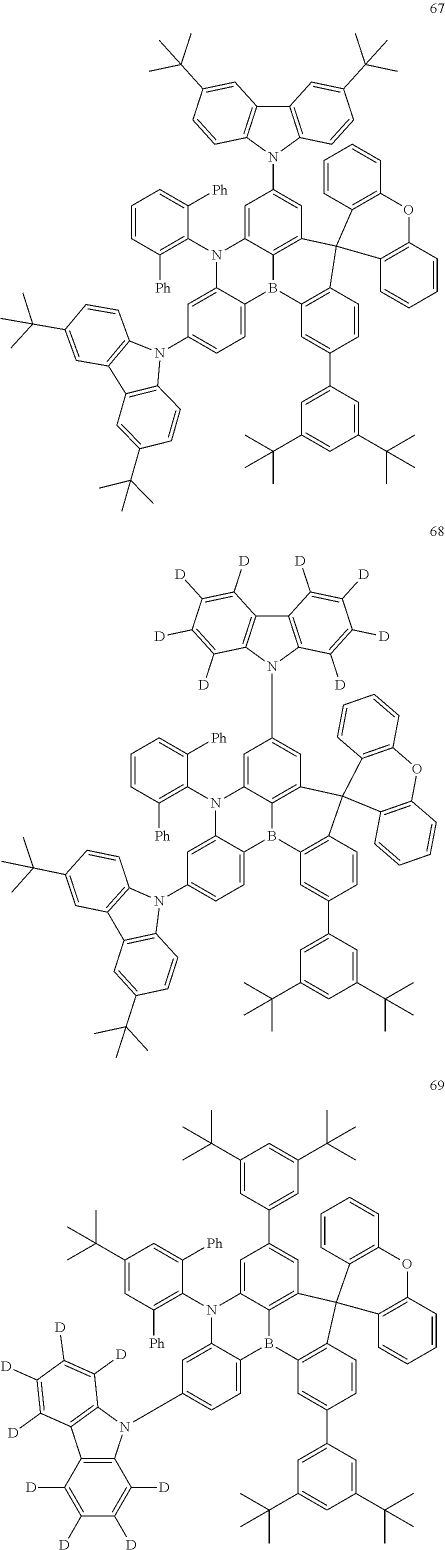

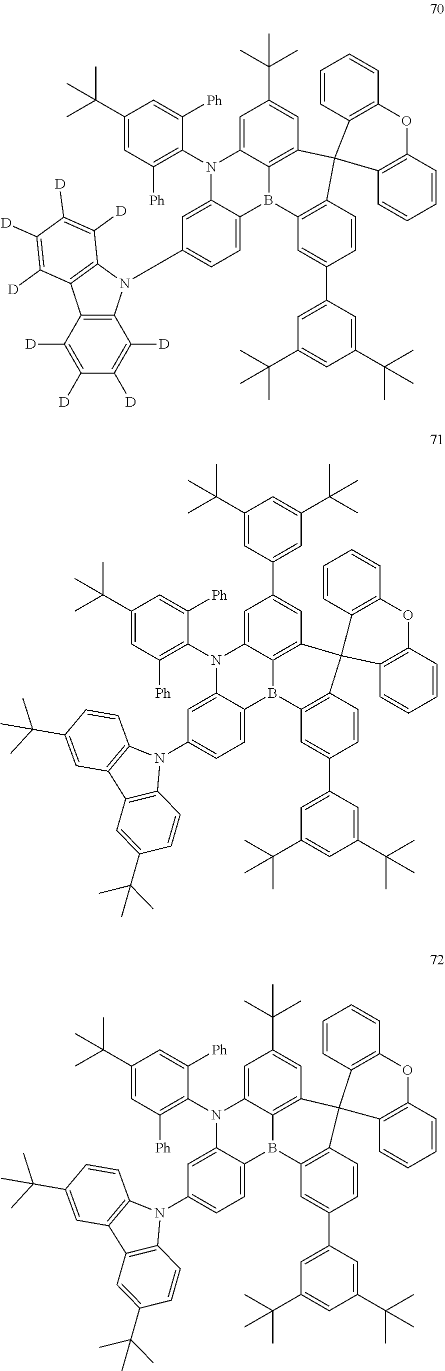

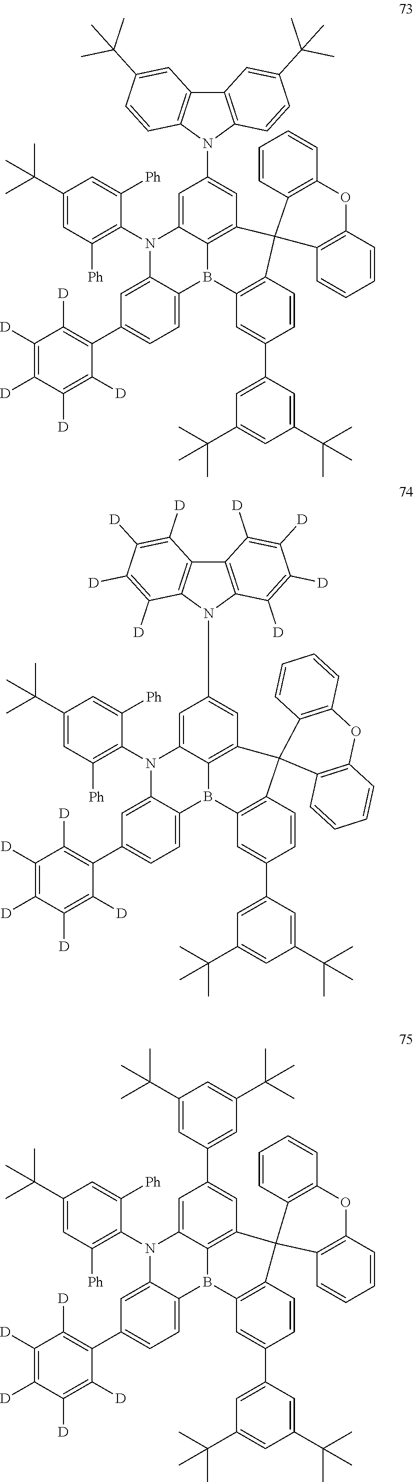

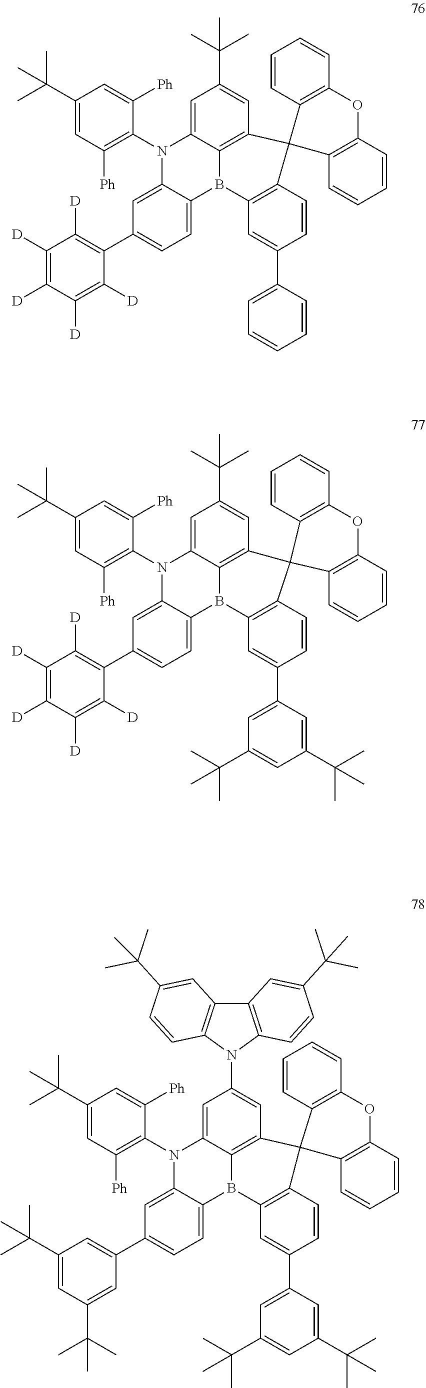

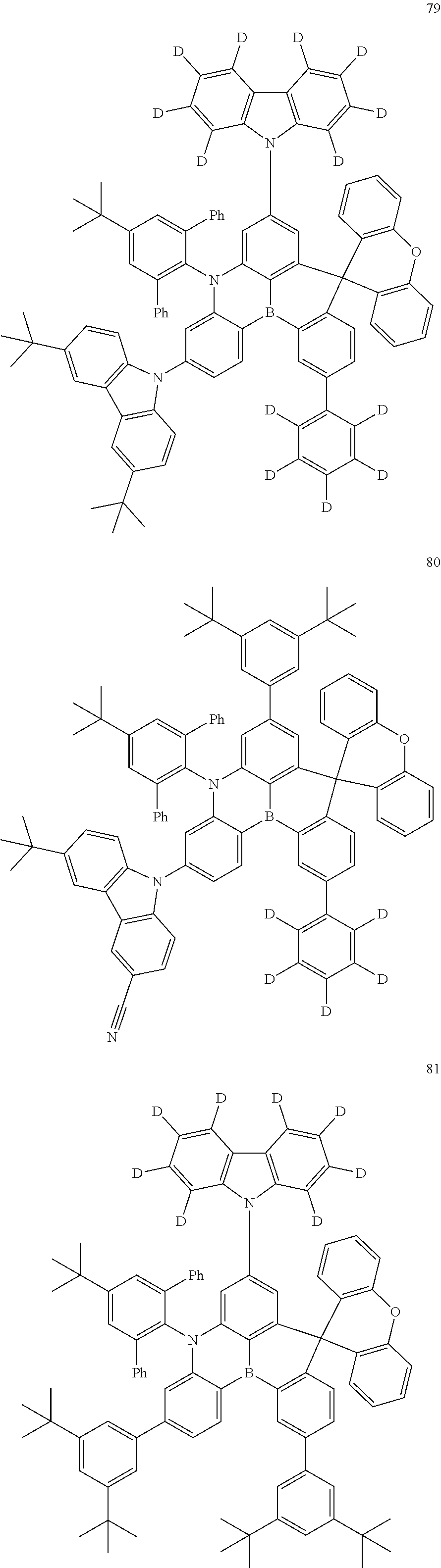

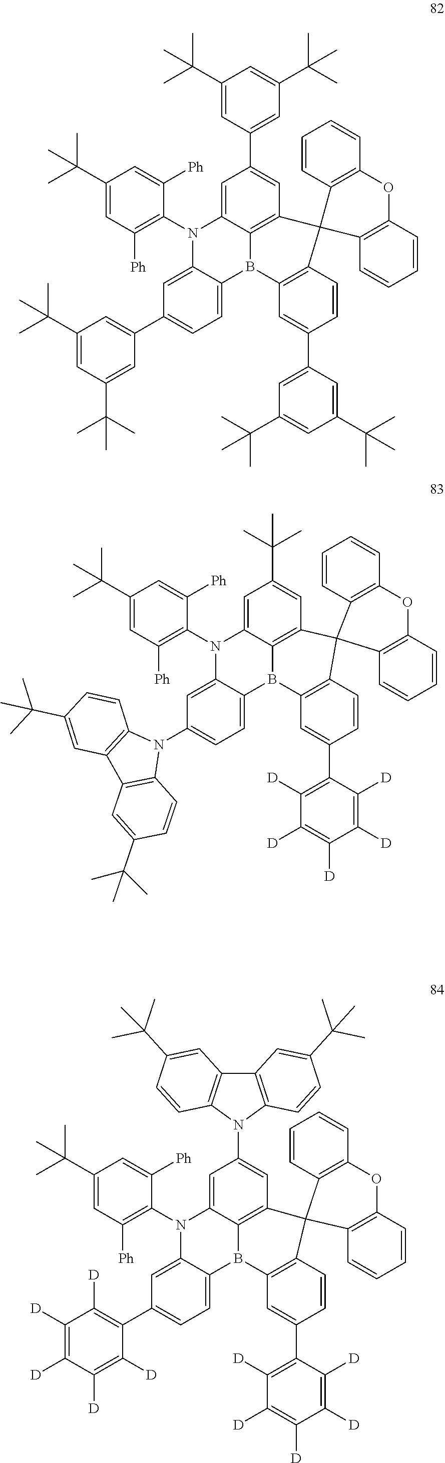

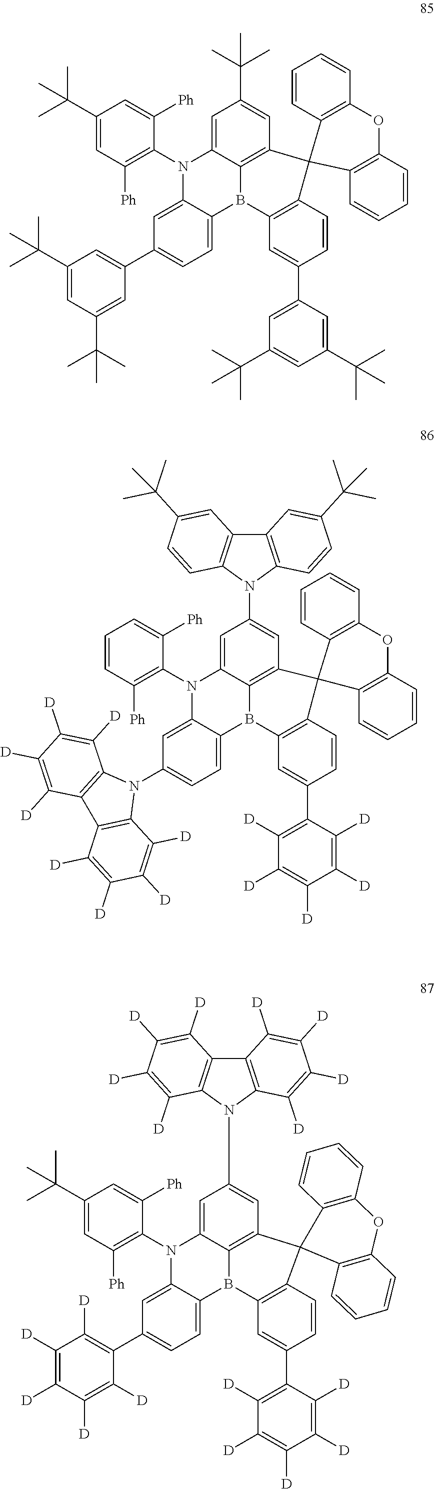

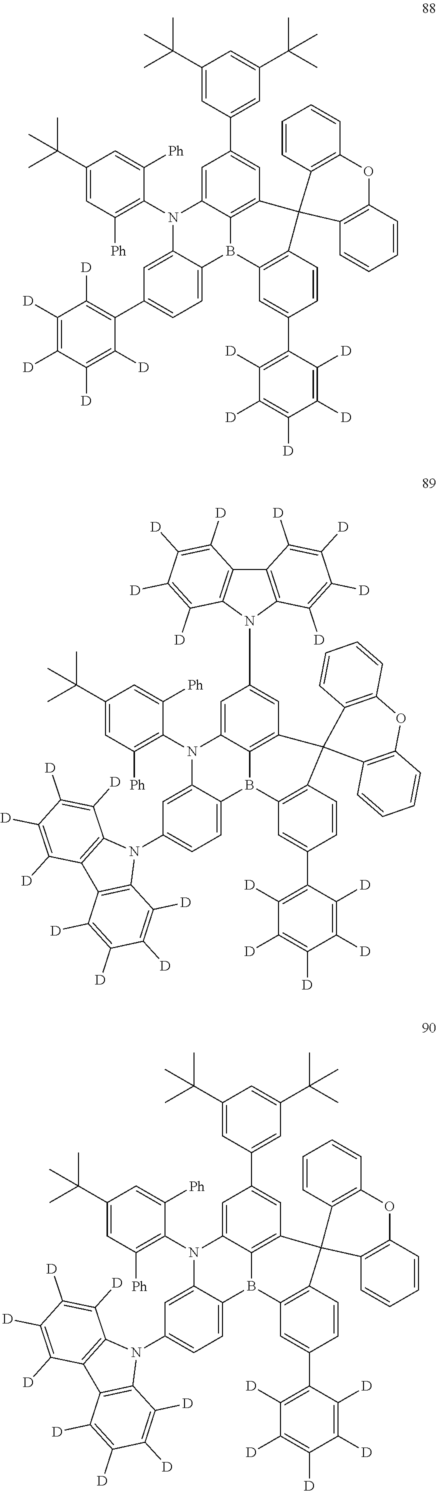

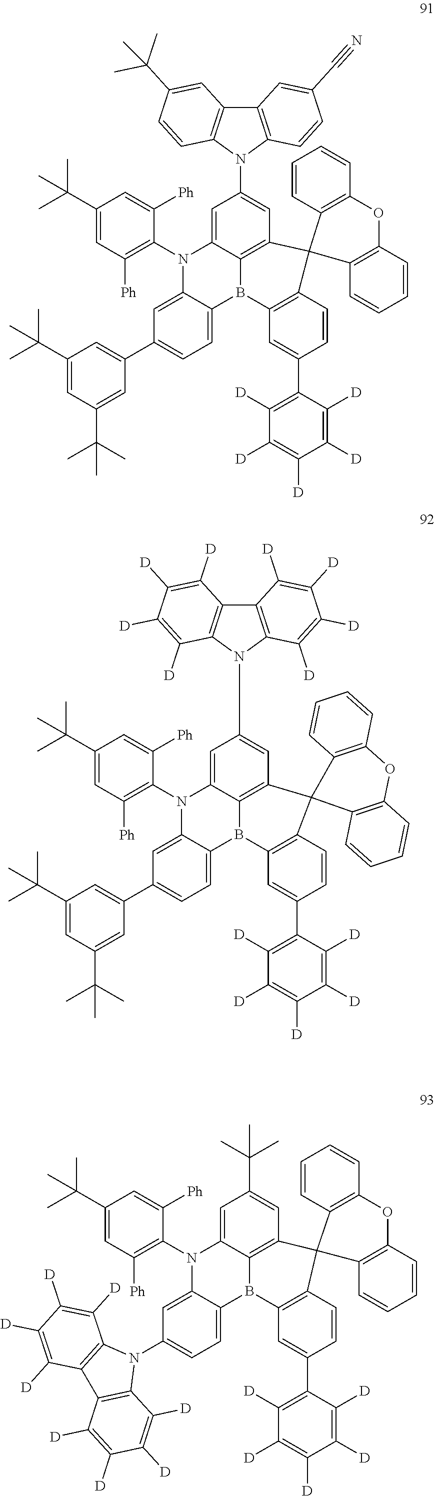

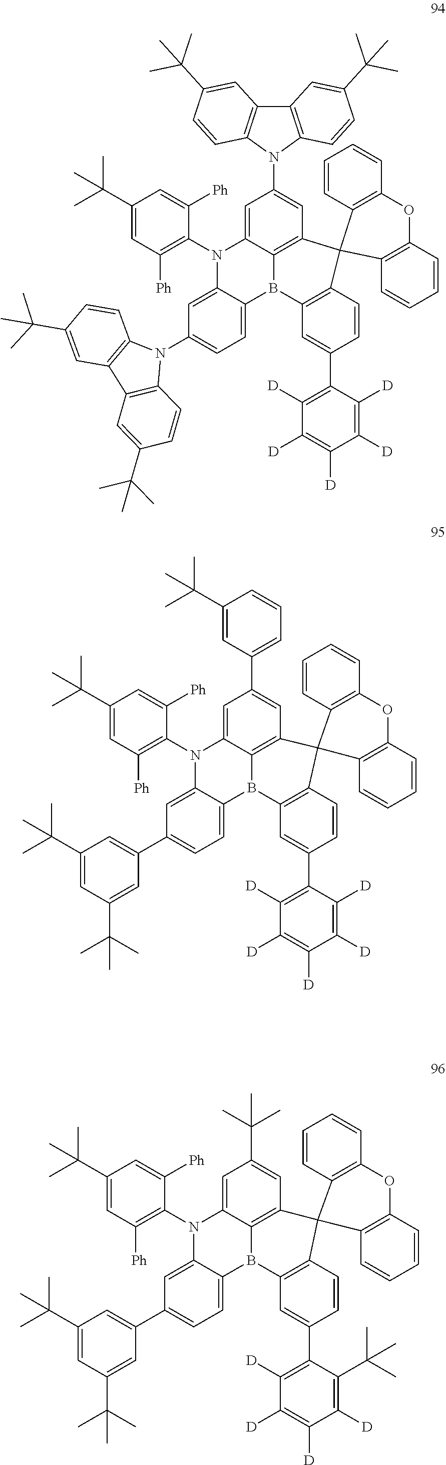

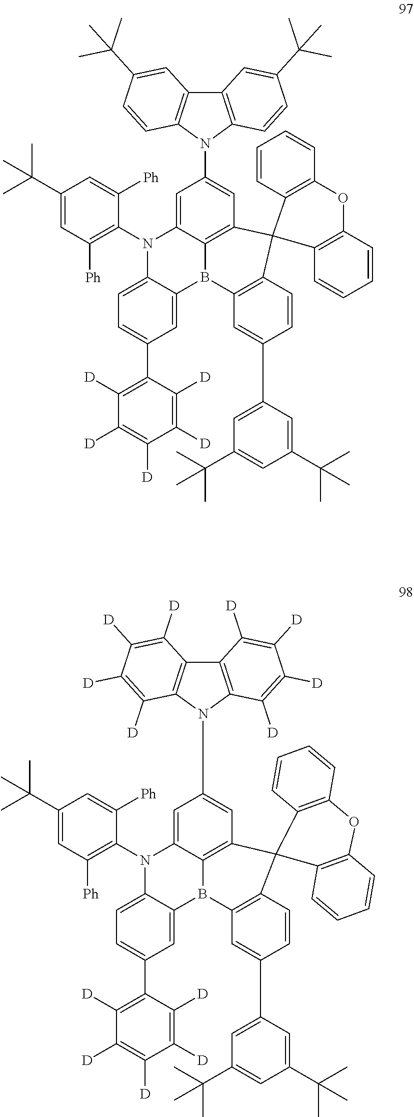 [SMILES: [2H]c1c([2H])c([2H])c(-c2ccc3c(c2)B2c4cc(-c5cc(C(C)(C)C)cc(C(C)(C)C)c5)ccc4C4(c5ccccc5Oc5ccccc54)c4cc(-n5c6ccc(C(C)(C)C)cc6c6cc(C(C)(C)C)ccc65)cc(c42)N3c2c(-c3ccccc3)cc(C(C)(C)C)cc2-c2ccccc2)c([2H])c1[2H] ; [2H]c1c([2H])c([2H])c(-c2ccc3c(c2)B2c4cc(-c5cc(C(C)(C)C)cc(C(C)(C)C)c5)ccc4C4(c5ccccc5Oc5ccccc54)c4cc(-n5c6c([2H])c([2H])c([2H])c([2H])c6c6c([2H])c([2H])c([2H])c([2H])c65)cc(c42)N3c2c(-c3ccccc3)cc(C(C)(C)C)cc2-c2ccccc2)c([2H])c1[2H]]

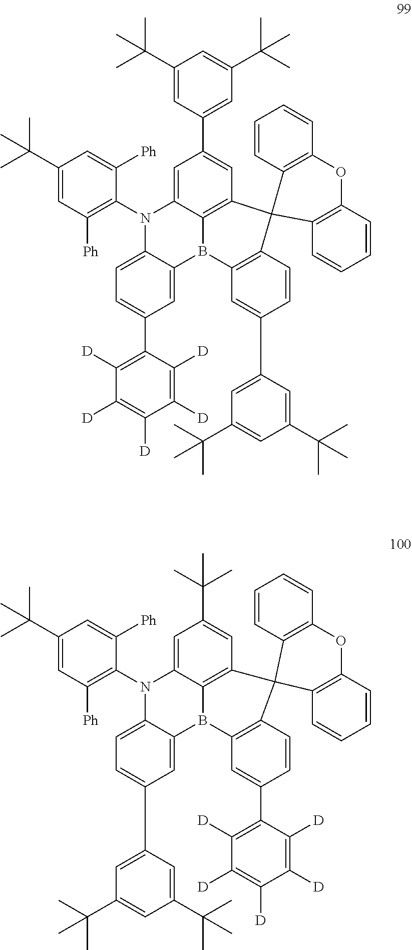 [SMILES: [2H]c1c([2H])c([2H])c(-c2ccc3c(c2)B2c4cc(-c5cc(C(C)(C)C)cc(C(C)(C)C)c5)ccc4C4(c5ccccc5Oc5ccccc54)c4cc(-c5cc(C(C)(C)C)cc(C(C)(C)C)c5)cc(c42)N3c2c(-c3ccccc3)cc(C(C)(C)C)cc2-c2ccccc2)c([2H])c1[2H] ; [2H]c1c([2H])c([2H])c(-c2ccc3c(c2)B2c4cc(-c5cc(C(C)(C)C)cc(C(C)(C)C)c5)ccc4N(c4c(-c5ccccc5)cc(C(C)(C)C)cc4-c4ccccc4)c4cc(C(C)(C)C)cc(c42)C32c3ccccc3Oc3ccccc32)c([2H])c1[2H]]

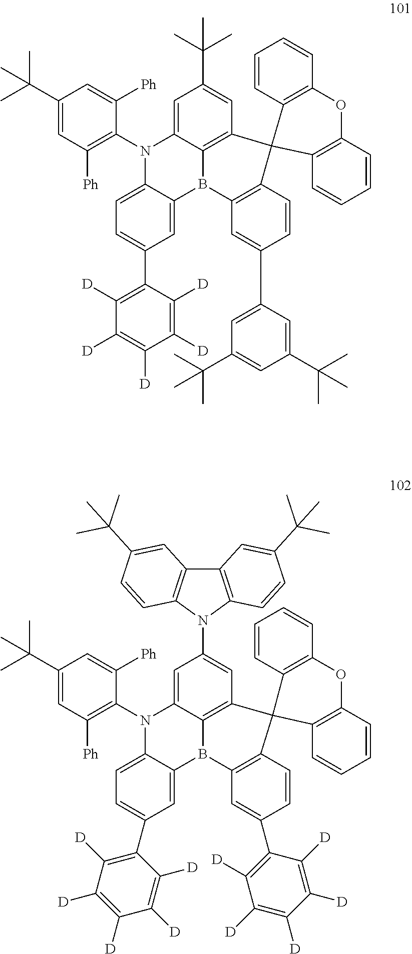 [SMILES: [2H]c1c([2H])c([2H])c(-c2ccc3c(c2)B2c4cc(-c5cc(C(C)(C)C)cc(C(C)(C)C)c5)ccc4C4(c5ccccc5Oc5ccccc54)c4cc(C(C)(C)C)cc(c42)N3c2c(-c3ccccc3)cc(C(C)(C)C)cc2-c2ccccc2)c([2H])c1[2H] ; [2H]c1c([2H])c([2H])c(-c2ccc3c(c2)B2c4cc(-c5c([2H])c([2H])c([2H])c([2H])c5[2H])ccc4C4(c5ccccc5Oc5ccccc54)c4cc(-n5c6ccc(C(C)(C)C)cc6c6cc(C(C)(C)C)ccc65)cc(c42)N3c2c(-c3ccccc3)cc(C(C)(C)C)cc2-c2ccccc2)c([2H])c1[2H]]

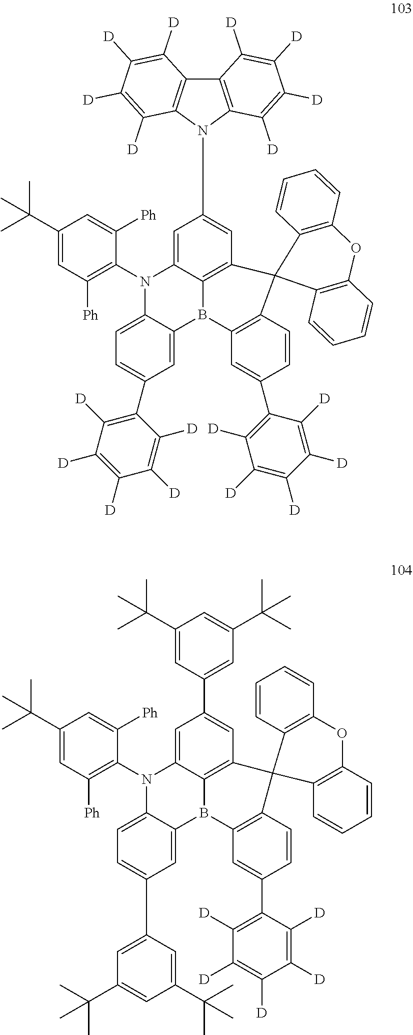 [SMILES: [2H]c1c([2H])c([2H])c(-c2ccc3c(c2)B2c4cc(-c5c([2H])c([2H])c([2H])c([2H])c5[2H])ccc4C4(c5ccccc5Oc5ccccc54)c4cc(-n5c6c([2H])c([2H])c([2H])c([2H])c6c6c([2H])c([2H])c([2H])c([2H])c65)cc(c42)N3c2c(-c3ccccc3)cc(C(C)(C)C)cc2-c2ccccc2)c([2H])c1[2H] ; [2H]c1c([2H])c([2H])c(-c2ccc3c(c2)B2c4cc(-c5cc(C(C)(C)C)cc(C(C)(C)C)c5)ccc4N(c4c(-c5ccccc5)cc(C(C)(C)C)cc4-c4ccccc4)c4cc(-c5cc(C(C)(C)C)cc(C(C)(C)C)c5)cc(c42)C32c3ccccc3Oc3ccccc32)c([2H])c1[2H]]

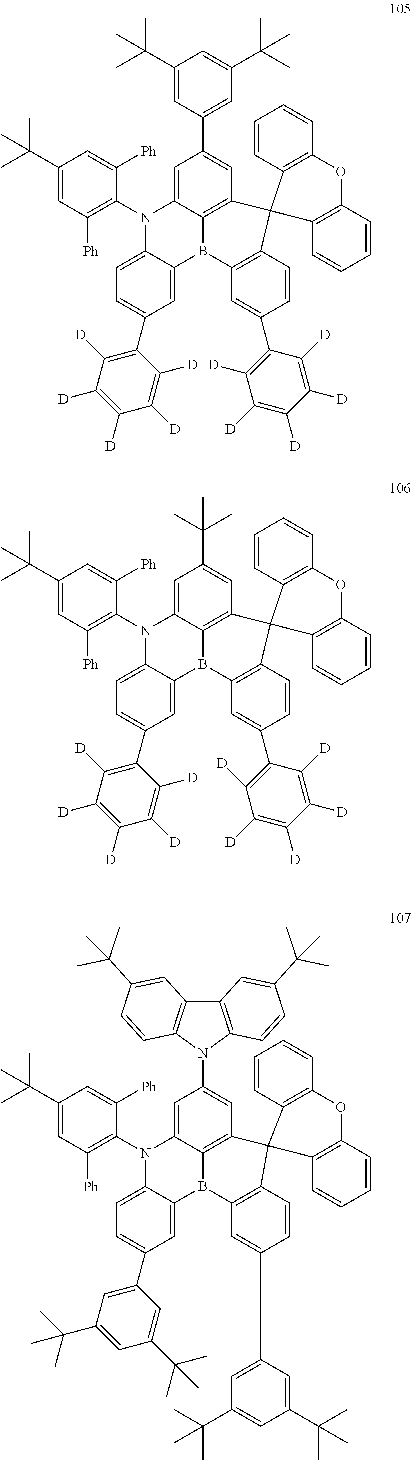

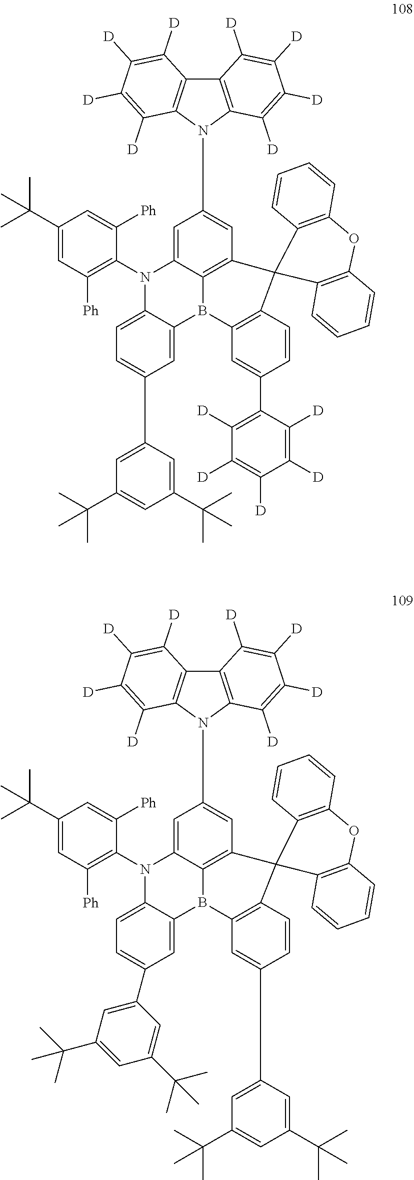 [SMILES: [2H]c1c([2H])c([2H])c(-c2ccc3c(c2)B2c4cc(-c5cc(C(C)(C)C)cc(C(C)(C)C)c5)ccc4N(c4c(-c5ccccc5)cc(C(C)(C)C)cc4-c4ccccc4)c4cc(-n5c6c([2H])c([2H])c([2H])c([2H])c6c6c([2H])c([2H])c([2H])c([2H])c65)cc(c42)C32c3ccccc3Oc3ccccc32)c([2H])c1[2H] ; [2H]c1c([2H])c([2H])c2c(c1[2H])c1c([2H])c([2H])c([2H])c([2H])c1n2-c1cc2c3c(c1)C1(c4ccccc4Oc4ccccc41)c1ccc(-c4cc(C(C)(C)C)cc(C(C)(C)C)c4)cc1B3c1cc(-c3cc(C(C)(C)C)cc(C(C)(C)C)c3)ccc1N2c1c(-c2ccccc2)cc(C(C)(C)C)cc1-c1ccccc1]

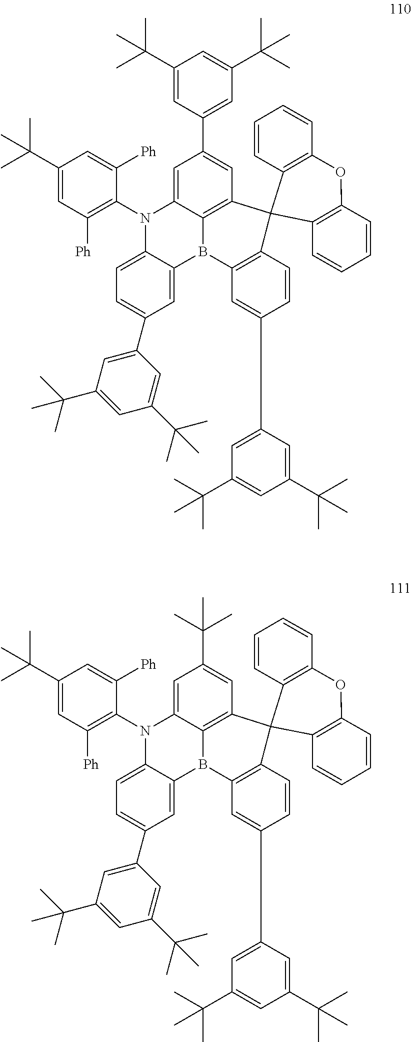 [SMILES: CC(C)(C)c1cc(-c2ccc3c(c2)B2c4cc(-c5cc(C(C)(C)C)cc(C(C)(C)C)c5)ccc4C4(c5ccccc5Oc5ccccc54)c4cc(-c5cc(C(C)(C)C)cc(C(C)(C)C)c5)cc(c42)N3c2c(-c3ccccc3)cc(C(C)(C)C)cc2-c2ccccc2)cc(C(C)(C)C)c1 ; CC(C)(C)c1cc(-c2ccc3c(c2)B2c4cc(-c5cc(C(C)(C)C)cc(C(C)(C)C)c5)ccc4C4(c5ccccc5Oc5ccccc54)c4cc(C(C)(C)C)cc(c42)N3c2c(-c3ccccc3)cc(C(C)(C)C)cc2-c2ccccc2)cc(C(C)(C)C)c1]

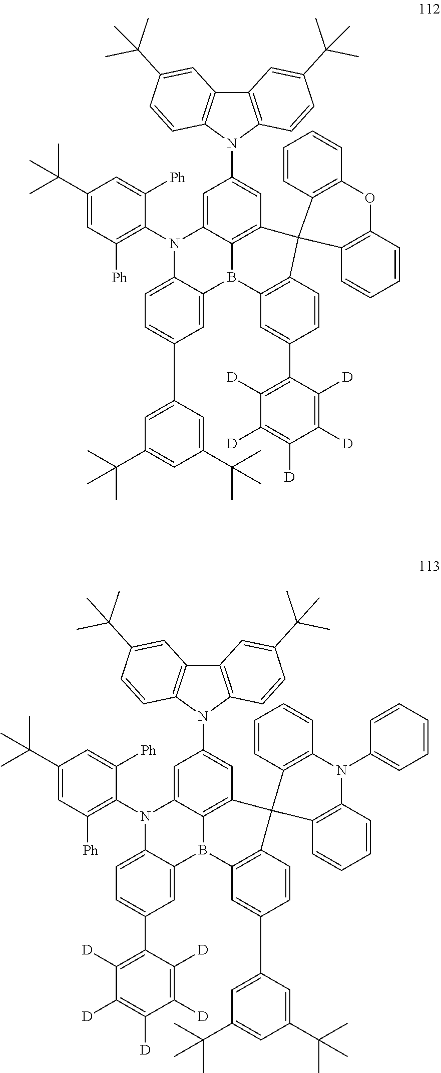 [SMILES: [2H]c1c([2H])c([2H])c(-c2ccc3c(c2)B2c4cc(-c5cc(C(C)(C)C)cc(C(C)(C)C)c5)ccc4N(c4c(-c5ccccc5)cc(C(C)(C)C)cc4-c4ccccc4)c4cc(-n5c6ccc(C(C)(C)C)cc6c6cc(C(C)(C)C)ccc65)cc(c42)C32c3ccccc3Oc3ccccc32)c([2H])c1[2H] ; [2H]c1c([2H])c([2H])c(-c2ccc3c(c2)B2c4cc(-c5cc(C(C)(C)C)cc(C(C)(C)C)c5)ccc4C4(c5ccccc5N(c5ccccc5)c5ccccc54)c4cc(-n5c6ccc(C(C)(C)C)cc6c6cc(C(C)(C)C)ccc65)cc(c42)N3c2c(-c3ccccc3)cc(C(C)(C)C)cc2-c2ccccc2)c([2H])c1[2H]]

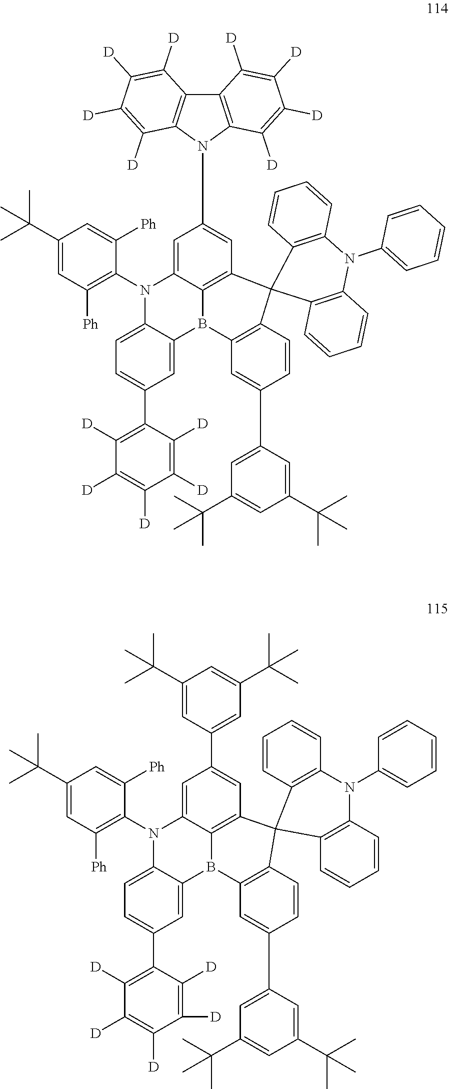 [SMILES: [2H]c1c([2H])c([2H])c(-c2ccc3c(c2)B2c4cc(-c5cc(C(C)(C)C)cc(C(C)(C)C)c5)ccc4C4(c5ccccc5N(c5ccccc5)c5ccccc54)c4cc(-n5c6c([2H])c([2H])c([2H])c([2H])c6c6c([2H])c([2H])c([2H])c([2H])c65)cc(c42)N3c2c(-c3ccccc3)cc(C(C)(C)C)cc2-c2ccccc2)c([2H])c1[2H] ; [2H]c1c([2H])c([2H])c(-c2ccc3c(c2)B2c4cc(-c5cc(C(C)(C)C)cc(C(C)(C)C)c5)ccc4C4(c5ccccc5N(c5ccccc5)c5ccccc54)c4cc(-c5cc(C(C)(C)C)cc(C(C)(C)C)c5)cc(c42)N3c2c(-c3ccccc3)cc(C(C)(C)C)cc2-c2ccccc2)c([2H])c1[2H]]

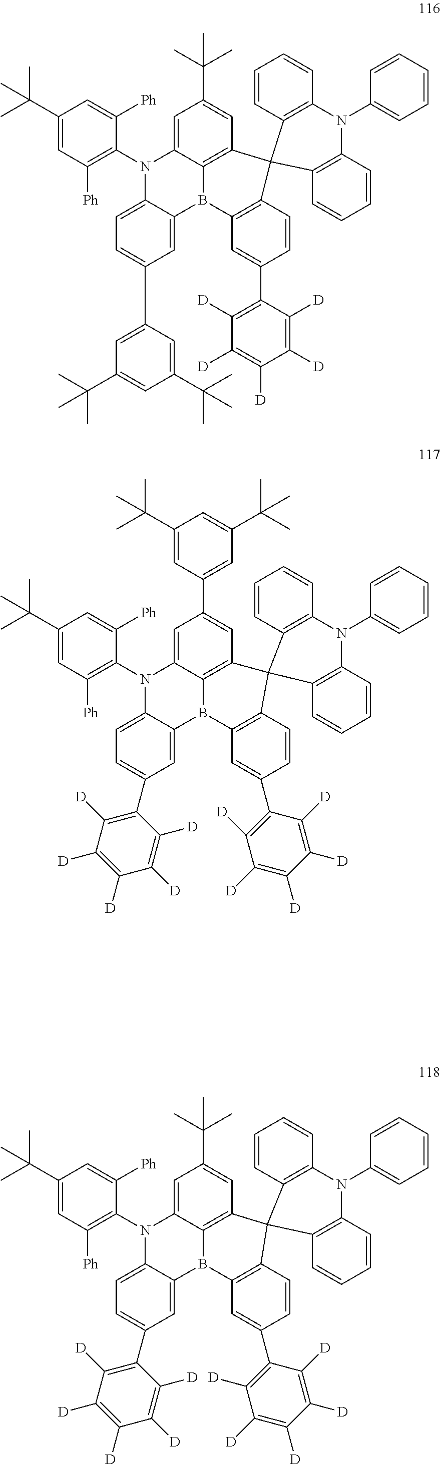

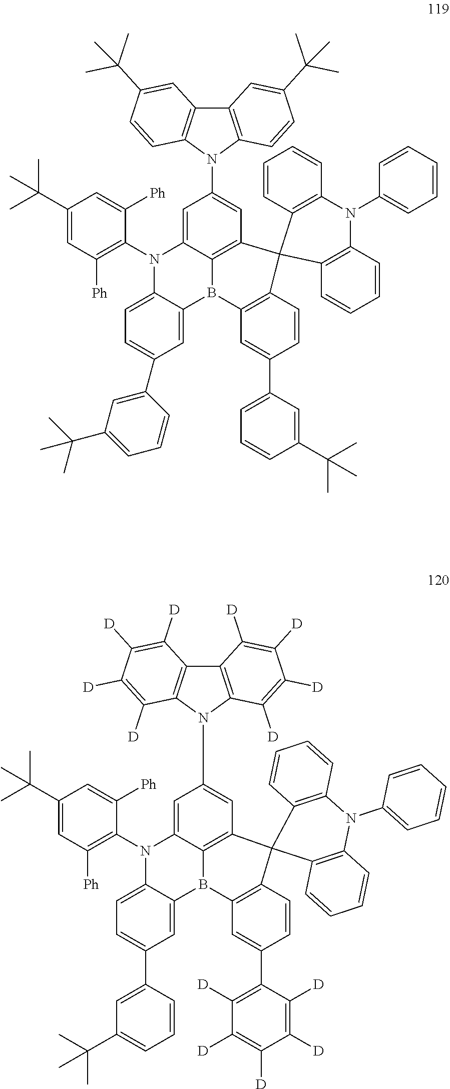 [SMILES: CC(C)(C)c1cccc(-c2ccc3c(c2)B2c4cc(-c5cccc(C(C)(C)C)c5)ccc4C4(c5ccccc5N(c5ccccc5)c5ccccc54)c4cc(-n5c6ccc(C(C)(C)C)cc6c6cc(C(C)(C)C)ccc65)cc(c42)N3c2c(-c3ccccc3)cc(C(C)(C)C)cc2-c2ccccc2)c1 ; [2H]c1c([2H])c([2H])c(-c2ccc3c(c2)B2c4cc(-c5cccc(C(C)(C)C)c5)ccc4N(c4c(-c5ccccc5)cc(C(C)(C)C)cc4-c4ccccc4)c4cc(-n5c6c([2H])c([2H])c([2H])c([2H])c6c6c([2H])c([2H])c([2H])c([2H])c65)cc(c42)C32c3ccccc3N(c3ccccc3)c3ccccc32)c([2H])c1[2H]]

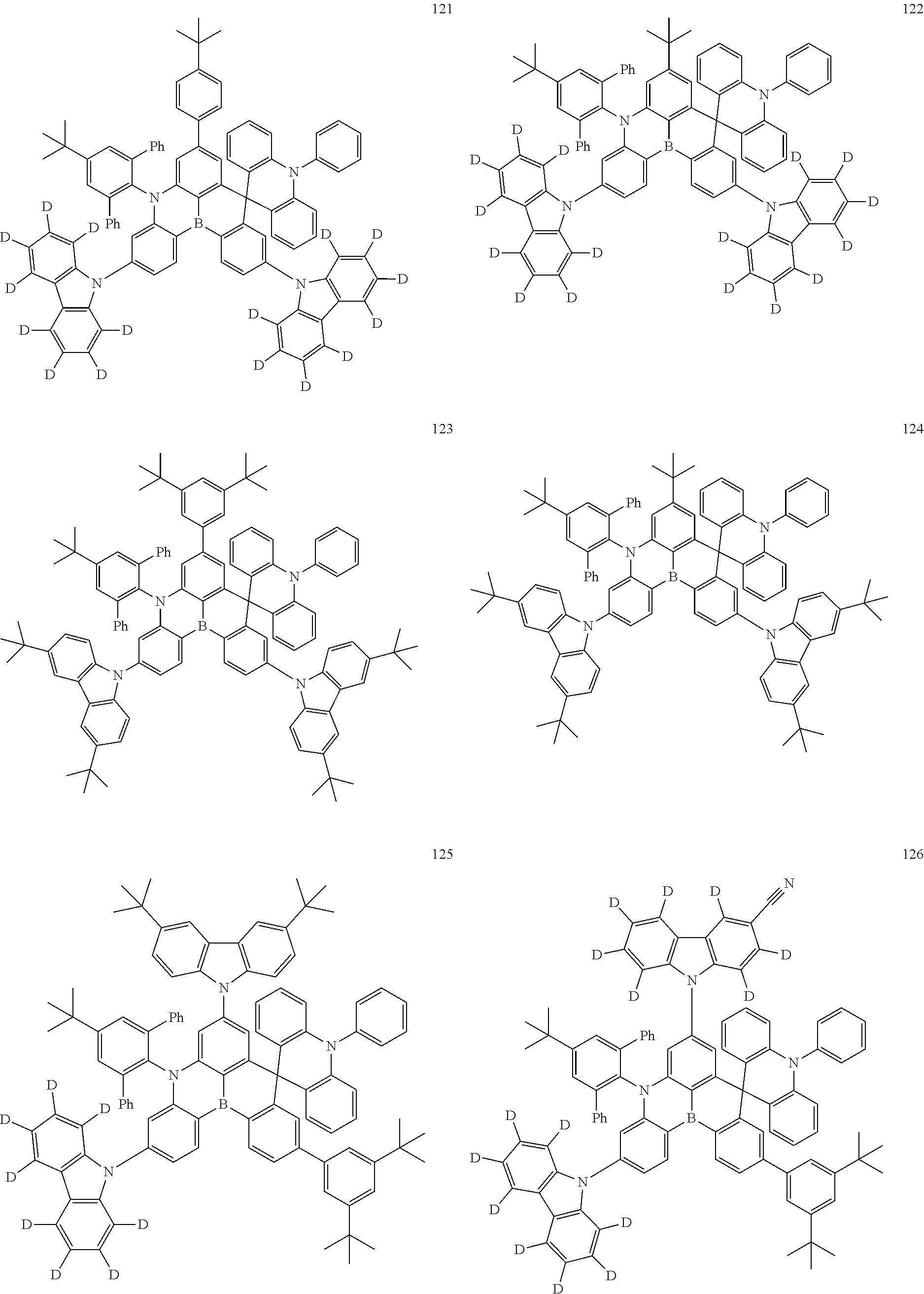

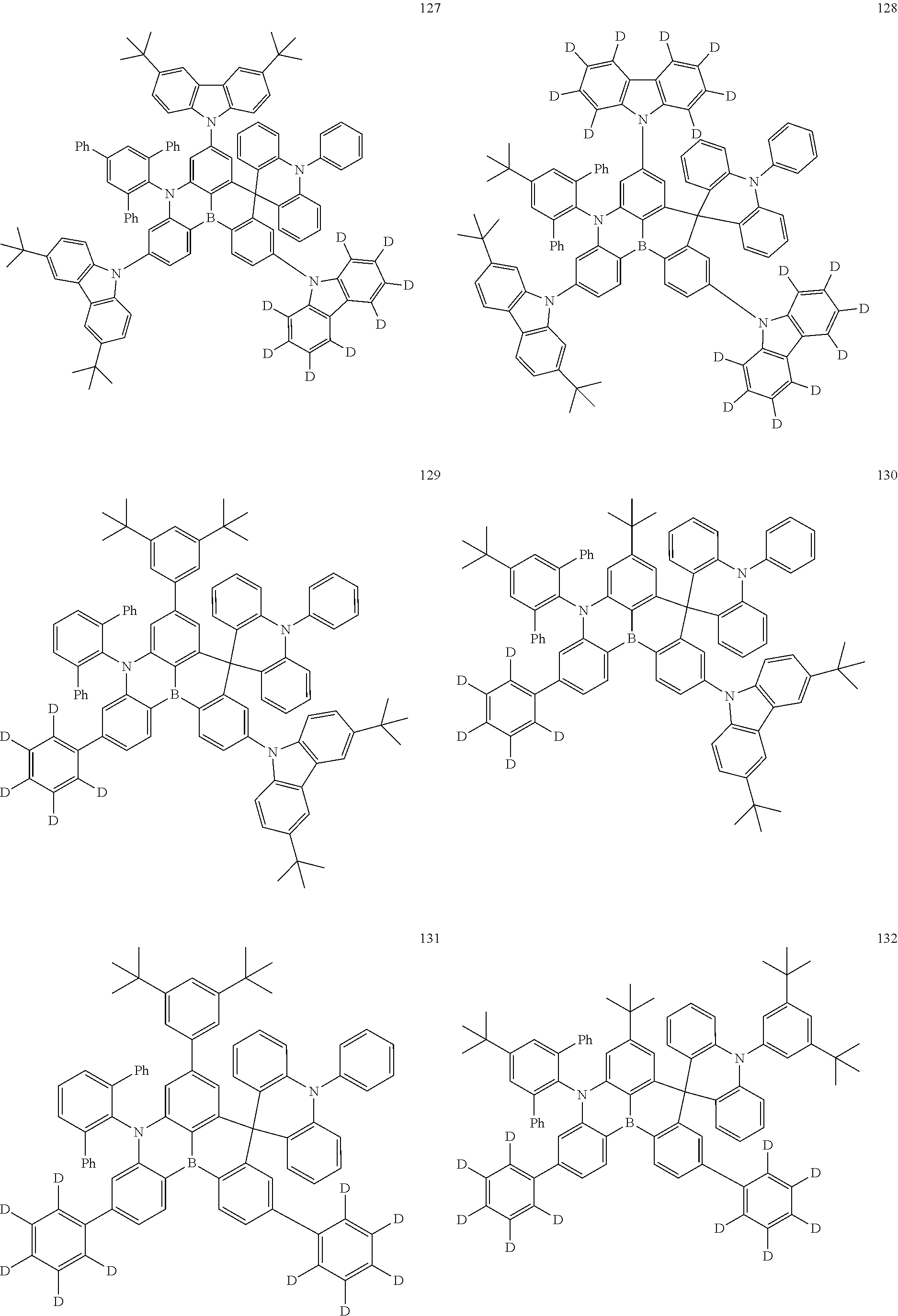

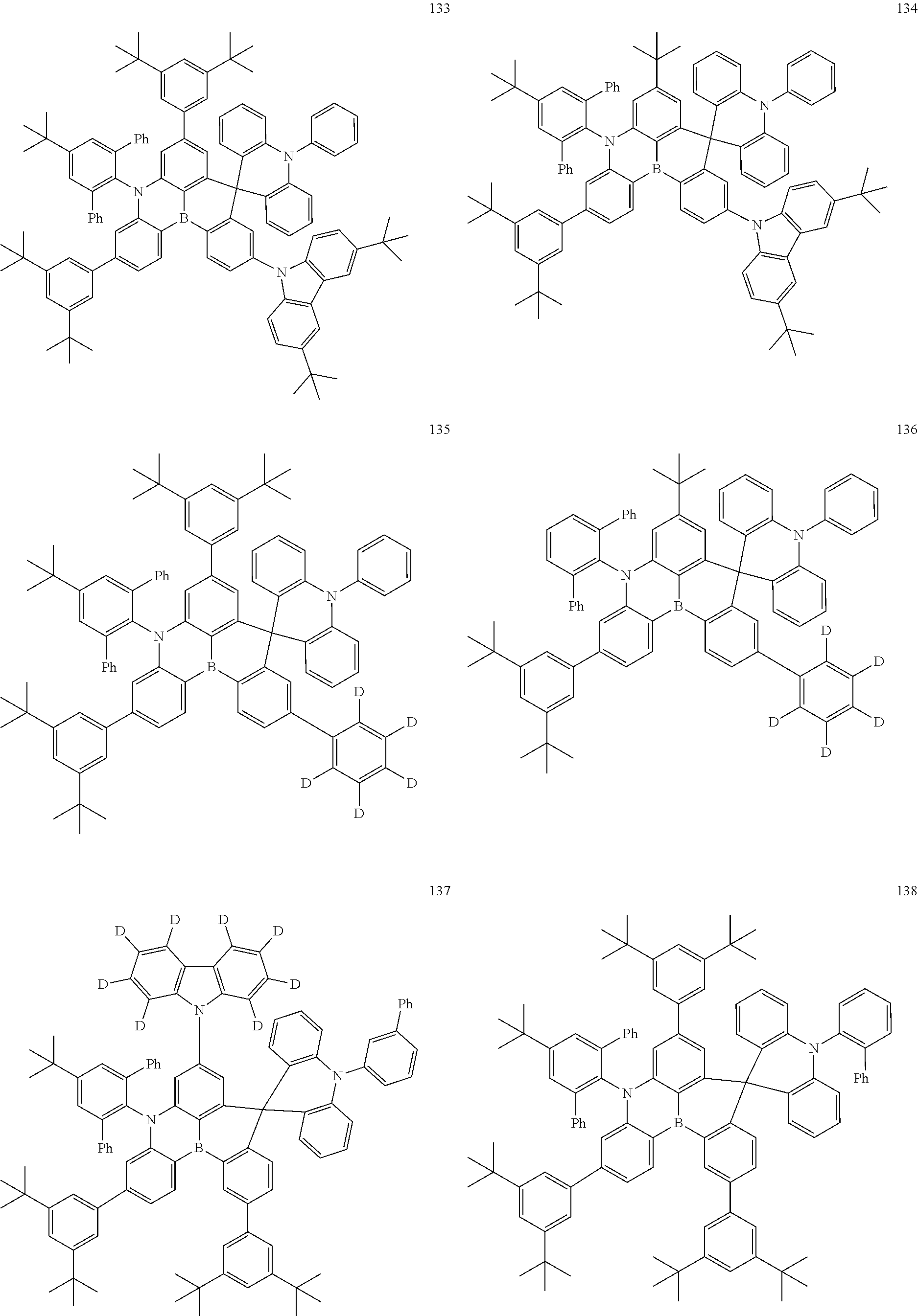

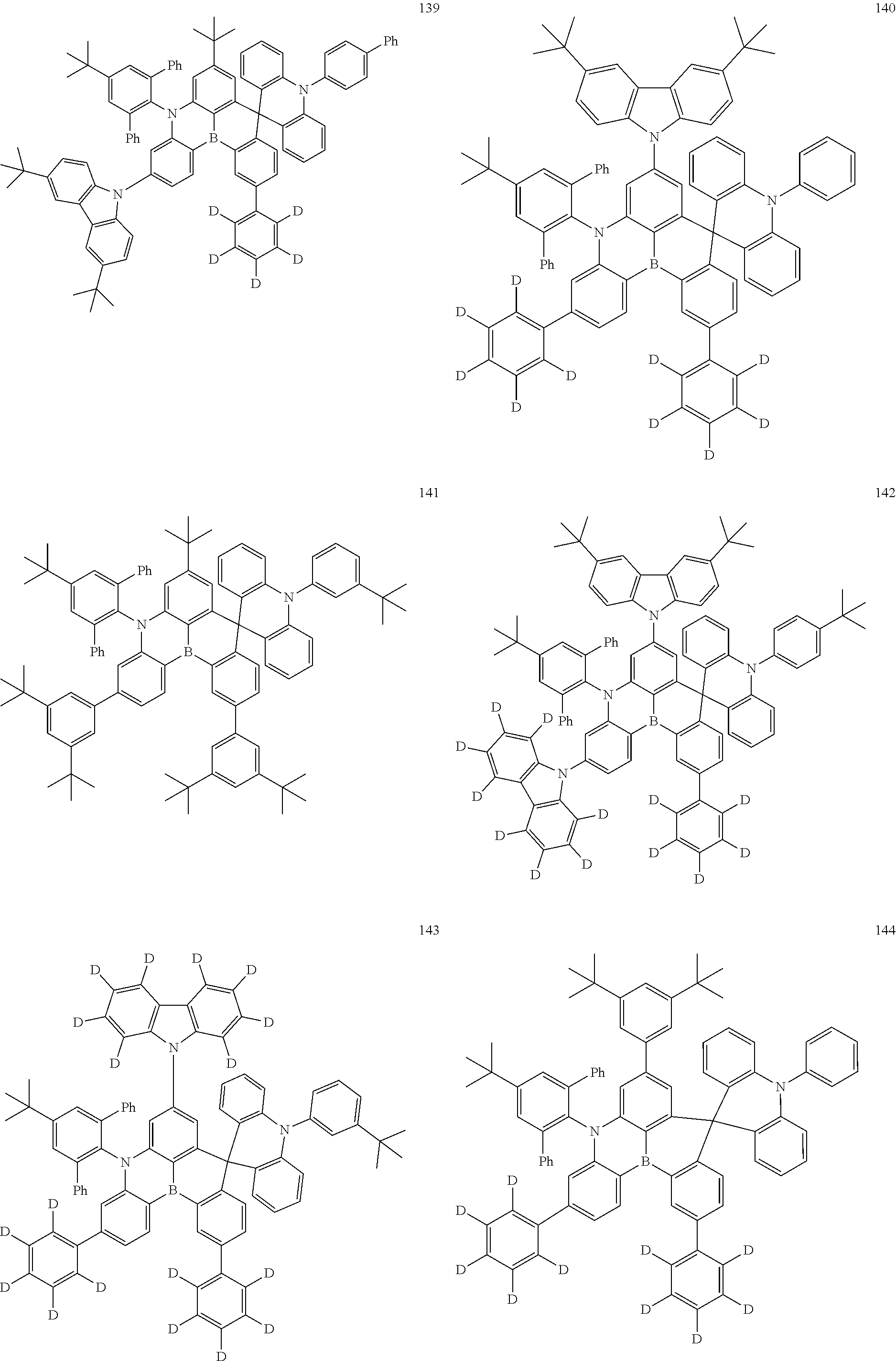

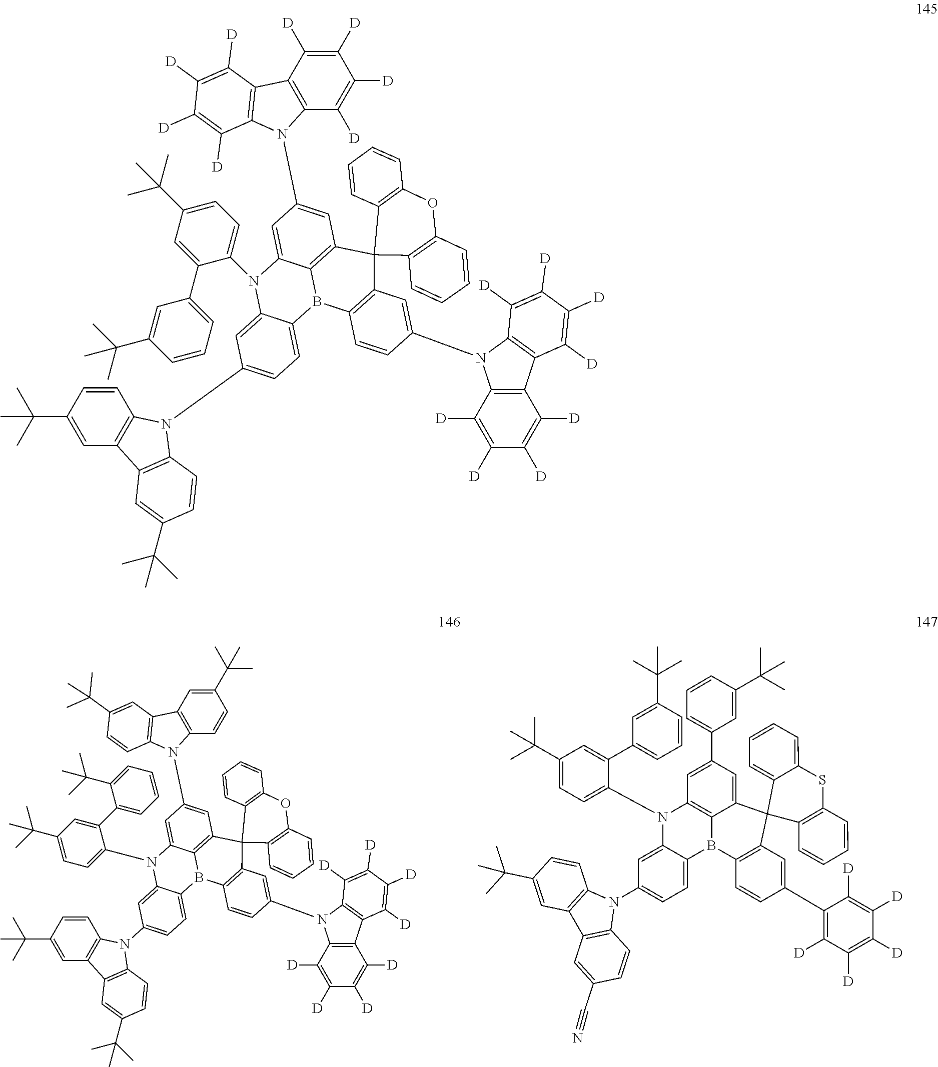

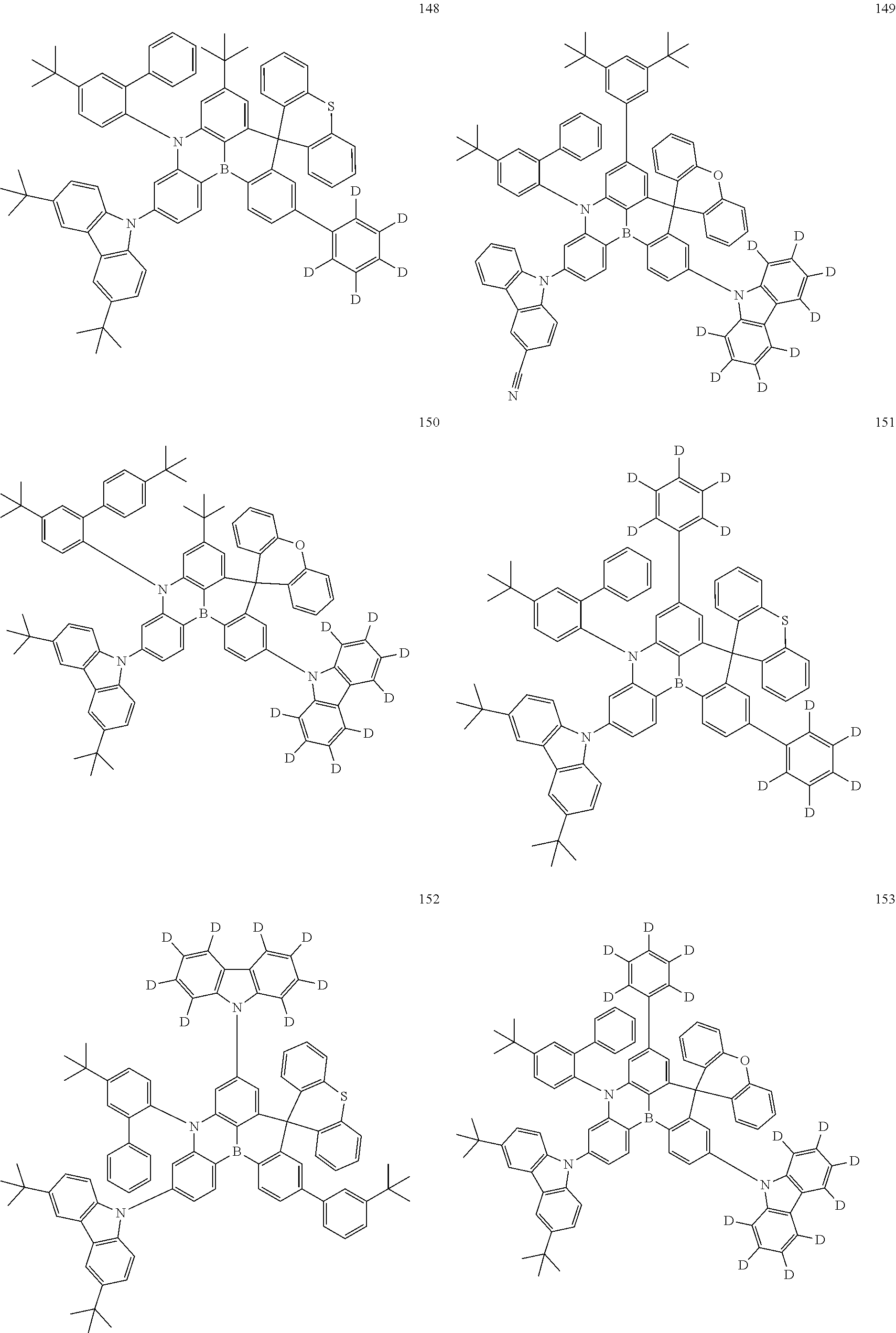

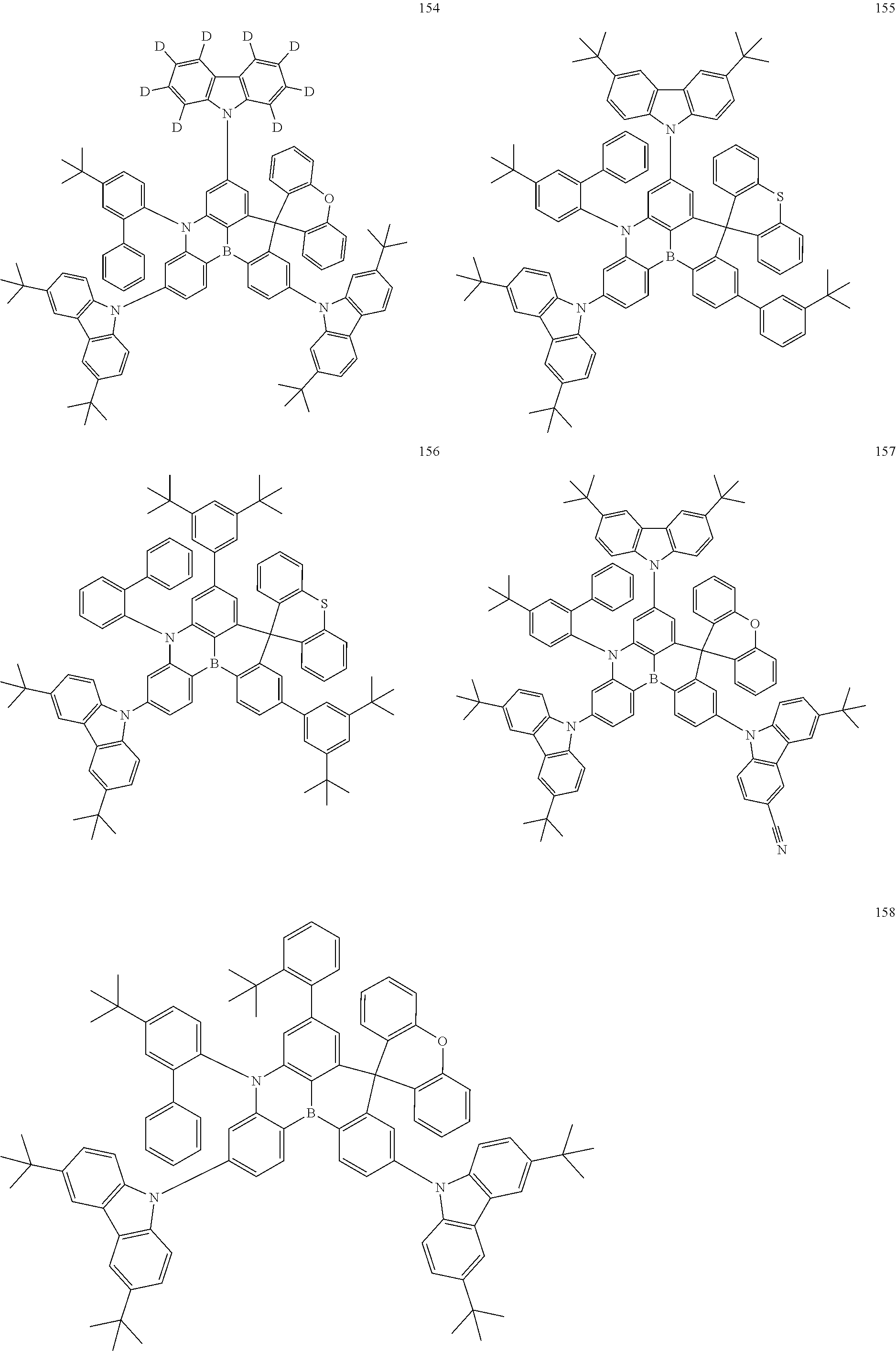

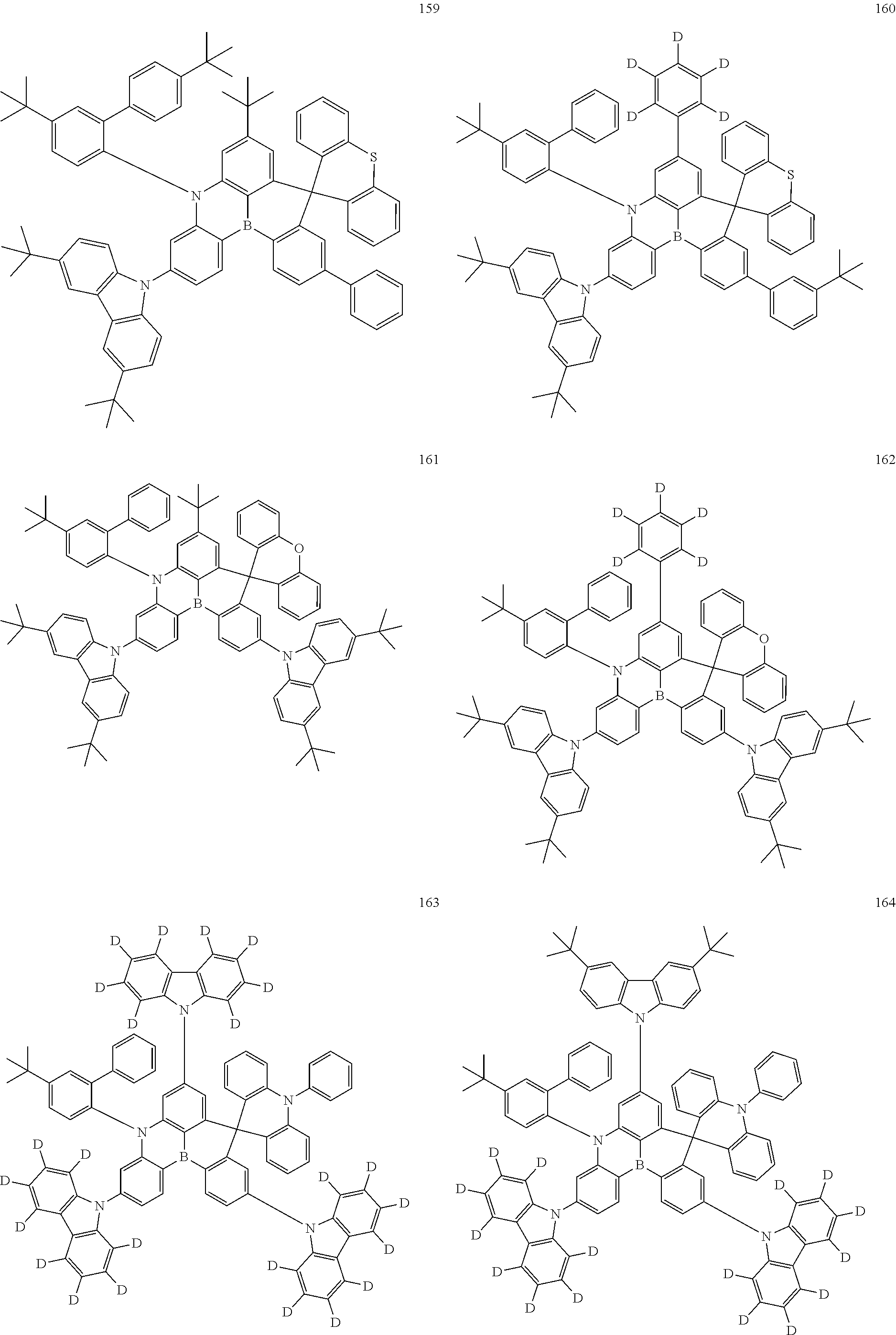

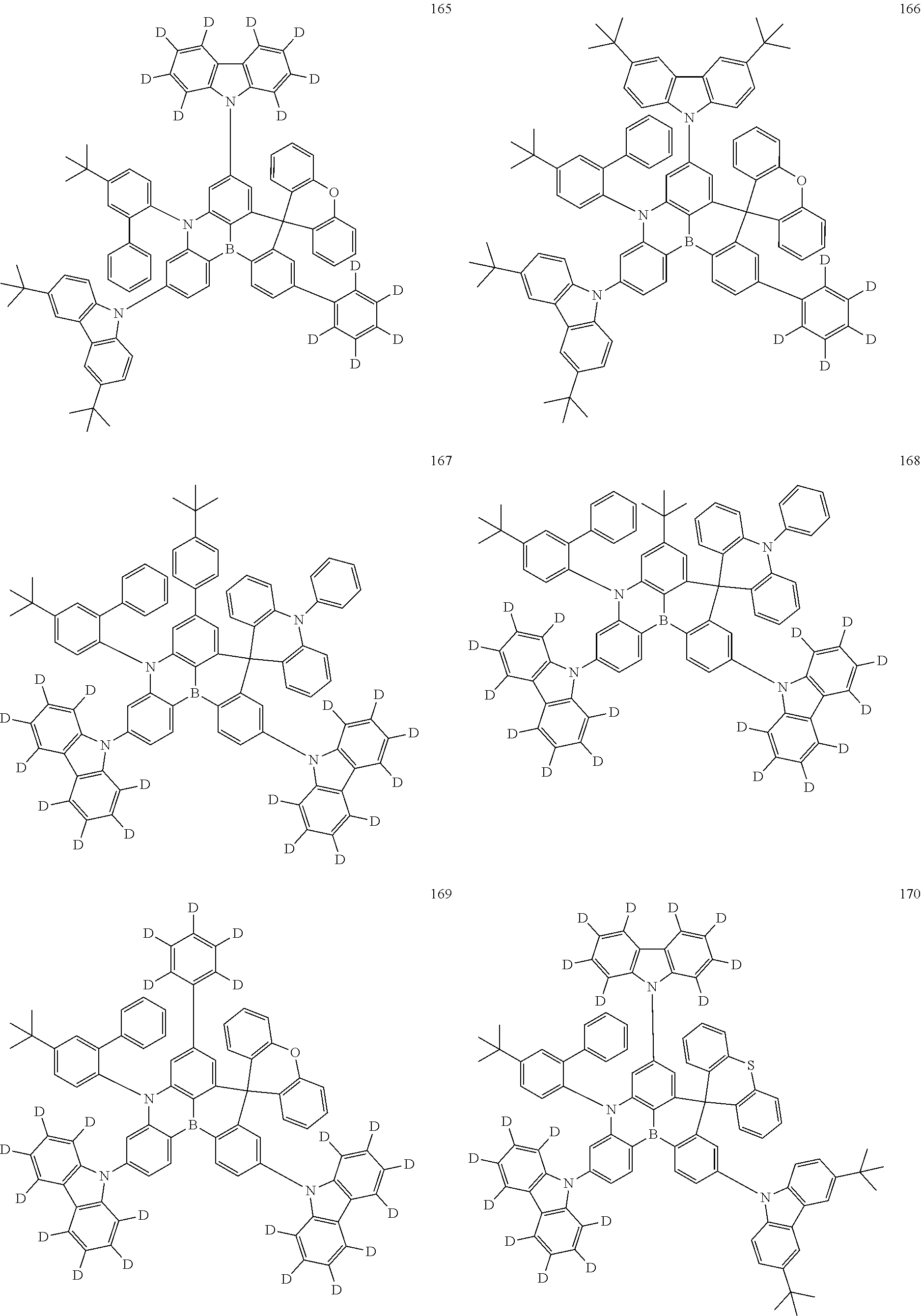

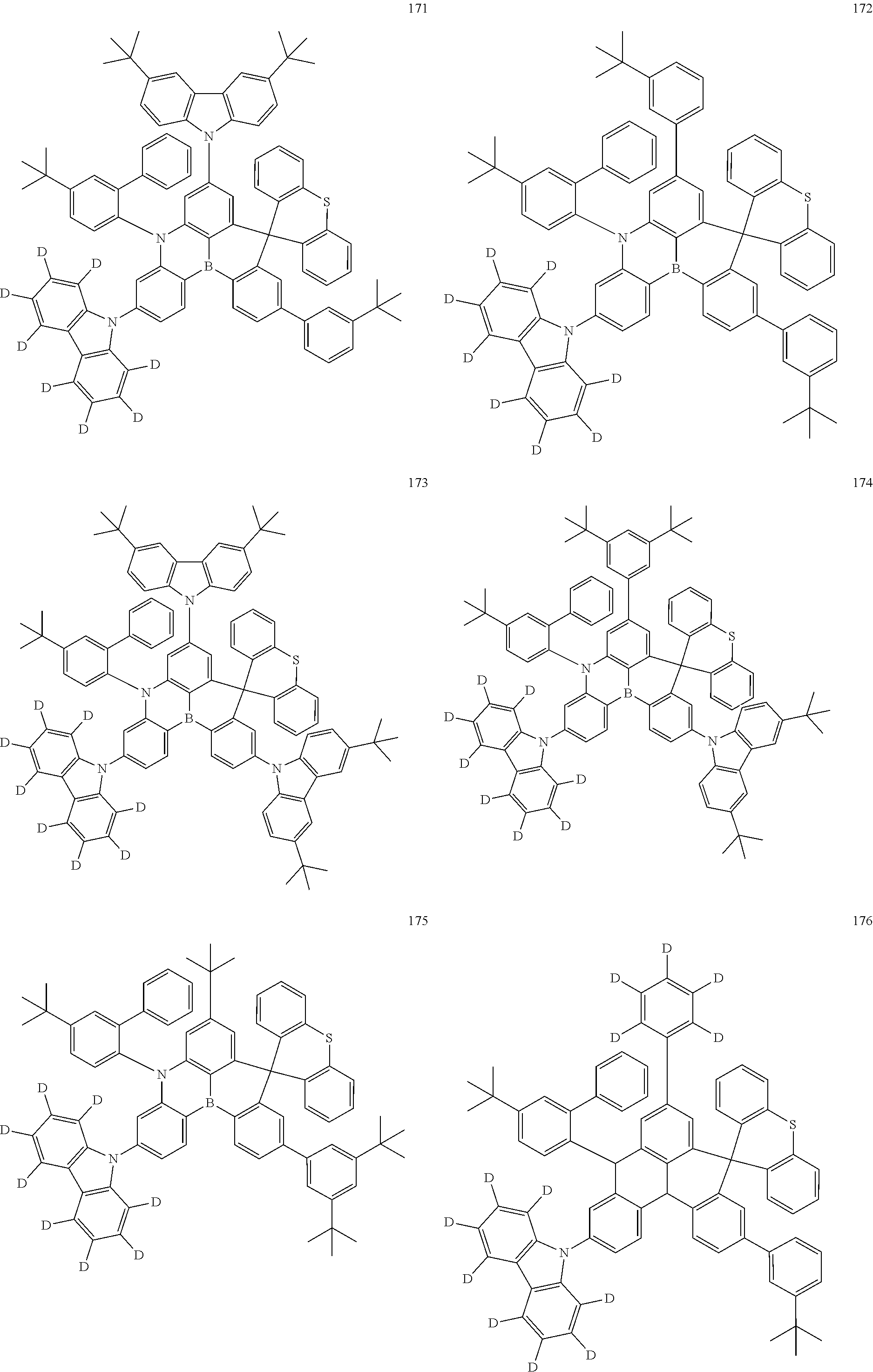

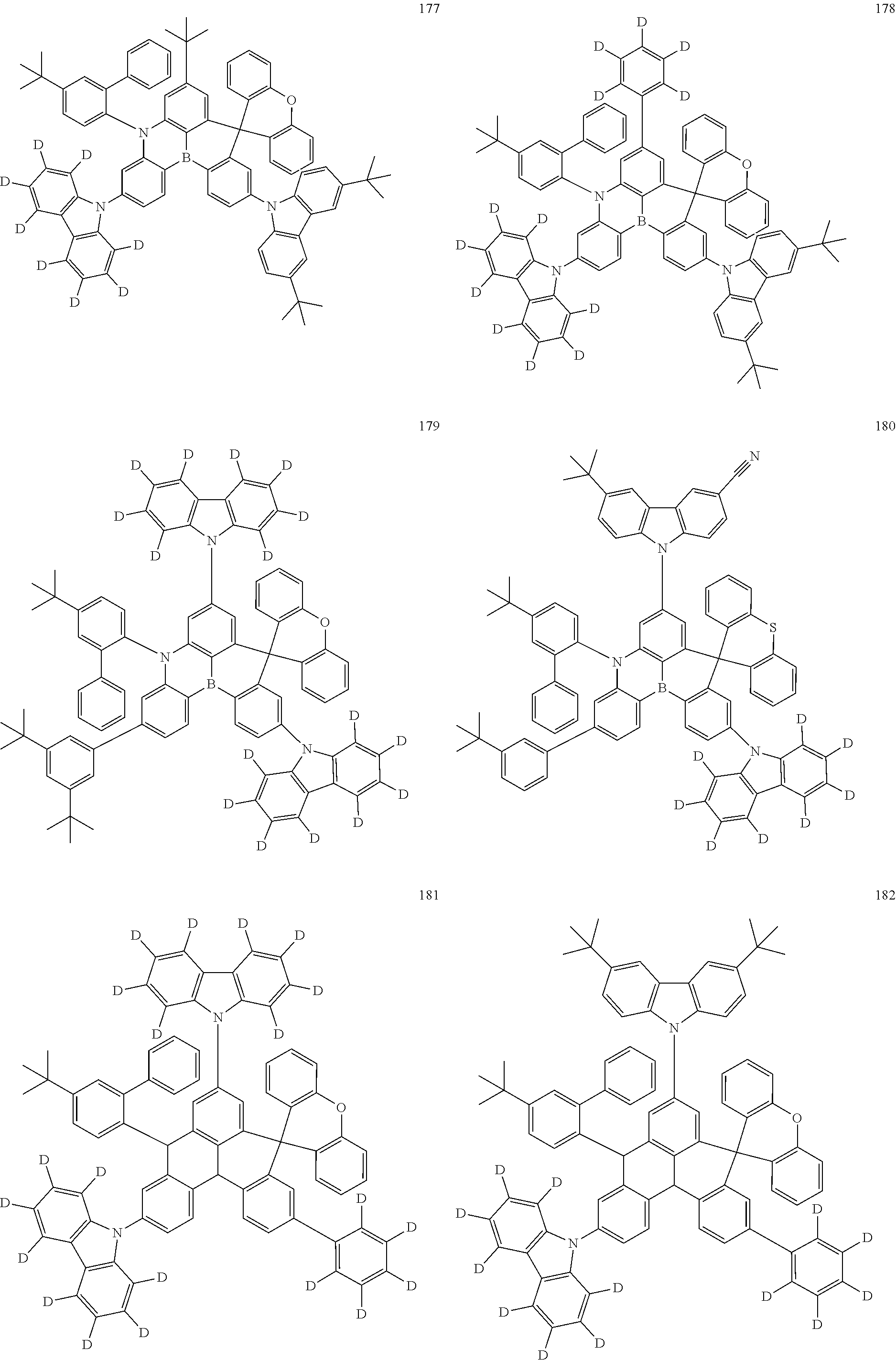

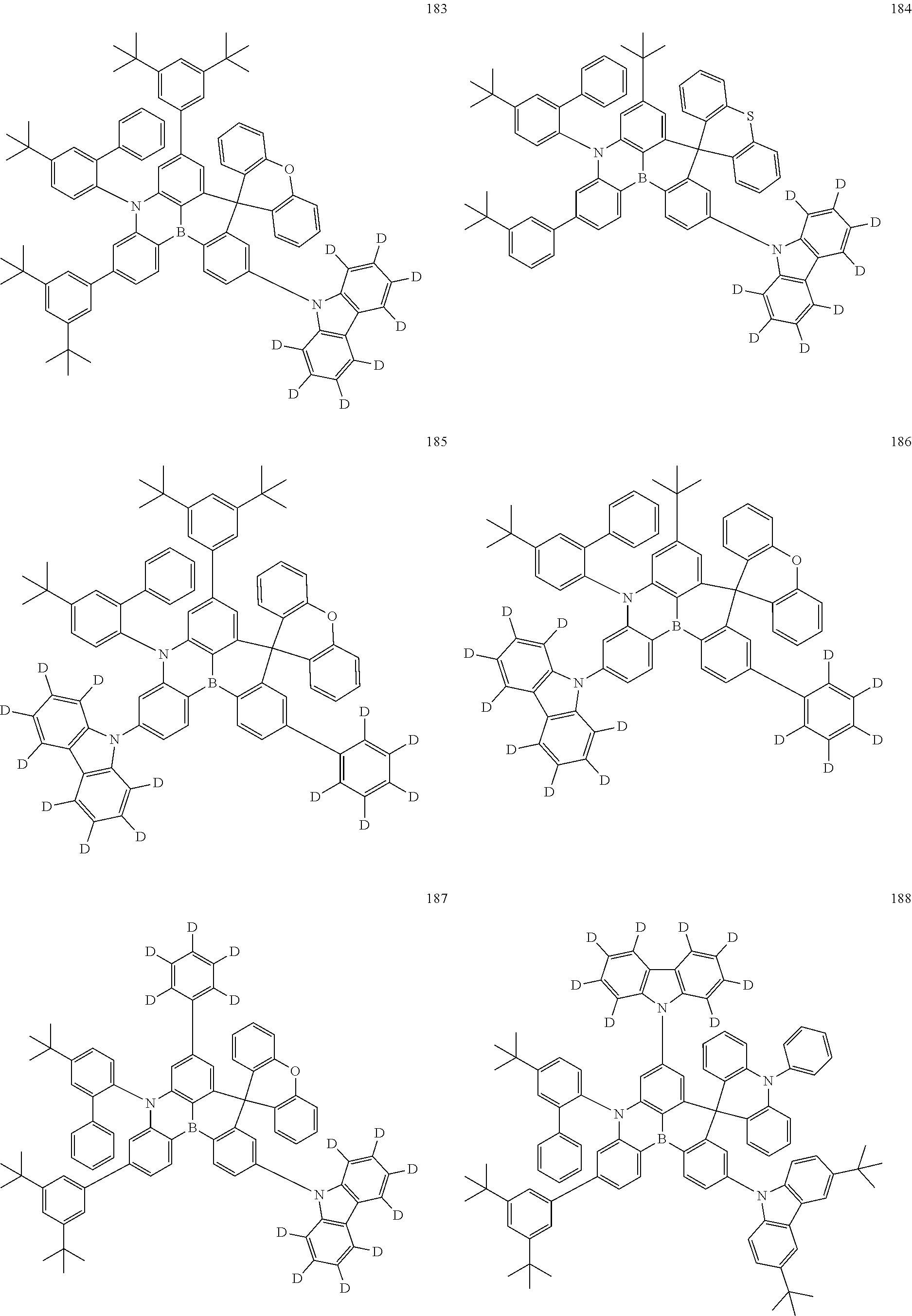

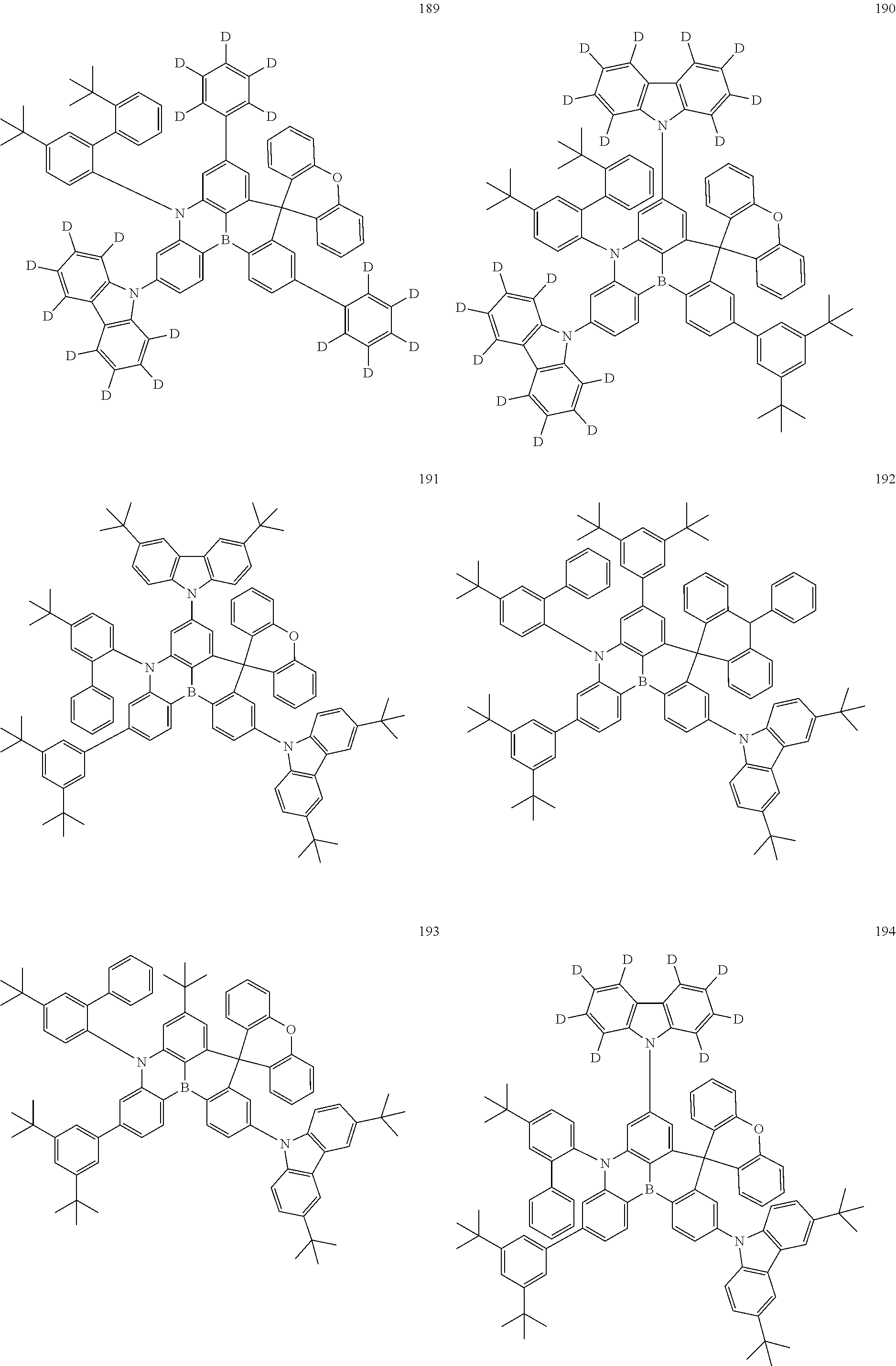

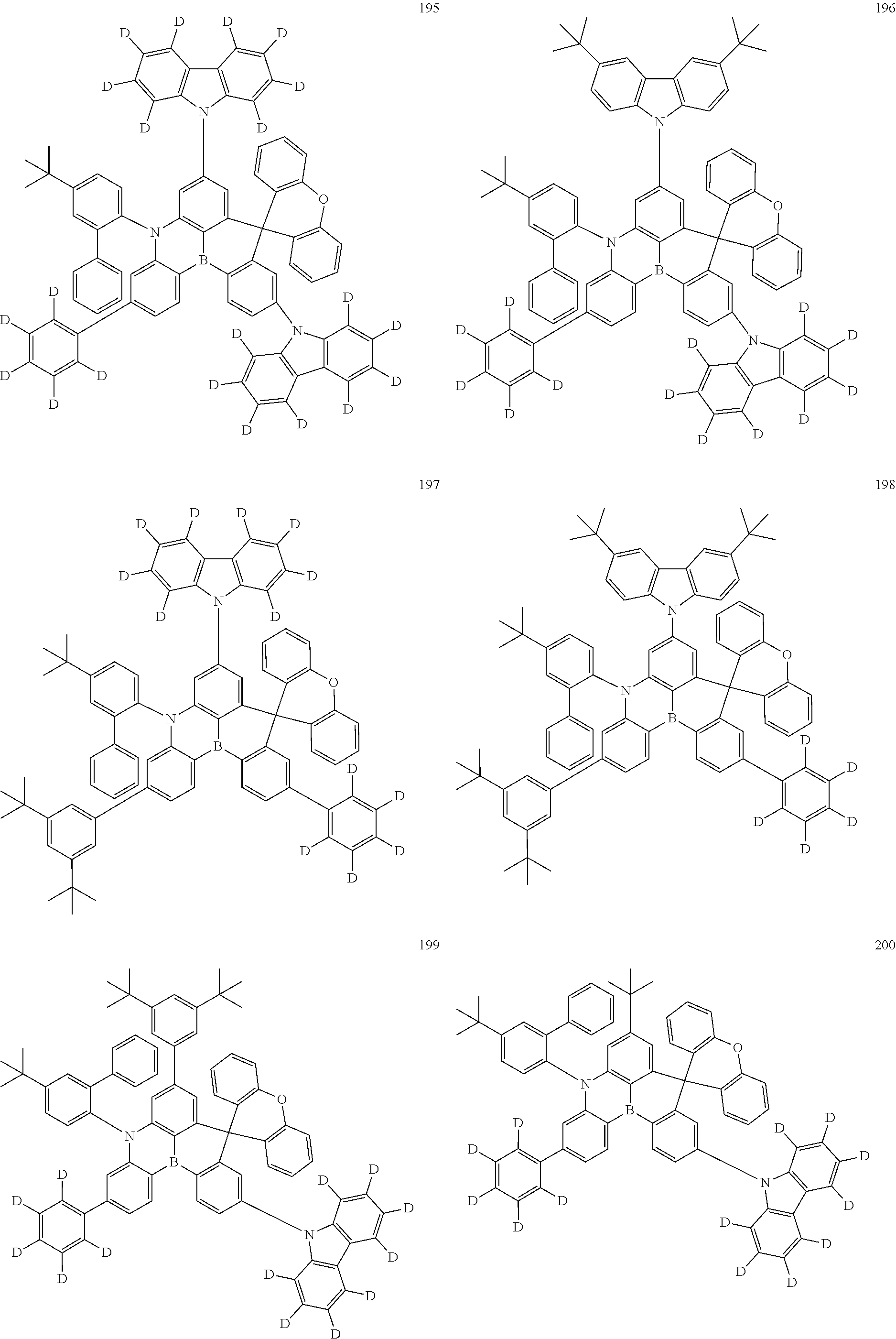

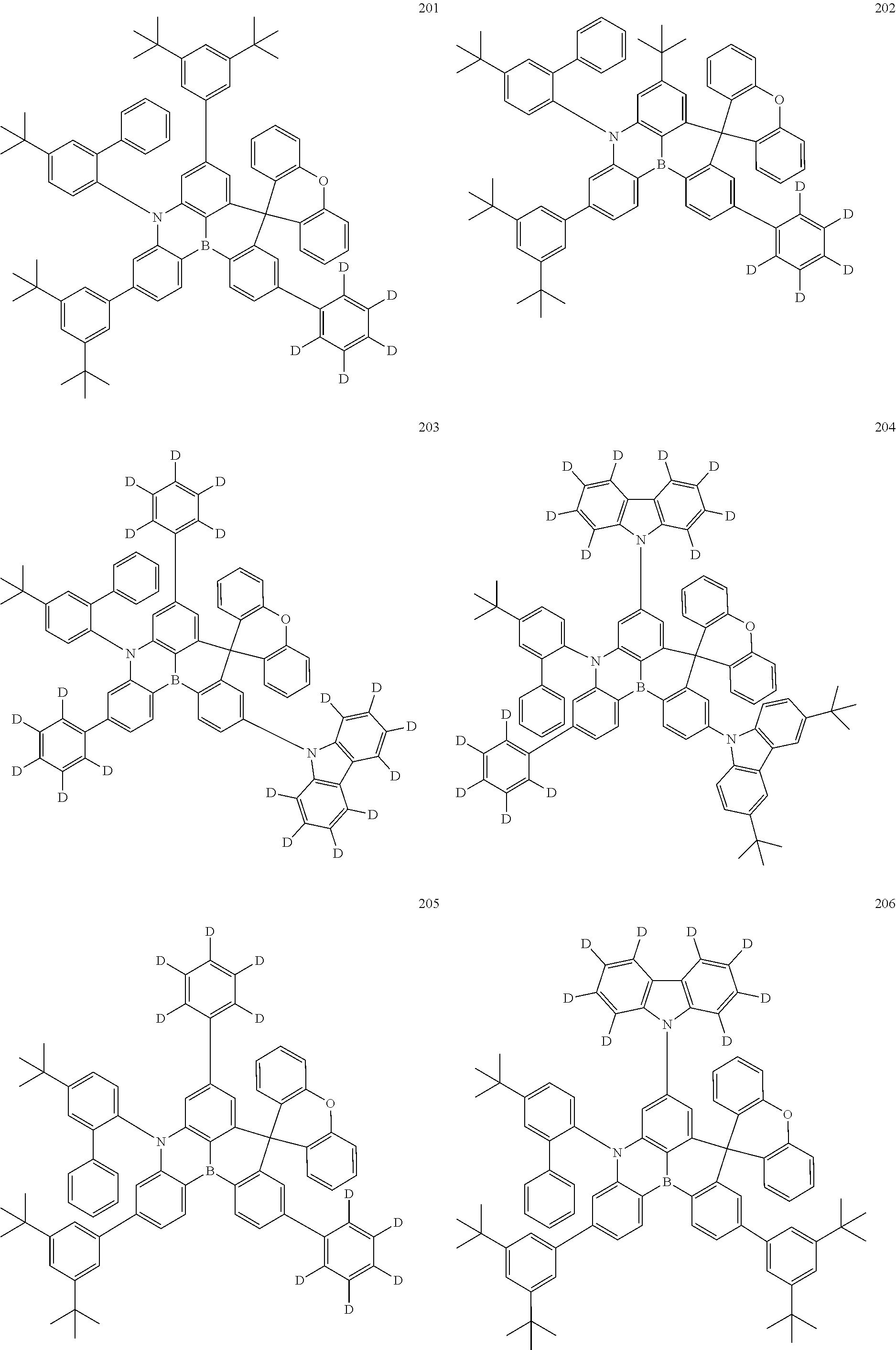

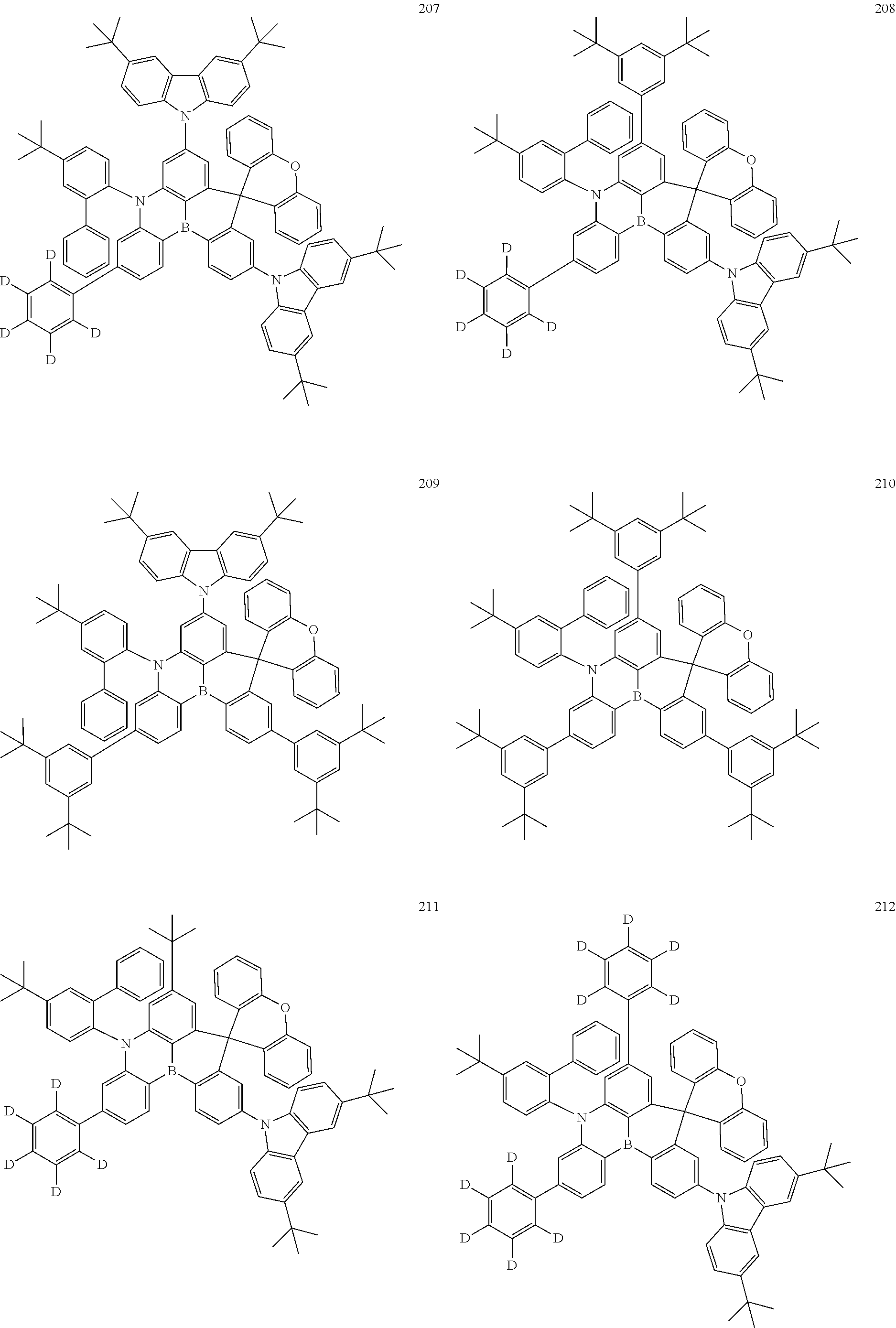

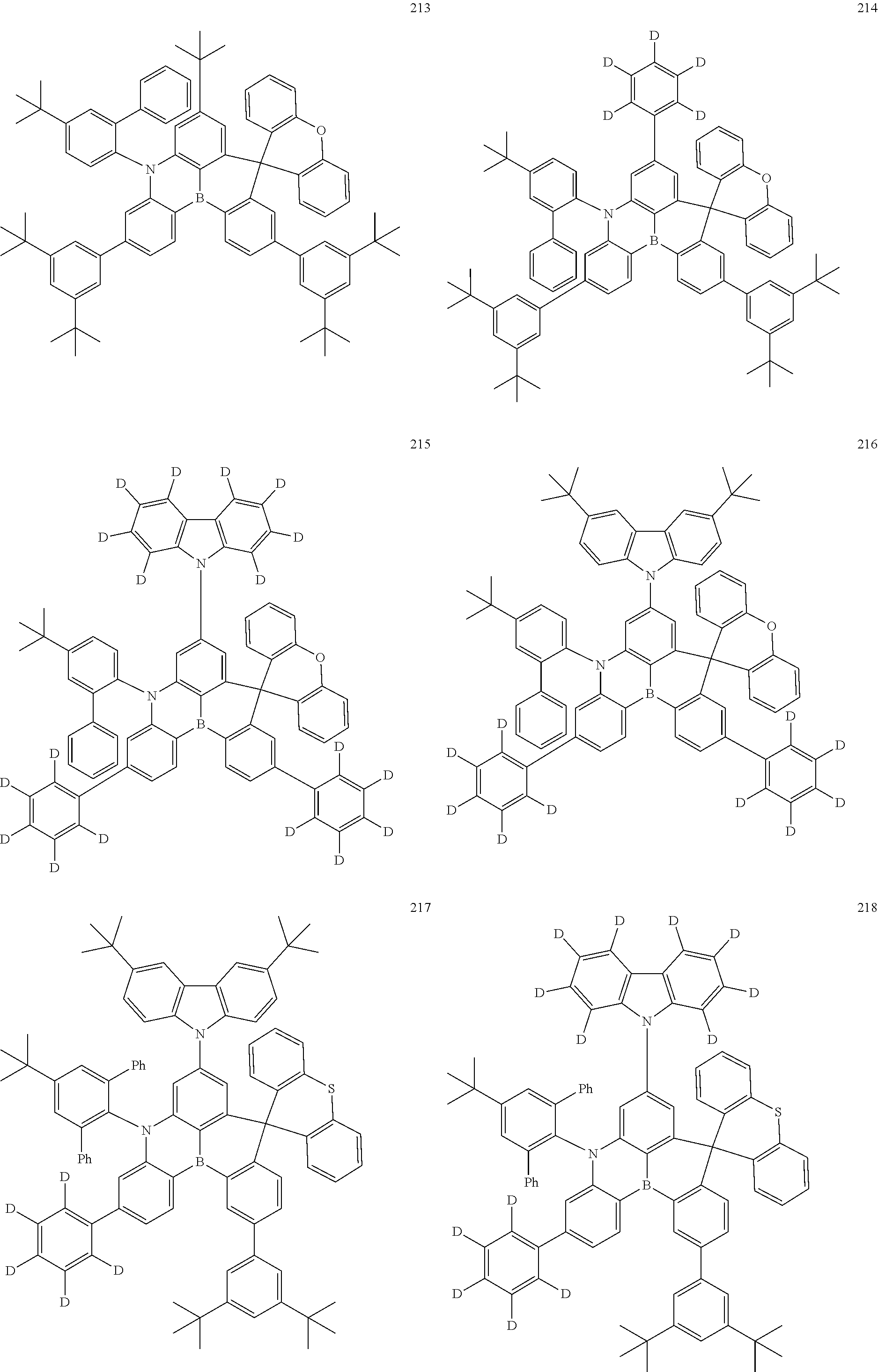

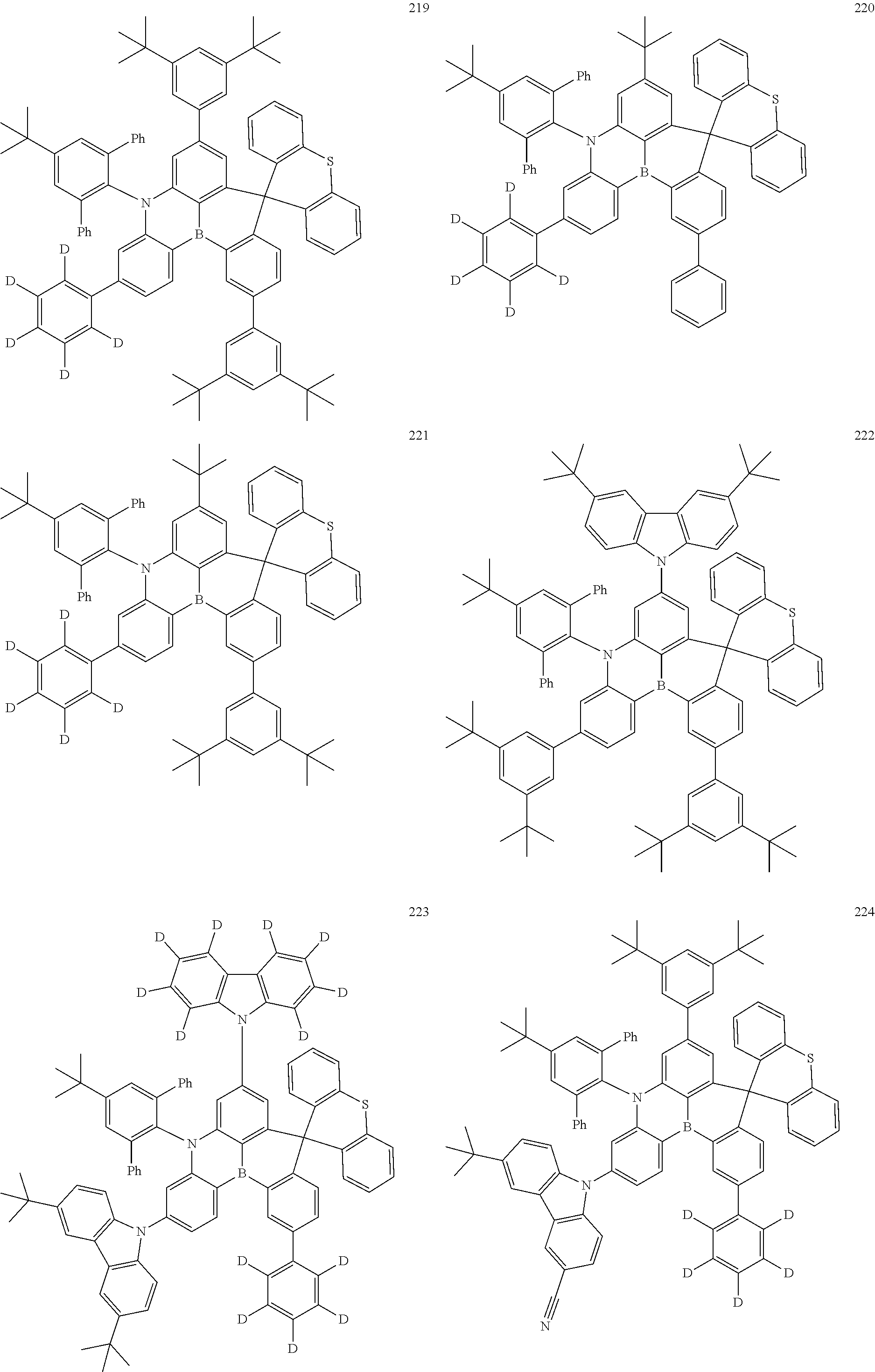

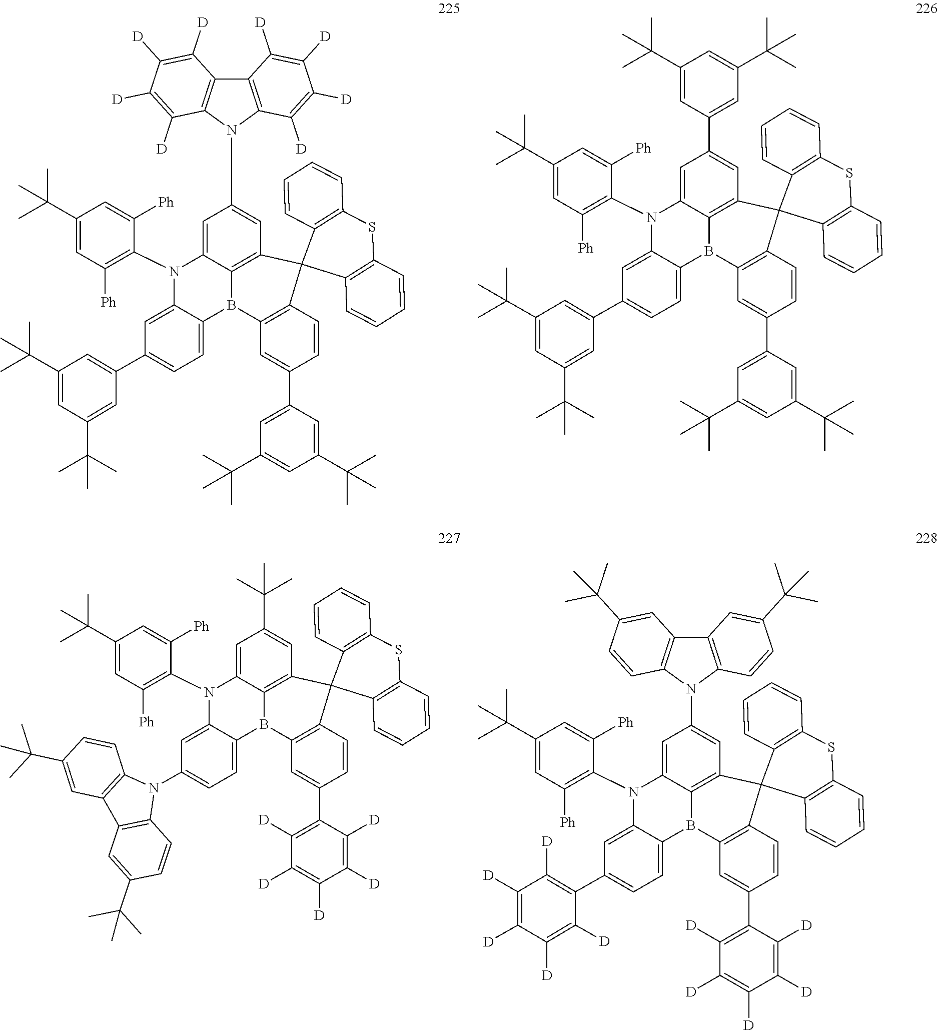

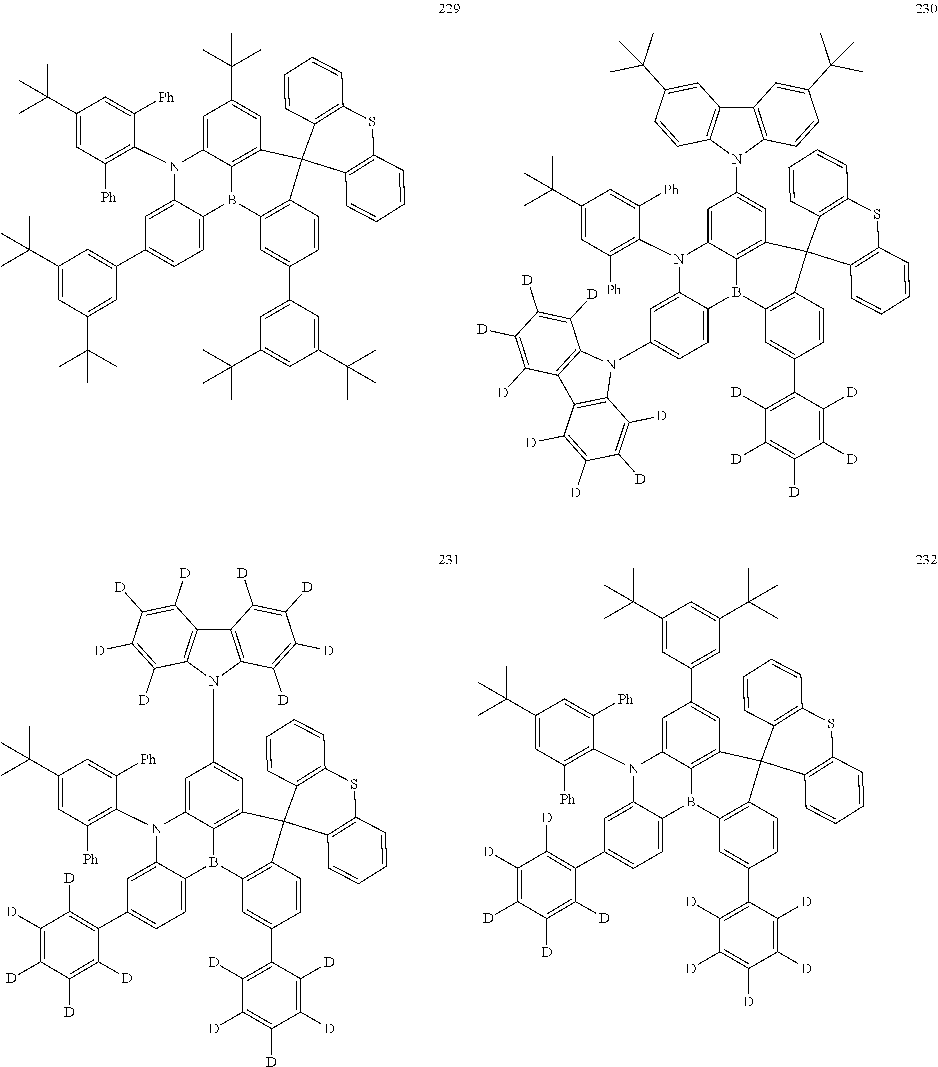

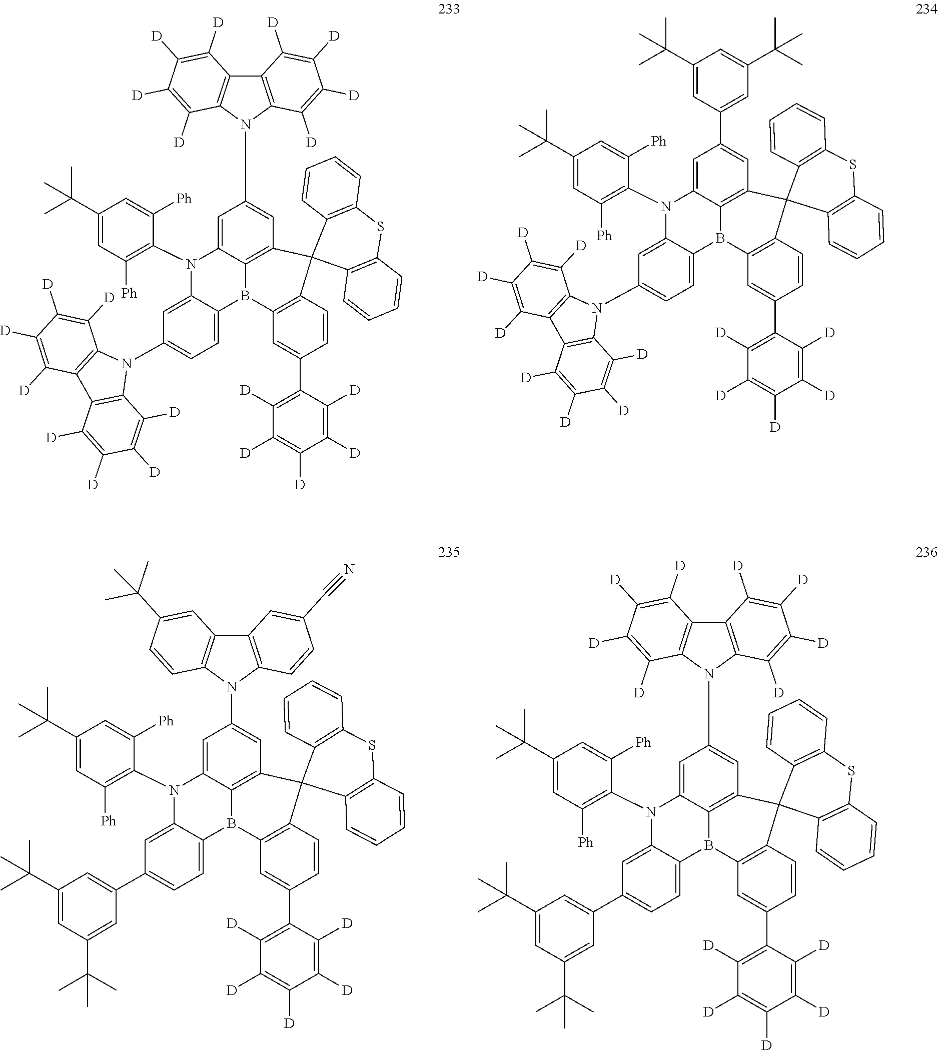

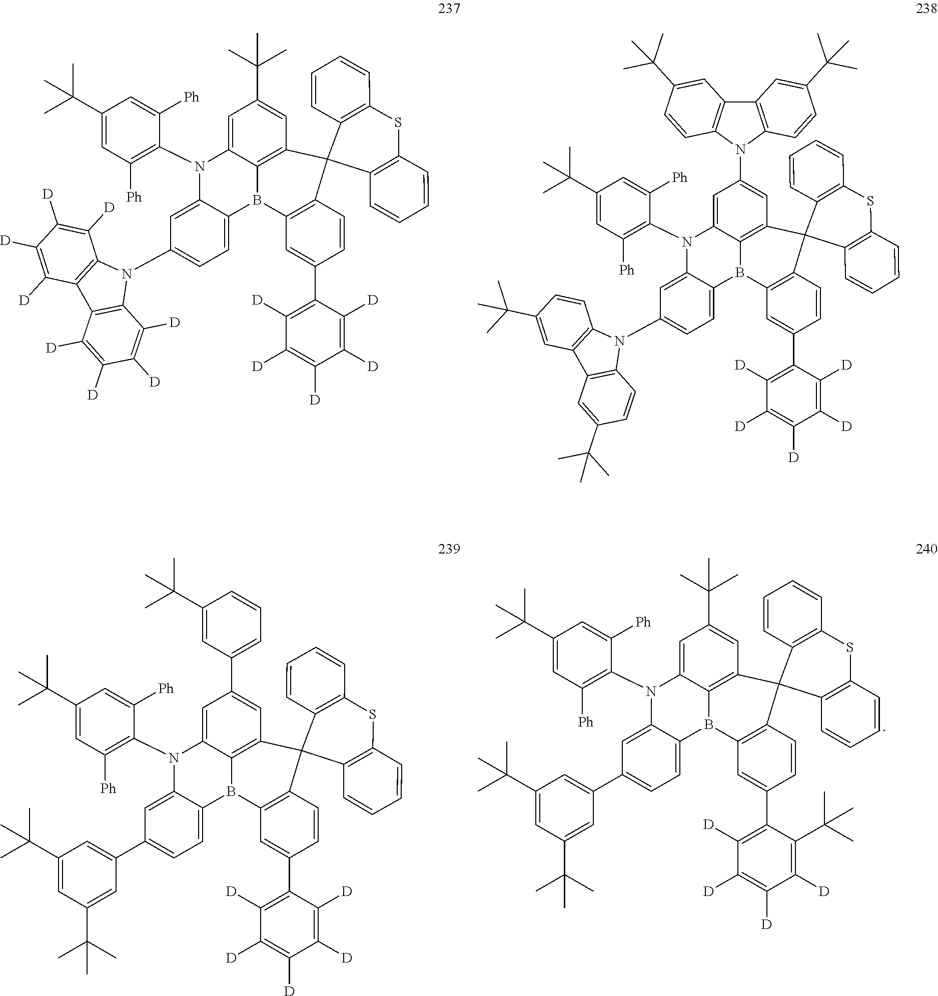

12. The light emitting device of claim 1, wherein the emission layer further comprises at least one selected from among a second compound represented by Formula HT-1 and a third compound represented by Formula ET-1: 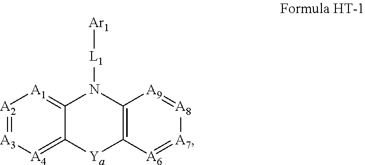
and
wherein, in Formula HT-1,
A₁ to A₄ and A₆ to A₉ are each independently N or CR₅₁,
L₁ is a direct linkage, a substituted or unsubstituted arylene group of 6 to 30 ring-forming carbon atoms, or a substituted or unsubstituted heteroarylene group of 2 to 30 ring-forming carbon atoms,
Yₐ is a direct linkage, CR₅₂R₅₃, or SiR₅₄R₅₅,
Ar₁ is a substituted or unsubstituted aryl group of 6 to 30 ring-forming carbon atoms, or a substituted or unsubstituted heteroaryl group of 2 to 30 ring-forming carbon atoms, and
R₅₁ to R₅₅ are each independently hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, 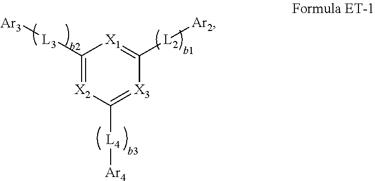
and
wherein, in Formula ET-1,
at least one selected from among X₁ to X₃ is N, and the remainder is CR₅₆,
R₅₆ is hydrogen, deuterium, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms,
L₂ to L₄ are each independently a direct linkage, a substituted or unsubstituted arylene group of 6 to 30 ring-forming carbon atoms, or a substituted or unsubstituted heteroarylene group of 2 to 30 ring-forming carbon atoms,
b1 to b3 are each independently an integer of 0 to 10, and
Ar₂ to Ar₃ are each independently hydrogen, deuterium, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

13. The light emitting device of claim 1, wherein the emission layer further comprises a fourth compound represented by Formula D-1: 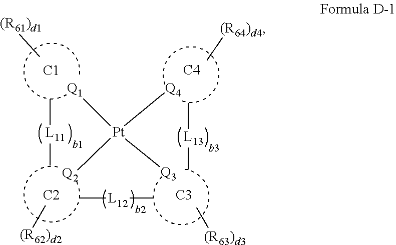
and
wherein, in Formula D-1,
Q₁ to Q₄ are each independently C or N,
C1 to C4 are each independently a substituted or unsubstituted hydrocarbon ring of 5 to 30 ring-forming carbon atoms, or a substituted or unsubstituted heterocycle of 2 to 30 ring-forming carbon atoms,
L₁₁ to L₁₃ are each independently a direct linkage, 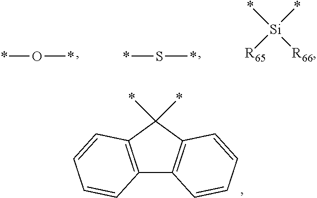
a substituted or unsubstituted alkylene group of 1 to 20 carbon atoms, a substituted or unsubstituted arylene group of 6 to 30 ring-forming carbon atoms, or a substituted or unsubstituted heteroarylene group of 2 to 30 ring-forming carbon atoms,
b1 to b3 are each independently 0 or 1,
R₆₁ to R₆₆ are each independently hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, or combined with an adjacent group to form a ring, and
d1 to d4 are each independently an integer of 0 to 4.

14. A fused polycyclic compound represented by Formula 1: 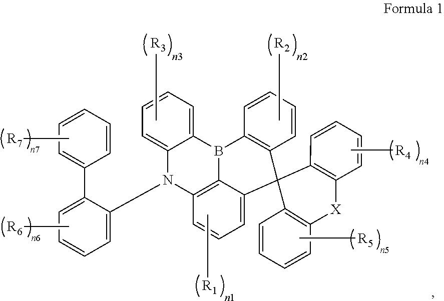
wherein, in Formula 1,
X is NR₈, O, or S,
R₁ to R₈ are each independently hydrogen, deuterium, a halogen, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
n1 is an integer of 0 to 3,
n2 to n6 are each independently an integer of 0 to 4, and
n7 is an integer of 0 to 5.

15. The fused polycyclic compound of claim 14, wherein R₂ and R₃ are each independently a substituted or unsubstituted amine group, a substituted or unsubstituted aryl group of 6 to 30 ring-forming carbon atoms, or a substituted or unsubstituted heteroaryl group of 2 to 30 ring-forming carbon atoms, and
n2 and n3 are each independently an integer of 1 to 4.

16. The fused polycyclic compound of claim 14, wherein the fused polycyclic compound represented by Formula 1 is represented by Formula 2: 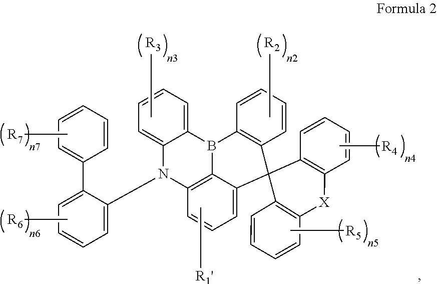
and
wherein, in Formula 2,
R₁′ is a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and
X, R₂ to R₇, and n2 to n7 are the same as defined in Formula 1.

17. The fused polycyclic compound of claim 14, wherein the fused polycyclic compound represented by Formula 1 is represented by any one selected from among Formula 3-1 to Formula 3-4: 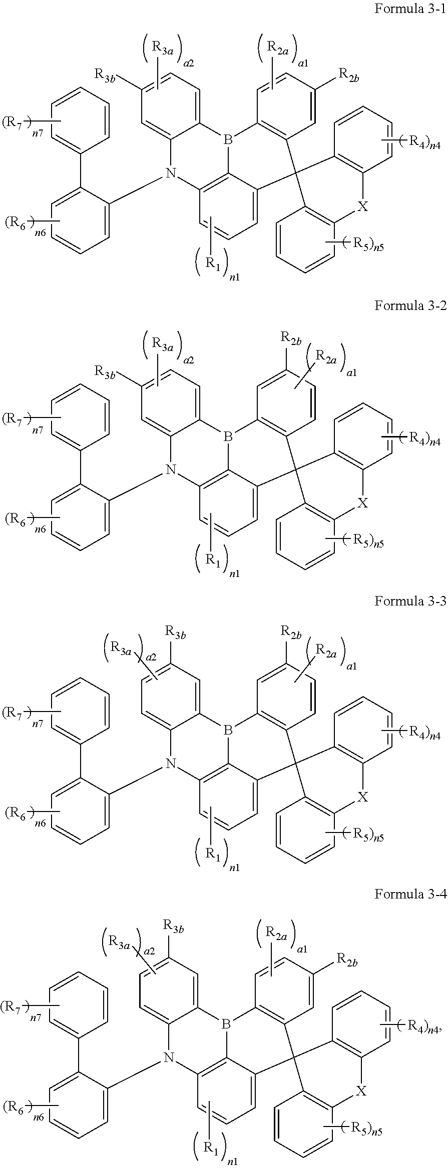
and
wherein, in Formula 3-1 to Formula 3-4,
R₂ₐ and R₃ₐ are each independently hydrogen, deuterium, a halogen, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
R_{2b} and R_{3b} are each independently a substituted or unsubstituted aryl group of 6 to 30 ring-forming carbon atoms, or a substituted or unsubstituted heteroaryl group of 2 to 30 ring-forming carbon atoms,
a1 and a2 are each independently an integer of 0 to 3, and
X, R₁, R₄ to R₇, n1, and n4 to n7 are the same as defined in Formula 1.

18. The fused polycyclic compound of claim 14, wherein the fused polycyclic compound represented by Formula 1 is represented by Formula 6: 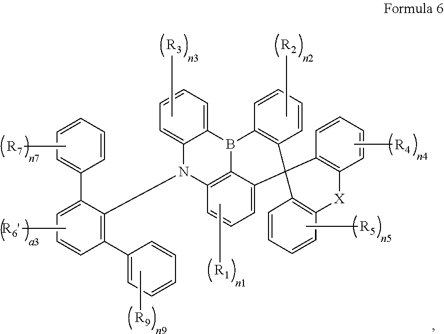
and
wherein, in Formula 6,
R₆′ and R₉ are each independently hydrogen, deuterium, a halogen, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
a3 is an integer of 0 to 3,
n9 is an integer of 0 to 5, and
X, R₁ to R₅, R₇, n1 to n5, and n7 are the same as defined in Formula 1.

19. The fused polycyclic compound of claim 14, wherein the fused polycyclic compound represented by Formula 1 is represented by any one selected from among Formula 8-1 to Formula 8-3: 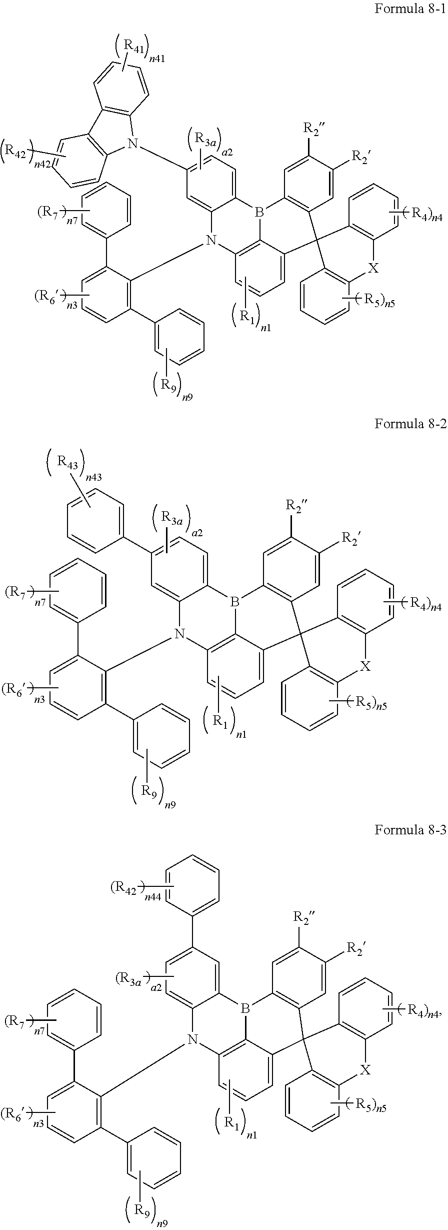
and
wherein, in Formula 8-1 to Formula 8-3,
R₃ₐ, R₂′, R₂″, and R₄₁ to R₄₄ are each independently hydrogen, deuterium, a halogen, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
R₆′, and R₉ are each independently hydrogen, deuterium, a halogen, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
at least one selected from among R₂′ and R₂″ is a substituted or unsubstituted aryl group of 6 to 30 ring-forming carbon atoms, or a substituted or unsubstituted heteroaryl group of 2 to 30 ring-forming carbon atoms,
a2 and a3 are each independently an integer of 0 to 3,
n9 is an integer of 0 to 5,
n41 and n42 are each independently an integer of 0 to 4,
n43 and n44 are each independently an integer of 0 to 5, and
X, R₁, R₄, R₅, R₇, n1, n4, n5, and n7 are the same as defined in Formula 1.

20. The fused polycyclic compound of claim 14, wherein the fused polycyclic compound represented by Formula 1 comprises at least one selected from among compounds in Compound Group 1: 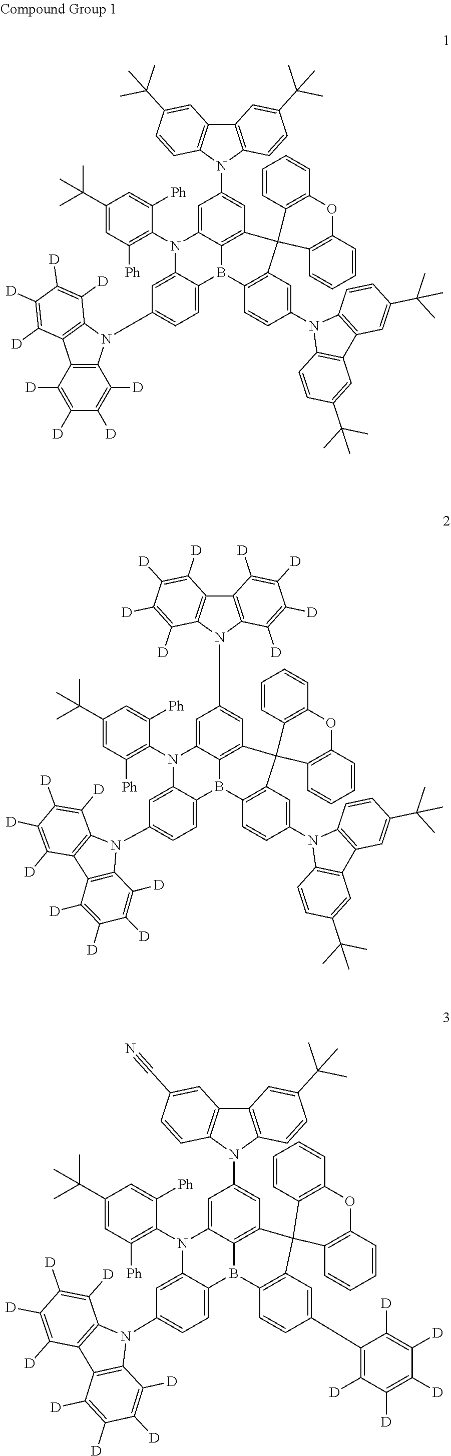 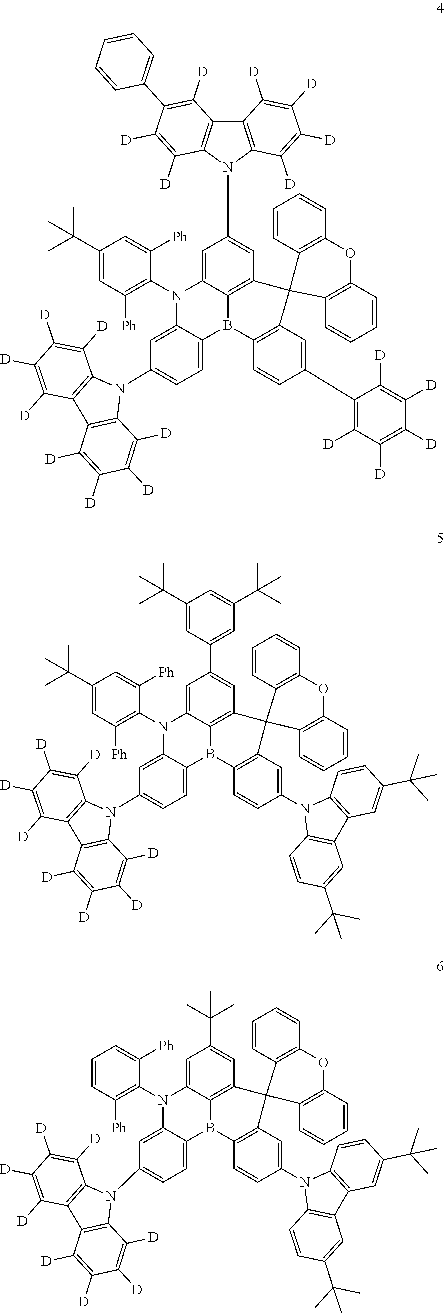 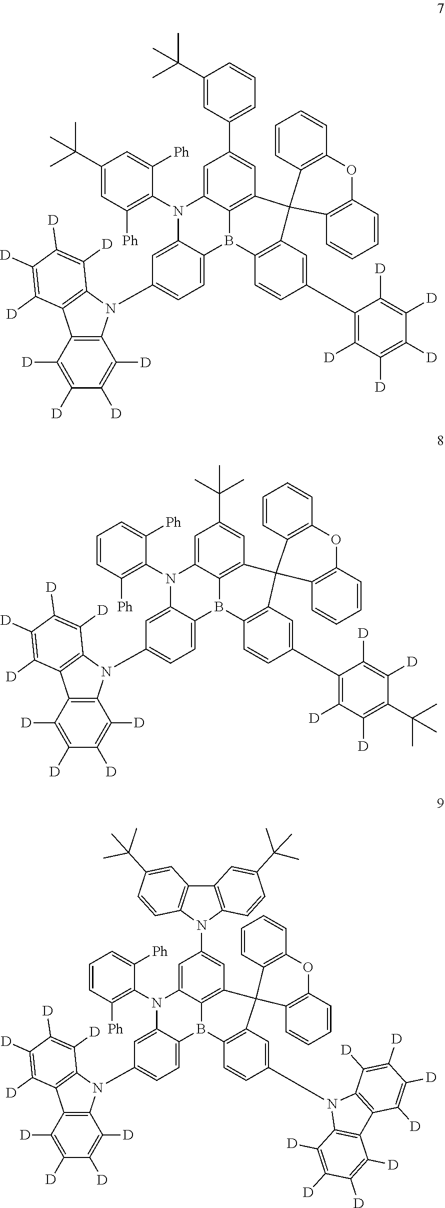 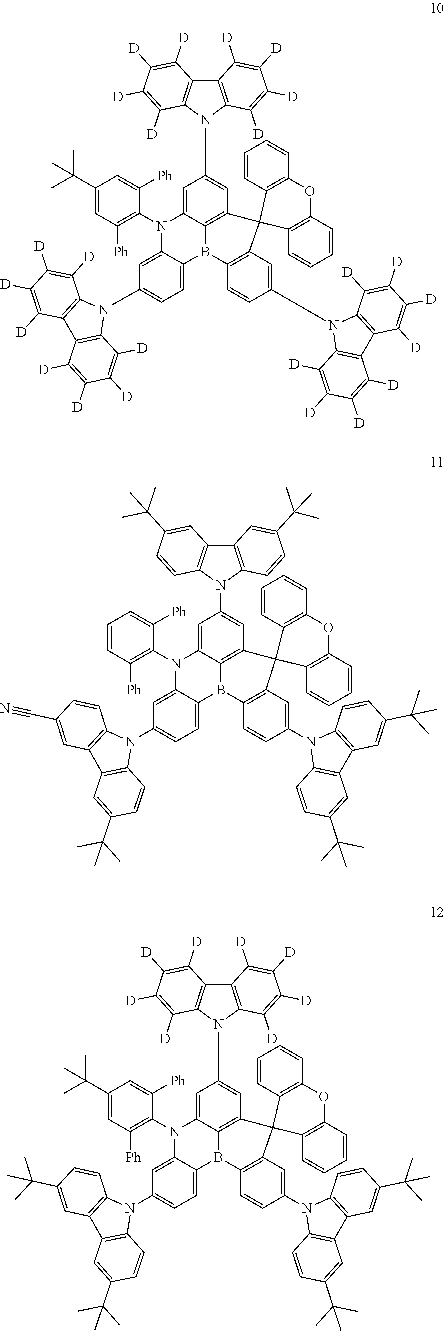 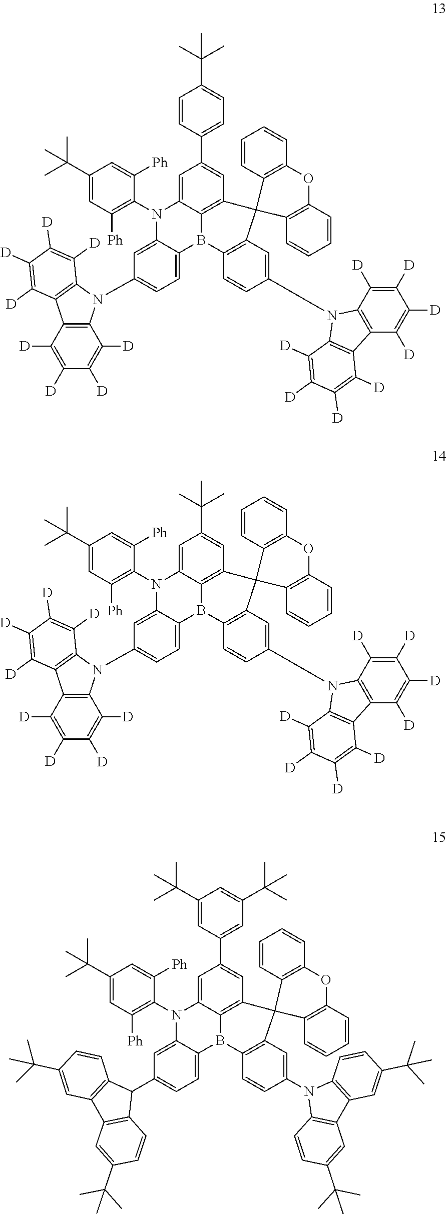 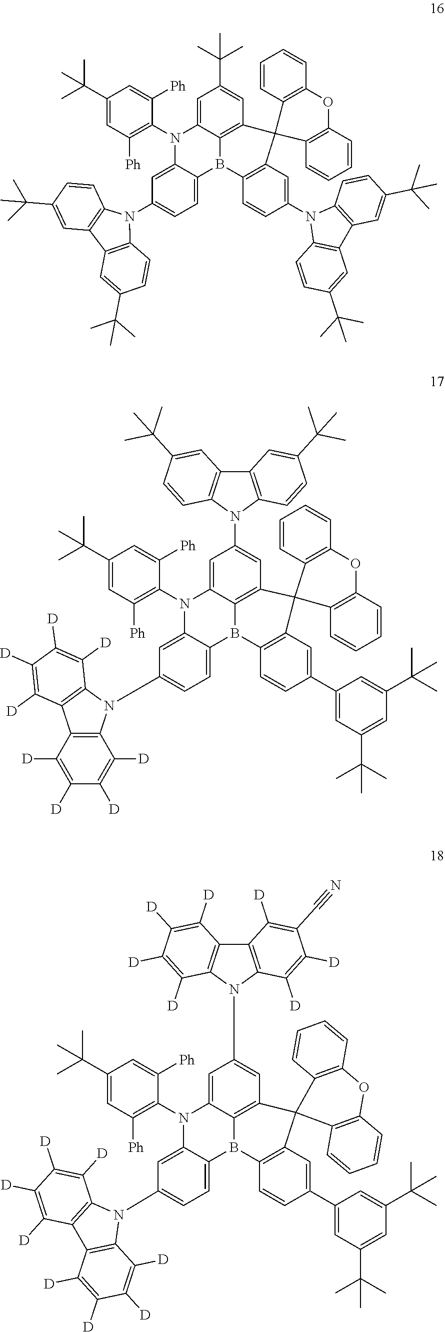 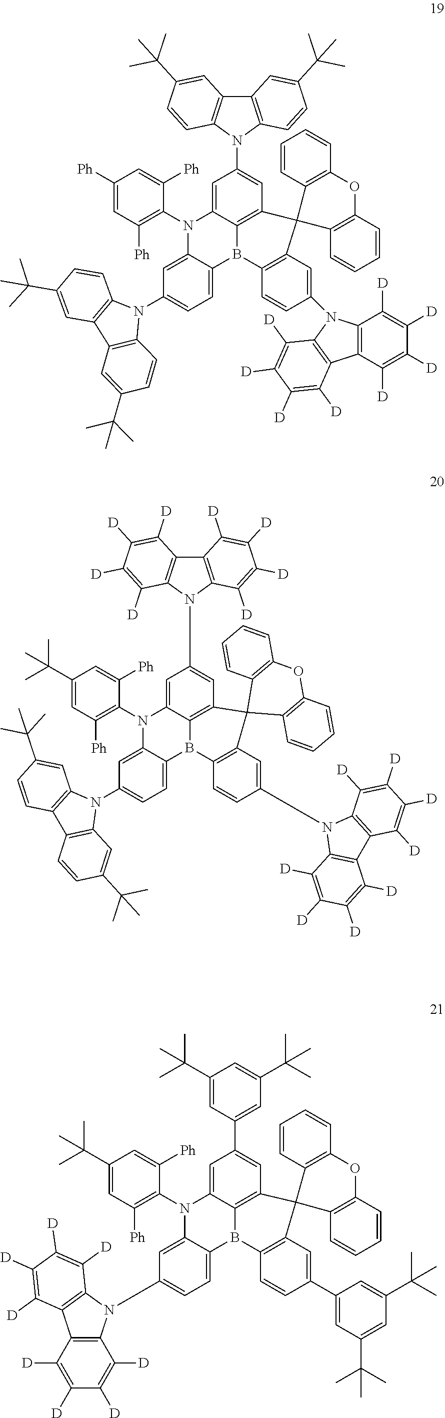 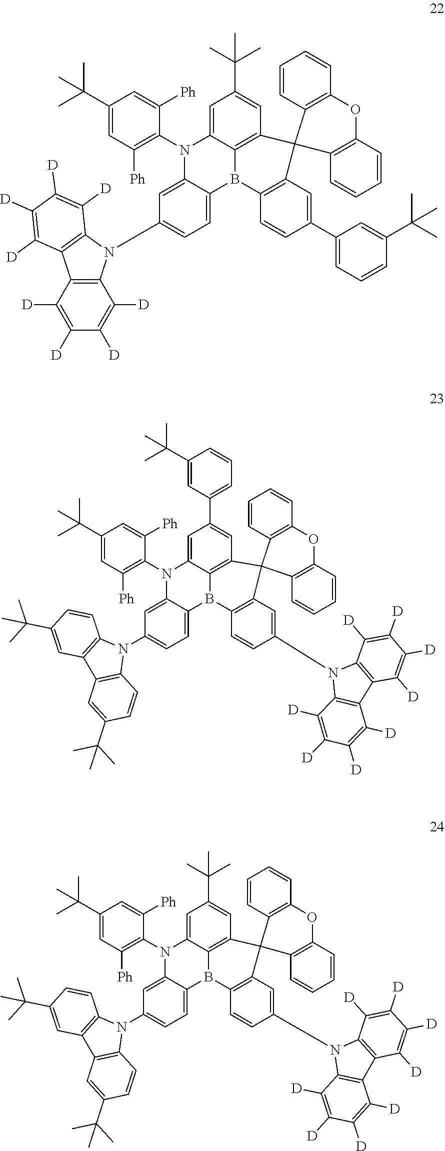 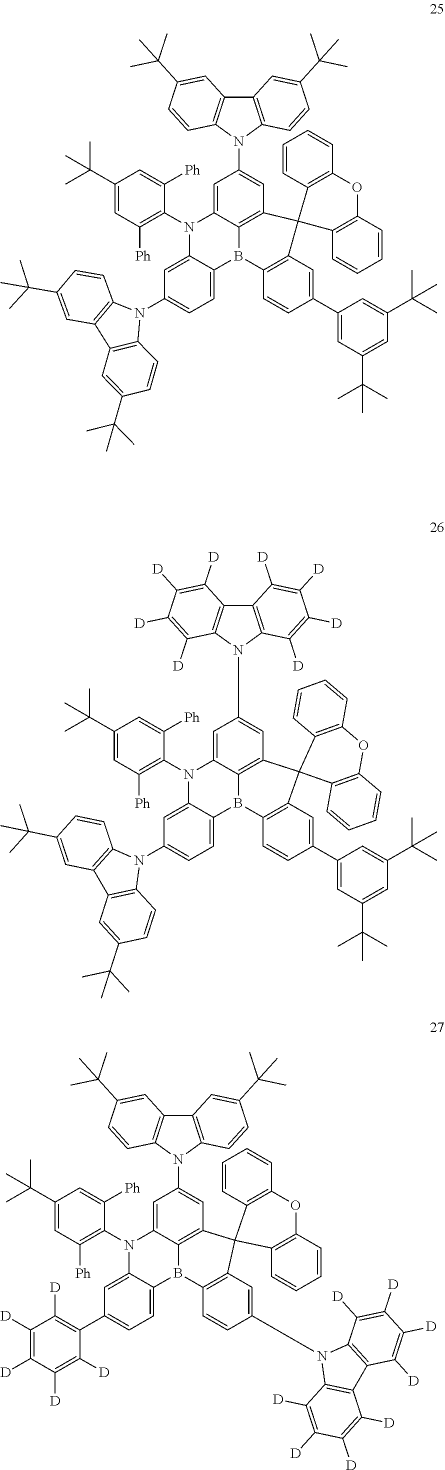 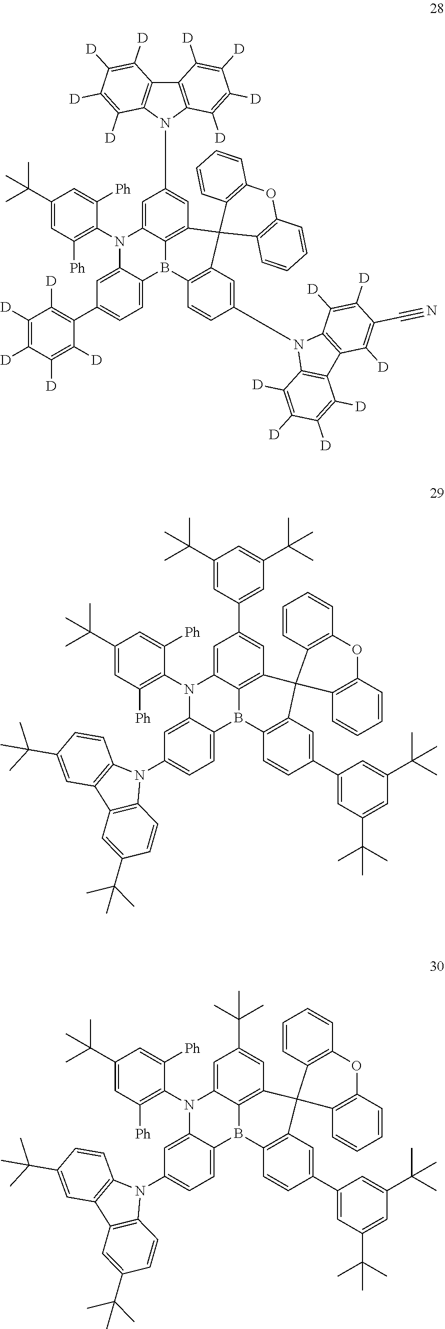 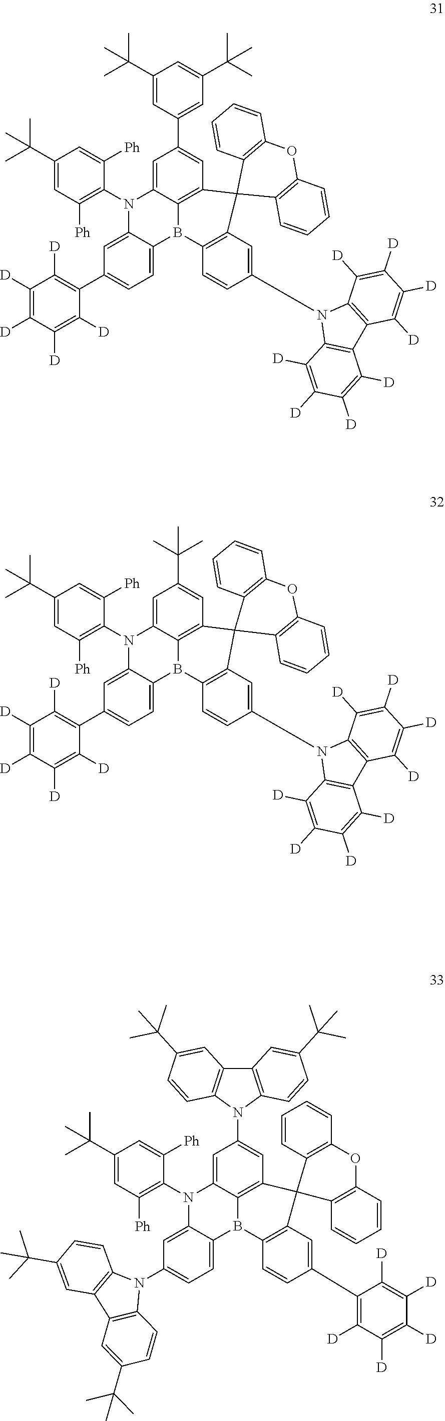 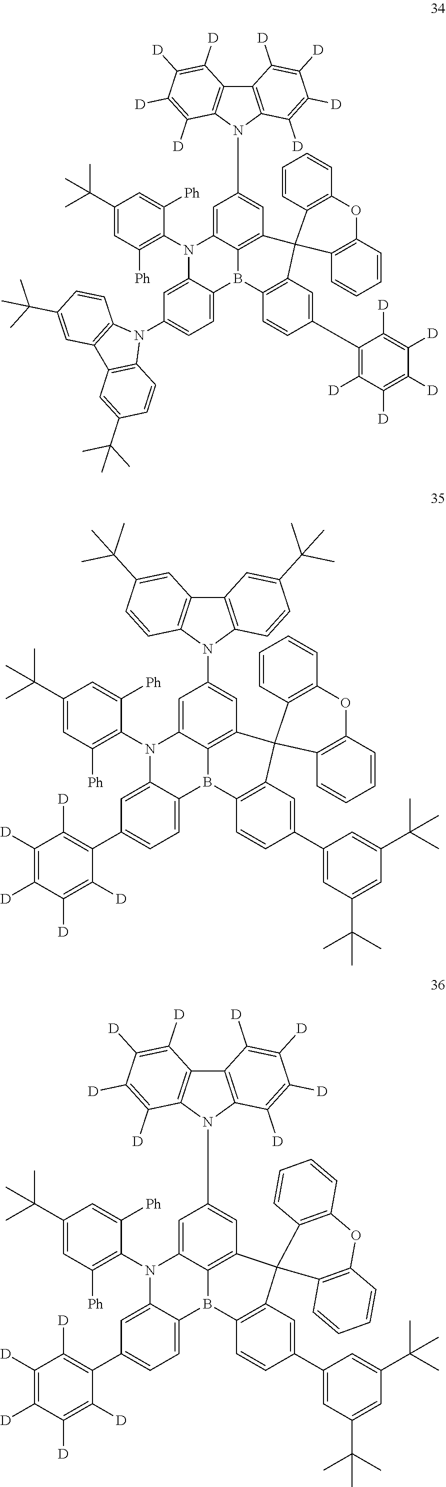 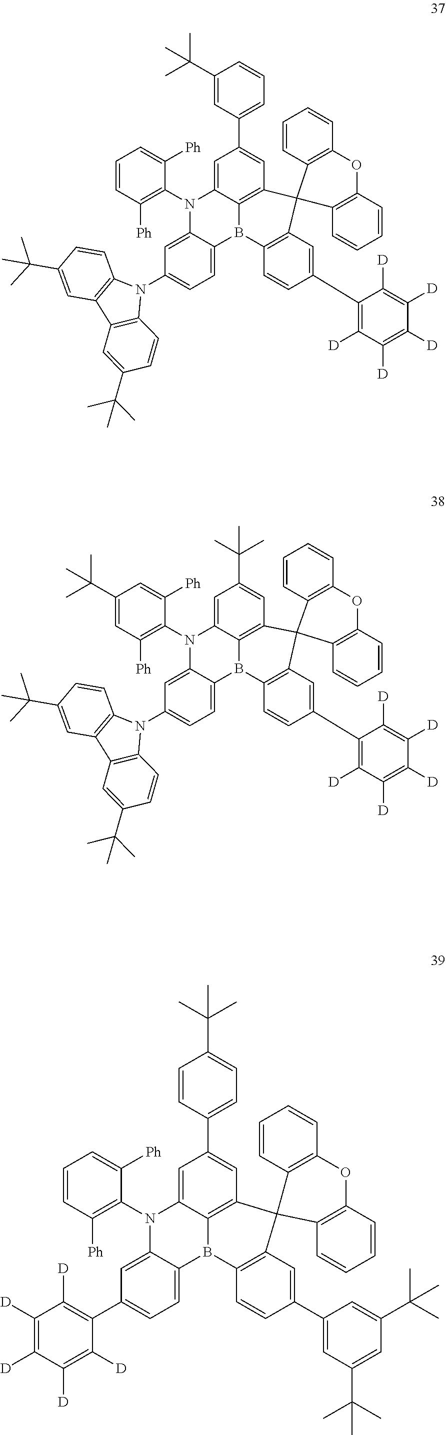 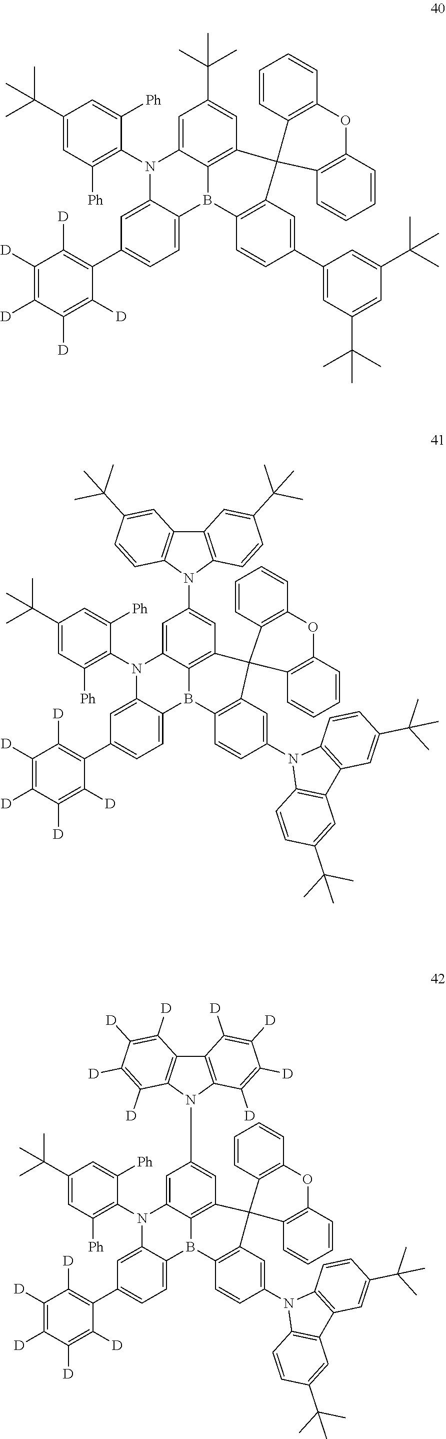 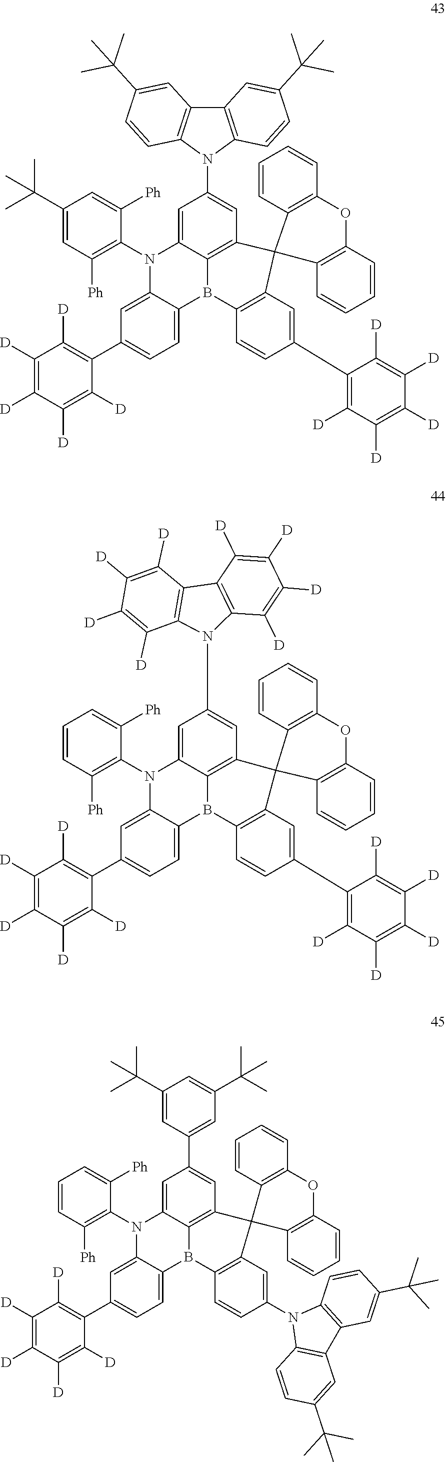 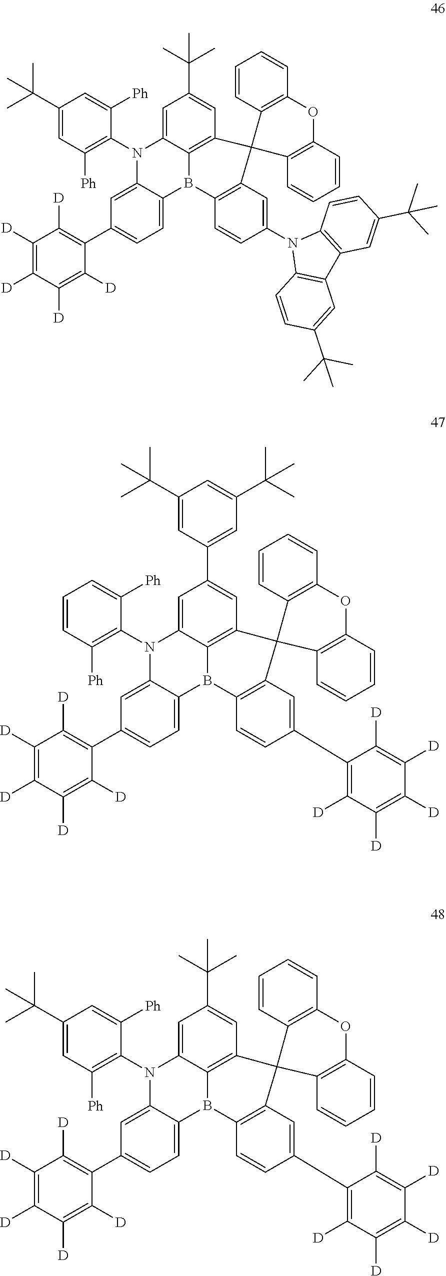 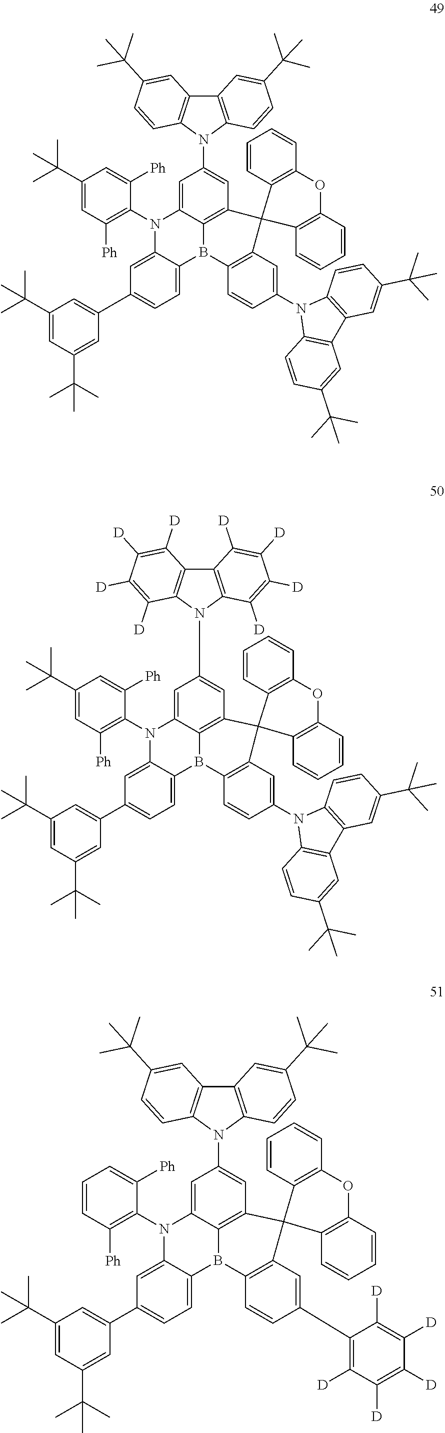 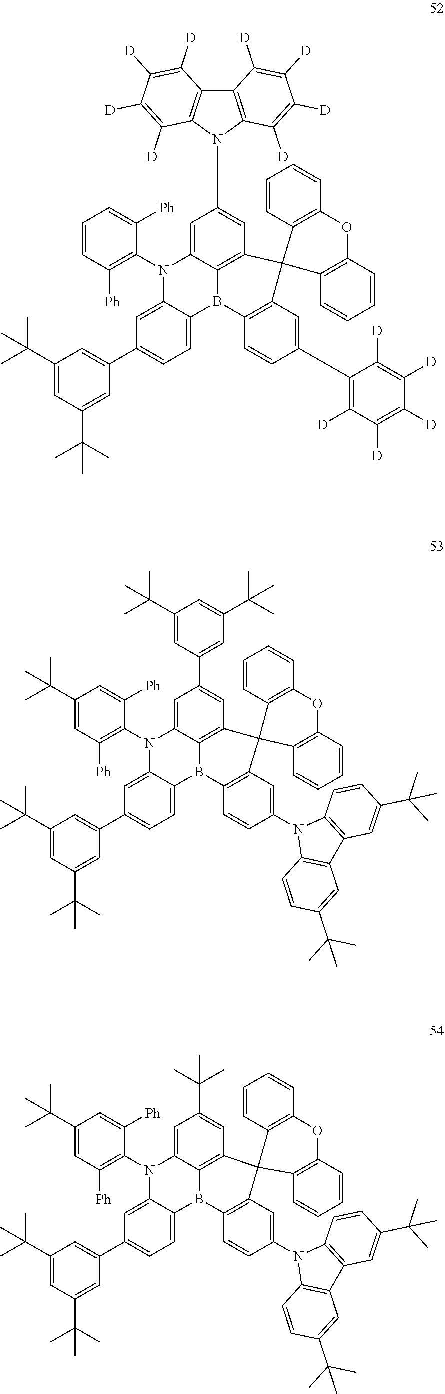 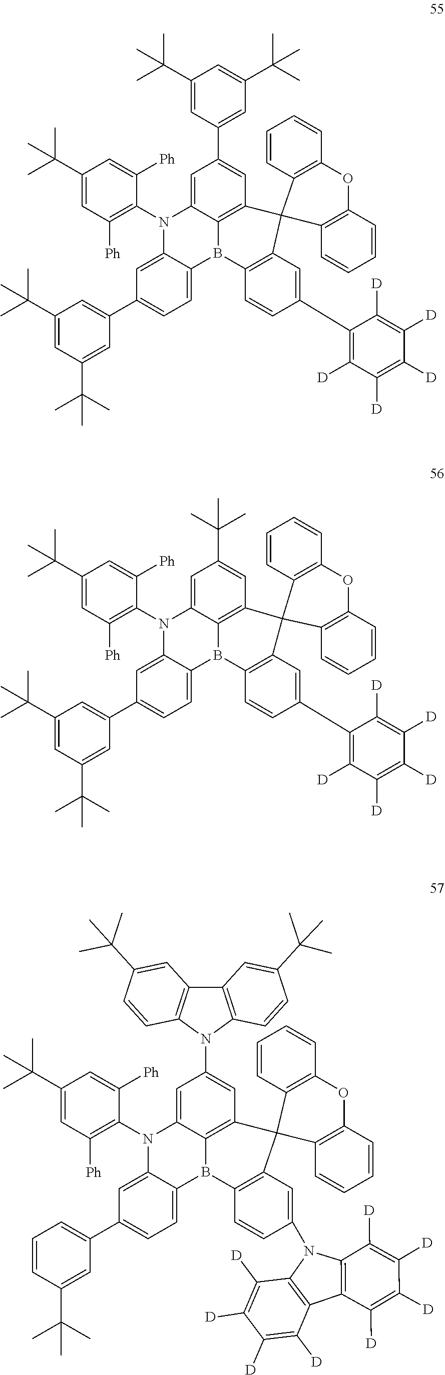 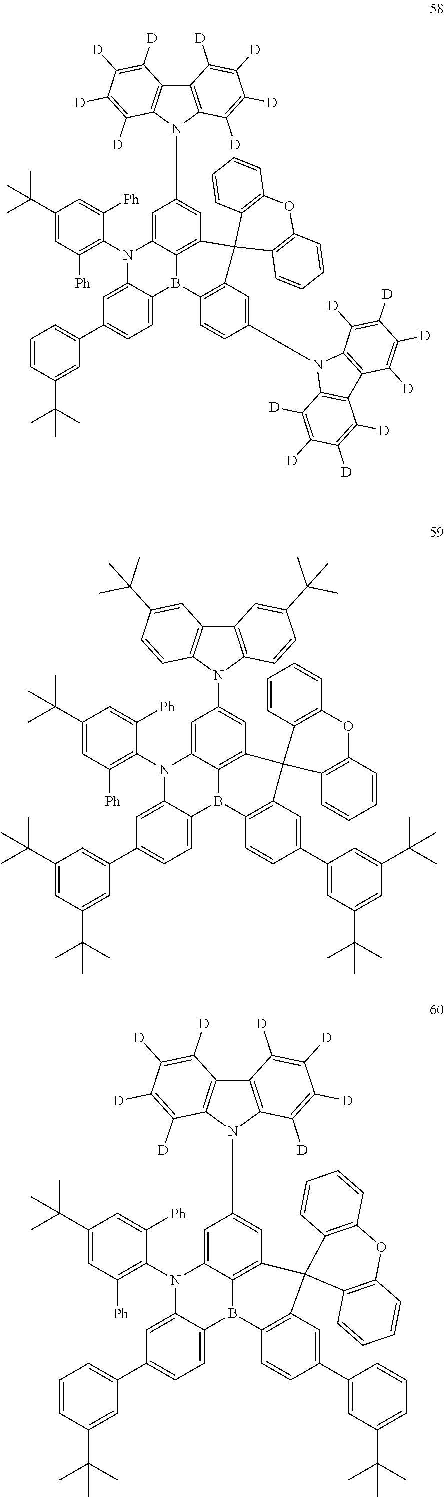 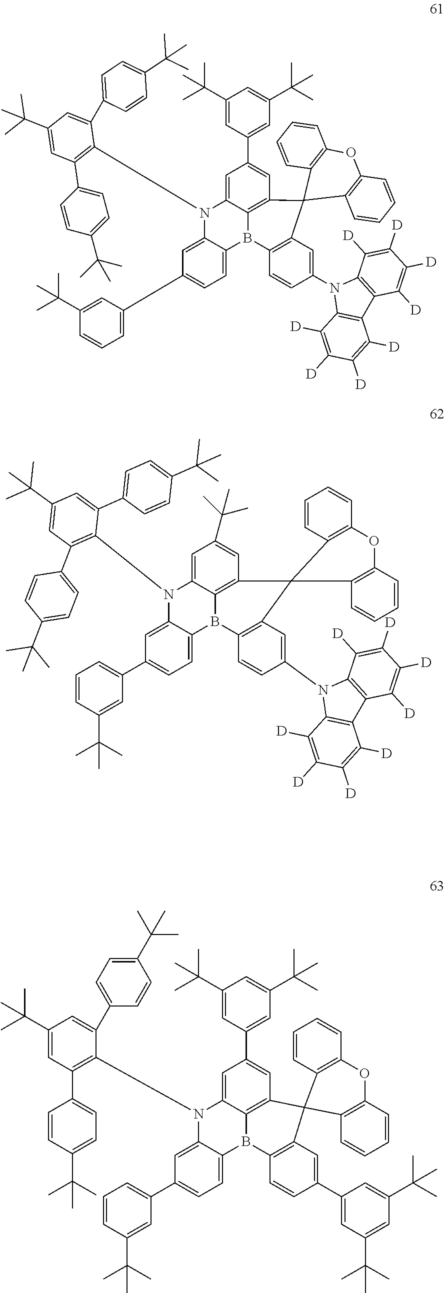 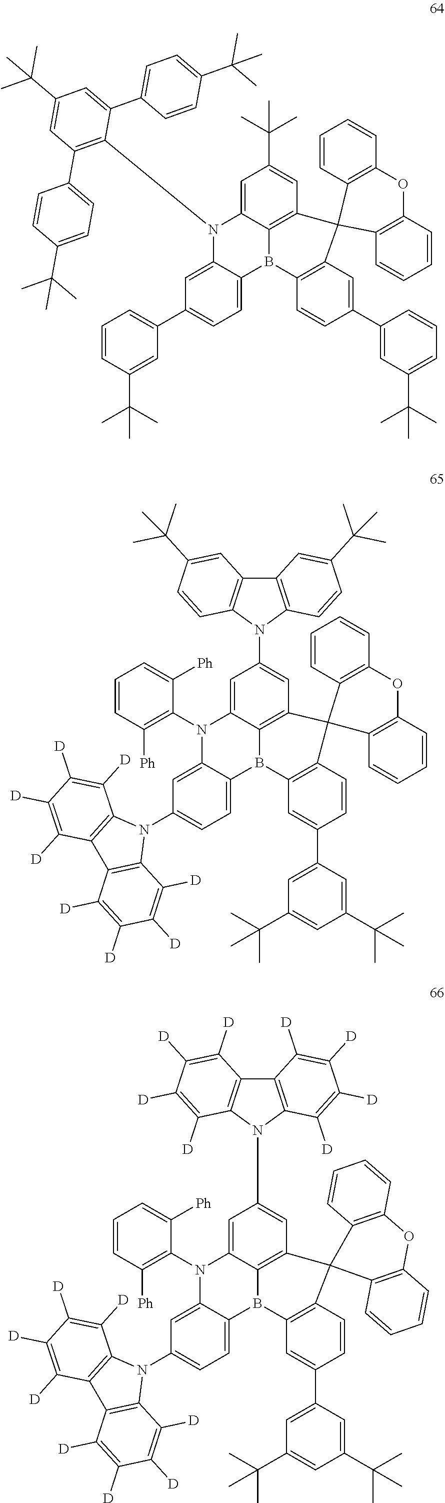 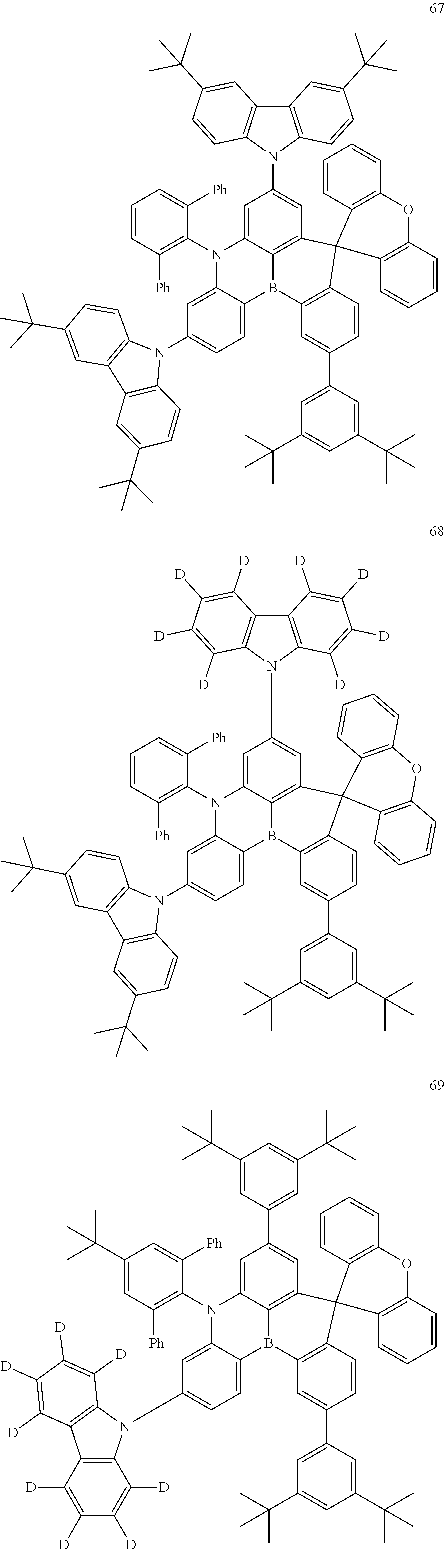 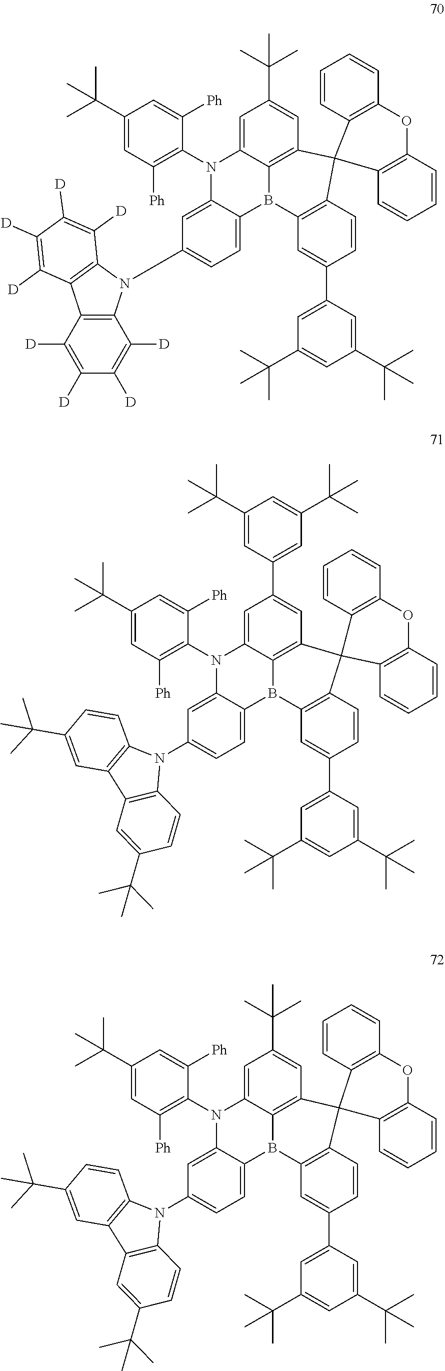 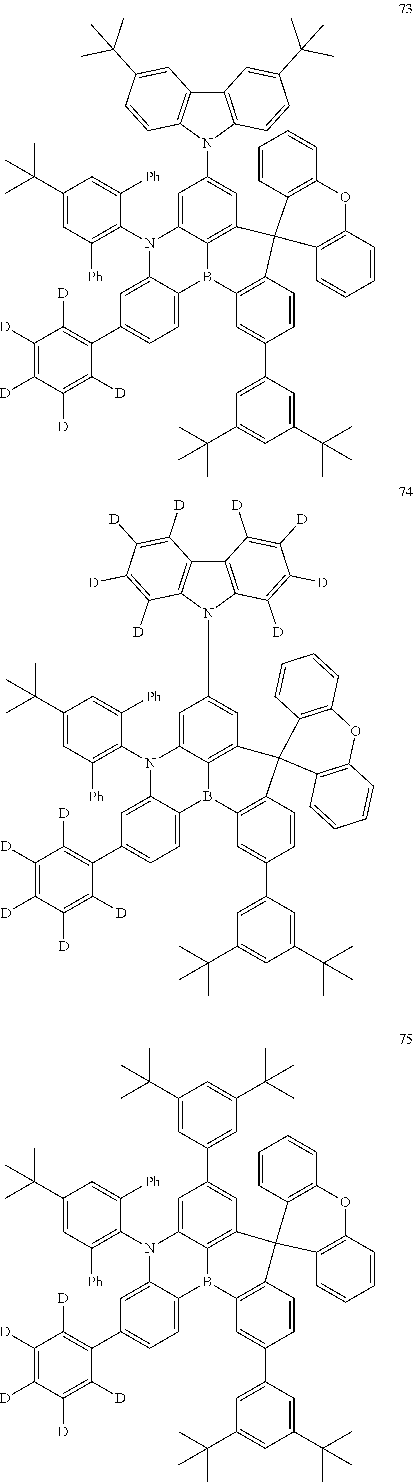 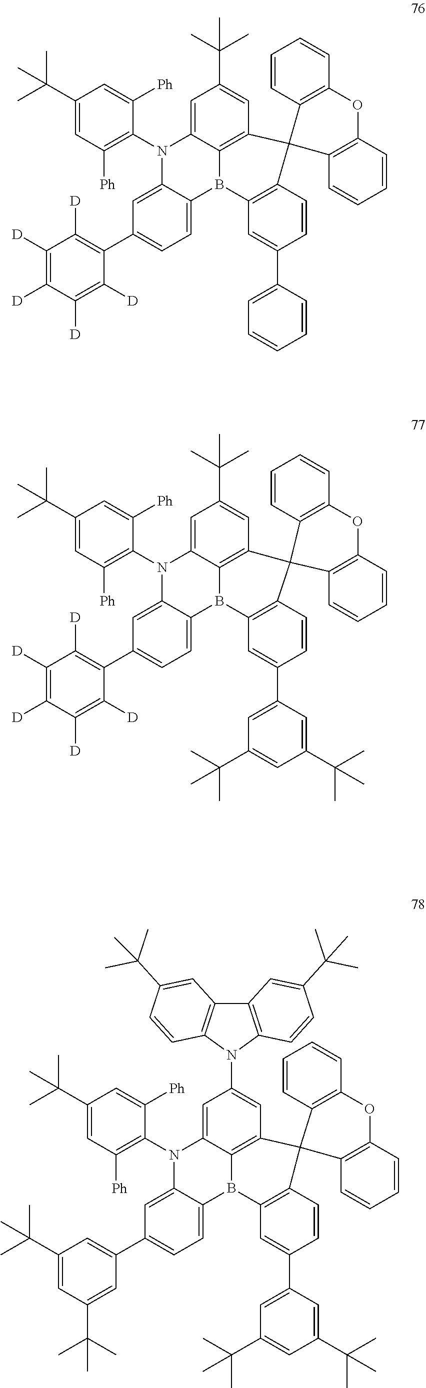 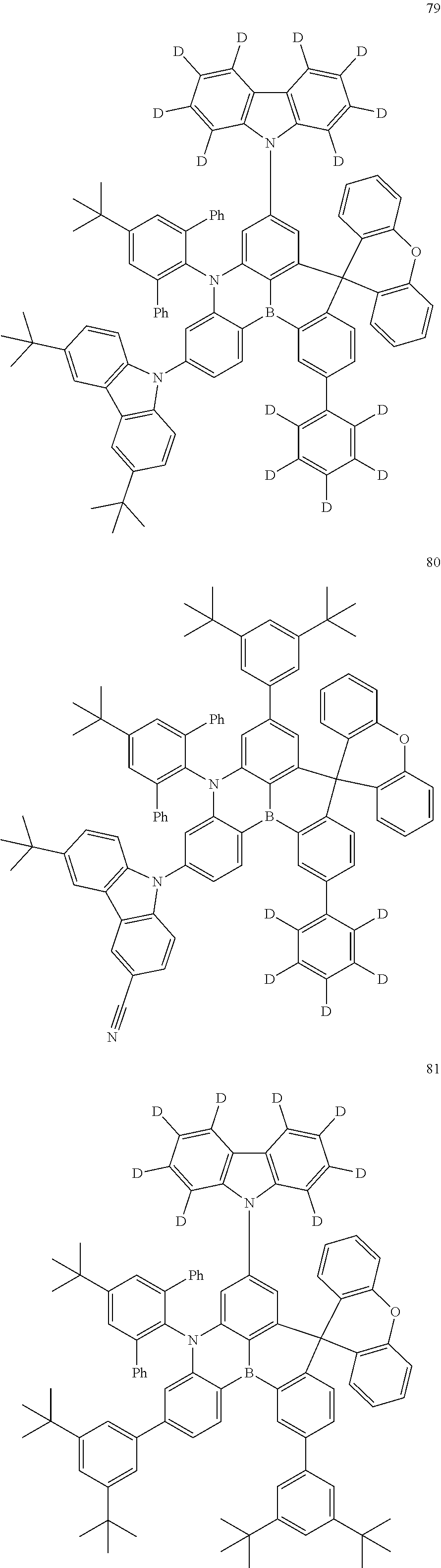 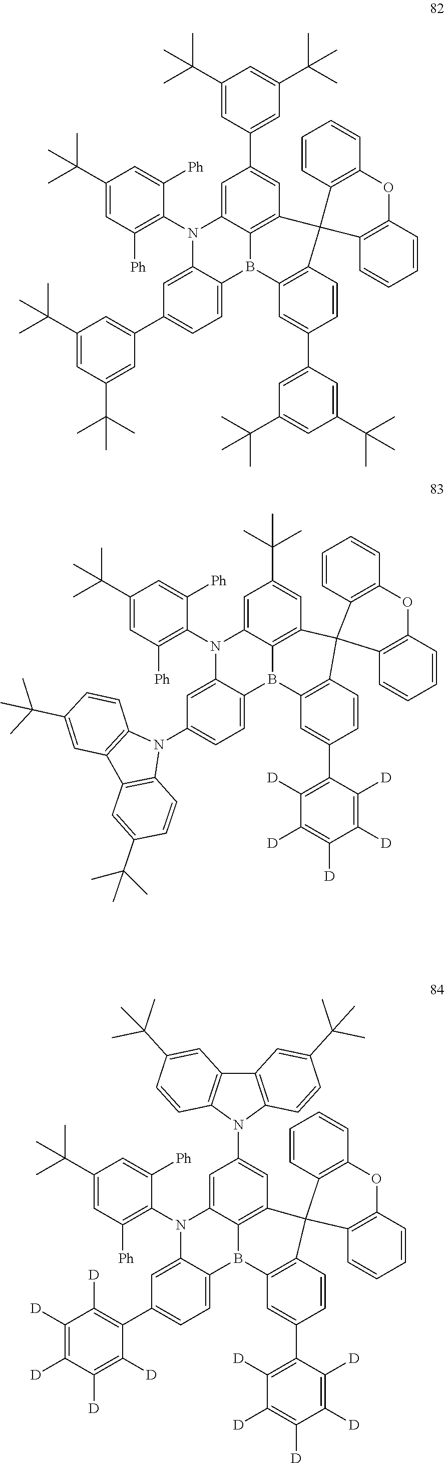 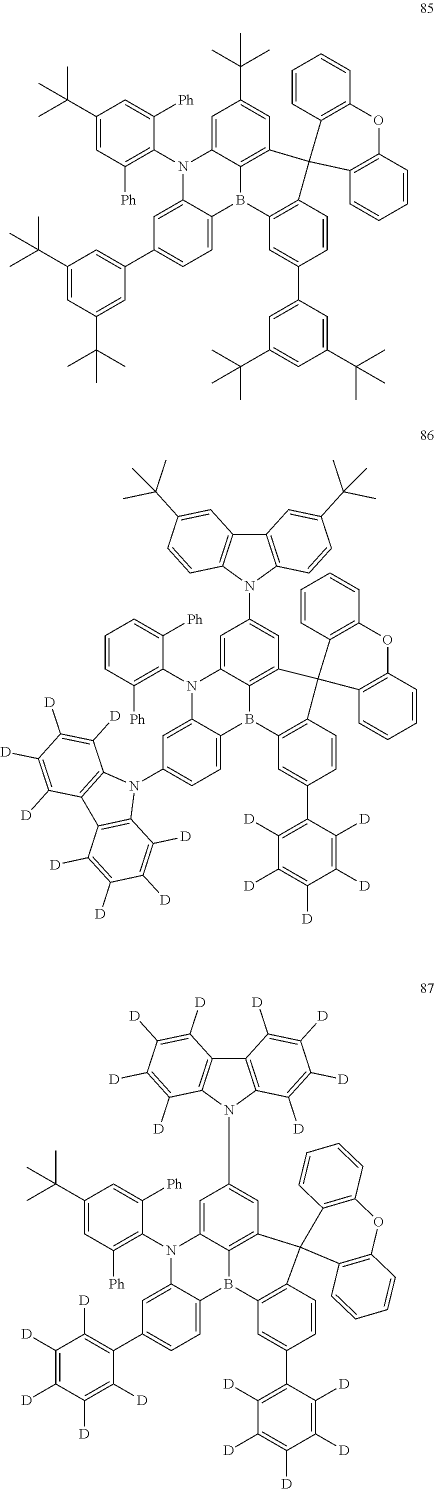 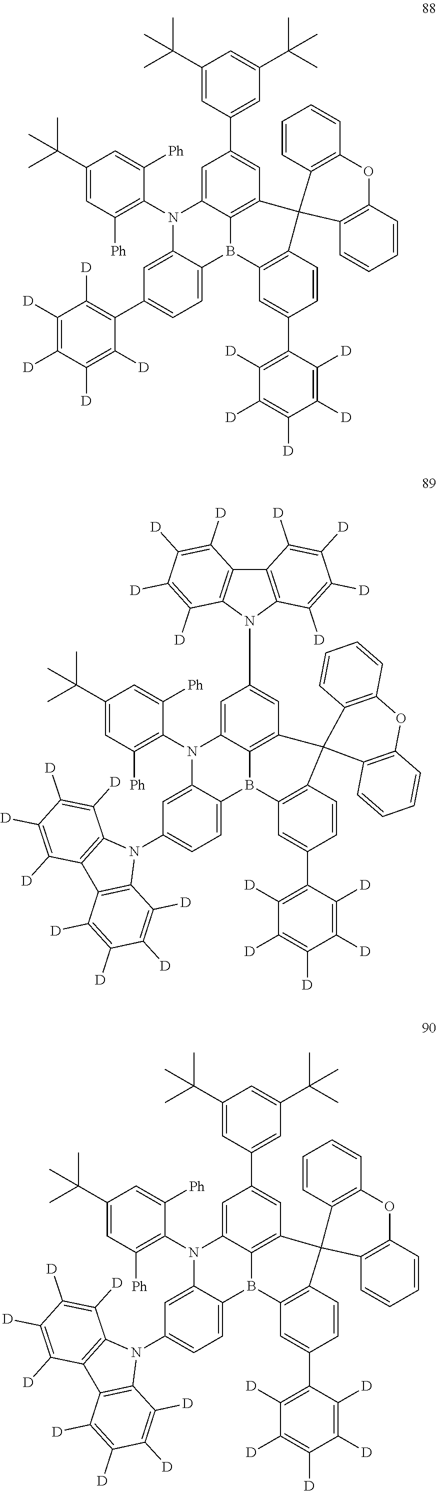 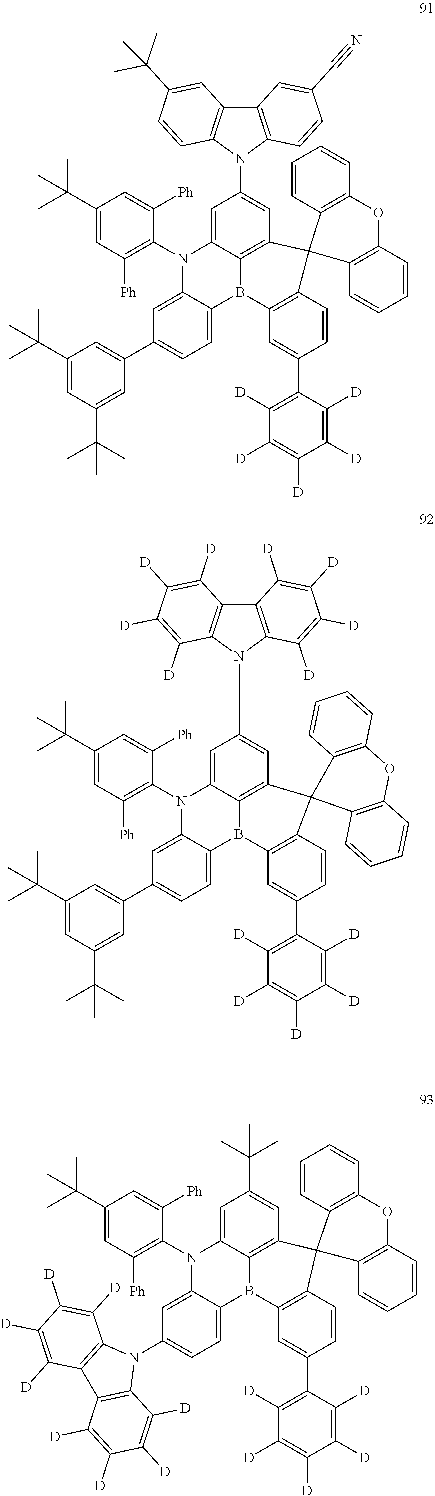 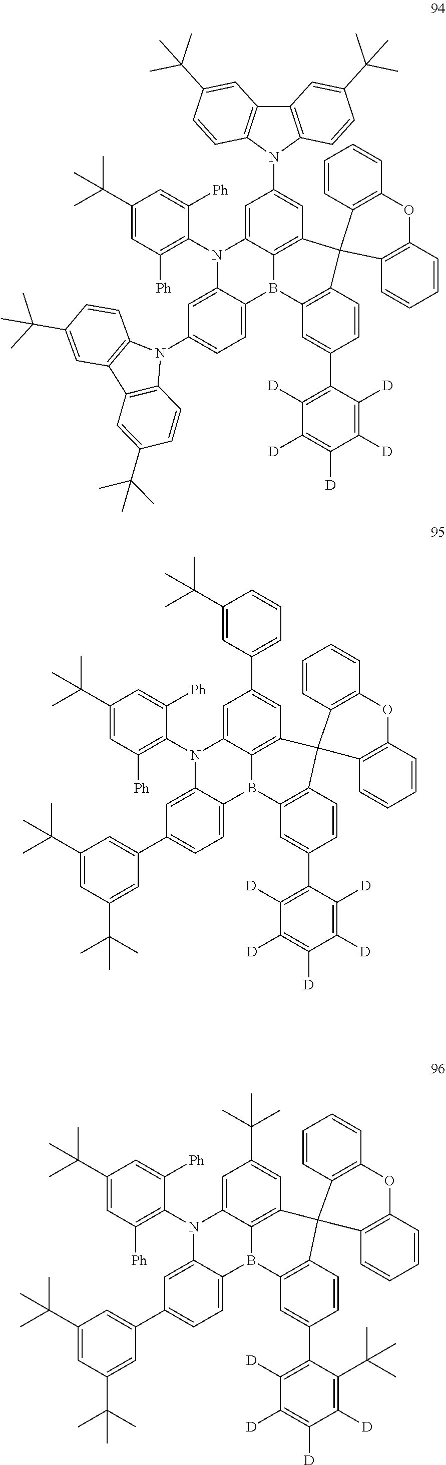 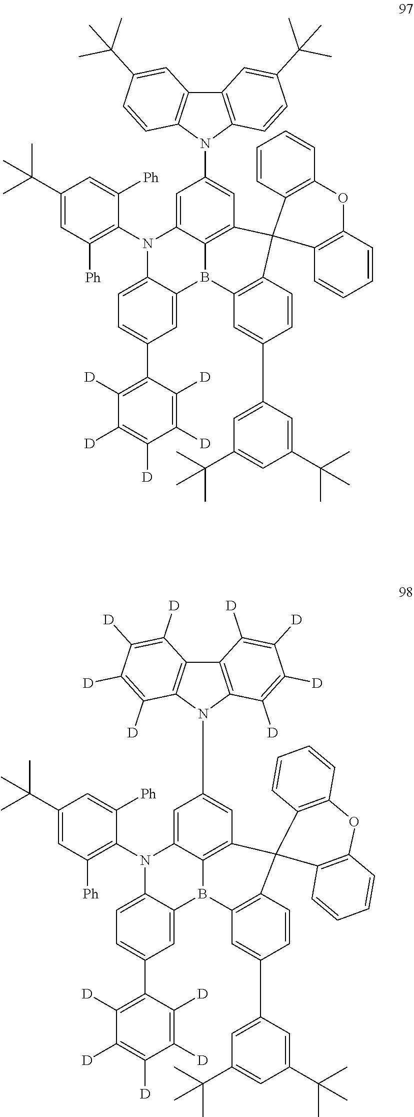 [SMILES: [2H]c1c([2H])c([2H])c(-c2ccc3c(c2)B2c4cc(-c5cc(C(C)(C)C)cc(C(C)(C)C)c5)ccc4C4(c5ccccc5Oc5ccccc54)c4cc(-n5c6ccc(C(C)(C)C)cc6c6cc(C(C)(C)C)ccc65)cc(c42)N3c2c(-c3ccccc3)cc(C(C)(C)C)cc2-c2ccccc2)c([2H])c1[2H] ; [2H]c1c([2H])c([2H])c(-c2ccc3c(c2)B2c4cc(-c5cc(C(C)(C)C)cc(C(C)(C)C)c5)ccc4C4(c5ccccc5Oc5ccccc54)c4cc(-n5c6c([2H])c([2H])c([2H])c([2H])c6c6c([2H])c([2H])c([2H])c([2H])c65)cc(c42)N3c2c(-c3ccccc3)cc(C(C)(C)C)cc2-c2ccccc2)c([2H])c1[2H]] 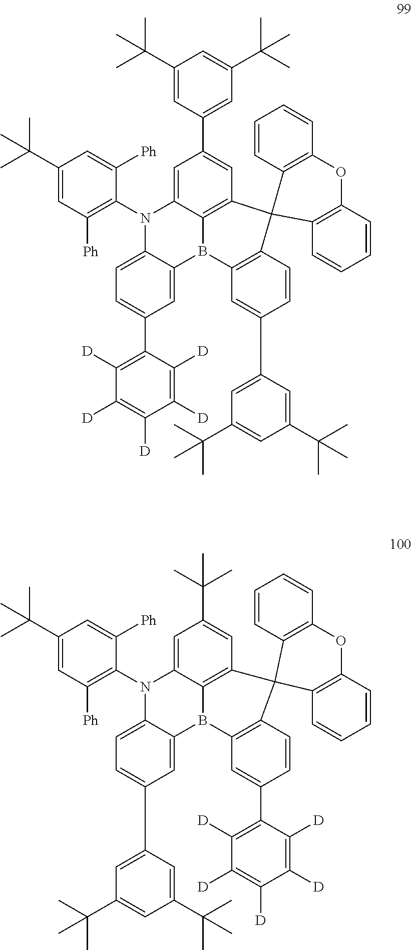 [SMILES: [2H]c1c([2H])c([2H])c(-c2ccc3c(c2)B2c4cc(-c5cc(C(C)(C)C)cc(C(C)(C)C)c5)ccc4C4(c5ccccc5Oc5ccccc54)c4cc(-c5cc(C(C)(C)C)cc(C(C)(C)C)c5)cc(c42)N3c2c(-c3ccccc3)cc(C(C)(C)C)cc2-c2ccccc2)c([2H])c1[2H] ; [2H]c1c([2H])c([2H])c(-c2ccc3c(c2)B2c4cc(-c5cc(C(C)(C)C)cc(C(C)(C)C)c5)ccc4N(c4c(-c5ccccc5)cc(C(C)(C)C)cc4-c4ccccc4)c4cc(C(C)(C)C)cc(c42)C32c3ccccc3Oc3ccccc32)c([2H])c1[2H]] 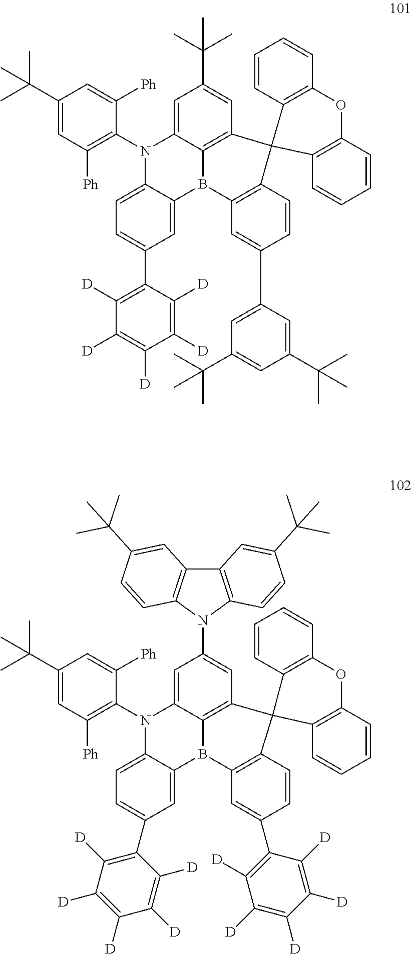 [SMILES: [2H]c1c([2H])c([2H])c(-c2ccc3c(c2)B2c4cc(-c5cc(C(C)(C)C)cc(C(C)(C)C)c5)ccc4C4(c5ccccc5Oc5ccccc54)c4cc(C(C)(C)C)cc(c42)N3c2c(-c3ccccc3)cc(C(C)(C)C)cc2-c2ccccc2)c([2H])c1[2H] ; [2H]c1c([2H])c([2H])c(-c2ccc3c(c2)B2c4cc(-c5c([2H])c([2H])c([2H])c([2H])c5[2H])ccc4C4(c5ccccc5Oc5ccccc54)c4cc(-n5c6ccc(C(C)(C)C)cc6c6cc(C(C)(C)C)ccc65)cc(c42)N3c2c(-c3ccccc3)cc(C(C)(C)C)cc2-c2ccccc2)c([2H])c1[2H]] 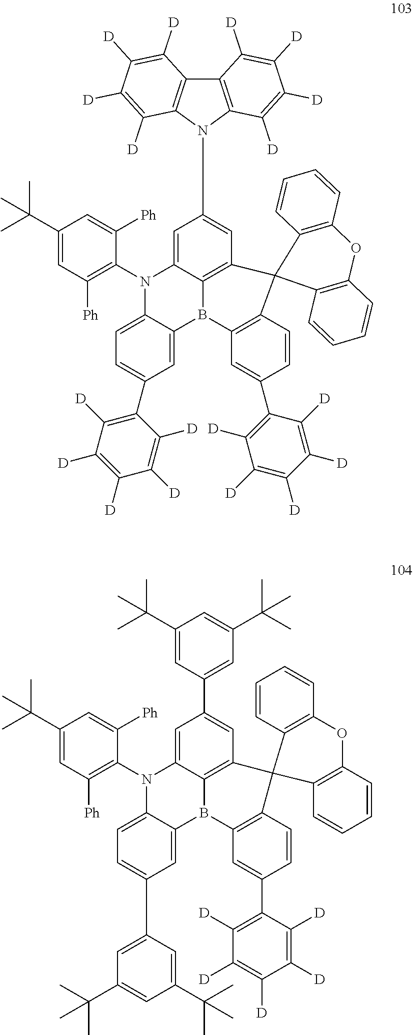 [SMILES: [2H]c1c([2H])c([2H])c(-c2ccc3c(c2)B2c4cc(-c5c([2H])c([2H])c([2H])c([2H])c5[2H])ccc4C4(c5ccccc5Oc5ccccc54)c4cc(-n5c6c([2H])c([2H])c([2H])c([2H])c6c6c([2H])c([2H])c([2H])c([2H])c65)cc(c42)N3c2c(-c3ccccc3)cc(C(C)(C)C)cc2-c2ccccc2)c([2H])c1[2H] ; [2H]c1c([2H])c([2H])c(-c2ccc3c(c2)B2c4cc(-c5cc(C(C)(C)C)cc(C(C)(C)C)c5)ccc4N(c4c(-c5ccccc5)cc(C(C)(C)C)cc4-c4ccccc4)c4cc(-c5cc(C(C)(C)C)cc(C(C)(C)C)c5)cc(c42)C32c3ccccc3Oc3ccccc32)c([2H])c1[2H]] 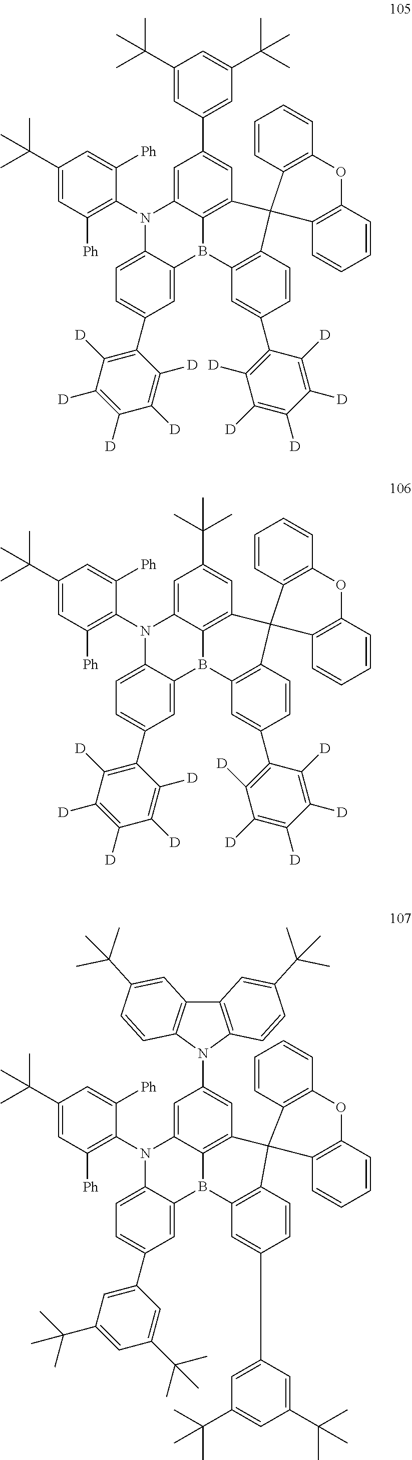 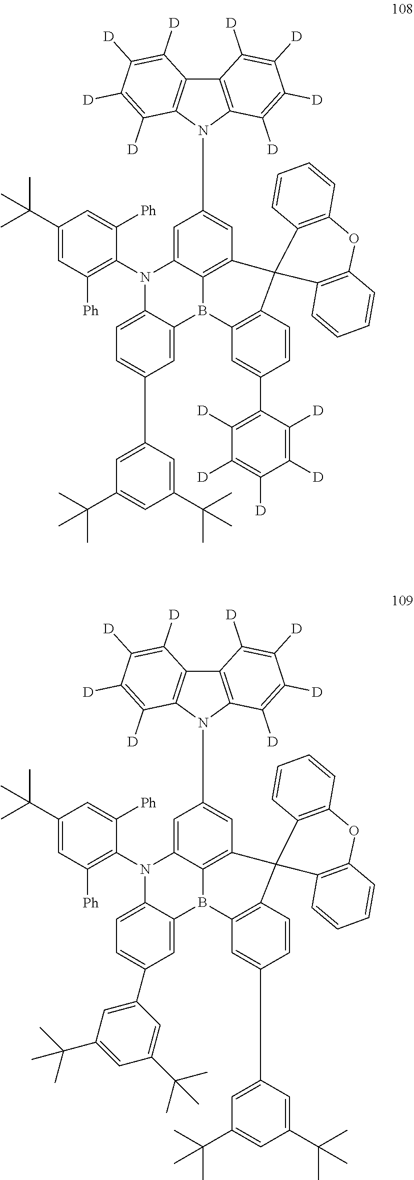 [SMILES: [2H]c1c([2H])c([2H])c(-c2ccc3c(c2)B2c4cc(-c5cc(C(C)(C)C)cc(C(C)(C)C)c5)ccc4N(c4c(-c5ccccc5)cc(C(C)(C)C)cc4-c4ccccc4)c4cc(-n5c6c([2H])c([2H])c([2H])c([2H])c6c6c([2H])c([2H])c([2H])c([2H])c65)cc(c42)C32c3ccccc3Oc3ccccc32)c([2H])c1[2H] ; [2H]c1c([2H])c([2H])c2c(c1[2H])c1c([2H])c([2H])c([2H])c([2H])c1n2-c1cc2c3c(c1)C1(c4ccccc4Oc4ccccc41)c1ccc(-c4cc(C(C)(C)C)cc(C(C)(C)C)c4)cc1B3c1cc(-c3cc(C(C)(C)C)cc(C(C)(C)C)c3)ccc1N2c1c(-c2ccccc2)cc(C(C)(C)C)cc1-c1ccccc1] 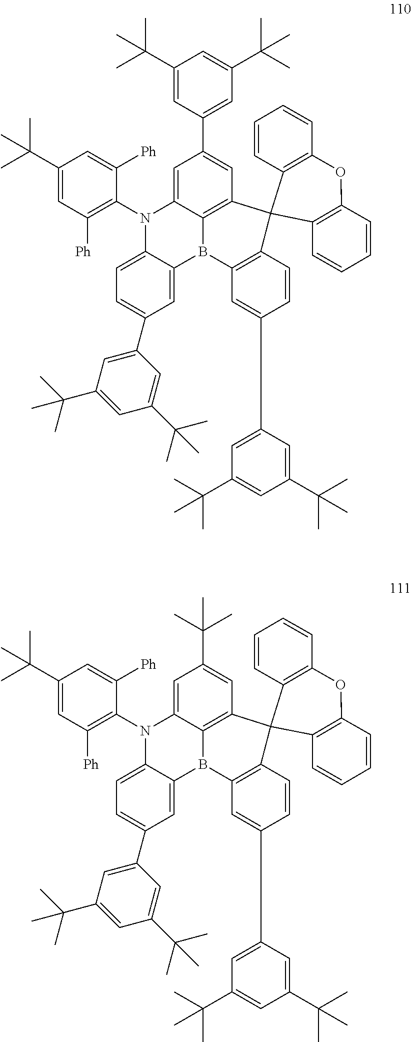 [SMILES: CC(C)(C)c1cc(-c2ccc3c(c2)B2c4cc(-c5cc(C(C)(C)C)cc(C(C)(C)C)c5)ccc4C4(c5ccccc5Oc5ccccc54)c4cc(-c5cc(C(C)(C)C)cc(C(C)(C)C)c5)cc(c42)N3c2c(-c3ccccc3)cc(C(C)(C)C)cc2-c2ccccc2)cc(C(C)(C)C)c1 ; CC(C)(C)c1cc(-c2ccc3c(c2)B2c4cc(-c5cc(C(C)(C)C)cc(C(C)(C)C)c5)ccc4C4(c5ccccc5Oc5ccccc54)c4cc(C(C)(C)C)cc(c42)N3c2c(-c3ccccc3)cc(C(C)(C)C)cc2-c2ccccc2)cc(C(C)(C)C)c1] 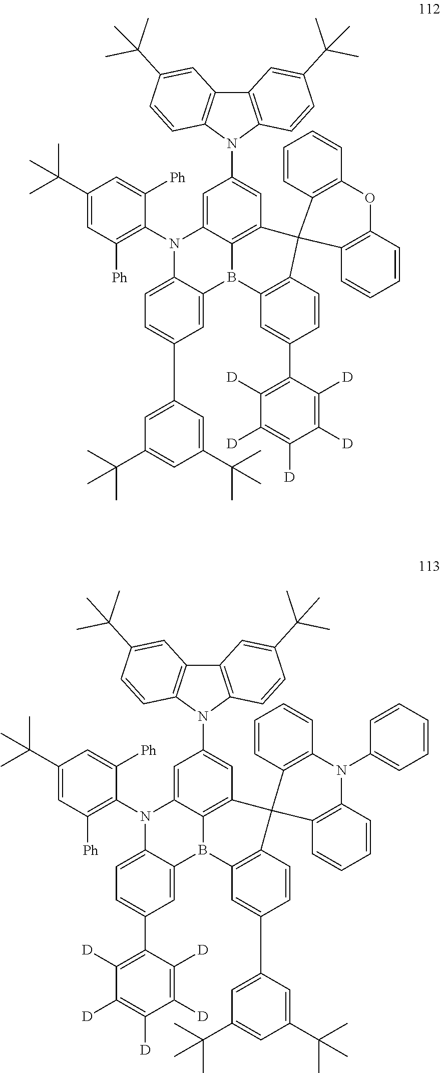 [SMILES: [2H]c1c([2H])c([2H])c(-c2ccc3c(c2)B2c4cc(-c5cc(C(C)(C)C)cc(C(C)(C)C)c5)ccc4N(c4c(-c5ccccc5)cc(C(C)(C)C)cc4-c4ccccc4)c4cc(-n5c6ccc(C(C)(C)C)cc6c6cc(C(C)(C)C)ccc65)cc(c42)C32c3ccccc3Oc3ccccc32)c([2H])c1[2H] ; [2H]c1c([2H])c([2H])c(-c2ccc3c(c2)B2c4cc(-c5cc(C(C)(C)C)cc(C(C)(C)C)c5)ccc4C4(c5ccccc5N(c5ccccc5)c5ccccc54)c4cc(-n5c6ccc(C(C)(C)C)cc6c6cc(C(C)(C)C)ccc65)cc(c42)N3c2c(-c3ccccc3)cc(C(C)(C)C)cc2-c2ccccc2)c([2H])c1[2H]] 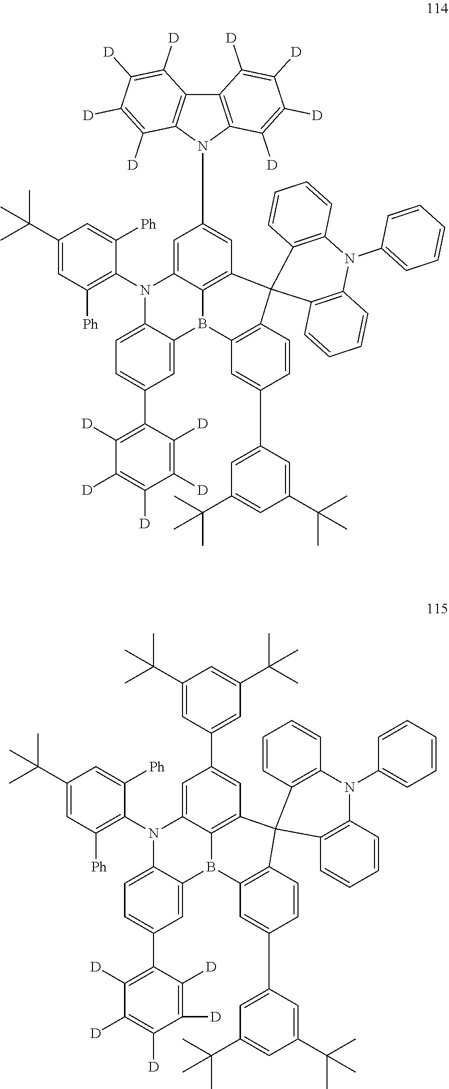 [SMILES: [2H]c1c([2H])c([2H])c(-c2ccc3c(c2)B2c4cc(-c5cc(C(C)(C)C)cc(C(C)(C)C)c5)ccc4C4(c5ccccc5N(c5ccccc5)c5ccccc54)c4cc(-n5c6c([2H])c([2H])c([2H])c([2H])c6c6c([2H])c([2H])c([2H])c([2H])c65)cc(c42)N3c2c(-c3ccccc3)cc(C(C)(C)C)cc2-c2ccccc2)c([2H])c1[2H] ; [2H]c1c([2H])c([2H])c(-c2ccc3c(c2)B2c4cc(-c5cc(C(C)(C)C)cc(C(C)(C)C)c5)ccc4C4(c5ccccc5N(c5ccccc5)c5ccccc54)c4cc(-c5cc(C(C)(C)C)cc(C(C)(C)C)c5)cc(c42)N3c2c(-c3ccccc3)cc(C(C)(C)C)cc2-c2ccccc2)c([2H])c1[2H]] 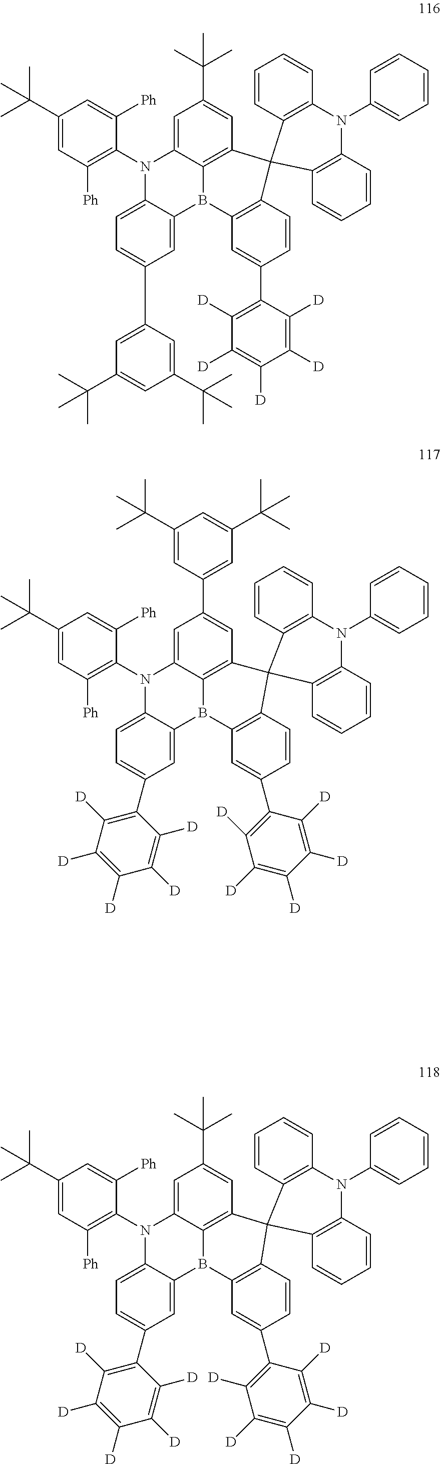 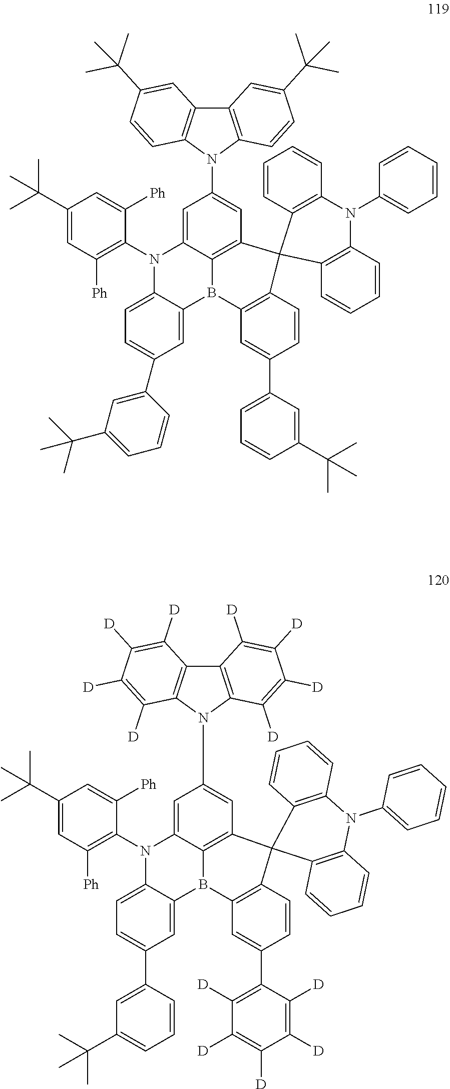 [SMILES: CC(C)(C)c1cccc(-c2ccc3c(c2)B2c4cc(-c5cccc(C(C)(C)C)c5)ccc4C4(c5ccccc5N(c5ccccc5)c5ccccc54)c4cc(-n5c6ccc(C(C)(C)C)cc6c6cc(C(C)(C)C)ccc65)cc(c42)N3c2c(-c3ccccc3)cc(C(C)(C)C)cc2-c2ccccc2)c1 ; [2H]c1c([2H])c([2H])c(-c2ccc3c(c2)B2c4cc(-c5cccc(C(C)(C)C)c5)ccc4N(c4c(-c5ccccc5)cc(C(C)(C)C)cc4-c4ccccc4)c4cc(-n5c6c([2H])c([2H])c([2H])c([2H])c6c6c([2H])c([2H])c([2H])c([2H])c65)cc(c42)C32c3ccccc3N(c3ccccc3)c3ccccc32)c([2H])c1[2H]] 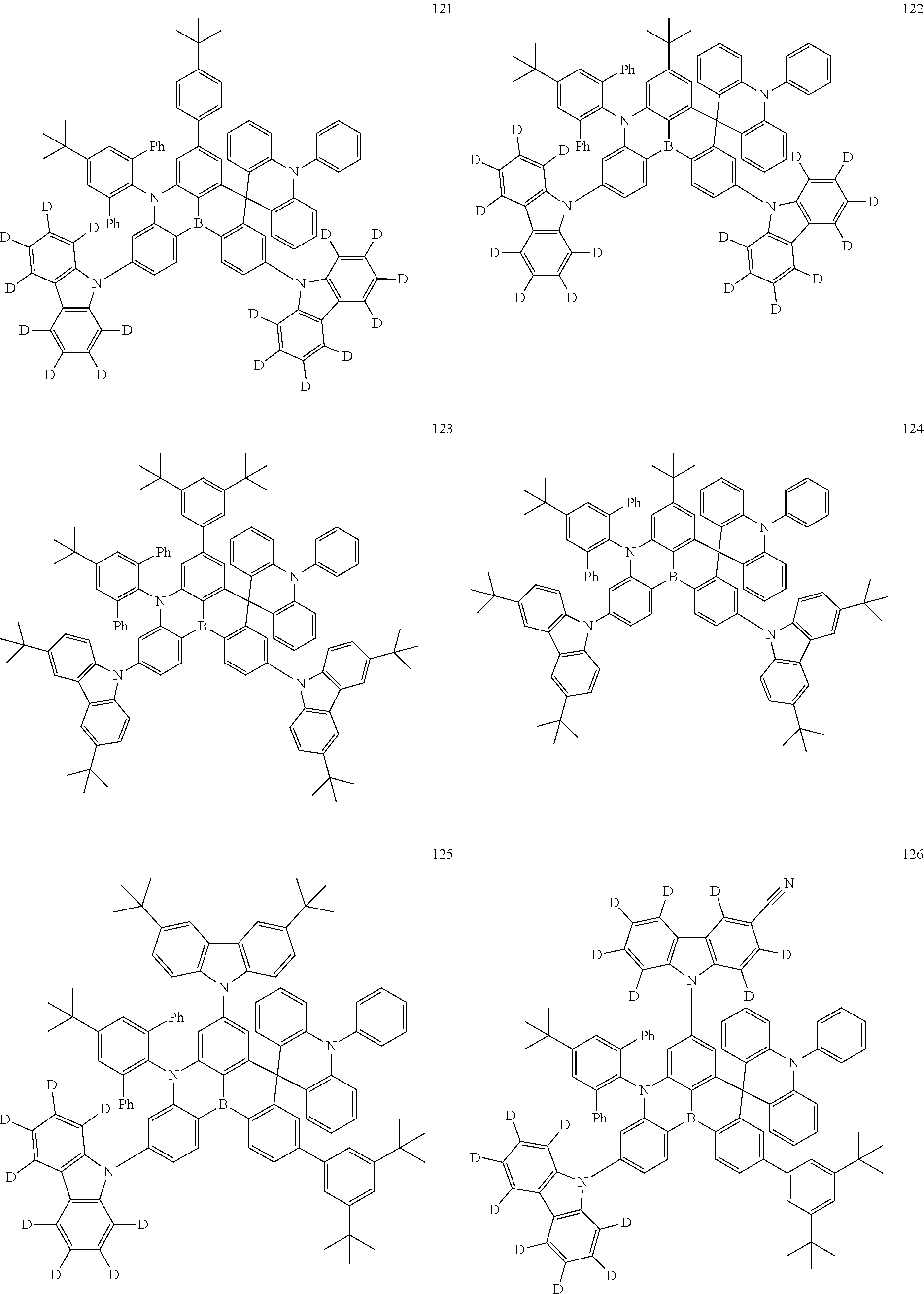 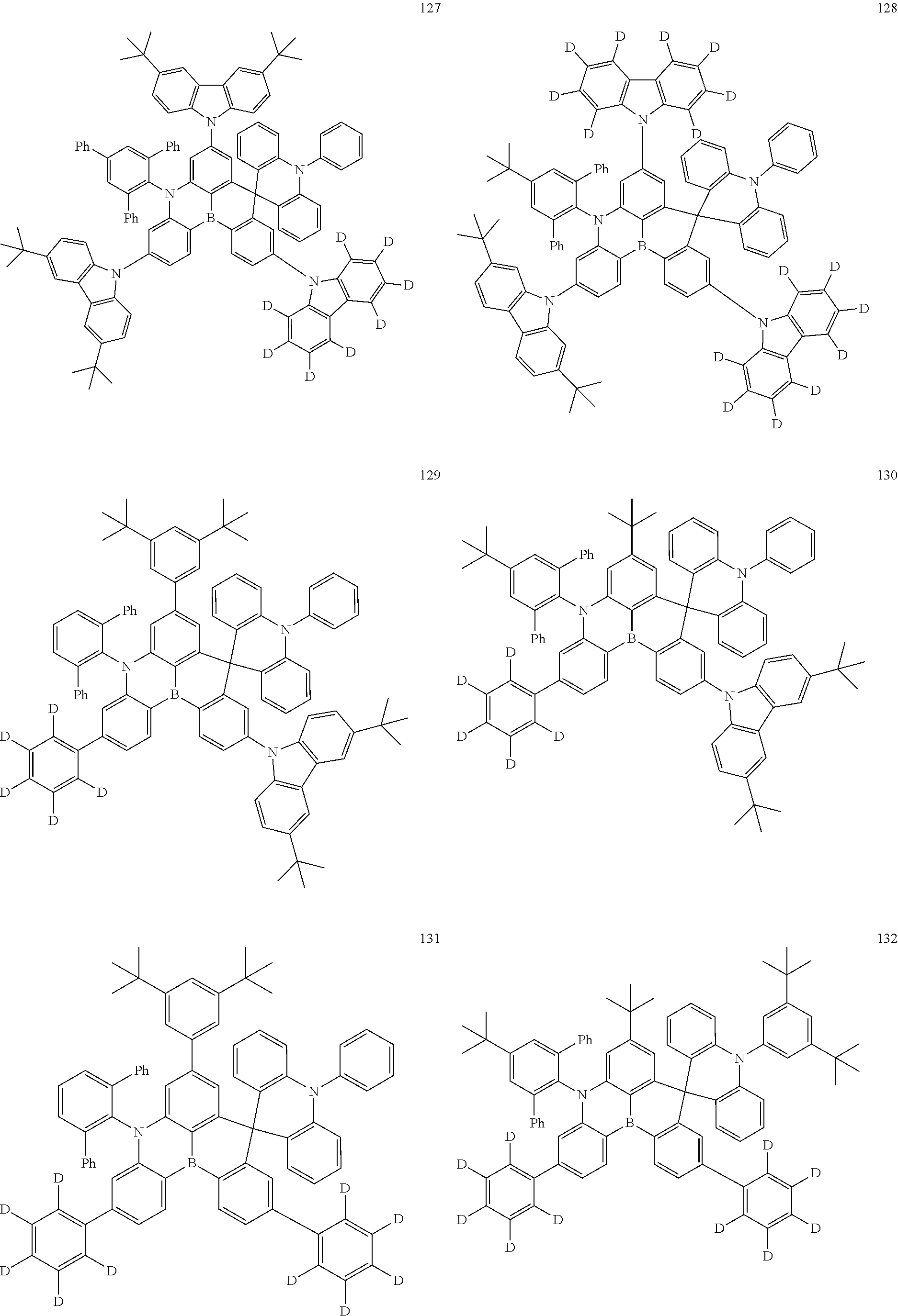 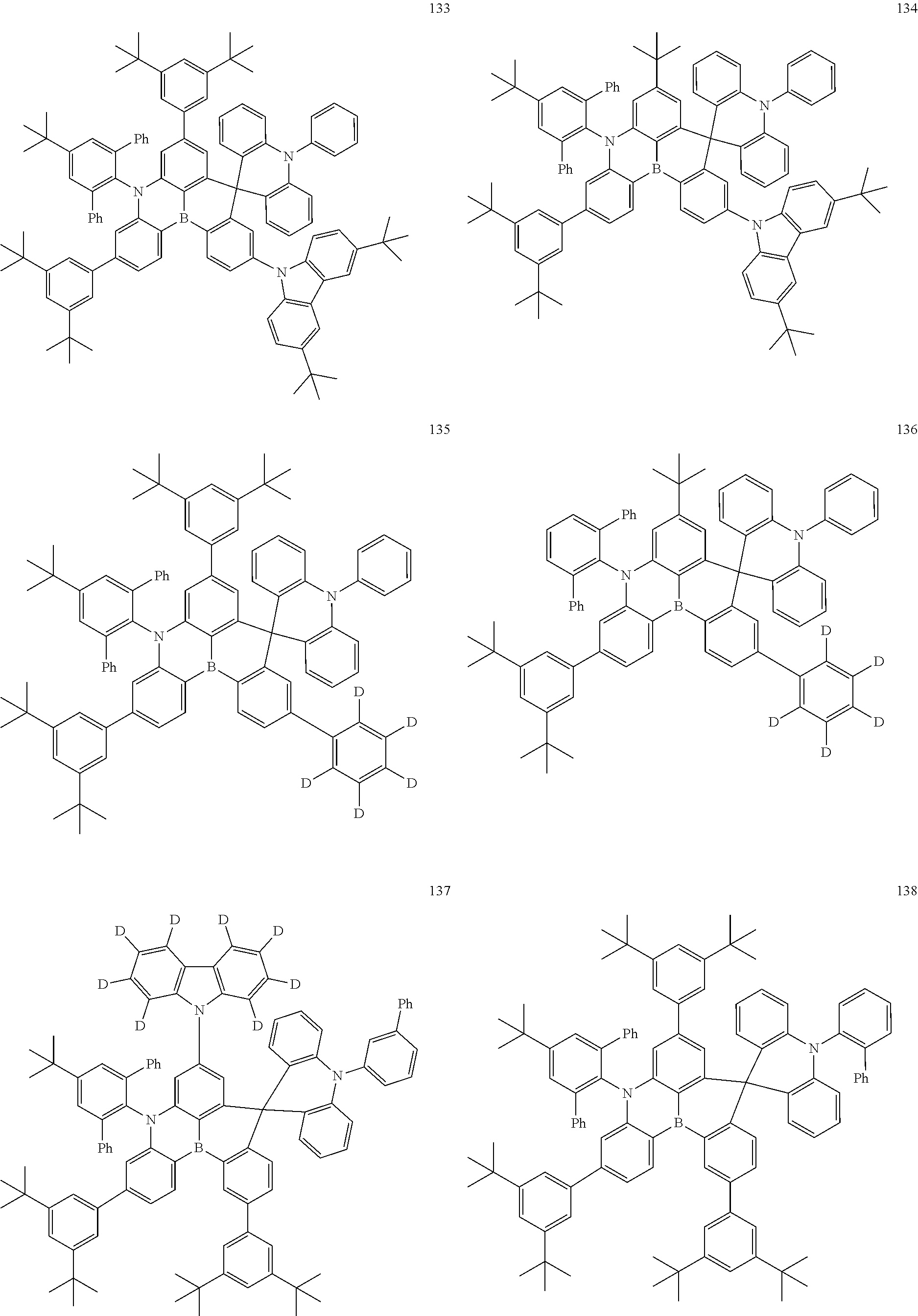 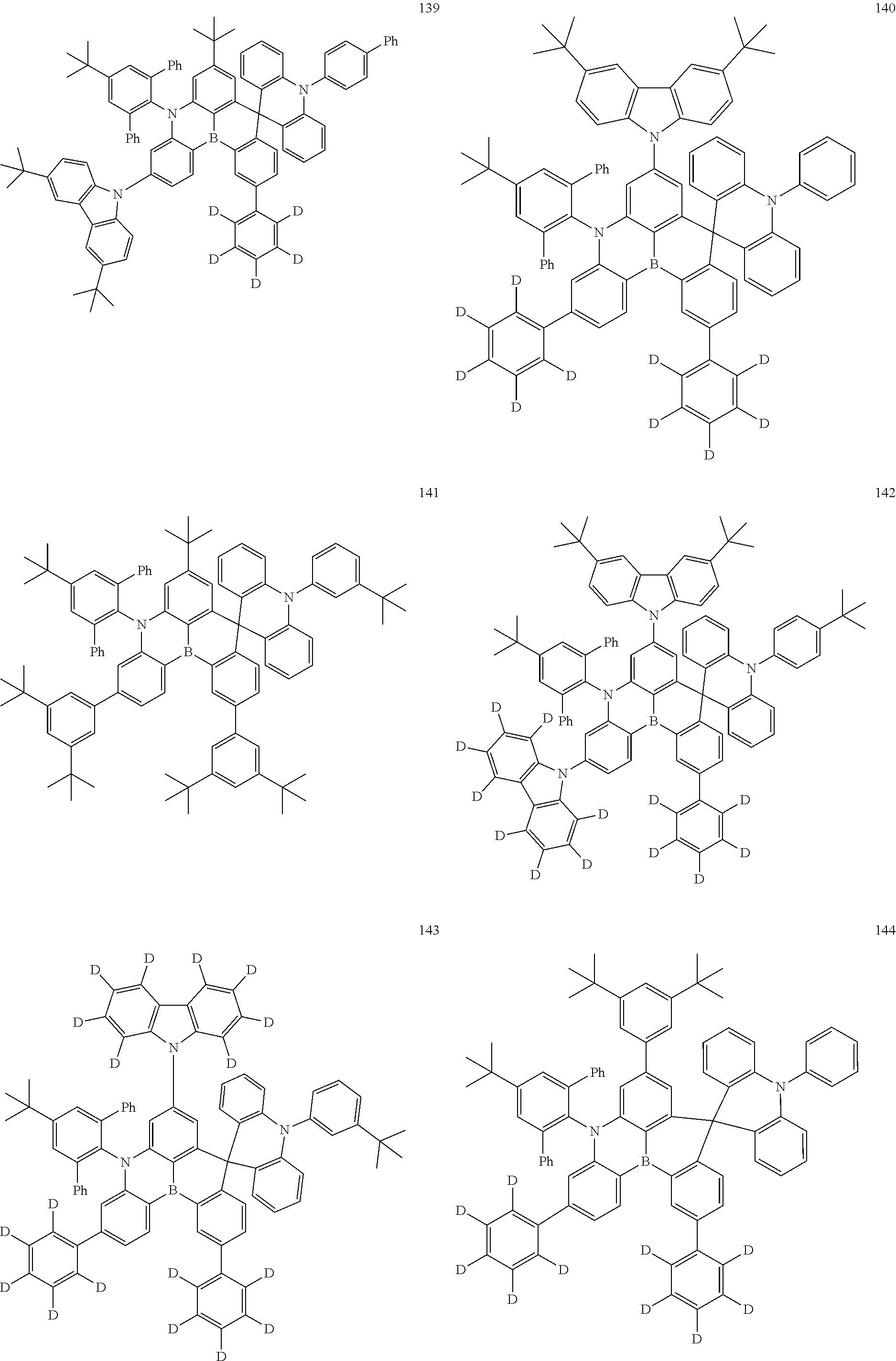 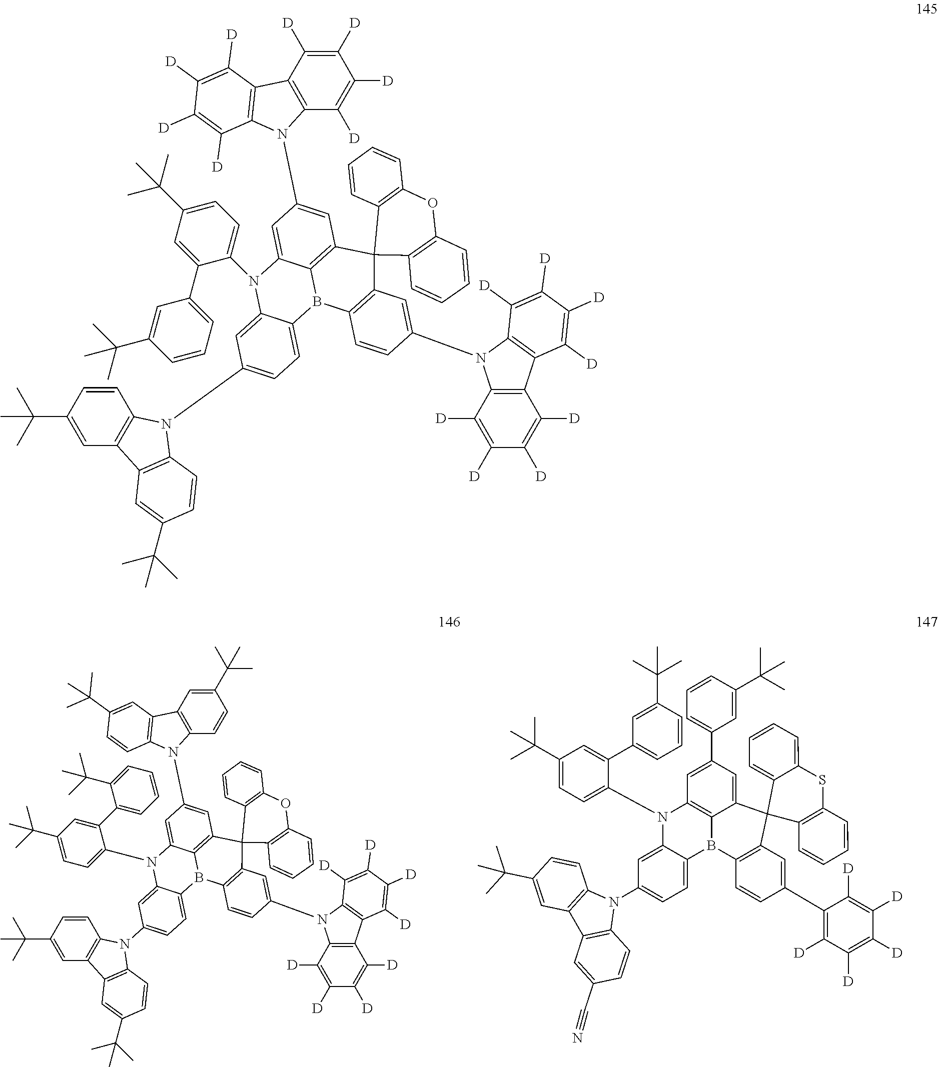 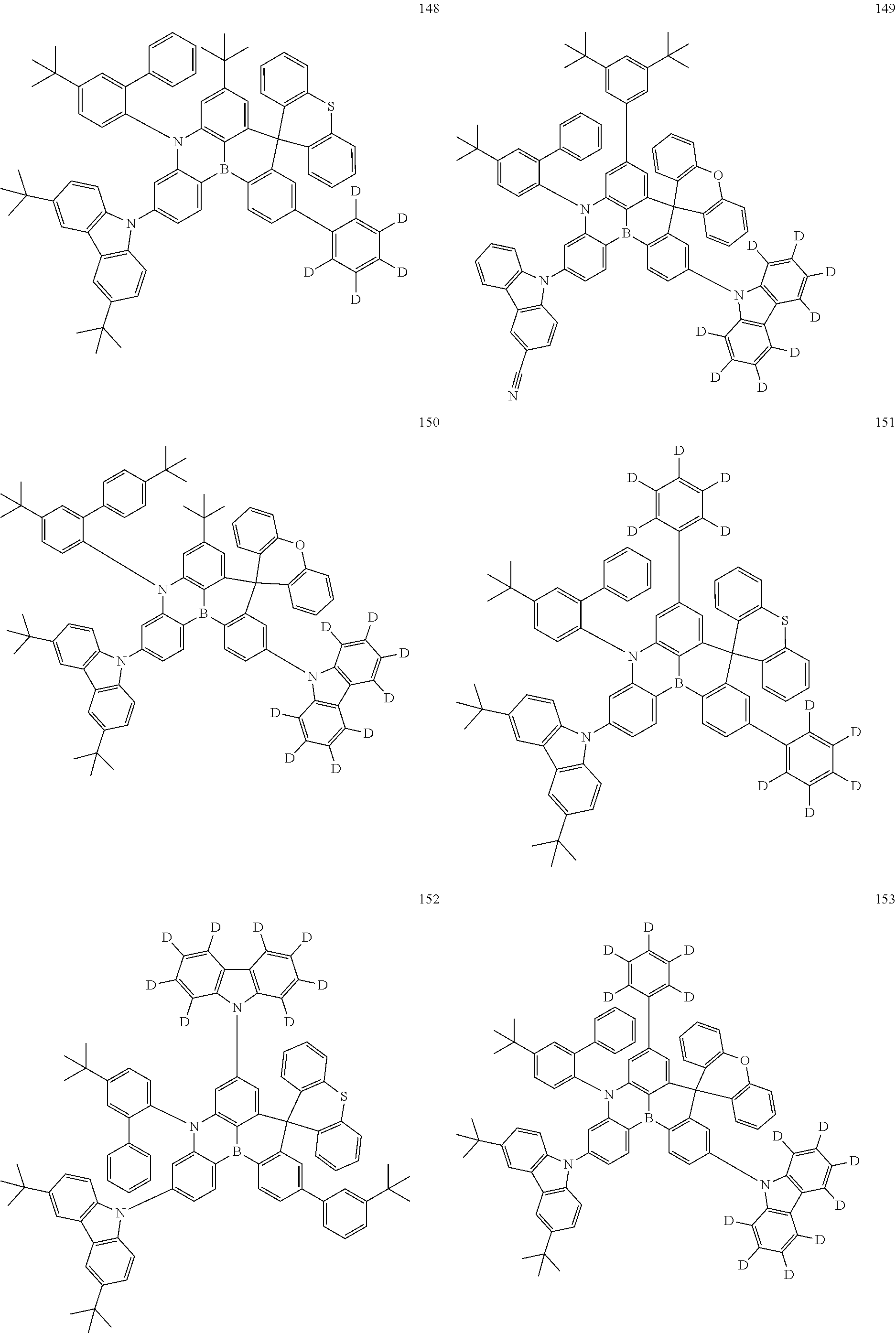 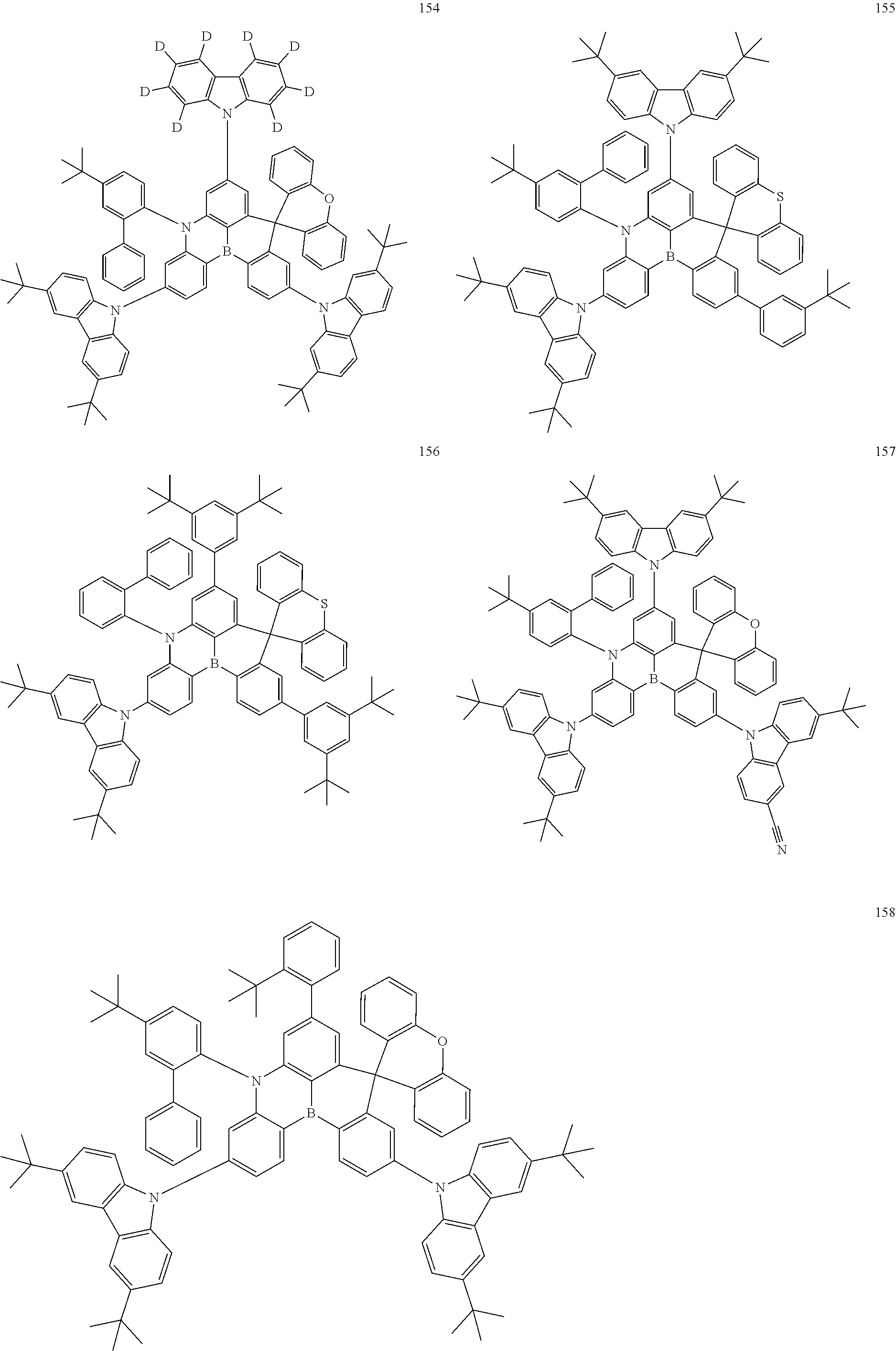 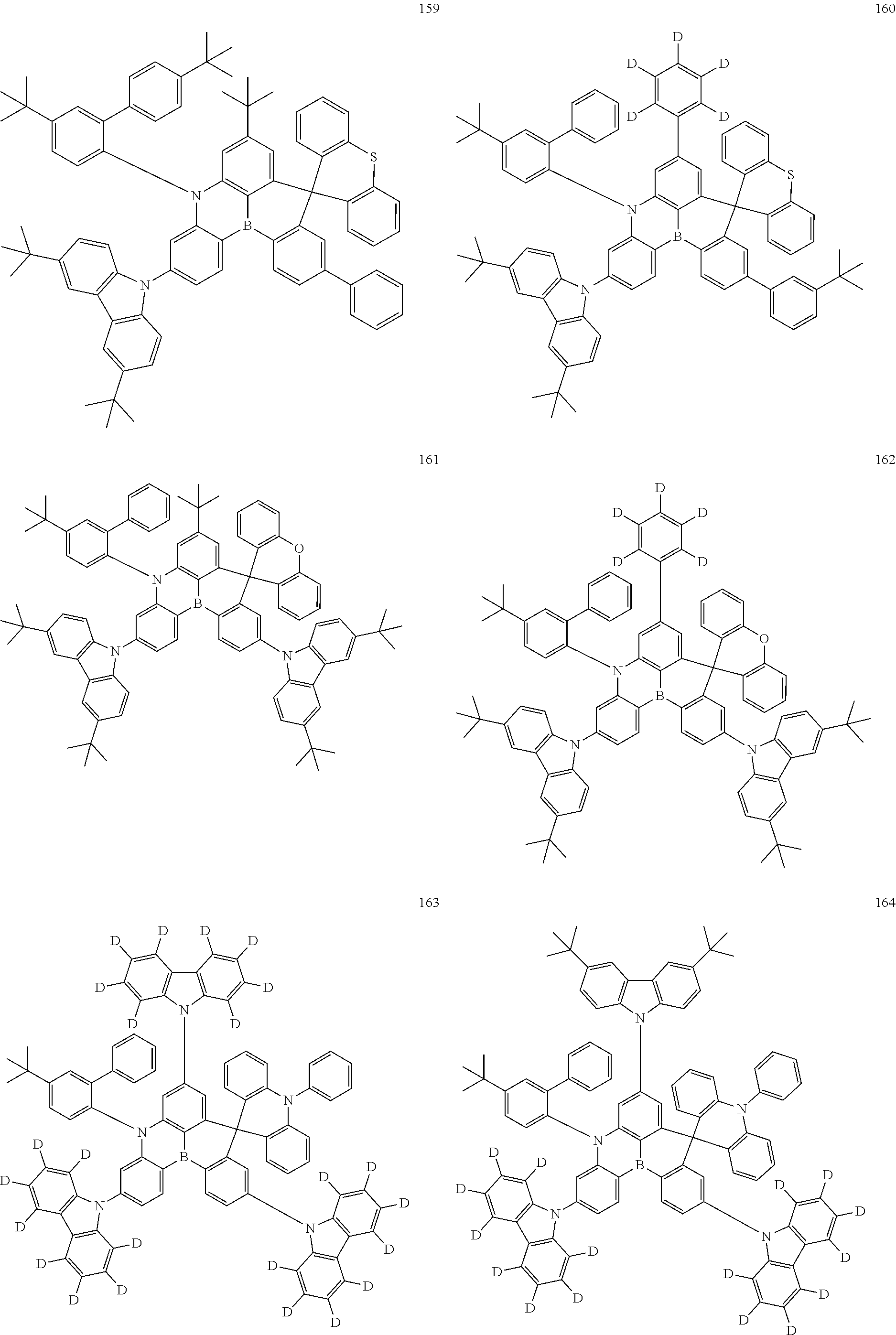 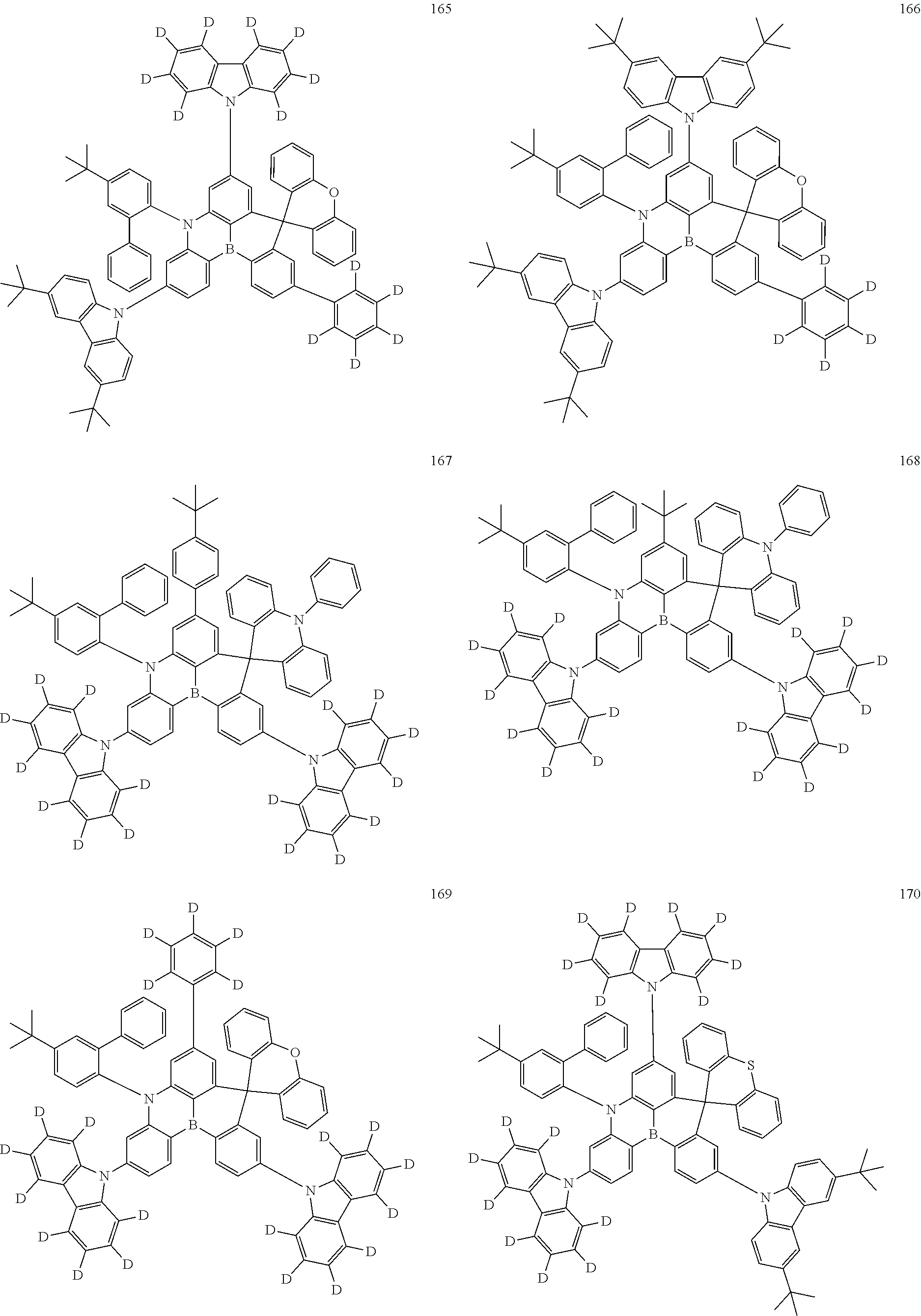 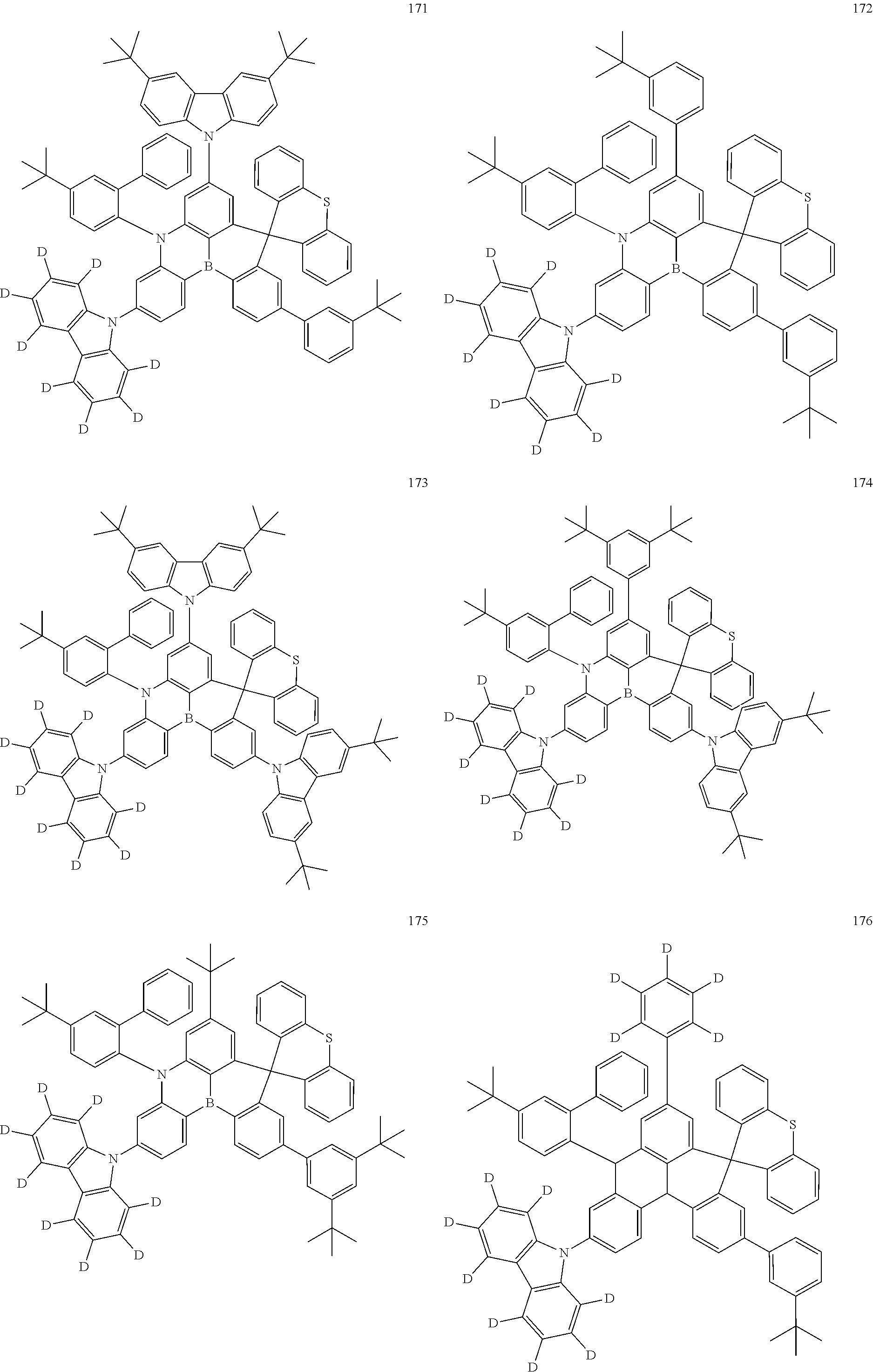 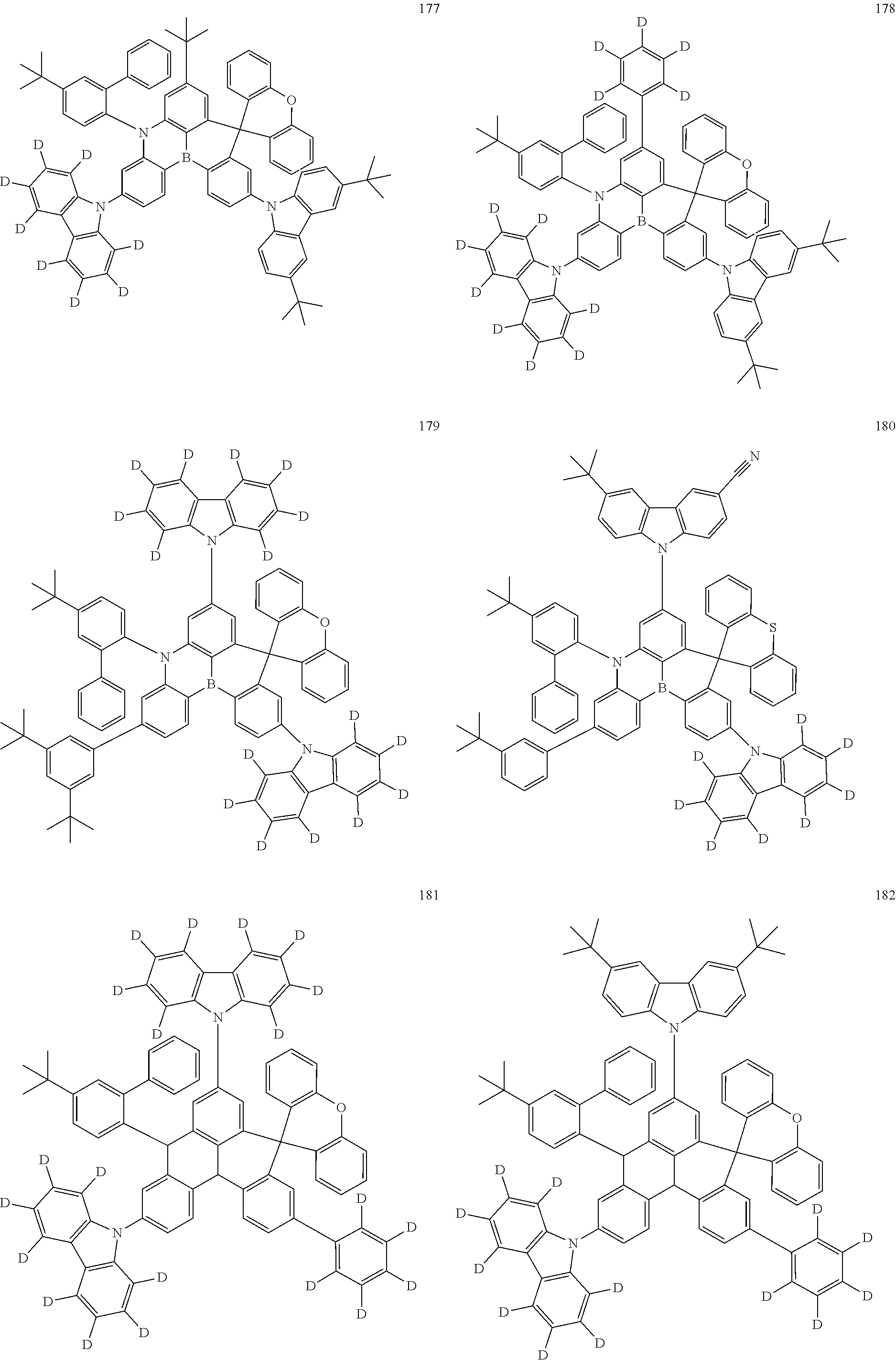 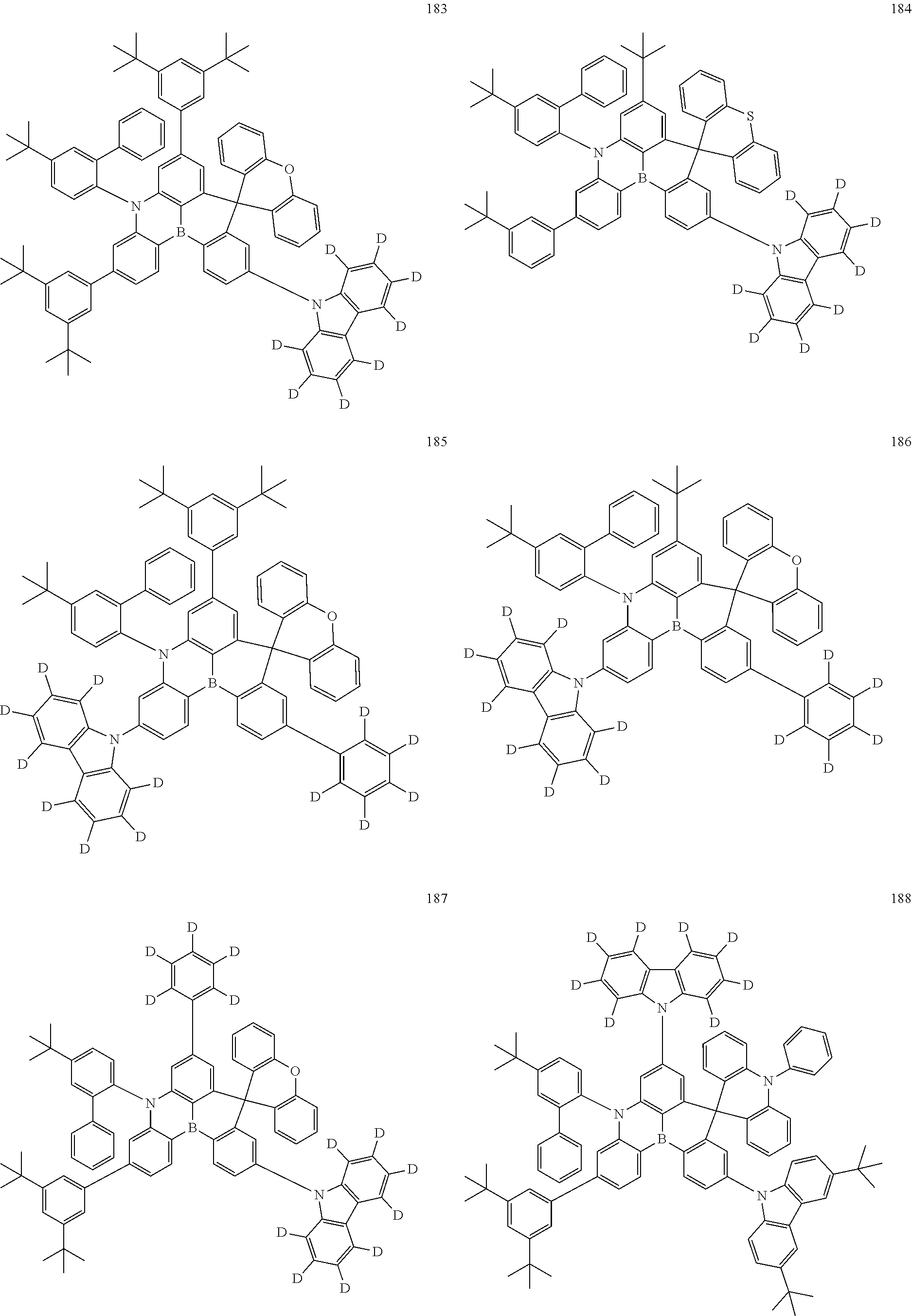 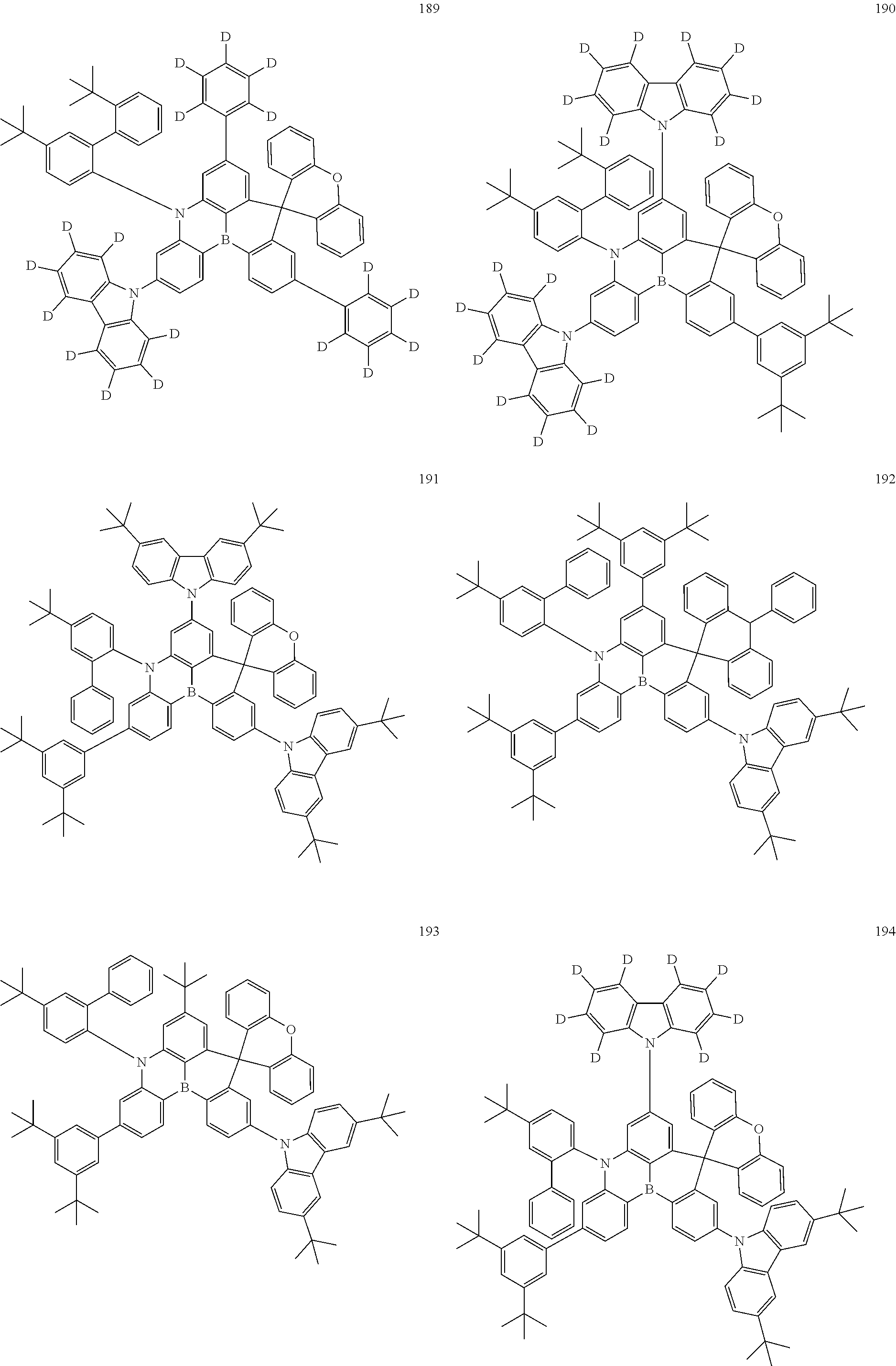 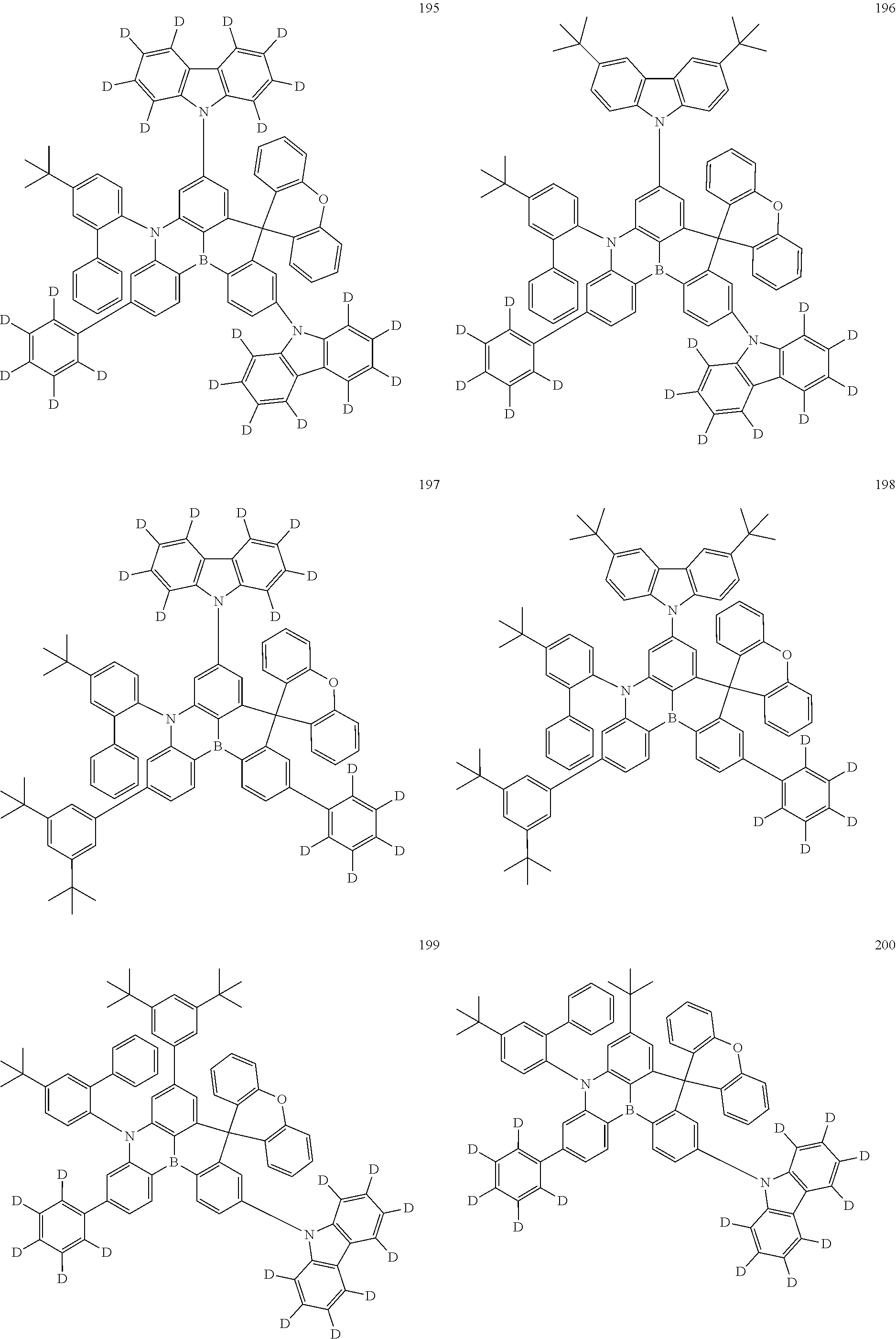 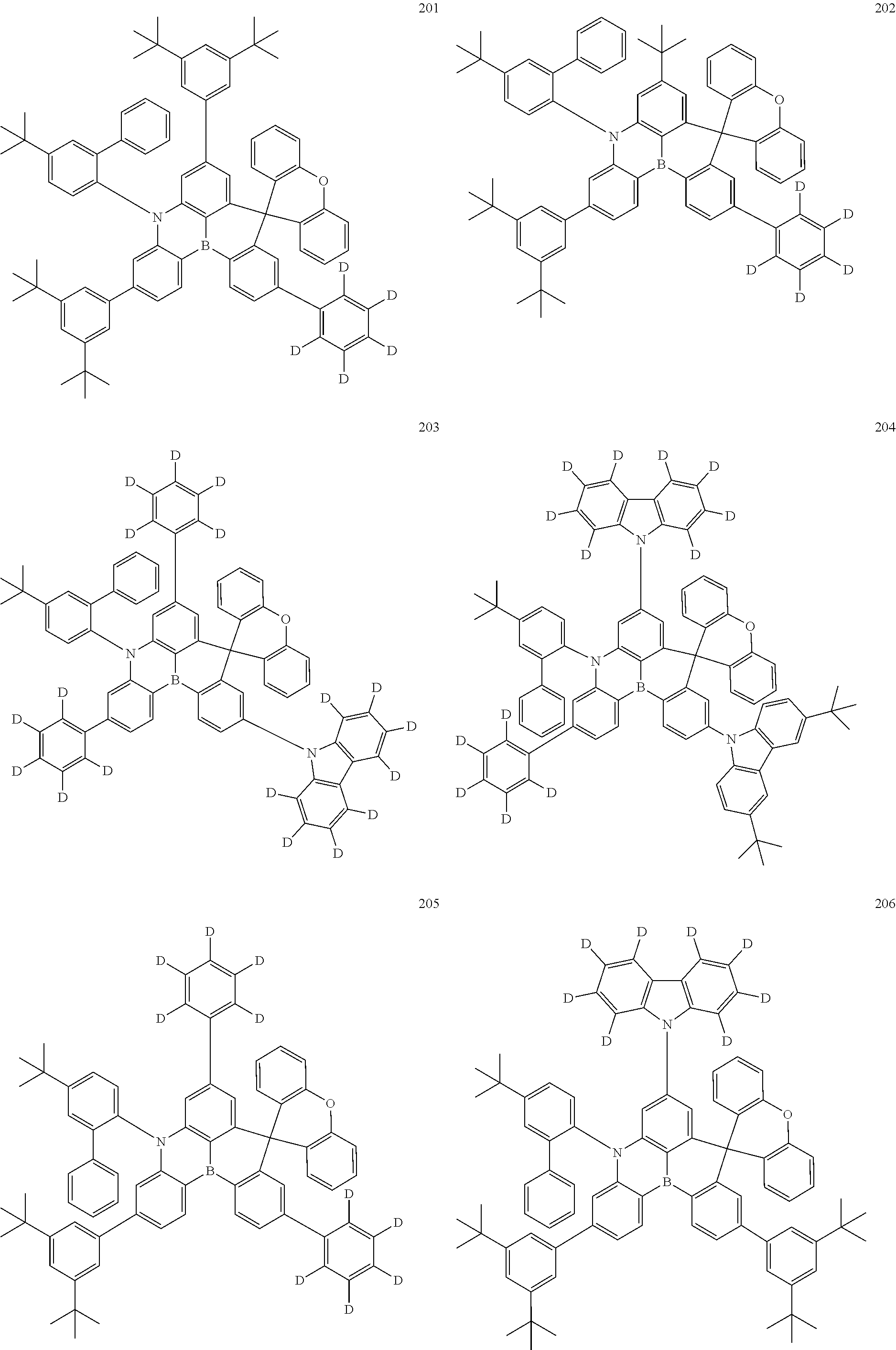 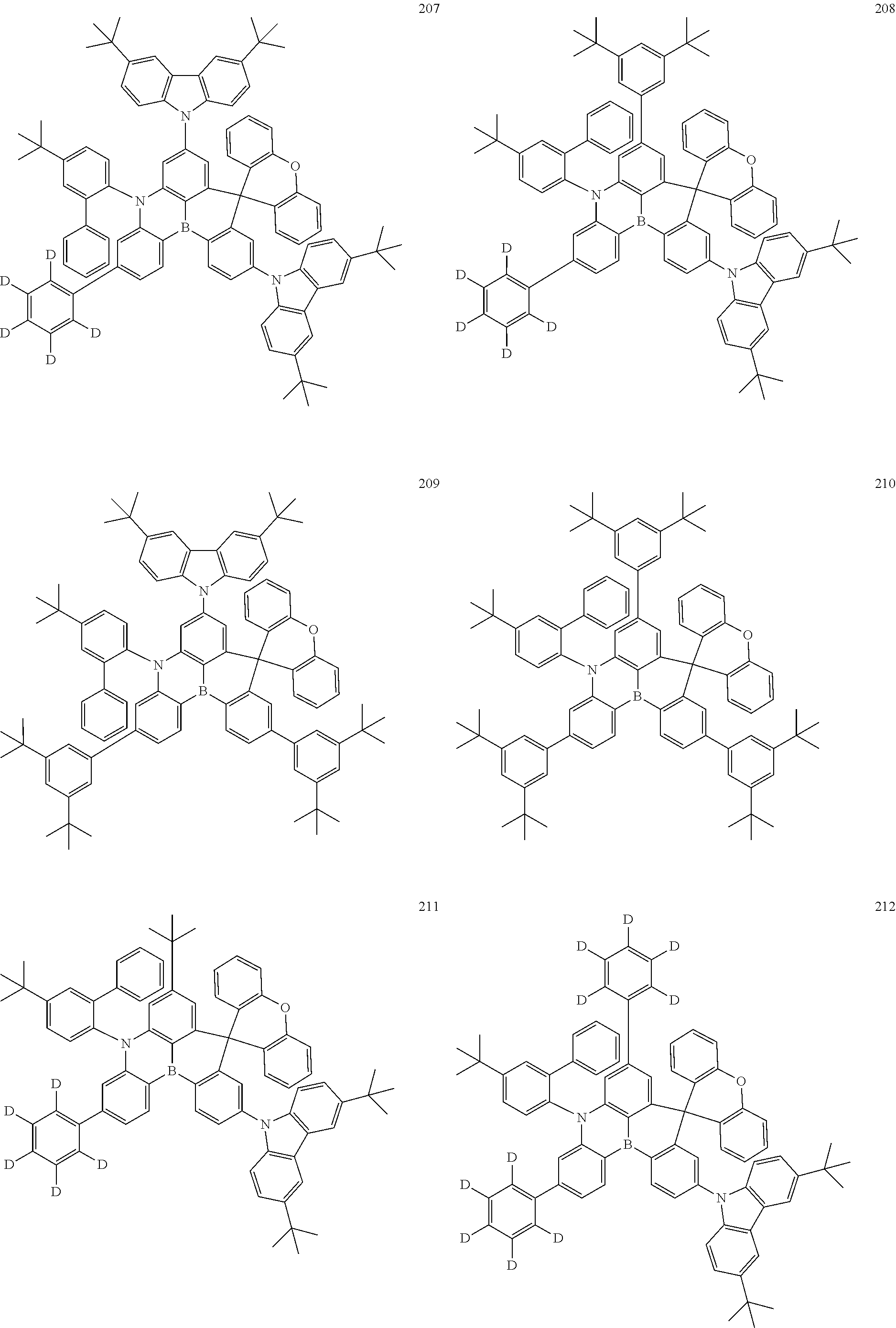 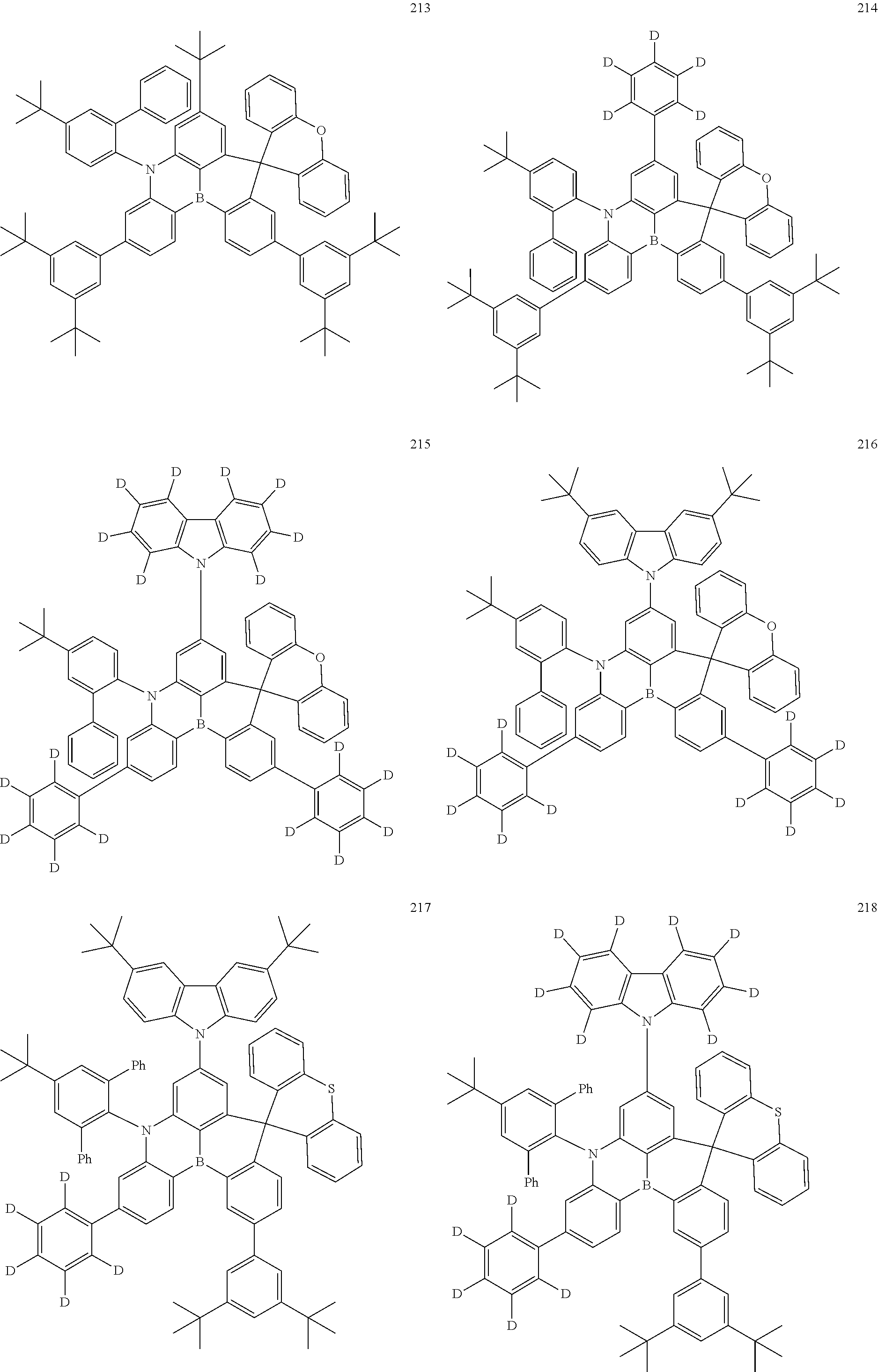 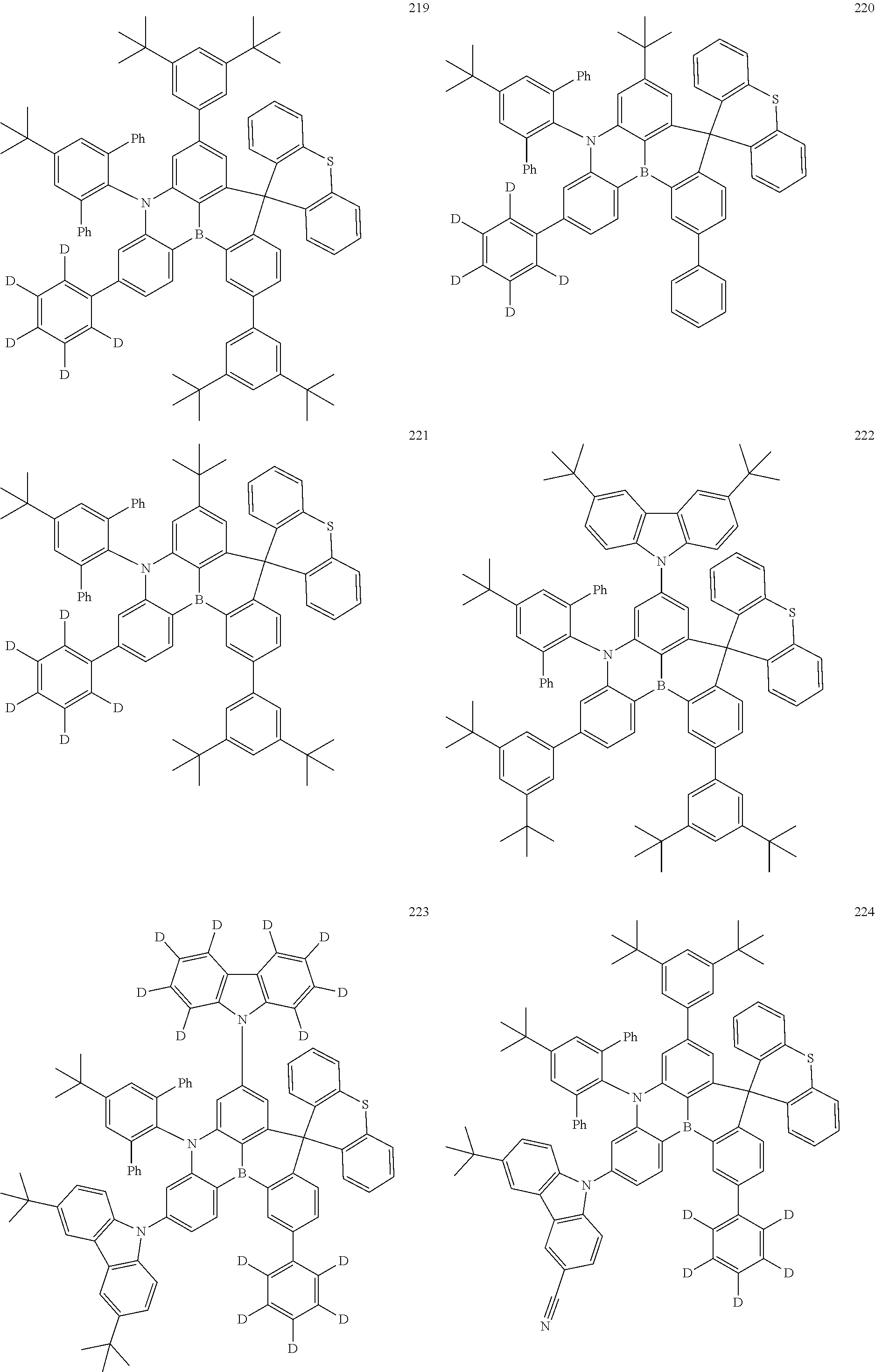 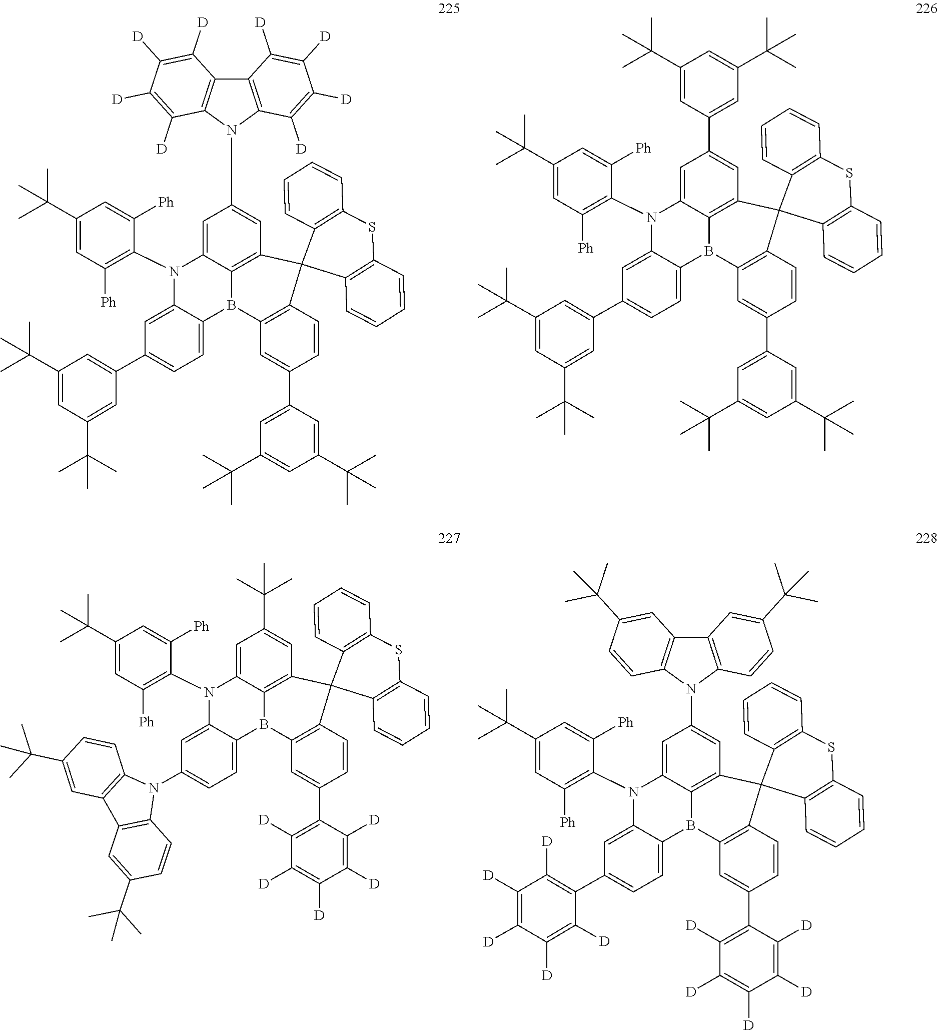 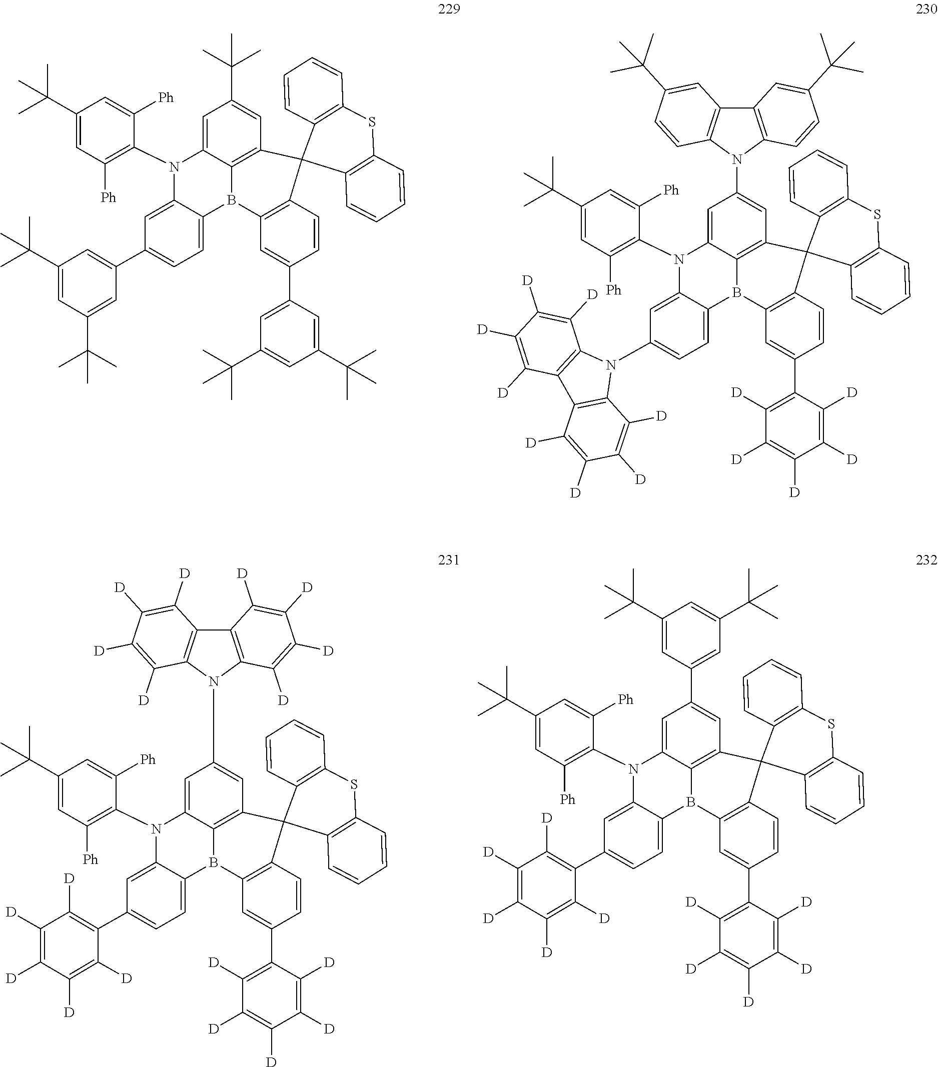 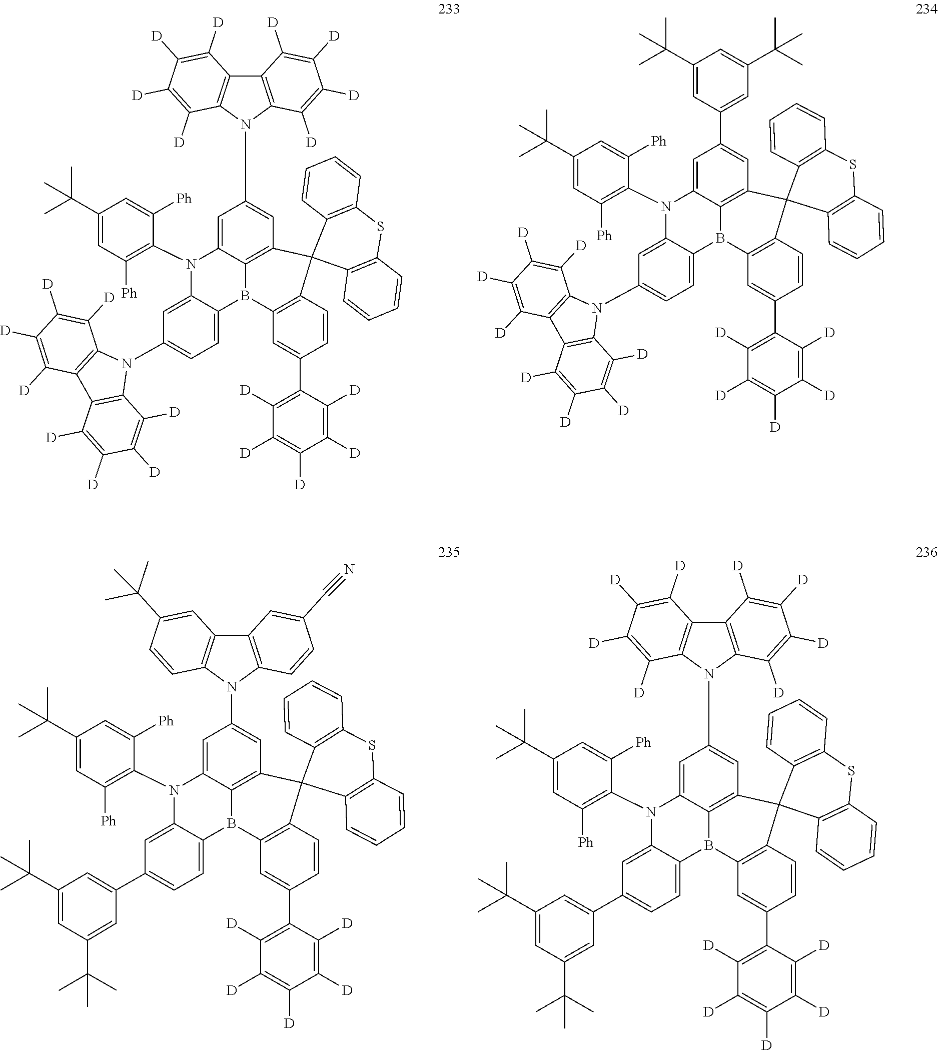 [chemical structure]
